(19) United States
(12) Patent Application Publication
(10) Pub. No.: US 2025/0188344 A1
(43) Pub. Date: Jun. 12, 2025

(54) Tetradentate Platinum And Palladium Complex Emitters

(71) Applicant: Arizona Board of Regents on behalf of Arizona State University, Scottsdale, AZ (US)

(72) Inventors: Jian Li, Tempe, AZ (US); Qian Wang, Gilbert, AZ (US); Nanqi Shao, Gilbert, AZ (US)

(21) Appl. No.: 18/968,374

(22) Filed: Dec. 4, 2024

Related U.S. Application Data
(60) Provisional application No. 63/613,283, filed on Dec. 21, 2023.
(60) Provisional application No. 63/611,414, filed on Dec. 18, 2023.
(60) Provisional application No. 63/606,270, filed on Dec. 5, 2023.
(60) Provisional application No. 63/606,265, filed on Dec. 5, 2023.
(60) Provisional application No. 63/606,247, filed on Dec. 5, 2023.

(51) Int. Cl. C09K 11/06

(52) U.S. Cl. CPC C09K 11/06; C09K 2211/185

(57) ABSTRACT

A series of novel tetradentate platinum (II) and palladium (II) complexes based with bulky substituents have been designed. These complexes can function as emitters in organic electroluminescent devices.

### CROSS-REFERENCE TO RELATED APPLICATIONS

The present application claims priority to U.S. Provisional Application No. 63/613,283, filed Dec. 21, 2023, U.S. Provisional Application No. 63/611,414, filed Dec. 18, 2023, U.S. Provisional Application No. 63/606,270, filed Dec. 5, 2023, U.S. Provisional Application No. 63/606,265, filed Dec. 5, 2023, and U.S. Provisional Application No. 63/606,247, filed Dec. 5, 2023, all of which applications are incorporated by reference herein in their entireties.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

In recent years, organic light emitting diodes (OLEDs) have attracted great attention from both academic and industrial areas due to their outstanding merits, like high color quality, wide-viewing angle, low cost fabrication, low power consumption, fast respond speed and high electron to photon conversion efficiency. Most of the organic light emitting diodes (OLEDs) are phosphorescent OLEDs using Iridium (Ir), palladium (Pd) and platinum (Pt) complexes, as these metal complexes have strong Spin-Orbital Coupling, they can efficiently emit light from their triplet exited state and reach nearly 100% internal efficiency. The development of efficient and stable narrowband deep blue emitters is the most interesting research topic in recent years. Due to the high energy of blue emitters, blue phosphorescent OLEDs suffer from low lifetimes.

There remains a need in the art for efficient and stable OLED components. This invention addresses this unmet need.

### SUMMARY OF THE INVENTION

In one aspect, the present invention relates to a compound of Formula I:

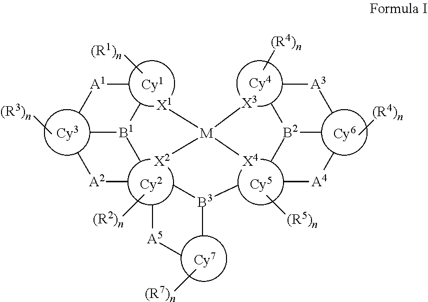

wherein:
M represents platinum (Pt) or palladium (Pd);
X¹, X², X³, and X⁴ are coordinated with M and are independently N or C;
each of Cy¹, Cy², Cy⁴, and Cy⁵ is independently substituted or unsubstituted aryl, cycloalkyl, cycloalkenyl, heteroaryl, heterocyclyl, carbene, or N-heterocyclic carbene;
Cy³, Cy⁶, and Cy⁷ are independently present or absent; wherein each Cy³, Cy⁶, and Cy⁷ present is independently substituted or unsubstituted aryl, cycloalkyl, cycloalkenyl, heteroaryl, heterocyclyl, carbene, or N-heterocyclic carbene;
wherein when Cy³ is absent, then B¹ is selected from the group consisting of CR⁸R⁹, CR¹═CR², C≡C, C═O, C═S, SiR⁸R⁹, GeR⁸R⁹, NR¹⁰, PR¹⁰, R¹⁰P═O, AsR¹⁰, R¹⁰As═O, O, S, S═O, SO₂, Se, Se═O, SeO₂, BR¹⁰, BiR¹⁰, R³Bi═O,

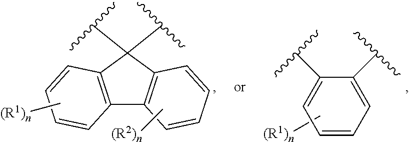

or B¹ is not present and Cy¹ and Cy² are connected by a single bond;
wherein when Cy³ is present, then B¹ is selected from the group consisting of CR⁸, SiR⁸, GeR⁸, N, P, P═O, As, As═O, B, R¹⁰Bi═O, or Bi, or B¹ is not present and Cy¹ and Cy² are connected by a single bond;
wherein when Cy⁶ is absent, then B² is selected from the group consisting of CR¹R², CR¹═CR², C≡C, C═O, C═S, SiR¹¹R¹², GeR¹¹R¹², NR¹³, PR¹³, R¹³P═O, AsR¹³, R¹³As═O, O, S, S═O, SO₂, Se, Se═O, SeO₂, BR¹³, BiR¹³, R¹³Bi═O,

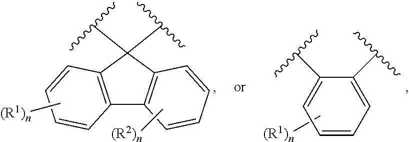

or B² is not present and Cy⁴ and Cy⁵ are connected by a single bond;
wherein when Cy⁶ is present, then B² is selected from the group consisting of CR¹¹, SiR¹¹, GeR¹¹, N, P, P═O, As, As═O, B, R¹³Bi═O, or Bi, or B² is not present and Cy⁴ and Cy⁵ are connected by a single bond;
wherein when Cy⁷ is absent, then A⁴ is absent and B² is A⁸;
wherein when Cy⁷ is present, then B² is selected from the group consisting of CR¹⁴, SiR¹⁴, GeR¹⁴, N, P, P═O, As, As═O, B, R¹⁴Bi═O, or Bi;
each of A¹, A², A³, A⁴, A⁵, and A⁸ is independently absent or present, and each of A¹, A², A³, A⁴, A⁵, and A⁸ represents a single bond, CR¹⁵R¹⁶, CR¹⁵═CR¹⁶, C≡C, C═O, C═S, SiR¹⁵R¹⁶, GeR¹⁵R¹⁶, NR¹⁷, PR¹⁷, R¹⁷P═O, AsR¹⁷, R¹⁷As═O, O, S, S═O, SO₂, Se, Se═O, SeO₂, BR¹⁷, BiR¹⁷, R¹⁷Bi═O,

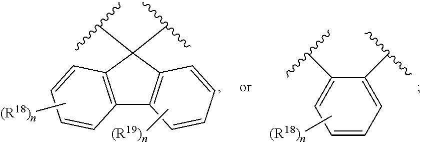

each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ is independently absent or present as a single substituent or multiple substituents, valency permitting, and each R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a fused ring of Formula A, Formula B, Formula C, or Formula D:

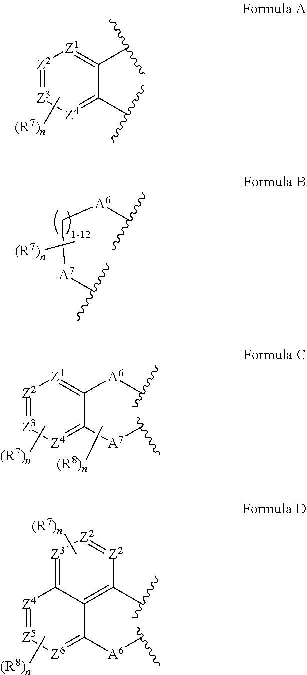

each of A⁶ and A⁷ is independently a single bond, CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

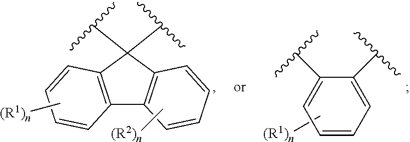

each of Z¹, Z², Z³, Z⁴, Z⁵, and Z⁶ is independently N, C, P, O, S, or Si.
each R⁷ and R⁸ is independently absent or present as a single substituent or multiple substituents, valency permitting, and each R⁷ and R⁸ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; wherein any two adjacent substituents may further join to form a fused ring; and
wherein one or more of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ optionally represents R^{X}, wherein R^{X} is a bulky substituent selected from the group consisting branched alkyl, cycloalkyl, bicyclo, fused bicyclo, adamantyl, ferrocenyl, dialkylamino, diarylamino, alkylarylamino, trialkylsilyl, tricycloalkylsilyl, triarylsilyl, triheteroarylsilyl, dialkylarylsilyl, alkyldiarylsilyl, alkylarylamino, and optionally substituted: aryl and heteroaryl.

In one embodiment, an organic light emitting device (OLED) and/or a consumer product including the compound is provided. In one embodiment, a formulation including the compound is included.

### BRIEF DESCRIPTION OF THE DRAWINGS

The following detailed description of preferred embodiments of the disclosure will be better understood when read in conjunction with the appended drawings. For the purpose of illustrating the invention, there are shown in the drawings embodiments which are presently preferred. It should be understood, however, that the invention is not limited to the precise arrangements and instrumentalities of the embodiments shown in the drawings.

FIG. 1 is a schematic diagram of an organic light emitting device.

FIG. 2 is a plot of PL intensity vs wavelength at room temperature and 77 K for an exemplary compound.

FIG. 3 is a plot of PL intensity vs wavelength at room temperature and 77 K for exemplary compound Pt605-m.

FIG. 4 is a plot of PL intensity vs wavelength at room temperature and 77 K for exemplary compound PtON5N-mtbb.

FIG. 5 is a plot of PL intensity vs wavelength at room temperature and 77 K for exemplary compound PtON5-dtb in 2-methyl-THF solution

FIG. 6 is a schematic illustration of triplet energy levels for such Pt complexes at room temperature, where T₁ originated from the phenoxy-carbazole functional group, i.e. blue solid line, in PtON5-AR structure, and T₁* originates from phenyl benzo-imidazole-carbene group, i.e. green long dash dot line.

FIG. 7 is a schematic illustration of new emitter design which could narrow emission spectra of Pt complexes by destabilizing the T₁* state through creating intramolecular interactions between: phenyl and benzo-imidazole-carbene groups, benzo-imidazole-carbene group and carbene-bonded aryl group, and carbene-bonded aryl group and pyridyl groups, or by stabilizing the T₁ state through extending conjugation level of carbazolyl groups.

FIG. 8 is the room temperature emission spectrum of PtON5-m in dichloromethane solution and the electroluminescent spectrum of device with a structure of ITO/HATCN (10 nm)/NPD (60 nm)/SiBCz (5 nm)/10 wt % PtON5-m: 60 wt % SiBCz: 30 wt % SiTrzCz2 (25 nm)/mSiTrzPh (5 nm)/BPyTP (40 nm)/LiQ/Al.

FIG. 9 is the room temperature emission spectra of 10% PtON5-m: SiBCz and 10% PtON5-m: SiTrzCz2 films. Shown also are the chemical structure of PtON5-m, PtON5-pCz-dtb, SiBCz and SiTrzCz2, and a schematic illustration of intermolecular interaction between PtON5-m and SiTrzCz2.

FIG. 10 is a plot of the room temperature emission spectra of 10% PtON5-dtb-m: SiTrzCz2 film.

FIG. 11 is a plot of PL intensity vs wavelength at room temperature and 77 K for exemplary compounds.

FIG. 12 is a plot of PL intensity vs wavelength at room temperature and 77 K for exemplary compounds.

FIG. 13 is a plot of PL intensity vs wavelength at room temperature and 77 K for exemplary compounds.

FIG. 14 is a plot of PL intensity vs wavelength at room temperature and 77 K for exemplary compound Pt2O1_pp.

FIG. 15 is a plot of PL intensity vs wavelength at room temperature for exemplary compound Pt2O5_N2m.

FIG. 16 is a plot of PL intensity vs wavelength at room temperature and 77 K for exemplary compound Pt8O5_N2m_pp

FIG. 17 is a schematic of energy levels that for narrowing emission full width at half maximum (FWHM).

FIG. 18 is a plot of PL intensity vs wavelength at room temperature and 77 K for exemplary compounds.

FIG. 19 is a plot of PL intensity vs wavelength at room temperature for exemplary compounds PtON5S56-m and PtON5S56-mtb. The photoluminescent spectra of exemplary compounds PtON5S56-m and PtON5S56-mtb are presented in FIG. 19. The photoluminescent spectra of exemplary compounds PtON5NS56-m and PtON5S56-dpm are presented in FIG. 20. The photoluminescent spectrum of another exemplary compound is presented in FIG. 21.

FIG. 20 is a plot of PL intensity vs wavelength at room temperature for exemplary compounds PtON5NS56-m and PtON5S56-dpm

FIG. 21 is a plot of PL intensity vs wavelength at room temperature and 77 K for an exemplary compound.

FIG. 22 is a plot of PL intensity vs wavelength at room temperature for exemplary compound Pt3O5-tbm.

### DETAILED DESCRIPTION

### Definitions

It is to be understood that the figures and descriptions in the present disclosure have been simplified to illustrate elements that are relevant for a clear understanding of the present invention, while eliminating, for the purpose of clarity, many other elements found in the art related to phosphorescent organic light emitting devices and the like. Those of ordinary skill in the art may recognize that other elements and/or steps are desirable and/or required in implementing the disclosed embodiments. However, because such elements and steps are well known in the art, and because they do not facilitate a better understanding of the present disclosure, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this disclosure belongs. Although any methods, materials and components similar or equivalent to those described herein can be used in the practice or testing of the disclosed embodiments, the preferred methods, and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, or ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

As referred to herein, a linking atom or a linking group can connect two groups such as, for example, an N and C group. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include, but are not limited to, hydrogen, hydroxyl, alkyl, alkoxy, ═O, halogen, nitro, amine, amide, thiol, aryl, heteroaryl, cycloalkyl, and heterocyclyl.

The term “cyclic structure” or the like terms used herein refer to any cyclic chemical structure which includes, but is not limited to, aryl, heteroaryl, cycloalkyl, cycloalkenyl, and heterocyclyl.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below.

The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula —(CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹—OA² or —OA¹—(OA²)ₐ—OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bond, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h] quinoxaline and dibenzo[f,h] quinoline. One of ordinary skill in the art can readily envision other nitrogen analogs of the aza-derivatives described above, and all such analogs are intended to be encompassed by the terms as set forth herein.

The term “aldehyde” as used herein is represented by the formula-C(O) H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula —(A¹O(O)C-A²-C(O)O), or —(A¹O(O)C-A²-OC(O))ₐ—, where A¹ and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula-(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” as used herein refers to the halogens fluorine, chlorine, bromine, and iodine.

The term “heterocyclyl,” as used herein refers to single and multi-cyclic non-aromatic ring systems and “heteroaryl” as used herein refers to single and multi-cyclic aromatic ring systems: in which at least one of the ring members is other than carbon. The term “heterocyclyl” includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N3.

The term “nitro” as used herein is represented by the formula —NO₂.

The term “nitrile” as used herein is represented by the formula —CN.

The term “ureido” as used herein refers to a urea group of the formula —NHC(O)NH₂ or —NHC(O)NH—.

The term “phosphoramide” as used herein refers to a group of the formula —P(O)(NA¹A²)₂, where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “carbamoyl” as used herein refers to an amide group of the formula-CONA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “sulfamoyl” as used herein refers to a group of the formula —S(O)₂NA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “silyl” as used herein is represented by the formula —SiA 1A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ is hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ is hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where Aland A² can be, independently, an alkyl, cycloalkyl, alkenyl, cycloalkenyl, alkynyl, cycloalkynyl, aryl, or heteroaryl group as described herein.

The term “thiol” as used herein is represented by the formula —SH.

The term “polymeric” includes polyalkylene, polyether, polyester, and other groups with repeating units, such as, but not limited to —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COOCH₂CH₃)]ₙ—CH₃, and —[CH₂CH(COO′Bu)]ₙ—CH₃, where n is an integer (e.g., n>1 or n>2).

“R,” “R¹,” “R²,” “R³,” “Rⁿ,” where n is an integer, as used herein can, independently, include hydrogen or one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within a second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

As described herein, compounds of the disclosure may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. It is also contemplated that, in certain aspects, unless expressly indicated to the contrary, individual substituents can be further optionally substituted (i.e., further substituted or unsubstituted). In some aspects, the optional substituent may be selected from the group consisting of hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, and any combination thereof; wherein two or more optional substituents may together join to form a fused ring.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2,2′ positions in a biphenyl, or 1,8 position in a naphthalene, as long as they can form a stable fused ring system.

In some aspects, a structure of a compound can be represented by a formula:

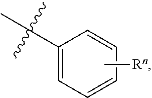

which is understood to be equivalent to a formula:

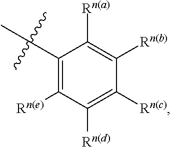

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

### Compounds

The compounds disclosed herein are suited for use in a wide variety of optical and electro-optical devices, including, but not limited to, photo-absorbing devices such as solar- and photo-sensitive devices, organic light emitting devices (OLEDs), photo-emitting devices, or devices capable of both photo-absorption and emission and as markers for bio-applications.

The compounds disclosed herein are useful in a variety of applications. As light emitting materials, the compounds can be useful in organic light emitting devices (OLEDs), luminescent devices and displays, and other light emitting devices.

In another aspect, the compounds can provide improved efficiency, improved operational lifetimes, or both in lighting devices, such as, for example, organic light emitting devices, as compared to conventional materials.

The compounds of the disclosure can be made using a variety of methods, including, but not limited to those recited in the examples provided herein.

In one aspect, the present invention relates to a compound of Formula I:

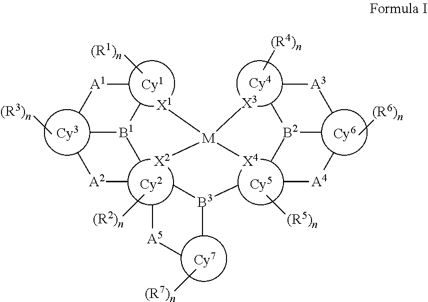

wherein:
M represents platinum (Pt) or palladium (Pd);
X¹, X², X³, and X⁴ are coordinated with M and are independently N or C;
each of Cy¹, Cy², Cy⁴, and Cy⁵ is independently substituted or unsubstituted aryl, cycloalkyl, cycloalkenyl, heteroaryl, heterocyclyl, carbene, or N-heterocyclic carbene;
Cy³, Cy⁶, and Cy⁷ are independently present or absent; wherein each Cy³, Cy⁶, and Cy⁷ present is independently substituted or unsubstituted aryl, cycloalkyl, cycloalkenyl, heteroaryl, heterocyclyl, carbene, or N-heterocyclic carbene;
wherein when Cy³ is absent, then B¹ is selected from the group consisting of CR⁸R⁹, CR¹═CR², C≡C, C═O, C═S, SiR⁸R⁹, GeR⁸R⁹, NR¹⁰, PR¹⁰, R¹⁰P═O, AsR¹⁰, R¹⁰As═O, O, S, S═O, SO₂, Se, Se═O, SeO₂, BR¹⁰, BiR¹⁰, R³Bi═O,

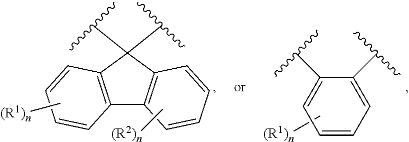

or B¹ is not present and Cy¹ and Cy² are connected by a single bond;
wherein when Cy³ is present, then B¹ is selected from the group consisting of CR⁸, SiR⁸, GeR⁸, N, P, P═O, As, As═O, B, R¹⁰Bi═O, or Bi, or B¹ is not present and Cy¹ and Cy² are connected by a single bond;
wherein when Cy⁶ is absent, then B² is selected from the group consisting of CR¹R², CR¹═CR², C≡C, C═O, C═S, SiR¹¹R¹², GeR¹¹R¹², NR¹³, PR¹³, R¹³P═O, AsR¹³, R¹³As═O, O, S, S═O, SO₂, Se, Se═O, SeO₂, BR¹³, BiR¹³, R¹³Bi═O,

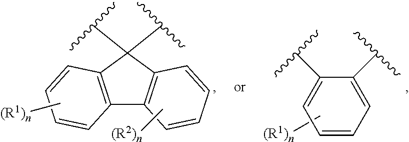

or B² is not present and Cy⁴ and Cy⁵ are connected by a single bond;
wherein when Cy⁶ is present, then B² is selected from the group consisting of CR¹¹, SiR¹¹, GeR¹¹, N, P, P═O, As, As═O, B, R¹³Bi═O, or Bi, or B² is not present and Cy⁴ and Cy⁵ are connected by a single bond;
wherein when Cy⁷ is absent, then A⁴ is absent and B² is A⁸;
wherein when Cy⁷ is present, then B² is selected from the group consisting of CR¹⁴, SiR¹⁴, GeR¹⁴, N, P, P═O, As, As═O, B, R¹⁴Bi═O, or Bi;
each of A¹, A², A³, A⁴, A⁵, and A⁸ is independently absent or present, and each of A¹, A², A³, A⁴, A⁵, and A⁸ represents a single bond, CR¹⁵R¹⁶, CR¹⁵═CR¹⁶, C≡C, C═O, C═S, SiR¹⁵R¹⁶, GeR¹⁵R¹⁶, NR¹⁷, PR¹⁷, R¹⁷P═O, AsR¹⁷, R¹⁷As═O, O, S, S═O, SO₂, Se, Se═O, SeO₂, BR¹⁷, BiR¹⁷, R¹⁷Bi═O,

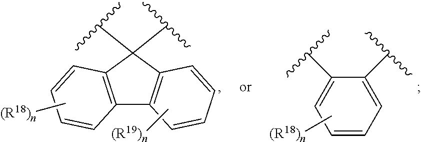

each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ is independently absent or present as a single substituent or multiple substituents, valency permitting, and each R¹, R², R³, R⁴, R⁵, R⁶, R⁷, R⁸, R⁹, R¹⁰, R¹, R¹², R¹³, R¹⁴, R¹⁵, R¹⁶, R¹⁷, R¹⁸, and R¹⁹ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a fused ring of Formula A, Formula B, Formula C, or Formula D:

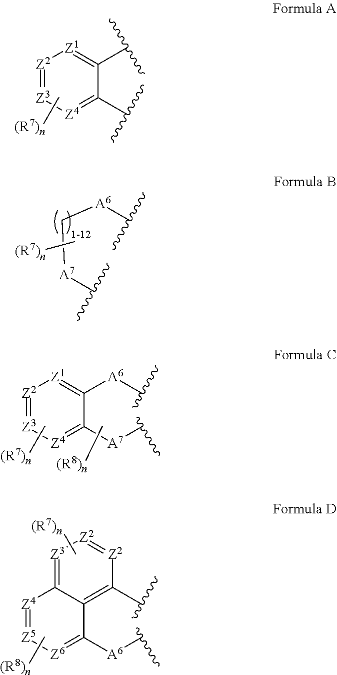

each of A⁶ and A⁷ is independently a single bond, CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

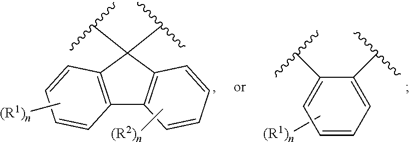

each of Z¹, Z², Z³, Z⁴, Z⁵, and Z⁶ is independently N, C, P, O, S, or Si.
each R⁷ and R⁸ is independently absent or present as a single substituent or multiple substituents, valency permitting, and each R⁷ and R⁸ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; wherein any two adjacent substituents may further join to form a fused ring; and
wherein one or more of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ optionally represents R^{X}, wherein R^{X} is a bulky substituent selected from the group consisting branched alkyl, cycloalkyl, dialkylamino, diarylamino, alkylarylamino, trialkylsilyl, triarylsilyl, dialkylarylsilyl, alkyldiarylsilyl, alkylarylamino, and optionally substituted: aryl and heteroaryl.

In one embodiment, each occurrence of the bulky group is selected from the group consisting of substituted or unsubstituted phenyl ring, heteroaryl ring, iso-propyl group, tert-butyl group, or diisopropyl amino group. In one embodiment, one or more occurrences of the bulky group represents a substituted aryl group. In one embodiment, one or more occurrences of the bulky group represents an unsubstituted aryl group. In one embodiment, one or more occurrences of the bulky group represents a fused polycyclic aryl group. In one embodiment, one or more occurrences of the bulky group represents a substituted heteroaryl group. In one embodiment, one or more occurrences of the bulky group represents an heteroaryl group. In one embodiment, one or more occurrences of the bulky group represents a fused polycyclic heteroaryl group. In one embodiment, one or more occurrences of the bulky group represents a branched alkyl group selected from the group consisting of isopropyl, isobutyl, s-butyl, t-butyl, isopentyl, s-pentyl, and neopentyl. In one embodiment, one or more occurrences of the bulky group represents a cycloalkyl group selected from the group consisting of cyclopropyl, cyclobutyl, cyclopentyl, cyclohexyl, and norbornyl. In one embodiment, one or more occurrences of the bulky group represents a heterocycloalkyl group. In one embodiment, one or more occurrences of the bulky group represents an amino group selected from the group consisting of diisopropylamino, diisobutylamino, di(sec-butyl)amino, di(tert-butyl)amino, di(neopentyl)amino, diisopentylamino, di(tert-pentyl)amino, N-isopropyl-N-methylamino, N-ethyl-N-isopropylamino, and N-methyl-N-(tert-butyl)amino.

In one embodiment, B² is present and the structure

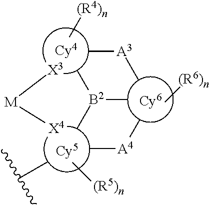

represents of the following structures:

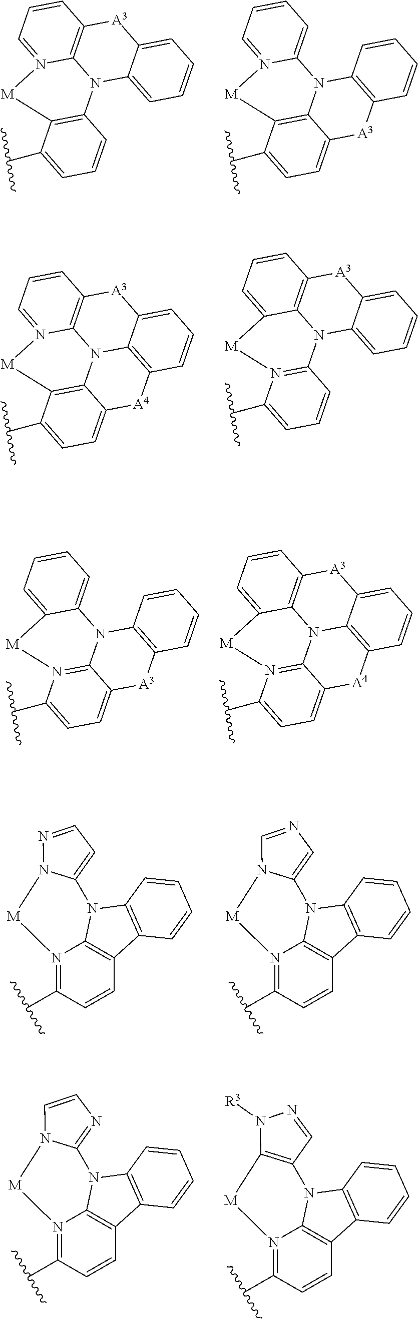

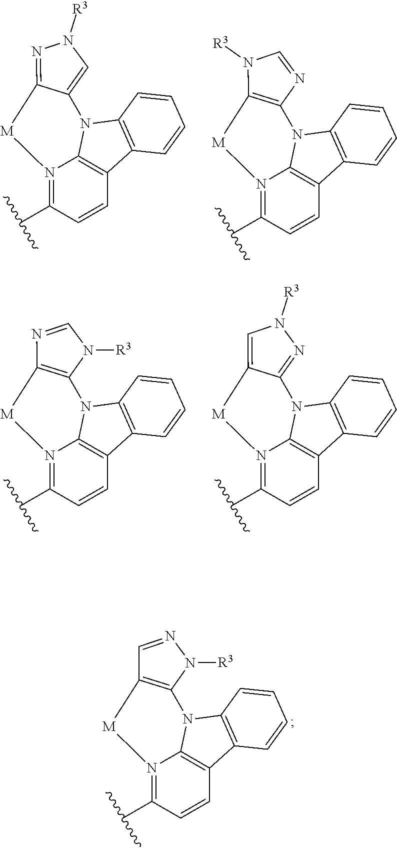

or
B² is not present and Cy⁶ is present and the structure

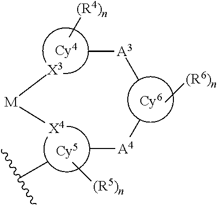

represents one of the following structures:

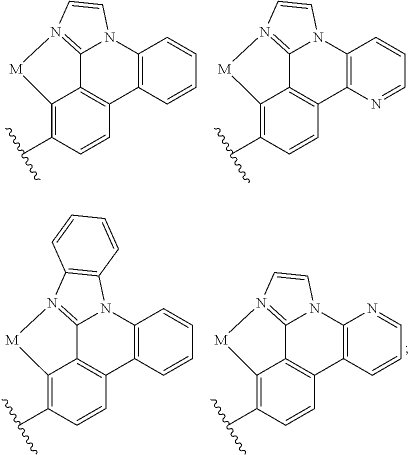

or
B² and Cy⁶ are both not present and the structure

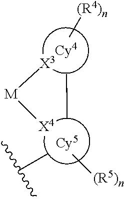

represents one of the following structures:

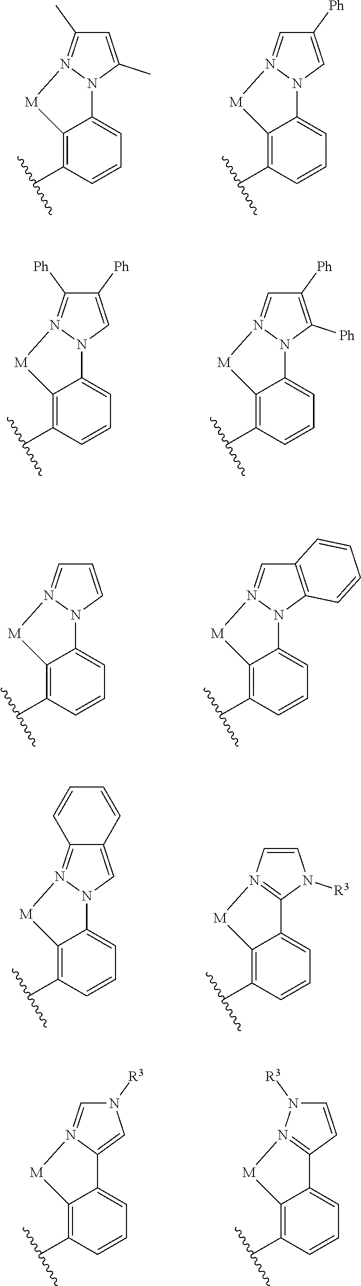

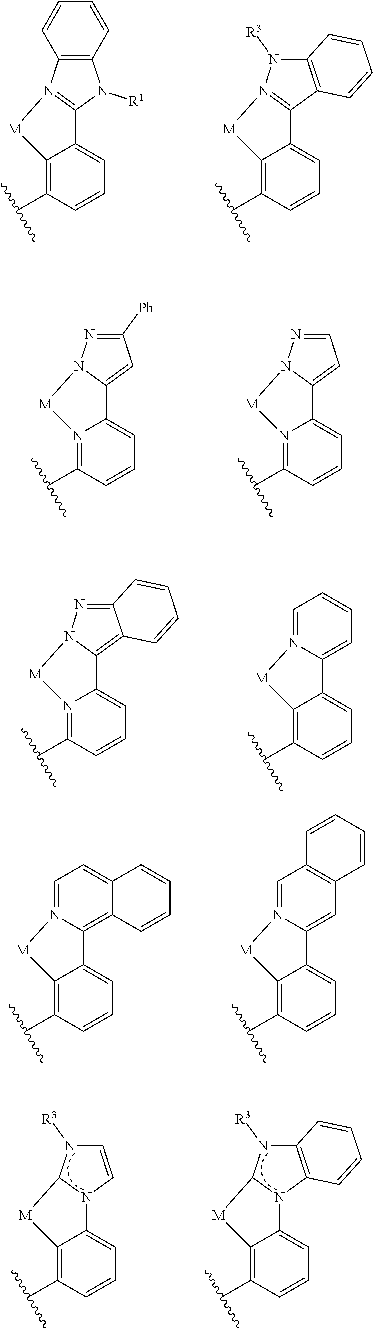

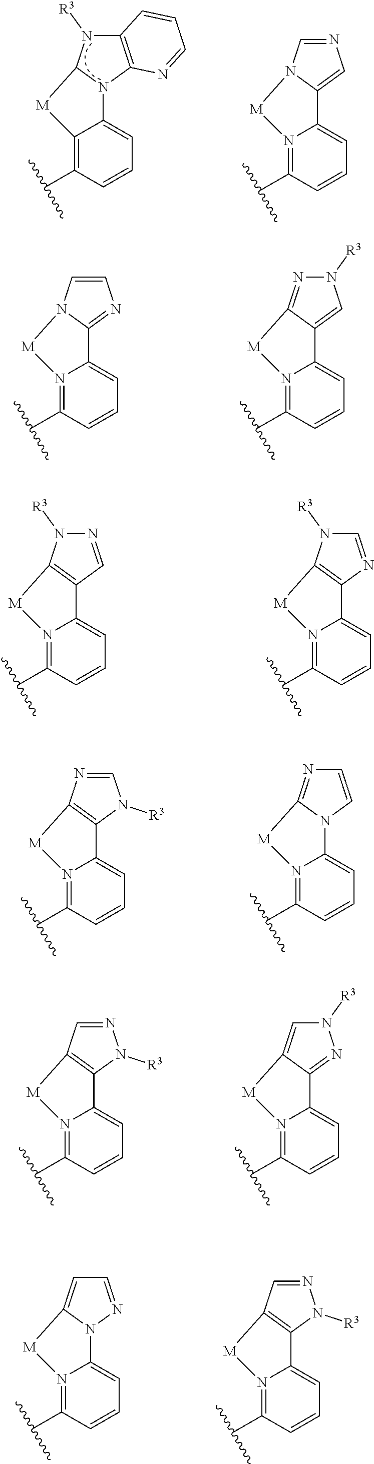

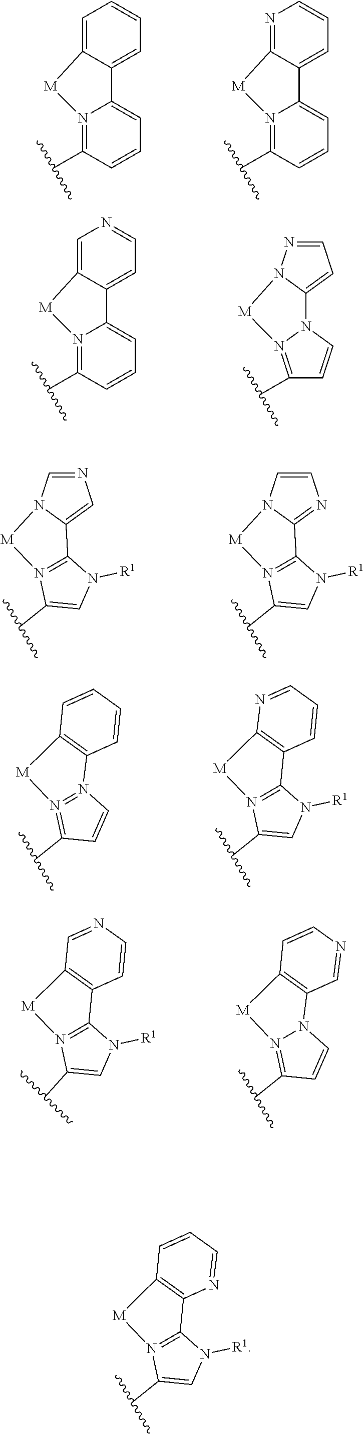

In one embodiment, the structure

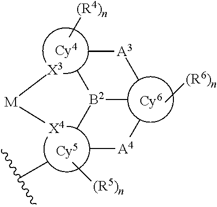

represents one of the following structures:

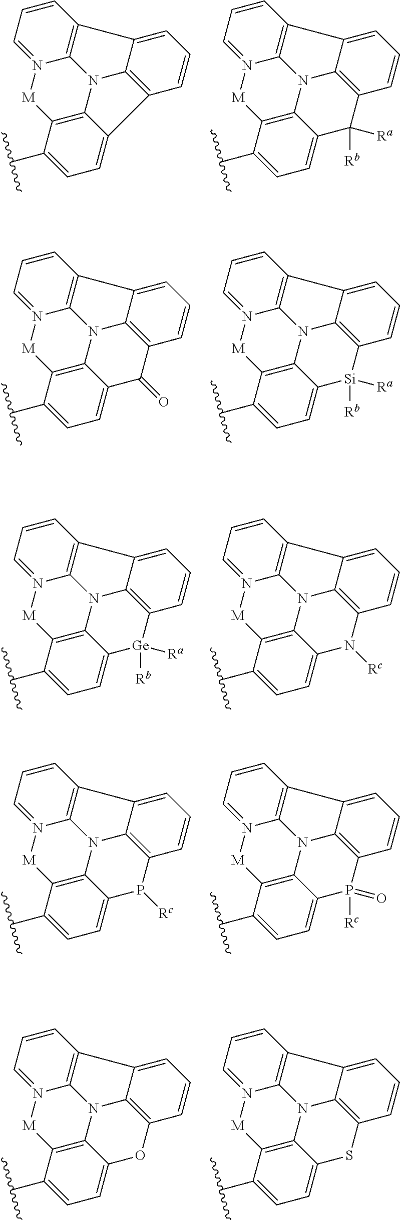

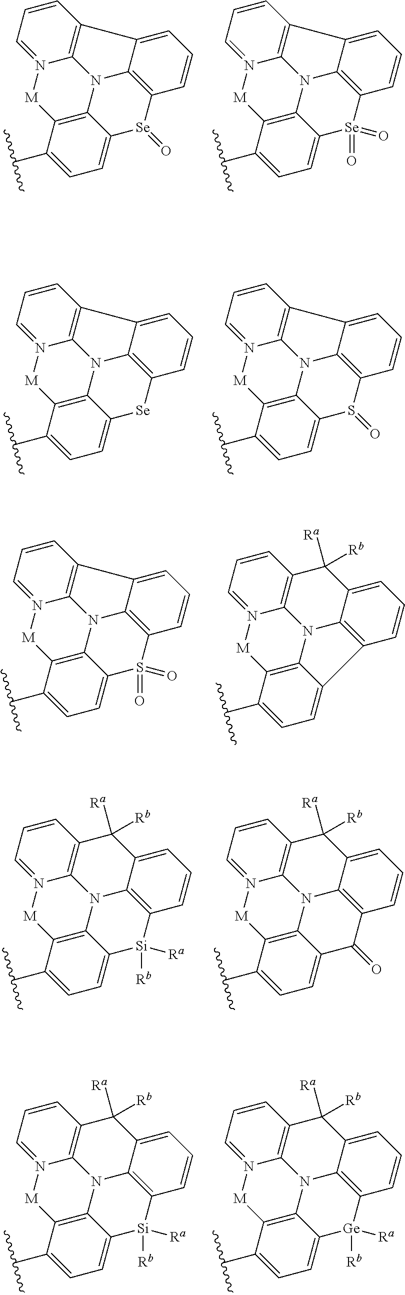

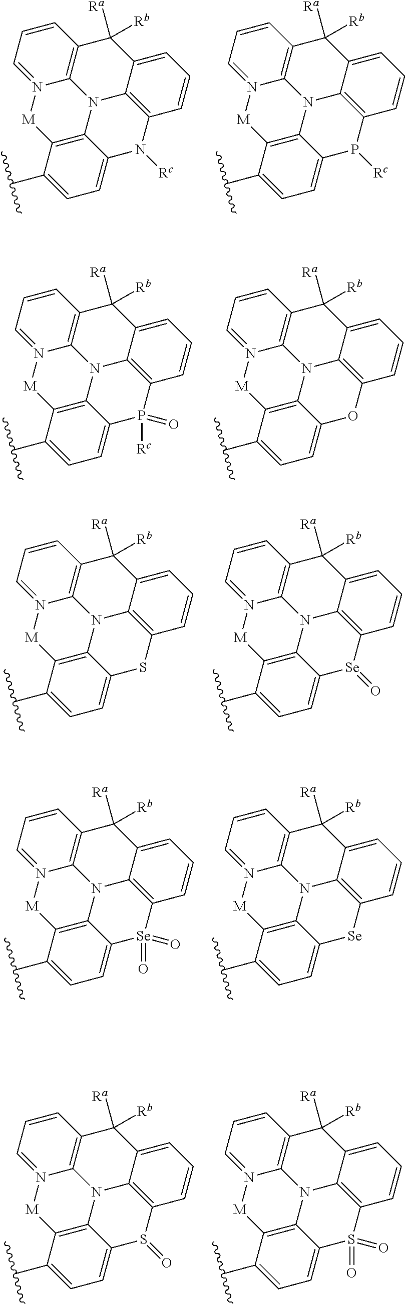

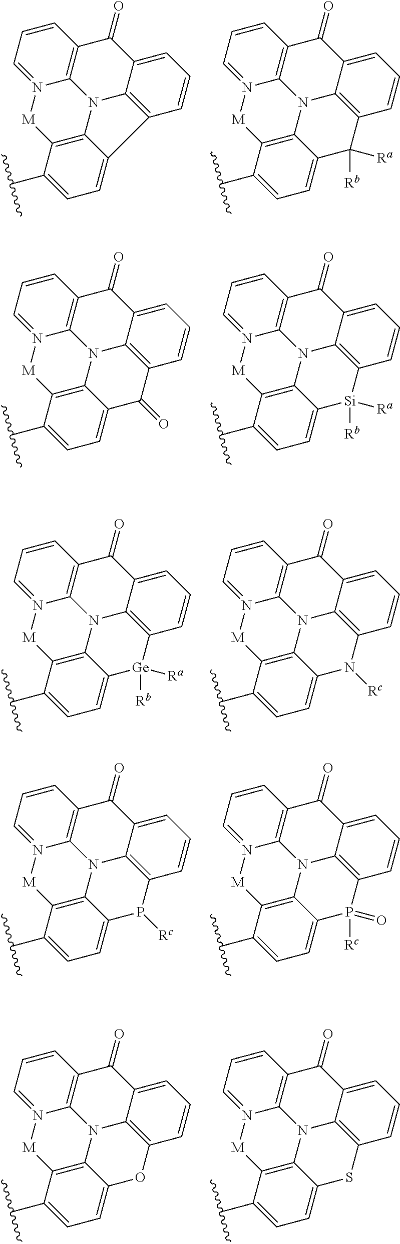

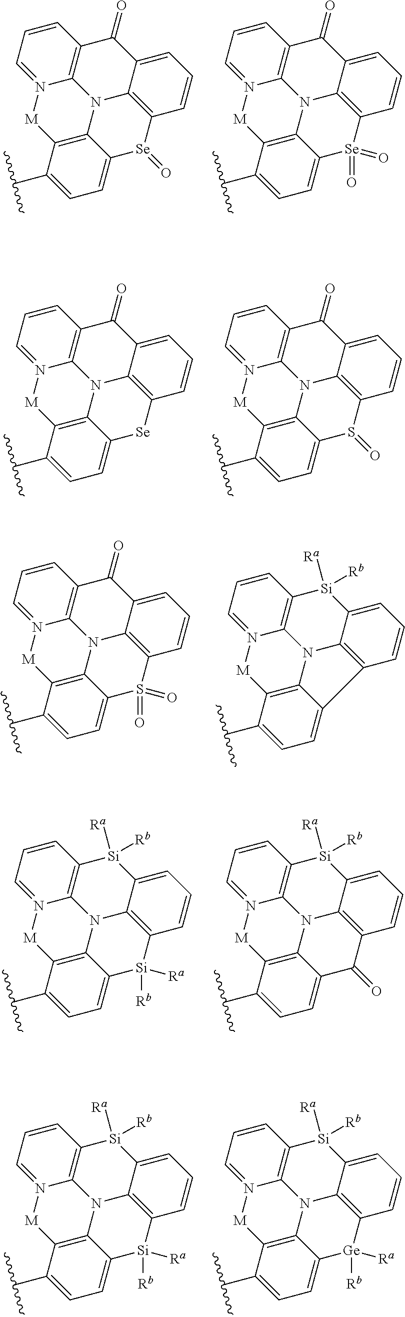

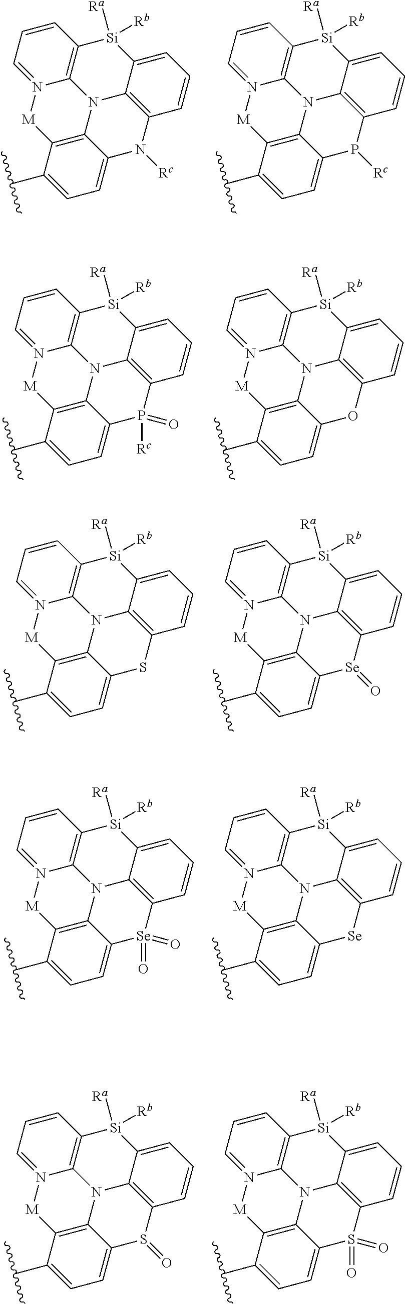

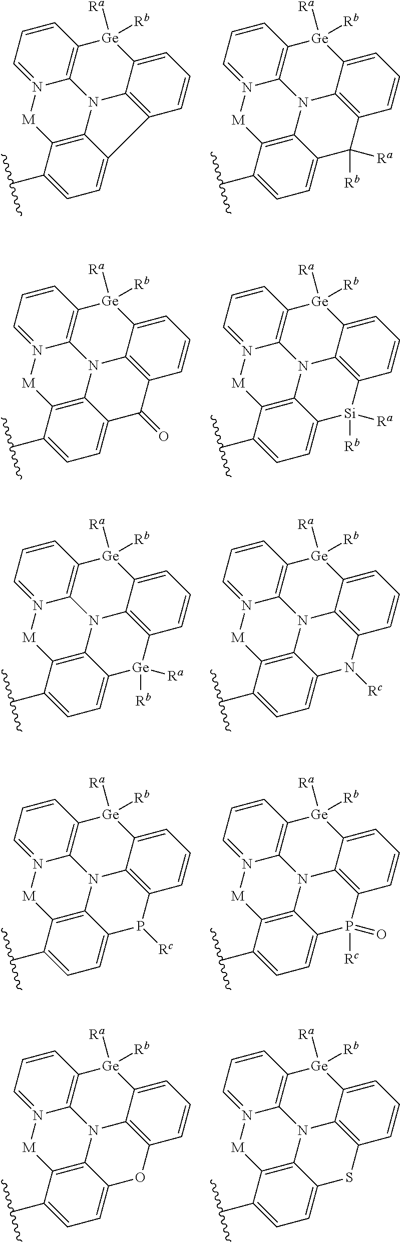

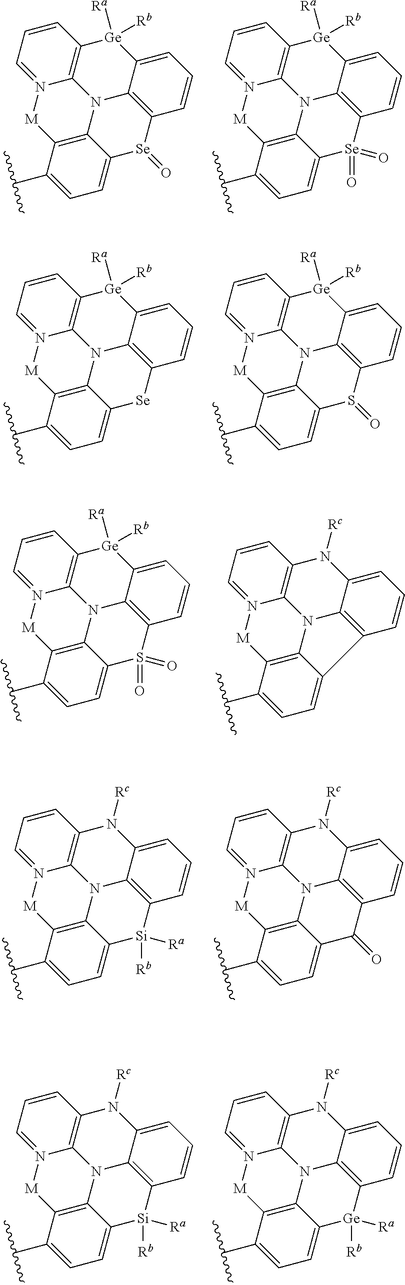

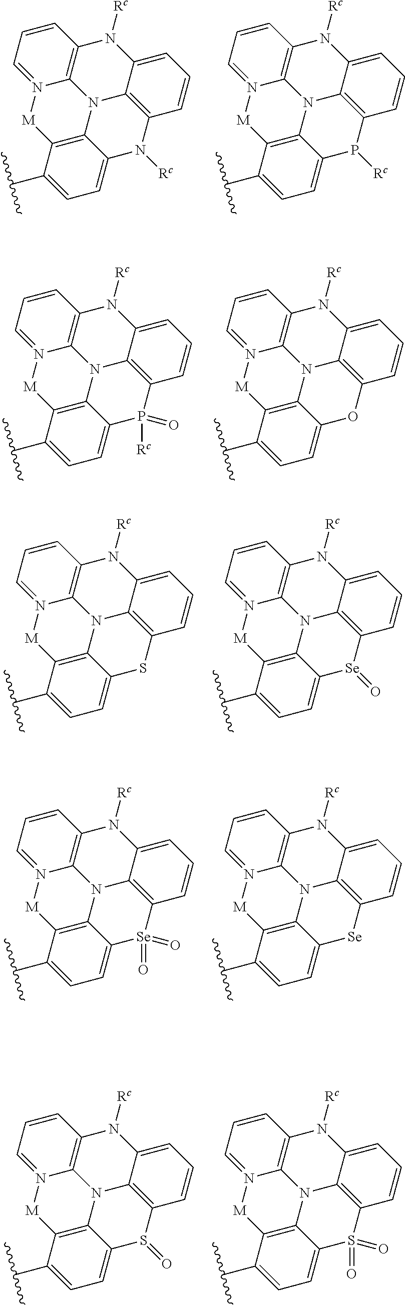

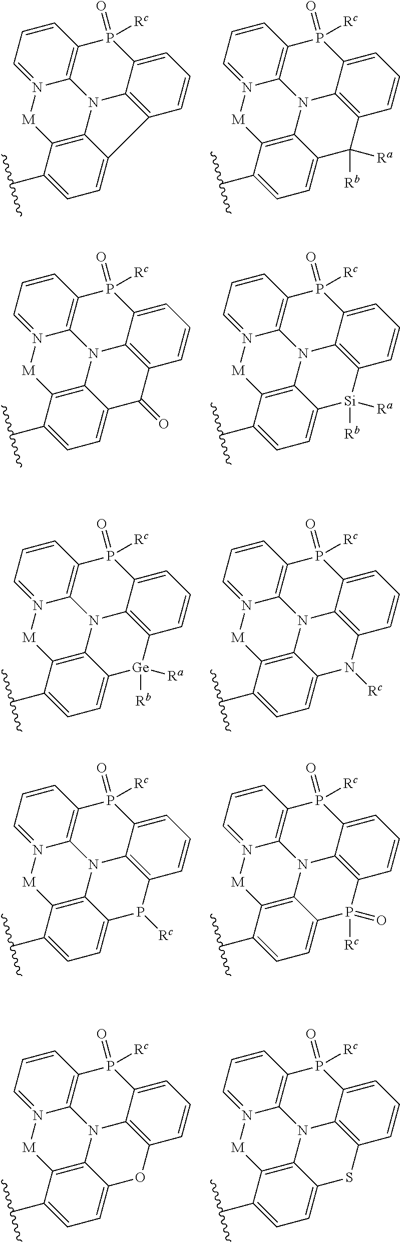

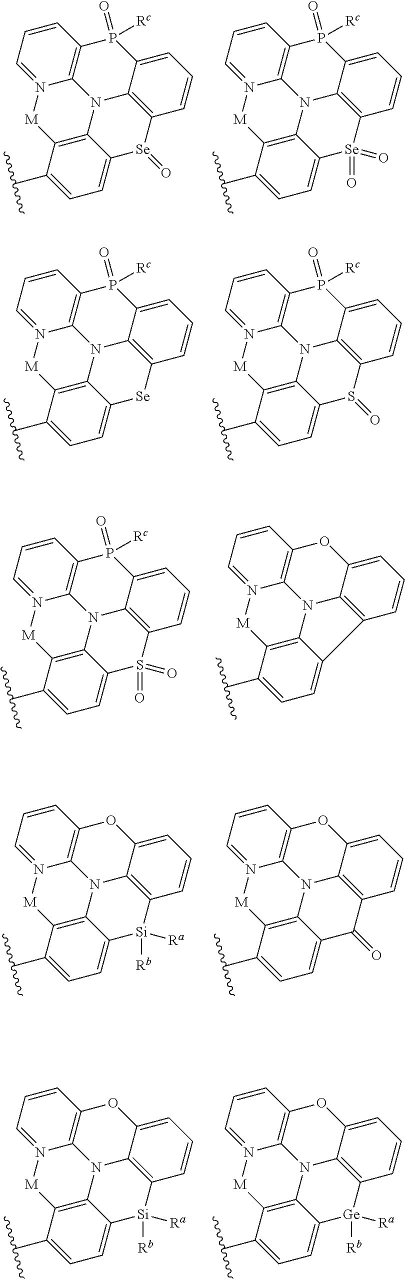

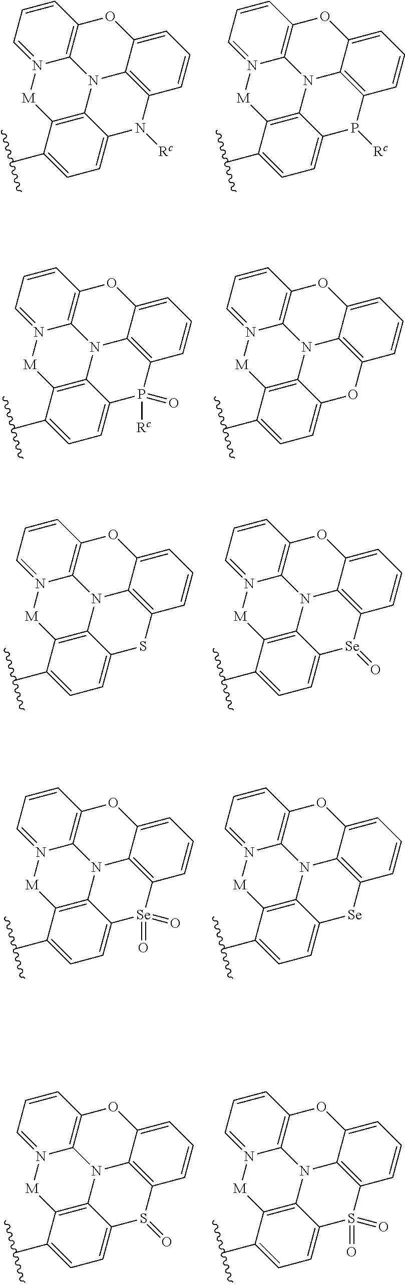

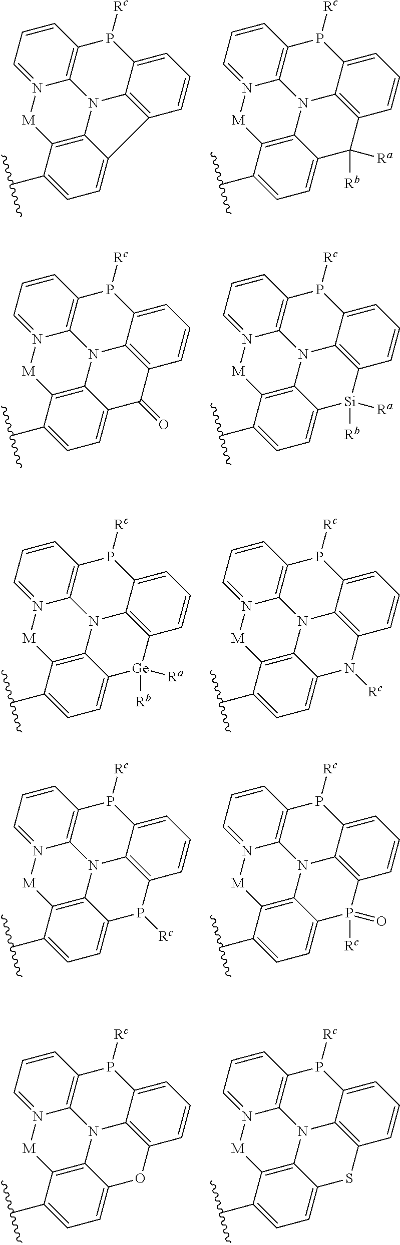

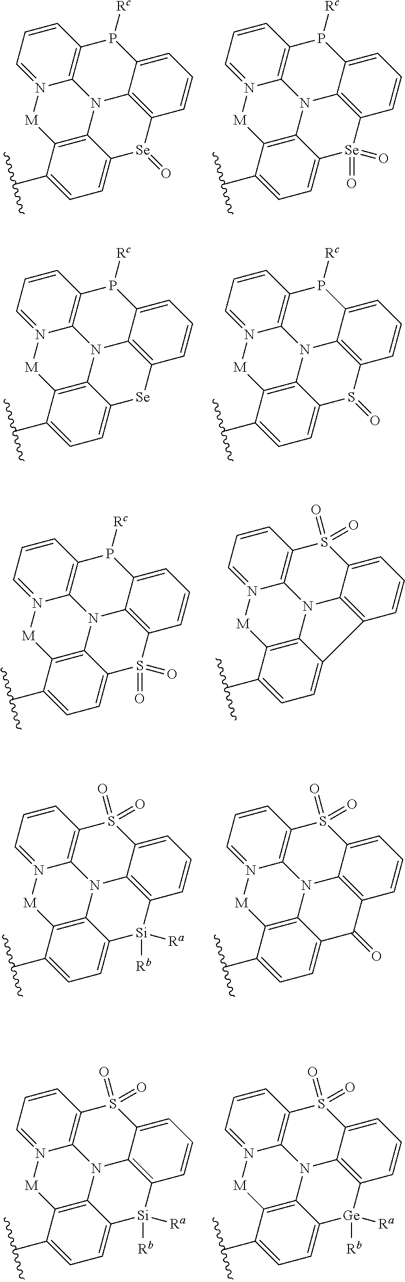

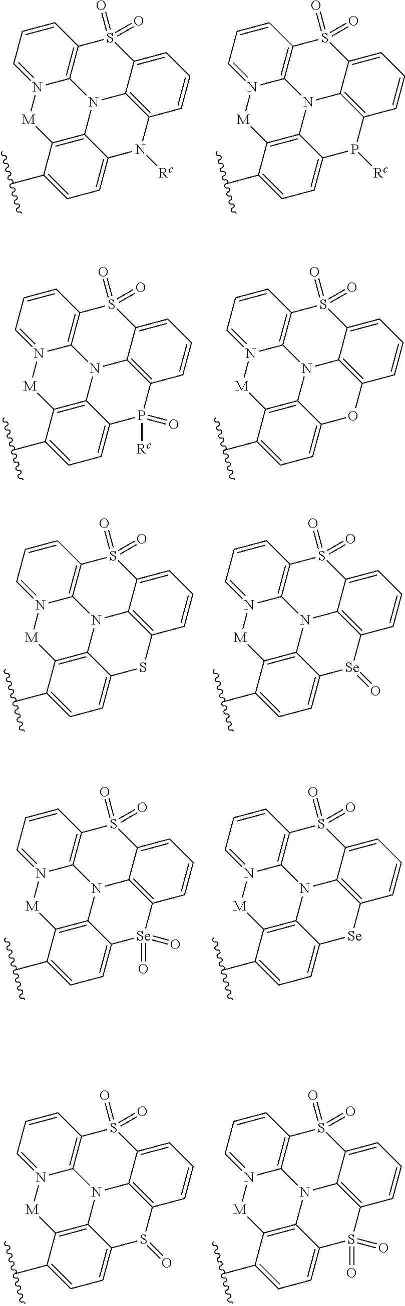

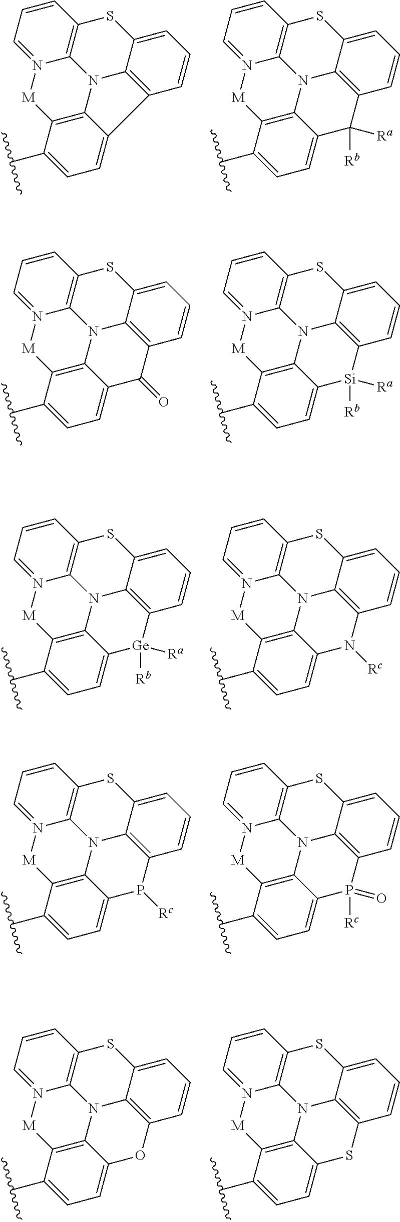

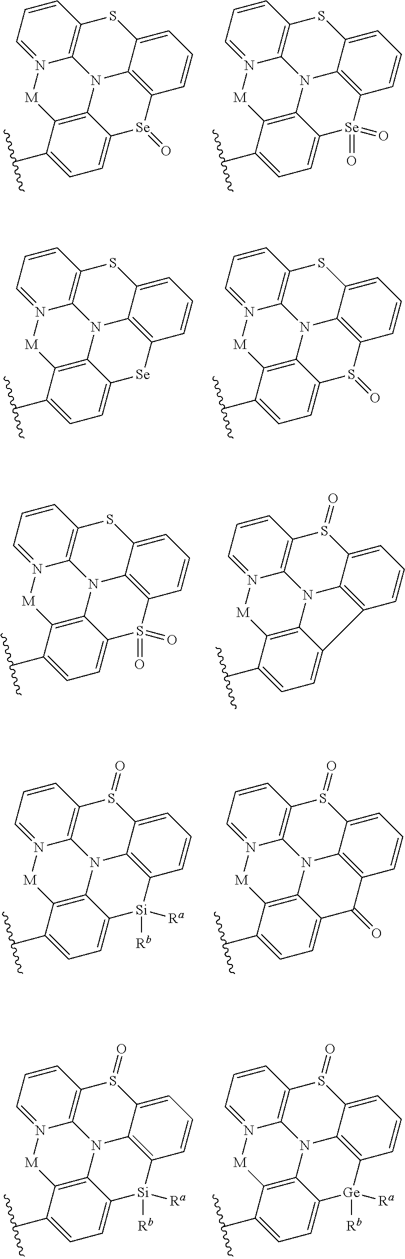

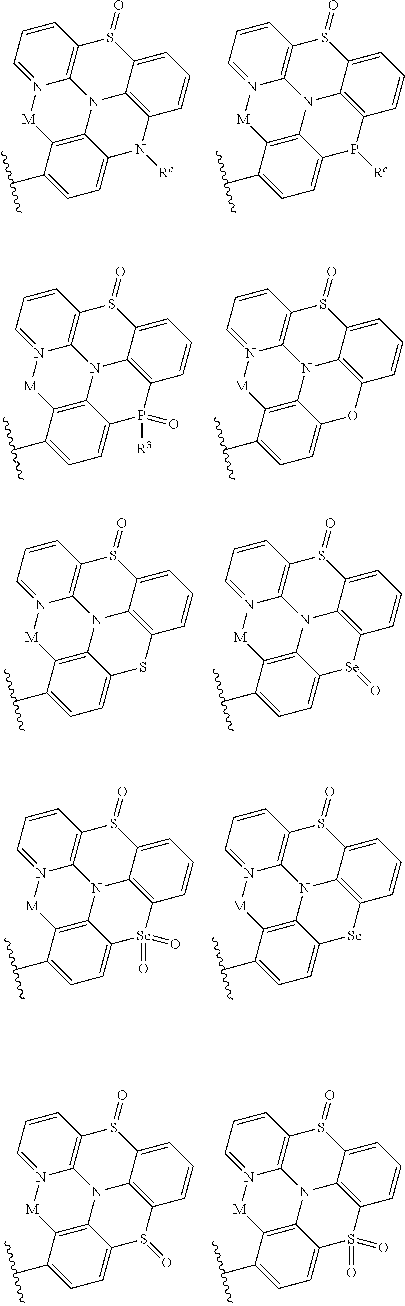

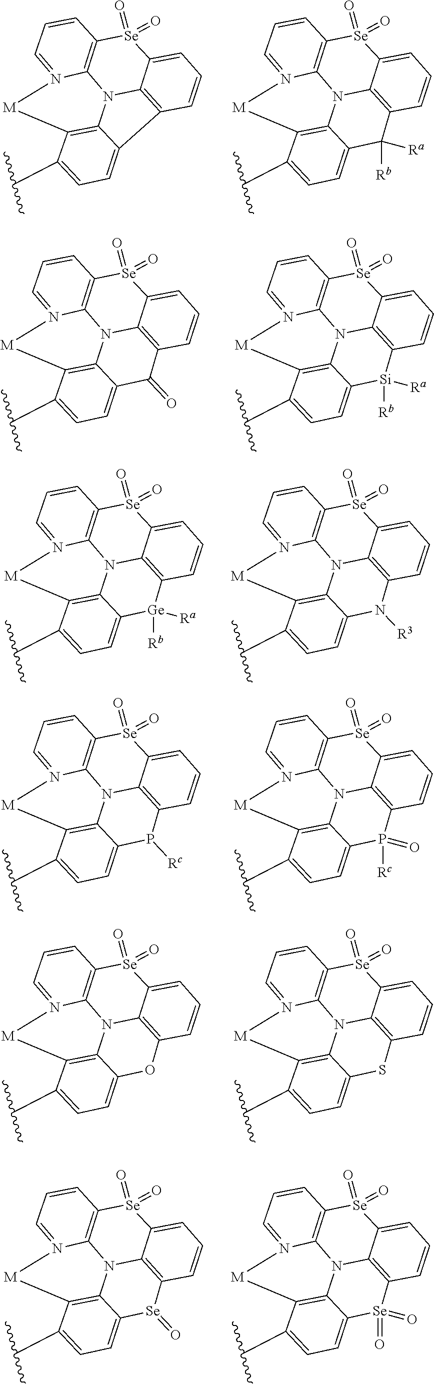

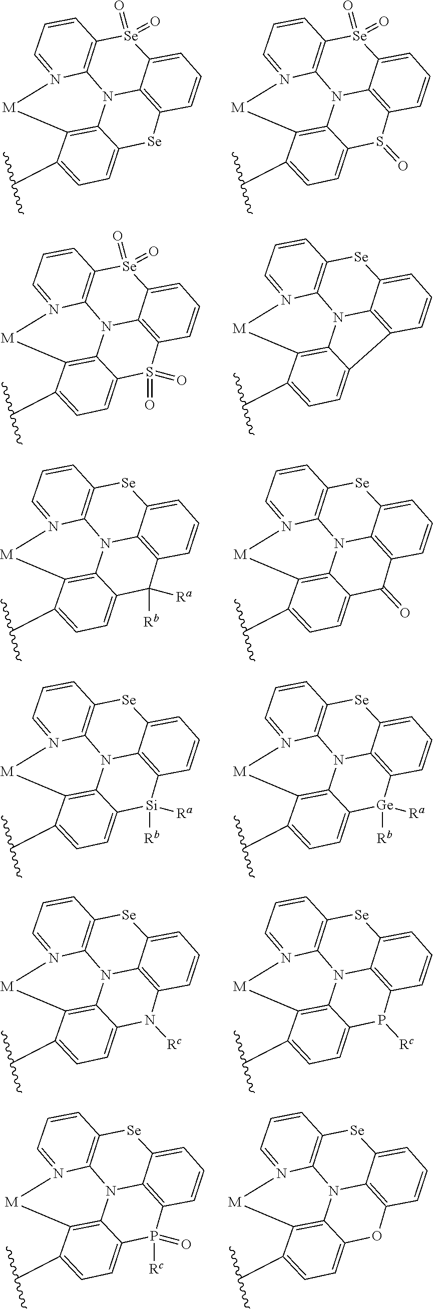

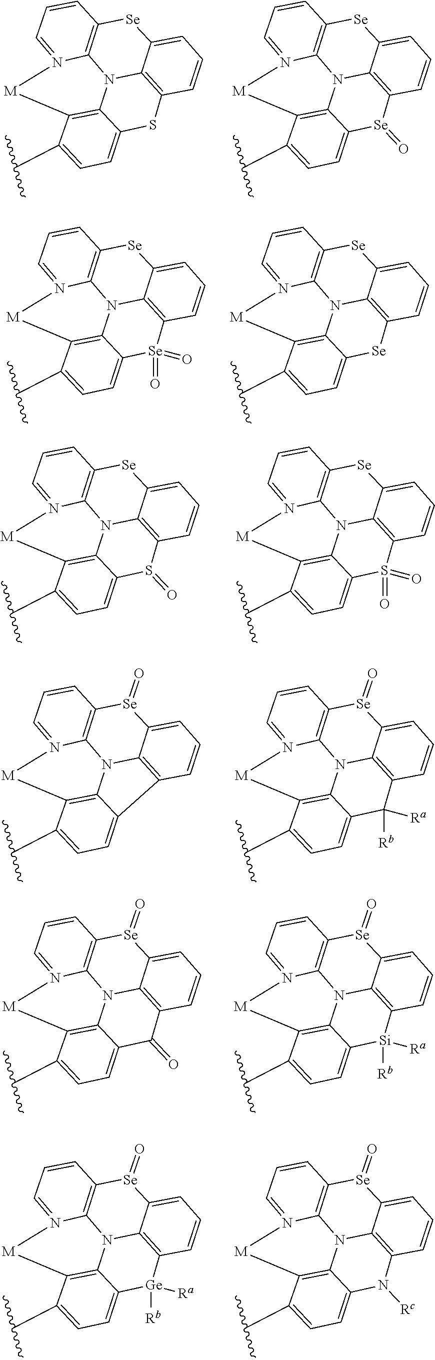

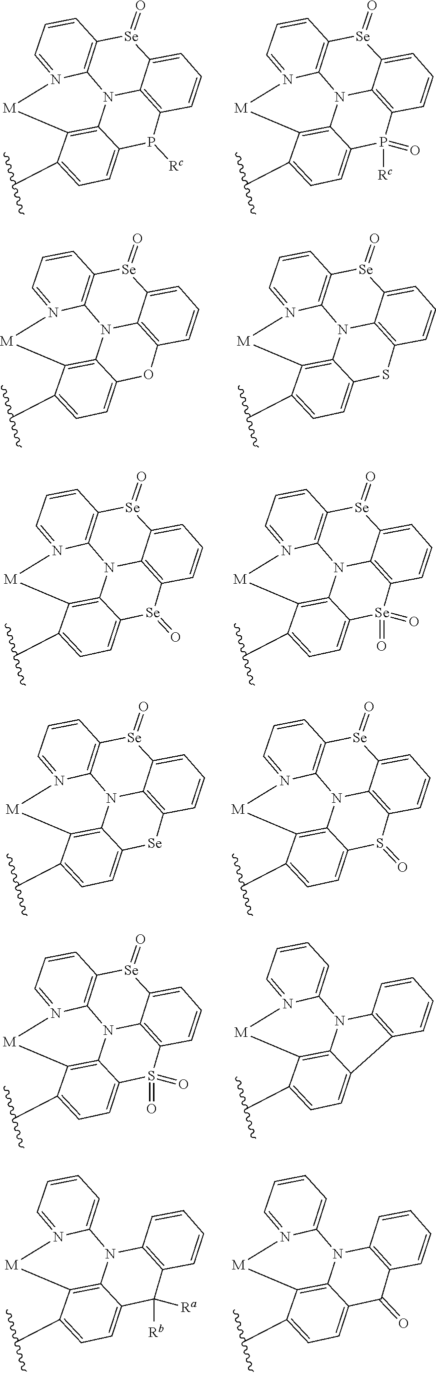

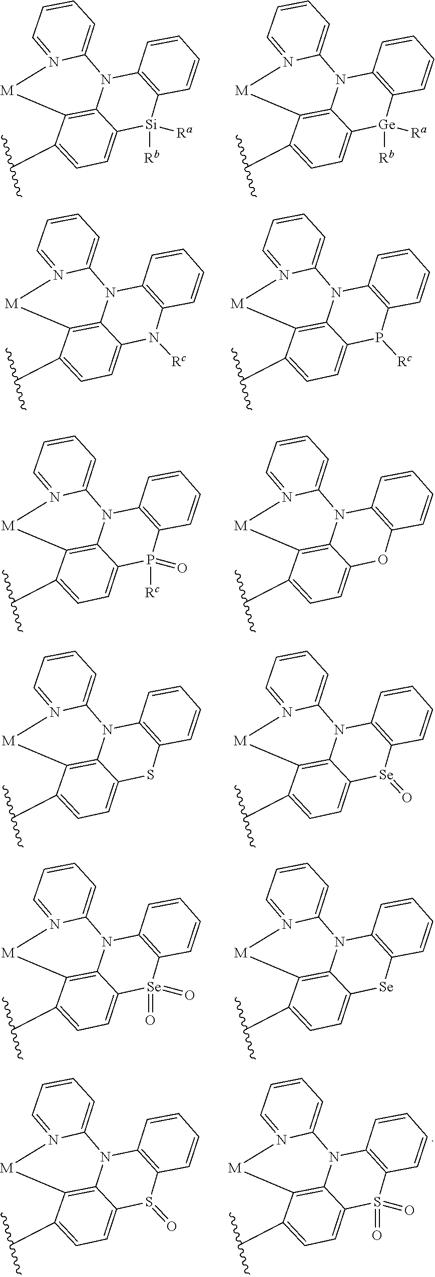

In one embodiment, the compound is represented by Formula II:

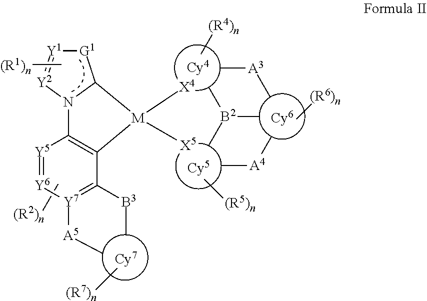

wherein:
G¹ is O, NR¹, CR¹, or S;
Y¹, Y², Y⁵, Y⁶, and Y⁷ is independently N, C, P, O, S, or Si; and
at least one R¹ is present and represents R^{X}.

In one embodiment, the compound is represented by one of the following structures, which together represent LIST 1:

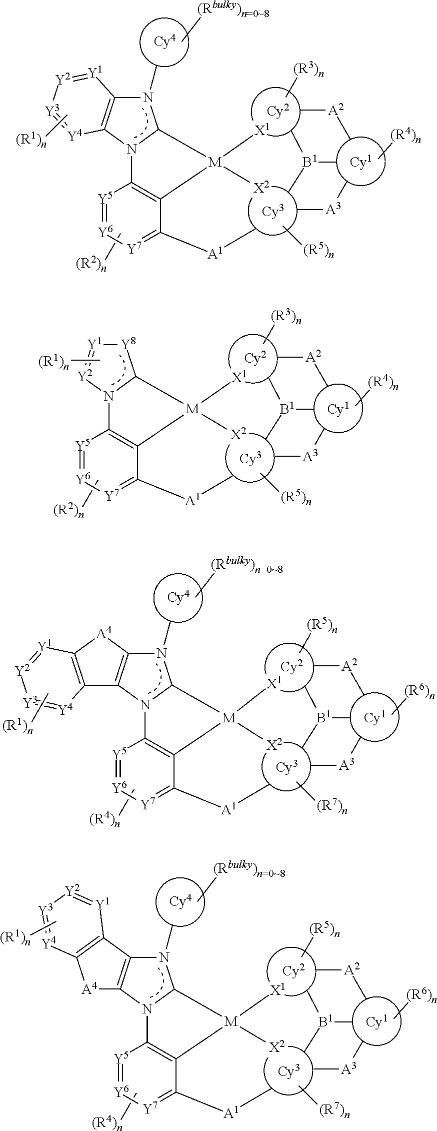

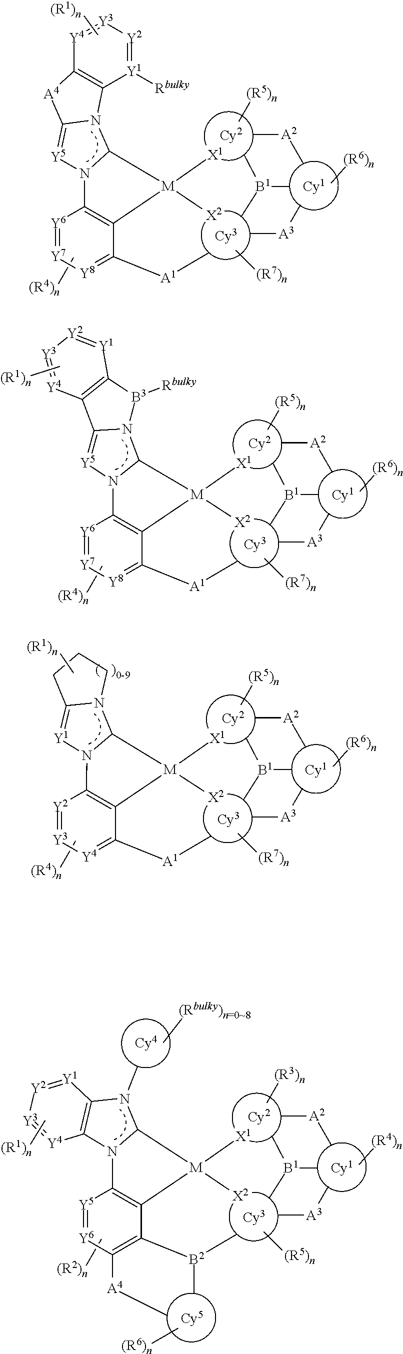

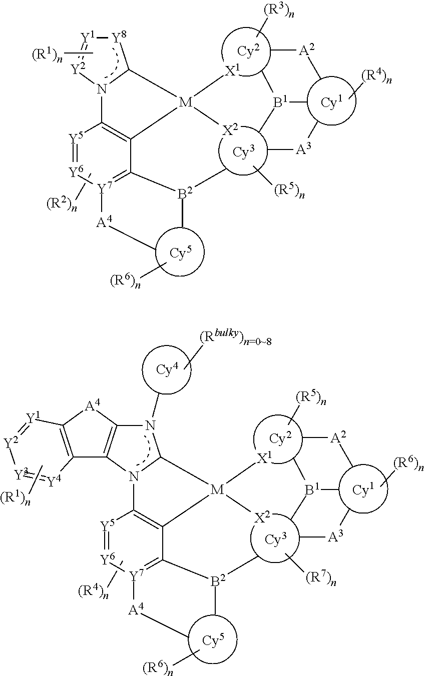

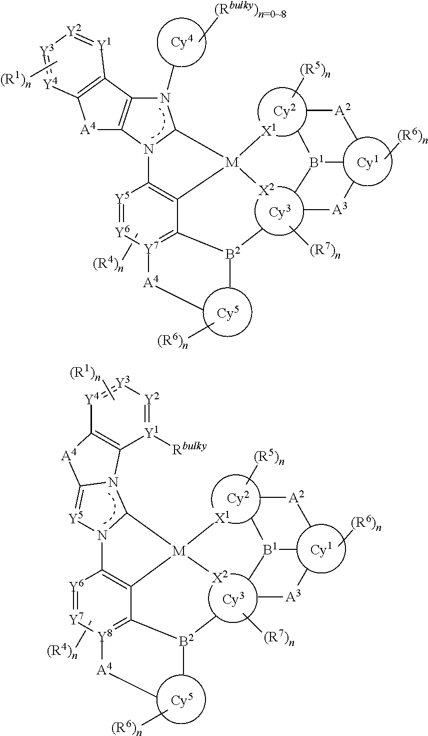

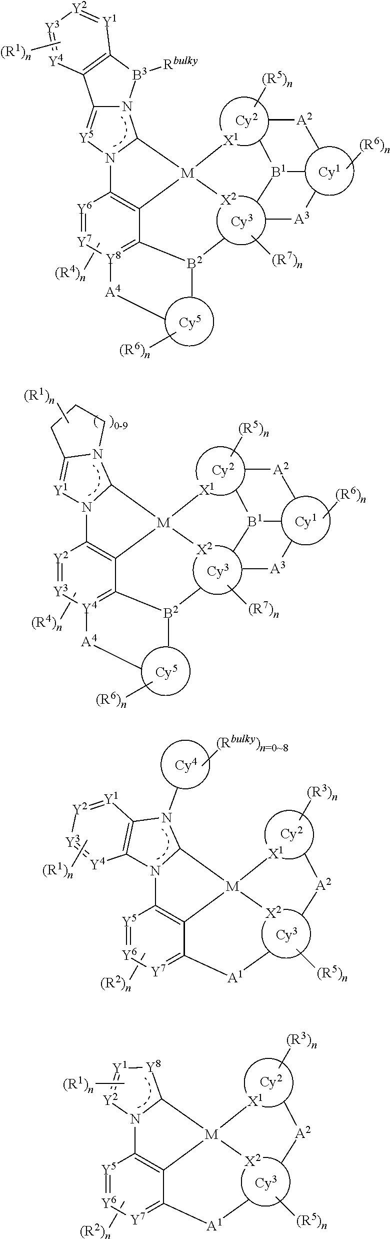

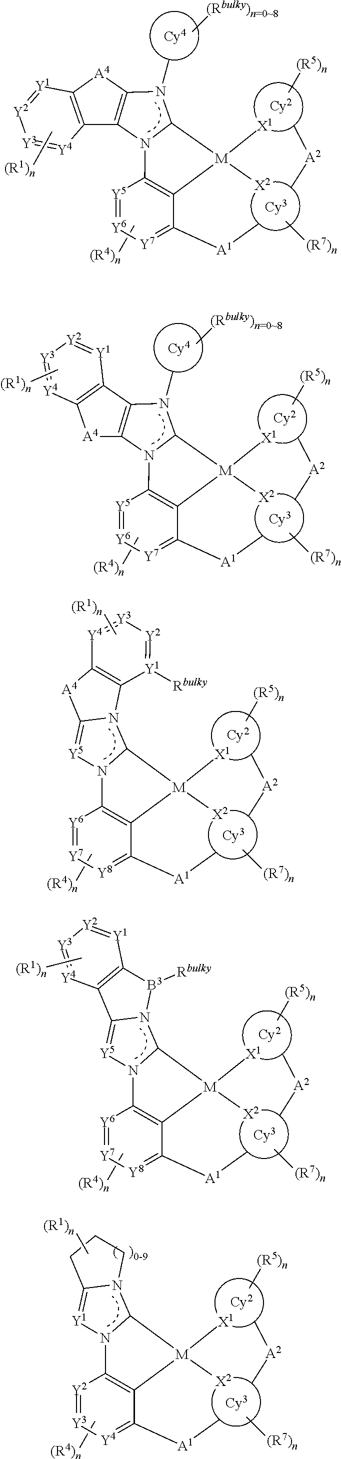

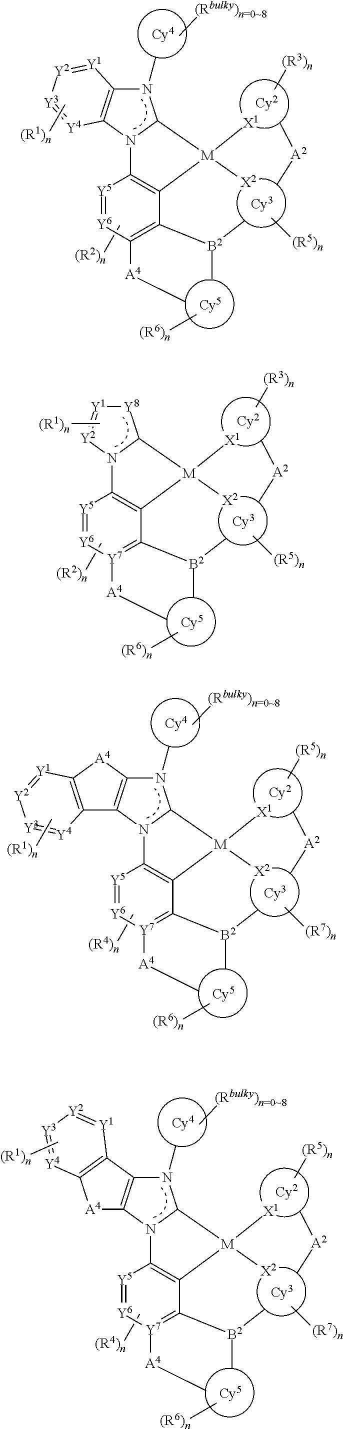

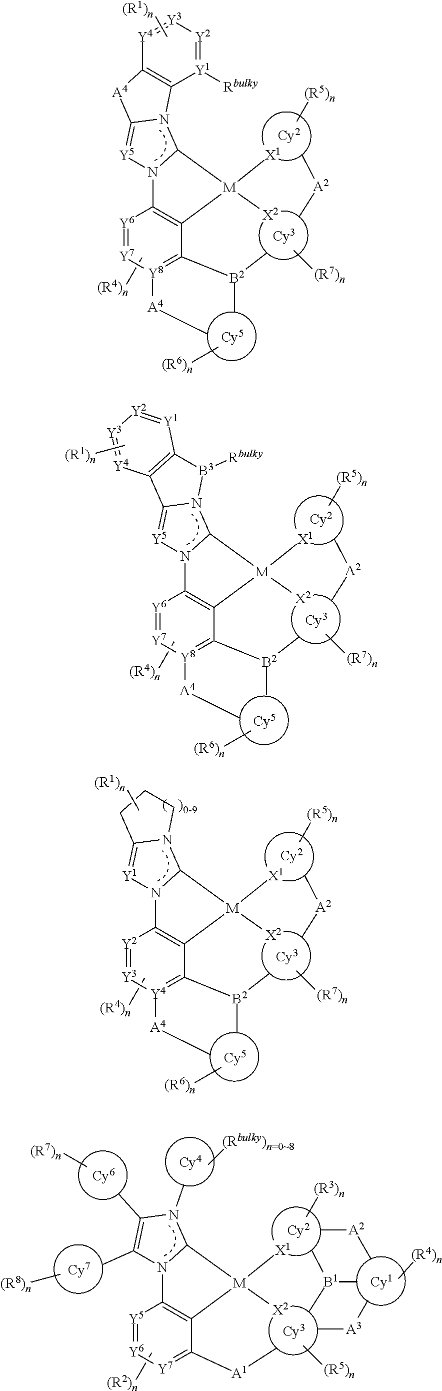

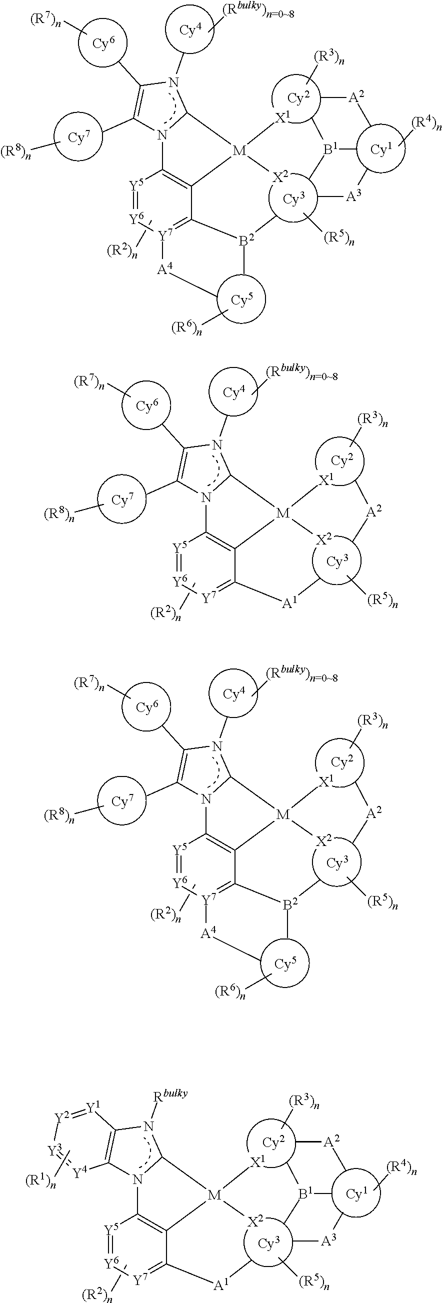

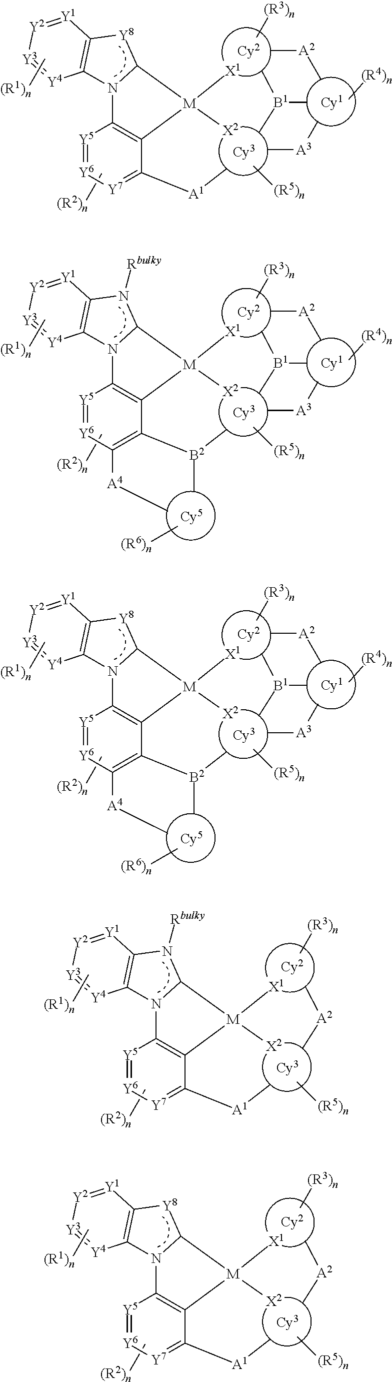

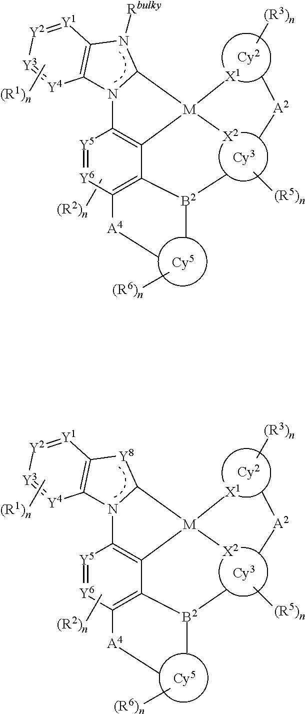

wherein:
M is platinum (Pt) or palladium (Pd);
each of X¹ and X² is coordinated with M and is independently N or C;
each of Y¹, Y², Y³, Y⁴, Y⁵, Y⁶, Y⁷, and Y⁸ is independently N, C, P, O, S, or Si;
each of Cy¹, Cy², Cy³, Cy⁴, Cy⁵, Cy⁶, and Cy⁷ is independently substituted or unsubstituted aryl, cycloalkyl, cycloalkenyl, heteroaryl, heterocyclyl, carbene, or N-heterocyclic carbene;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═0, O, S, S═O, SO₂, Se, Se═O, SeO₂, BR³, BiR³, R³Bi═O,

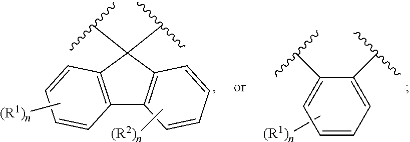

each of B¹, B², and B³ is independently CR¹, SiR¹, GeR¹, N, P, P═O, As, As═O, B, R³Bi═O, or Bi;
R^{bulky} represents R^{X};
each of R¹, R², R³, R⁴, R⁵, R⁶, R⁷, and R⁸ is independently absent or present as a single substituent or multiple substituents, valency permitting, and each R¹, R², R³, R⁴, R⁵, R⁶, R⁷, and R⁸ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by one of the following structures, which together represent LIST 2:

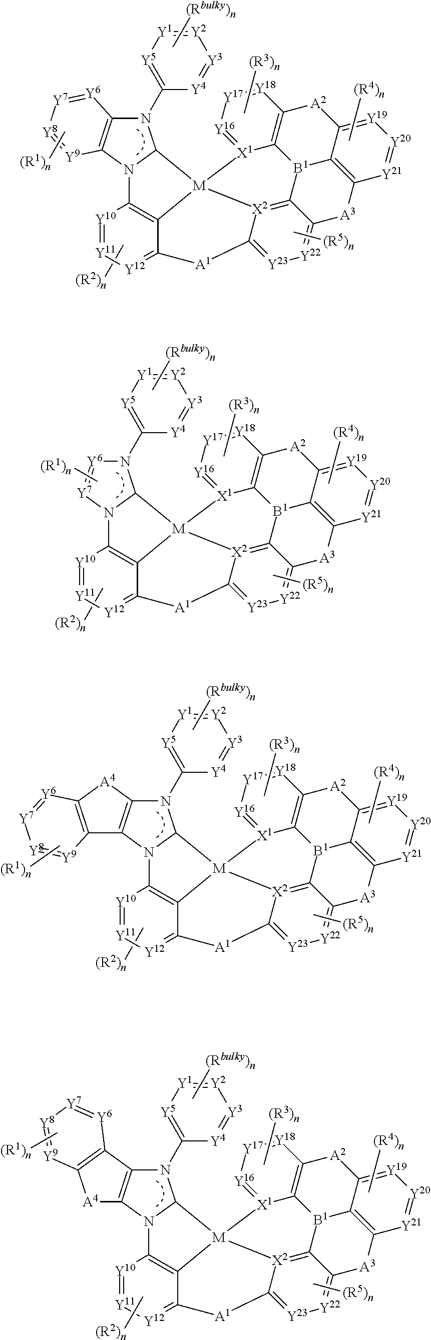

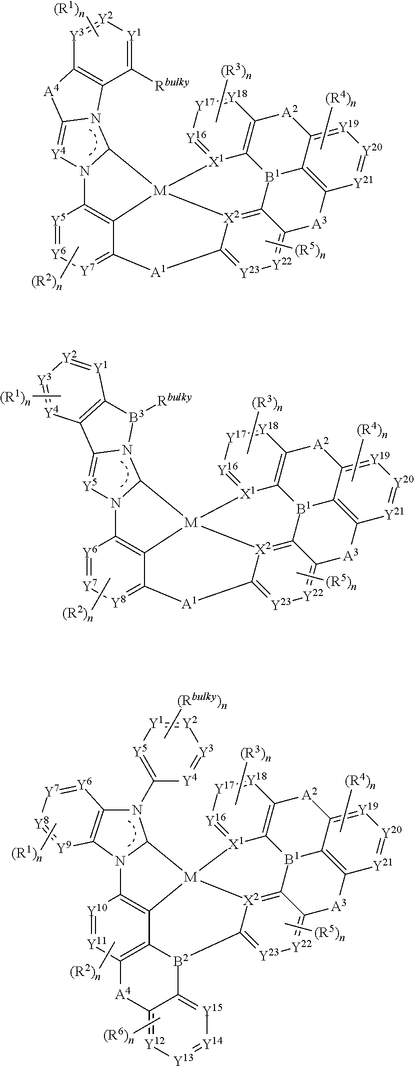

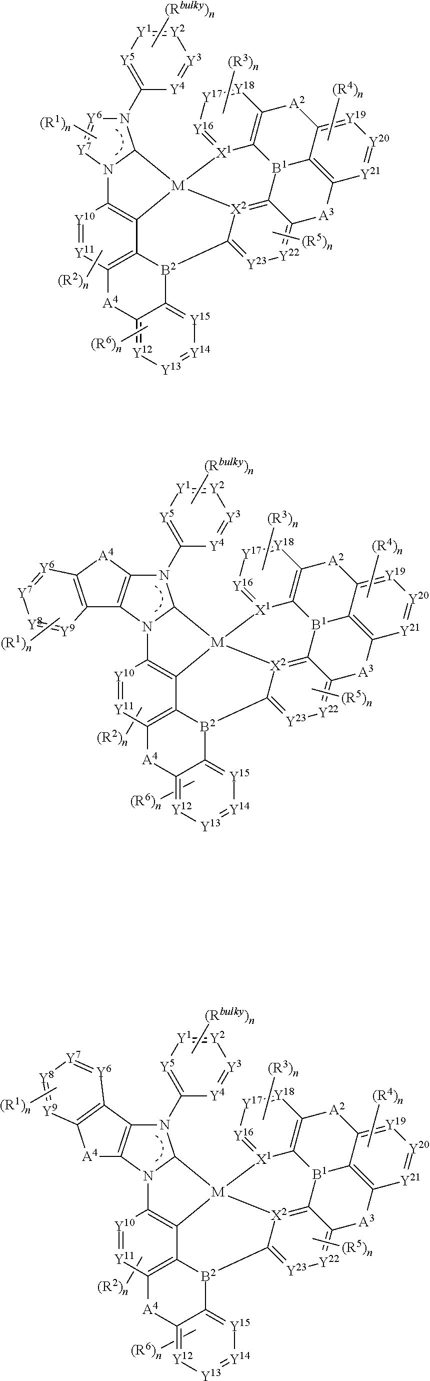

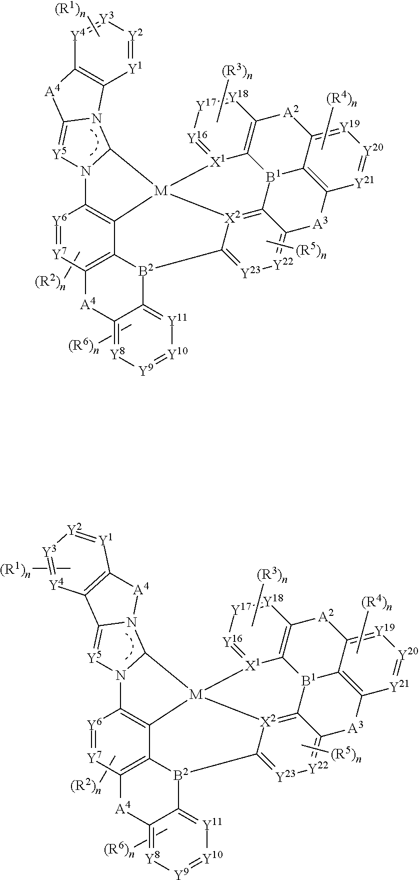

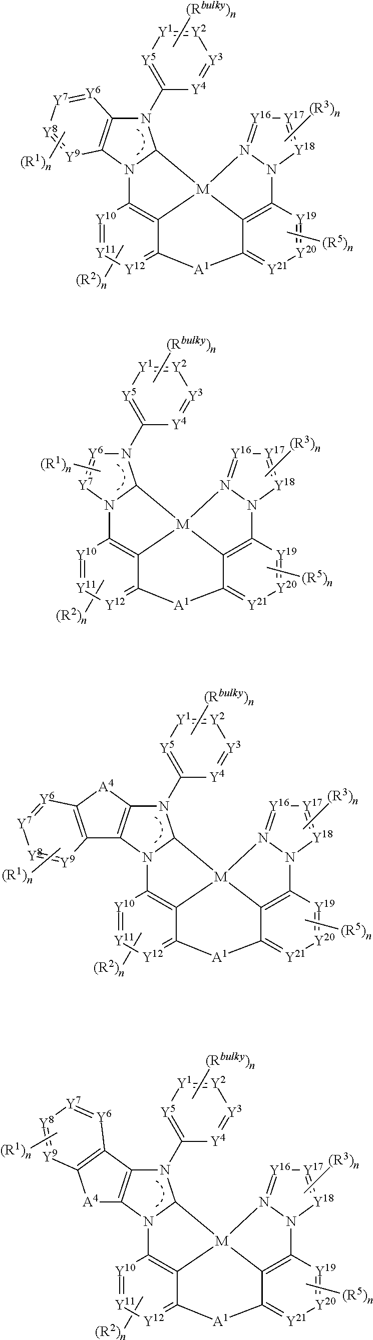

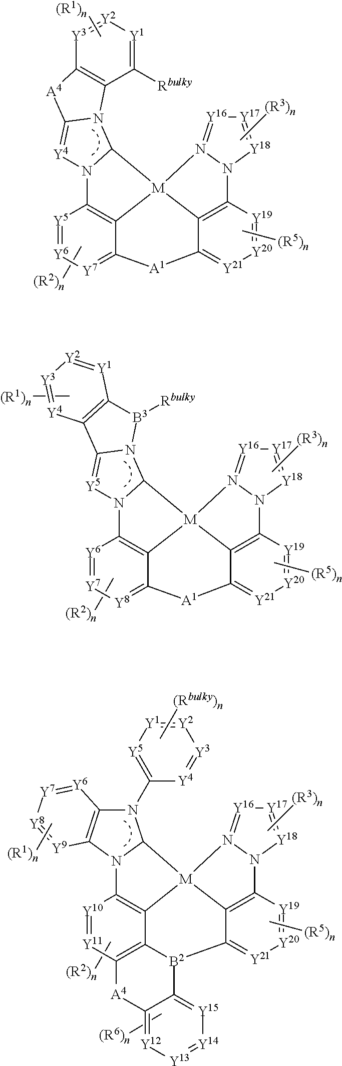

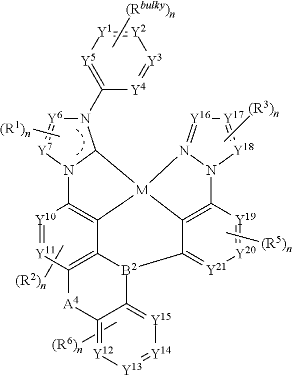

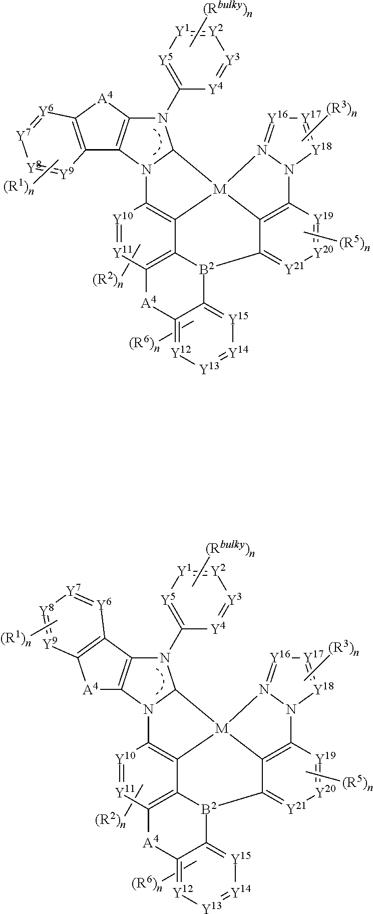

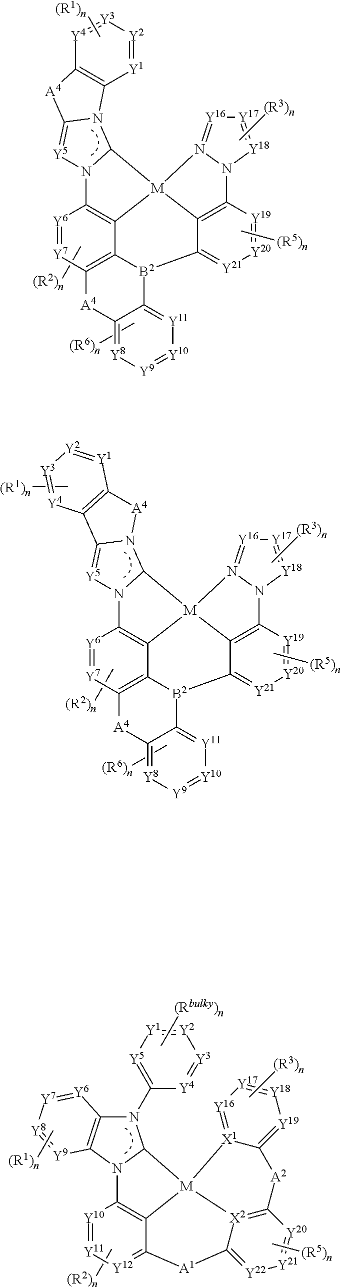

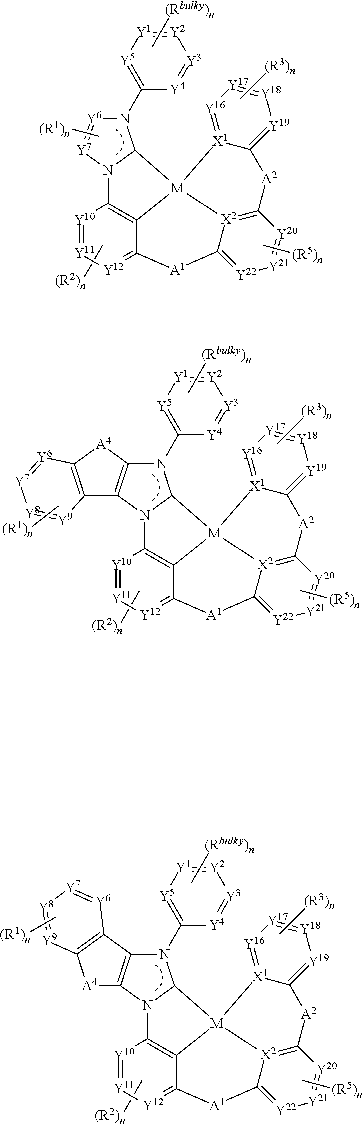

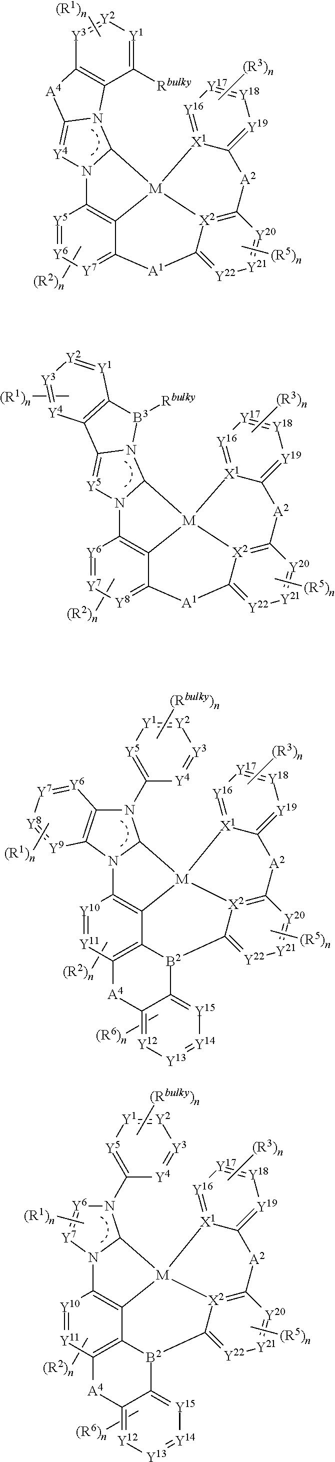

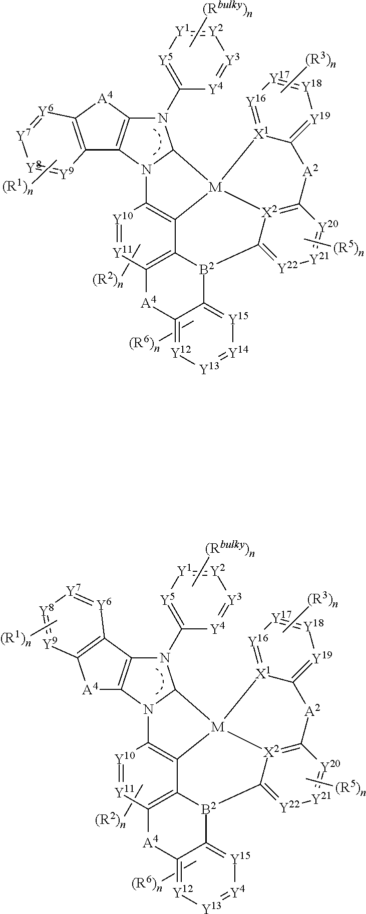

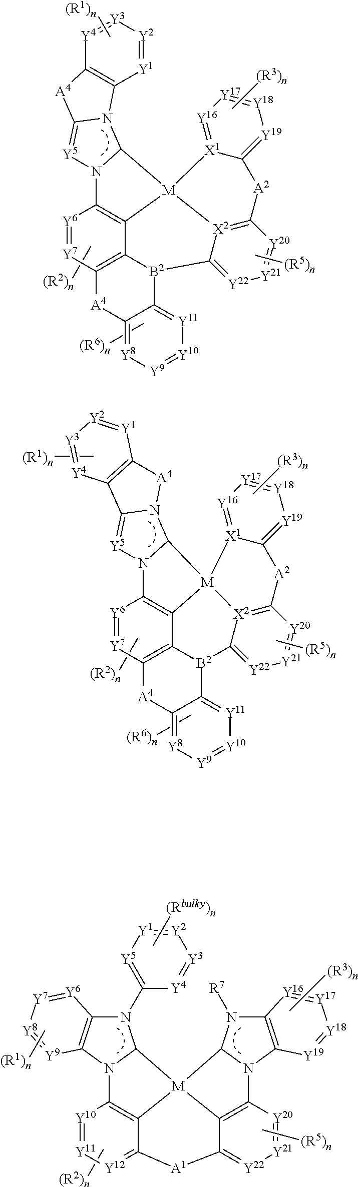

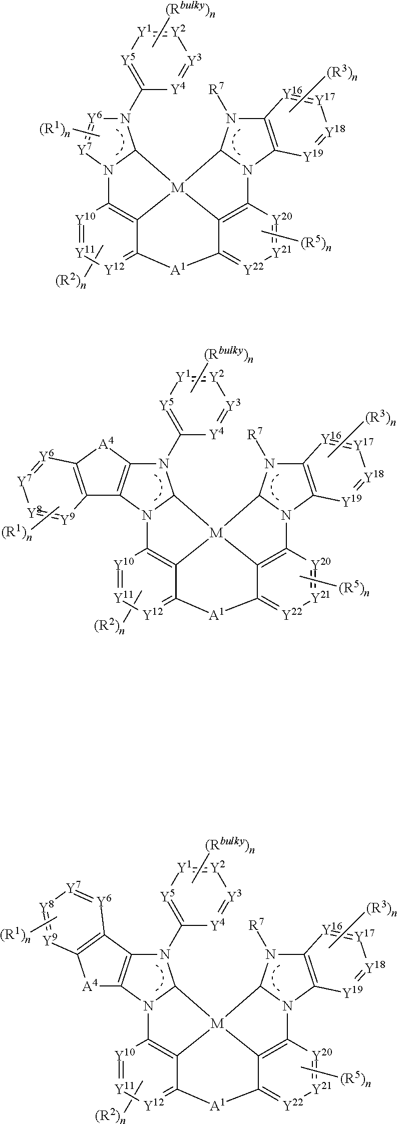

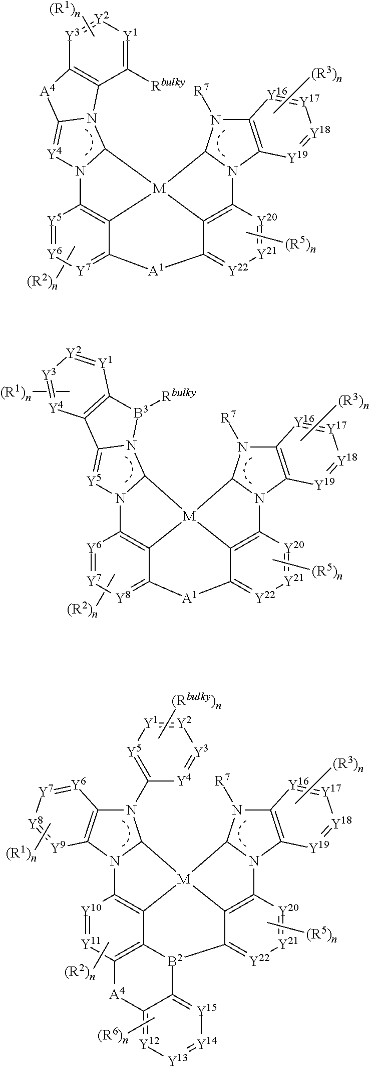

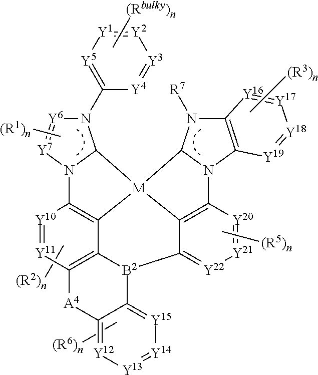

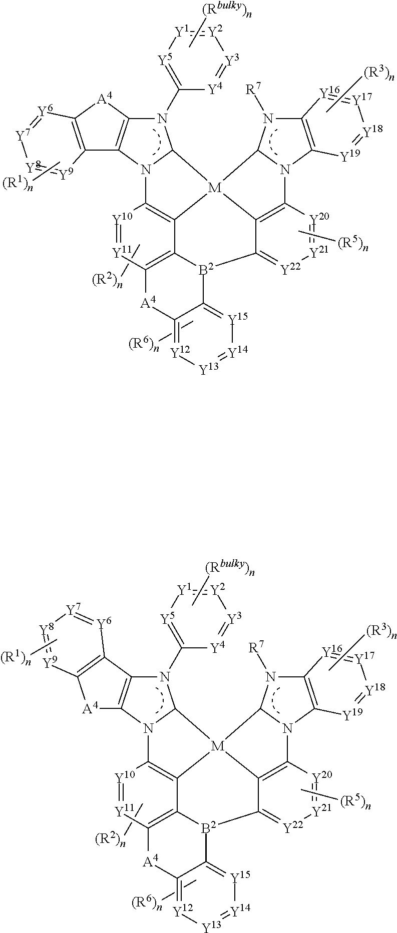

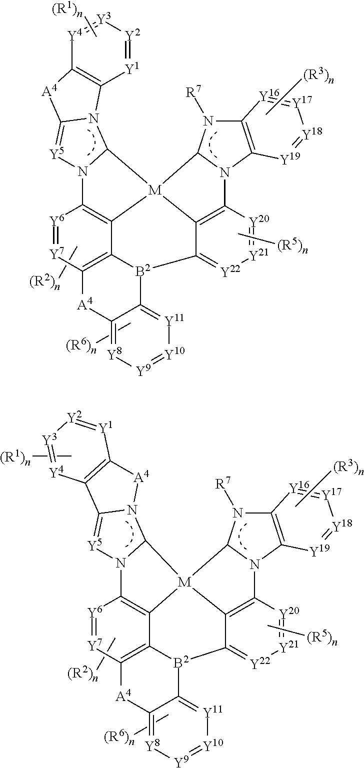

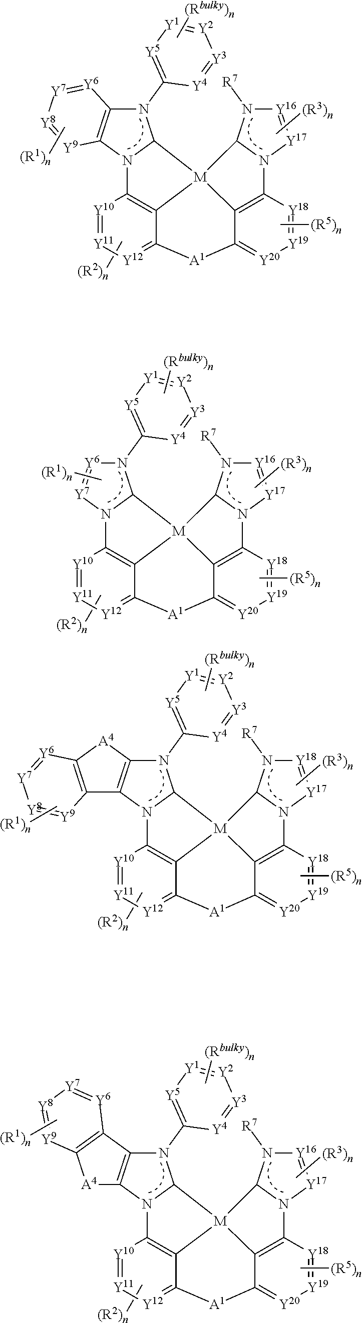

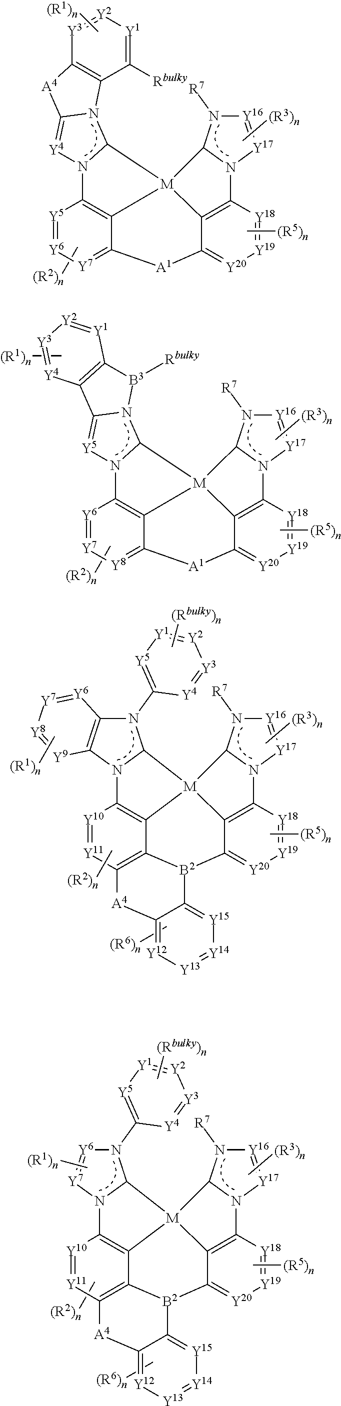

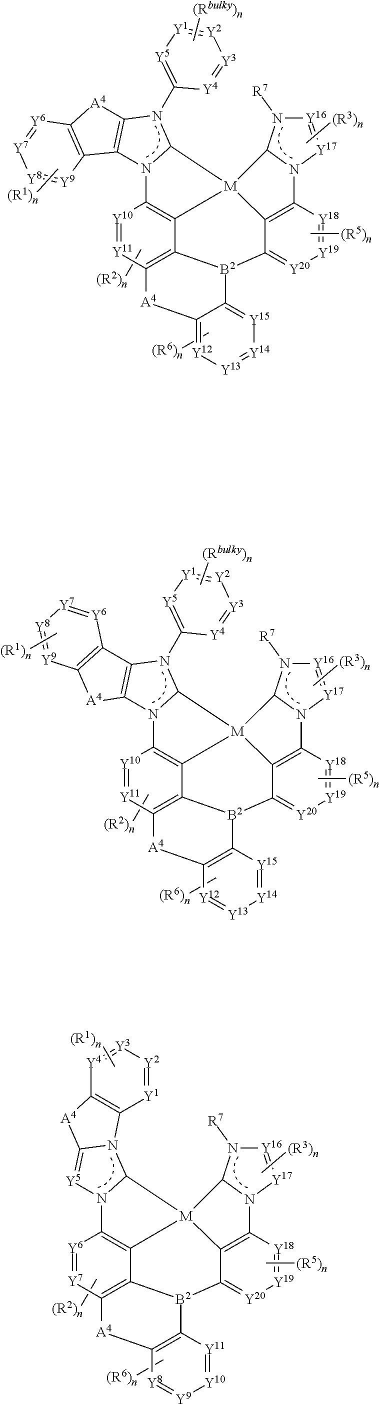

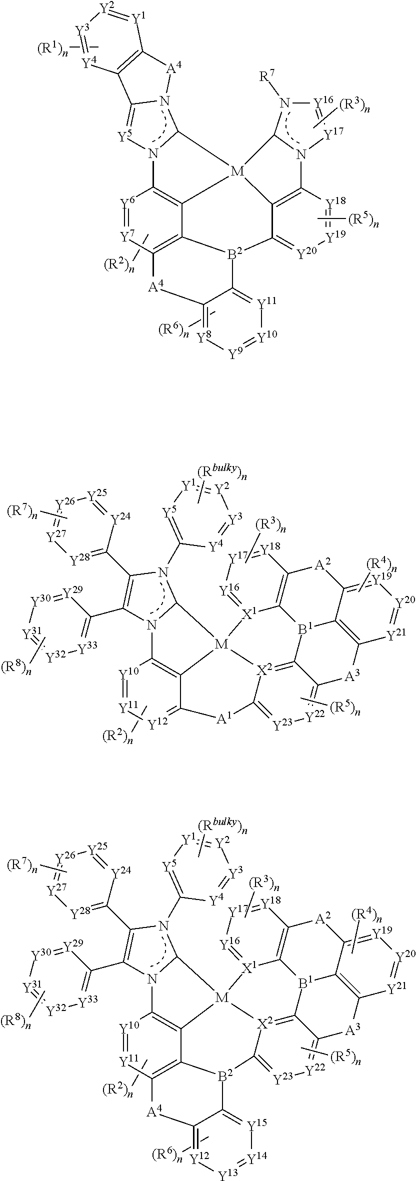

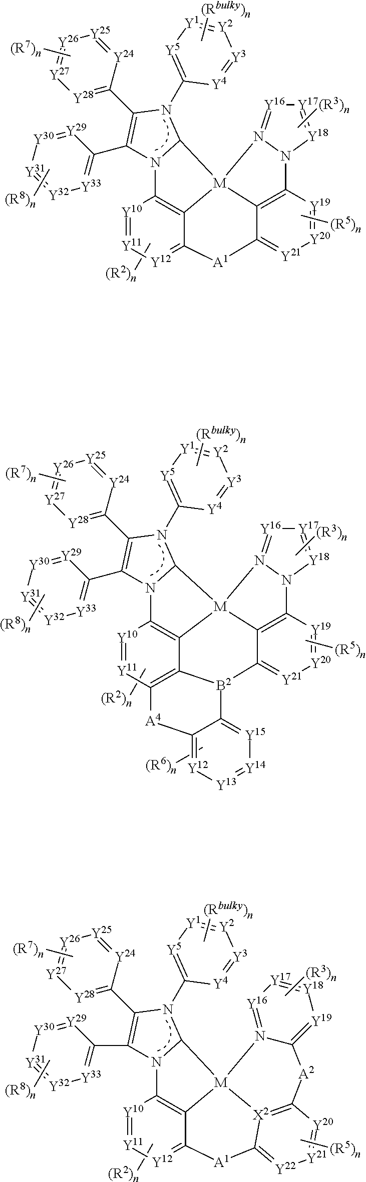

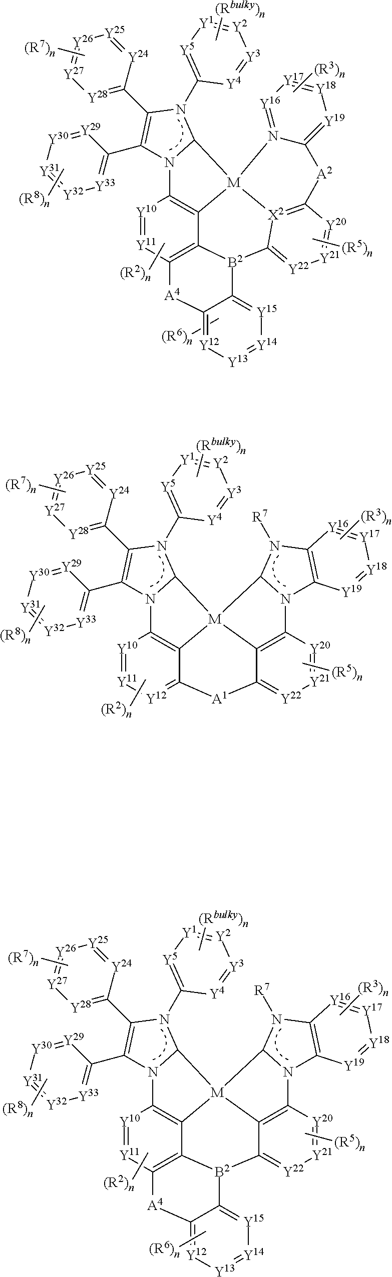

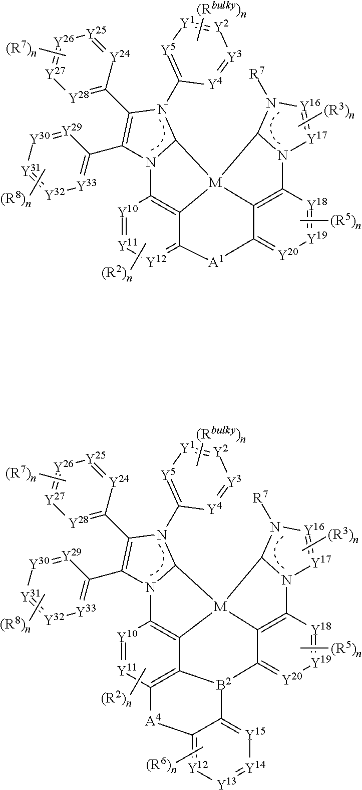

wherein:
M is platinum (Pt) or palladium (Pd);
each of X¹ and X² is coordinated with M and is independently N or C;
each of Y¹, Y², Y³, Y⁴, Y⁵, Y⁶, Y⁷, Y⁸, Y⁹, Y¹⁰, Y¹¹, Y¹², Y¹³, Y¹⁴, Y¹⁵, Y¹⁶, Y¹⁷, Y¹⁸, Y¹⁹, Y²⁰, Y²¹, Y²², Y²³, Y²⁴, Y²⁵, Y²⁶, Y²⁷, Y²⁸, Y²⁹, Y³⁰, Y³¹, Y³², and Y³³ is independently N, C, P, O, S, or Si;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

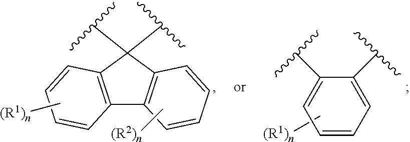

each of B¹, B², and B³ is independently CR¹, SiR¹, GeR¹, N, P, P═O, As, As═O, B, R³Bi═O, or Bi;
R^{bulky} represents R^{X};
each of R¹, R², R³, R⁴, R⁵, R⁶, R⁷, and R⁸ is independently absent or present as a single substituent or multiple substituents, valency permitting, and each R¹, R², R³, R⁴, R⁵, R⁶, R⁷, and R⁸ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by one of the following structures, which together represent LIST 2A

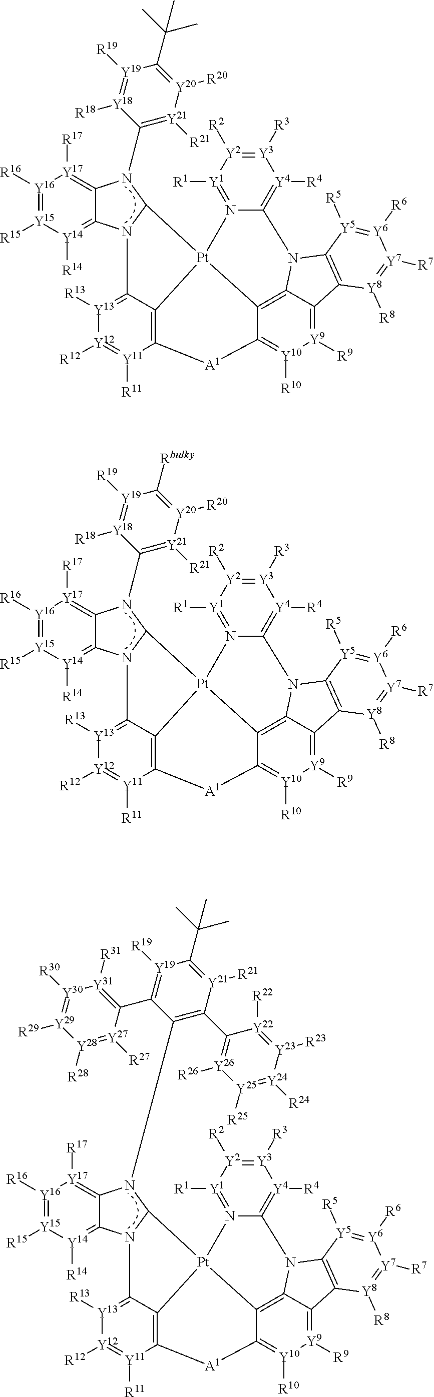

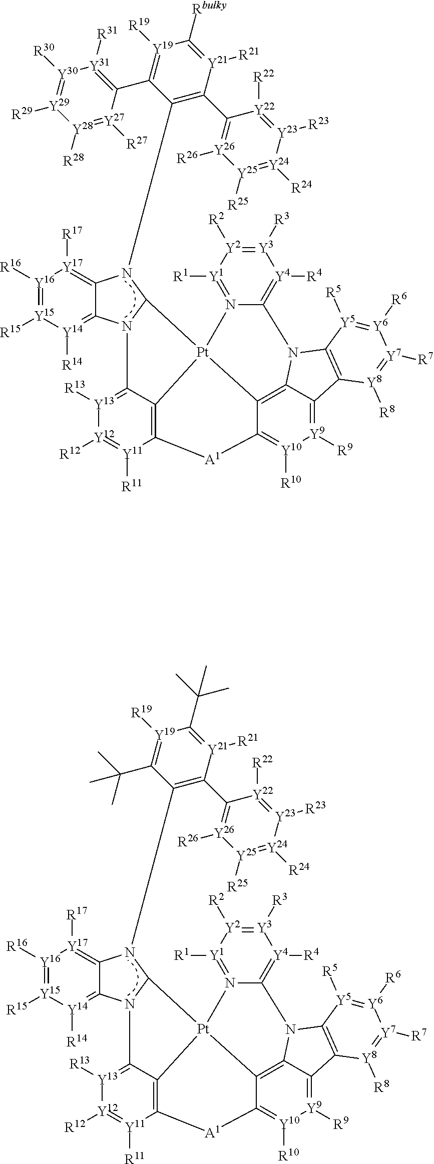

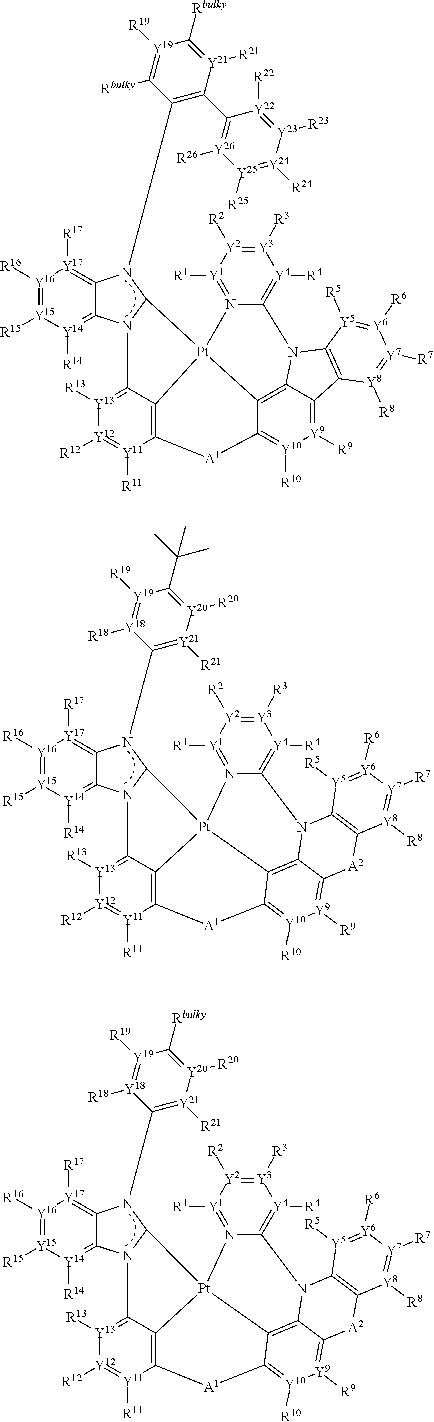

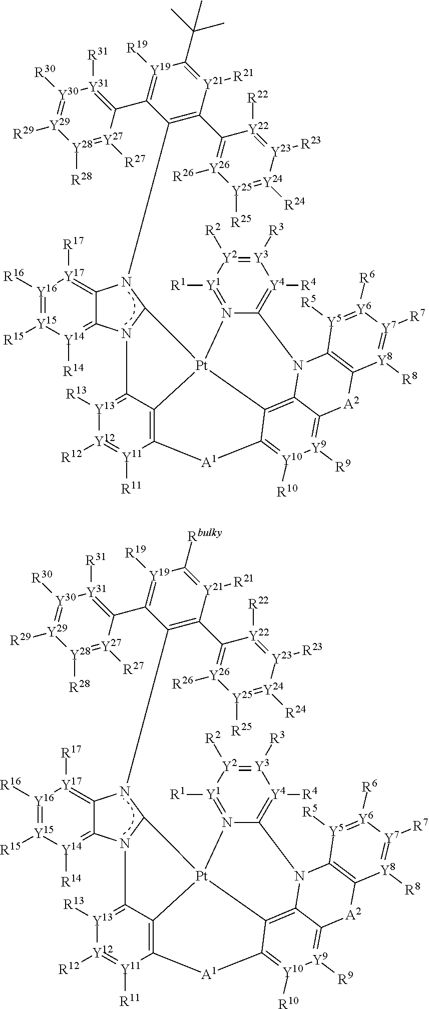

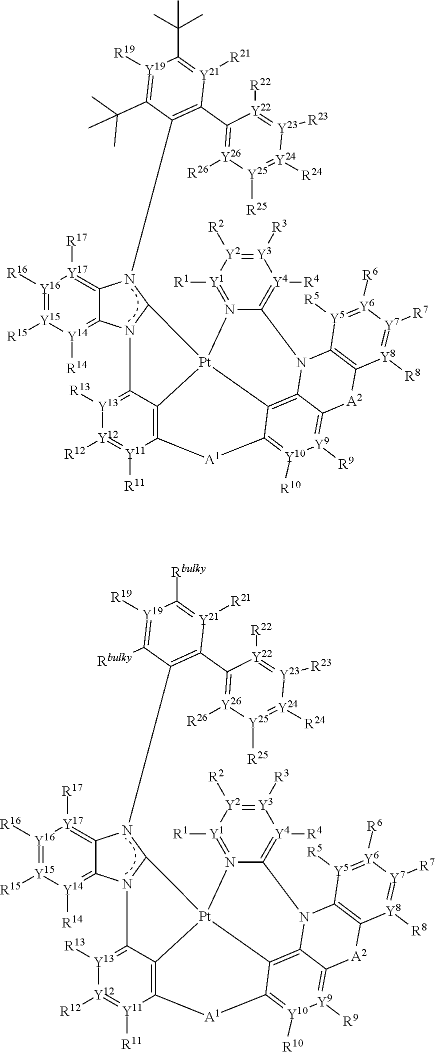

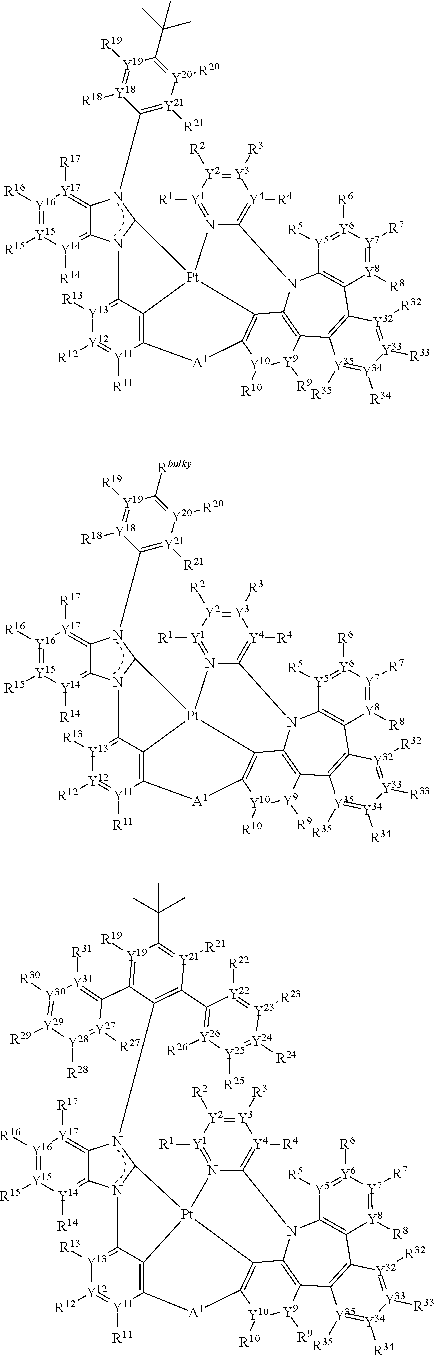

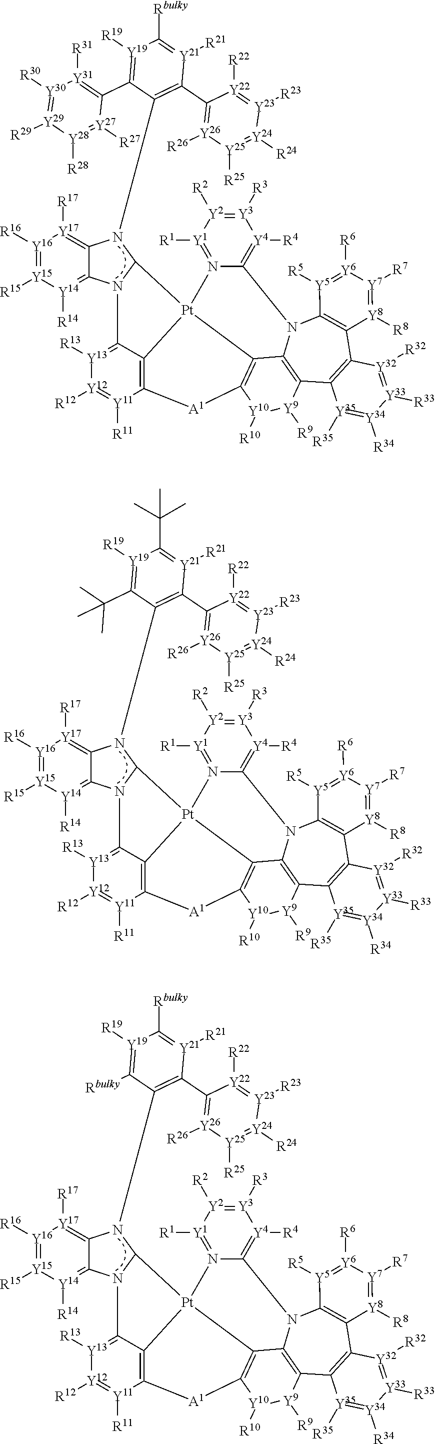

wherein:
M represents platinum (Pt) or palladium (Pd);
each of Y¹, Y², Y³, Y⁴, Y⁵, Y⁶, Y⁷, Y⁸, Y⁹, Y¹⁰, Y¹¹, Y¹², Y¹³, Y¹⁴, Y¹⁵, Y¹⁶, Y¹⁷, Y¹⁸, Y¹⁹, Y²⁰, Y²¹, Y²², Y²³, Y²⁴, Y²⁵, Y²⁶, Y²⁷, Y²⁸, Y²⁹, Y³⁰, Y³¹, Y³², Y³³, Y³⁴, and Y³⁵ is independently C, N, P, O, S, or Si.
each of A¹ and A² is independently absent or present, and each of A¹ and A² present represents a single bond, CR¹⁵R¹⁶, CR¹⁵═CR¹⁶, C≡C, C═O, C═S, SiR¹⁵R¹⁶, GeR¹⁵R¹⁶, NR¹⁷, PR¹⁷, R¹⁷P═O, AsR¹⁷, R¹⁷As═O, O, S, S═O, SO₂, Se, Se═O, SeO₂, BR¹⁷, BiR¹⁷, R¹⁷Bi═O,

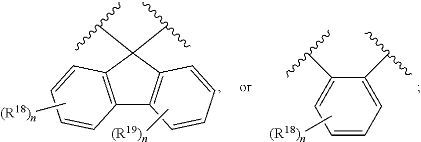

R^{bulky} represents R^{X};
each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴, R²⁵, R²⁶, R²⁷, R²⁸, R²⁹, R³⁰, R³¹, R³², R³³, R³⁴, and R³⁵ is independently absent or present, valency permitting, and each R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴, R²⁵, R²⁶, R²⁷, R²⁸, R²⁹, R³⁰, R³¹, R³², R³³, R³⁴, and R³⁵ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.
any two of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴, R²⁵, R²⁶, R²⁷, R²⁸, R²⁹, R³⁰, R³¹, R³², R³³, R³⁴, and R³⁵ on the same ring or adjacent rings are optionally bonded together to form a fused ring system of Formula A, Formula B, Formula C, or Formula D.

In one embodiment, the compound is represented by one of the following structures, which together represent LIST 3:

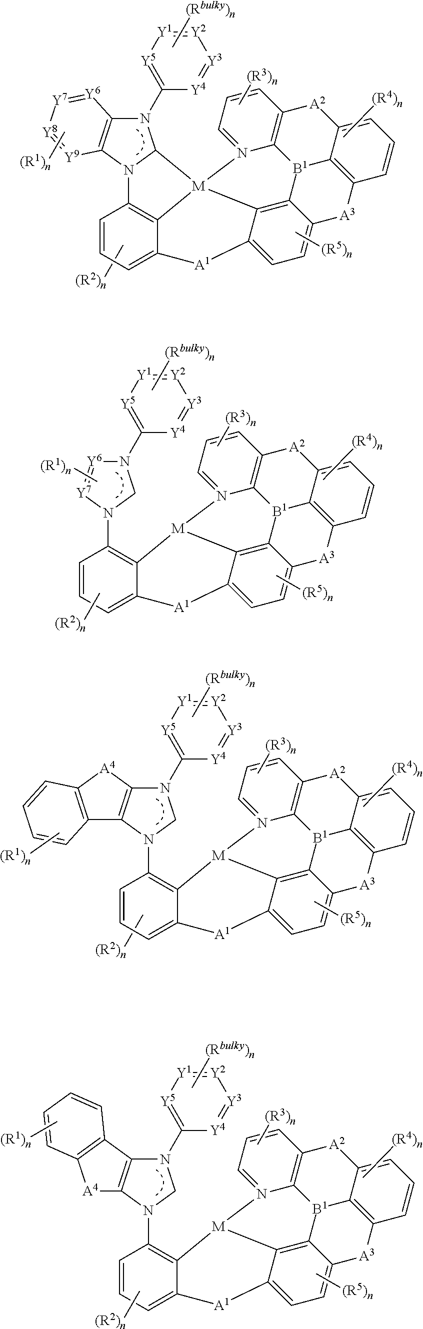

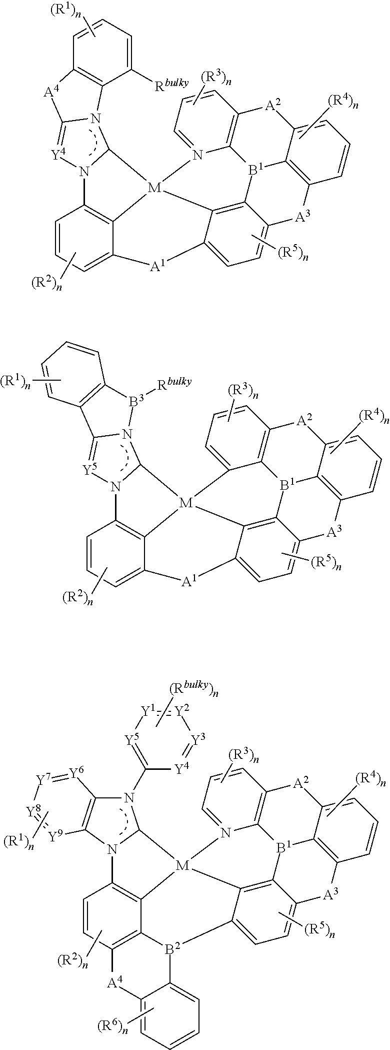

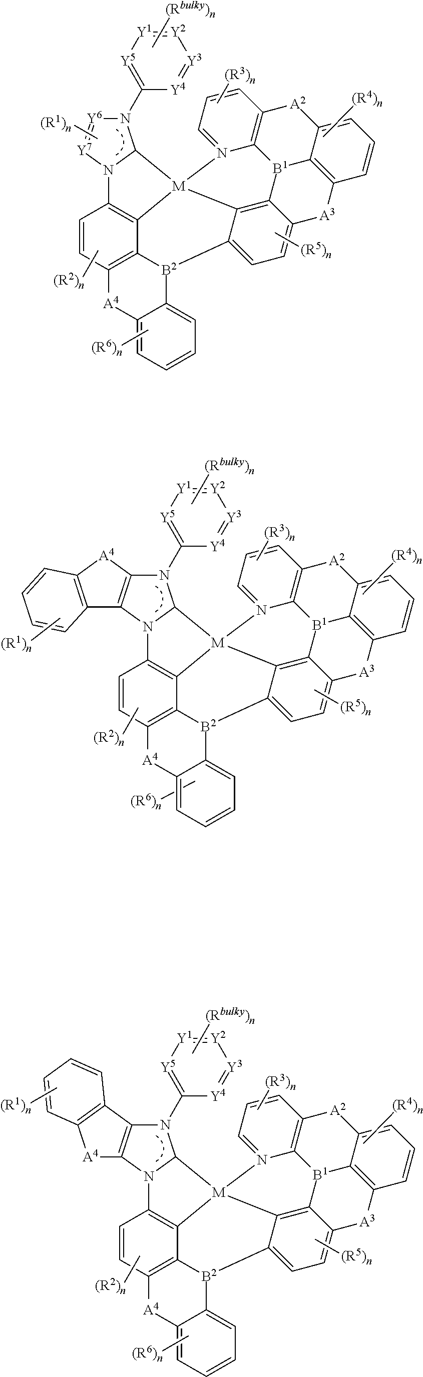

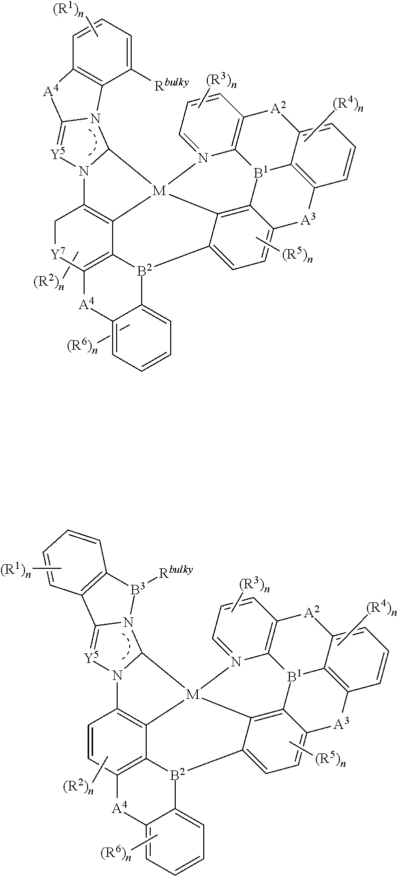

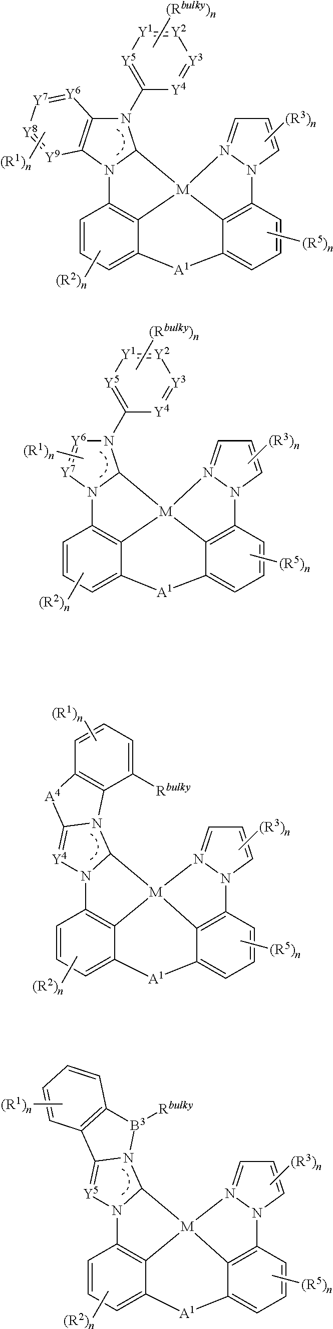

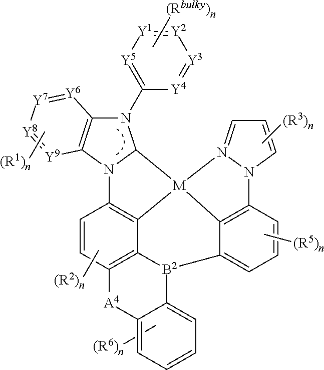

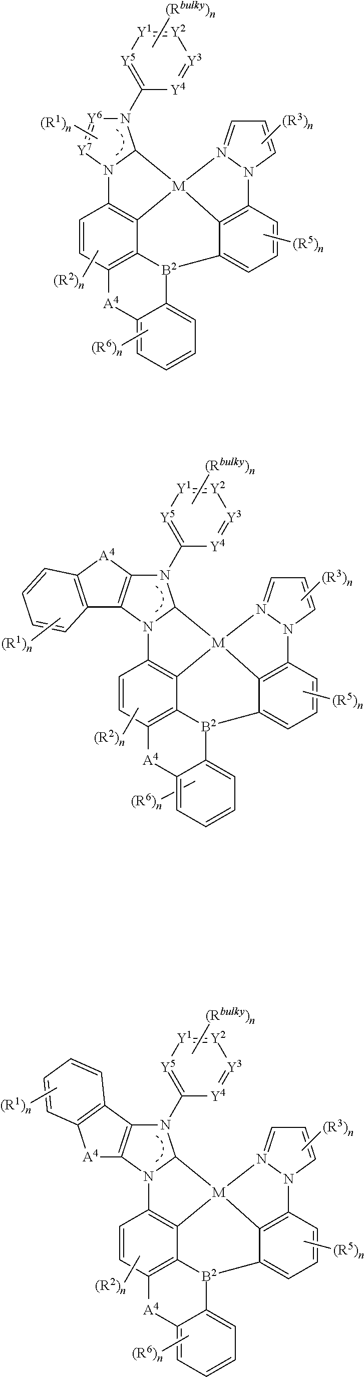

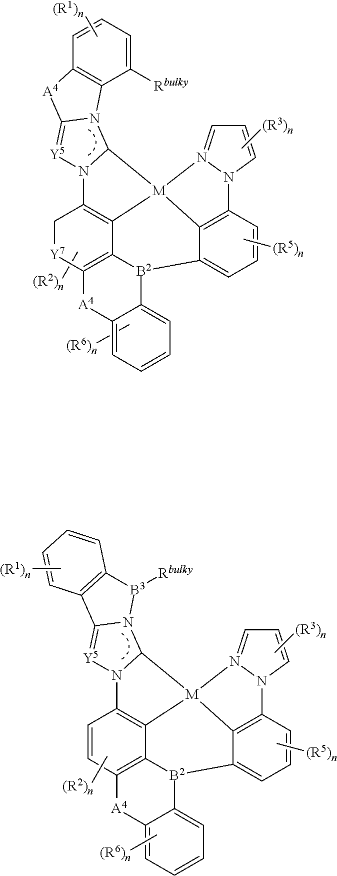

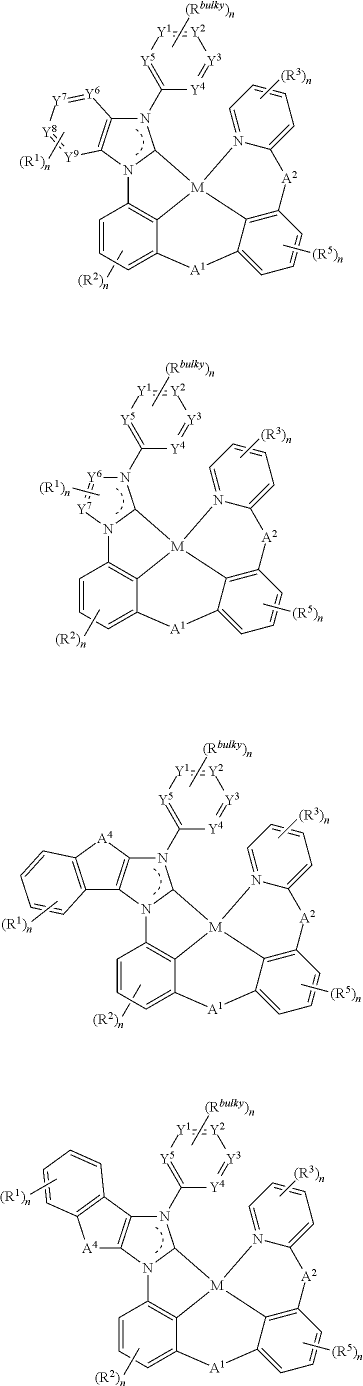

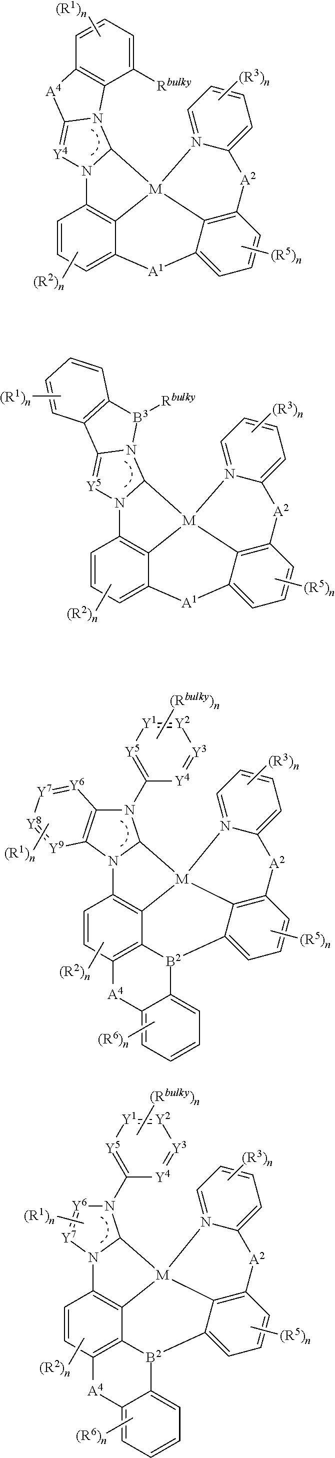

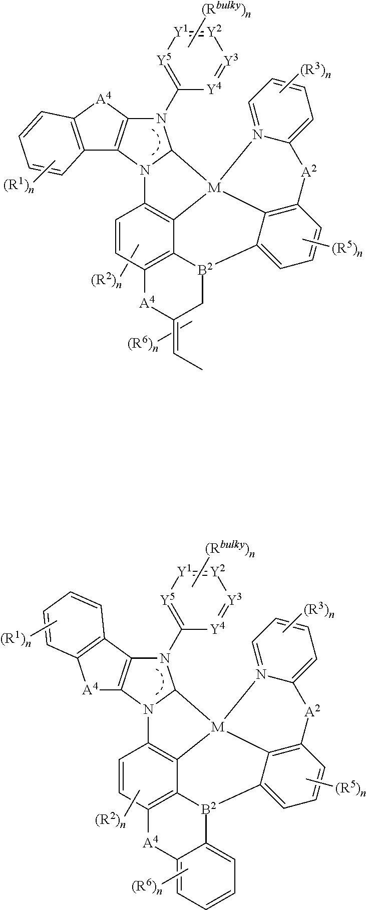

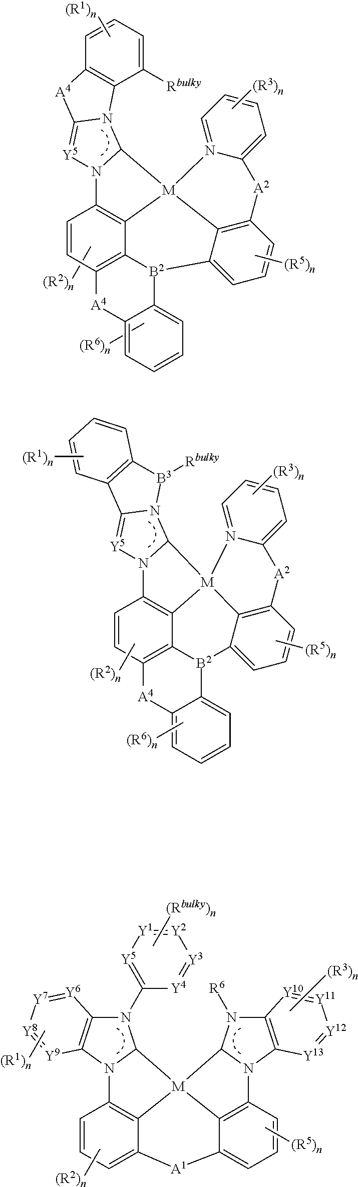

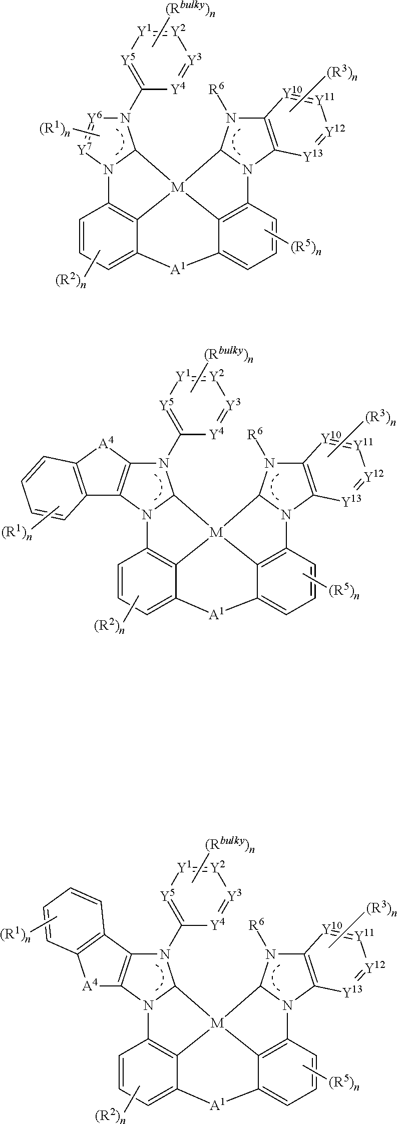

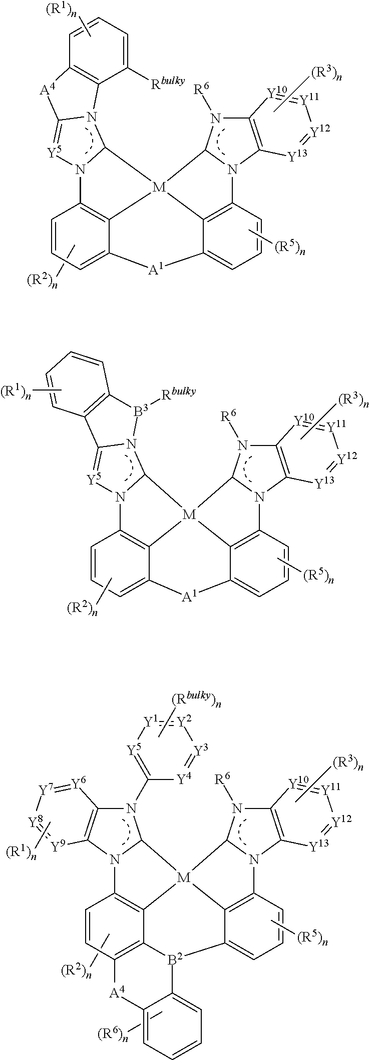

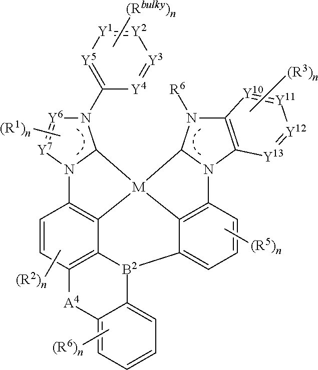

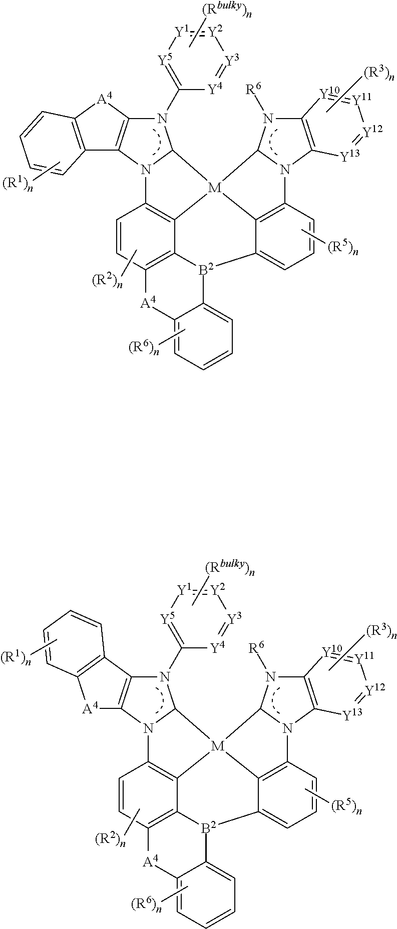

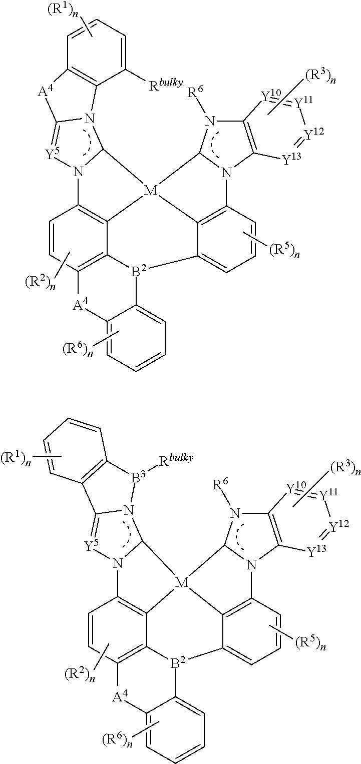

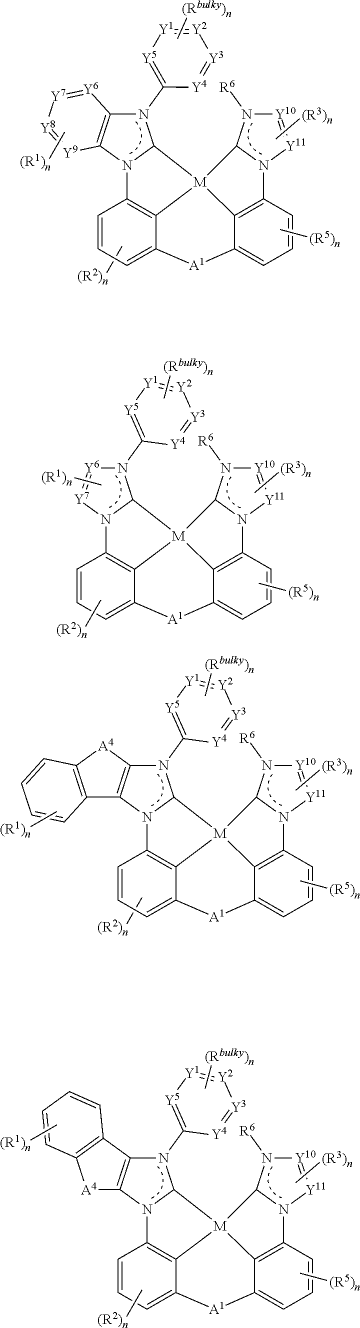

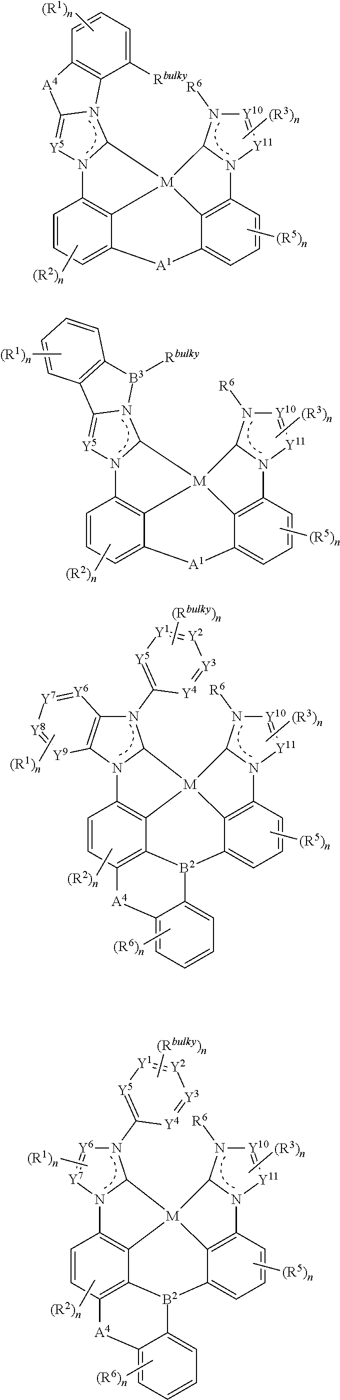

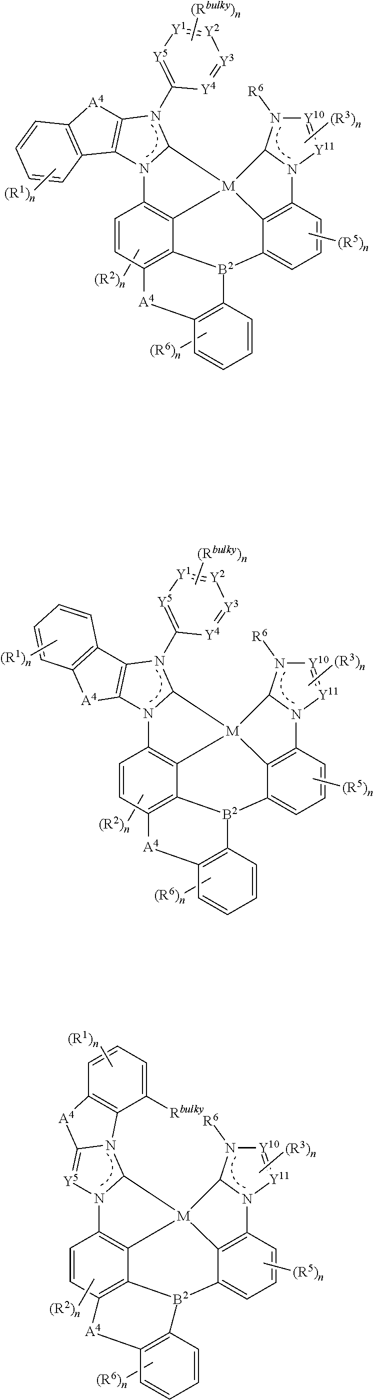

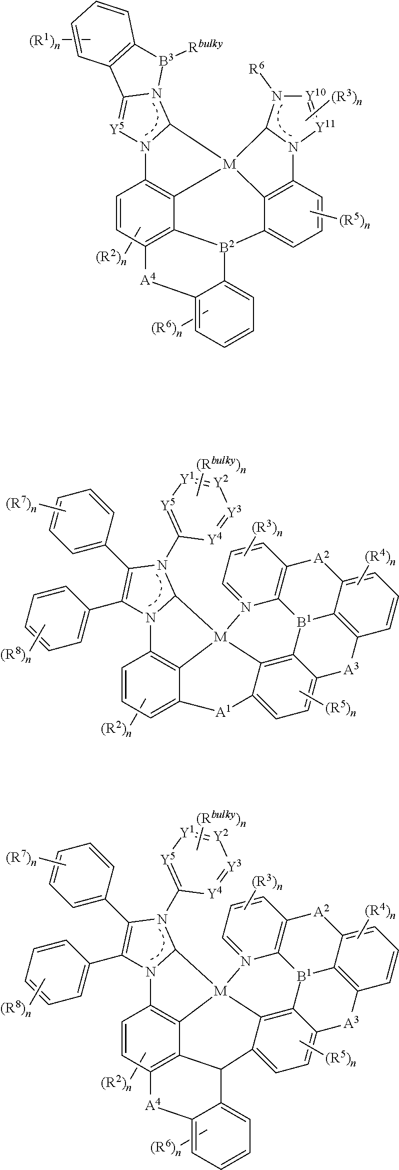

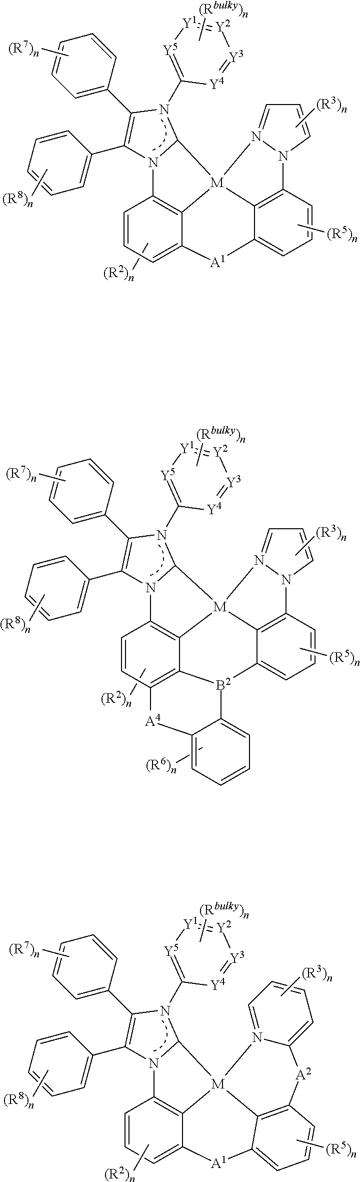

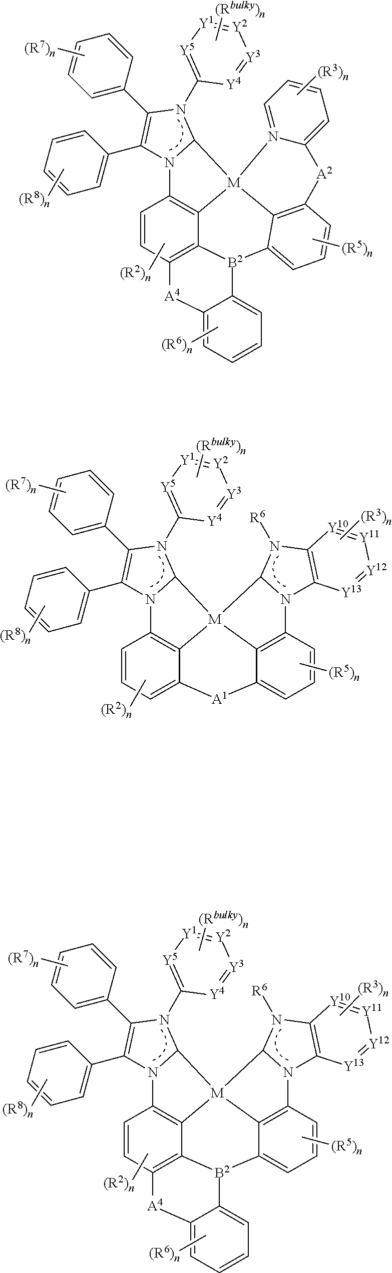

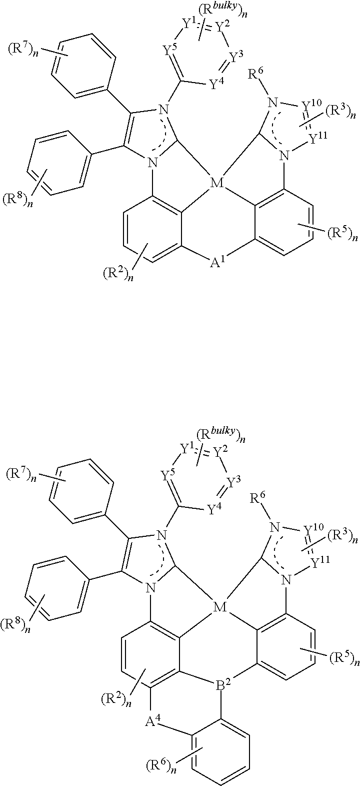

wherein:
M is platinum (Pt) or palladium (Pd);
each of Y¹, Y², Y³, Y⁴, Y⁵, Y⁶, Y⁷, Y⁸, Y⁹, Y¹⁰, Y¹¹, Y¹², and Y¹³ is independently N, C, P, O, S, or Si;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

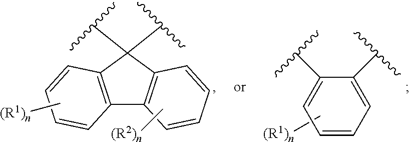

each of B¹, B², and B³ is independently CR¹, SiR¹, GeR¹, N, P, P═O, As, As═O, B, R³Bi═O, or Bi;
R^{bulky} represents R^{X};
each of R¹, R², R³, R⁴, R⁵, R⁶, R⁷, and R⁸ is independently absent or present as a single substituent or multiple substituents, valency permitting, and each R¹, R², R³, R⁴, R⁵, and R⁶ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by Formula III:

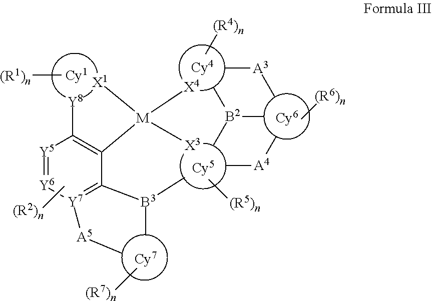

wherein:
each of Y⁵, Y⁶, and Y⁷ is independently N, C, P, O, S, or Si;
Cy¹ is selected from the group consisting of N-heterocyclic carbene, carbene, imidazole, and benzimidazole; wherein when Cy¹ is N-heterocyclic carbene or carbene, X¹ is C and Y⁸ is N; and when Cy¹ is imidazole or benzimidazole, X¹ is N and Y⁸ is C.
X¹ is N; and
Y⁵ optionally fuses to R¹ or a substituent on R¹ to form a ring.

In one embodiment, the compound is represented by one of the following structures, which together represent LIST 4:

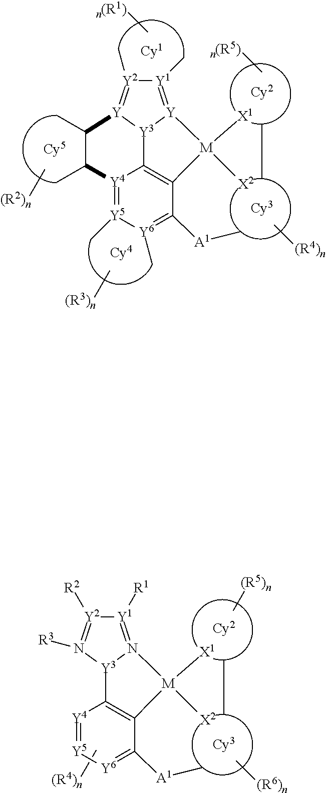

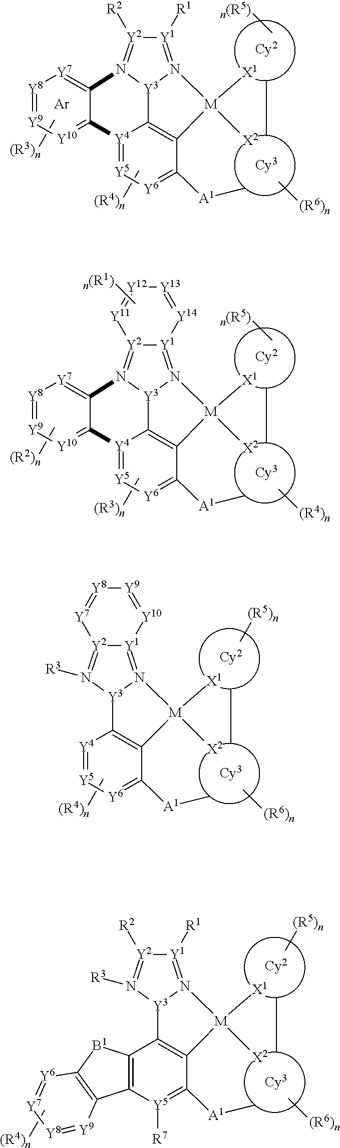

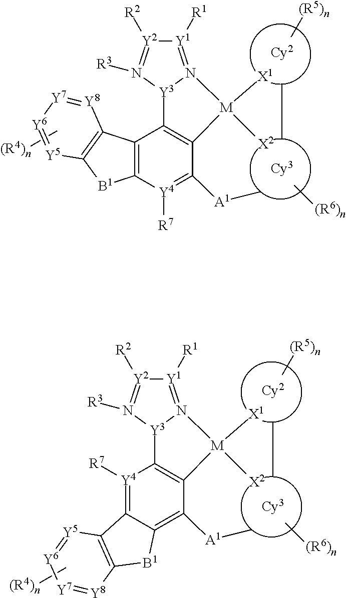

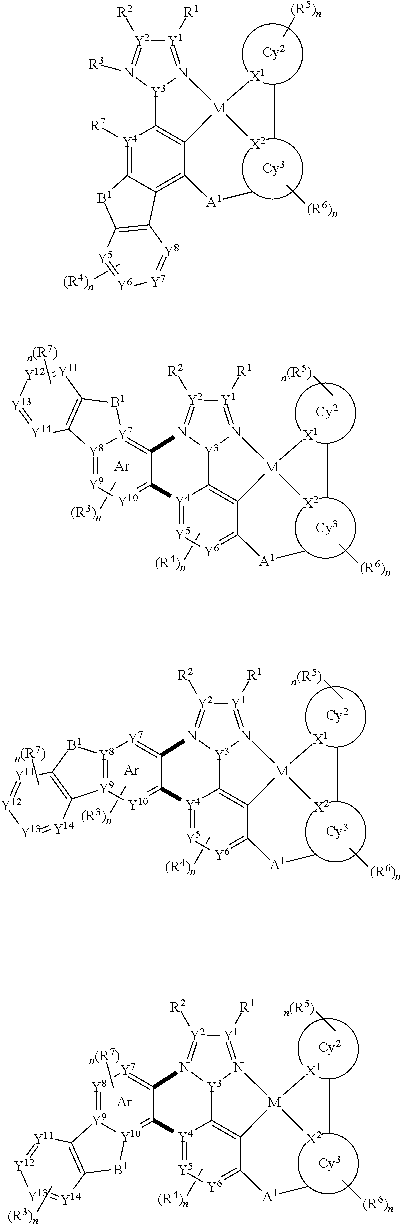

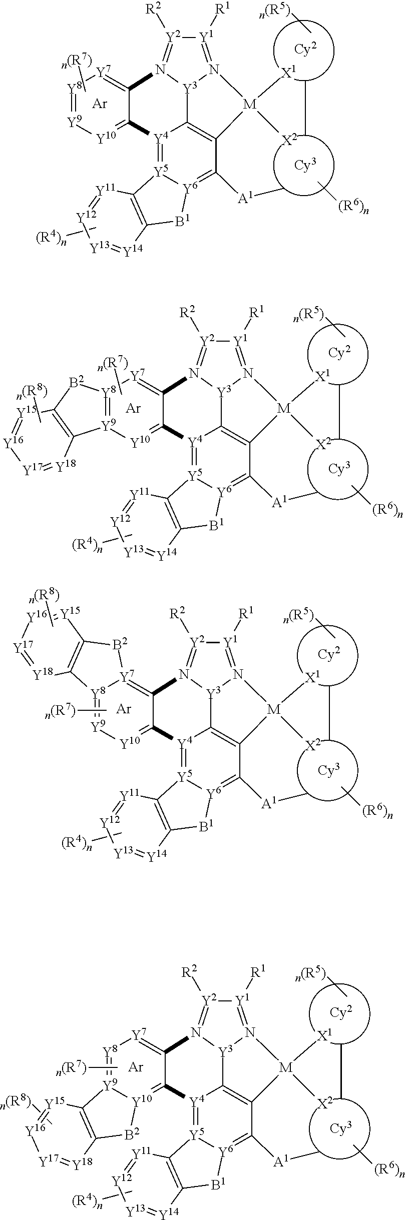

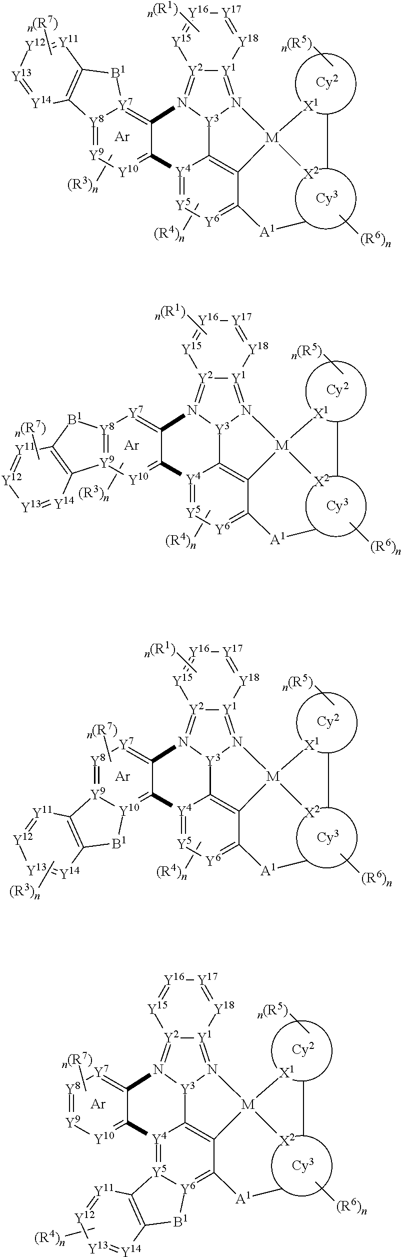

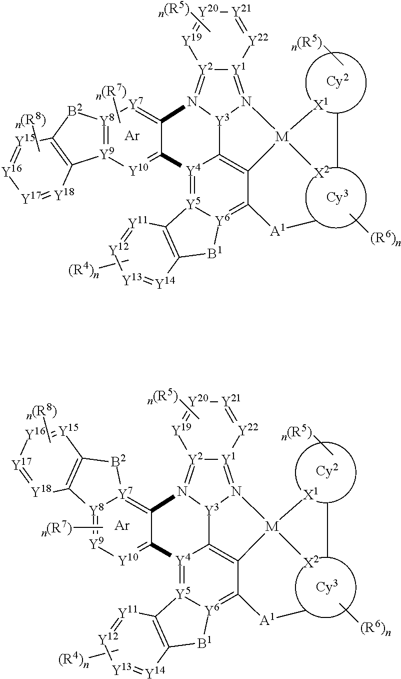

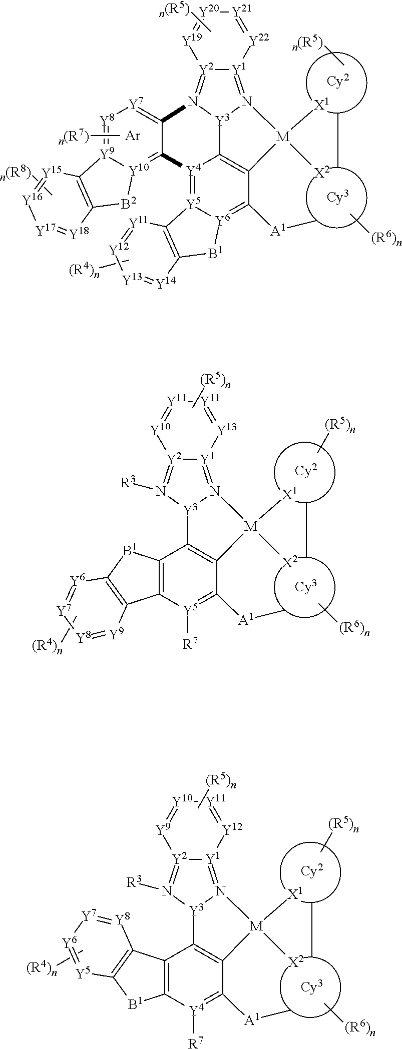

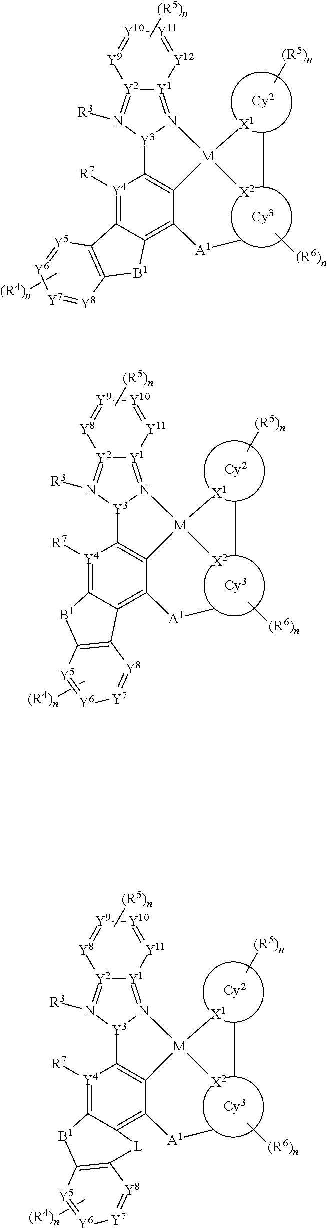

wherein:
M is platinum (Pt) or palladium (Pd);
each of Cy¹, Cy², Cy³, Cy⁴and Cy⁵ is independently substituted or unsubstituted aryl, cycloalkyl, cycloalkenyl, heteroaryl, heterocyclyl, carbene, or N-heterocyclic carbene;
Each of A¹, A², and A³ is independently absent or present; wherein each of A¹, A², and A³ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

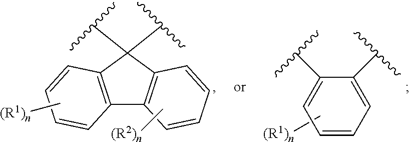

each Of Y¹, Y², Y³, Y⁴, Y⁵, Y⁶, Y⁷, Y⁸, Y⁹, Y¹⁰, Y¹¹, Y¹², Y¹³, Y¹⁴, Y¹⁵, Y¹⁶, Y¹⁷, Y¹⁸, Y¹⁹, and Y²⁰ is independently N, C, P, O, S, or Si;
each of Ar is independently substituted or unsubstituted aryl, cycloalkyl, cycloalkenyl, heteroaryl, or heterocyclyl;
each of B¹ and B² is independently a single bond, CR¹R², CR¹=CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, or R³Bi═O;
each of R¹, R², R³, R⁴, R⁵, R⁶, R⁷ and R⁸ is independently absent or present as a single substituent or multiple substituents, valency permitting, and each R¹, R², R³, R⁴, R⁵, R⁶, R⁷, R⁸, and R⁹ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two substituents optionally join to form a ring that is optionally further substituted.

In one embodiment, the moiety

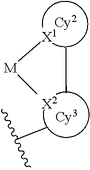

is independently one of the following structures:

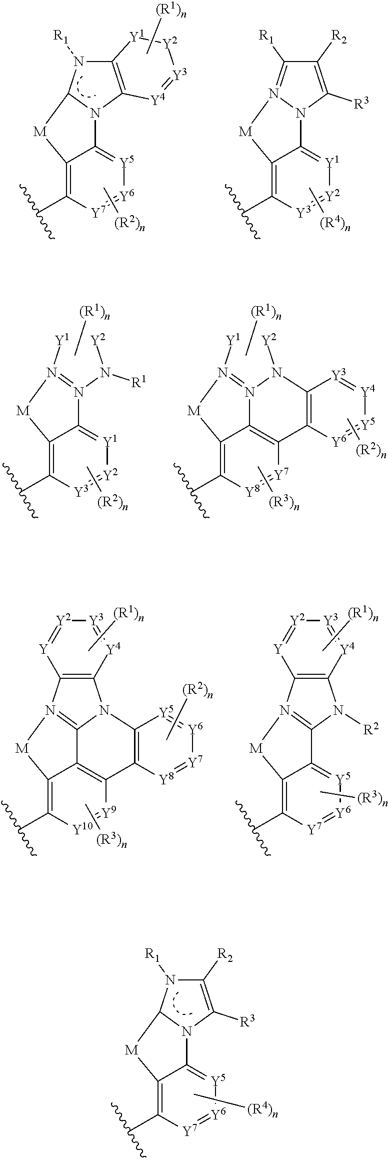

wherein:
each of Y¹, Y², Y³, Y⁴, Y⁵, Y⁶, Y⁷, Y⁸, Y⁹, and Y¹⁰ is independently N, C, P, O, S, or Si;
each of R¹, R², R³, R⁴ is independently absent or present as a single substituent or multiple substituents, valency permitting, and each R¹, R², R³, R⁴ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

In one embodiment, the compound is represented by one of the following structures, which together represent LIST 5:

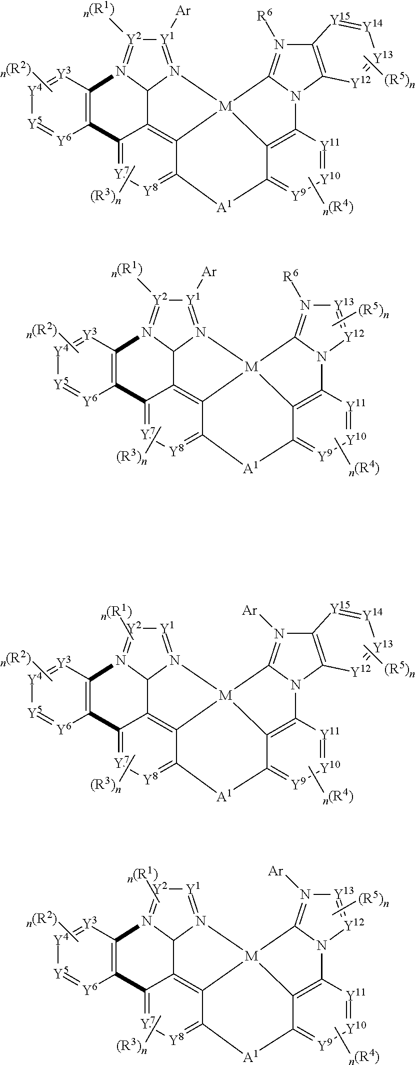

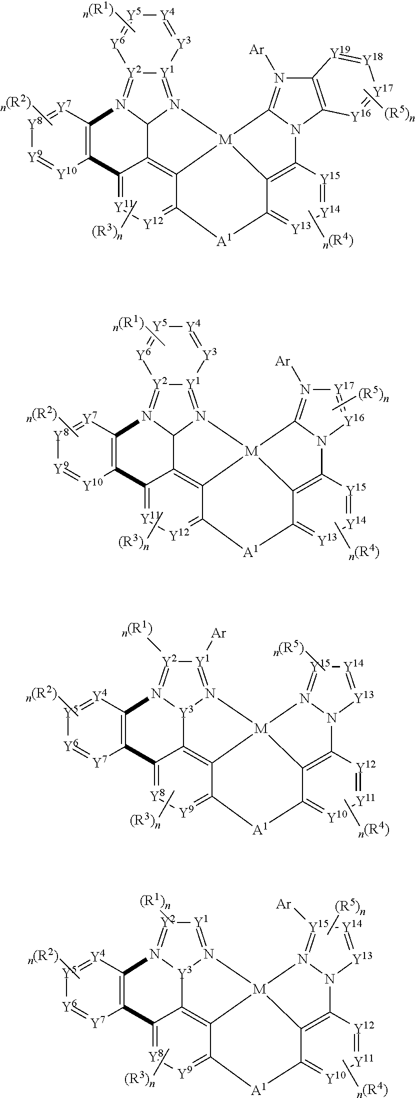

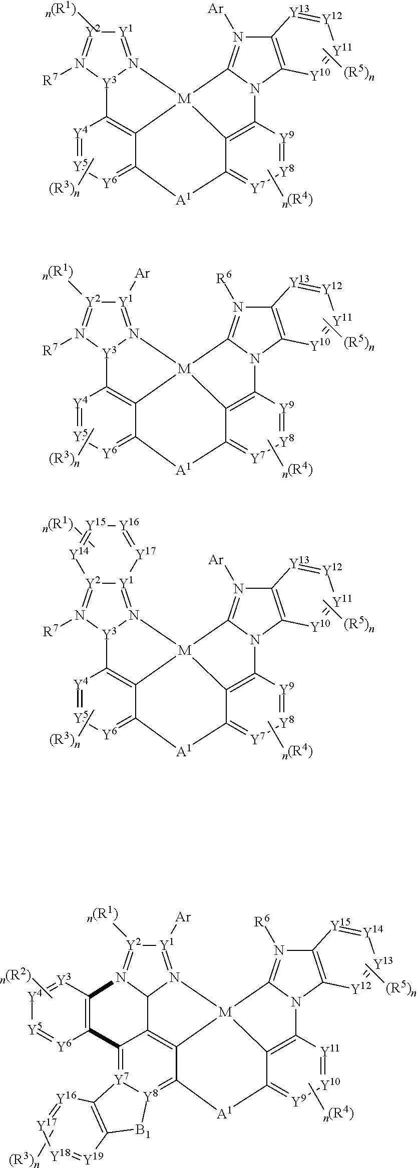

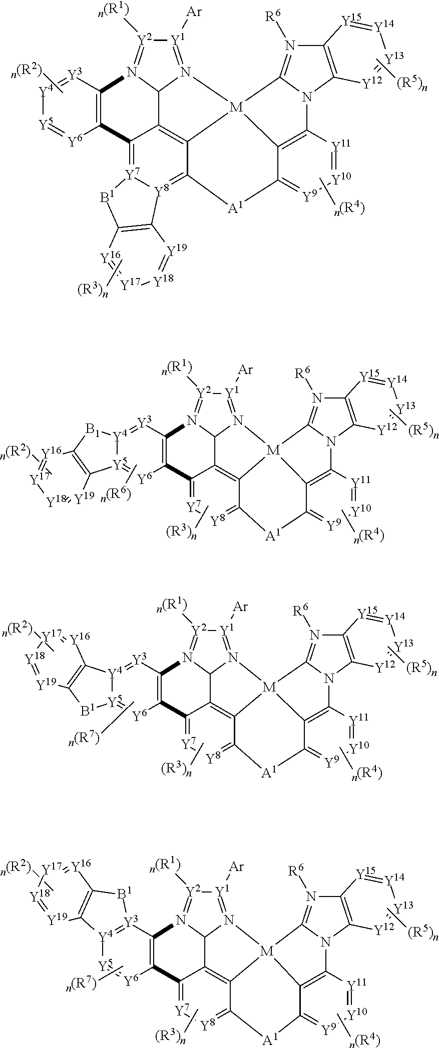

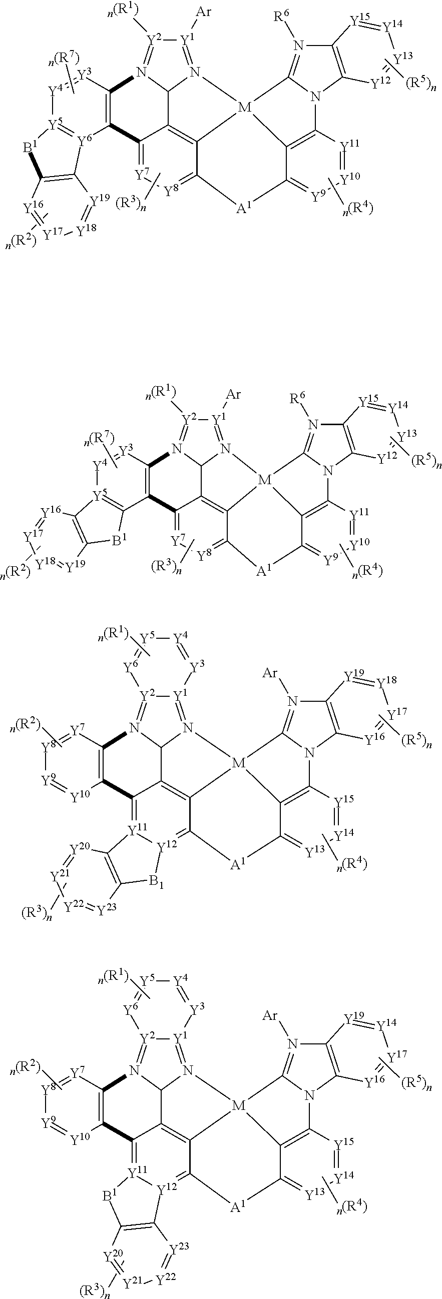

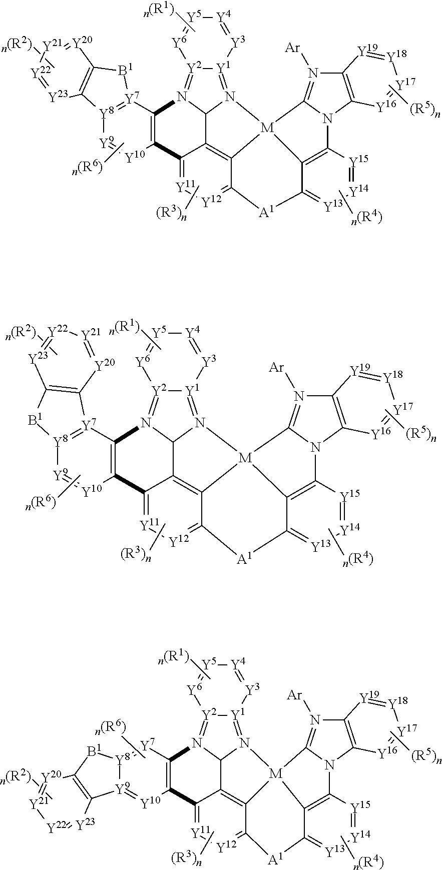

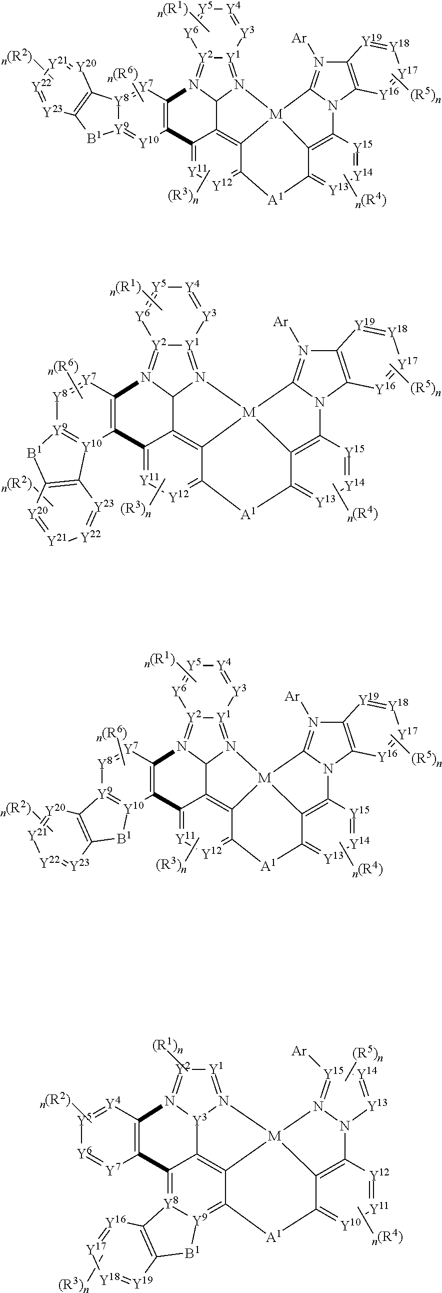

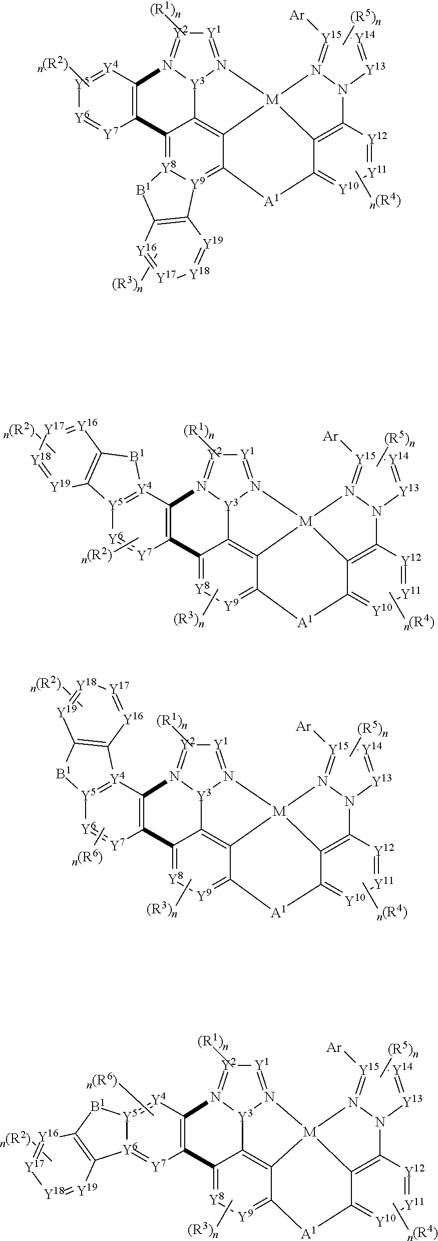

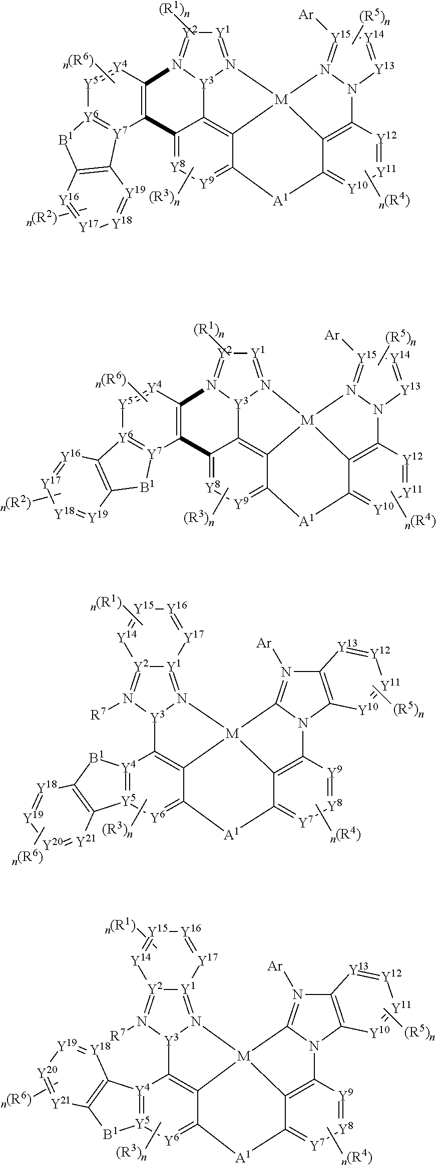

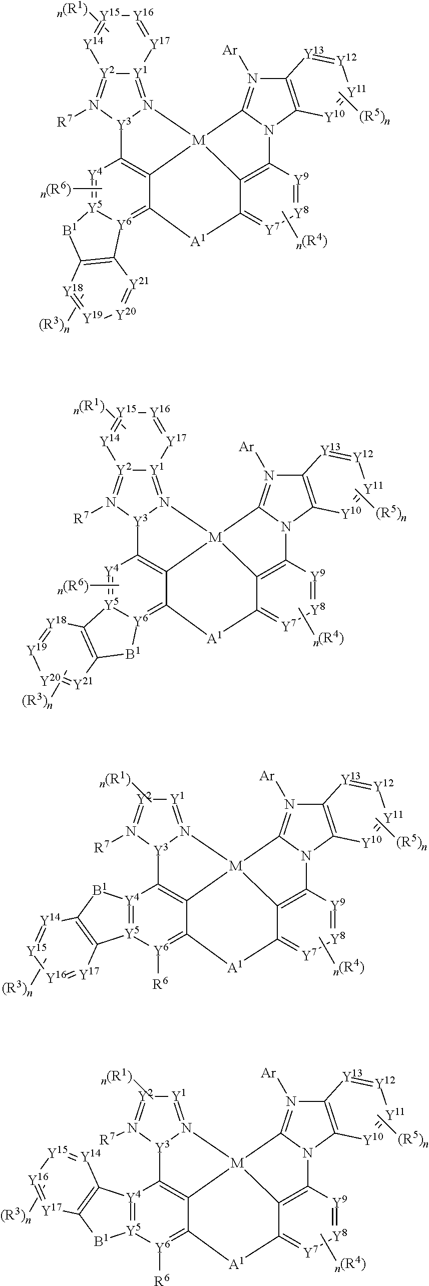

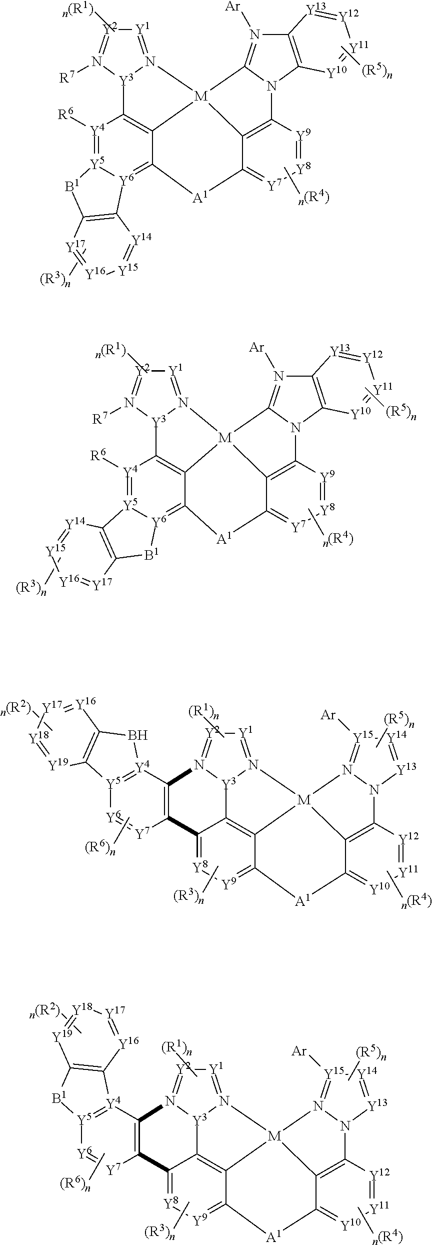

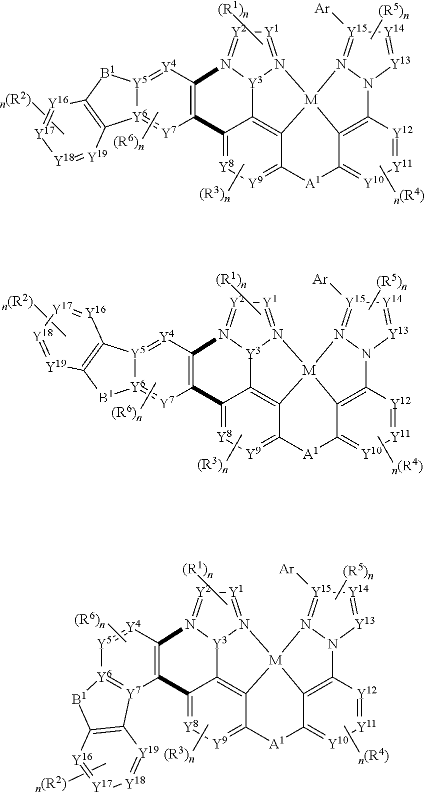

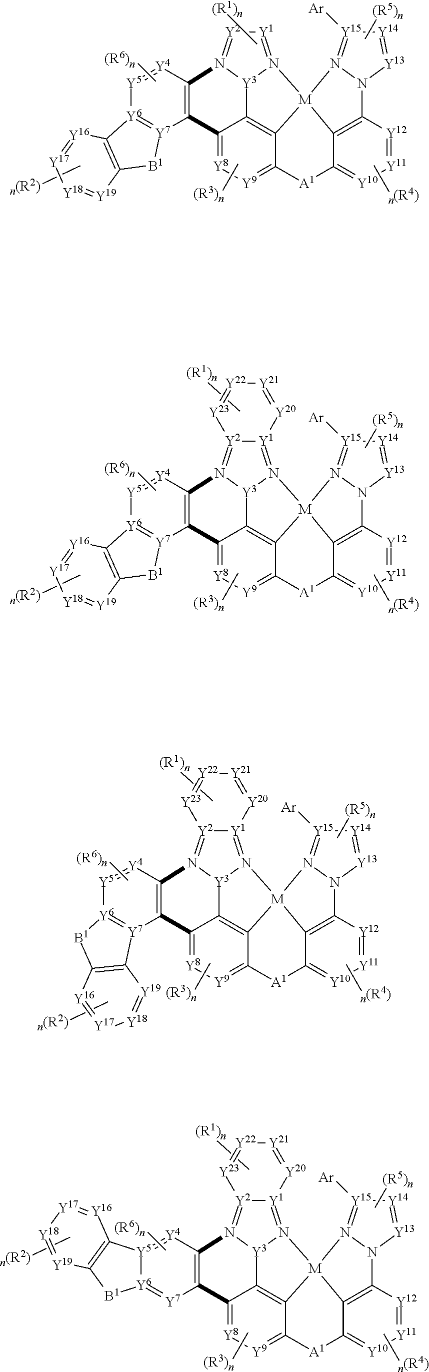

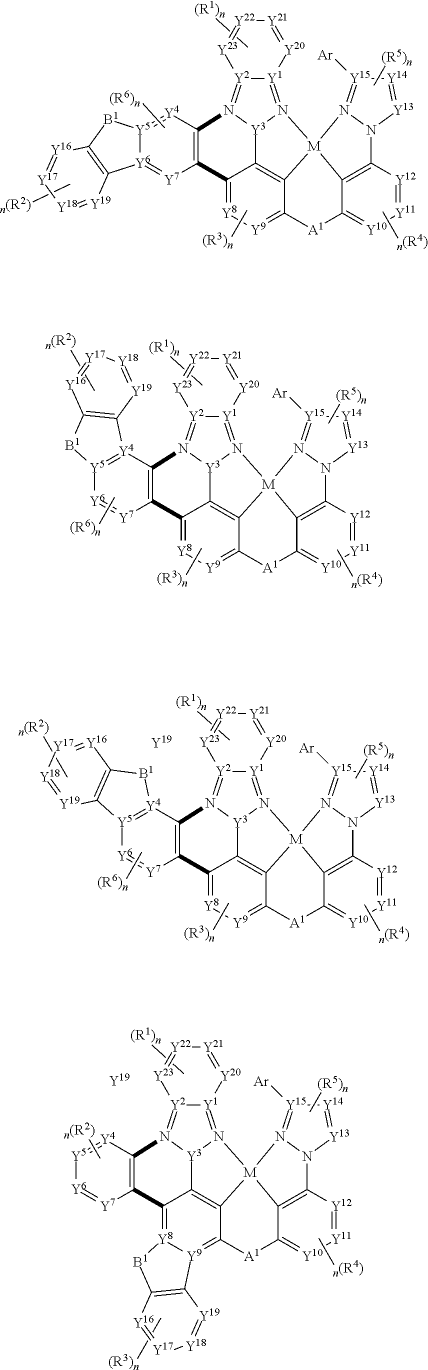

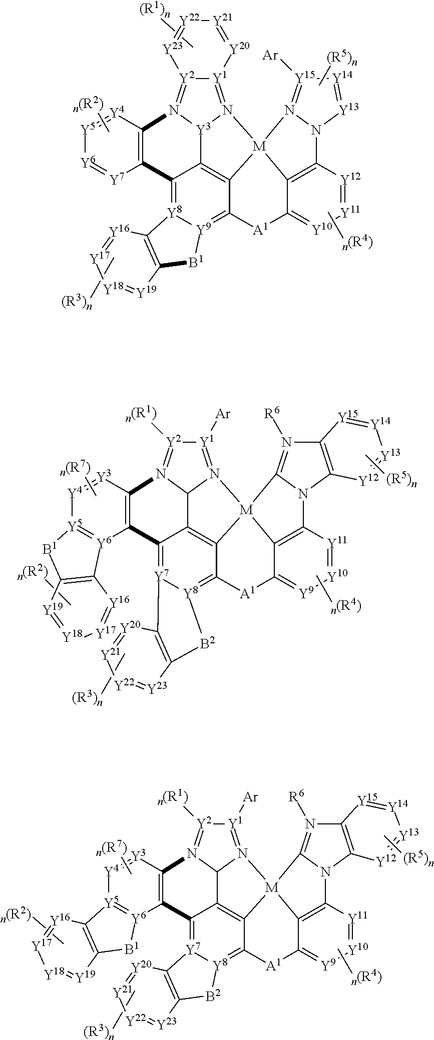

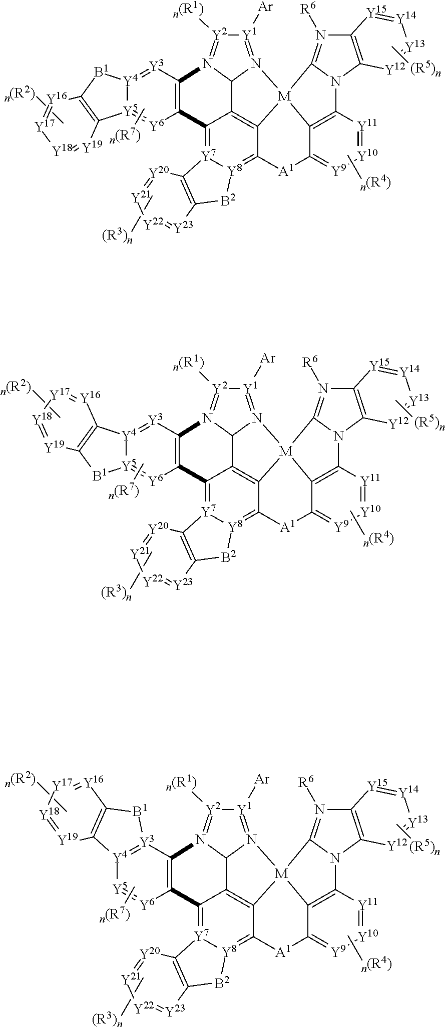

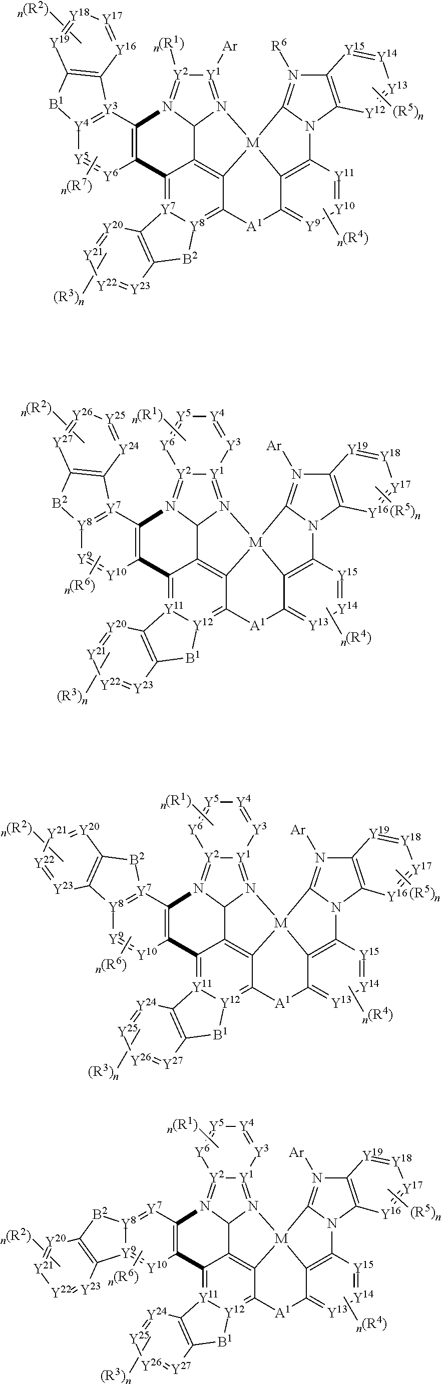

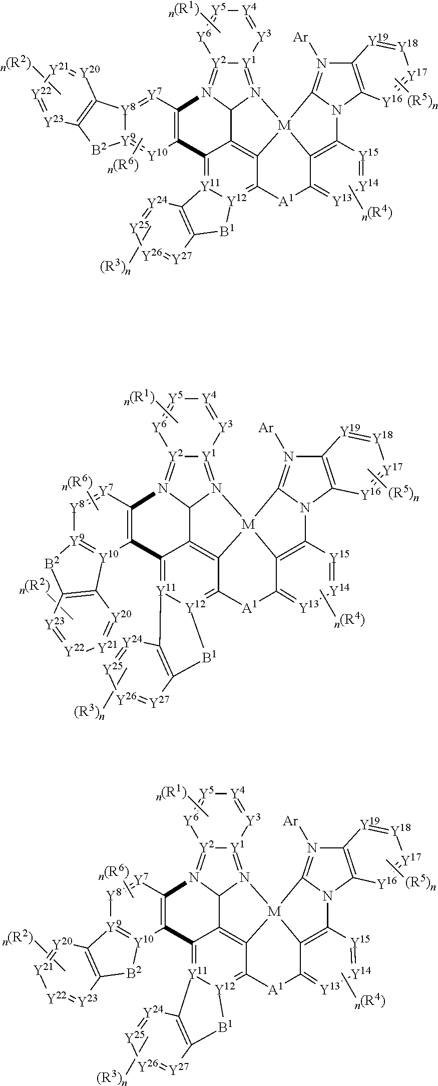

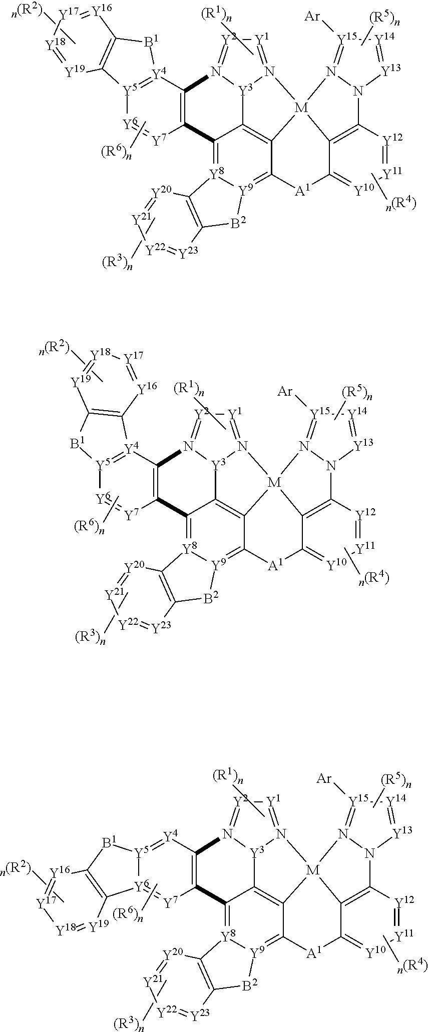

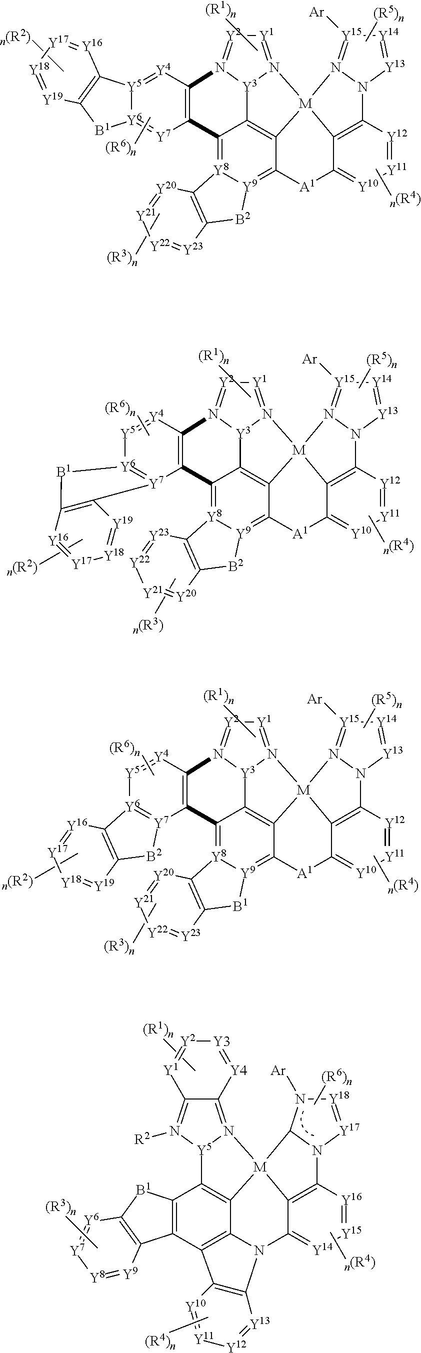

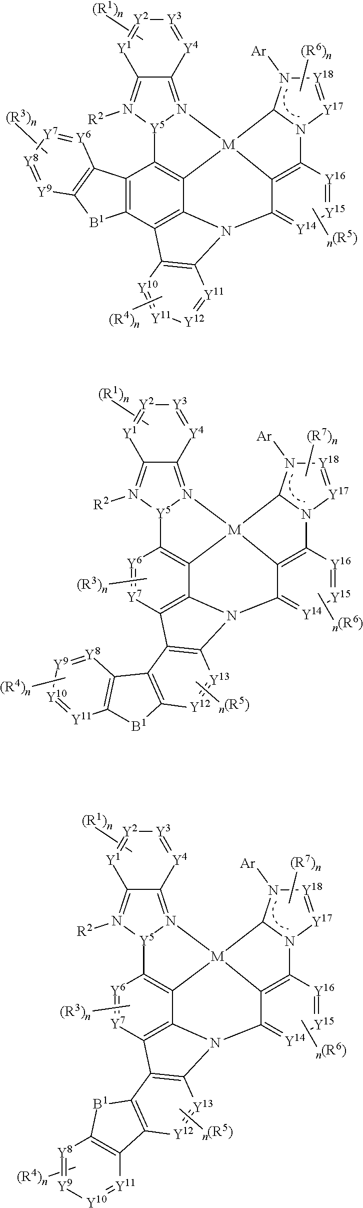

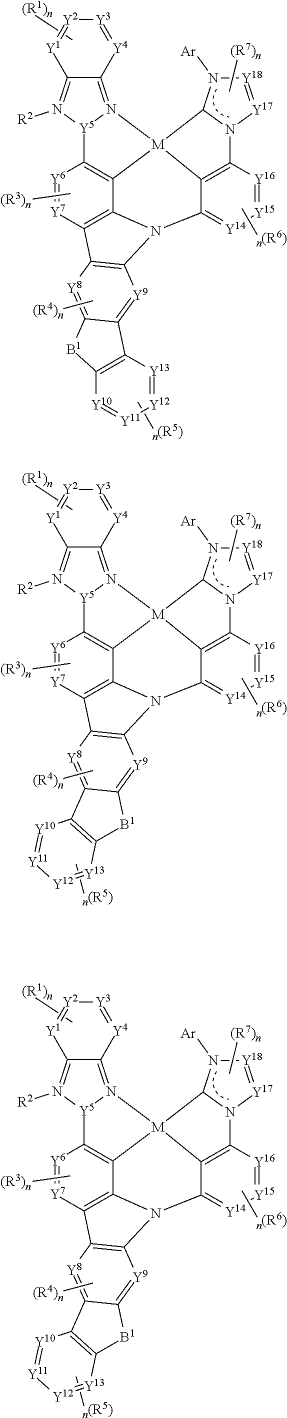

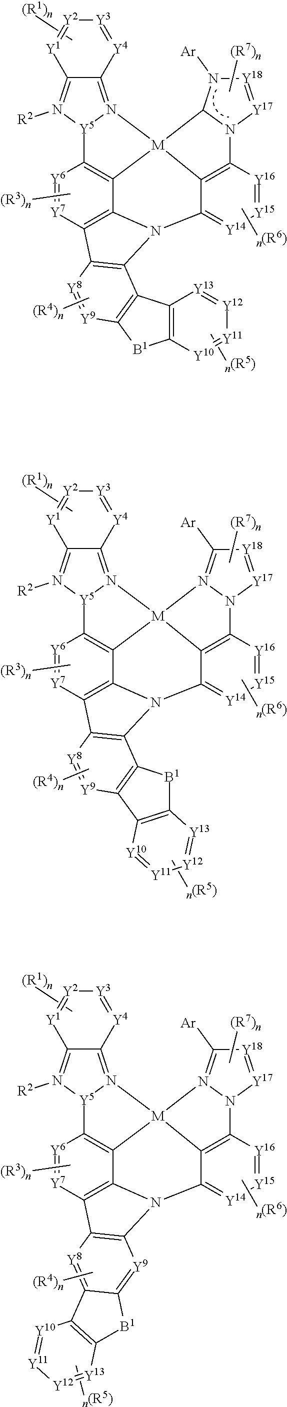

wherein:
M is platinum (Pt) or palladium (Pd);
each of Cy¹, Cy², and Cy³ is independently substituted or unsubstituted aryl, cycloalkyl, cycloalkenyl, heteroaryl, heterocyclyl, carbene, or N-heterocyclic carbene;
Each of A¹, A², and A³ is independently a single bond, CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O;
each Of Y¹, Y², Y³, Y⁴, Y⁵, Y⁶, Y⁷, Y⁸, Y⁹, Y¹⁰, Y¹¹, Y¹², Y¹³, Y¹⁴, Y¹⁵, Y¹⁶, Y¹⁷, Y¹⁸, Y¹⁹, Y²⁰ is independently N, C, P, O, S, or Si;
Ar is independently substituted or unsubstituted aryl, cycloalkyl, cycloalkenyl, heteroaryl, heterocyclyl;
B¹, B², and A¹ are each independently a single bond, CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O;
each of R¹, R², R³, R⁴, R⁵, and R⁶ is independently absent or present as a single substituent or multiple substituents, valency permitting, and each R¹, R², R³, R⁴, R⁵, R⁶, R⁷, R⁸, and R⁹ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
provided that at least one of R¹, R², R³, R⁴, R⁵, and R⁶ represents R^{X};
wherein any two adjacent substituents optionally join to form a fused ring of Formula A, Formula B, Formula C, or Formula D.

In one embodiment, Cy¹ represents N-heterocyclic carbene;
X¹ represents C; and
two groups R¹ join to form a ring which is further substituted with at least one R^{X}; or
two groups R¹ join to form a ring which is substituted with divalent linking group A^{X}, wherein A^{X} is covalently bonded to Cy²; and wherein A^{X} represents a single bond, CR¹⁵R¹⁶, CR¹⁵═CR¹⁶, C≡C, C═O, C═S, SiR¹⁵R¹⁶, GeR¹⁵R¹⁶, NR¹⁷, PR¹⁷, R¹⁷P═O, AsR¹⁷, R¹⁷As═O, O, S, S═O, SO₂, Se, Se═O, SeO₂, BR¹⁷, BiR¹⁷, R¹⁷Bi═O,

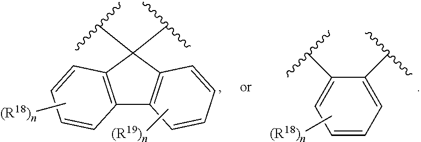

In one embodiment, Cy¹ represents N-heterocyclic carbene;
X¹ represents C; and
two adjacent two adjacent substituents R³ are present and together represent a group of Formula C.

In one embodiment, the compound is represented by one of the following structures, which together represent LIST 6:

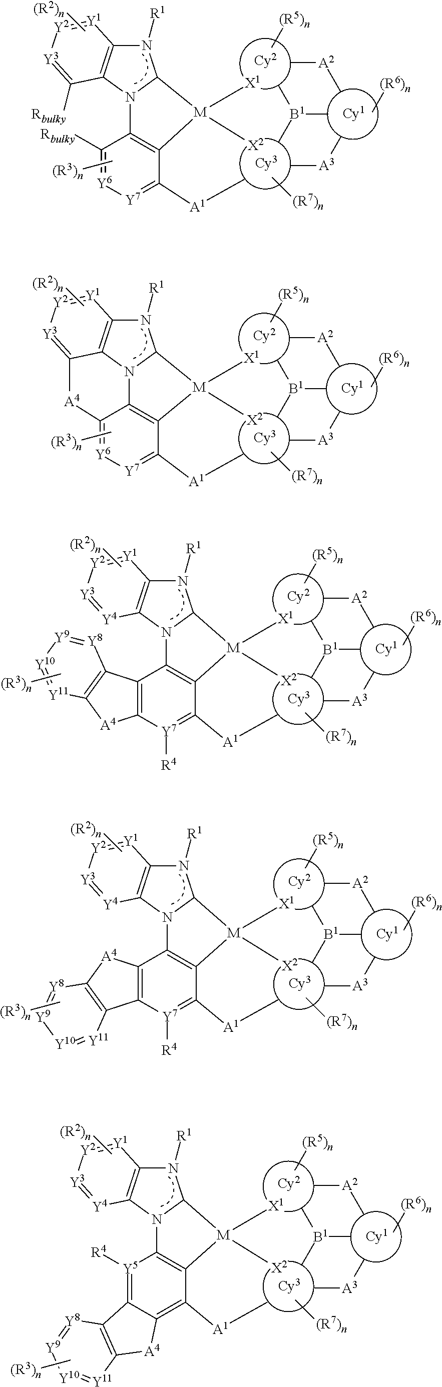

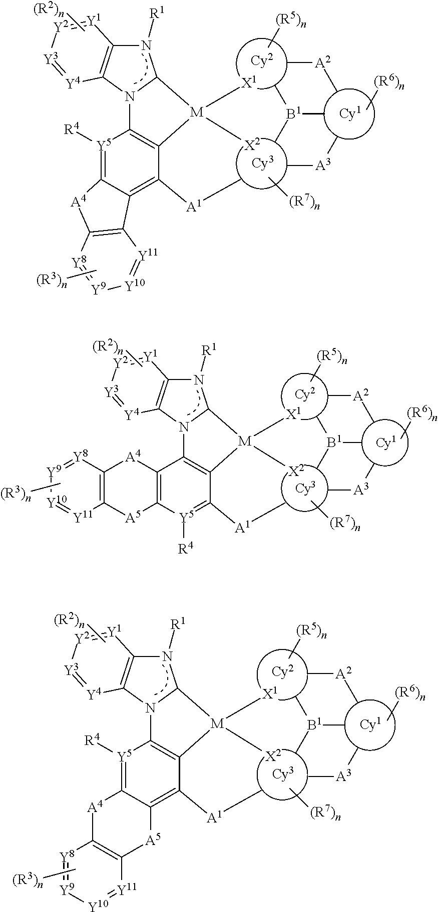

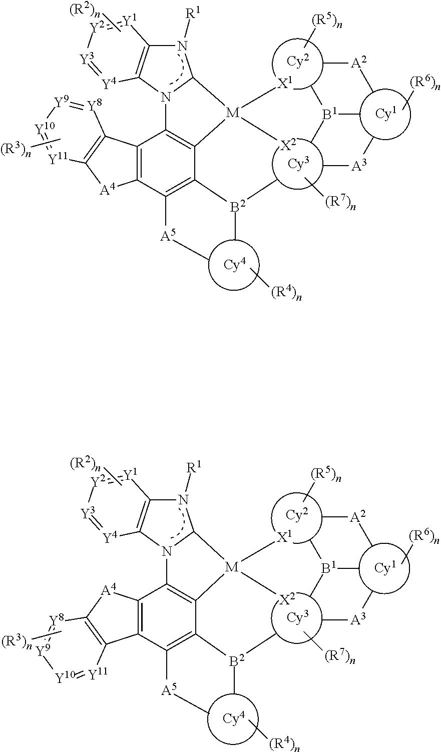

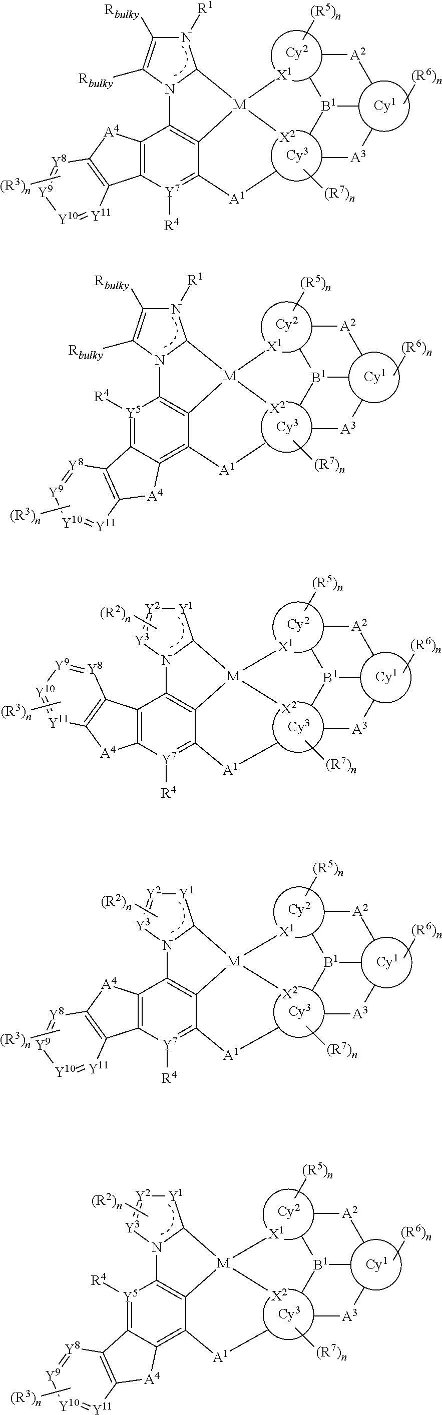

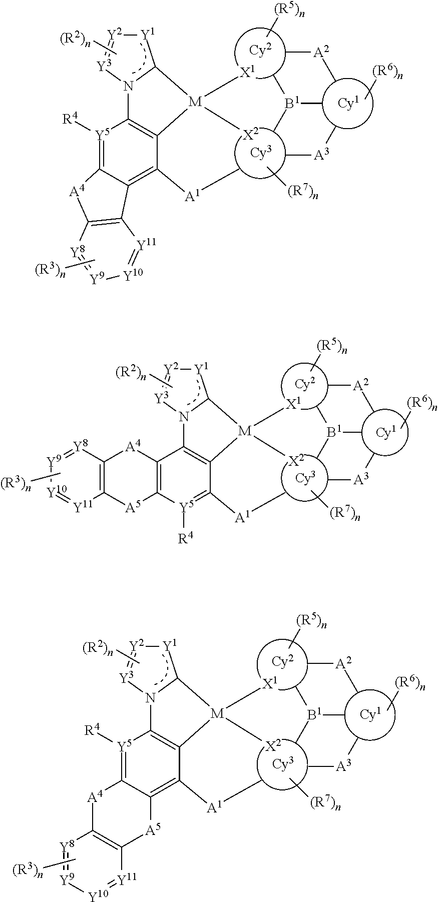

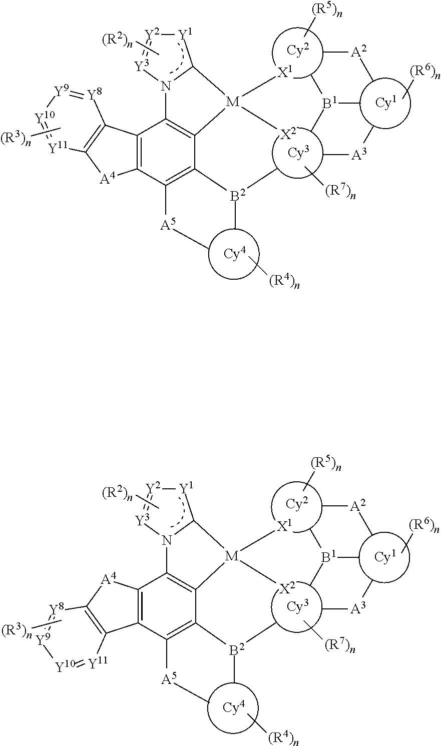

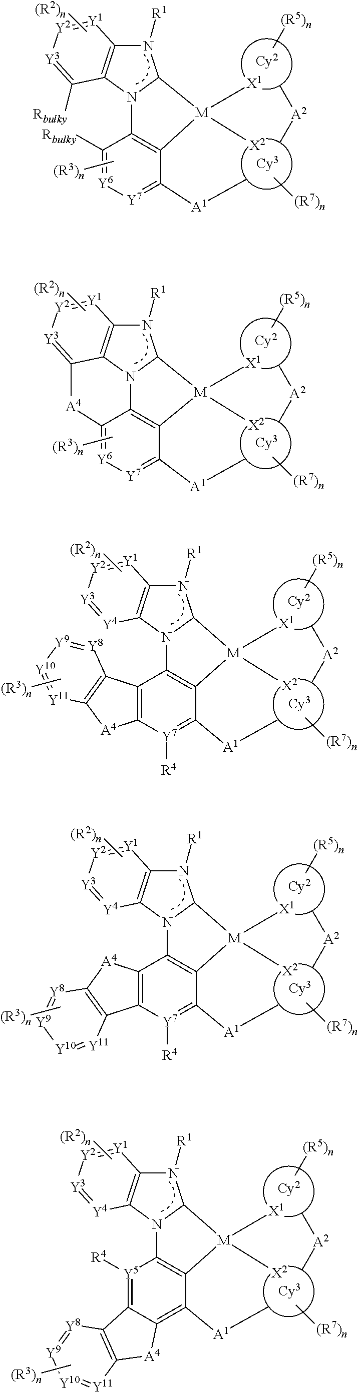

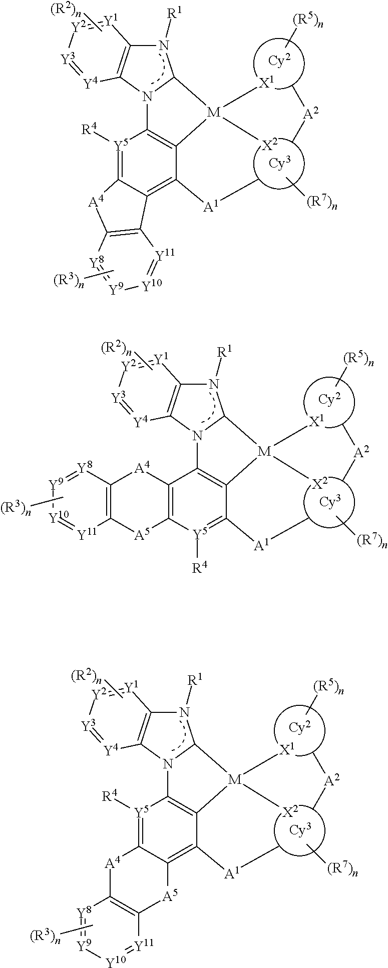

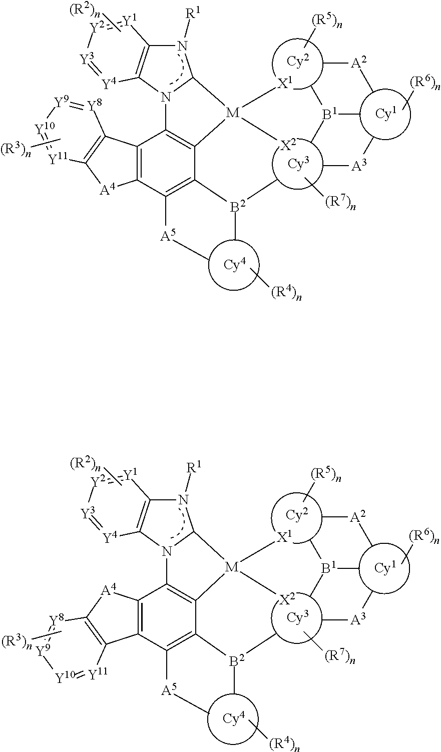

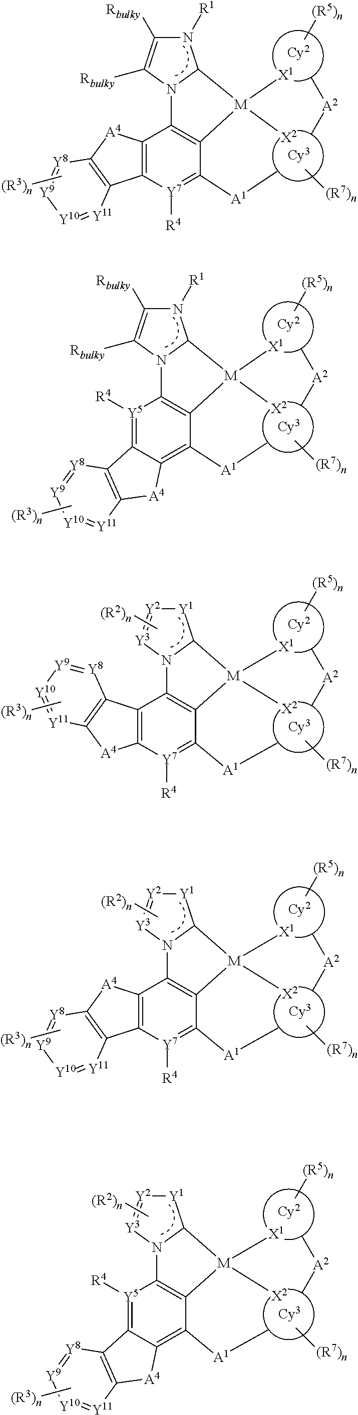

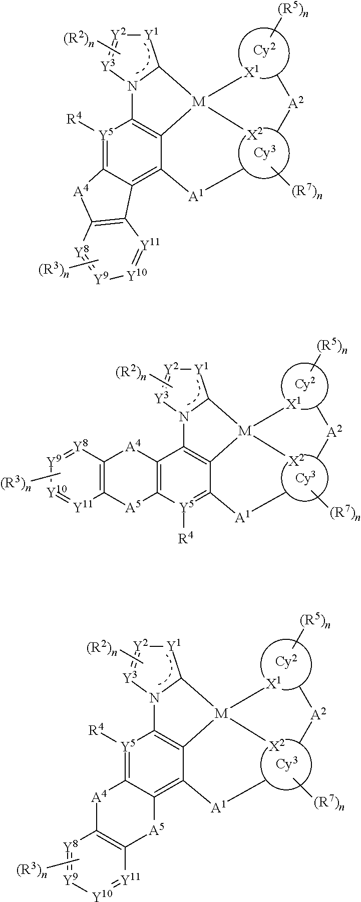

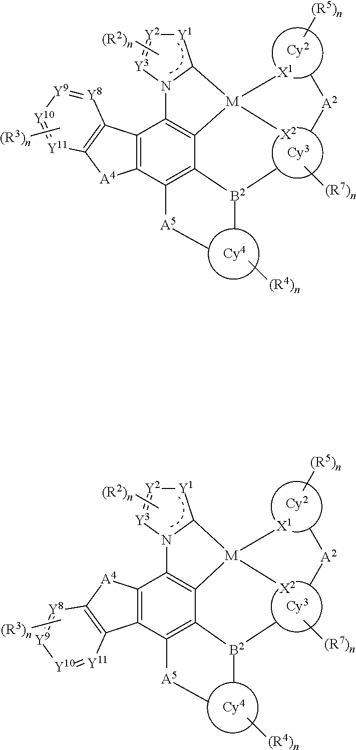

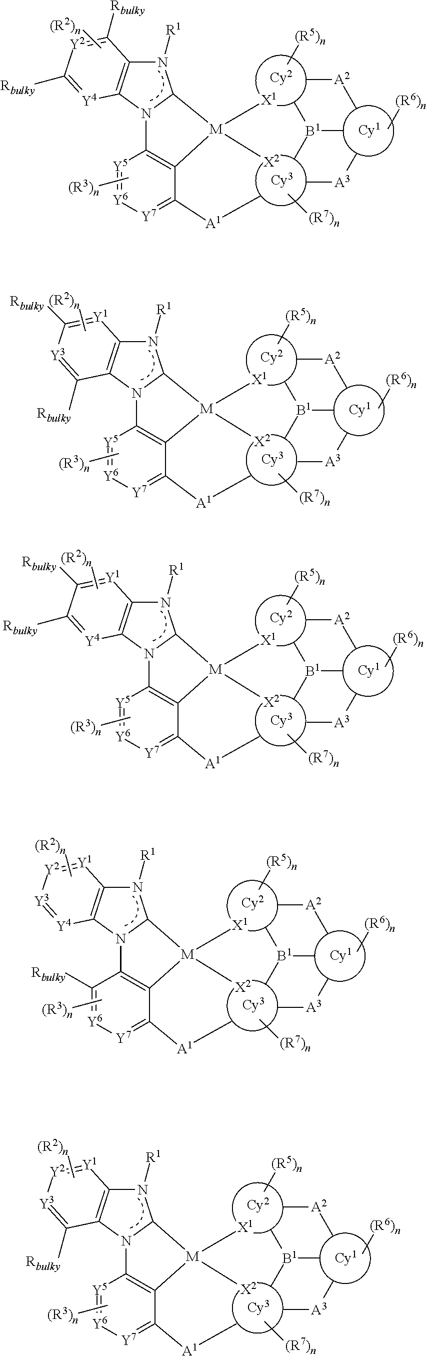

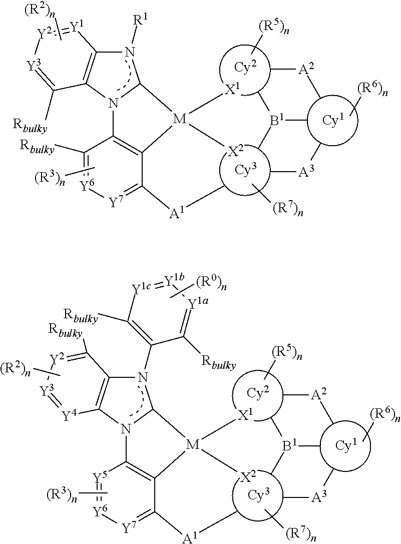

wherein:
M is platinum (Pt) or palladium (Pd);
each of X¹, and X² is coordinated with M and is independently N or C;
each of Y^{1a}, Y^{1b}, Y^{1c}, Y¹, Y², Y³, Y⁴, Y⁵, Y⁶, Y⁷, and Y⁸ is independently N, C, P, O, S, or Si;
each of Cy¹, Cy², Cy³, Cy⁴, and Cy⁵ is independently substituted or unsubstituted aryl, cycloalkyl, cycloalkenyl, heteroaryl, heterocyclyl, carbene, or N-heterocyclic carbene;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

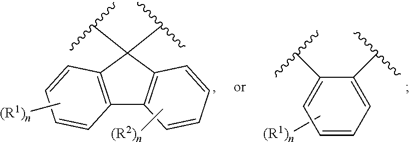

each of B¹ and B² is independently CR¹, SiR¹, GeR¹, N, P, P═O, As, As═O, B, R³Bi═O, or Bi;
R^{bulky} represents R^{X};
each of R¹, R², R³, R⁴, R⁵, R⁶, R⁷, and R⁸ is independently absent or present as a single substituent or multiple substituents, valency permitting, and each R¹, R², R³, R⁴, R⁵, and R⁶ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by one of the following structures, which together represent LIST 7:

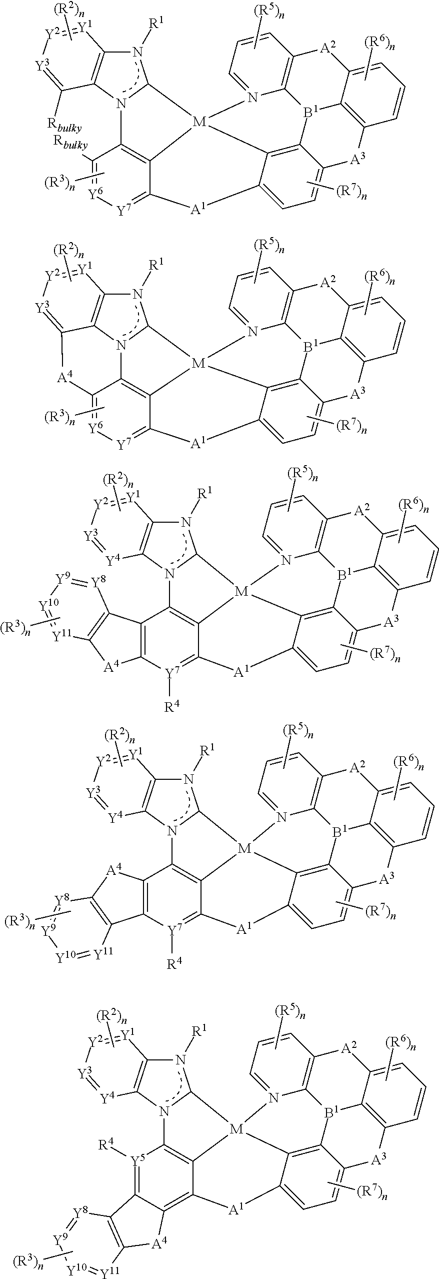

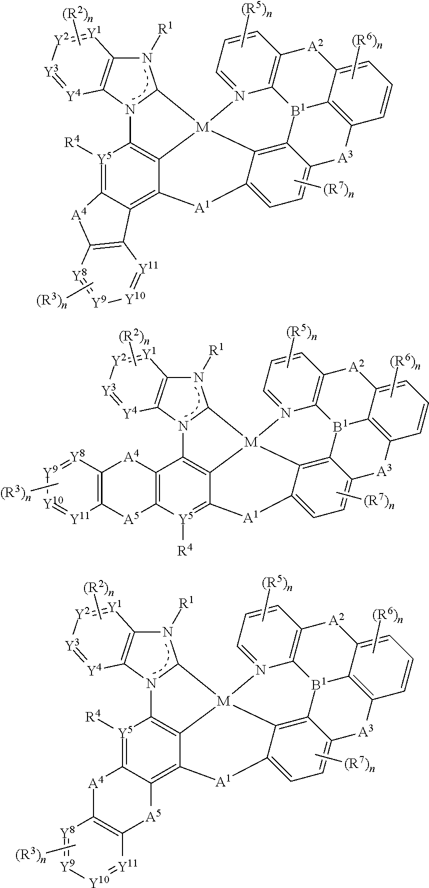

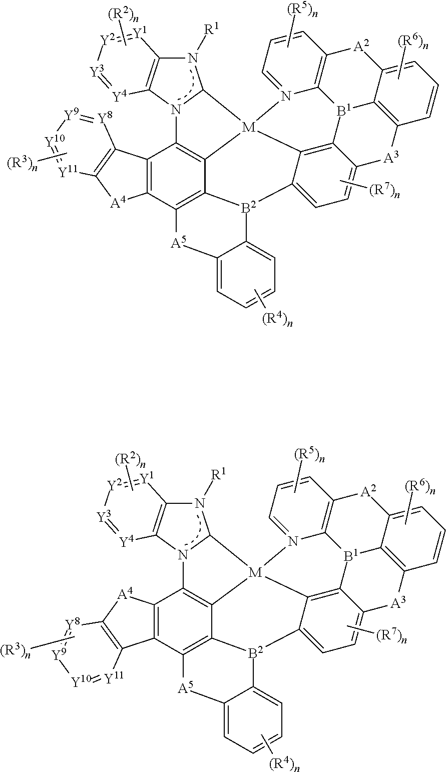

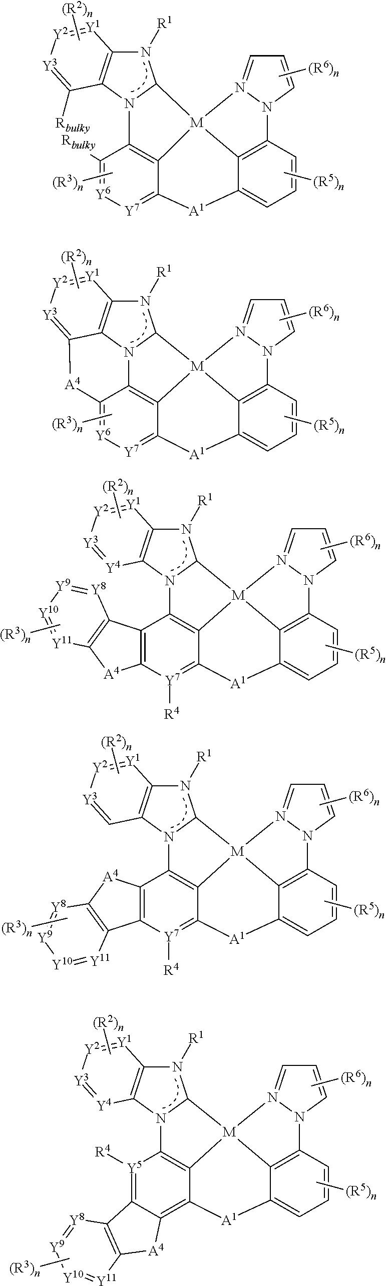

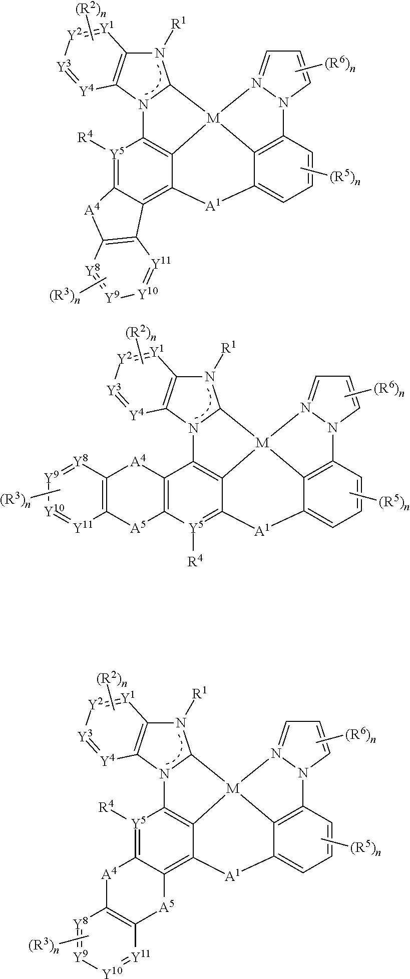

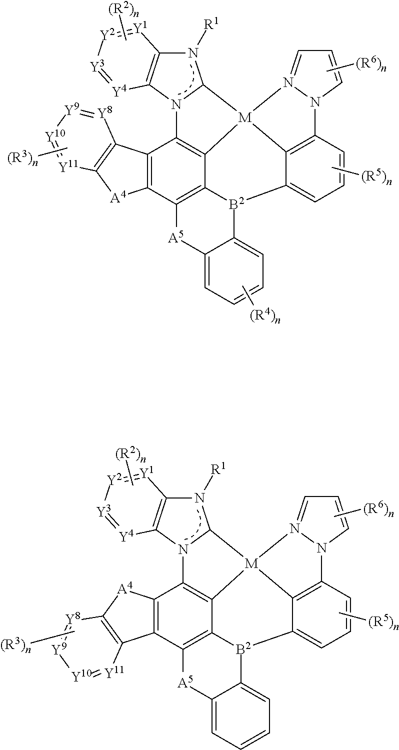

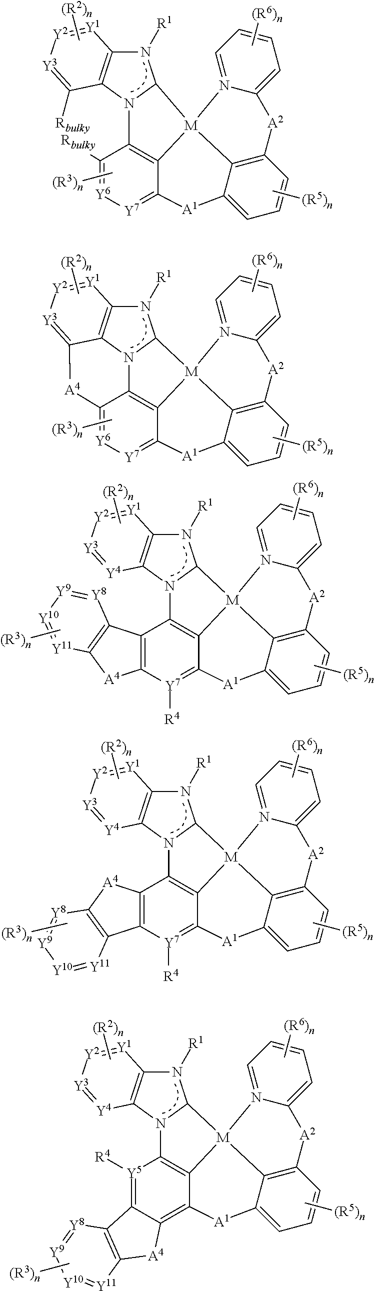

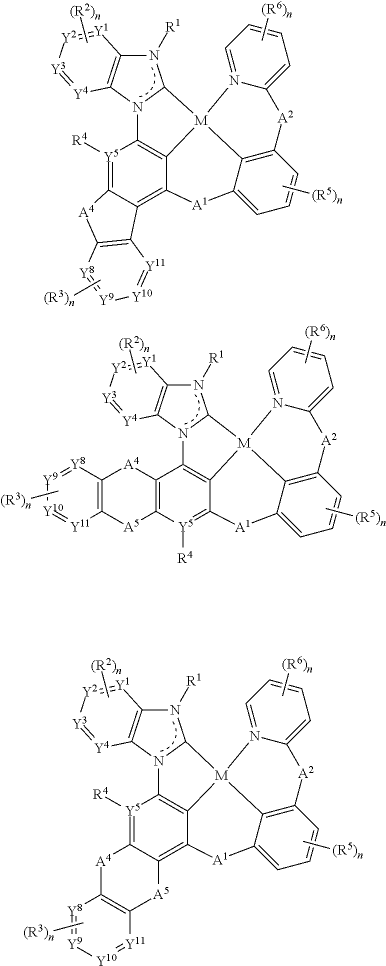

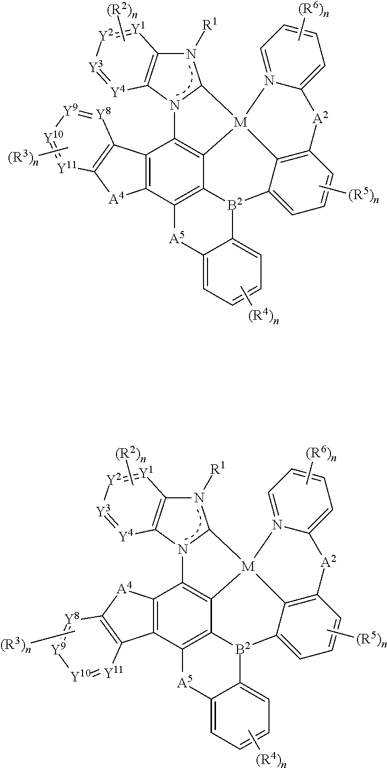

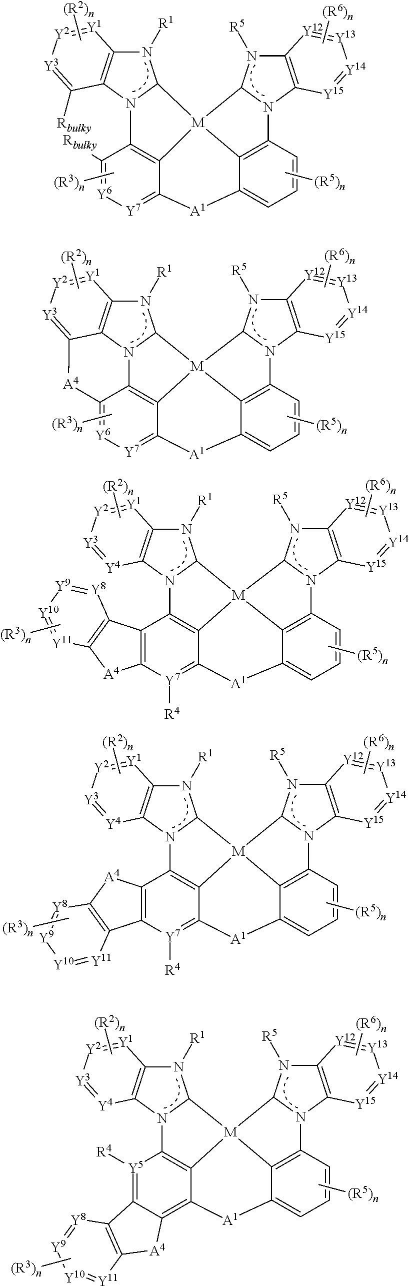

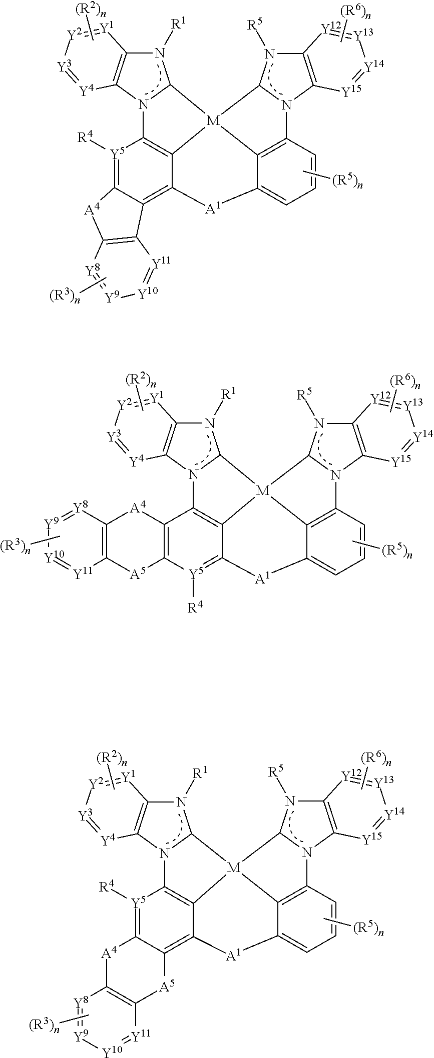

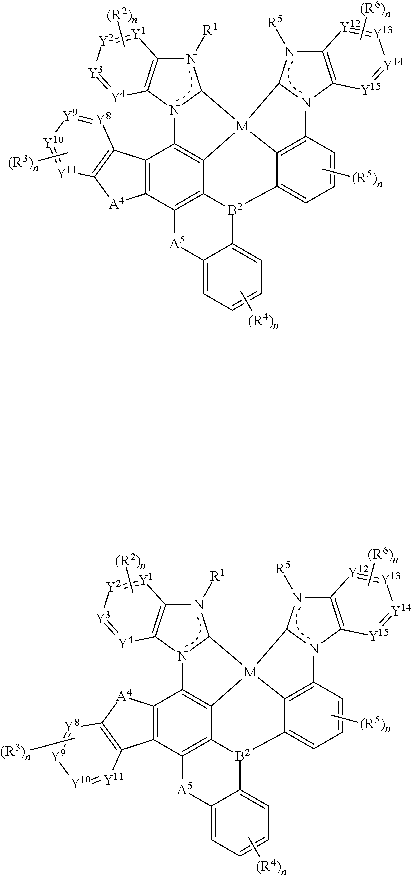

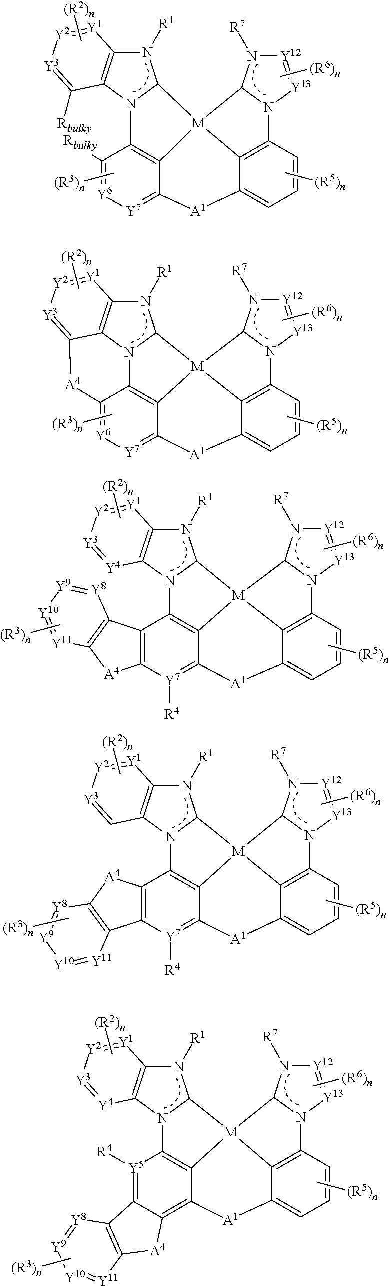

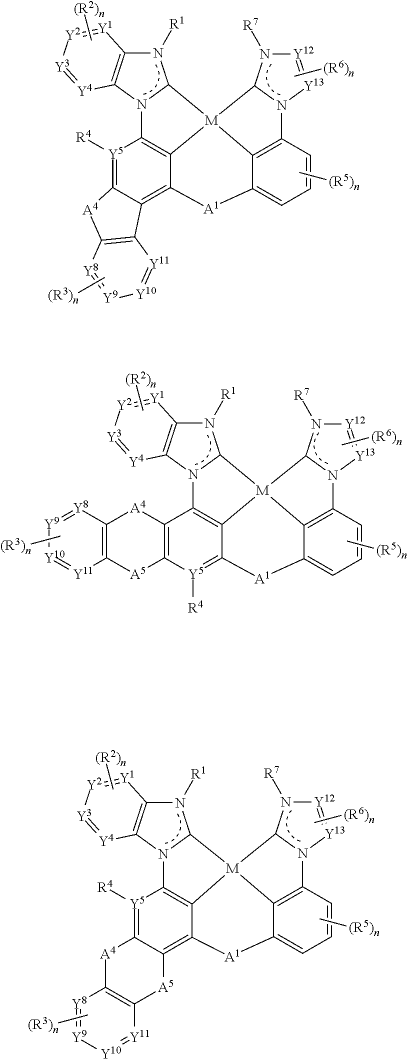

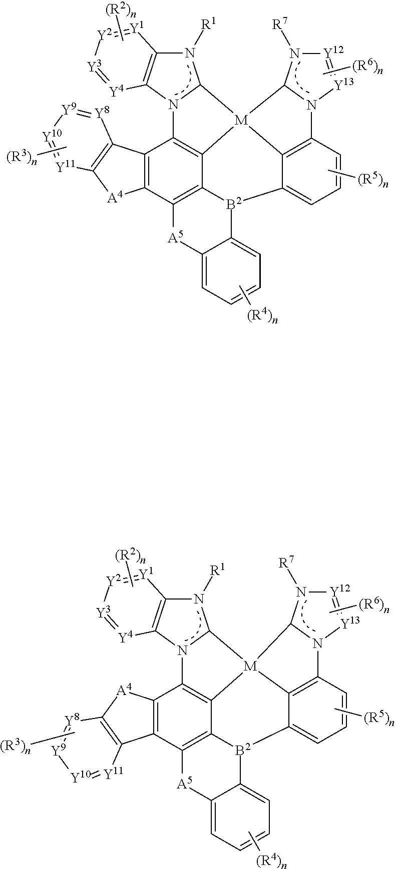

wherein:
M is platinum (Pt) or palladium (Pd);
each of Y¹, Y², Y³, Y⁴, Y⁵, Y⁶, Y⁷, Y⁸, Y⁹, Y¹⁰, Y¹¹, Y¹², Y¹³, Y¹⁴, and Y¹⁵ is independently N, C, P, O, S, or Si;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

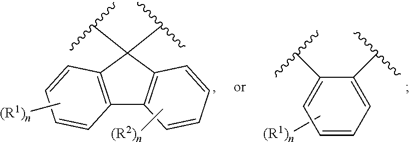

each of B¹, B², and B³ is independently CR¹, SiR¹, GeR¹, N, P, P═O, As, As═O, B, R³Bi═O, or Bi;
R^{bulky} represents R^{X};
each of R¹, R², R³, R⁴, R⁵, R⁶, R⁷, and R⁸ is independently absent or present as a single substituent or multiple substituents, valency permitting, and each R¹, R², R³, R⁴, R⁵, and R⁶ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by one of the following structures, which together represent LIST 7A:

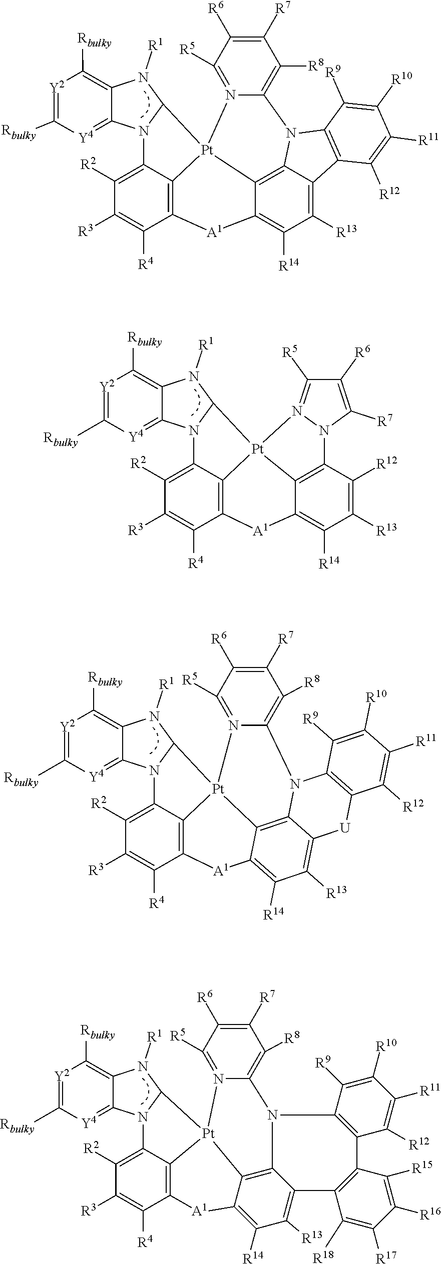

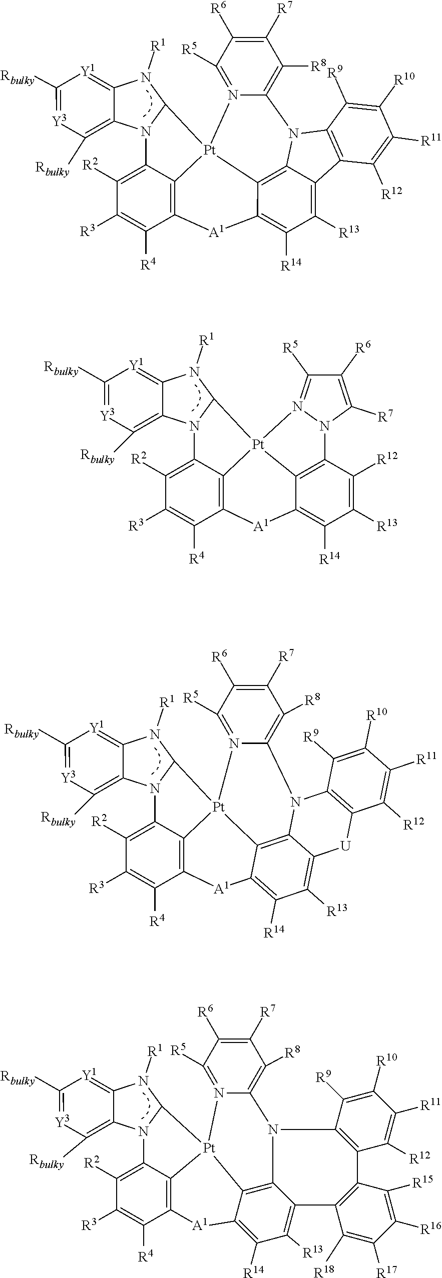

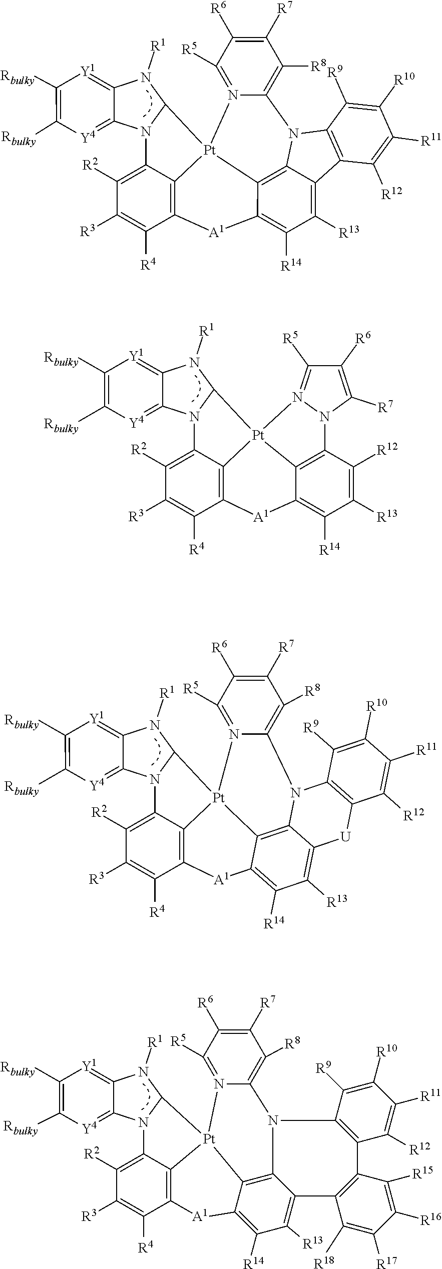

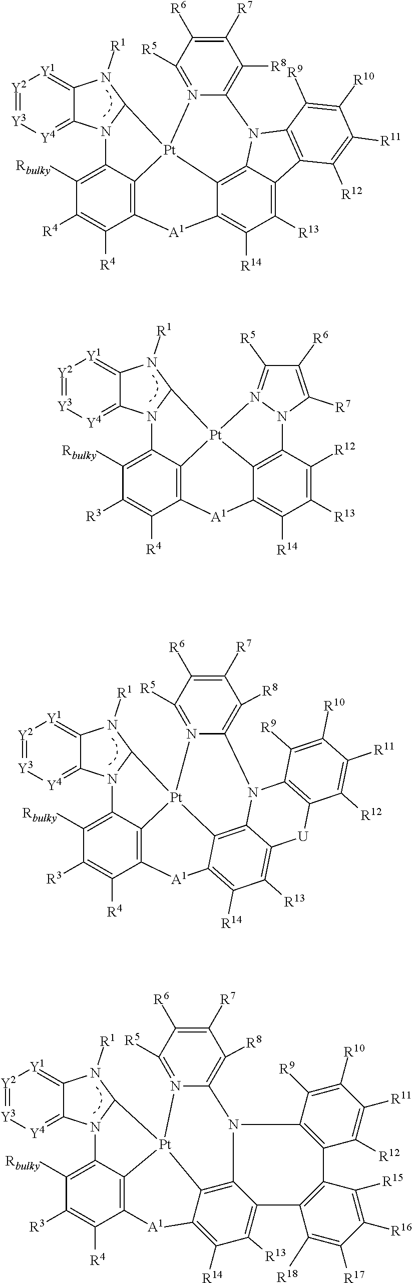

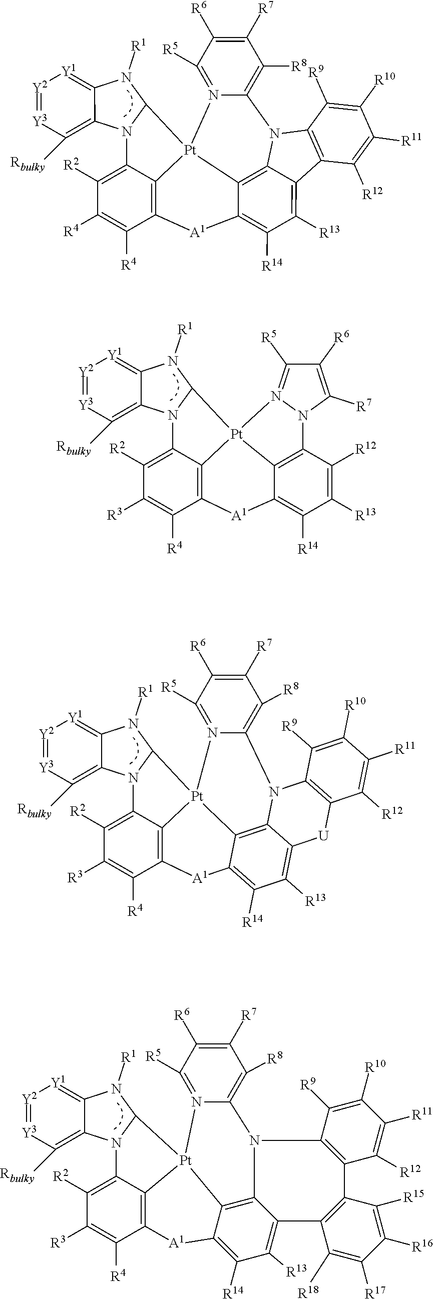

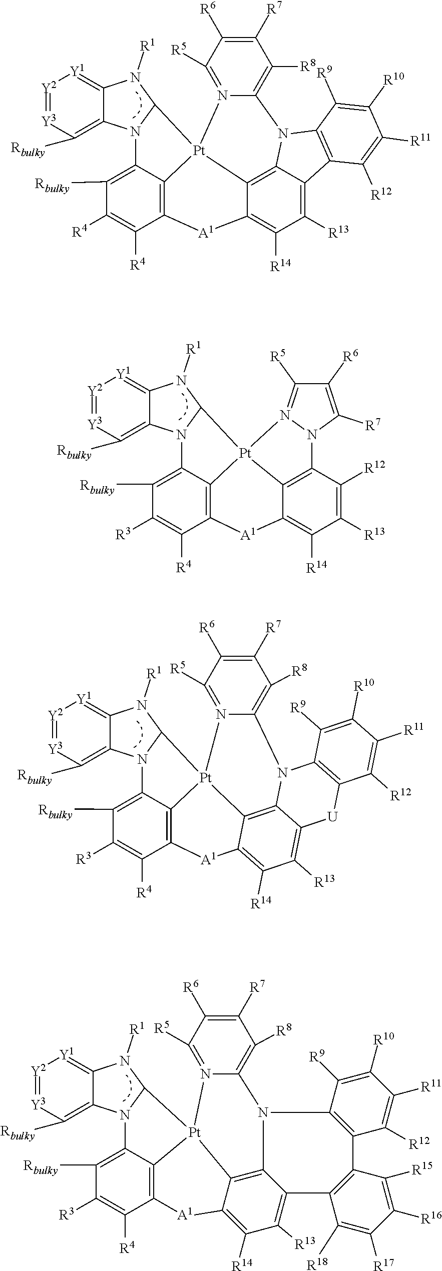

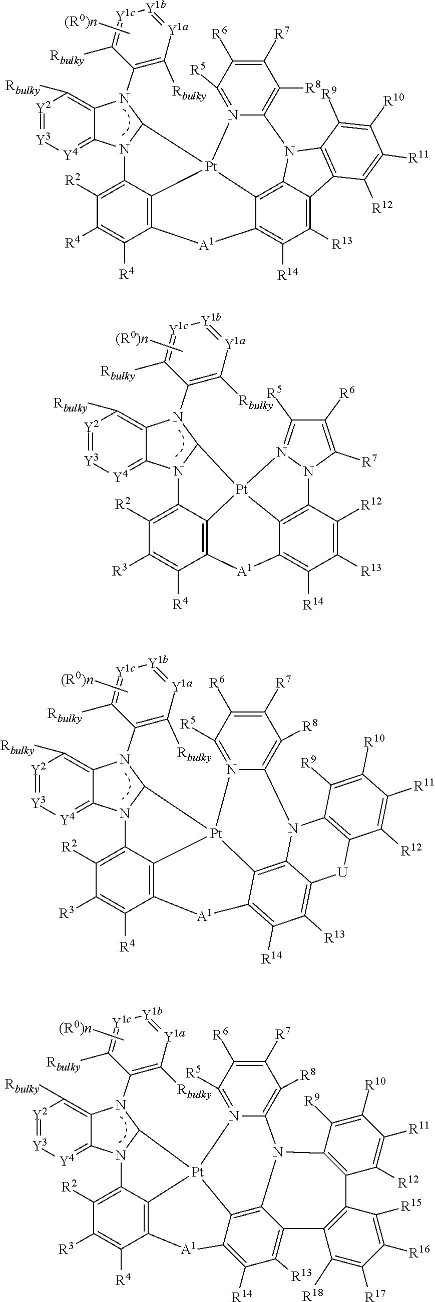

wherein:
each Y^{1a}, Y^{1b}, Y^{1c}, Y¹, Y², Y³, Y⁴, Y⁵, Y⁶, and Y⁷ is independently N, C, P, O, S, or Si;
A¹ is absent or present; wherein if present A¹ represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

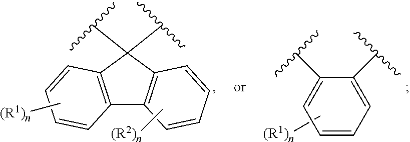

R^{bulky} represents R^{X};
each of R⁰, R¹, R², R³, R⁴, R⁵, R⁶, R⁷, R⁸, R⁹, R¹⁰, R¹¹, R¹², R¹³, R¹⁴, R¹⁵, R¹⁶, R¹⁷, and R¹⁸ is independently absent or present as a single substituent or multiple substituents, valency permitting, and each R⁰, R¹, R², R³, R⁴, R⁵, R⁶, R⁷, R⁸, R⁹, R¹⁰, R¹¹, R¹², R¹³, R¹⁴, R¹⁵, R¹⁶, R¹⁷, and R¹⁸ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted;
U represents CR¹R², C═O, C═S, SiR¹R², GER¹R², NR³, PR³, R³P═O, AsR³, R³As═O, O, S, S═O, SO₂, Se, Se═O, SeO₂, BR³, BiR³, R³Bi═O,

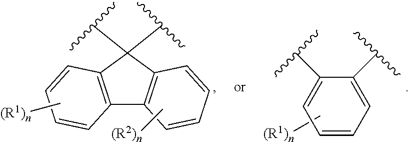

In one embodiment, A¹ is not present; Cy¹ is heteroaryl; X¹ is N; and two adjacent substituents R¹, two adjacent substituents R², two adjacent substituents R³, or two adjacent substituents R⁷ are present and together represent a group of Formula C.

In one embodiment, the compound is represented by one of the following structures, which together represent LIST 8:

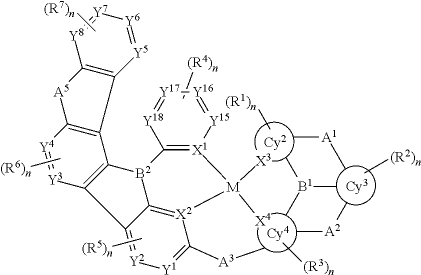

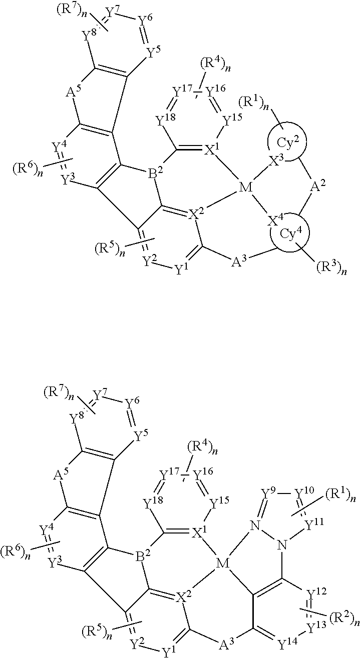

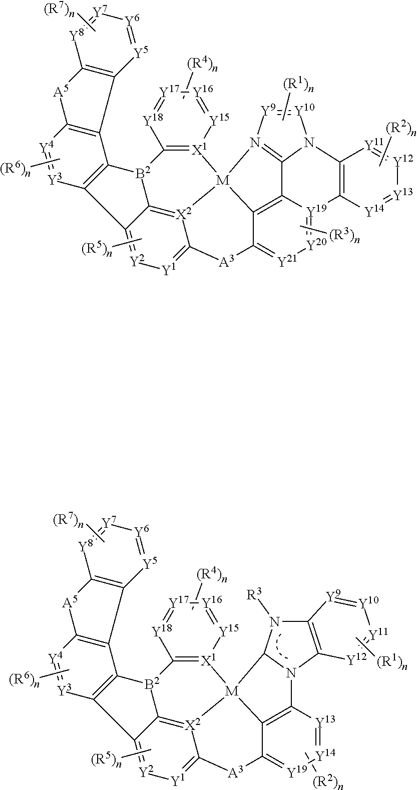

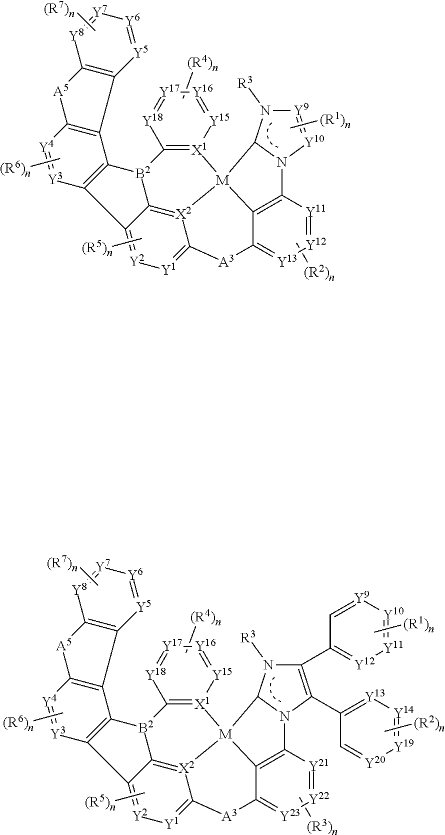

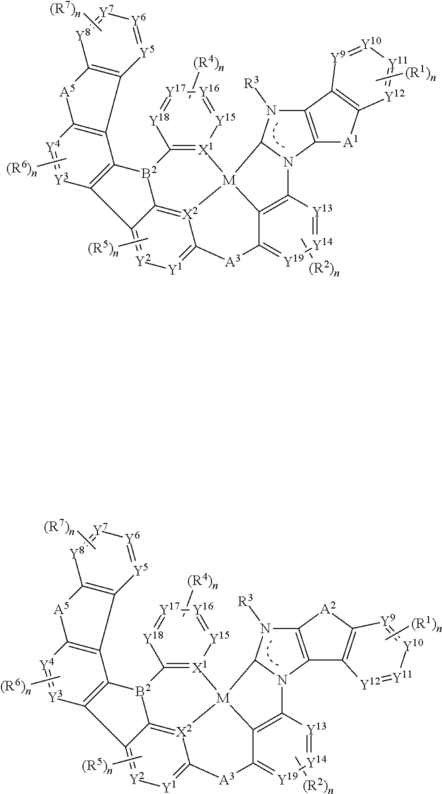

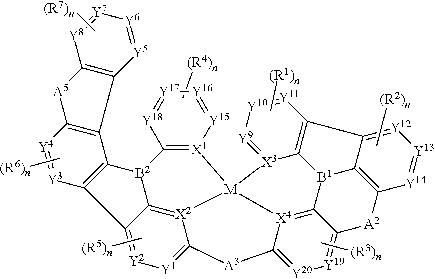

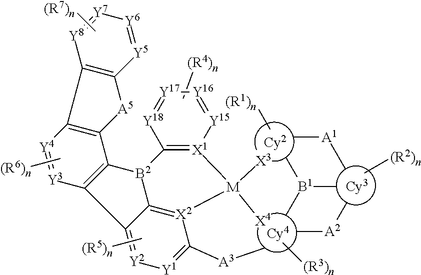

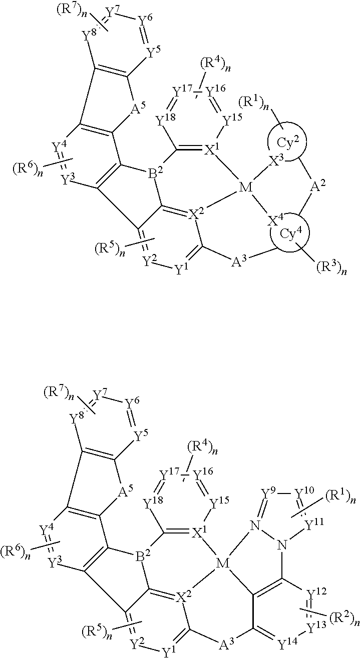

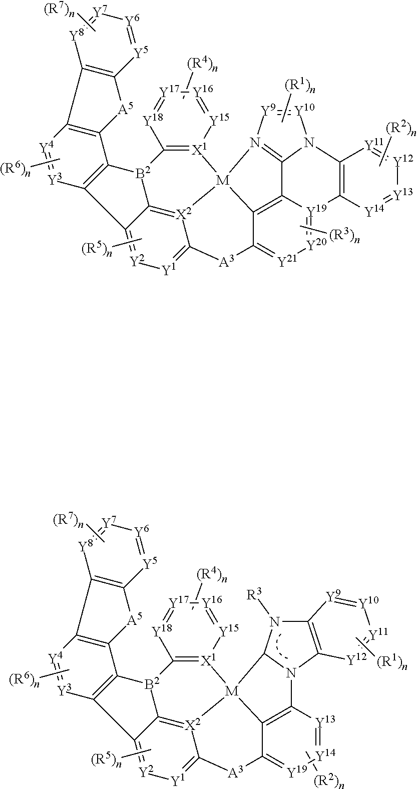

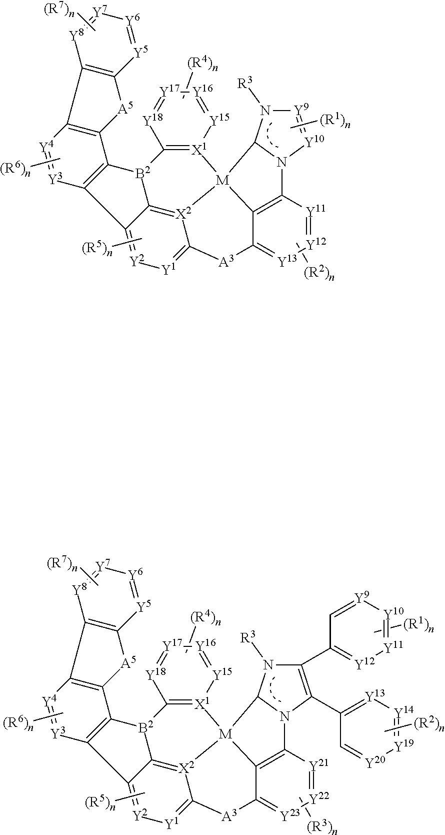

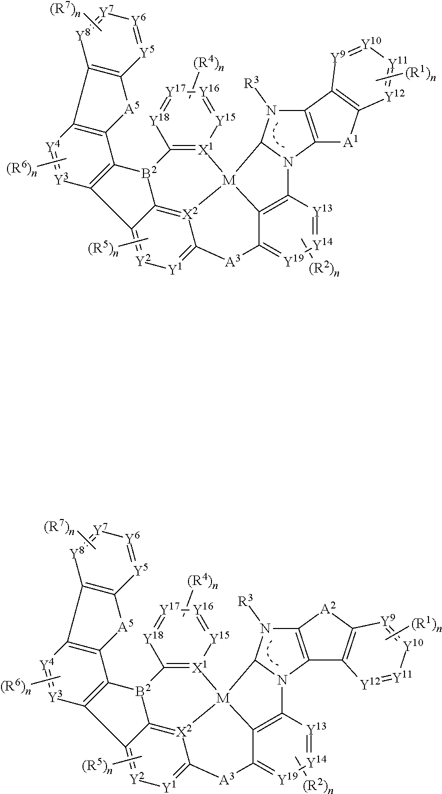

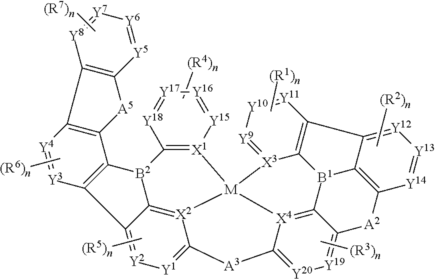

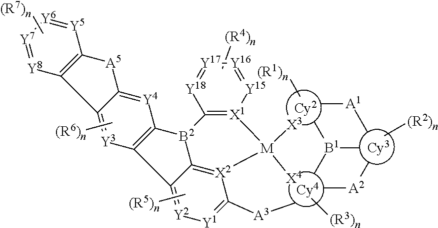

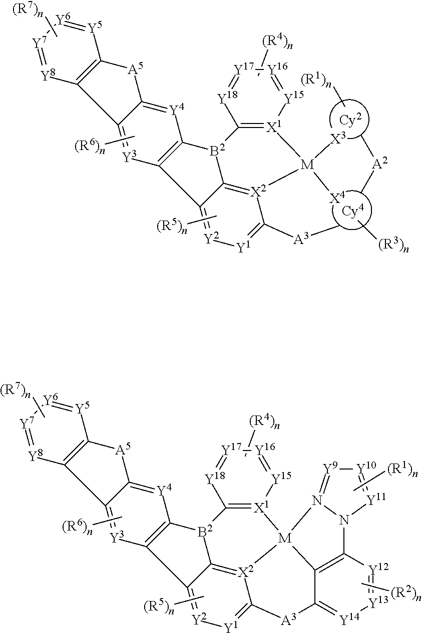

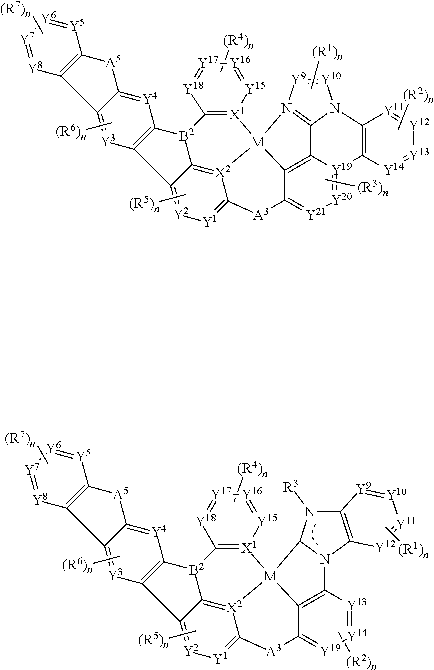

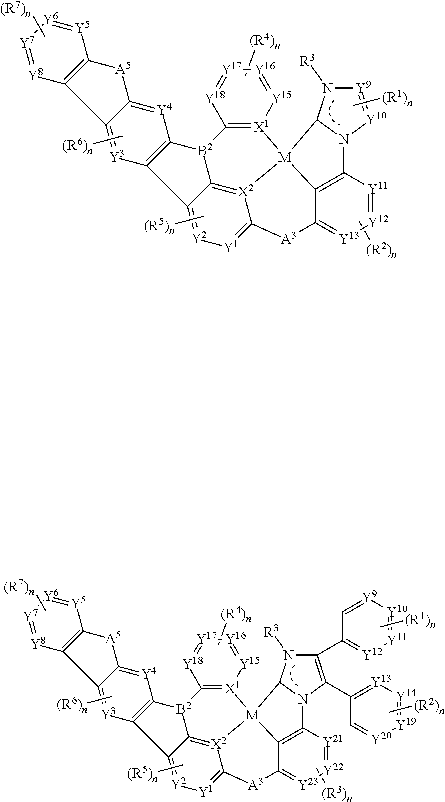

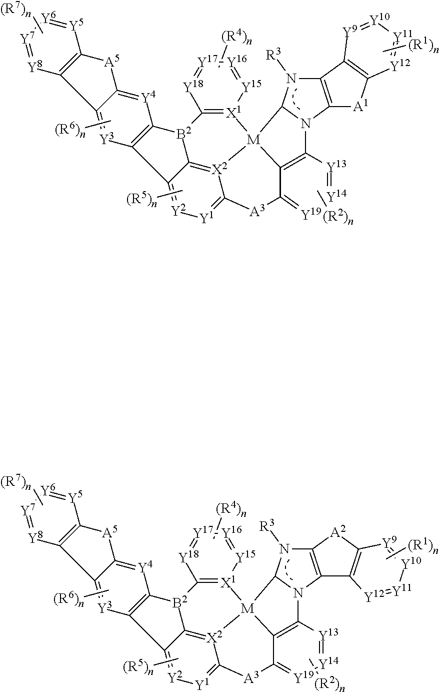

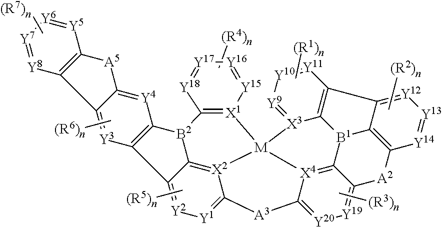

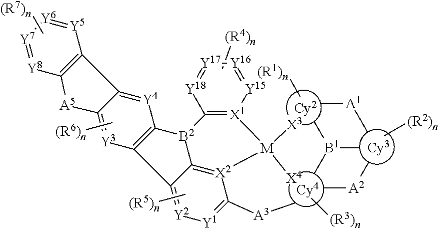

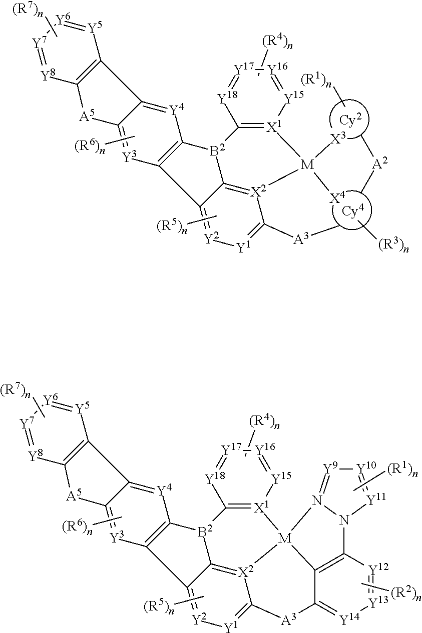

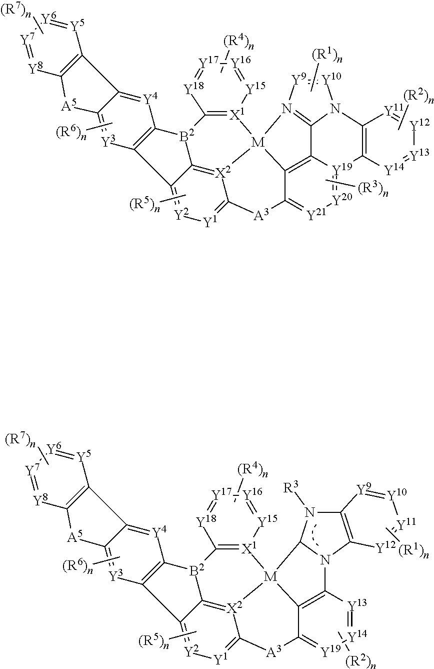

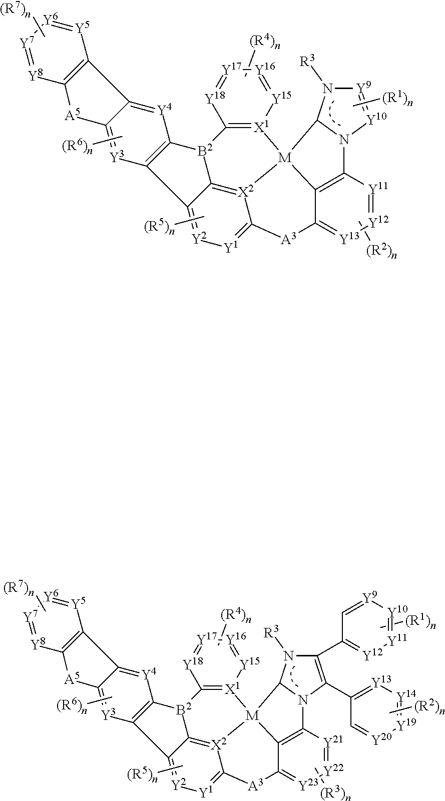

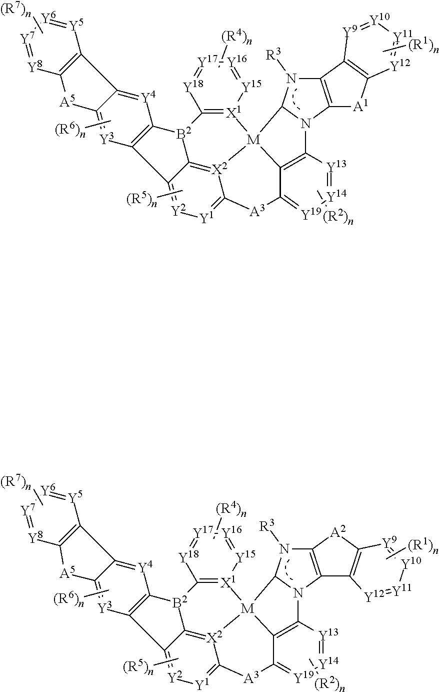

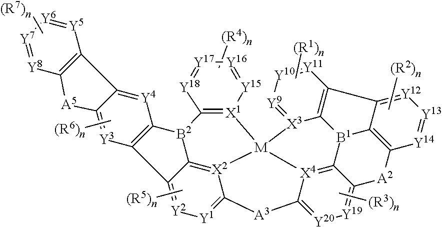

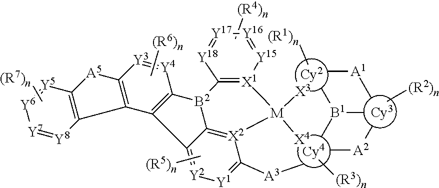

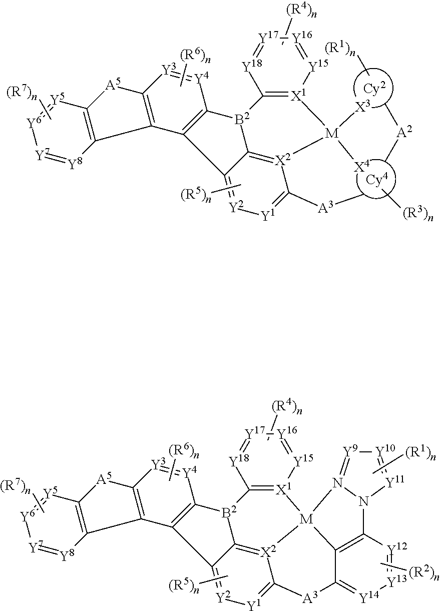

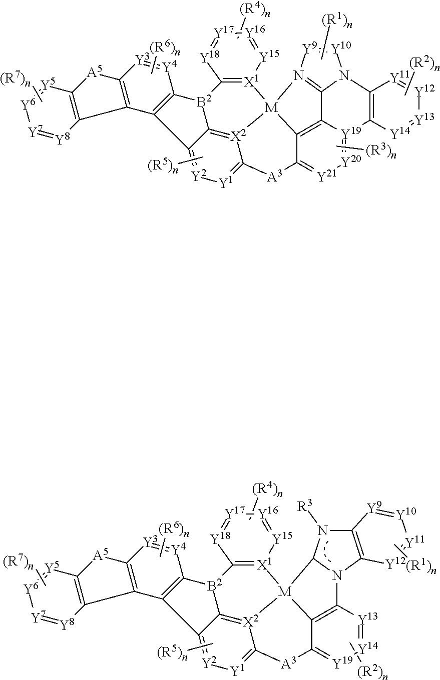

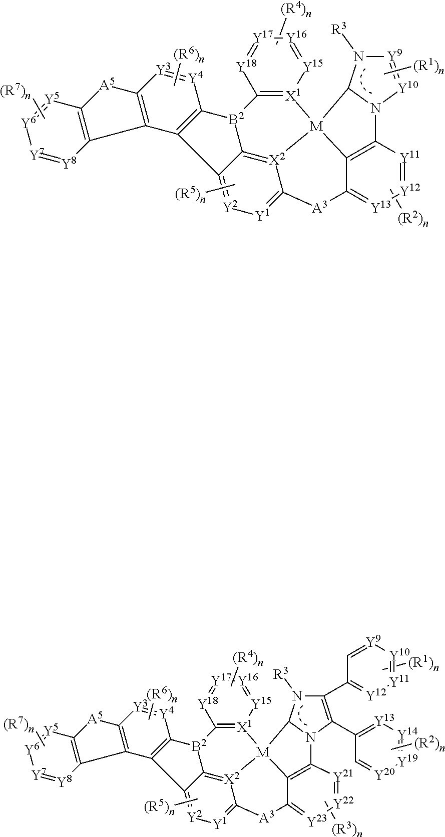

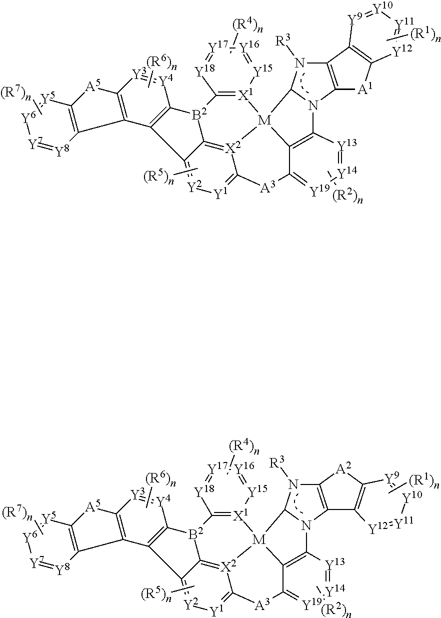

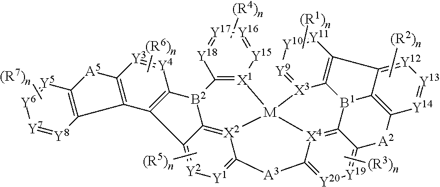

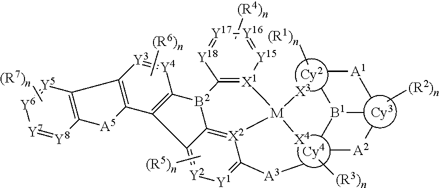

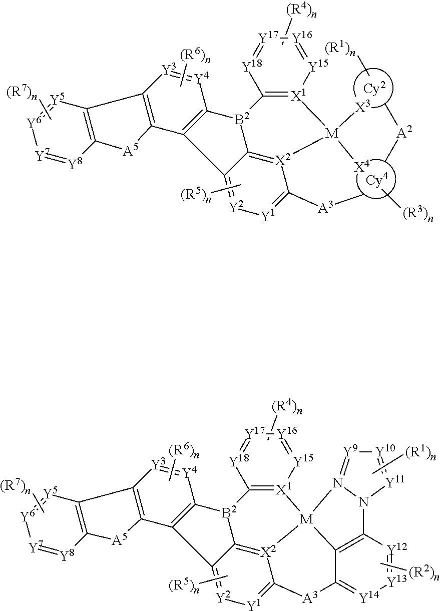

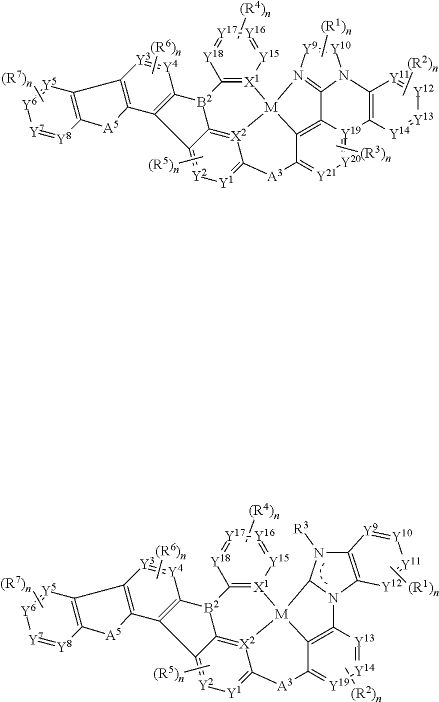

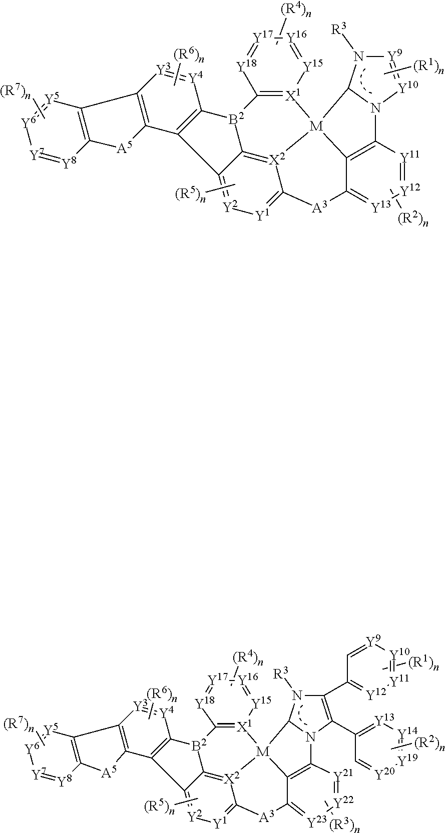

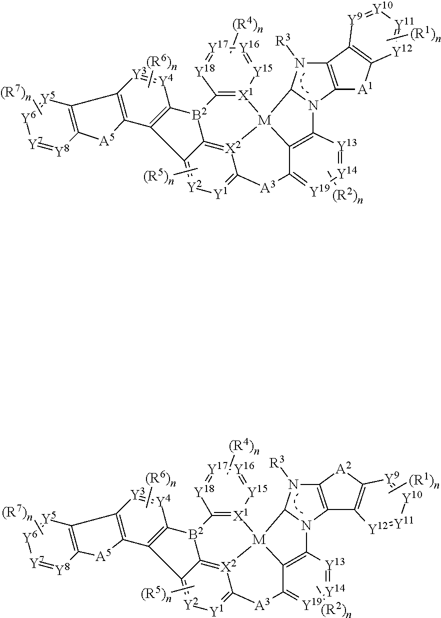

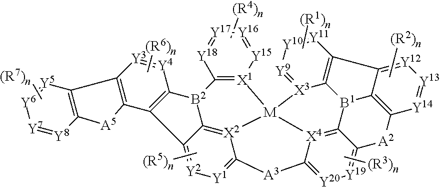

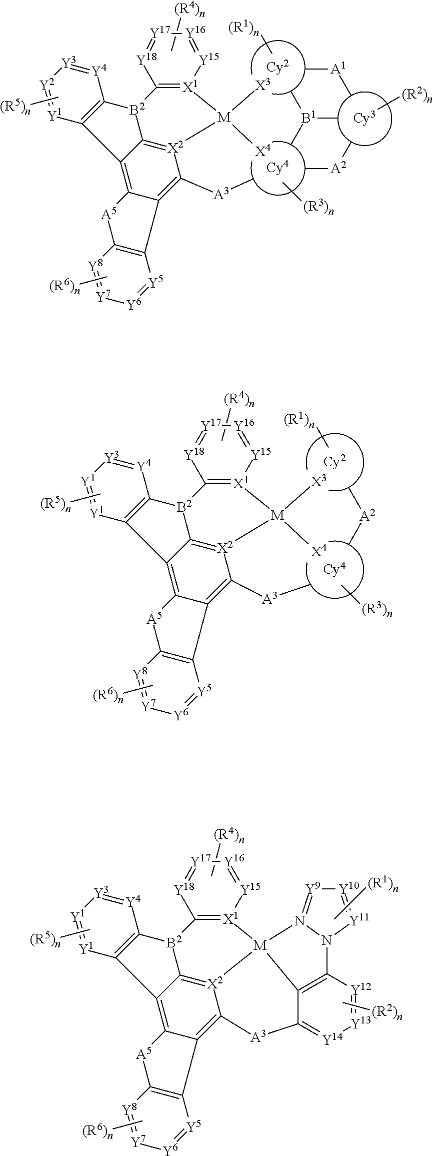

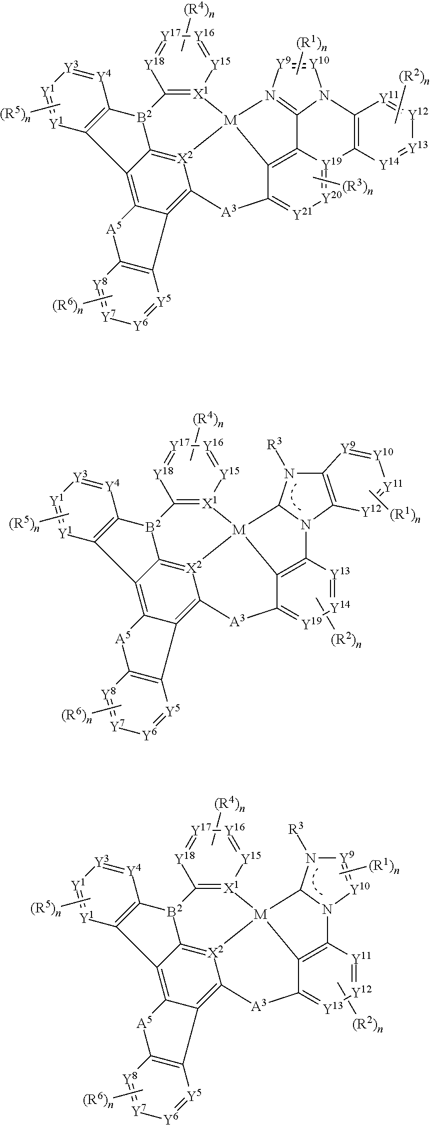

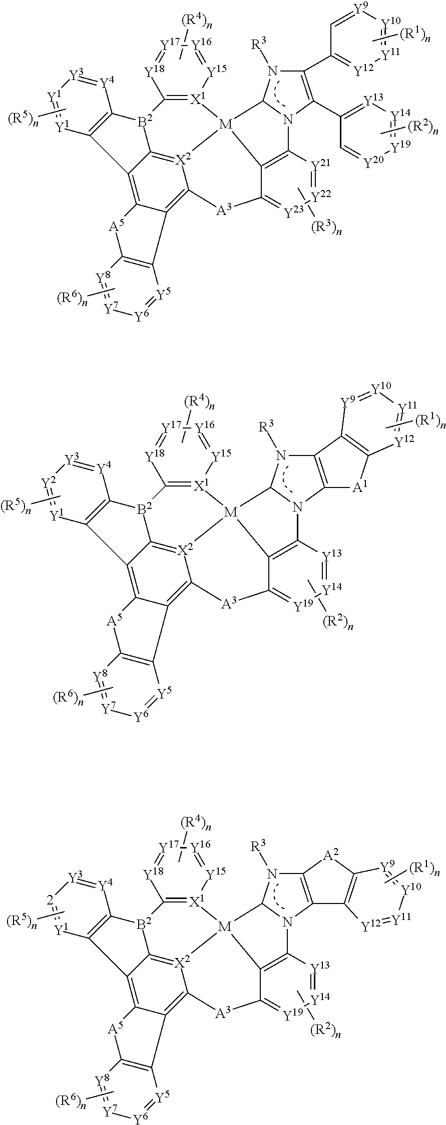

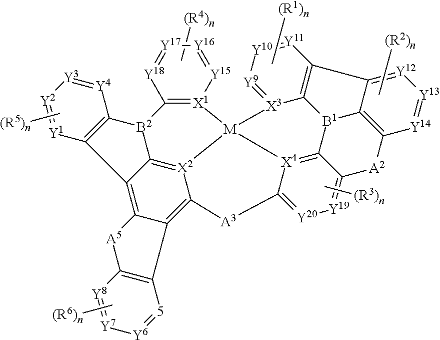

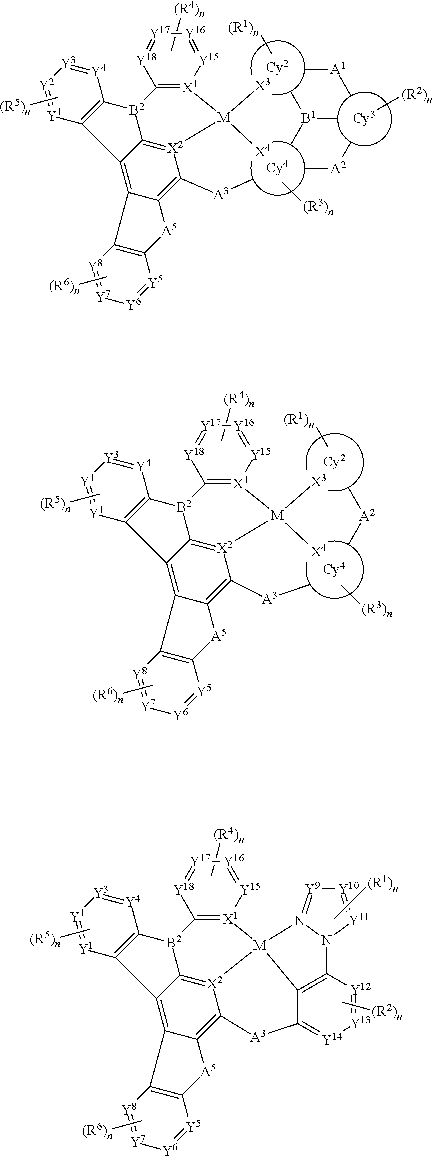

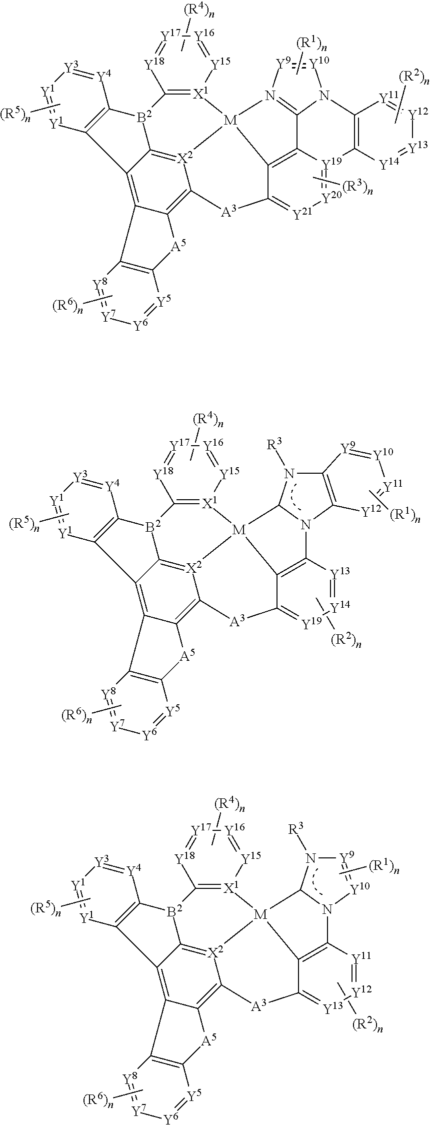

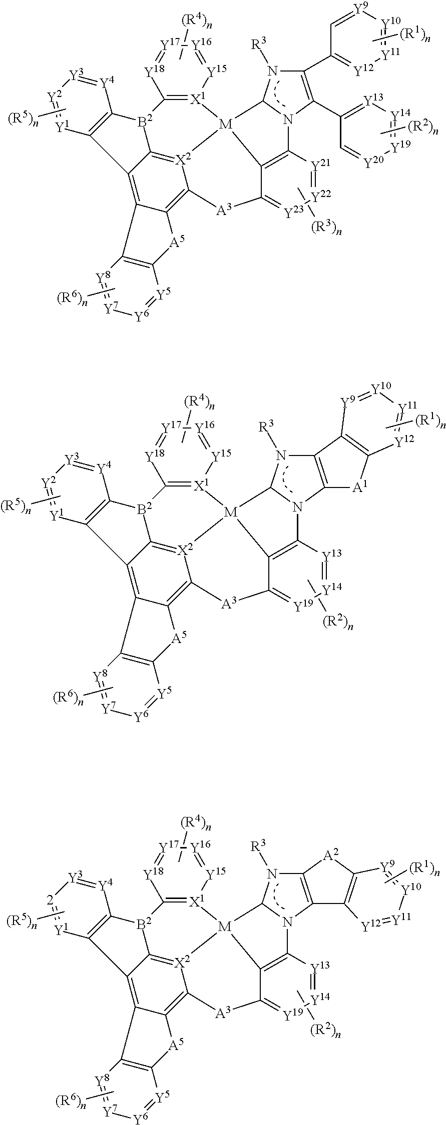

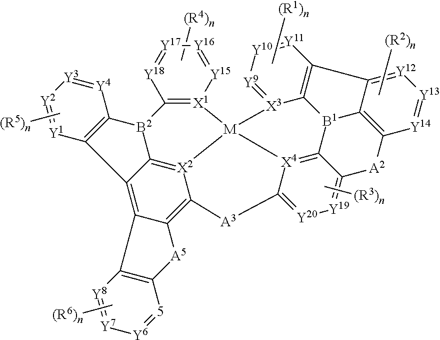

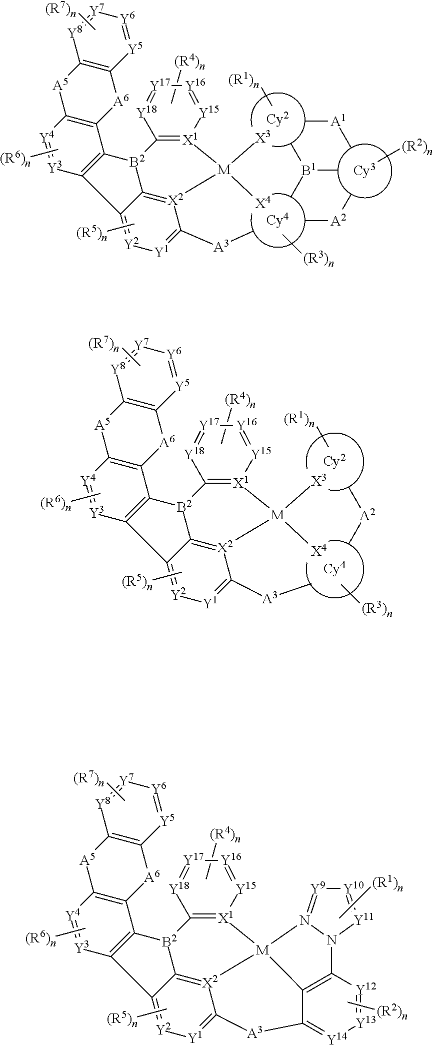

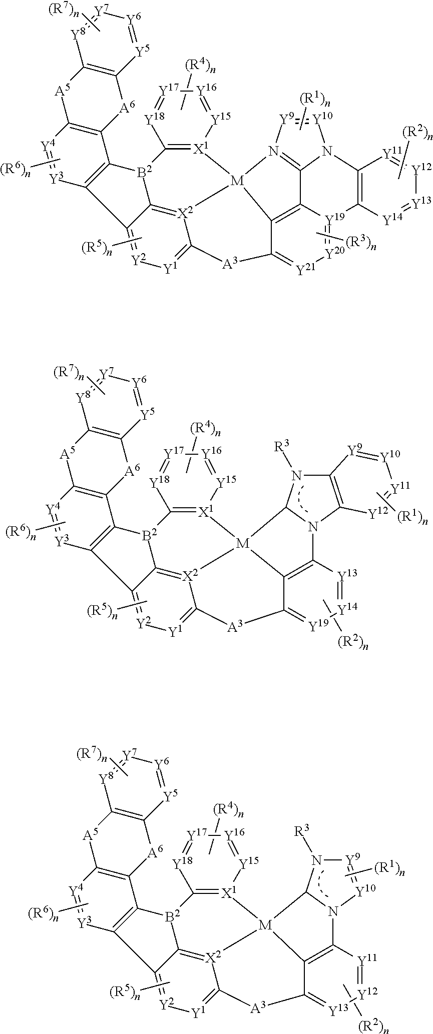

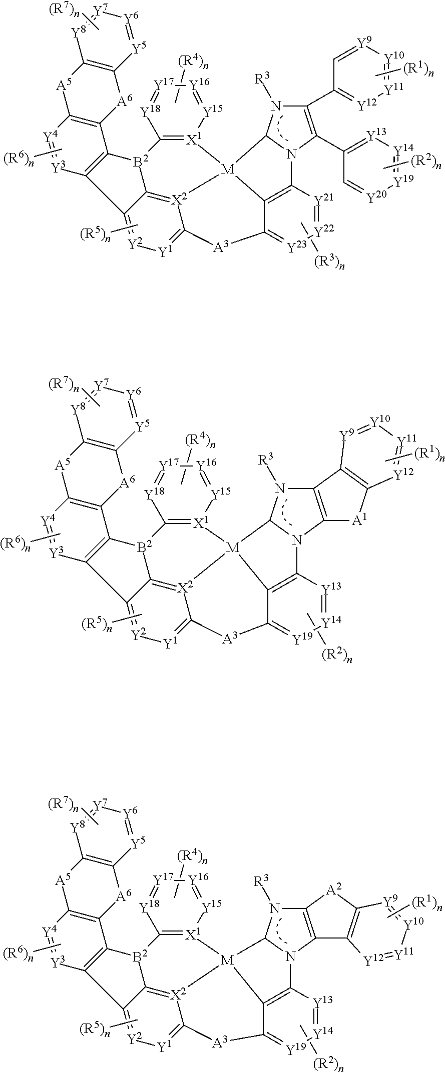

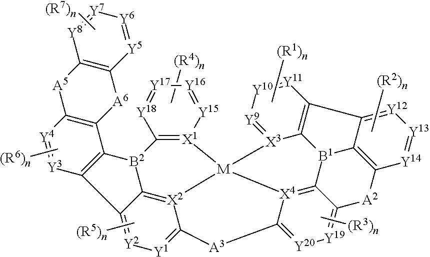

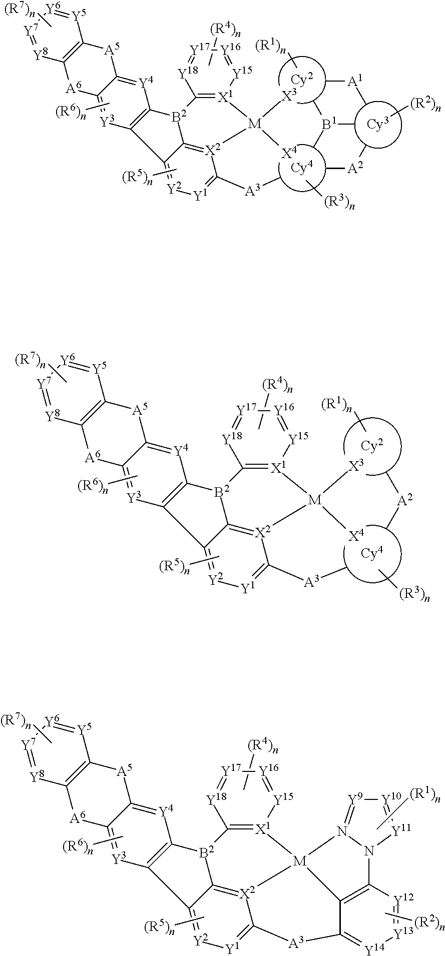

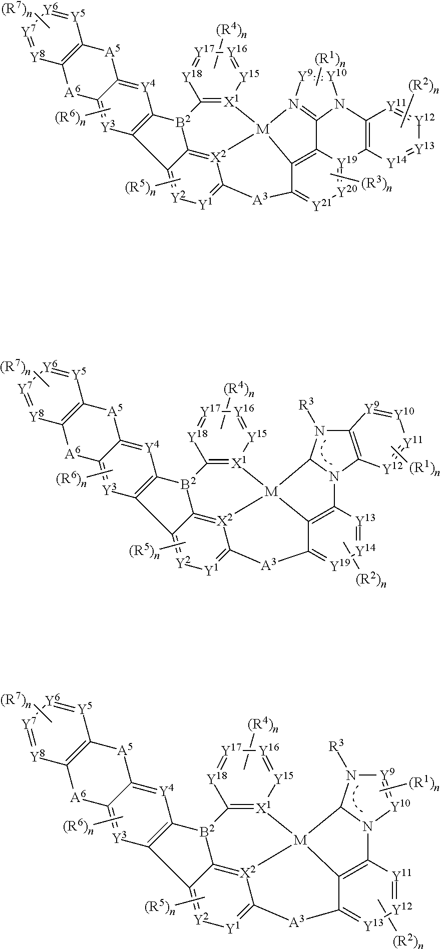

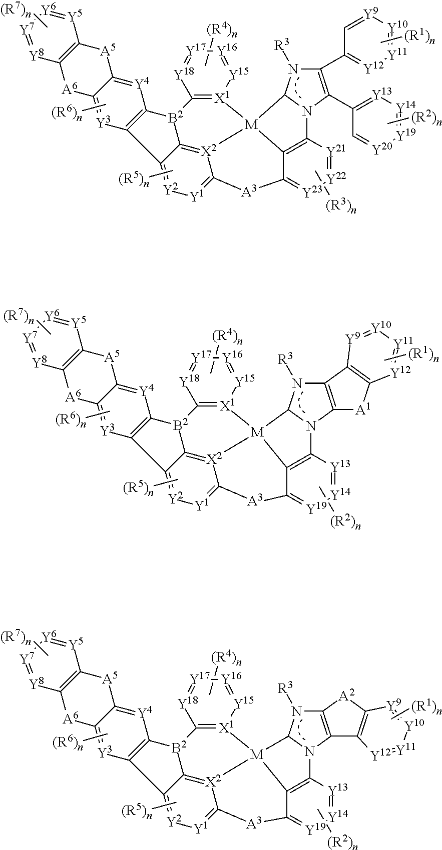

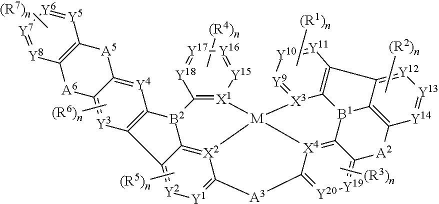

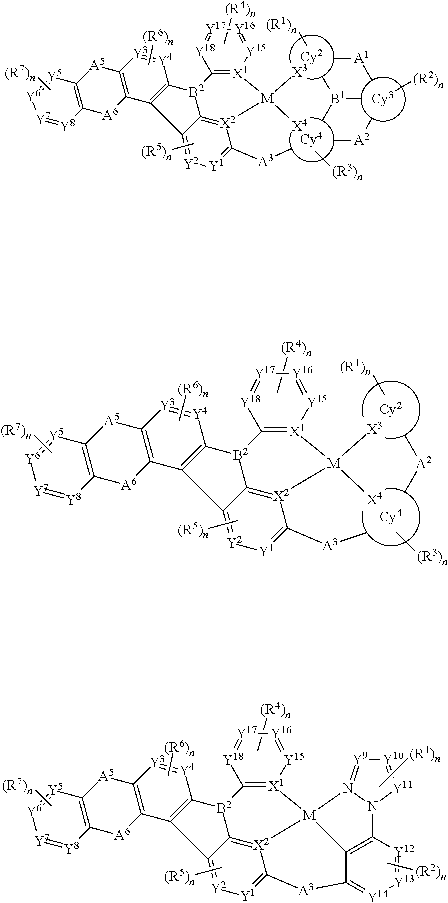

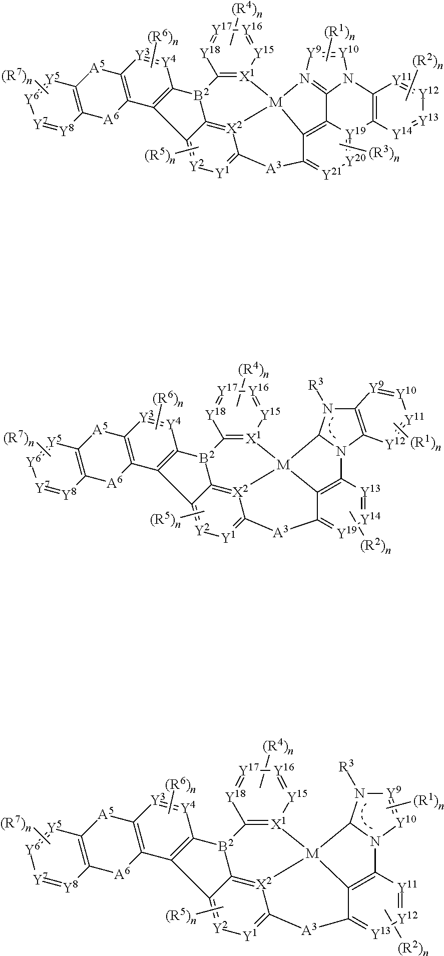

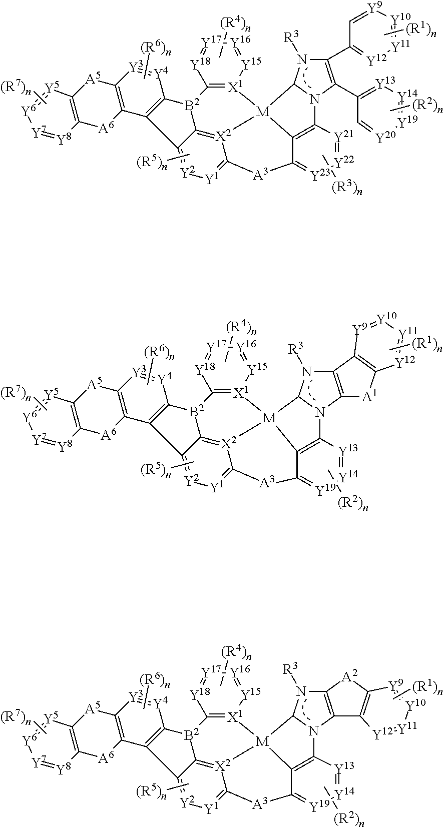

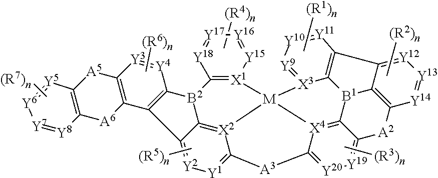

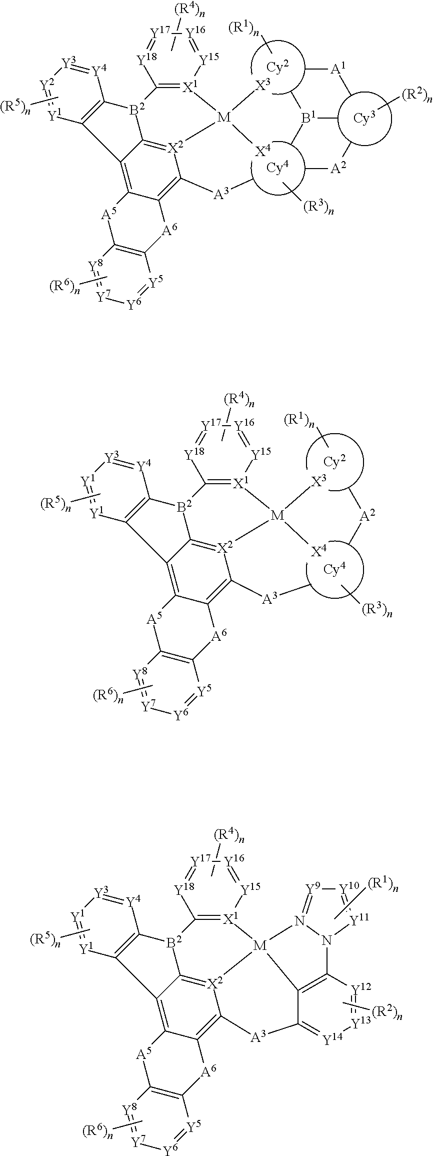

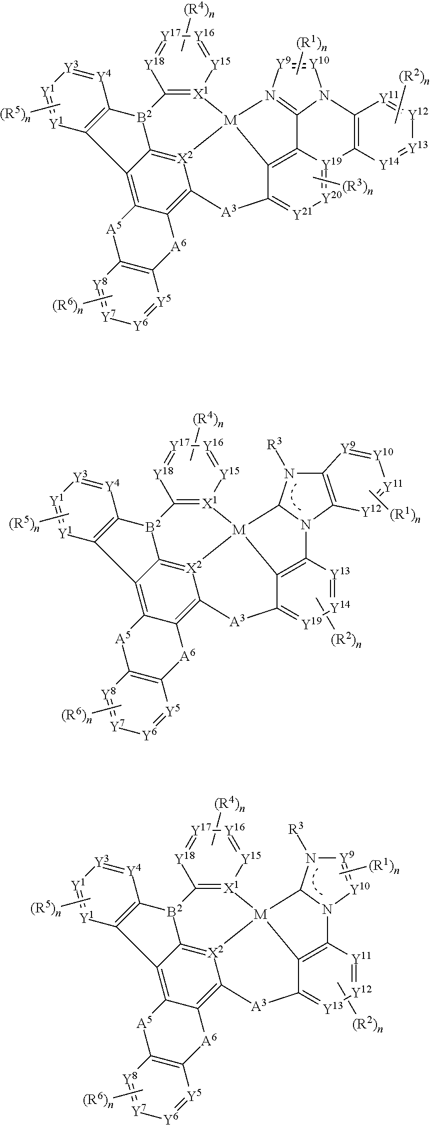

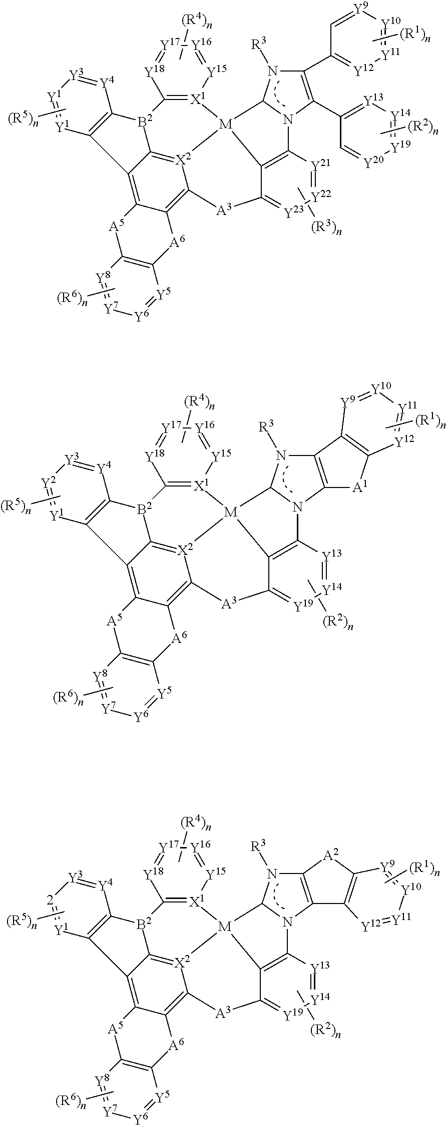

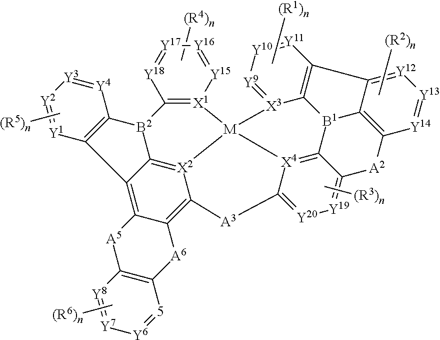

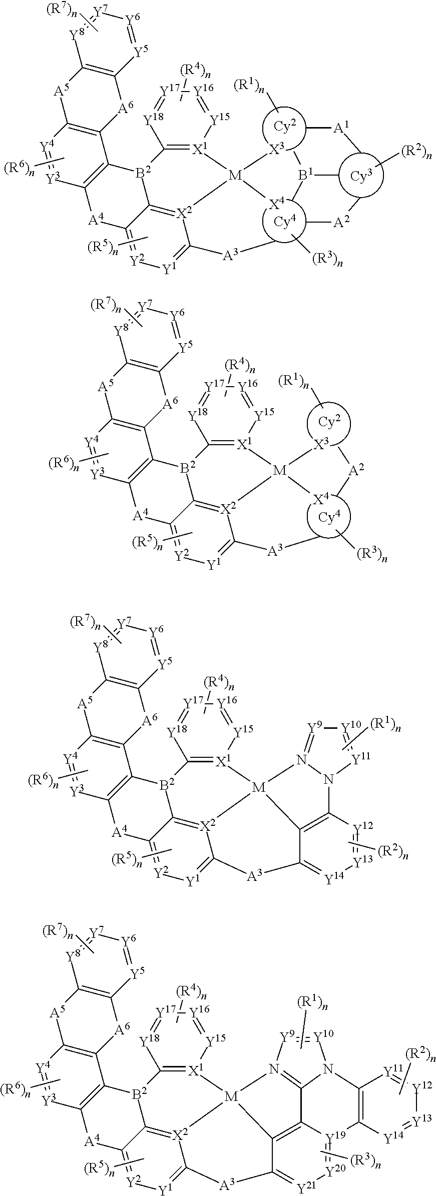

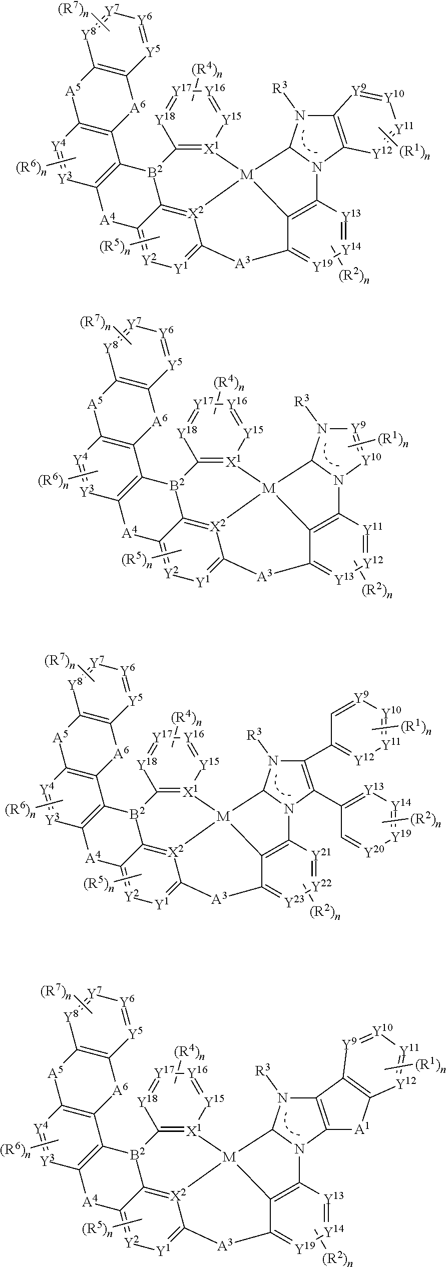

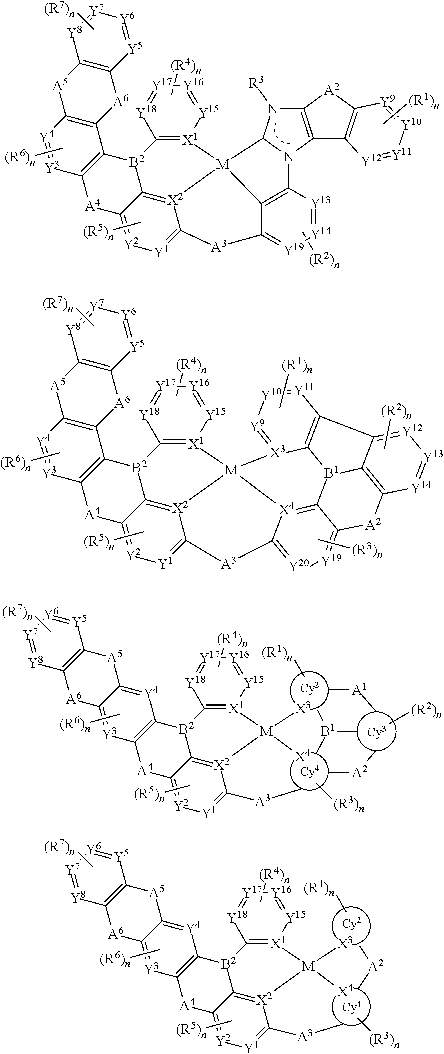

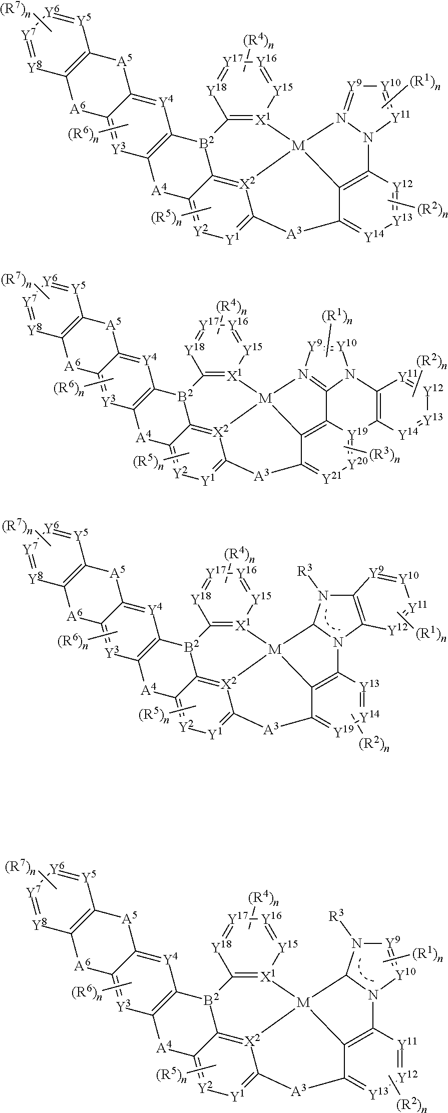

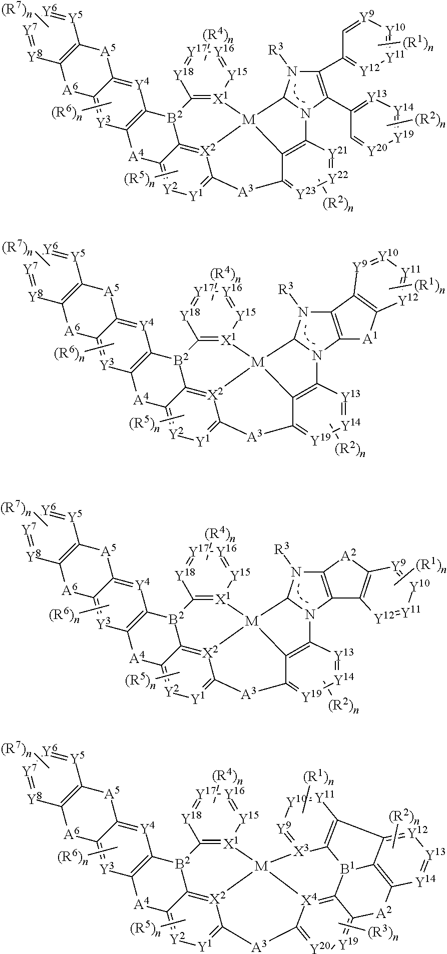

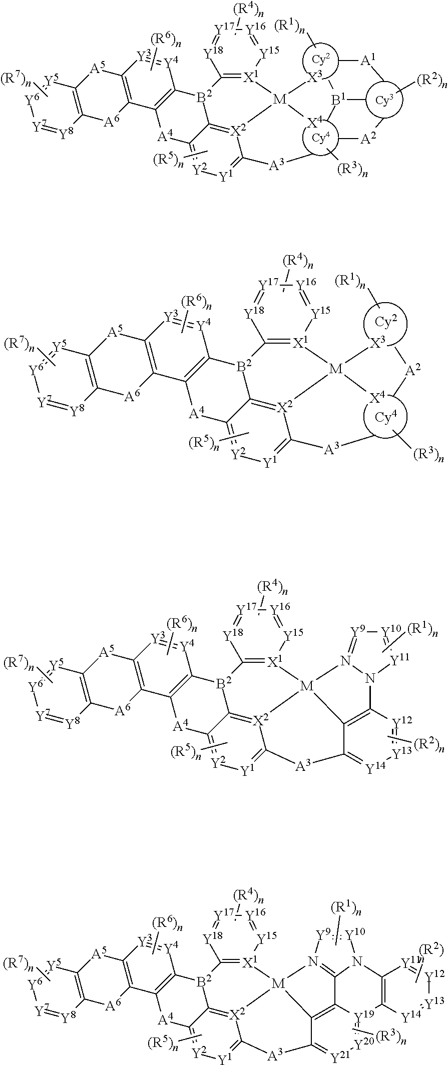

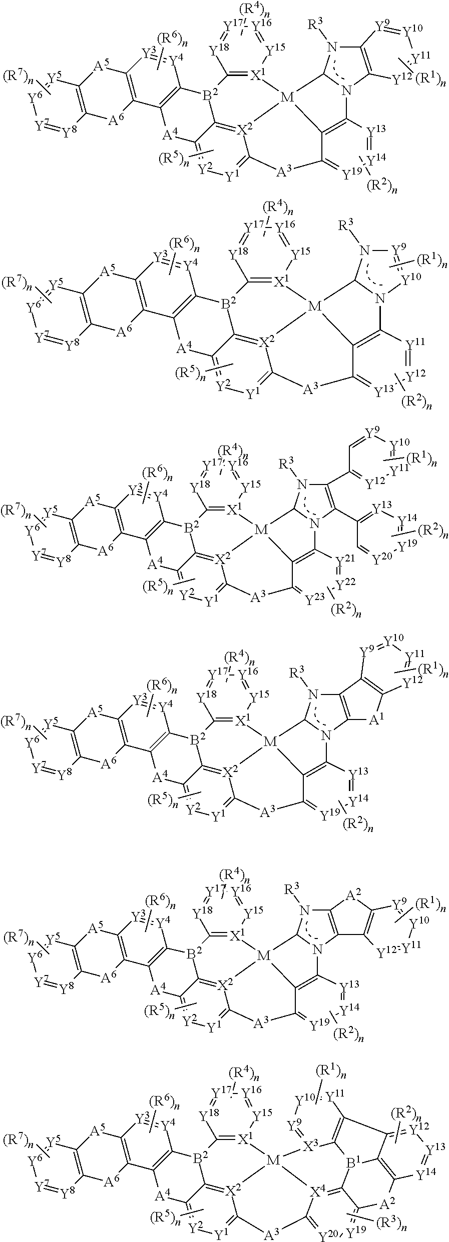

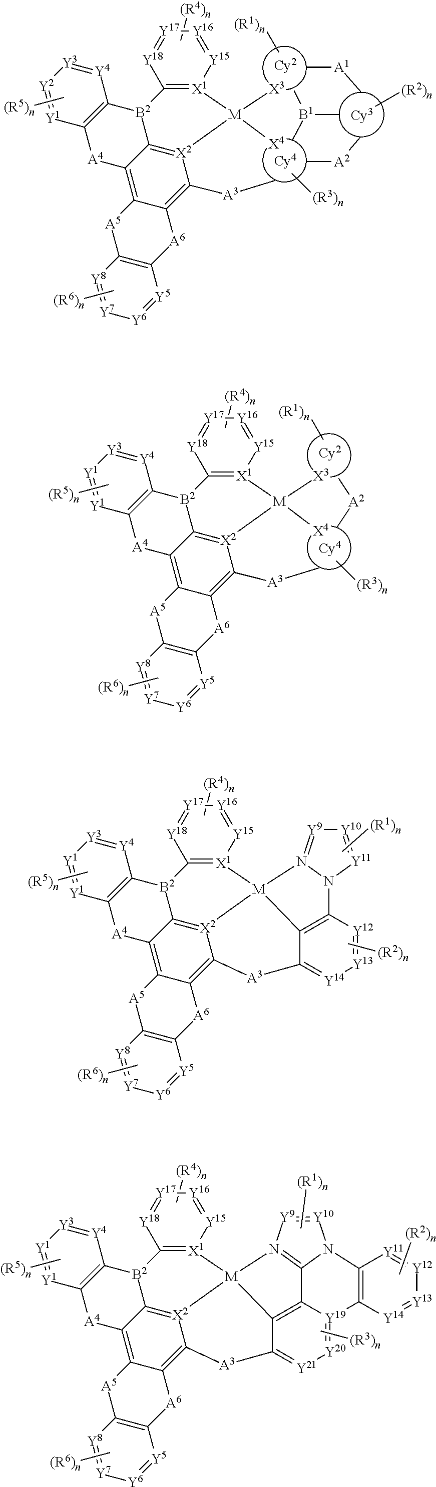

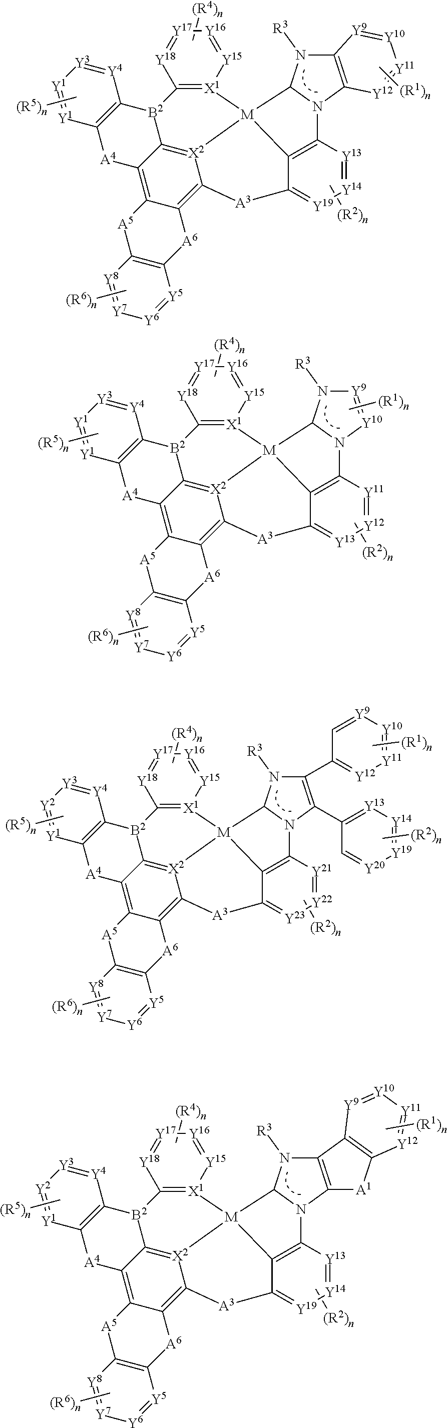

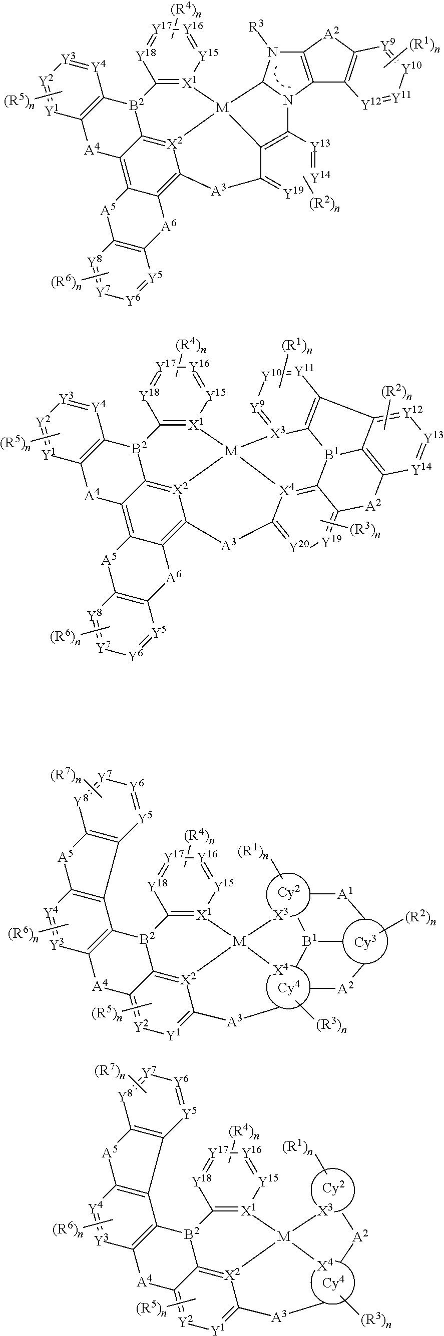

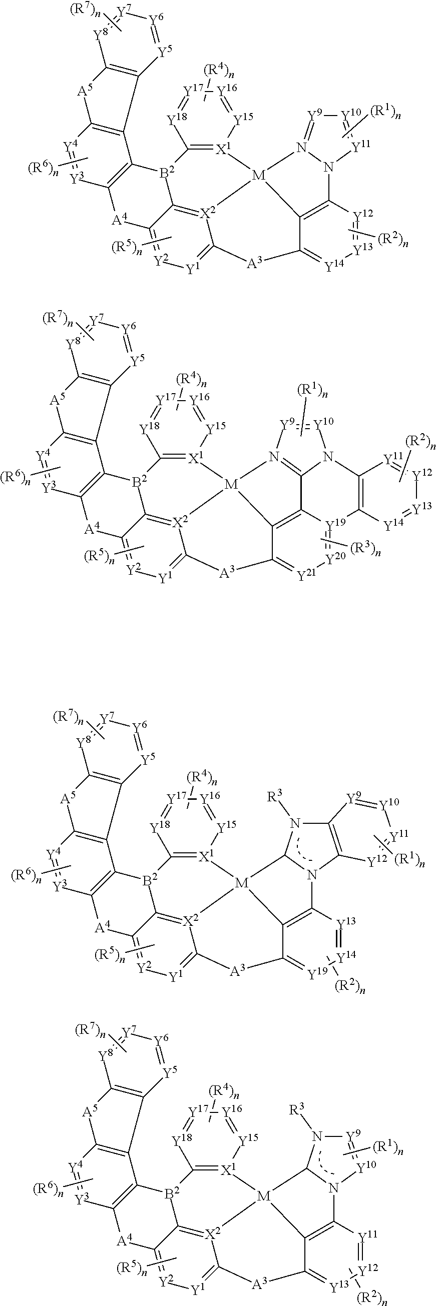

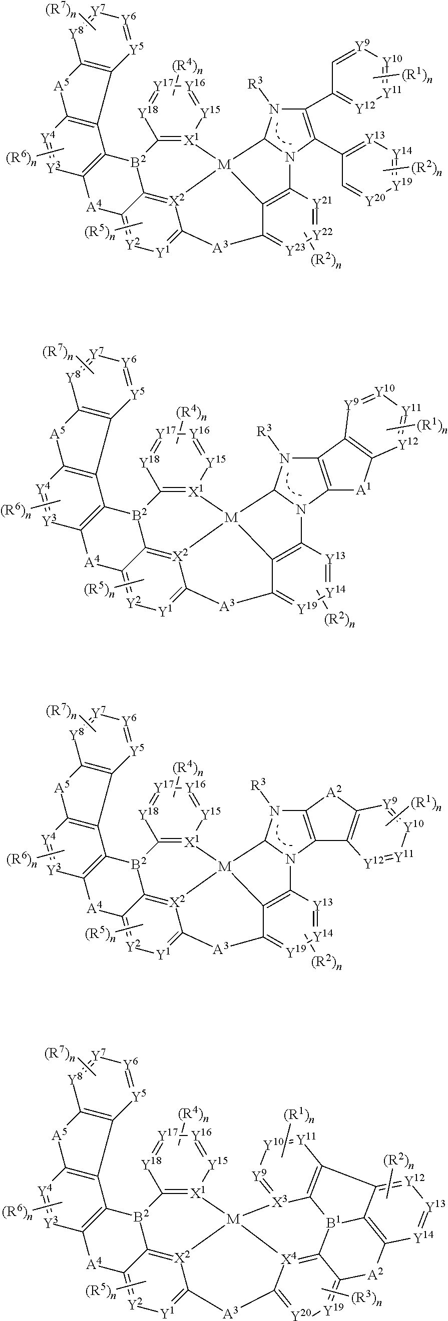

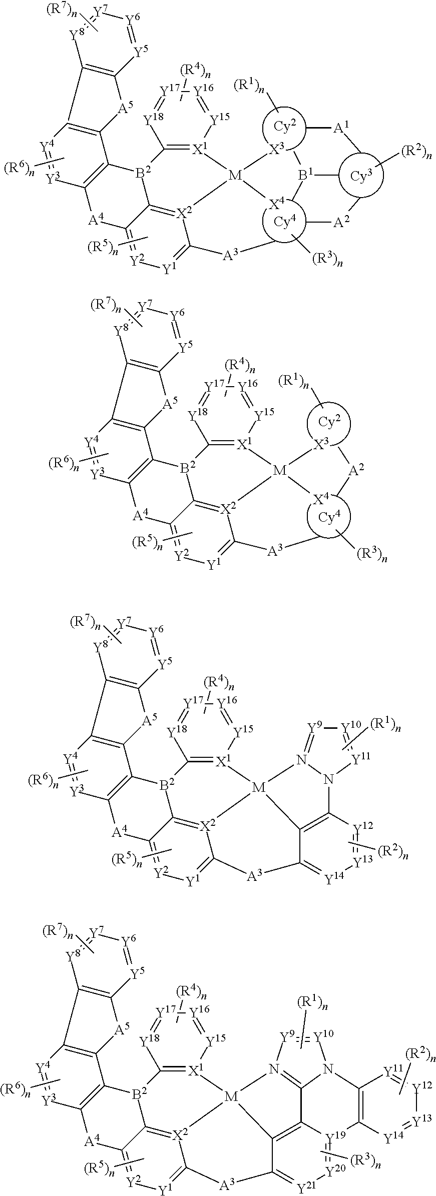

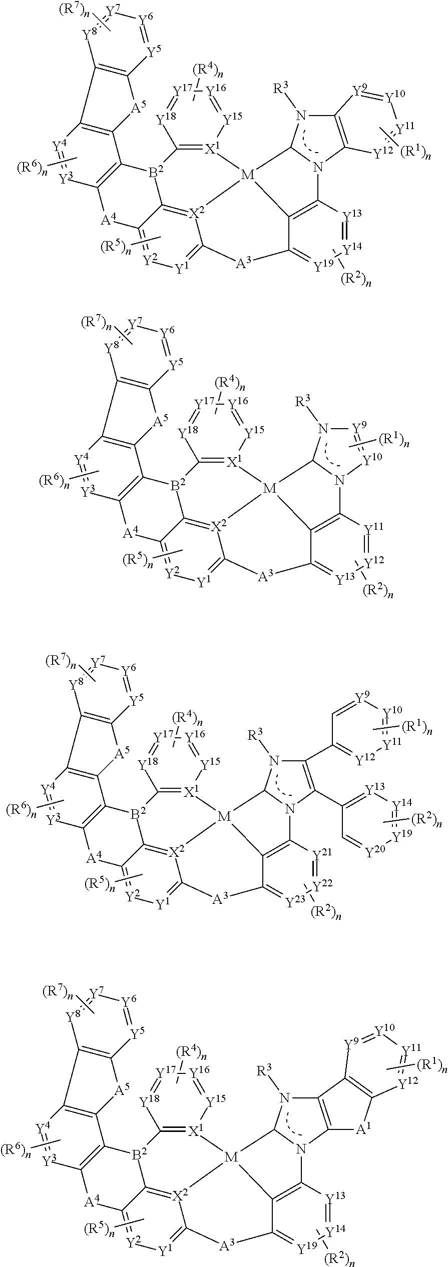

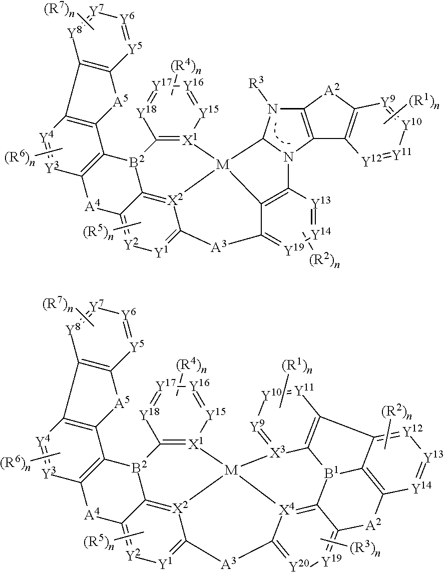

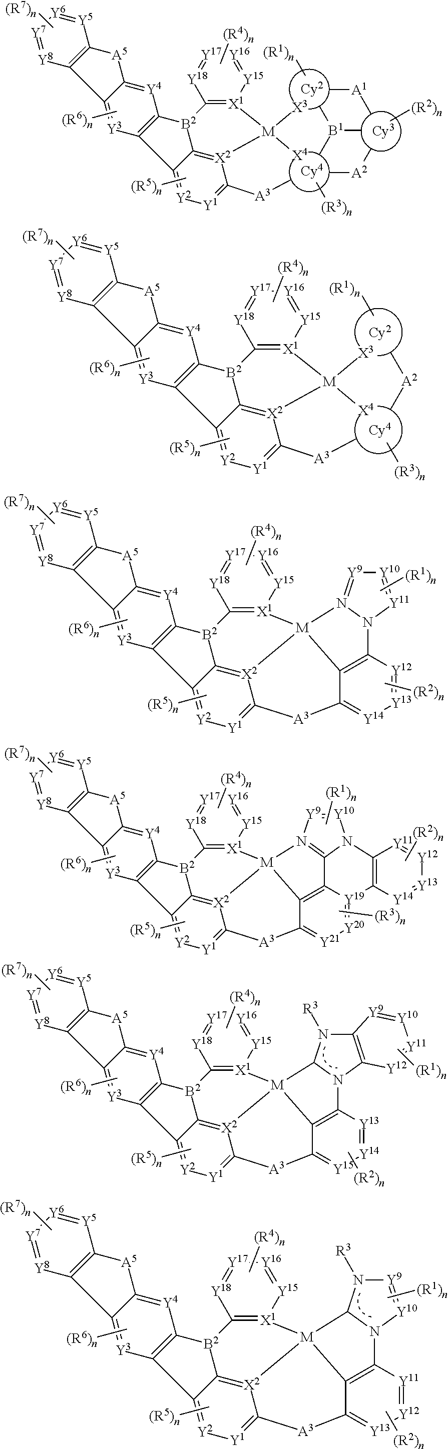

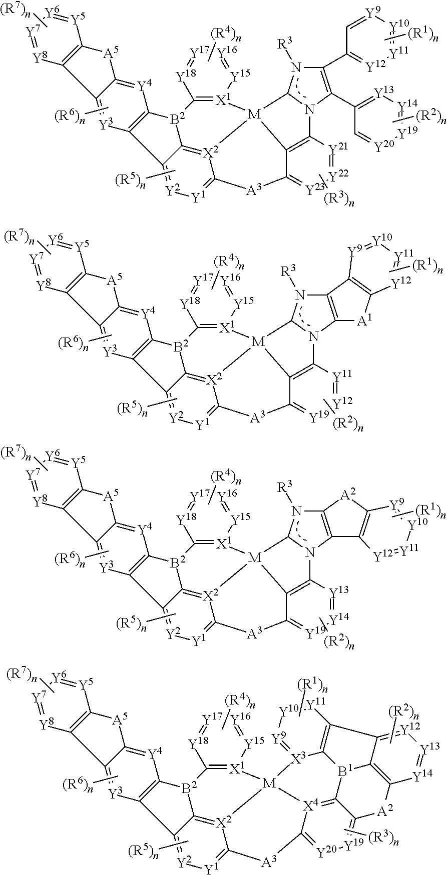

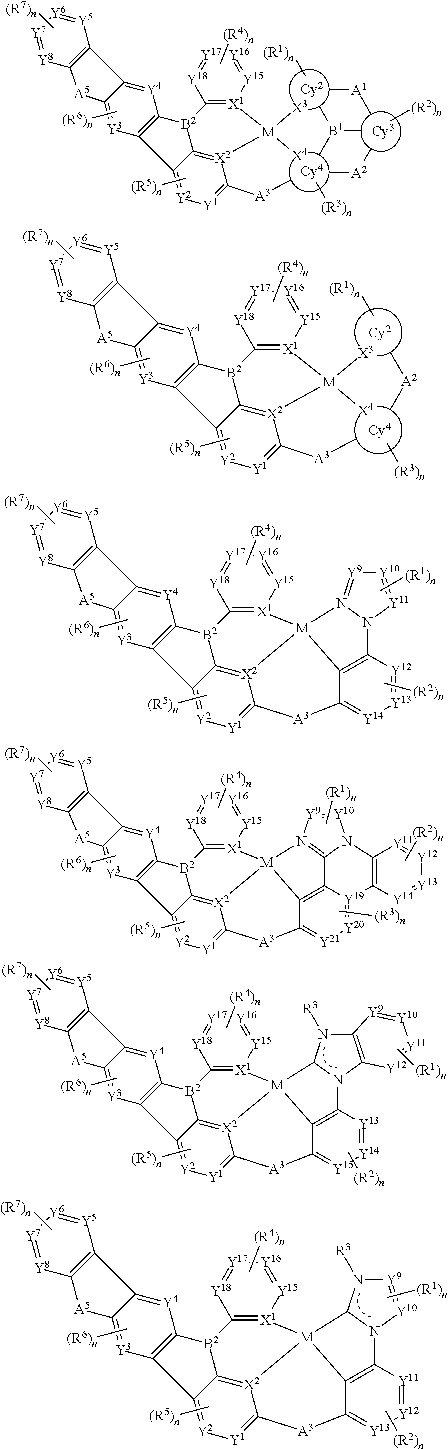

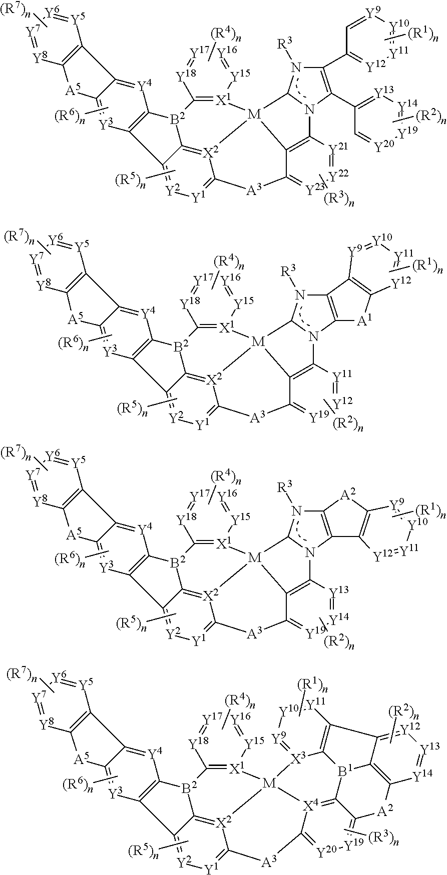

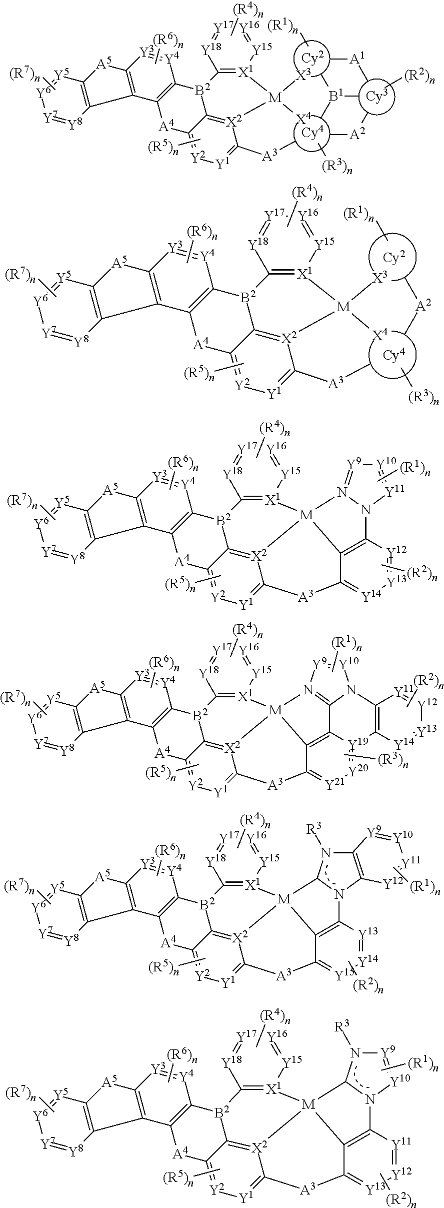

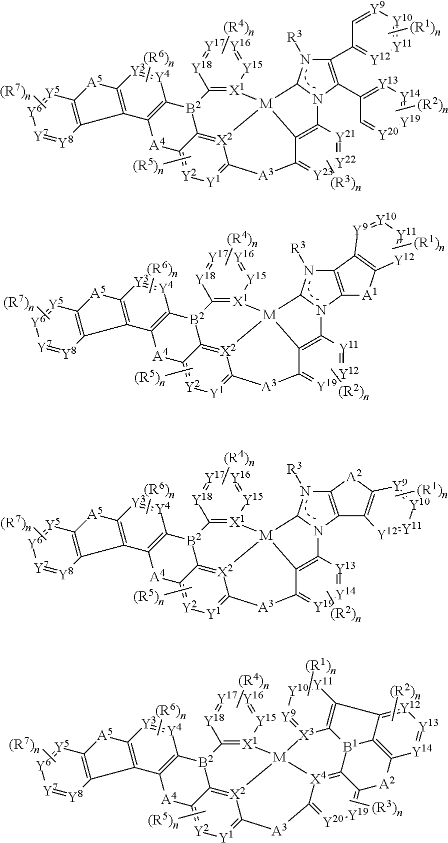

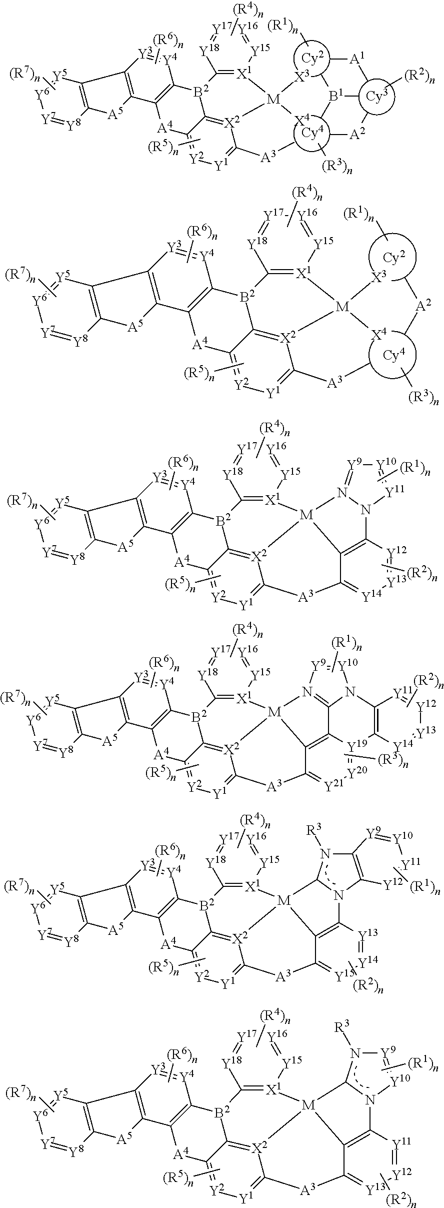

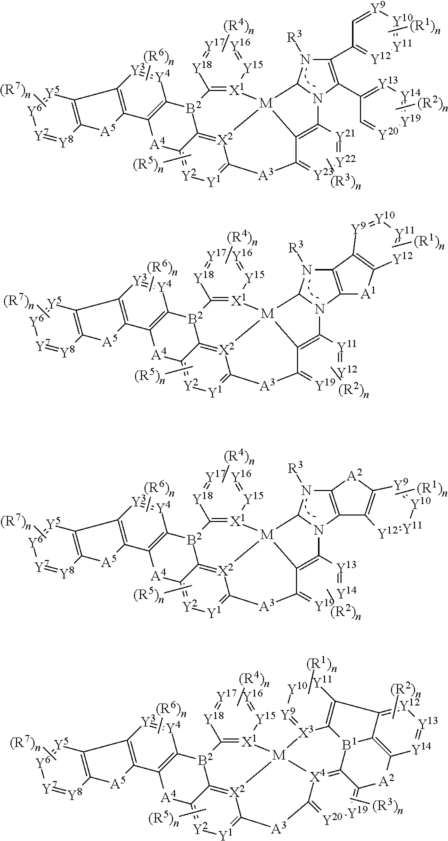

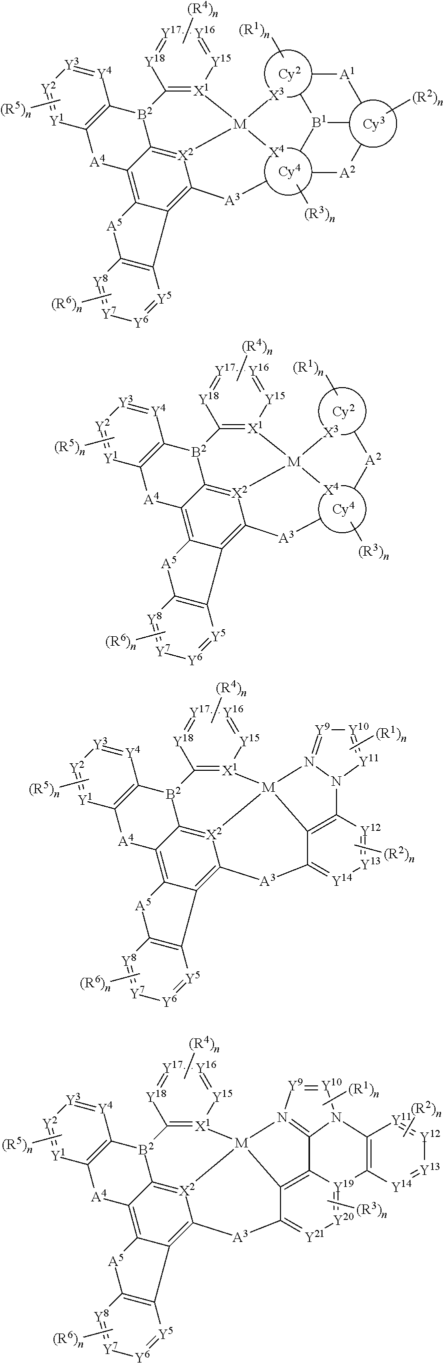

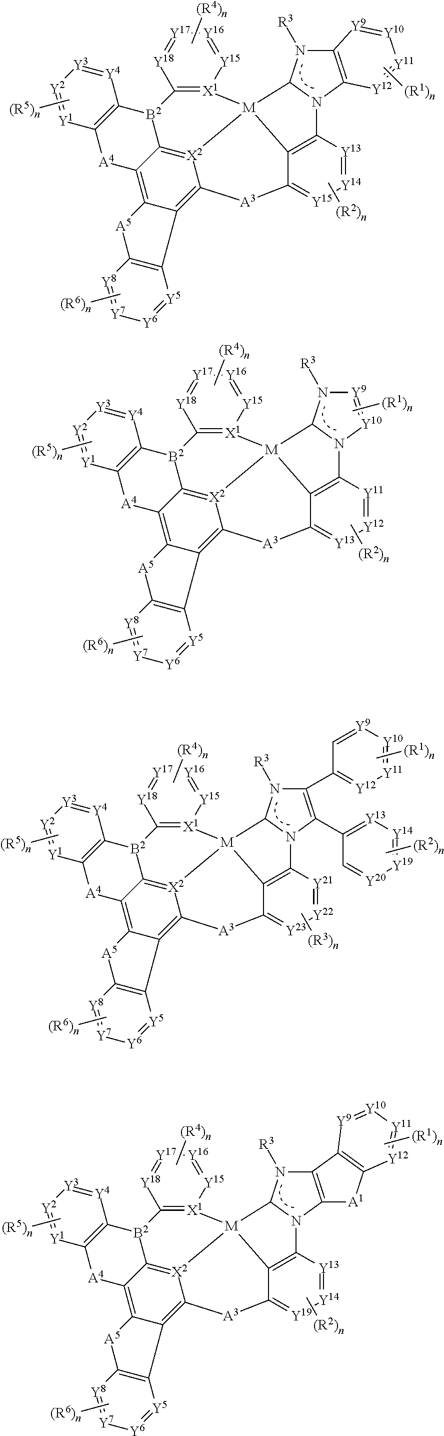

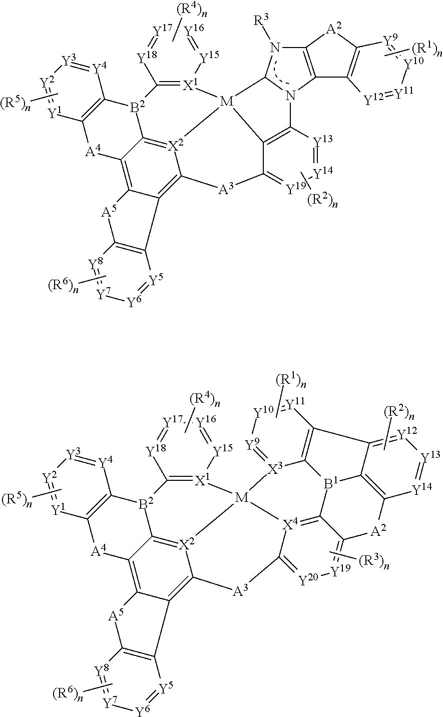

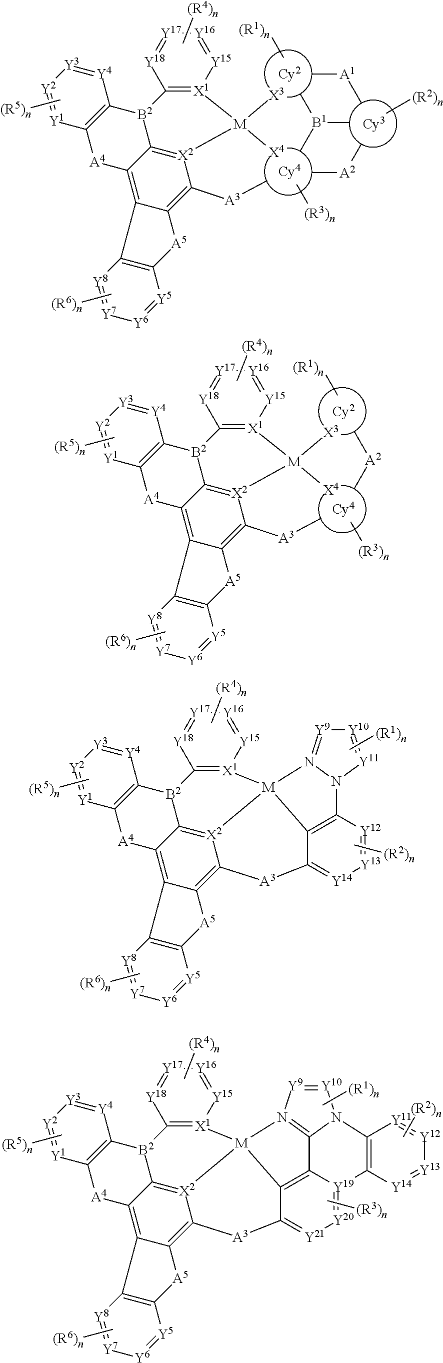

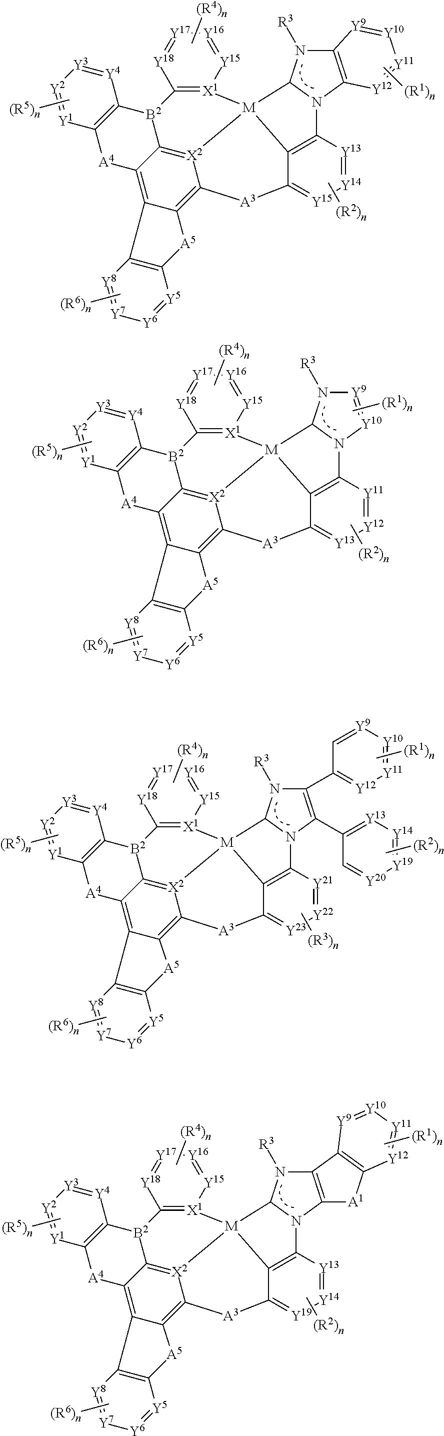

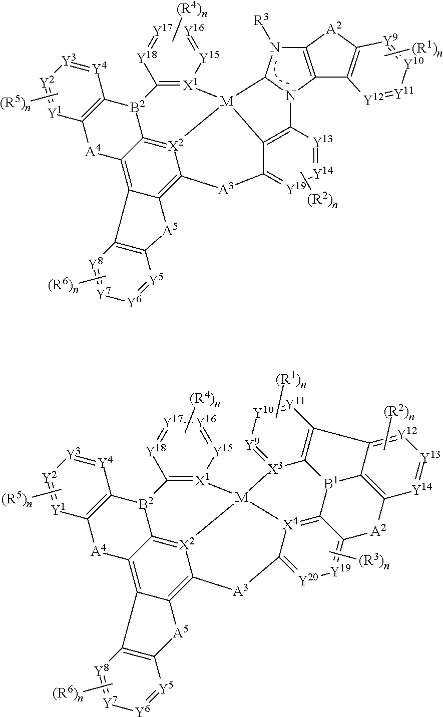

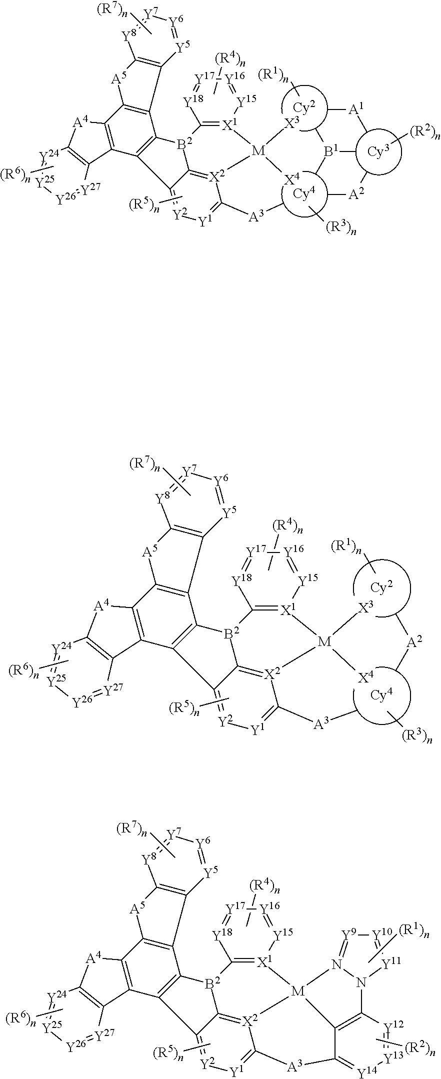

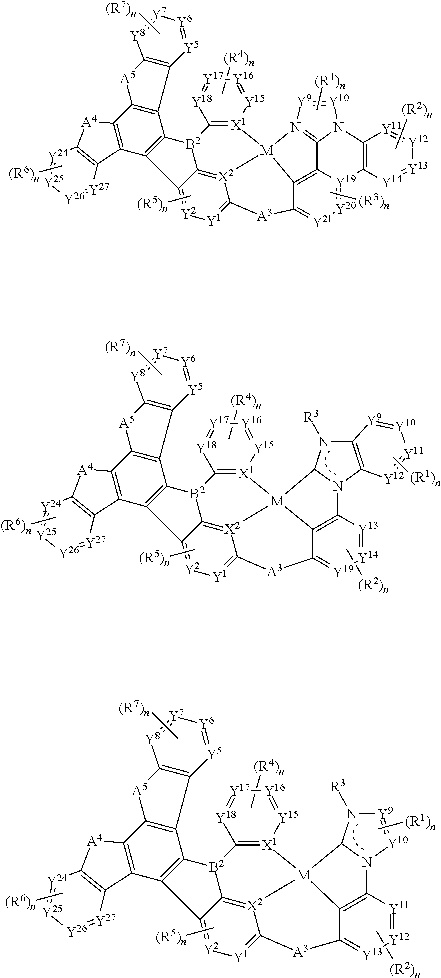

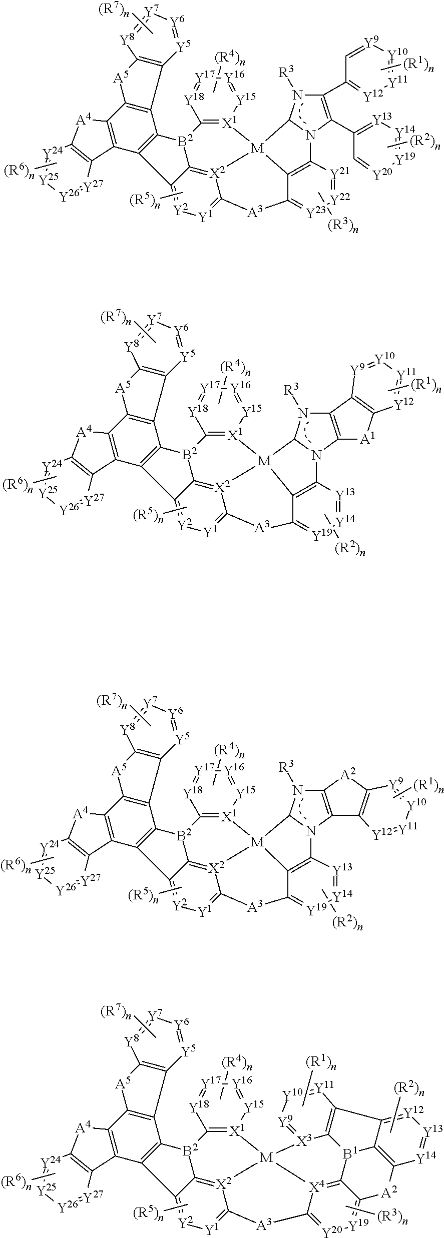

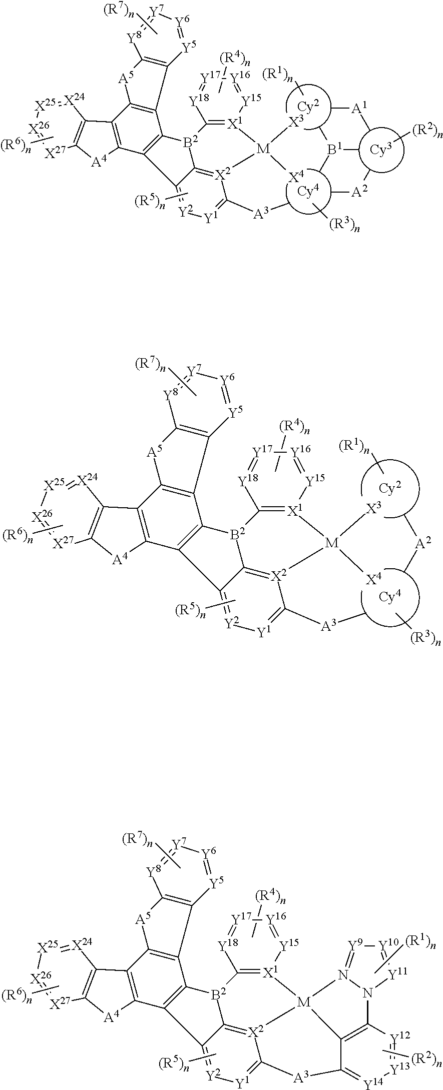

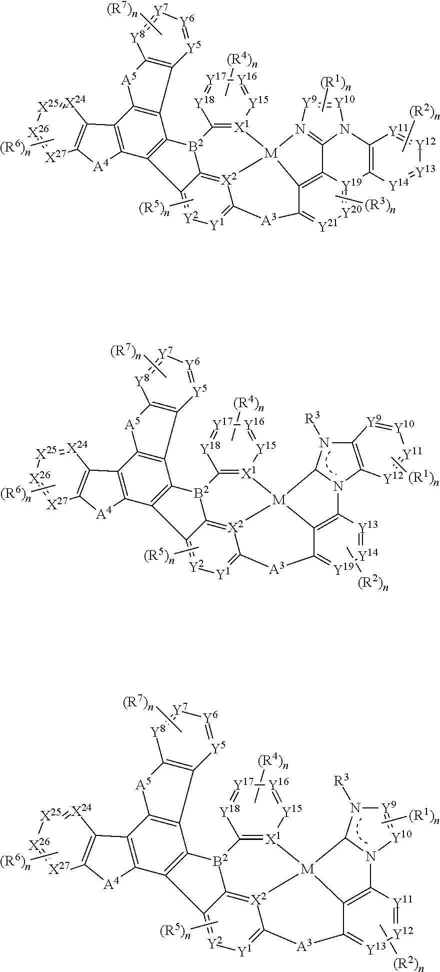

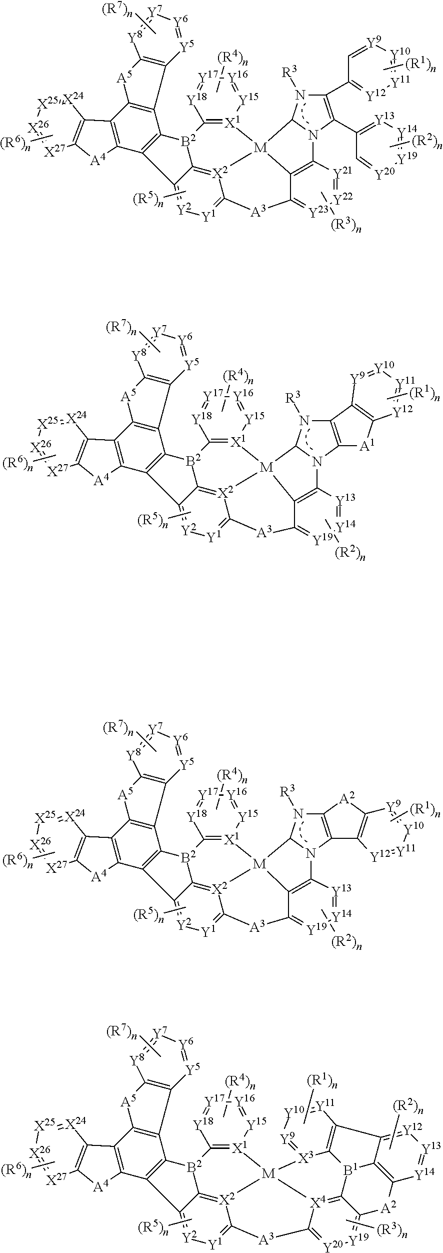

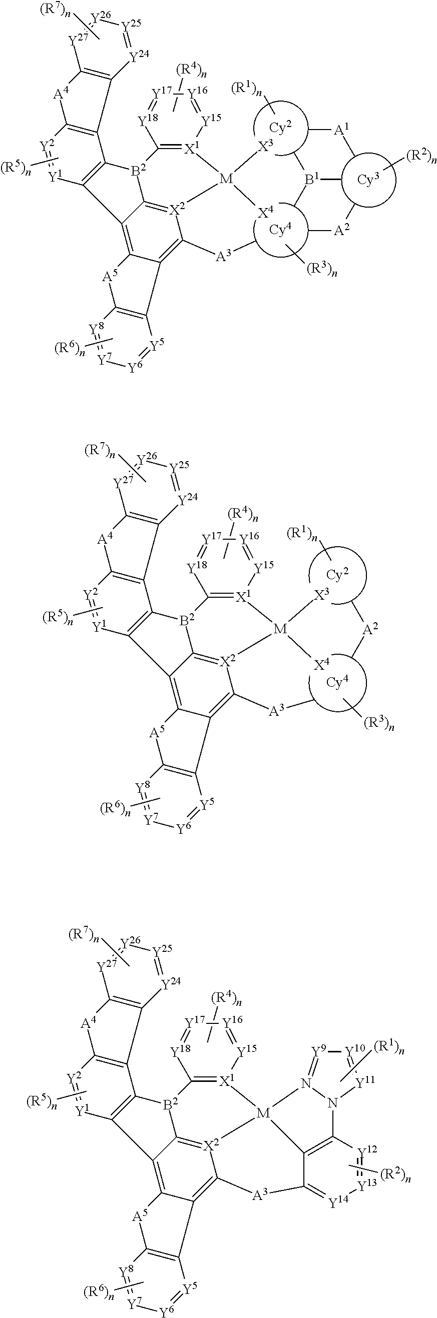

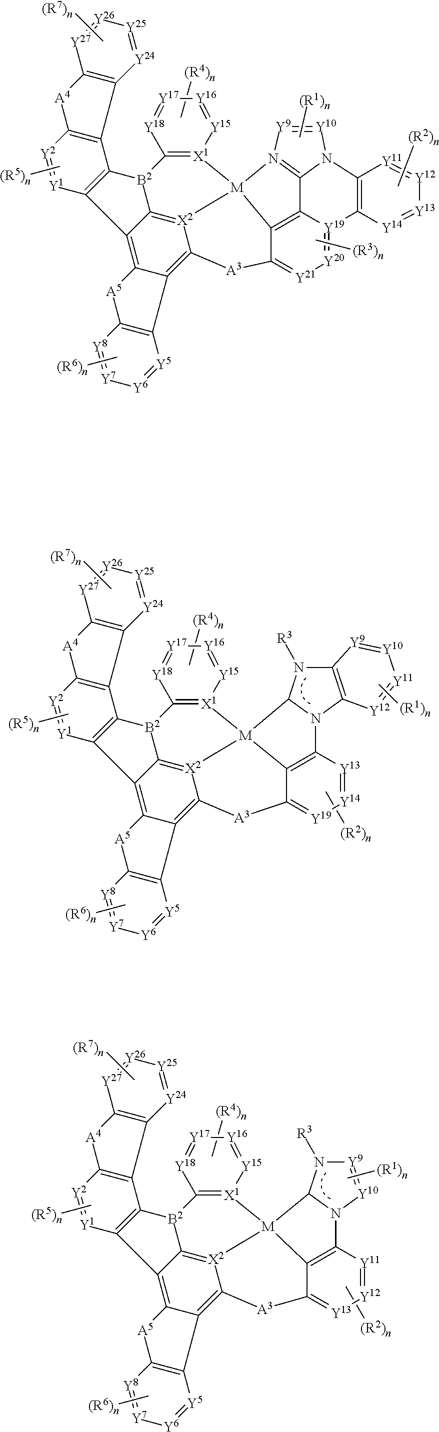

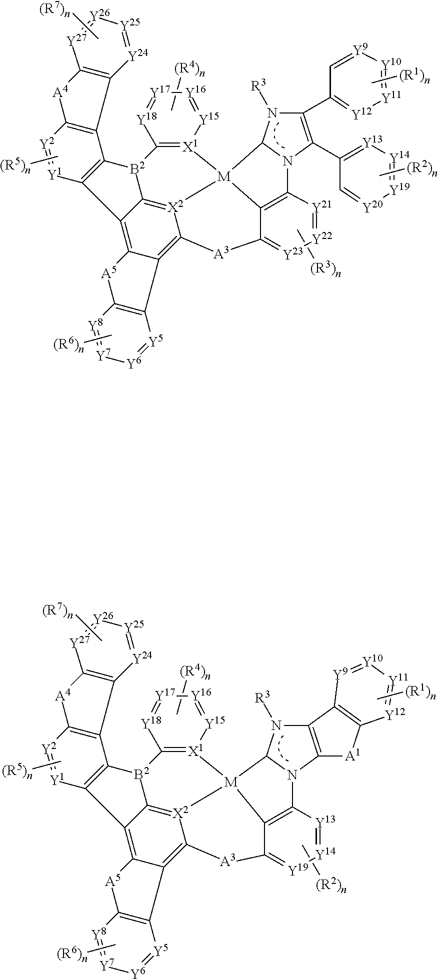

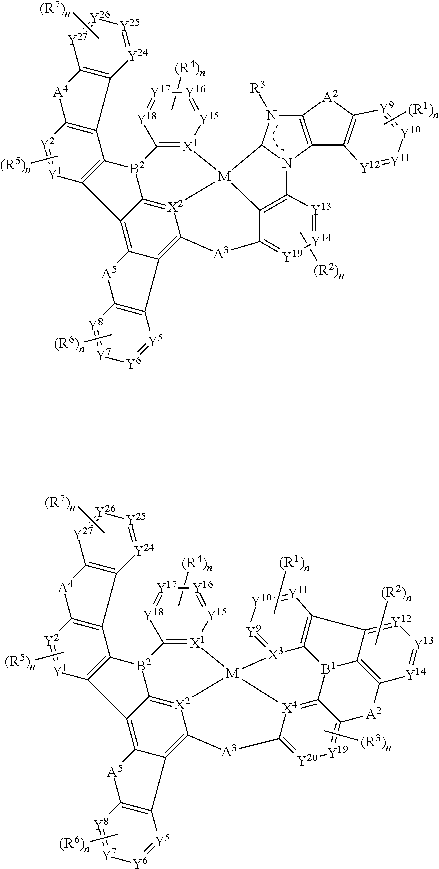

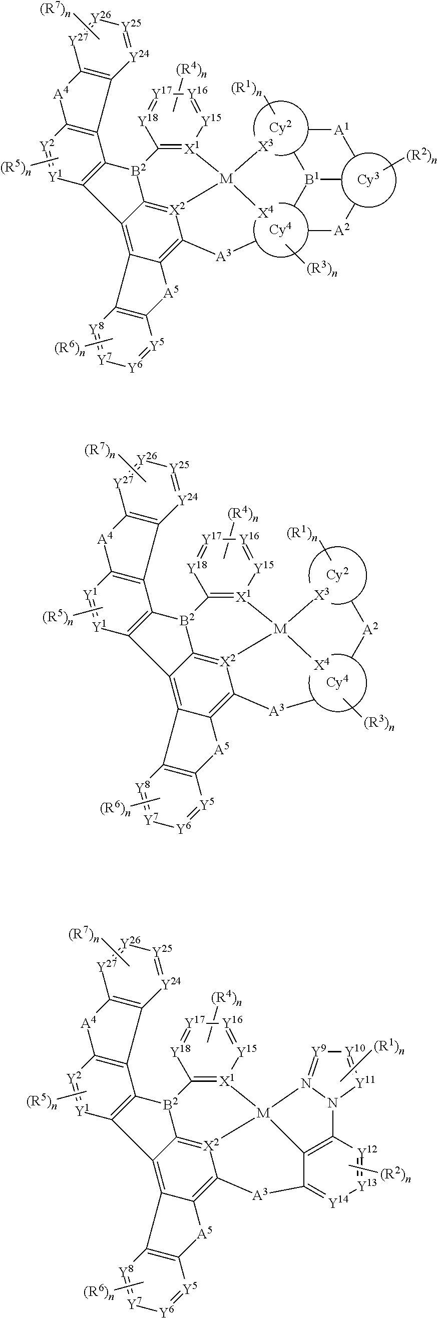

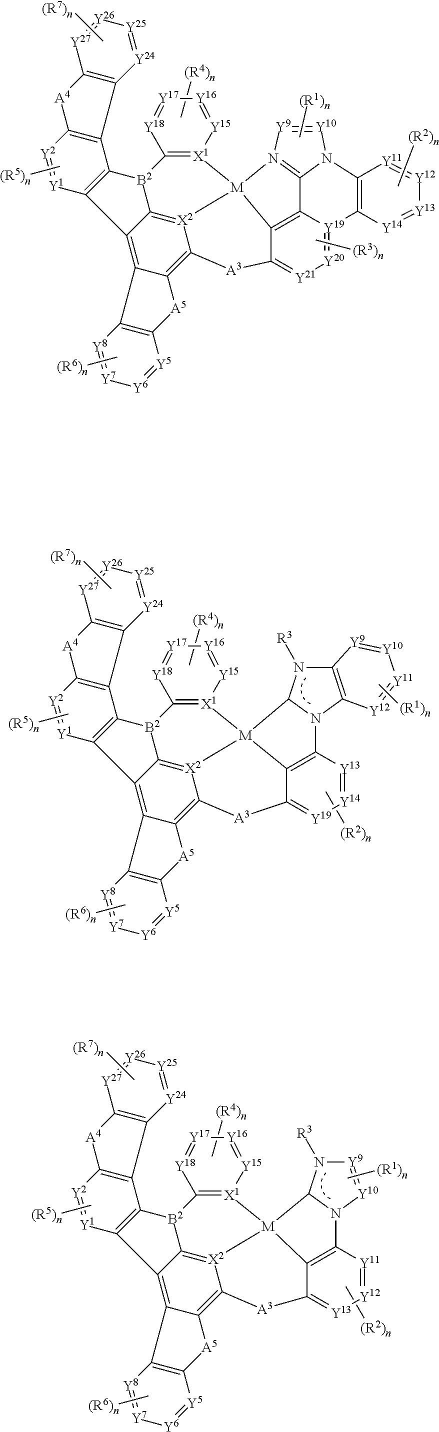

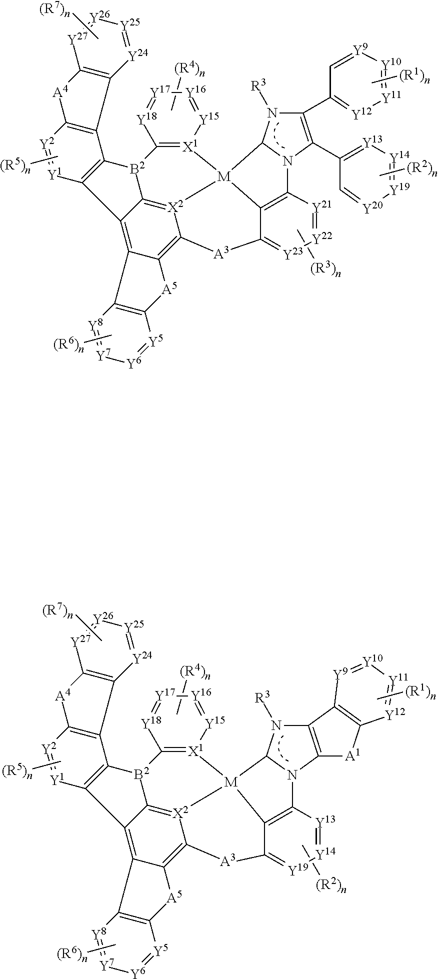

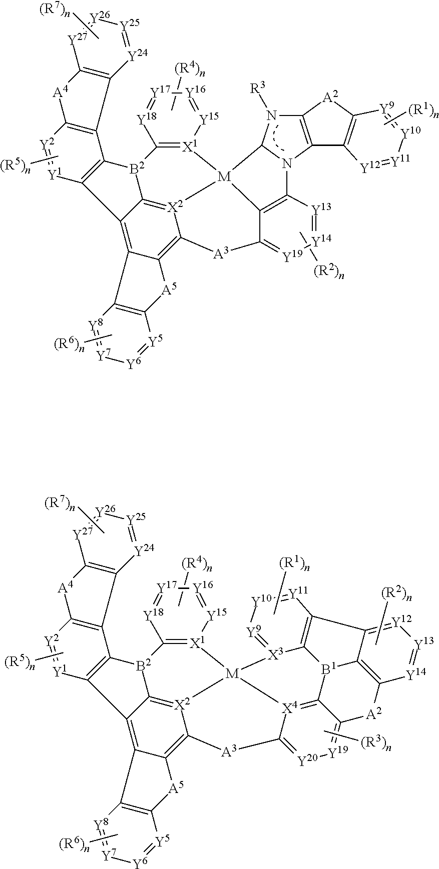

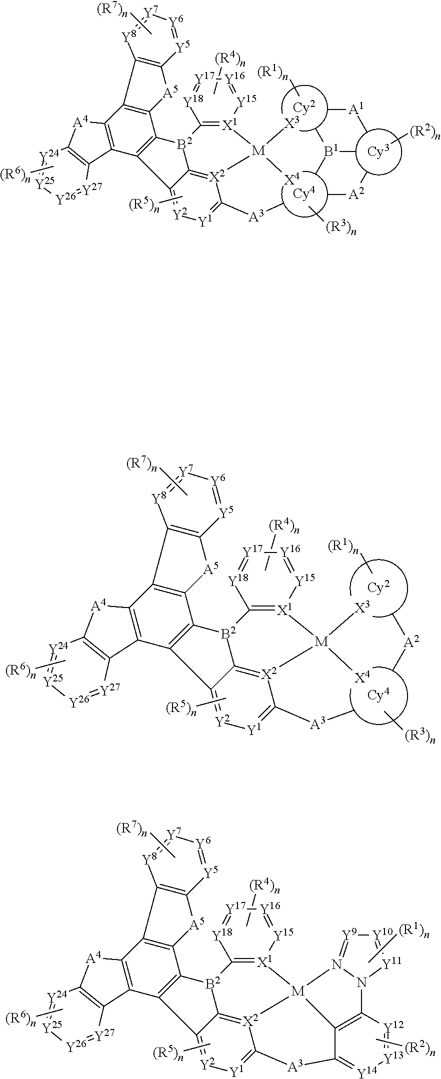

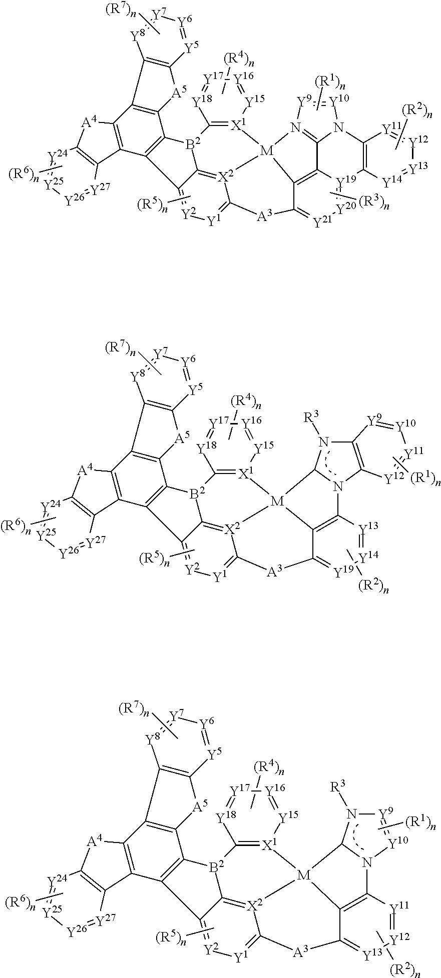

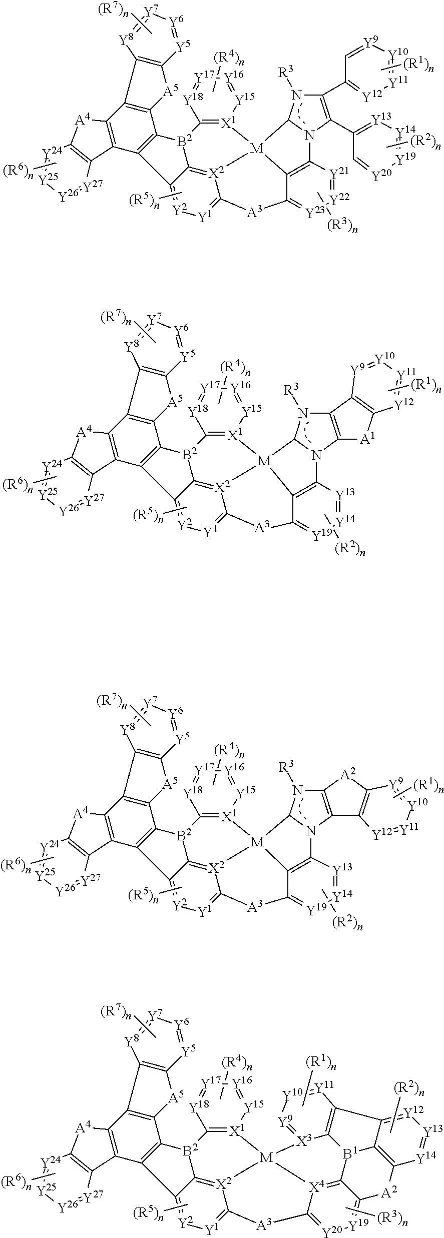

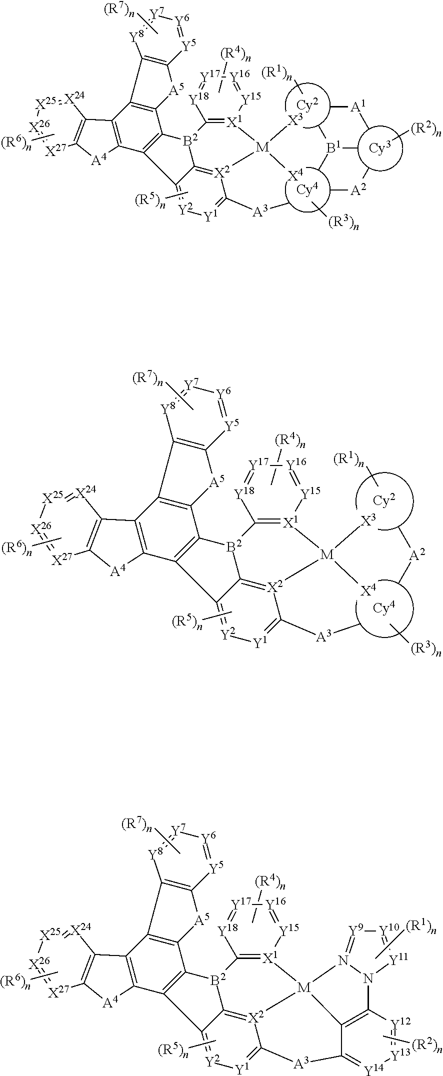

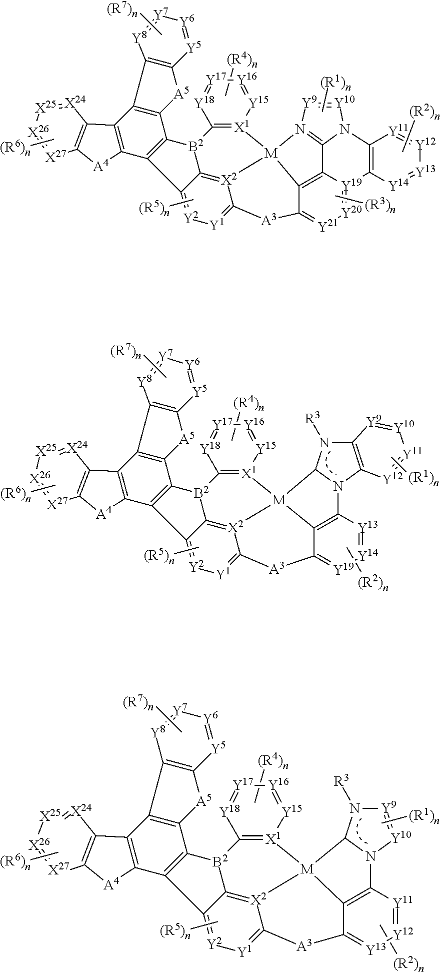

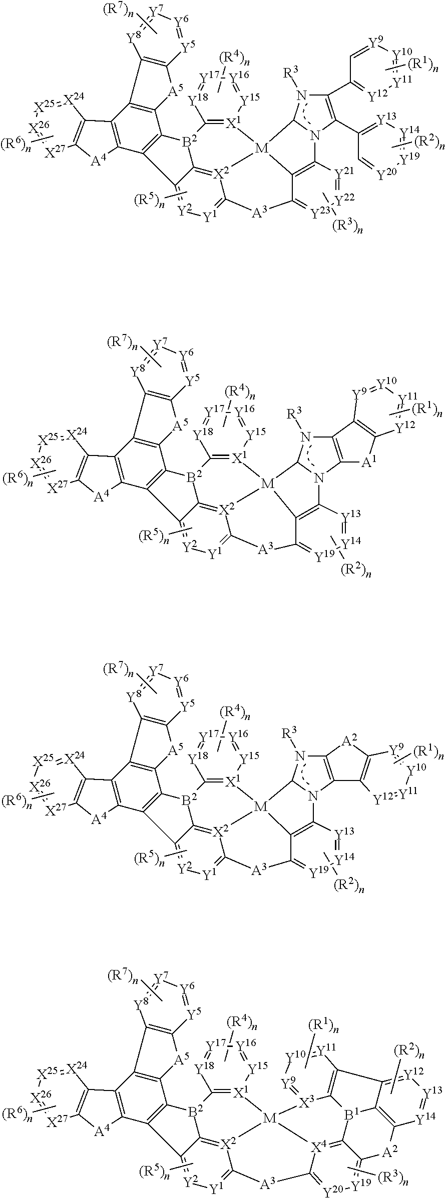

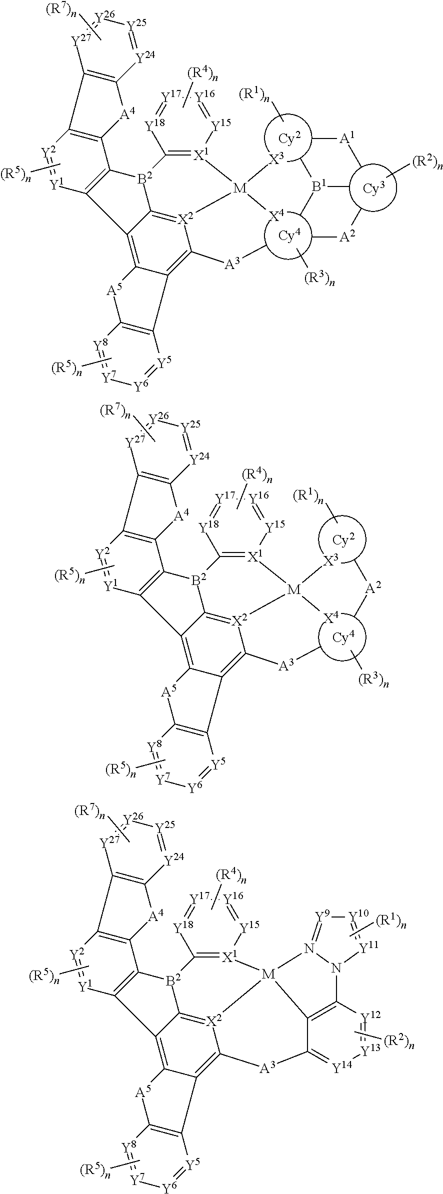

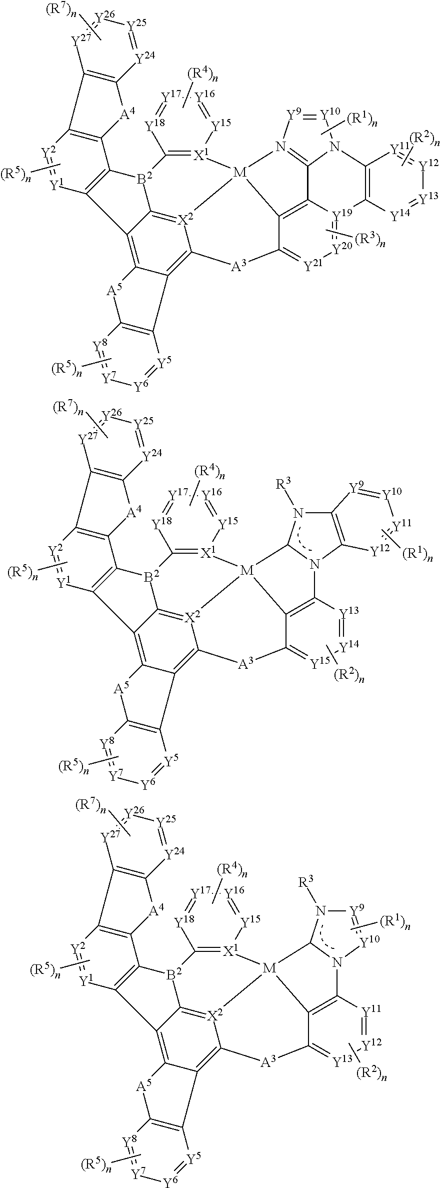

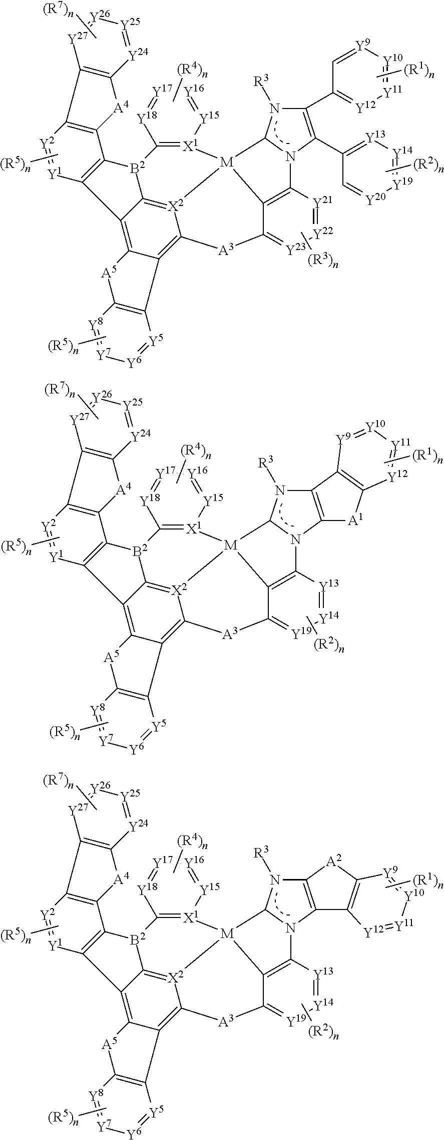

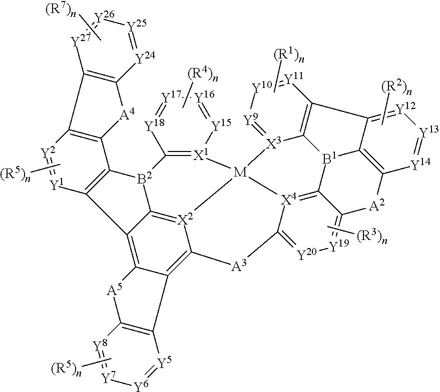

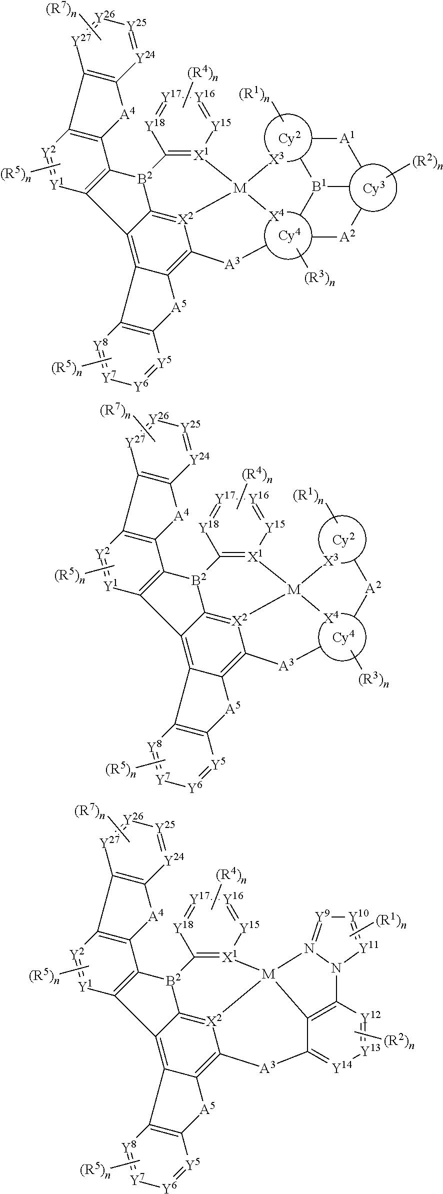

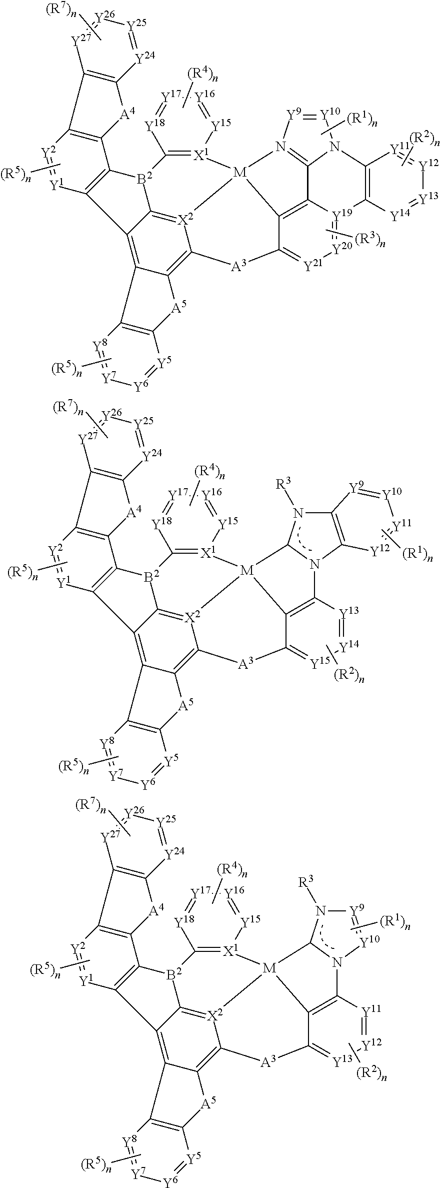

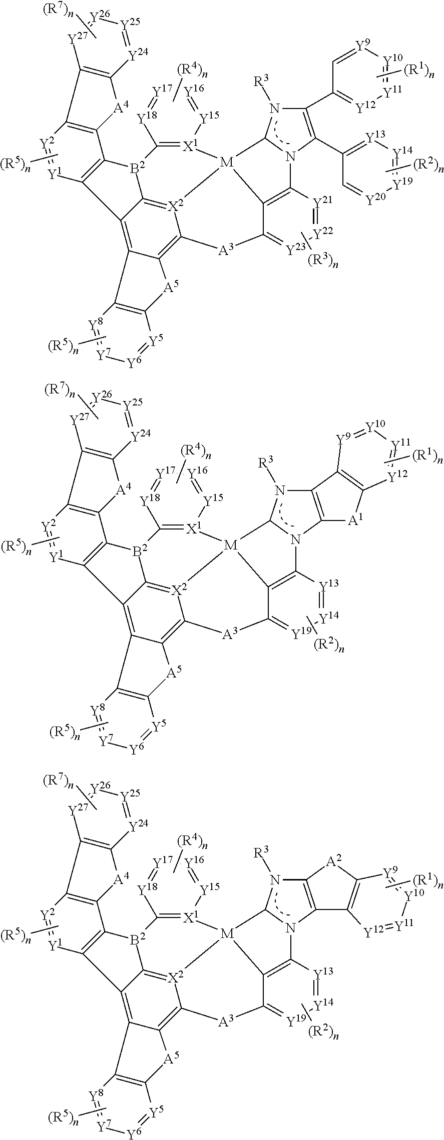

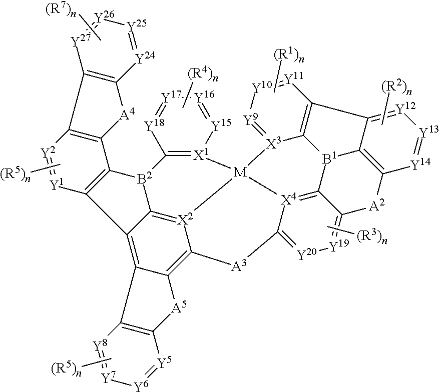

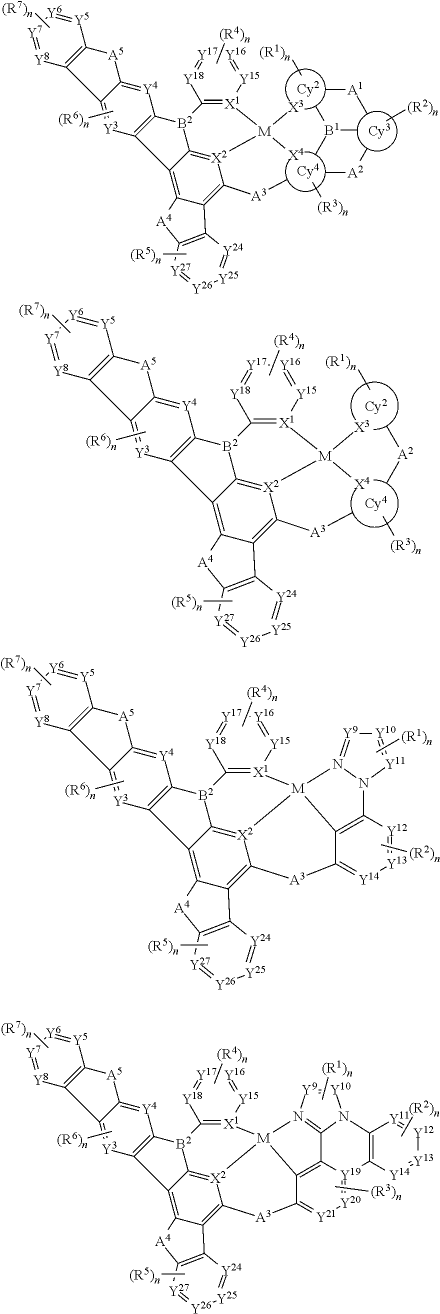

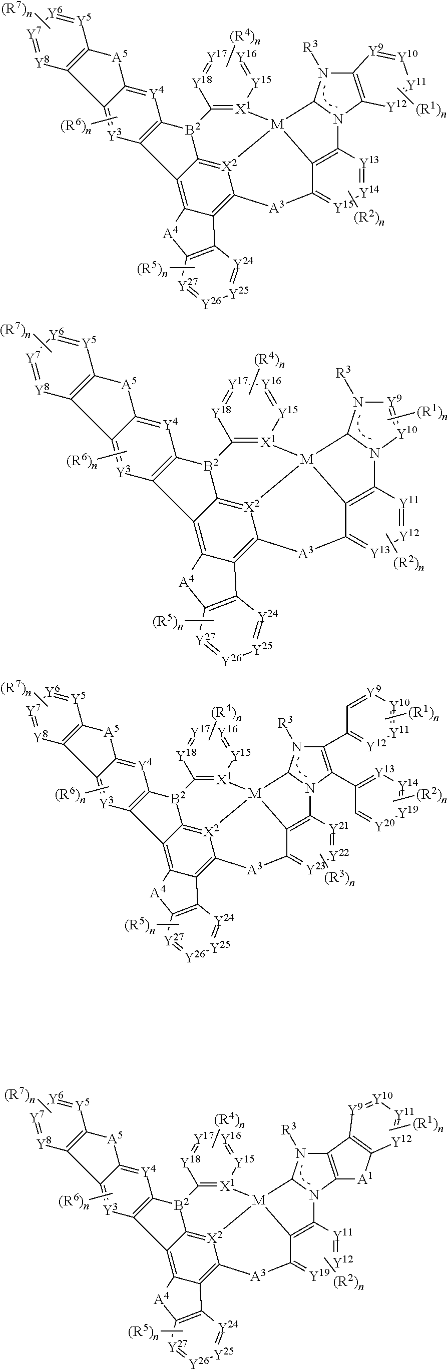

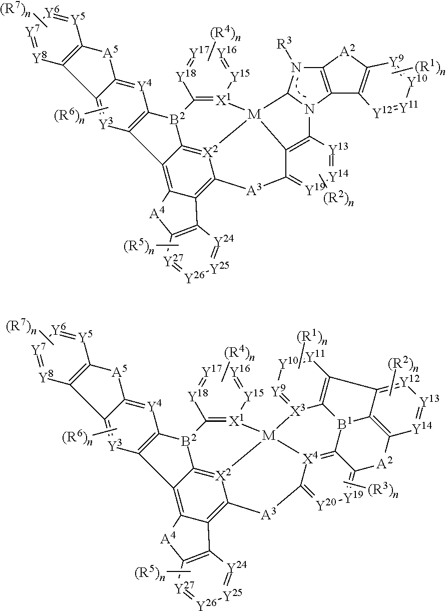

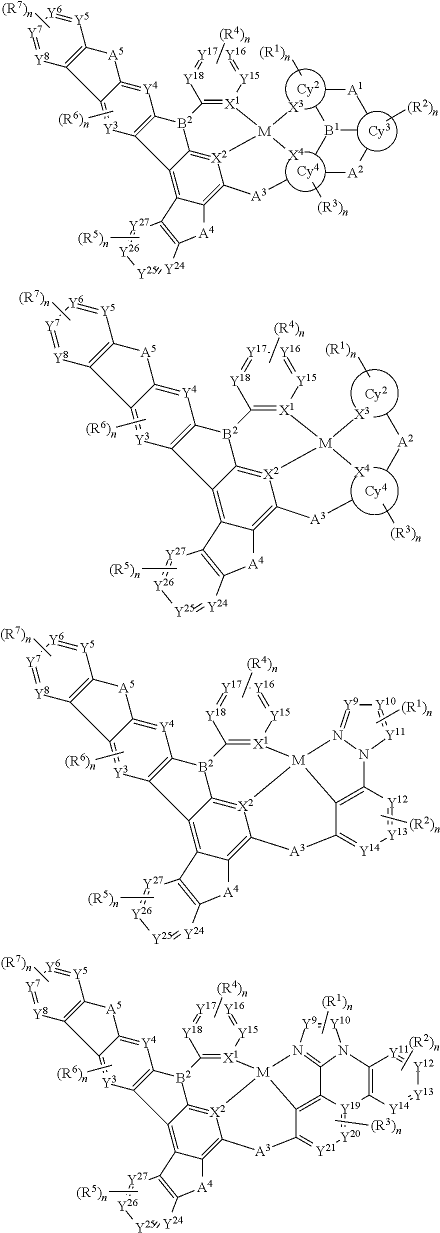

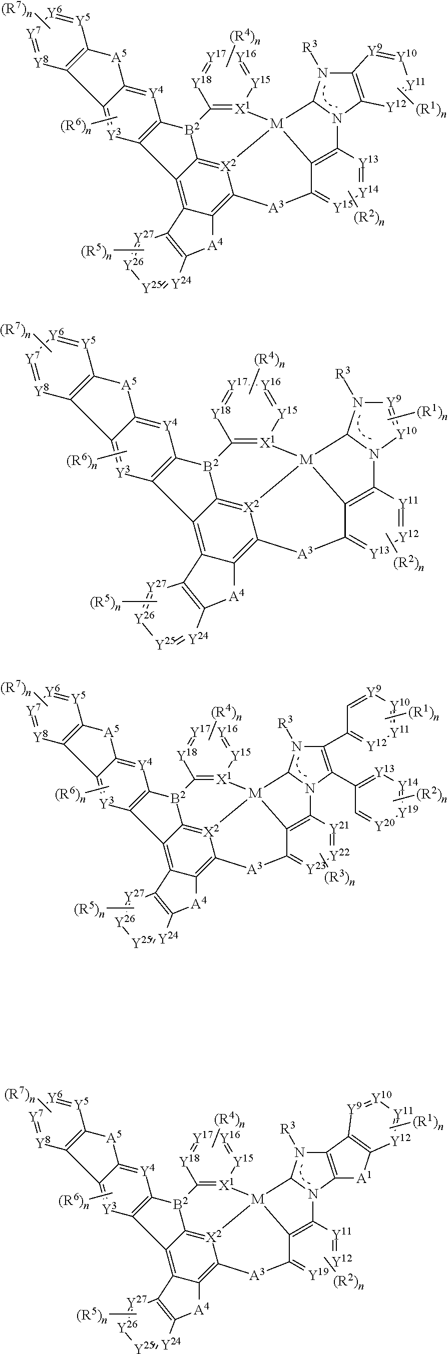

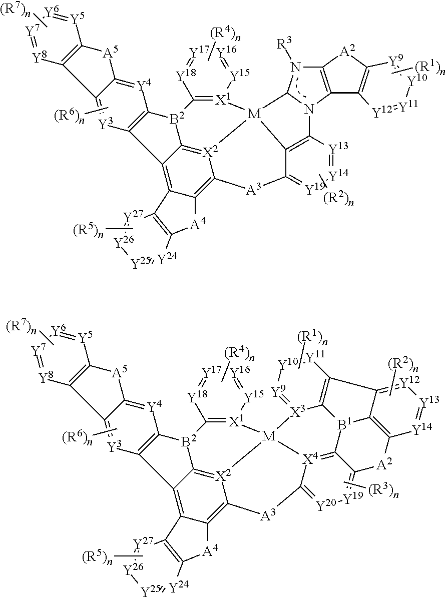

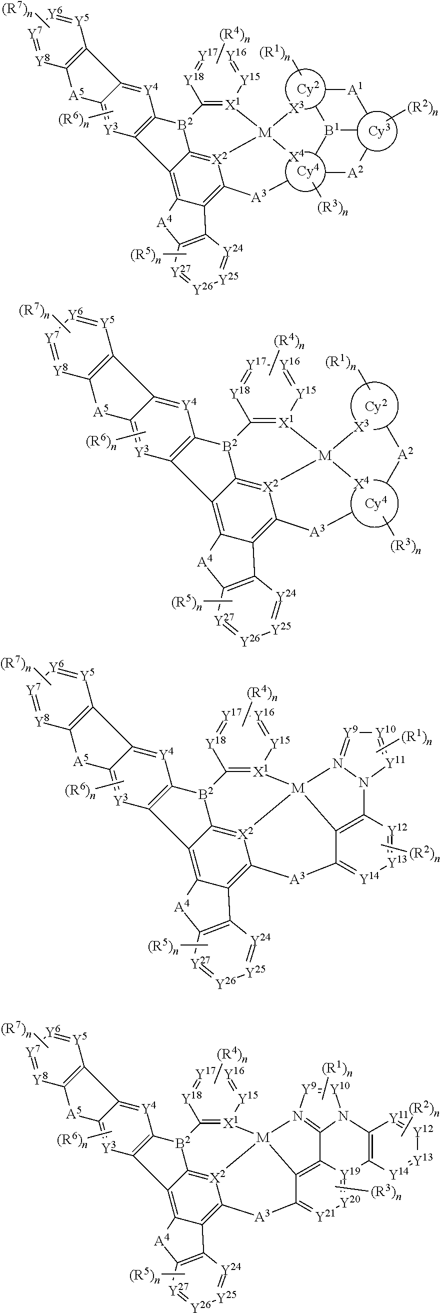

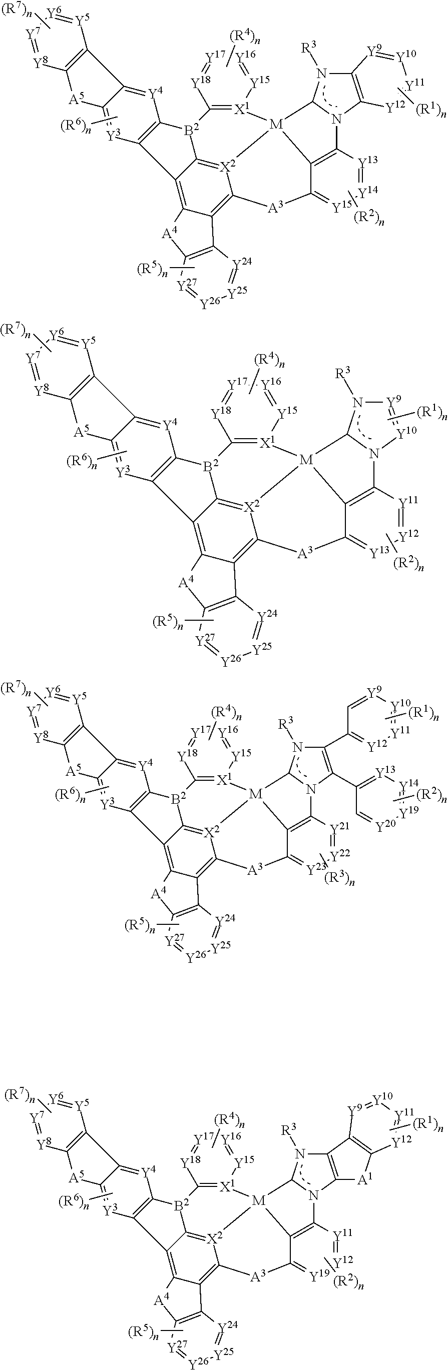

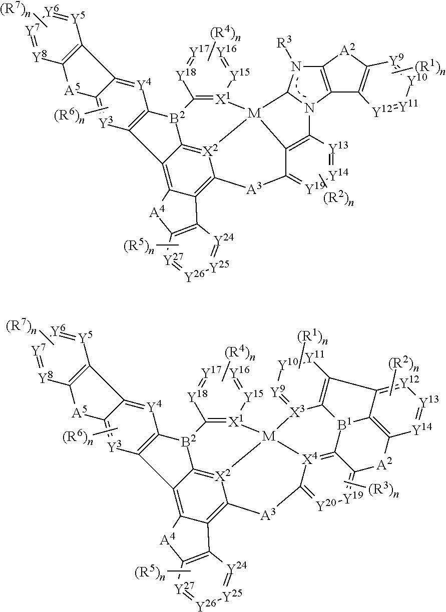

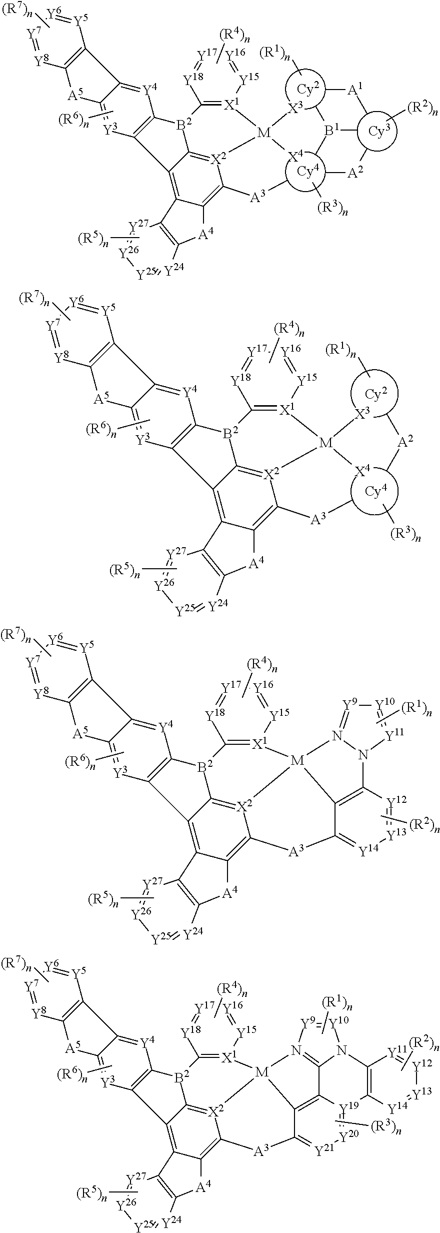

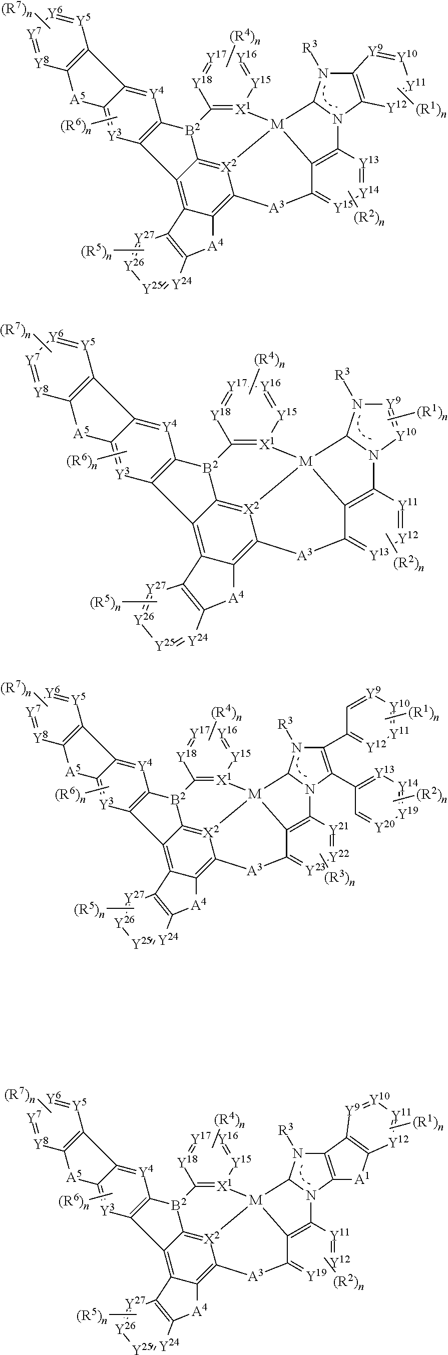

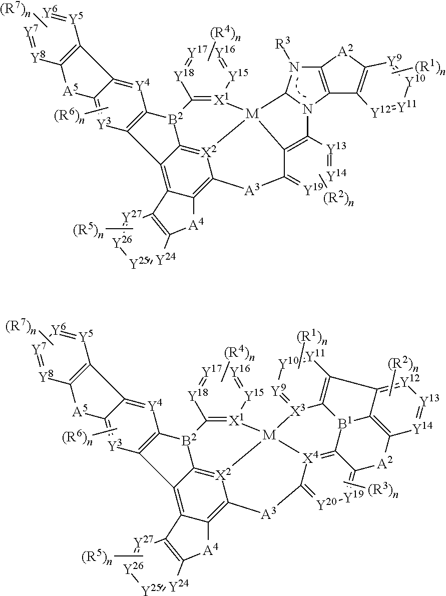

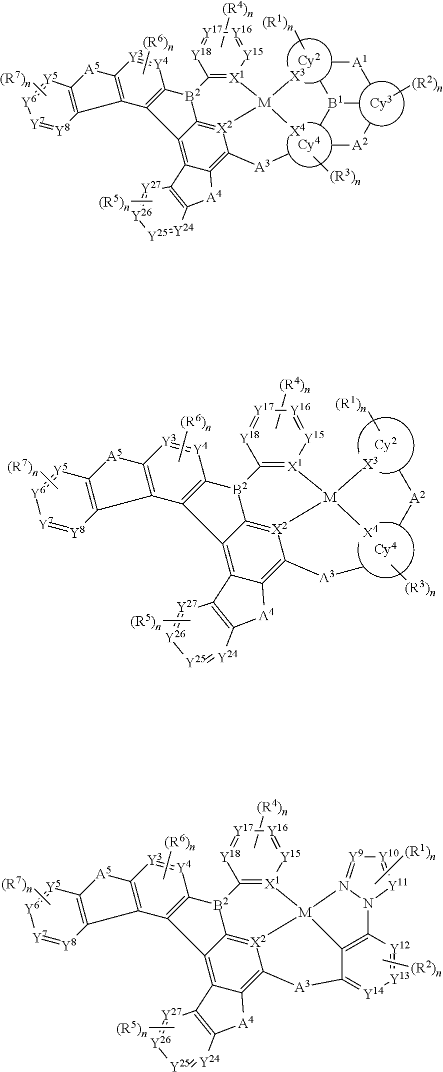

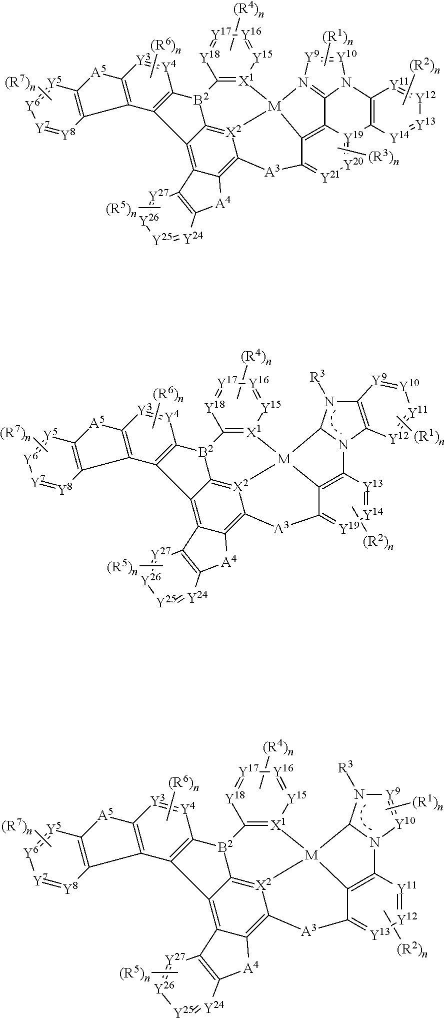

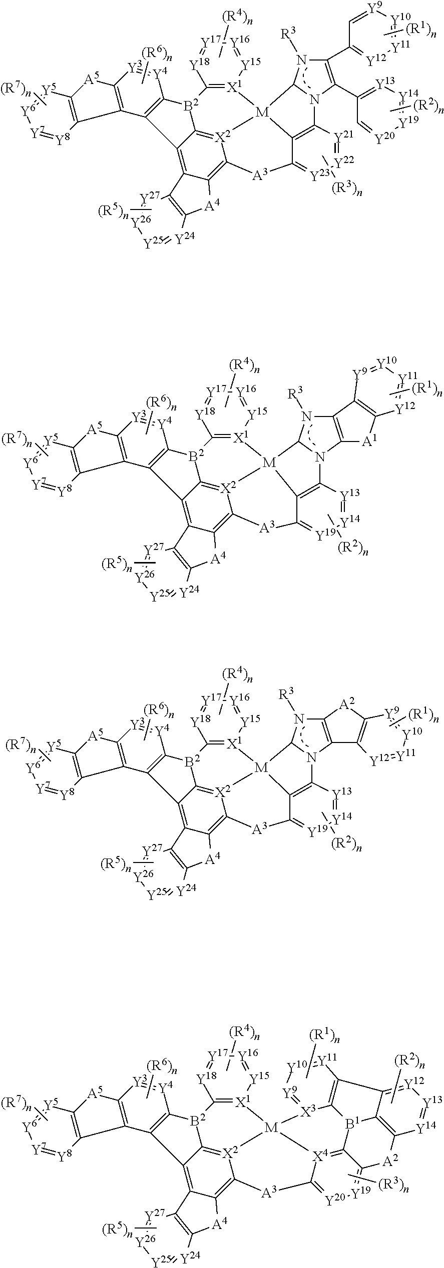

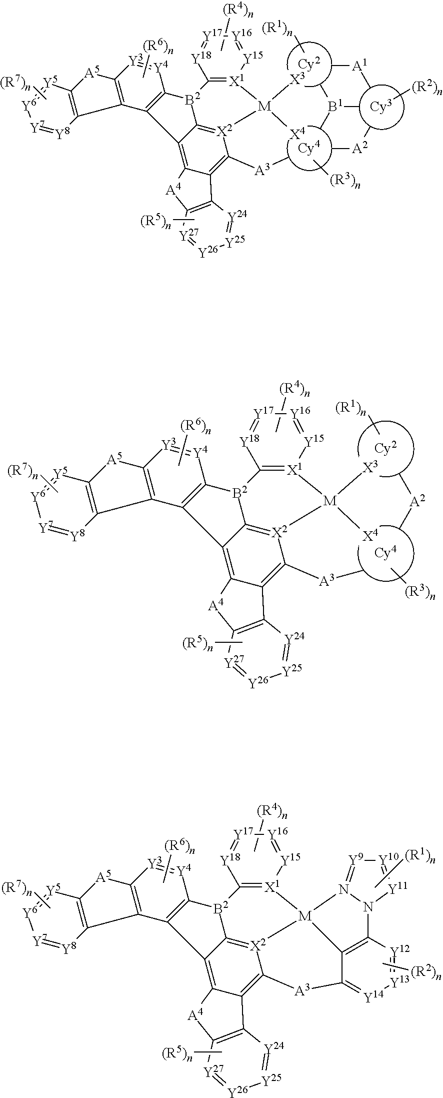

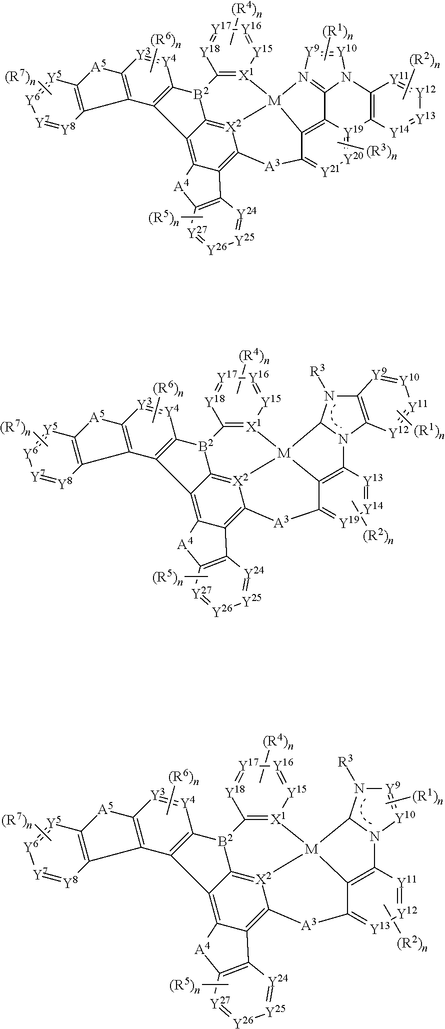

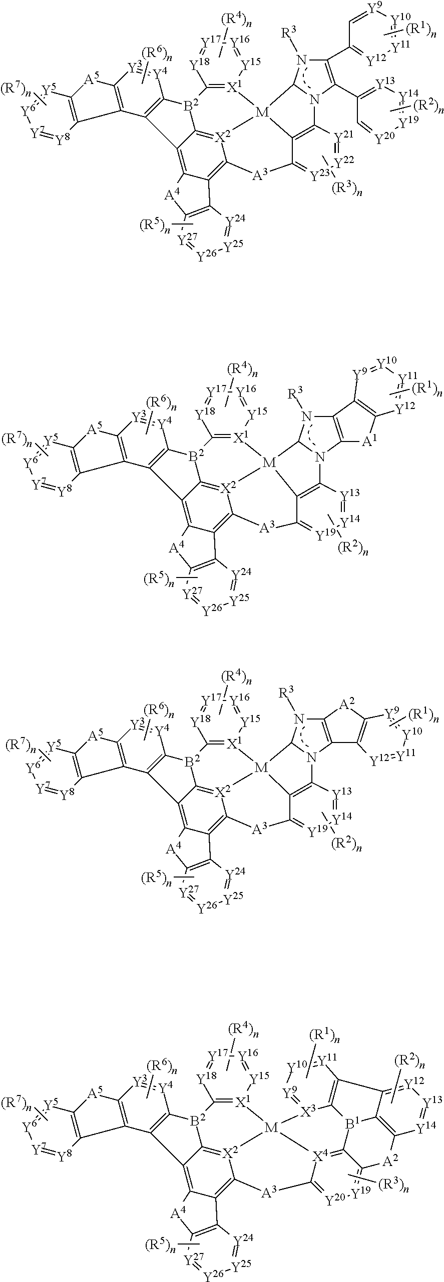

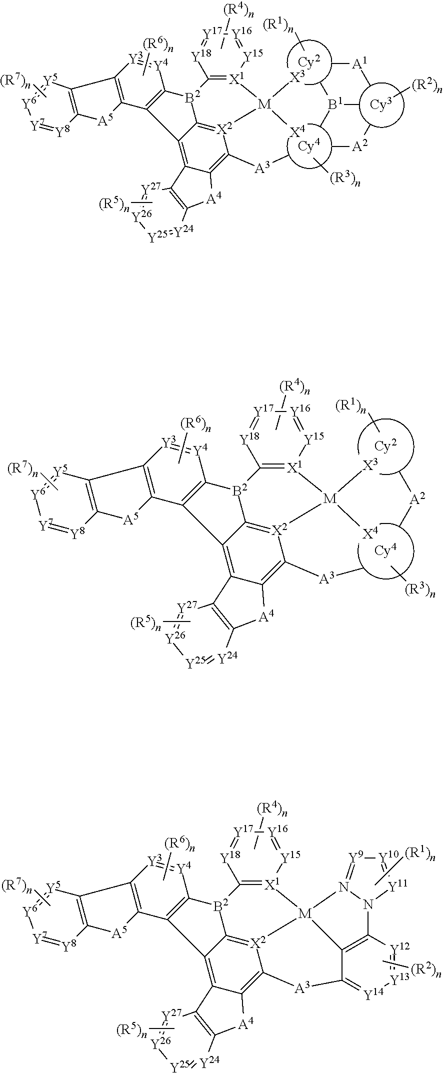

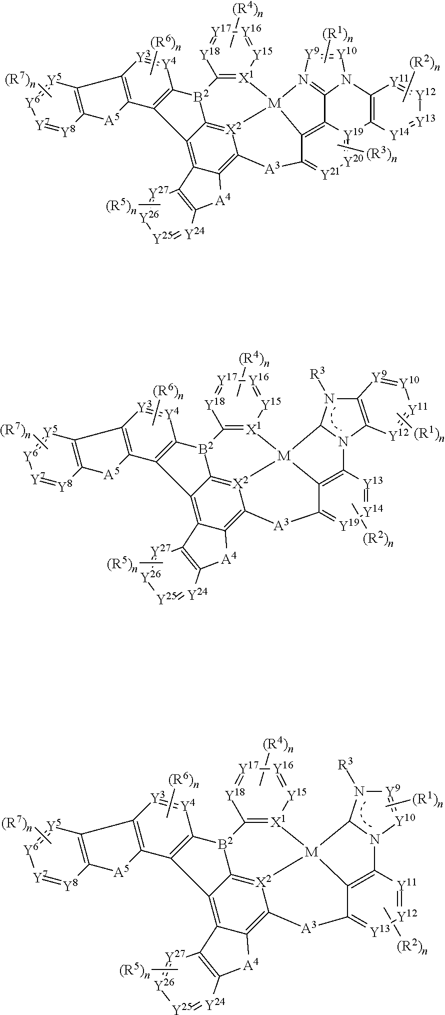

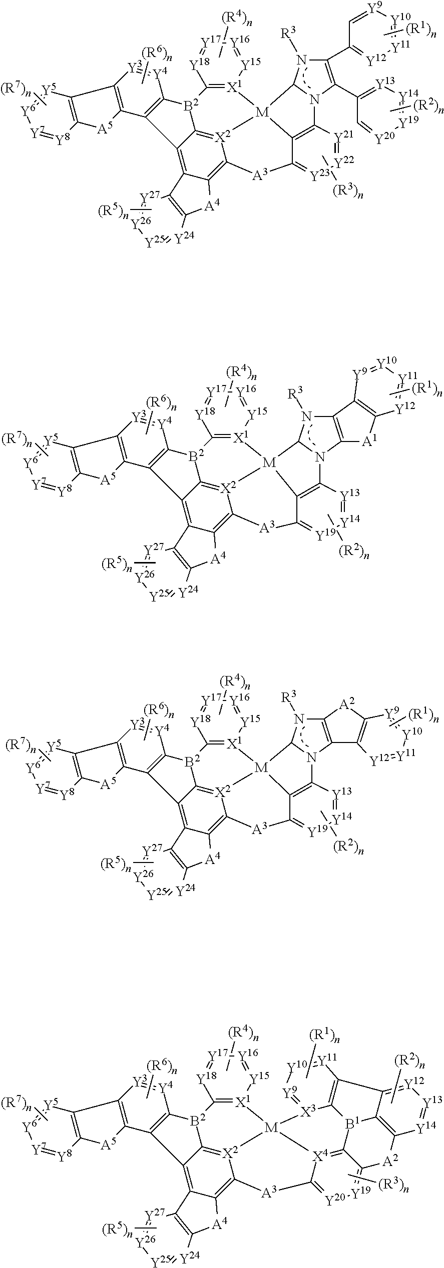

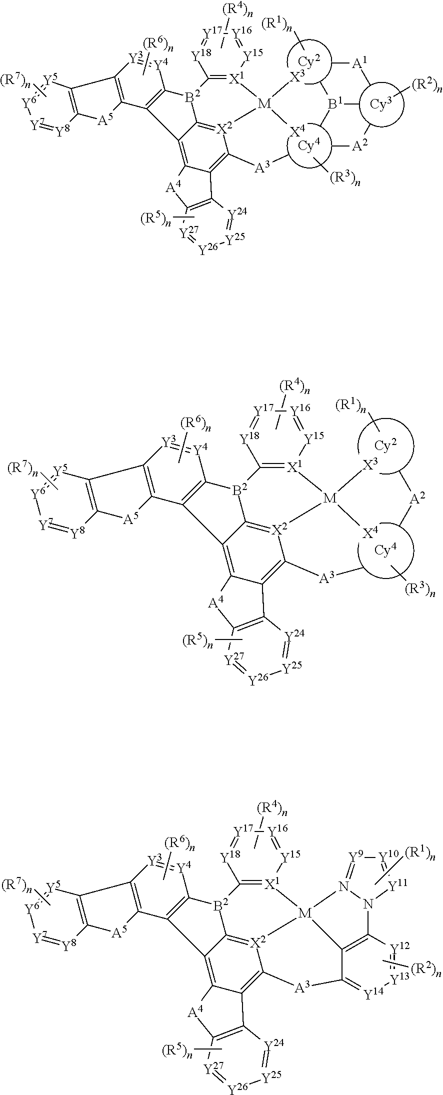

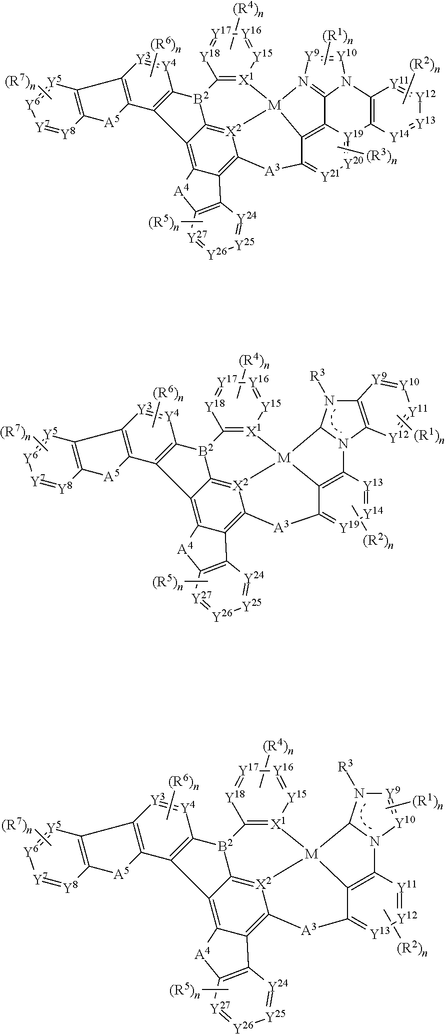

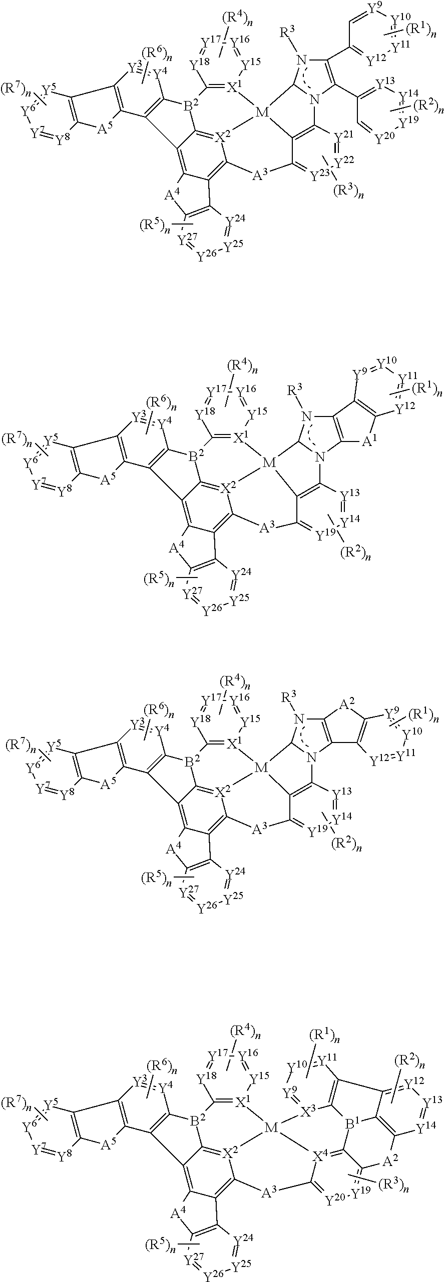

wherein:
M is platinum (Pt) or palladium (Pd).
each of X¹ and X² is coordinated with M and is independently N or C;
each of Y¹, Y², Y³, Y⁴, Y⁵, Y⁶, Y⁷, Y⁸, Y⁹, Y¹⁰, Y¹¹, Y¹², Y¹³, Y¹⁴, Y¹⁵, Y¹⁶, Y¹⁷, Y¹⁸, Y¹⁹, Y²⁰, Y²¹, Y²², Y²³, Y²⁴, Y²⁵, Y²⁶, and Y²⁷ is independently N, C, P, O, S, or Si;
each of Cy¹, Cy², Cy³, and Cy⁴ is independently substituted or unsubstituted aryl, cycloalkyl, cycloalkenyl, heteroaryl, heterocyclyl, carbene, or N-heterocyclic carbene;

Each of A¹, A², A³, A⁴, A⁵, A⁶, A⁷, and A⁸ is independently absent or present; wherein each of A¹, A², A³, A⁴, A⁵, A⁶, A⁷, and A⁸ present represents a single bond; CR¹R², CR¹=CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

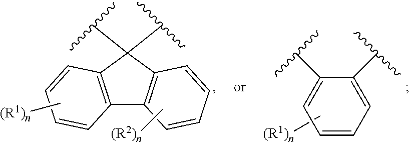

each of B¹ and B² is independently CR¹, SiR¹, GeR¹, N, P, P═O, As, As═O, B, R³Bi═O, or Bi;
each of R¹, R², R³, R⁴, R⁵, R⁶, R⁷, and R⁸ is independently absent or present as a single substituent or multiple substituents, valency permitting, and each R¹, R², R³, R⁴, R⁵, and R⁶ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, B¹ is not present; B² is not present; Cy¹ is heteroaryl; X¹ is N; and

the structure

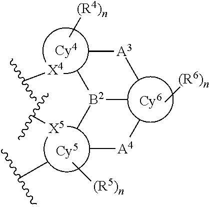

represents

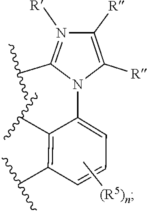

wherein R′ and R″ each represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof; and each occurrence of R″ represents aryl or heteroaryl;
wherein any two adjacent groups R′ or R″ optionally join to form a fused ring which is optionally further substituted.

In one embodiment, B¹ is not present; Cy¹ represents a heteroaryl; X¹ is N; and two adjacent substituents R¹, two adjacent substituents R², two adjacent substituents R³, or two adjacent substituents R⁷ are present and together represent a group of Formula C.

In one embodiment, the compound is represented by one of the following structures, which together represent LIST 9:

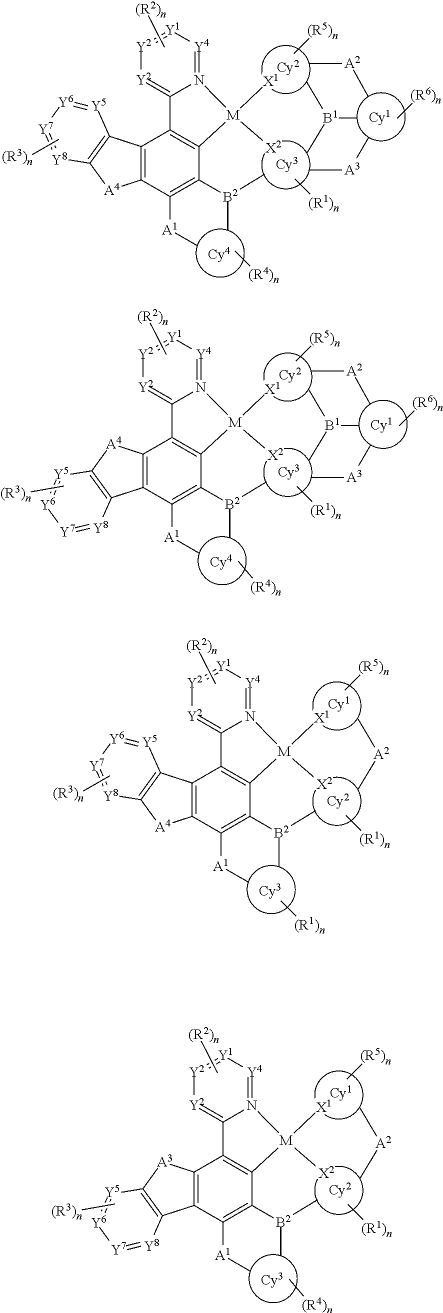

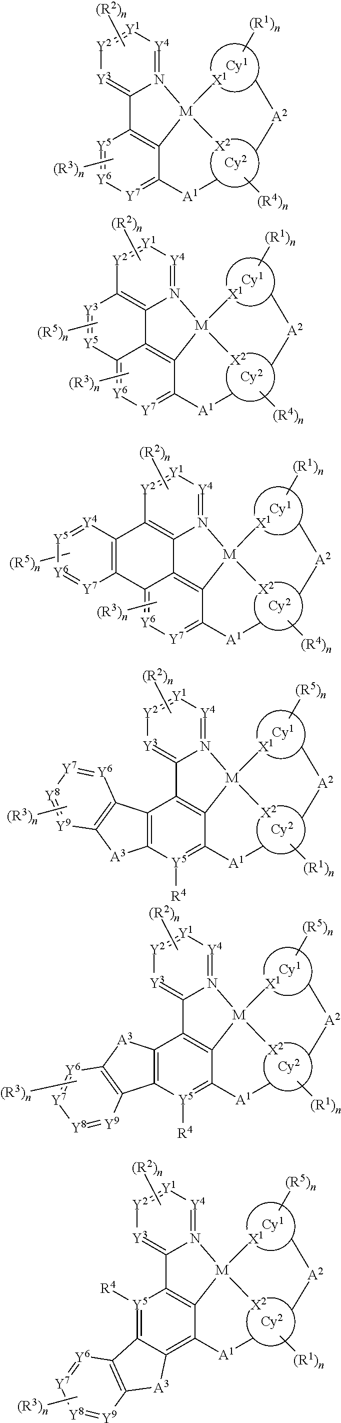

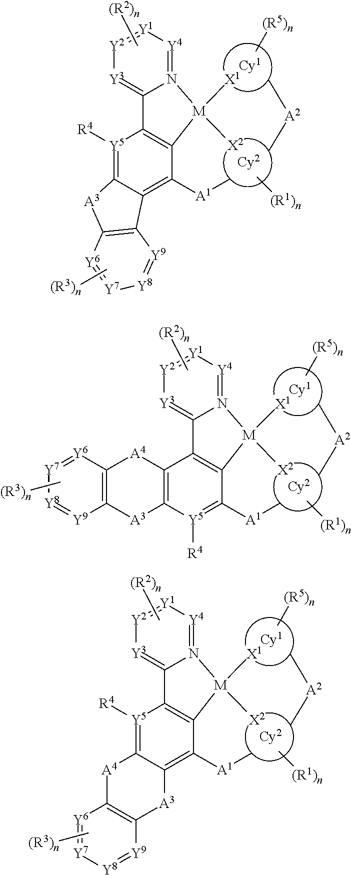

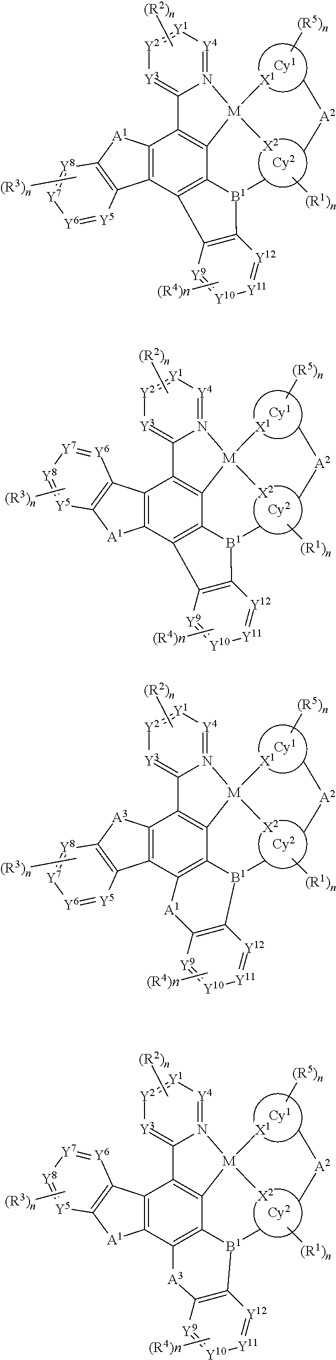

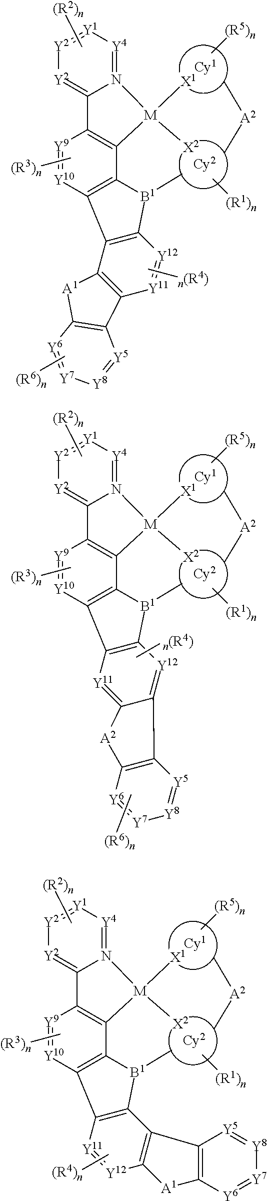

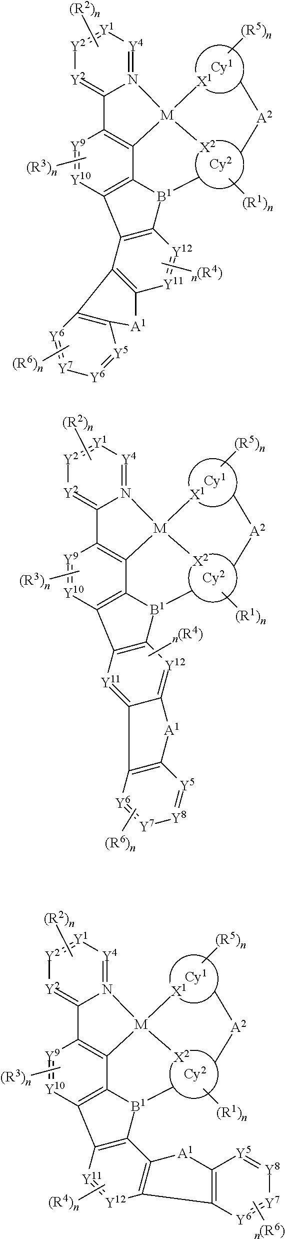

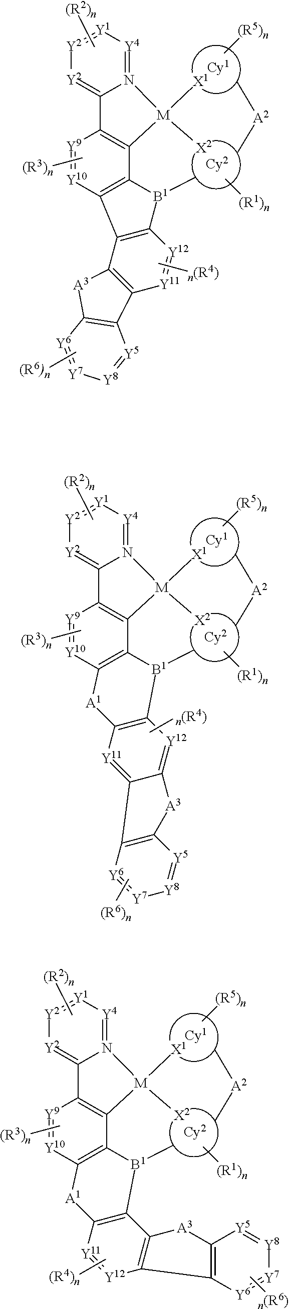

wherein:
M is platinum (Pt) or palladium (Pd);
each of X¹ and X² is coordinated with M and is independently N or C;
Each of Y¹, Y², Y³, Y⁴, Y⁵, Y⁶, Y⁷, and Y⁸ is independently N, C, P, O, S, or Si;
Each of Cy¹, Cy², Cy³, Cy⁴, and Cy⁵ is independently substituted or unsubstituted aryl, cycloalkyl, cycloalkenyl, heteroaryl, heterocyclyl, carbene, or N-heterocyclic carbene;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O,

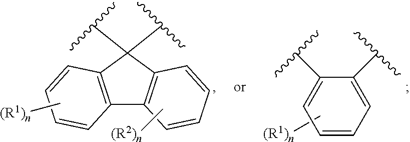

Each of B¹ and B² is independently CR¹, SiR¹, GeR¹, N, P, P═O, As, As═O, B, R³Bi═O, or Bi;
each of R¹, R², R³, R⁴, R⁵, and R⁶ is independently absent or present as a single substituent or multiple substituents, valency permitting, and each R¹, R², R³, R⁴, R⁵, and R⁶ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by one of the following structures, which together represent LIST 10:

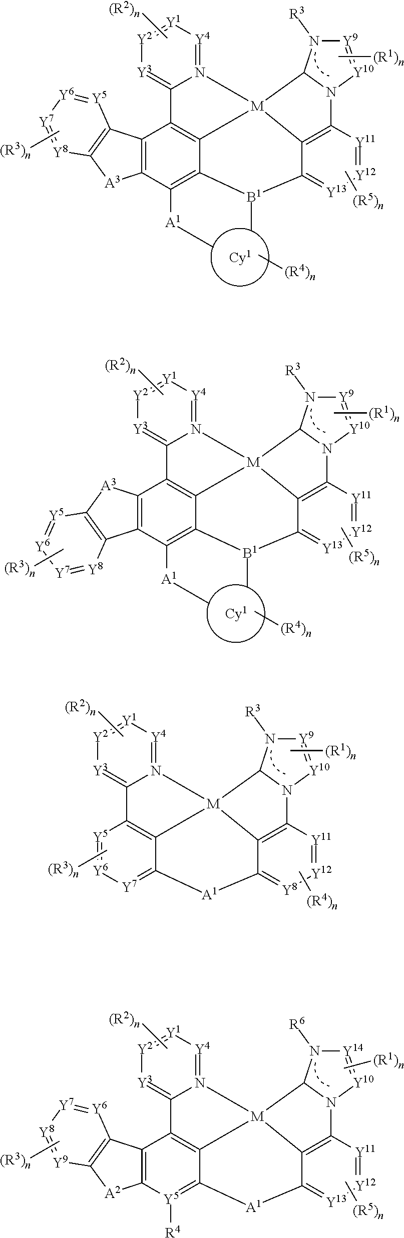

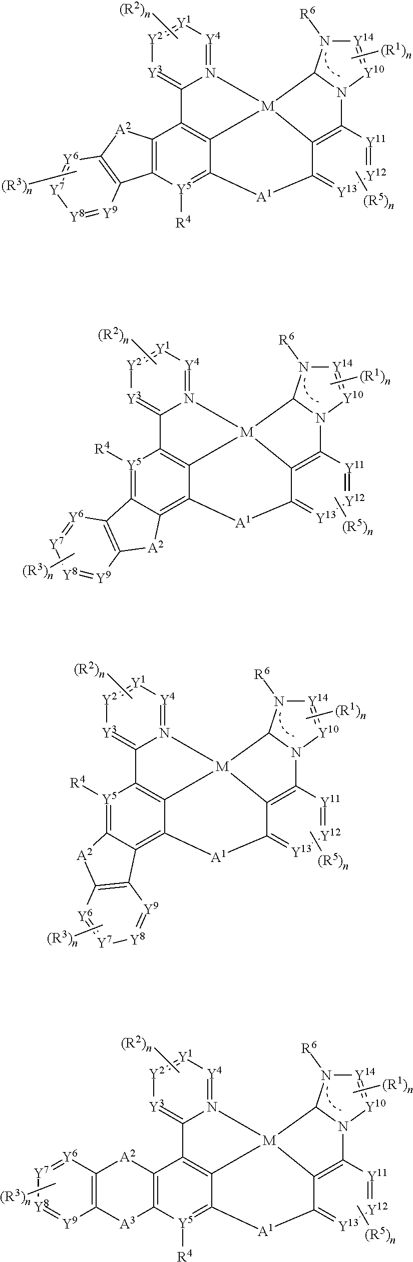

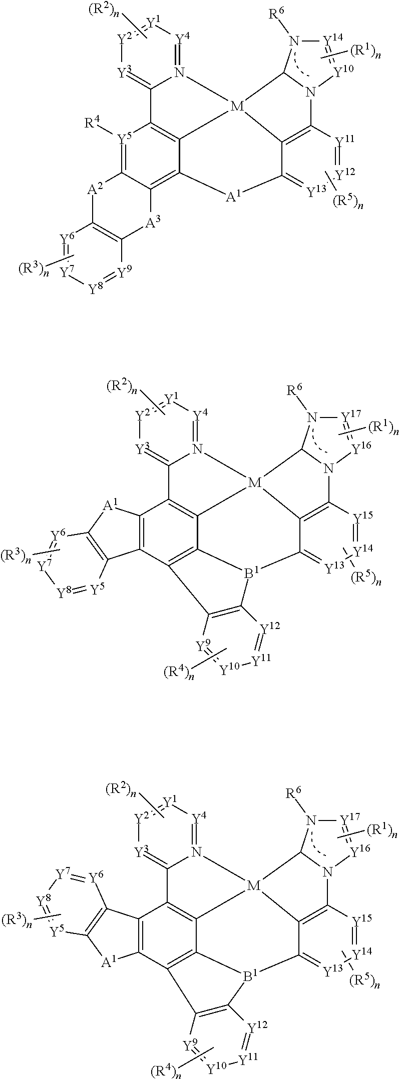

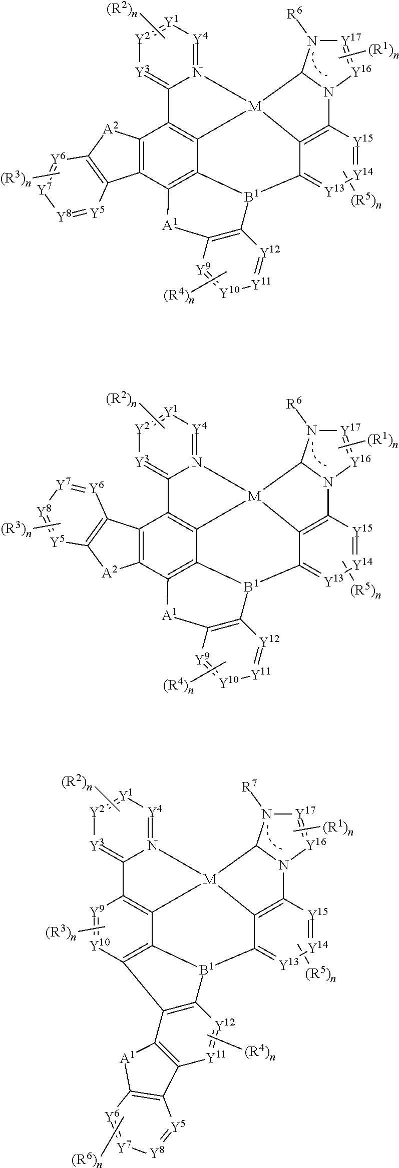

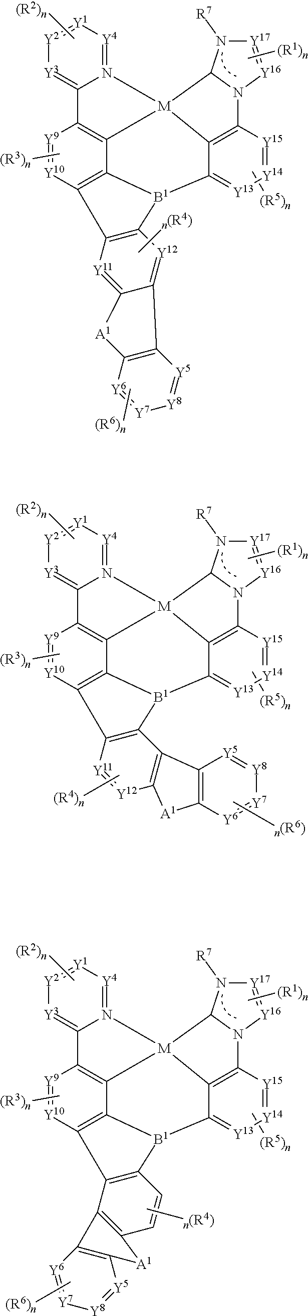

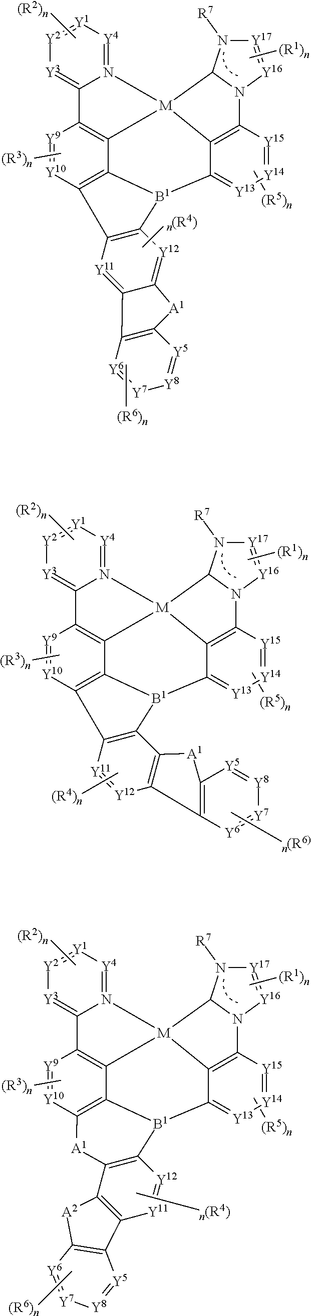

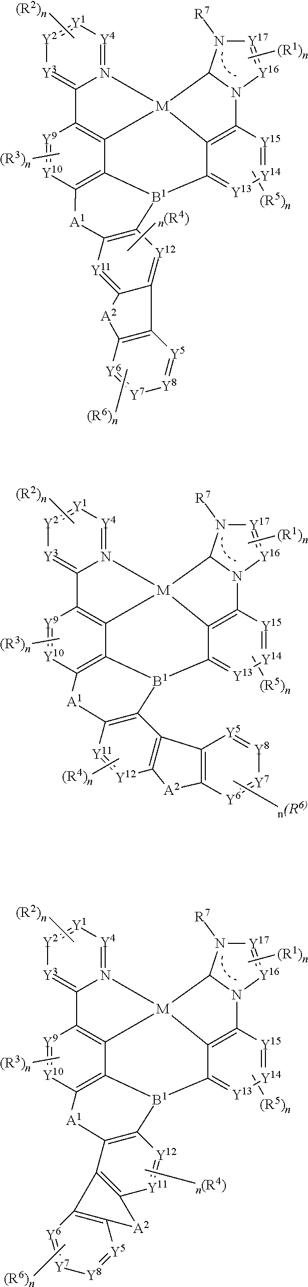

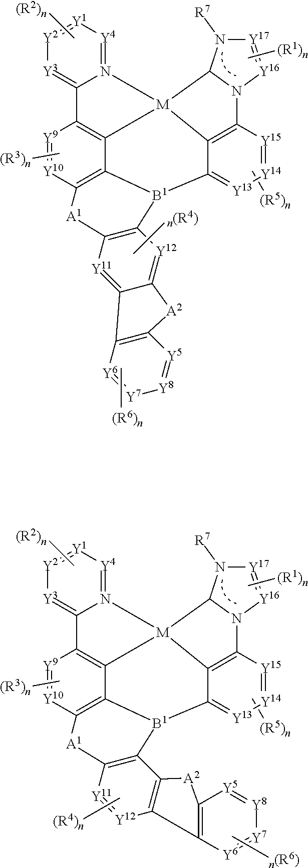

wherein:
M is platinum (Pt) or palladium (Pd);
Each of Y¹, Y², Y³, Y⁴, Y⁵, Y⁶, Y⁷, Y⁸, Y⁹, Y¹⁰, Y¹¹, Y¹², Y¹³, Y¹⁴, and Y¹⁵ is independently N, C, P, O, S, or Si;
each of A¹, A², A³, and A⁴ is independently absent or present; wherein each of A¹, A², A³, and A⁴ present represents a single bond; CR¹R², CR¹═CR², C≡C, C═O, C═S, SiR¹R², GeR¹R², NR³, PR³, R³P═O, AsR³, R³As═O, O, S, S═O, SO₂, Se, Se=O, SeO₂, BR³, BiR³, R³Bi═O,

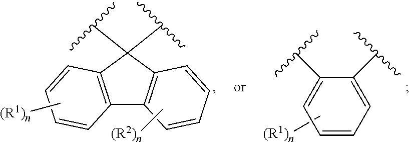

each of B¹ and B² is independently CR¹, SiR¹, GeR¹, N, P, P═O, As, As═O, B, R³Bi═O, or Bi;
R^{bulky} represents R^{X}.
each of R¹, R², R³, R⁴, R⁵, R⁶, and R⁷ is independently absent or present as a single substituent or multiple substituents, valency permitting, and each R¹, R², R³, R⁴, R⁵, R⁶, and R⁷ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a ring which is optionally further substituted.

In one embodiment, the compound is represented by one of the following structures, which together represent LIST 11:

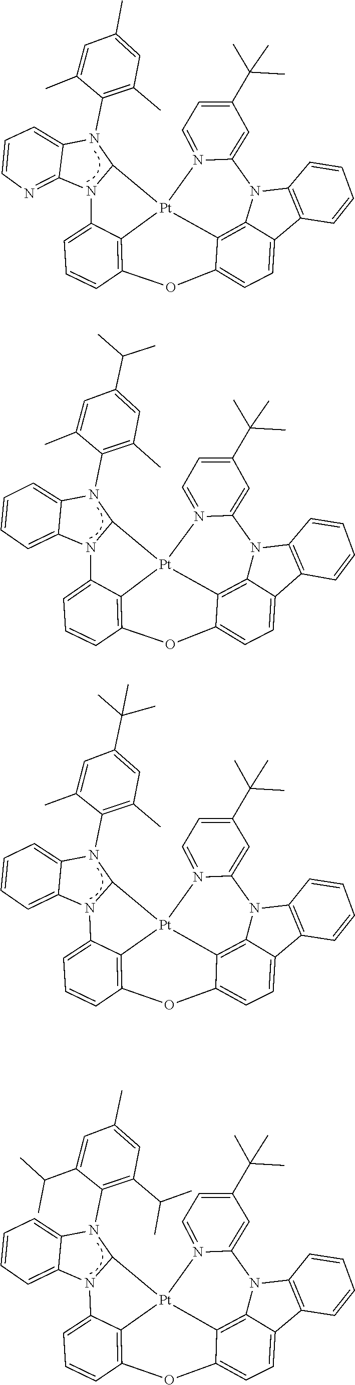

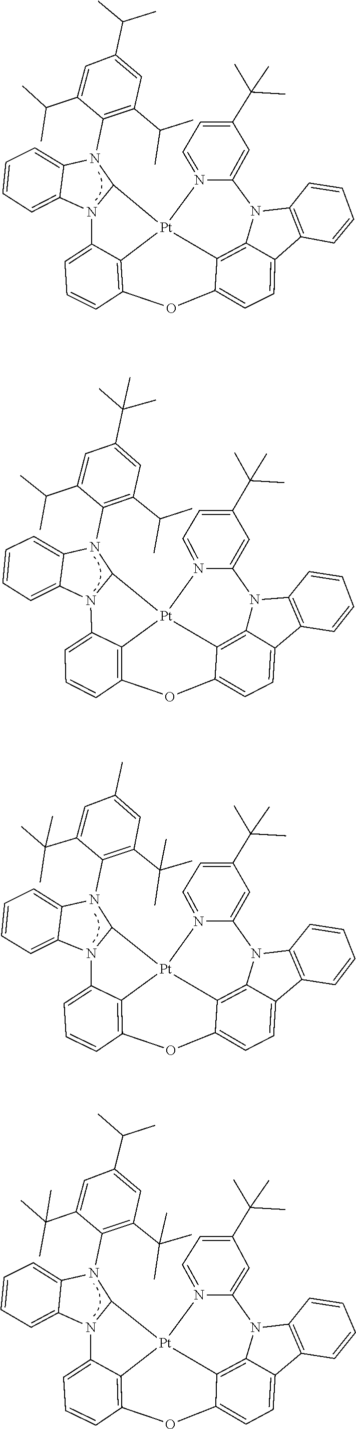

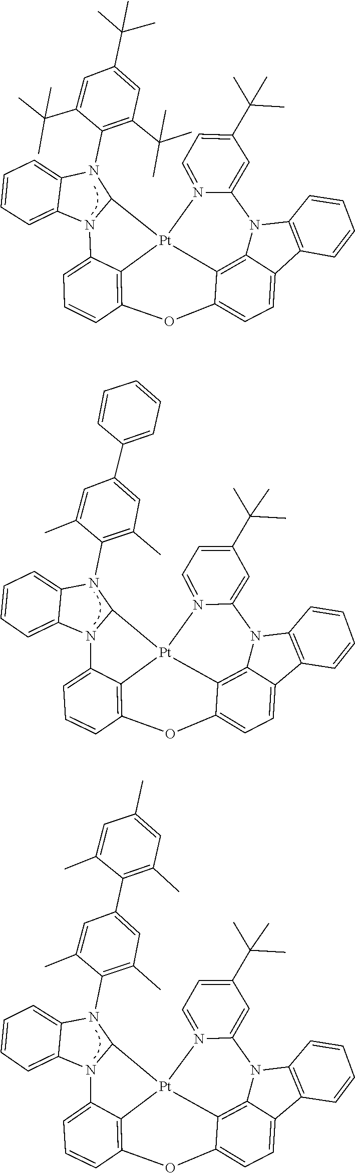

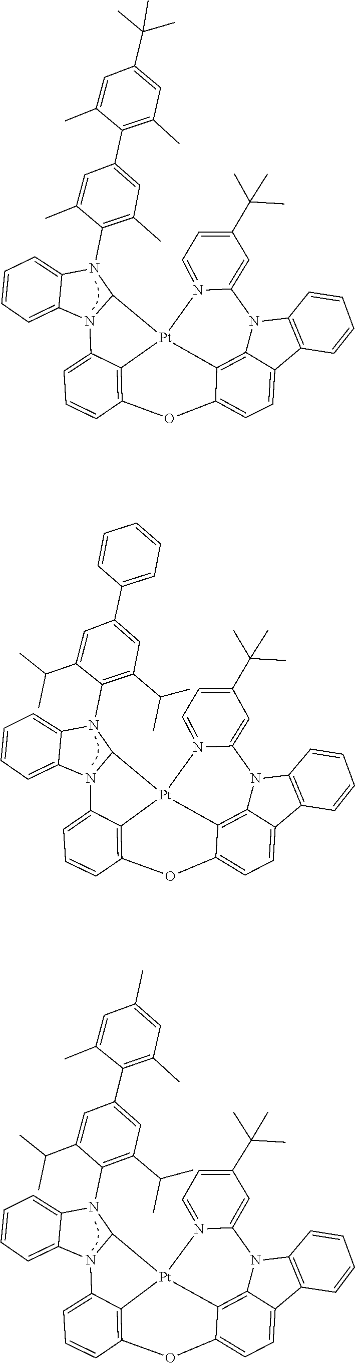

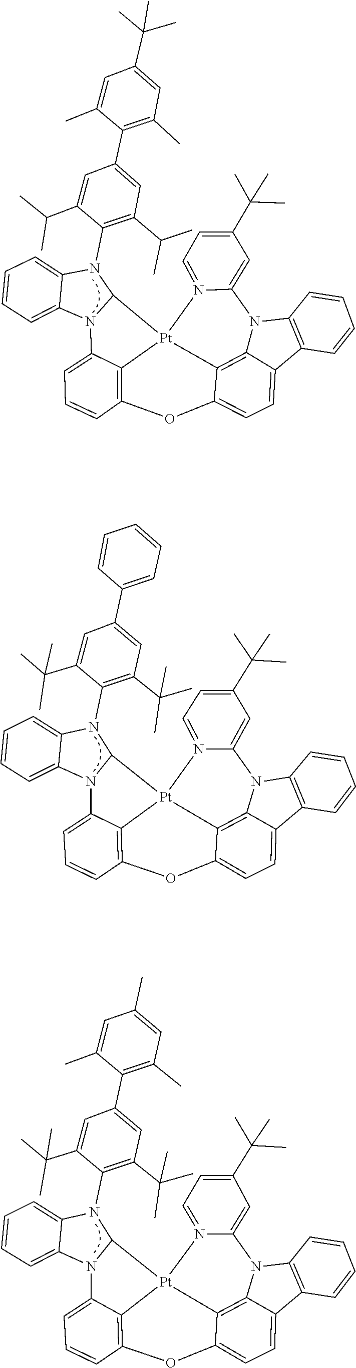

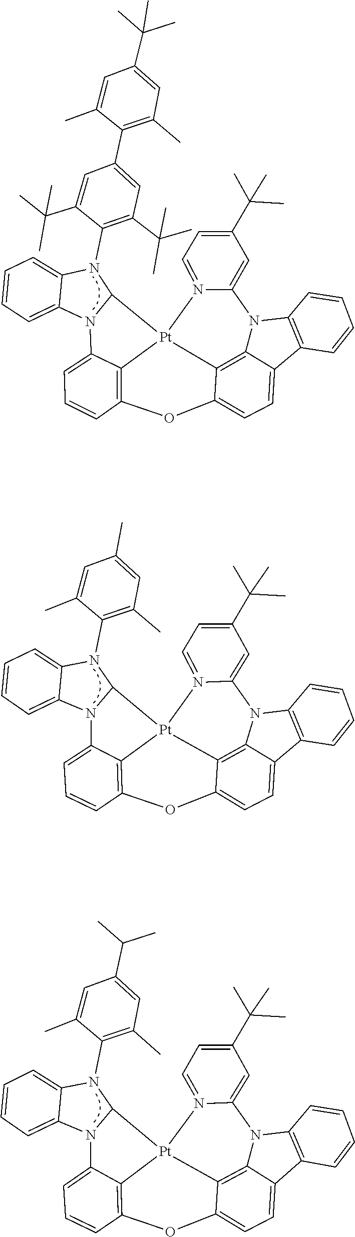

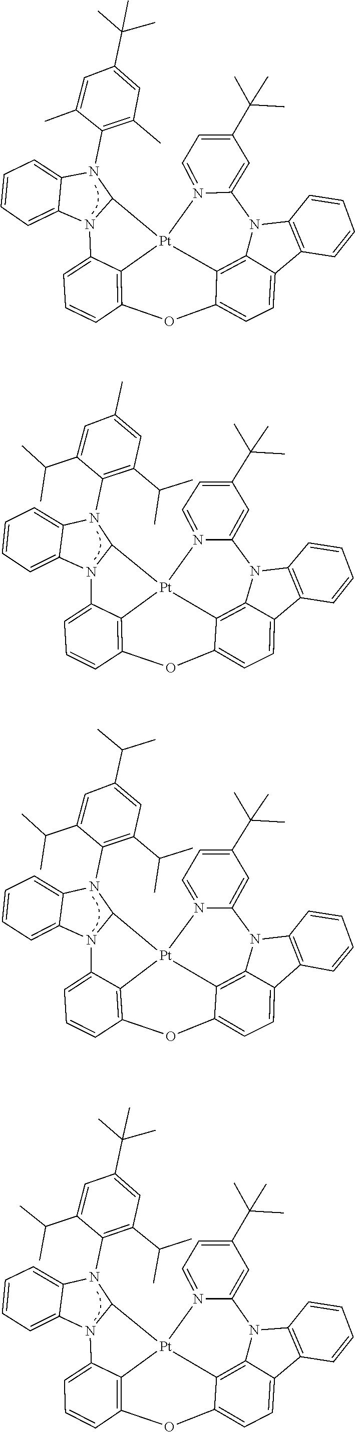

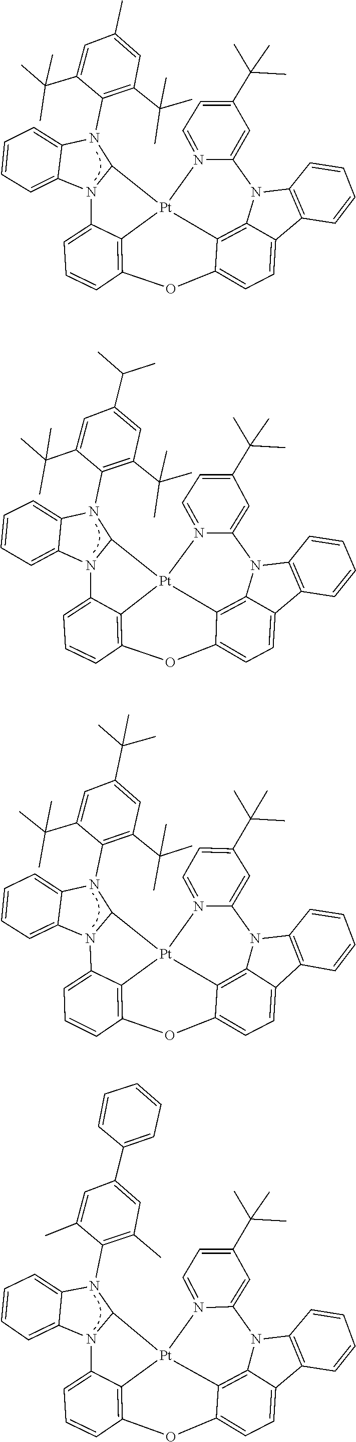

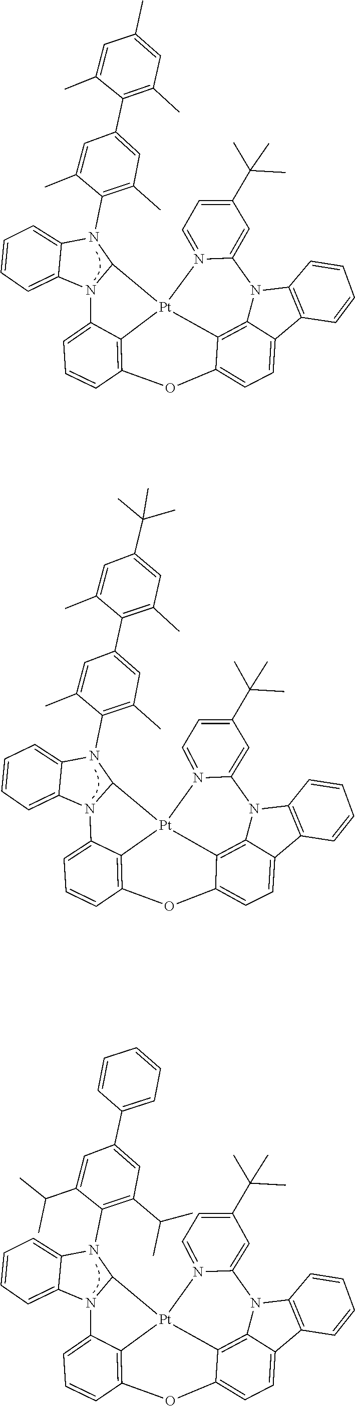

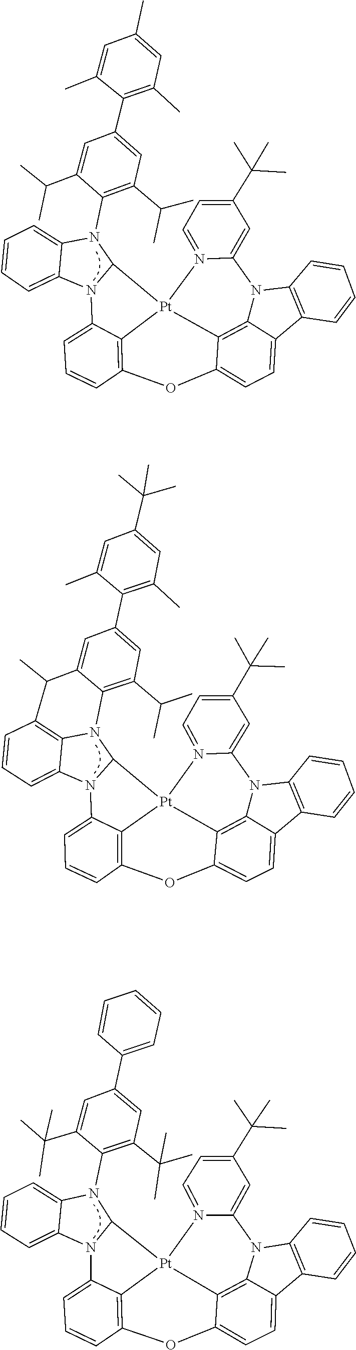

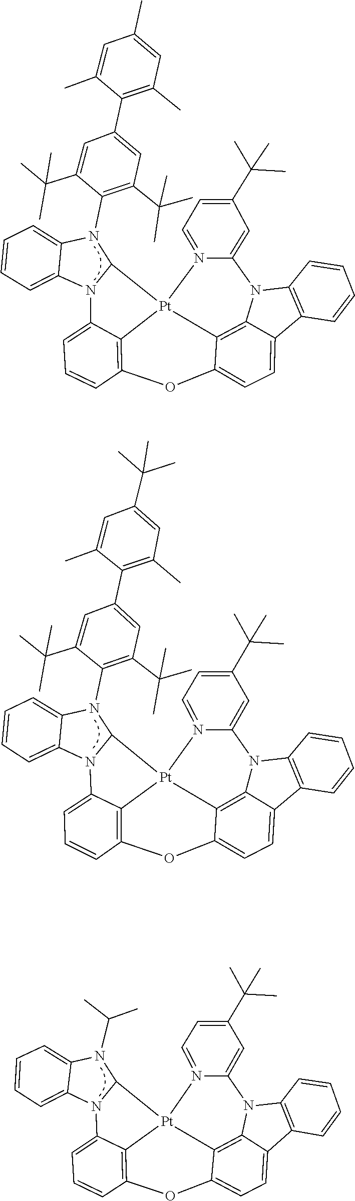

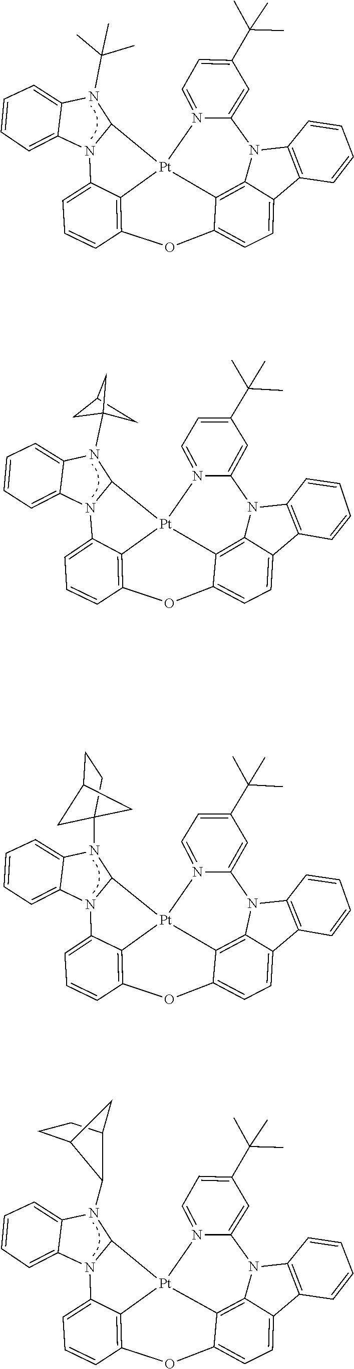

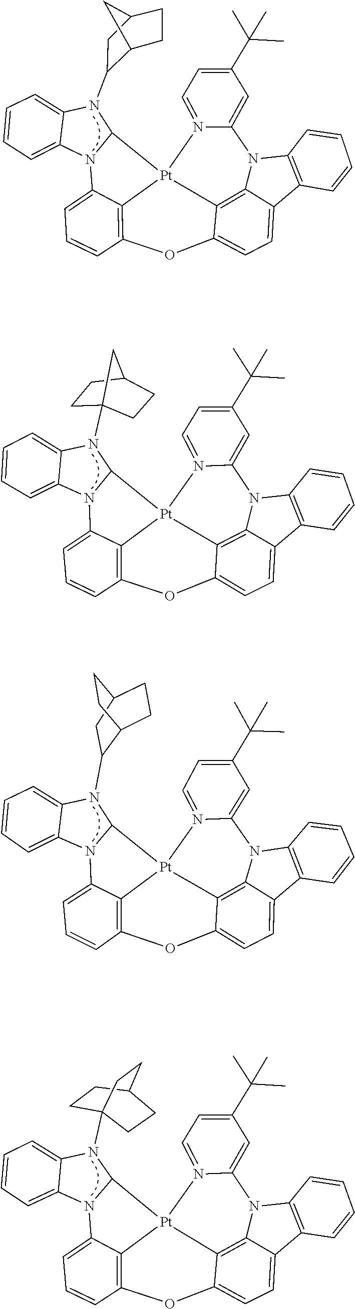

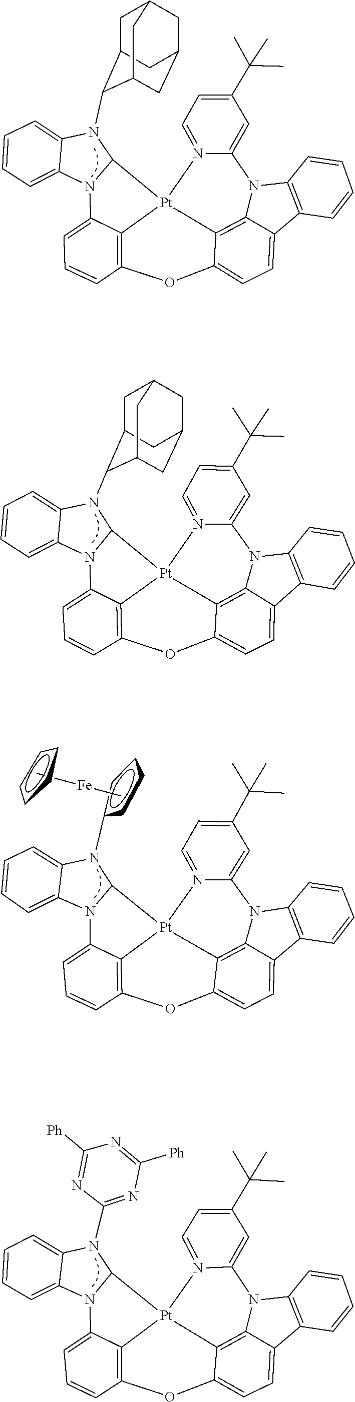

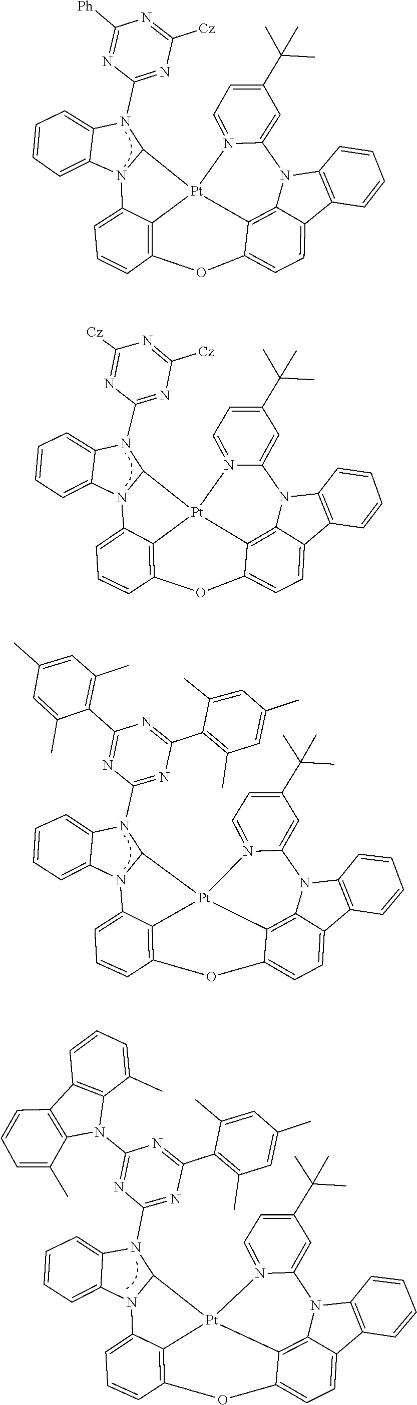

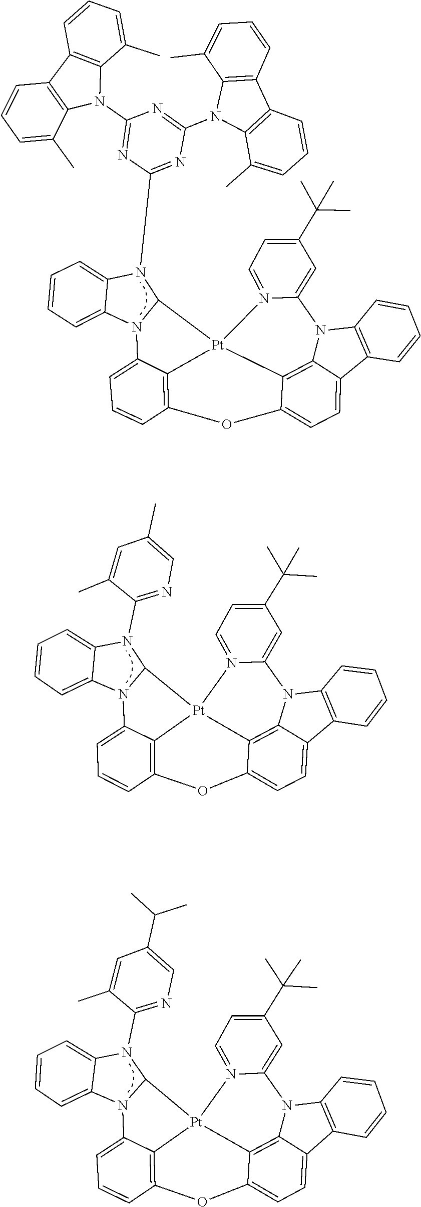

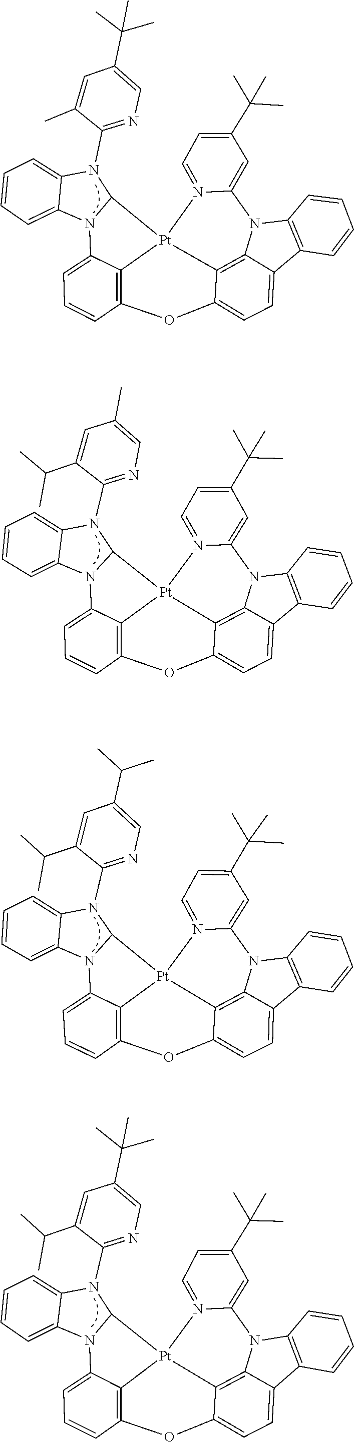

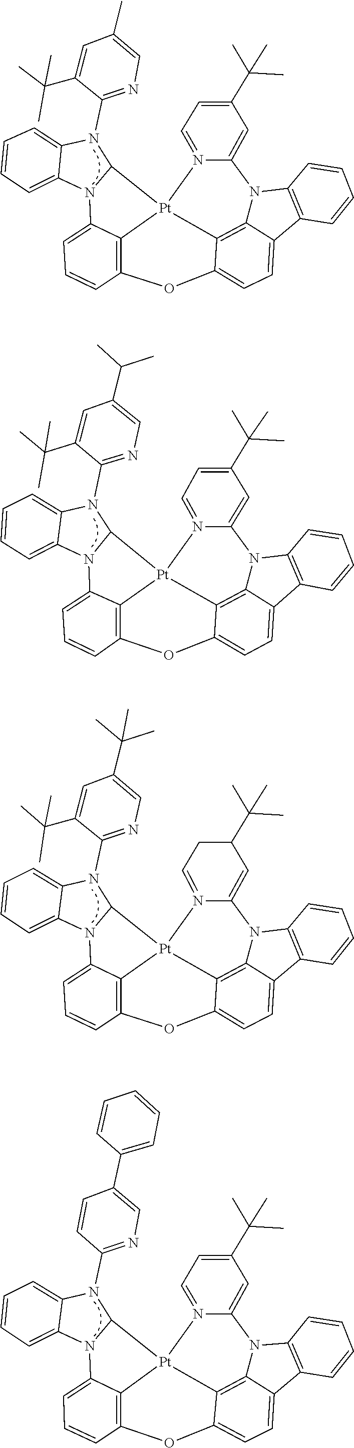

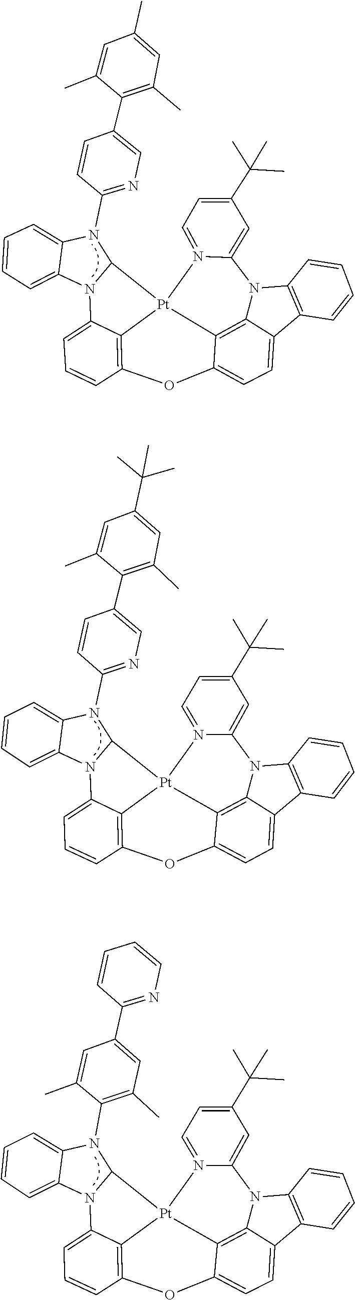

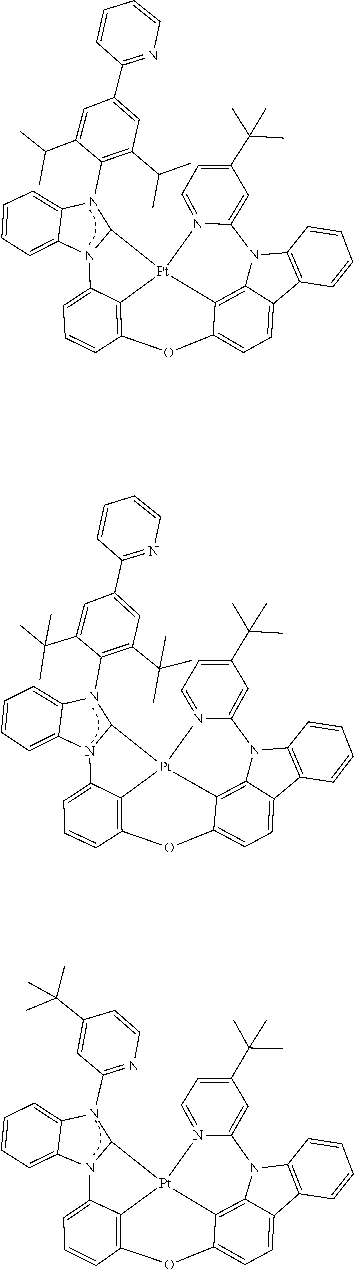

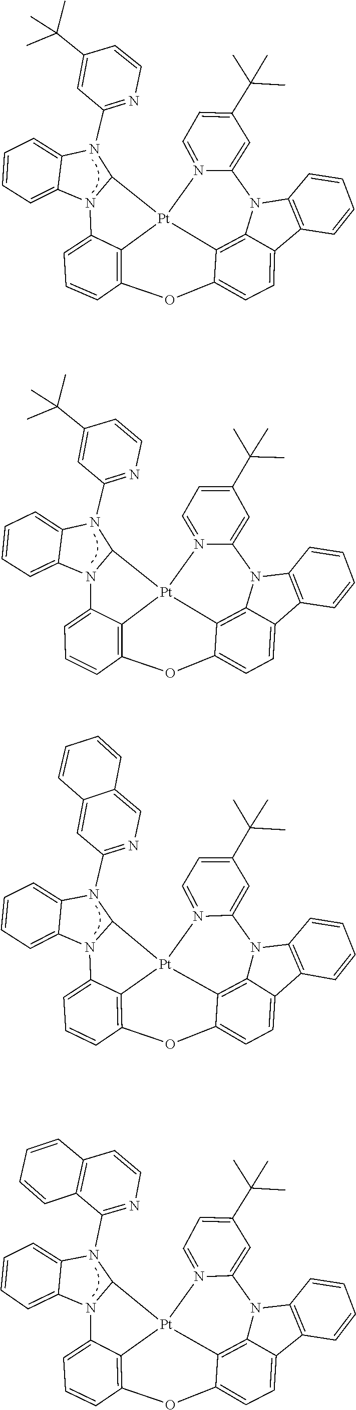

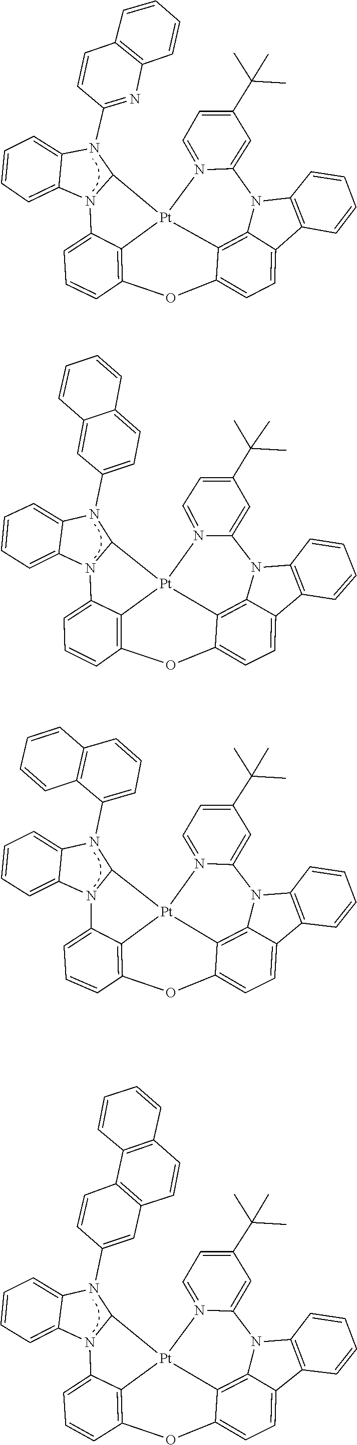

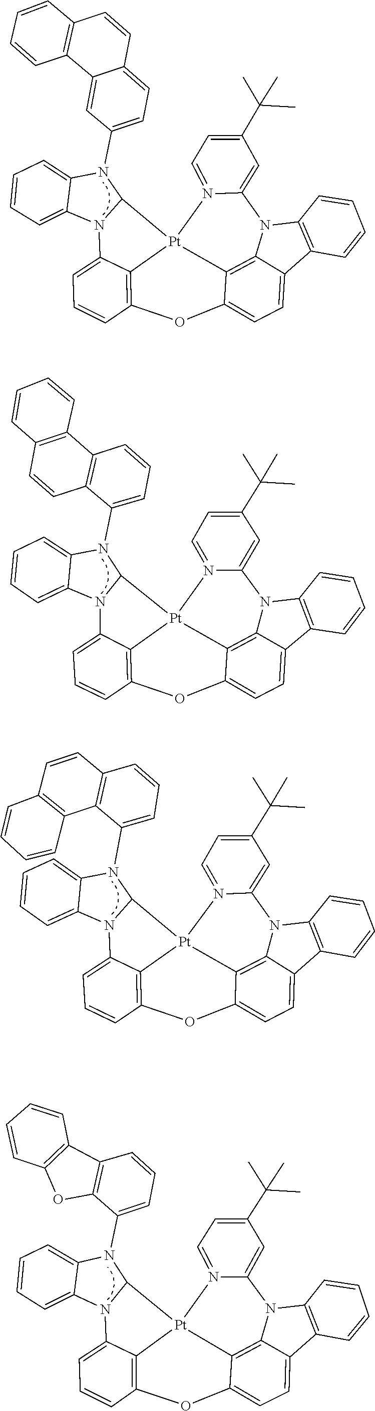

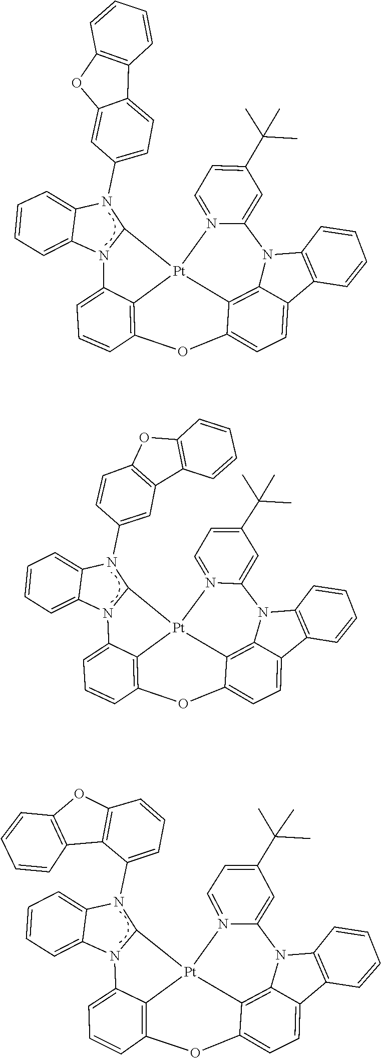

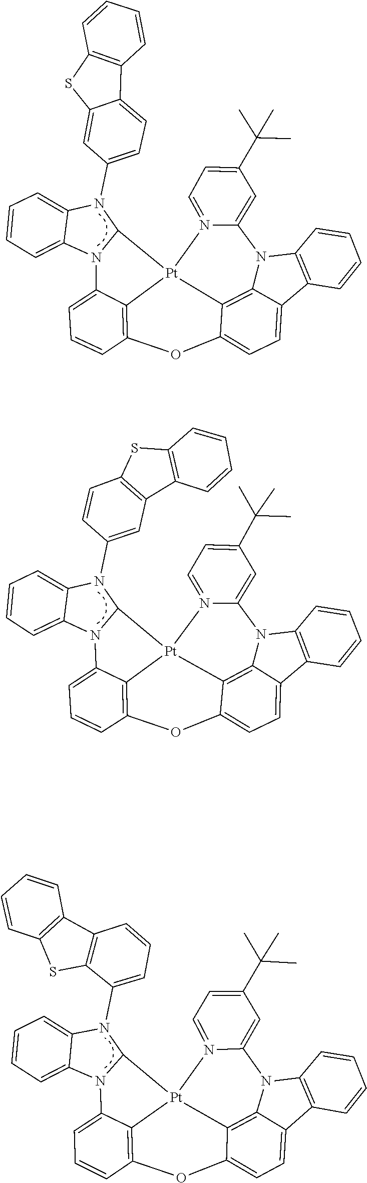

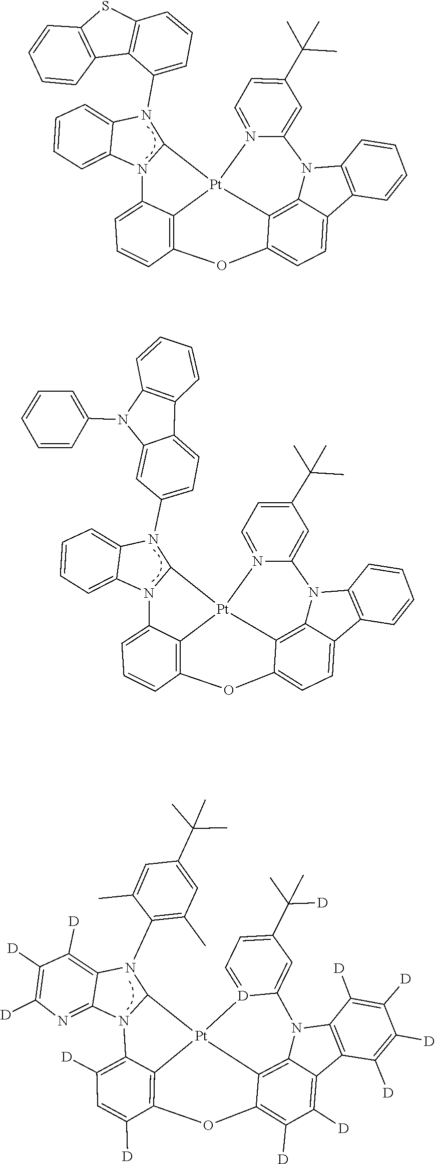

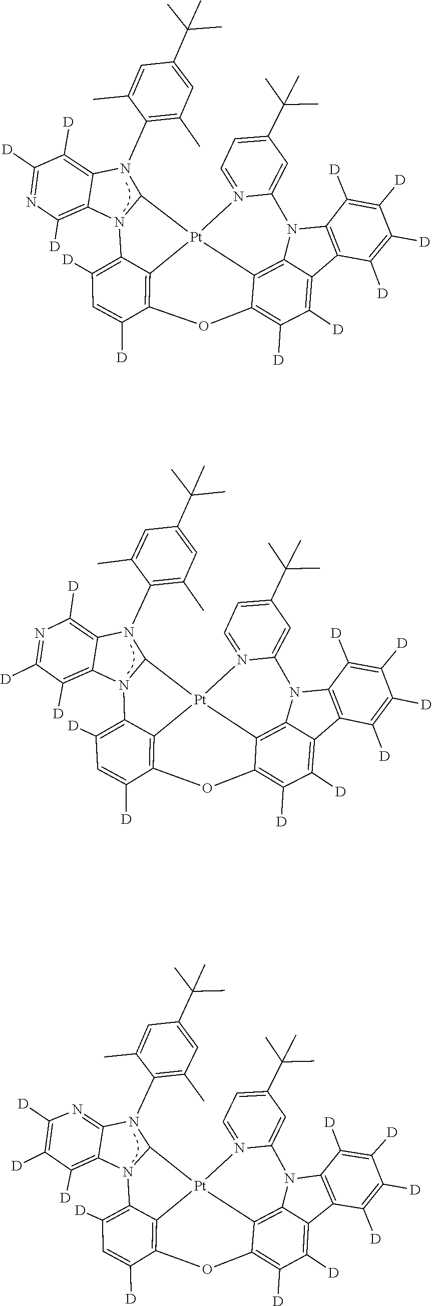

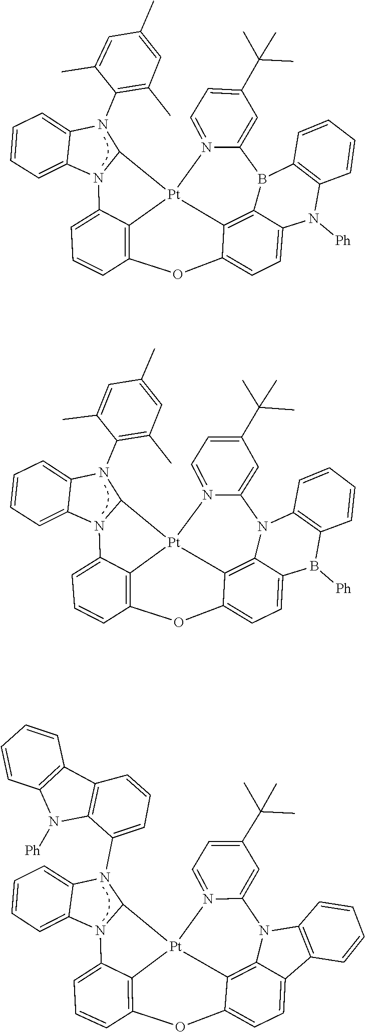

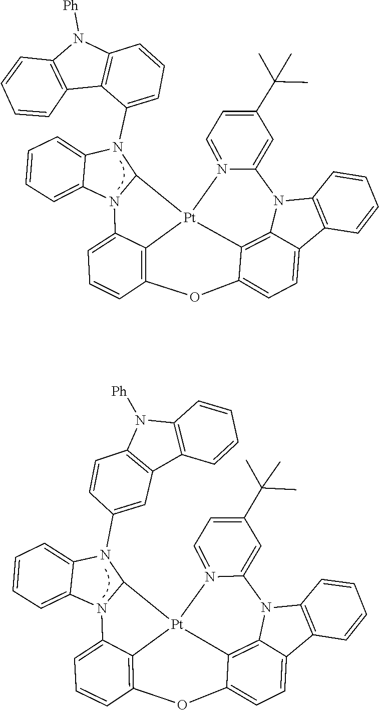

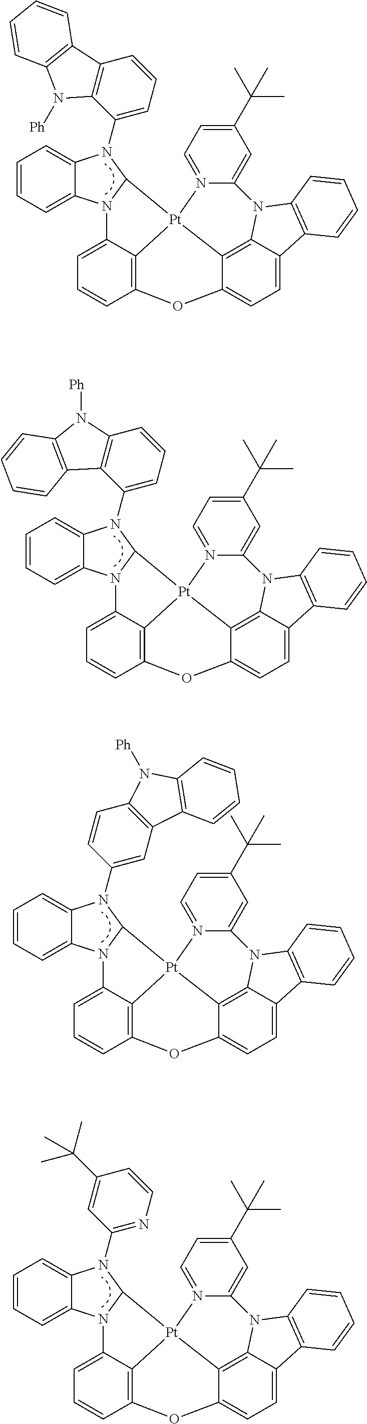

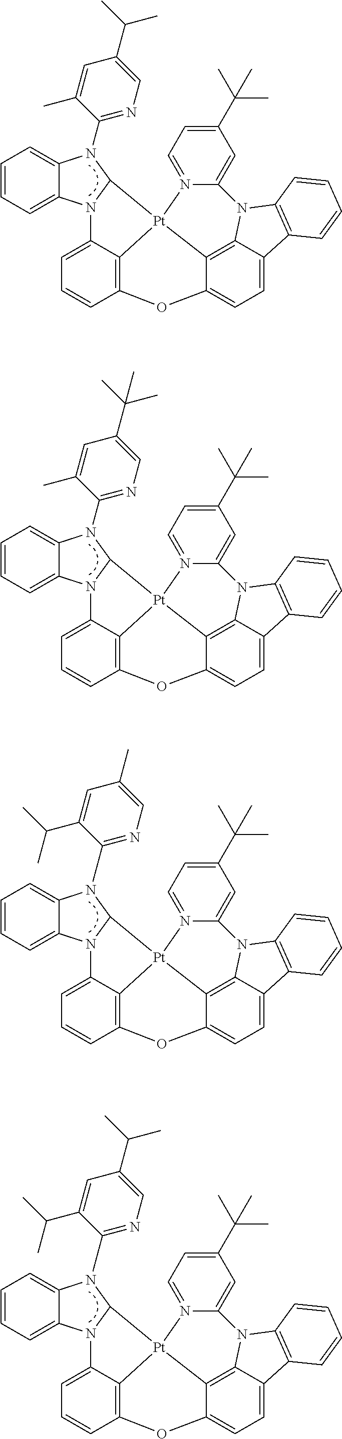

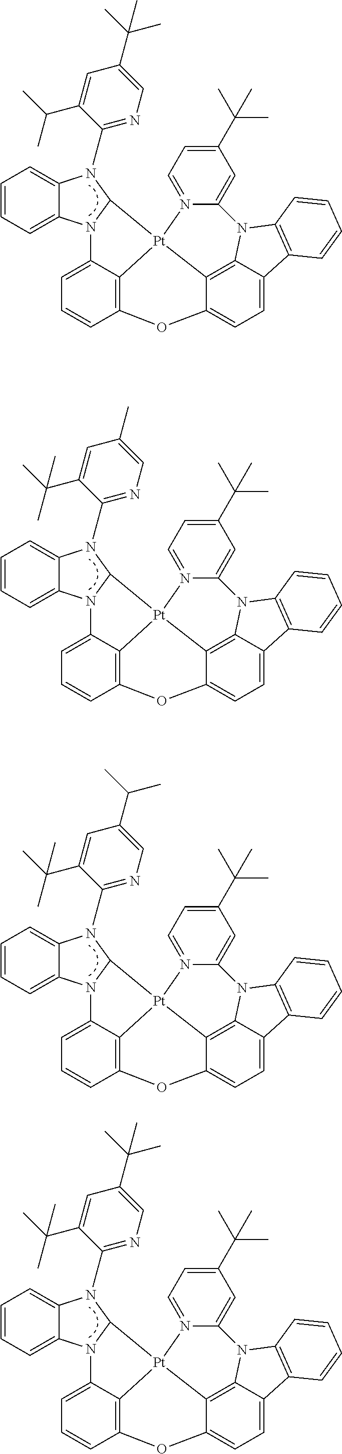

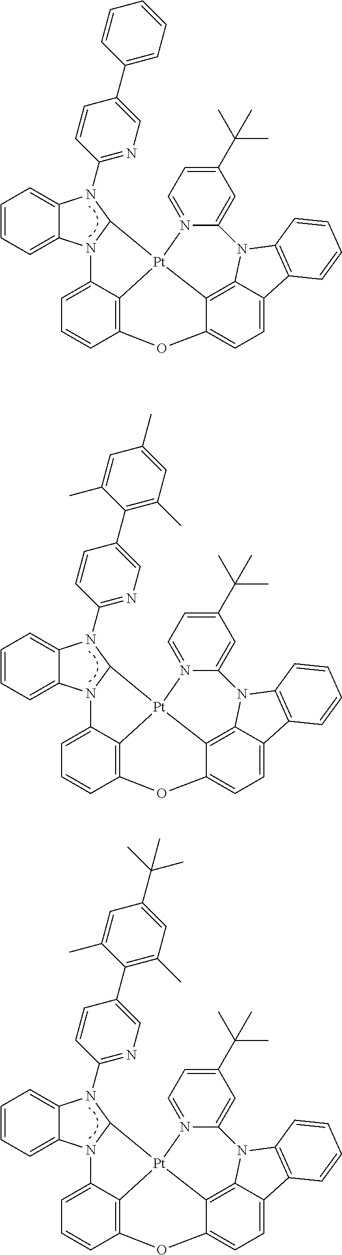

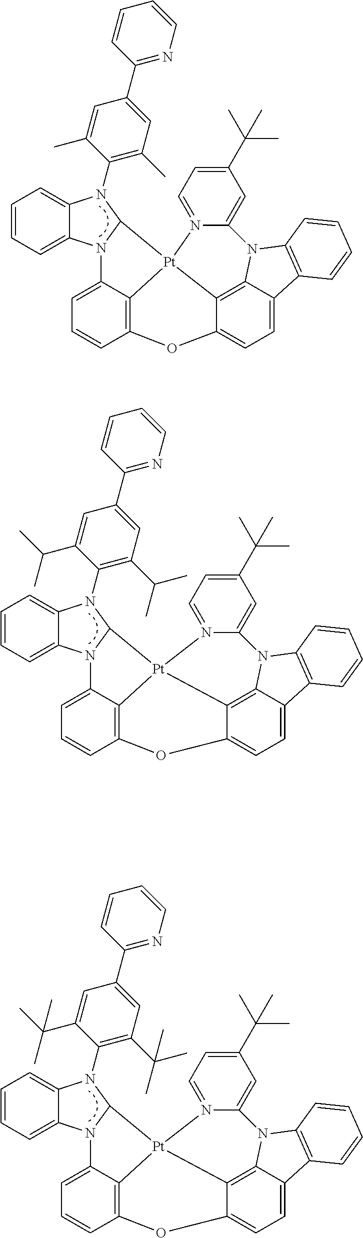

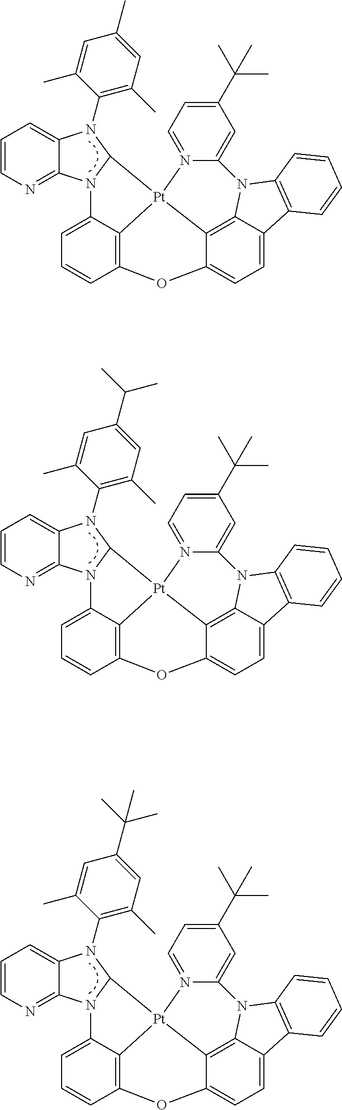

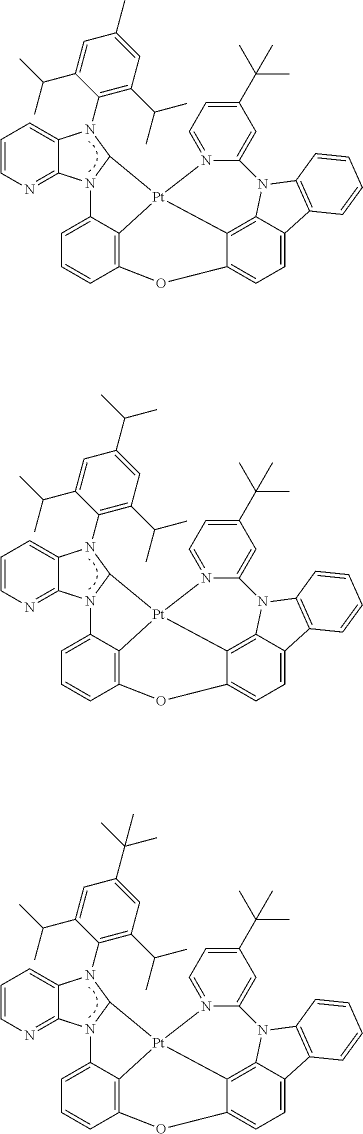

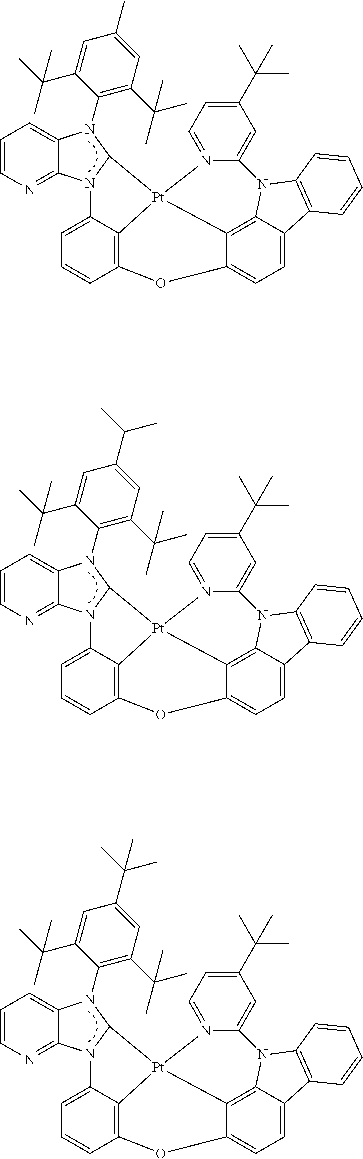

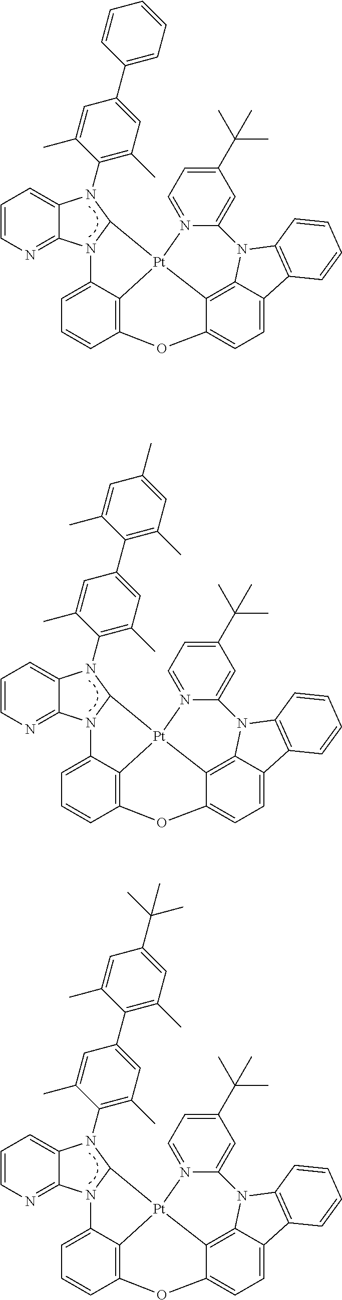

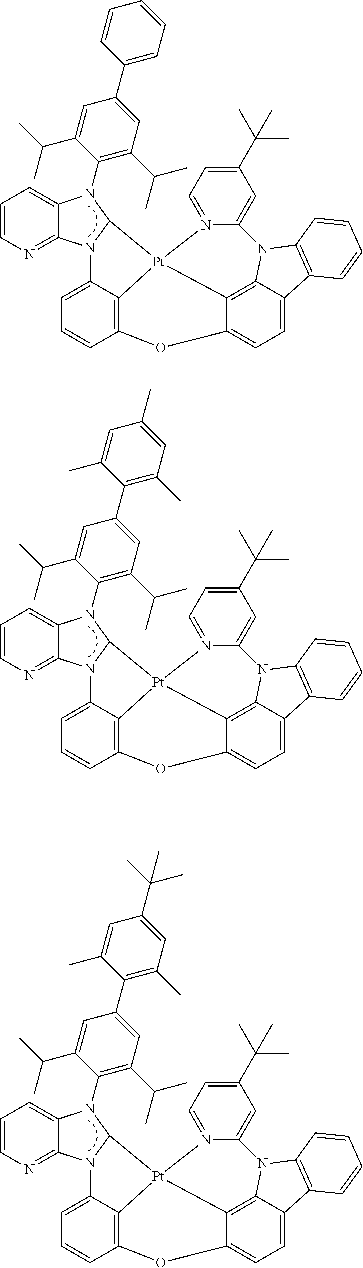

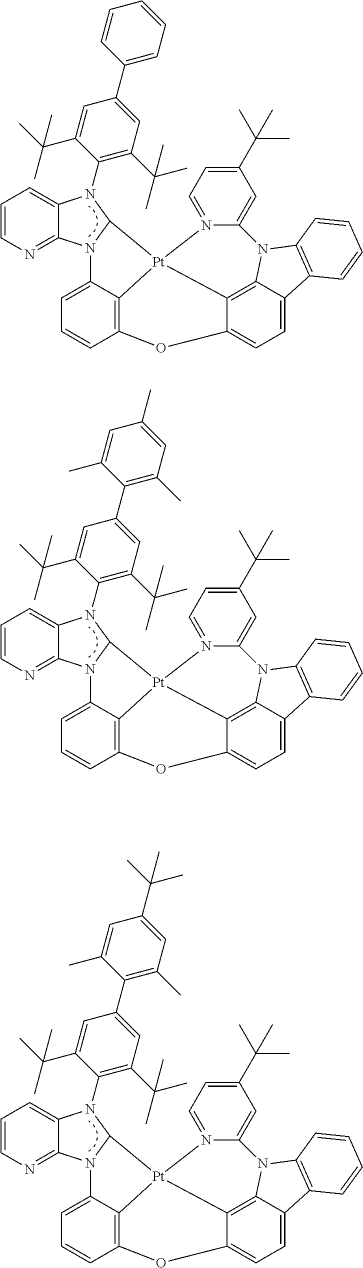

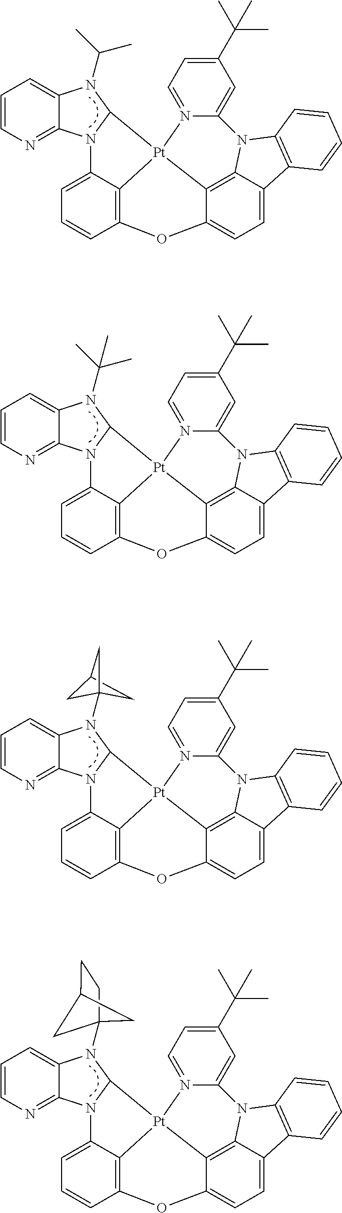

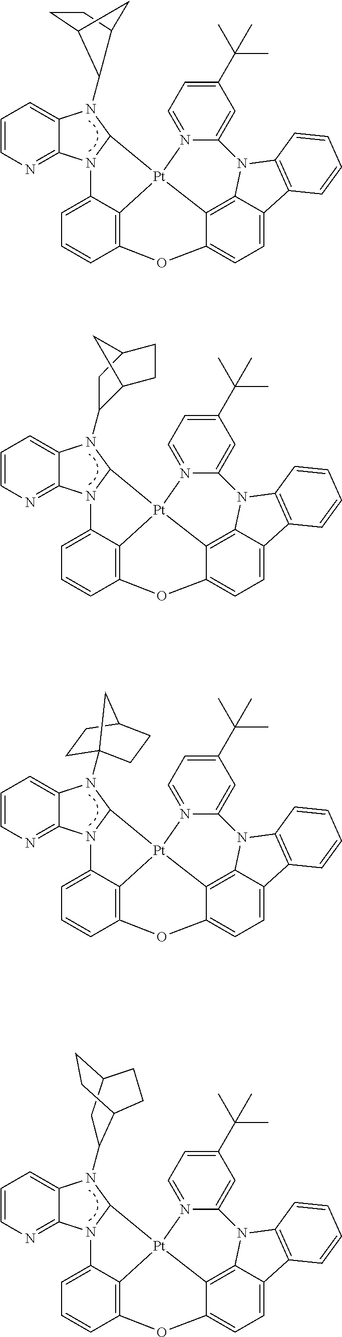

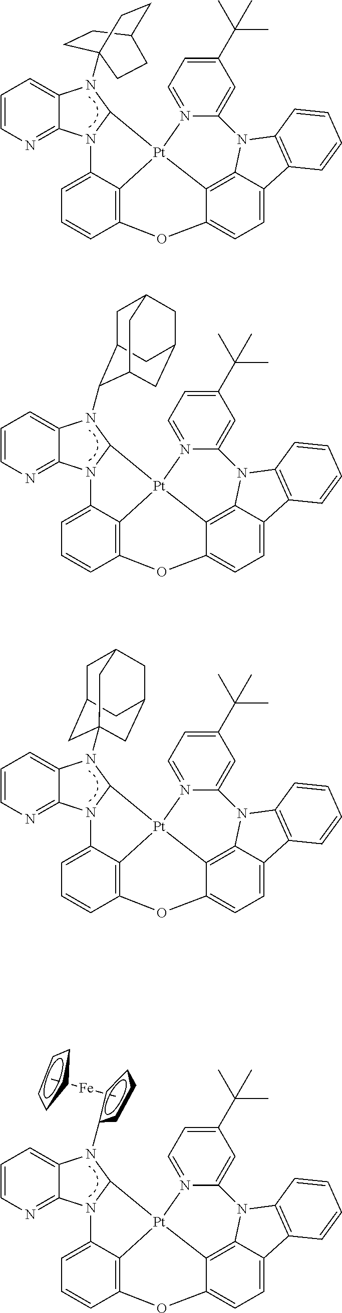

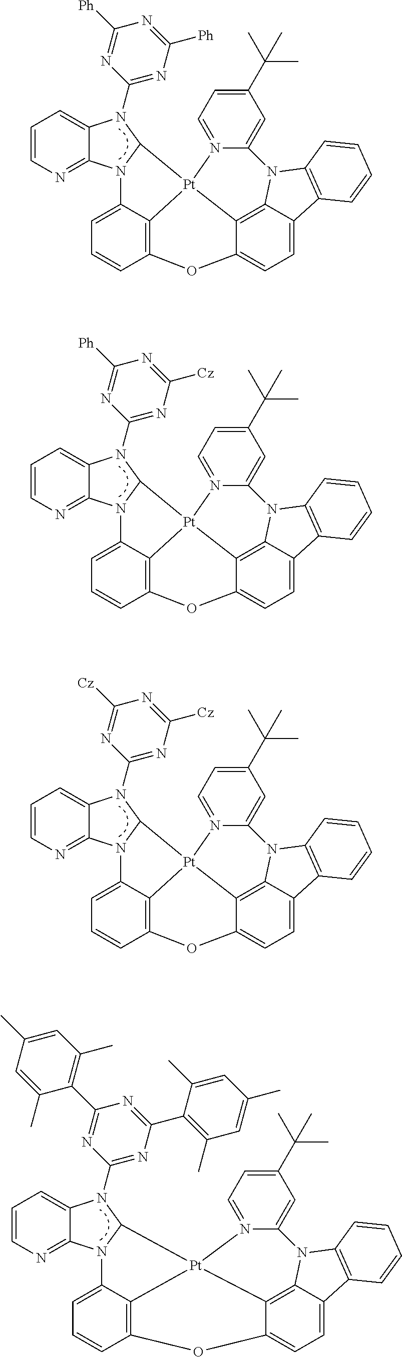

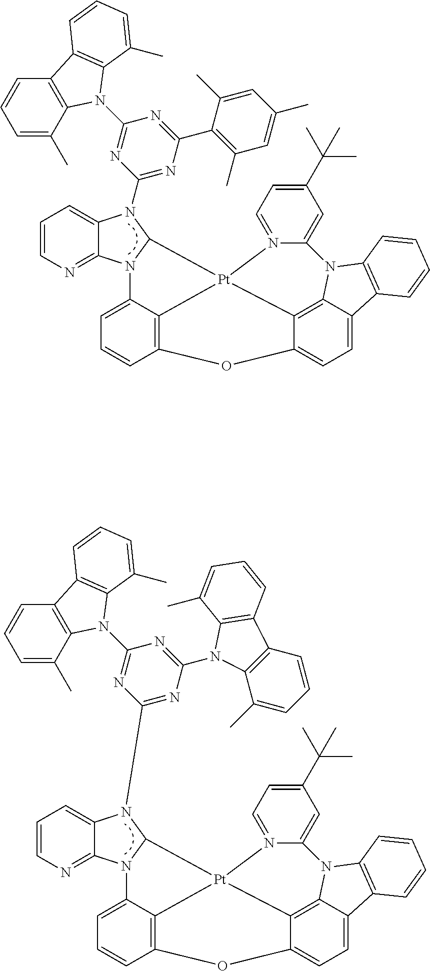

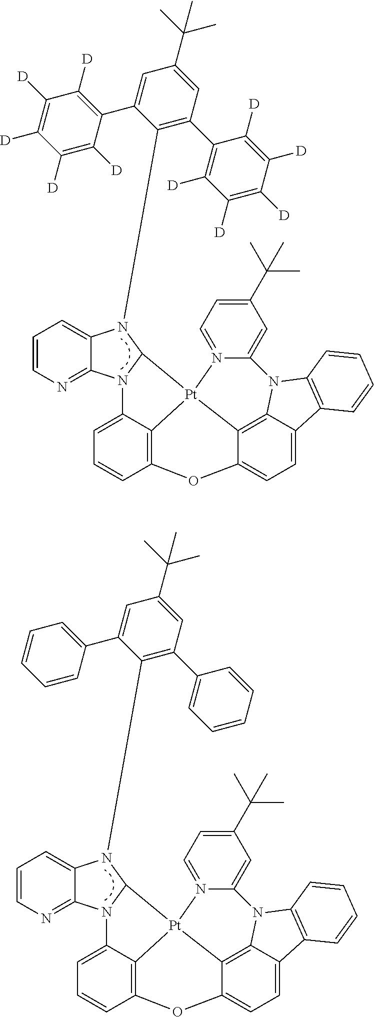

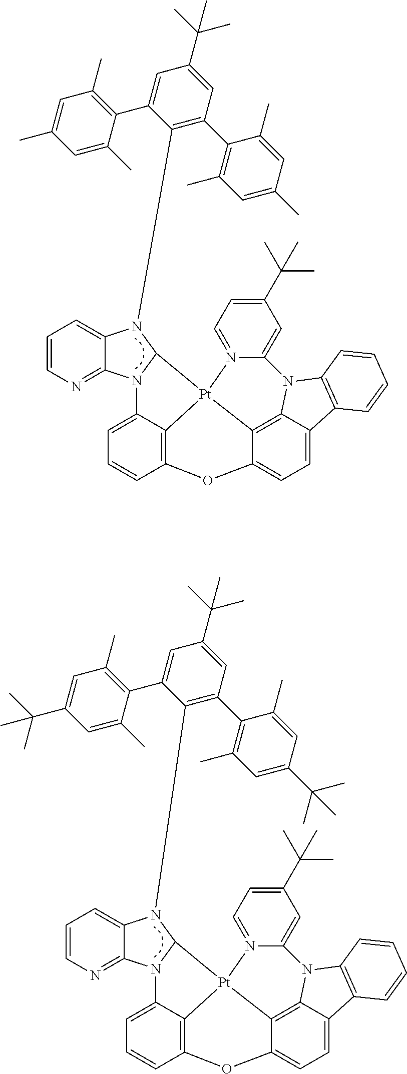

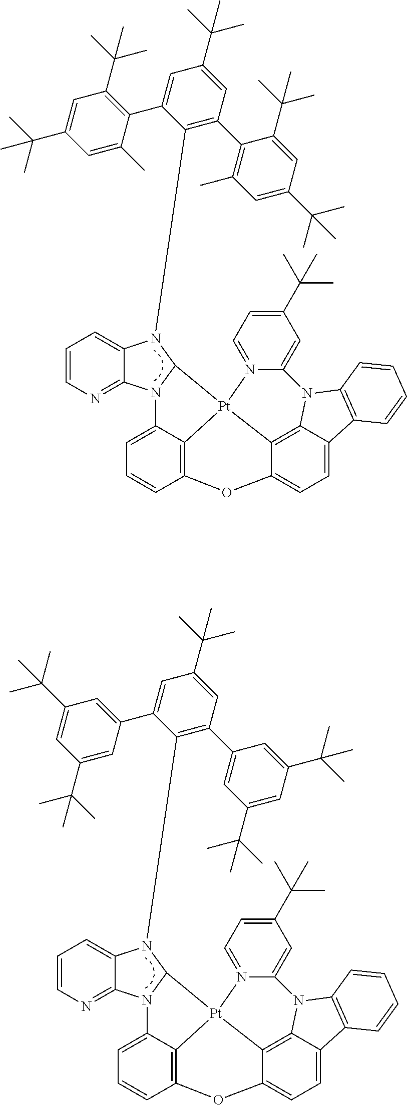

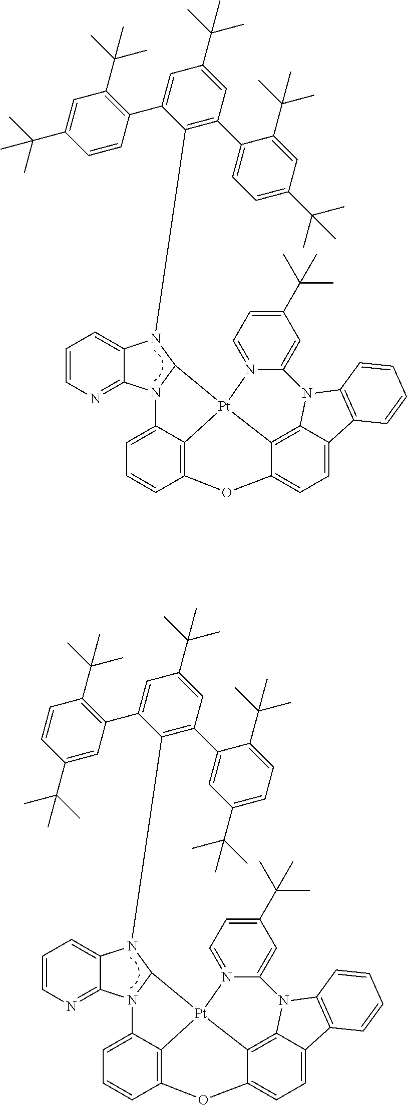

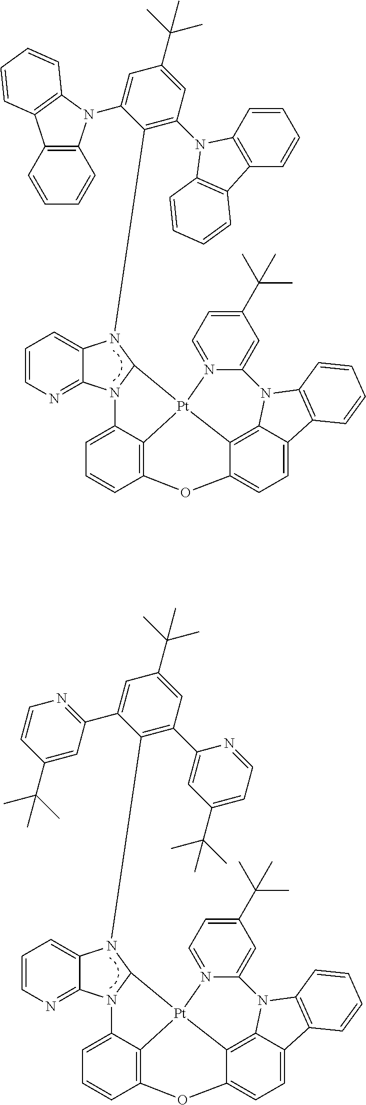

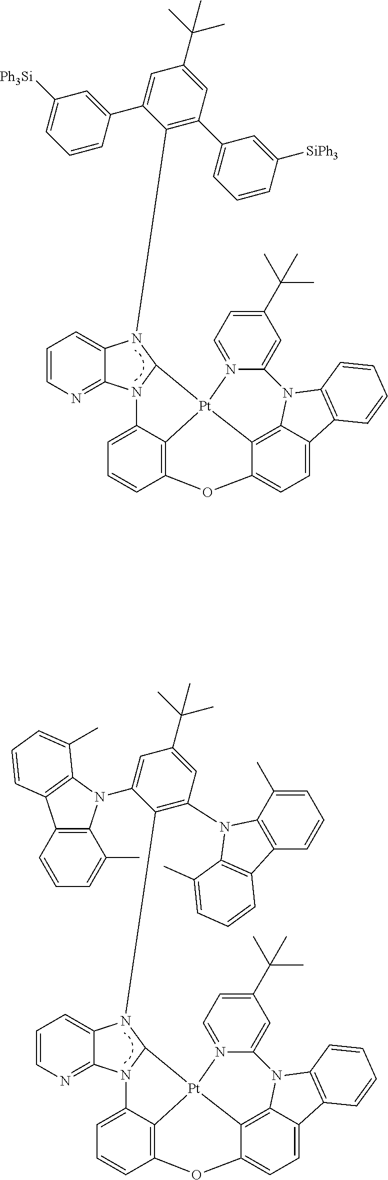

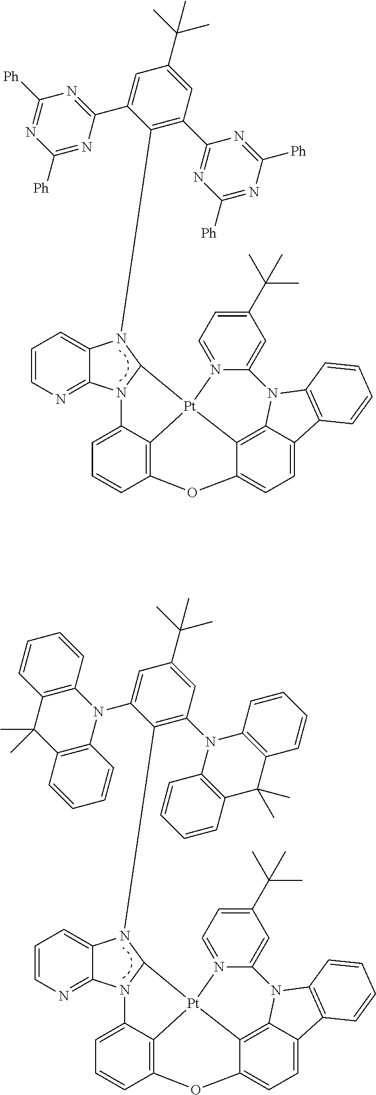

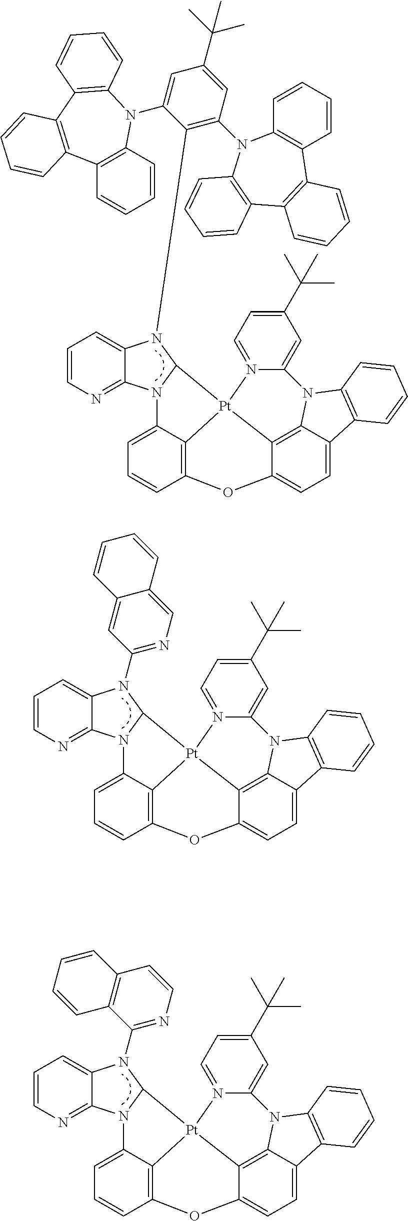

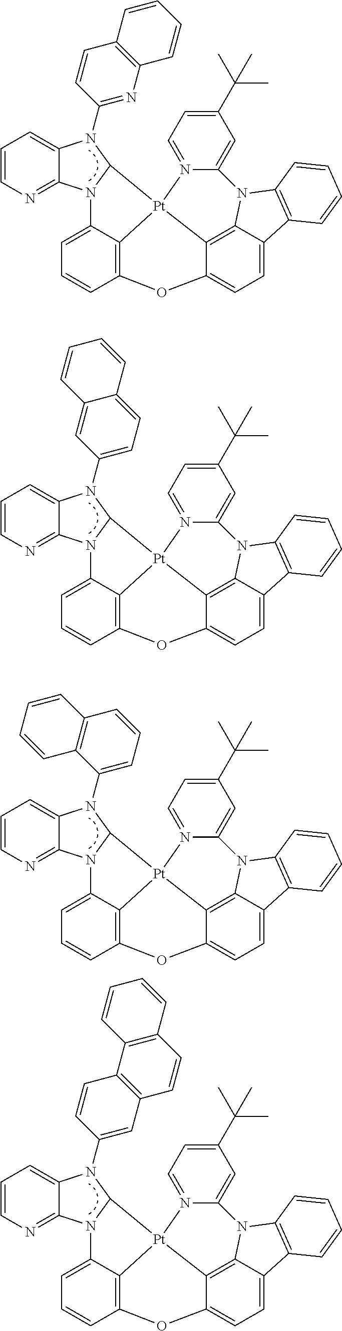

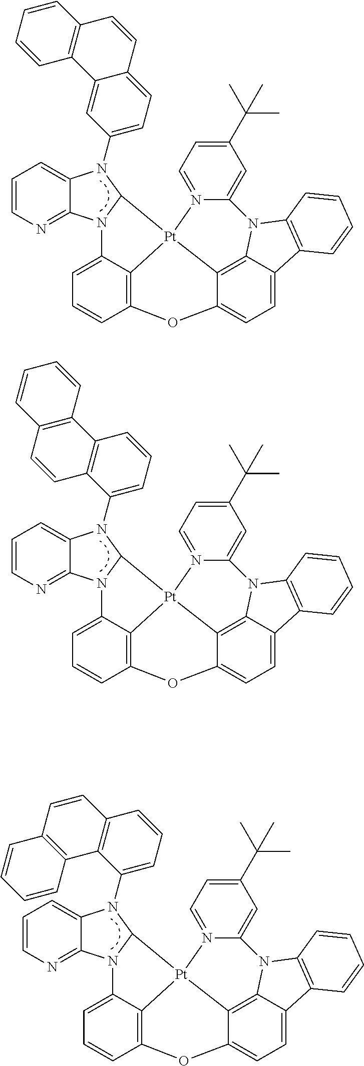

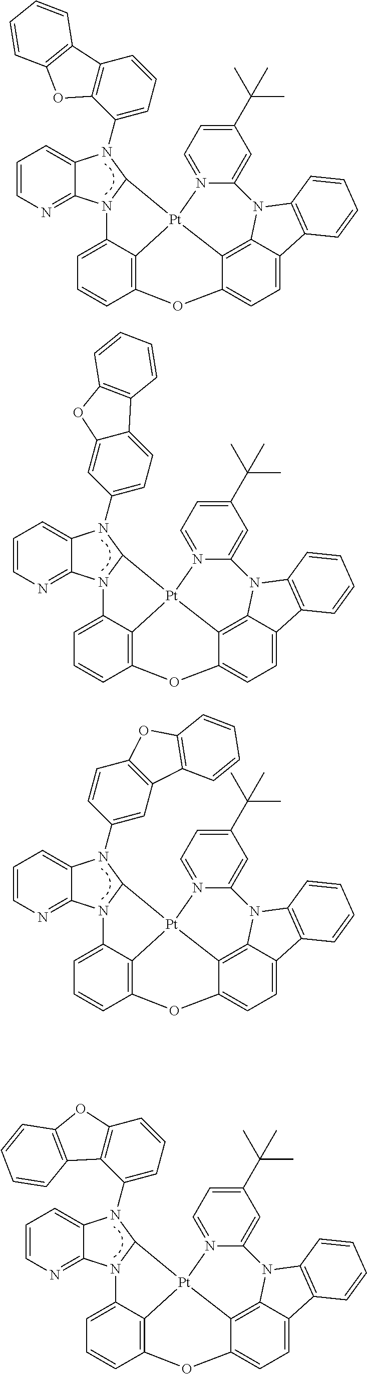

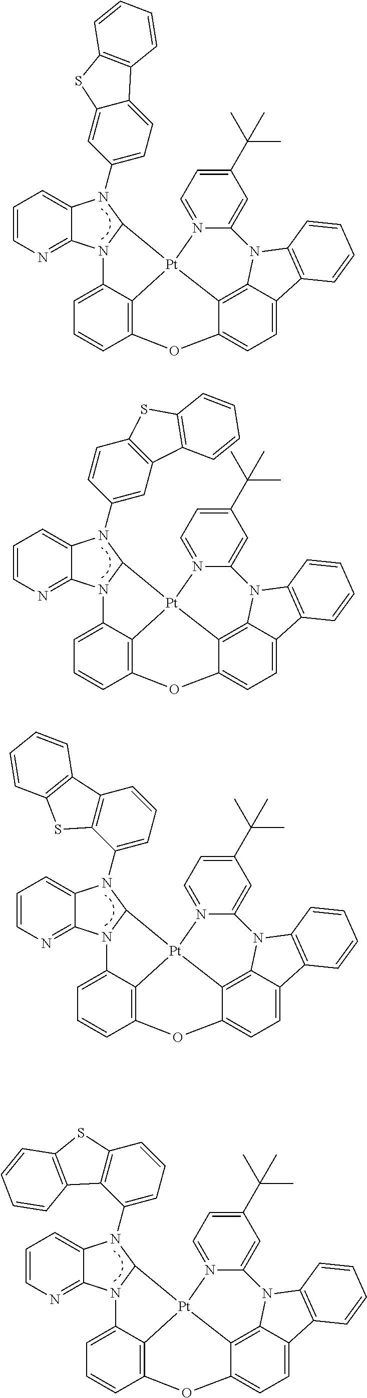

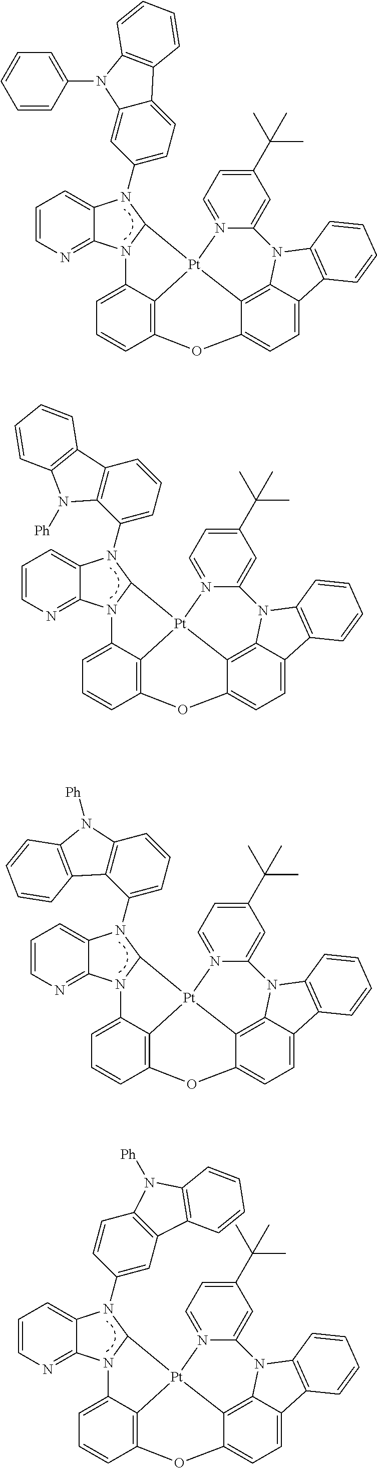

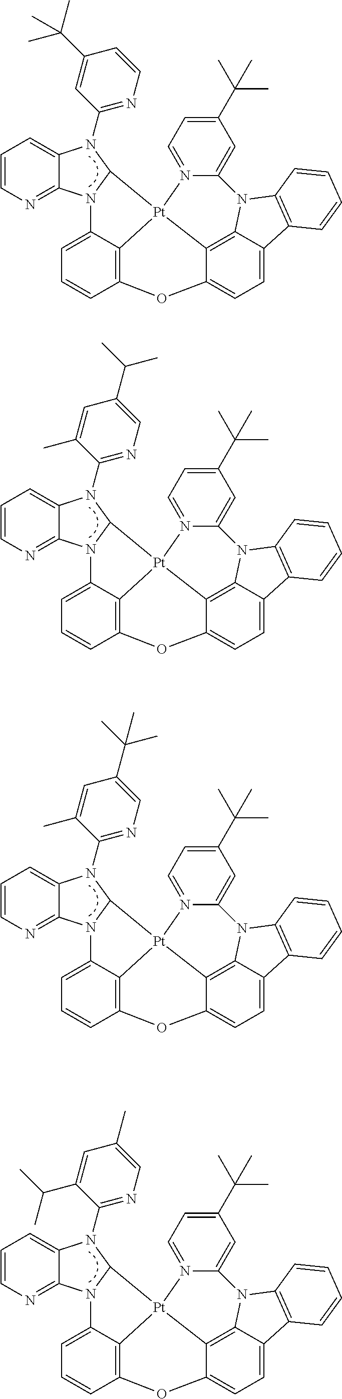

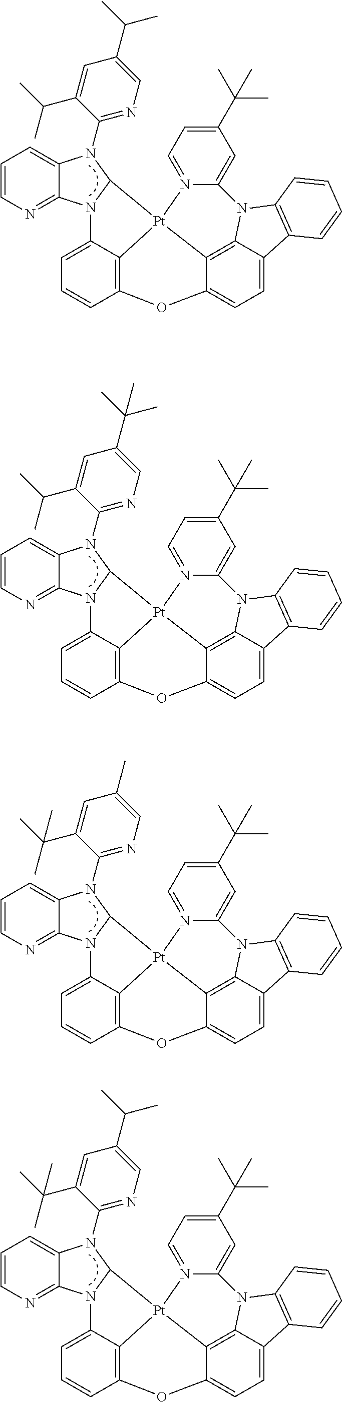

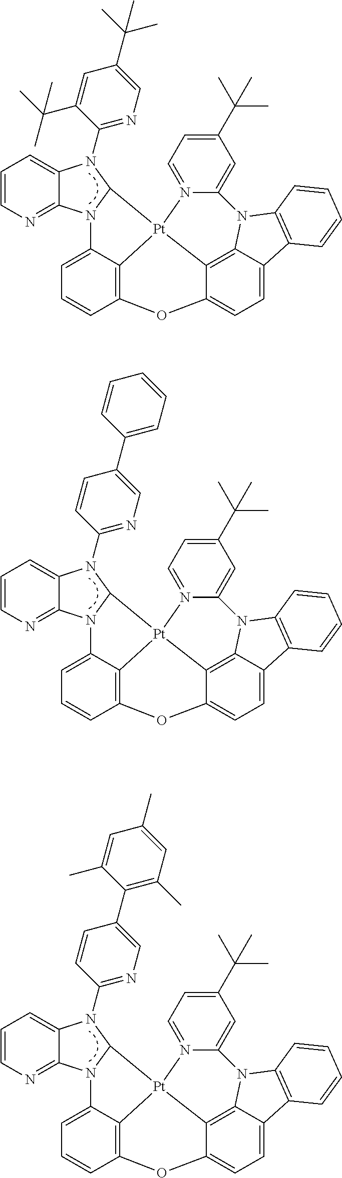

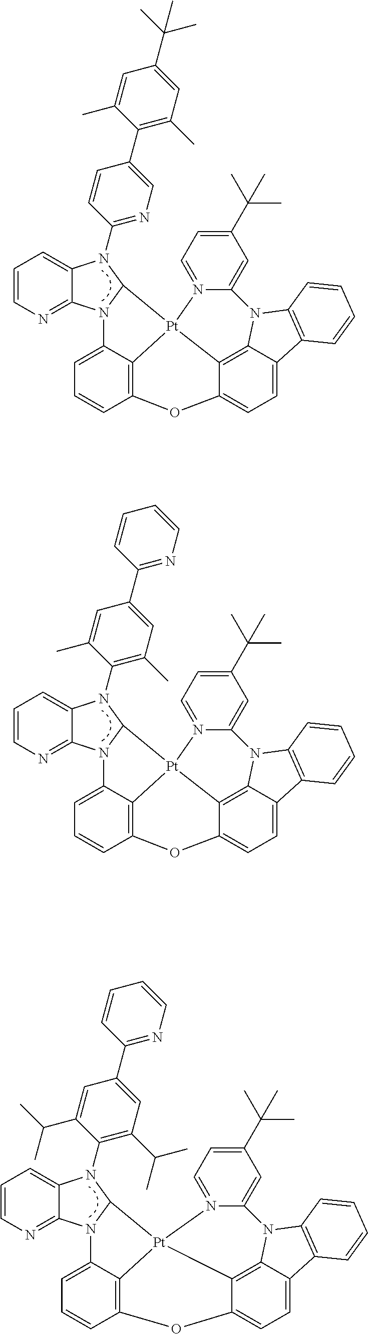

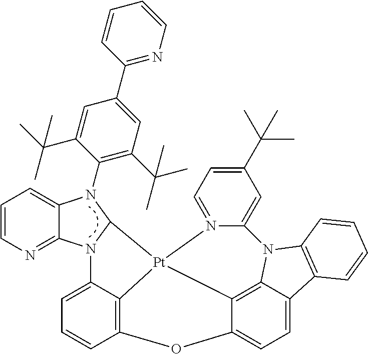

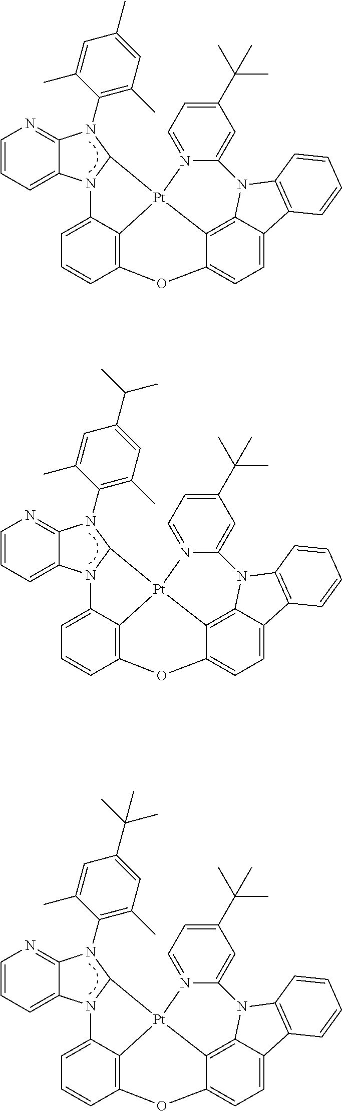

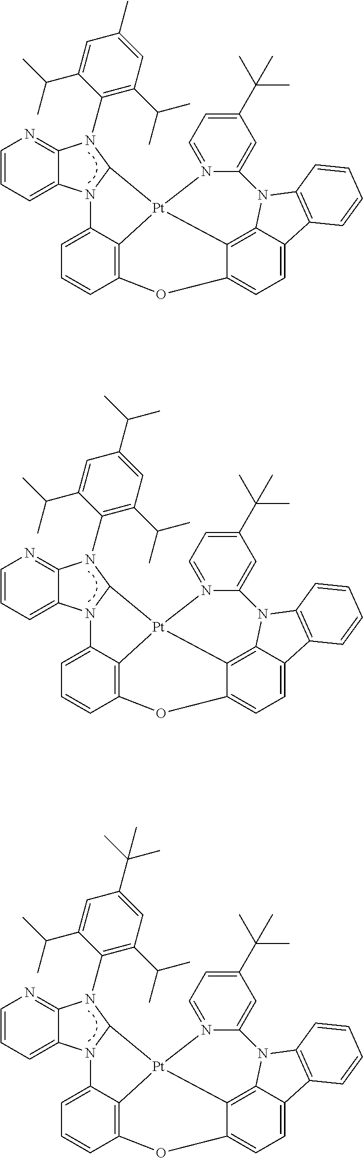

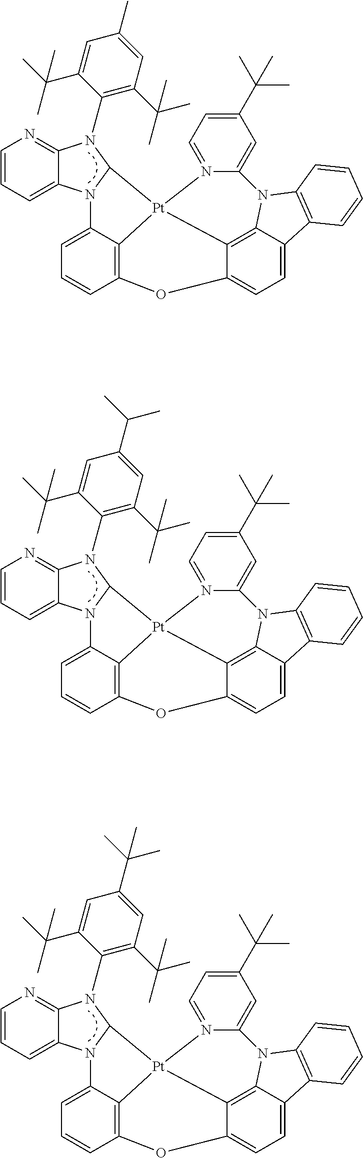

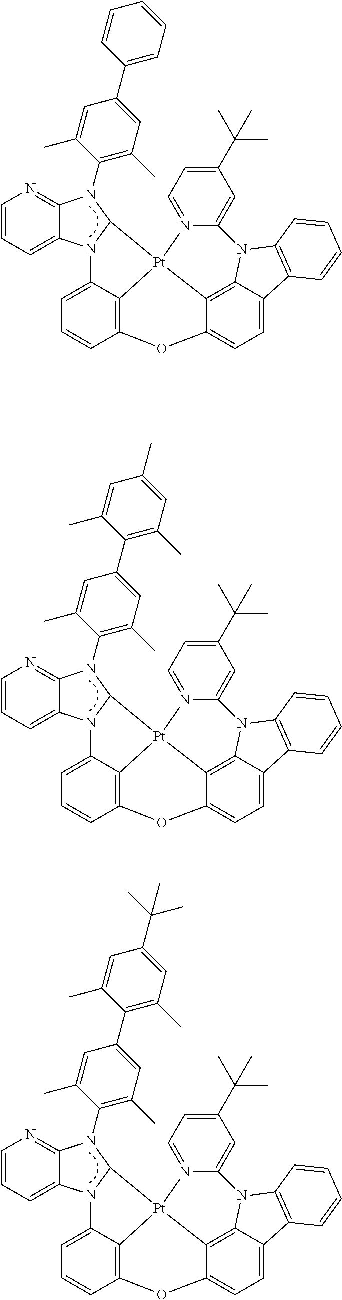

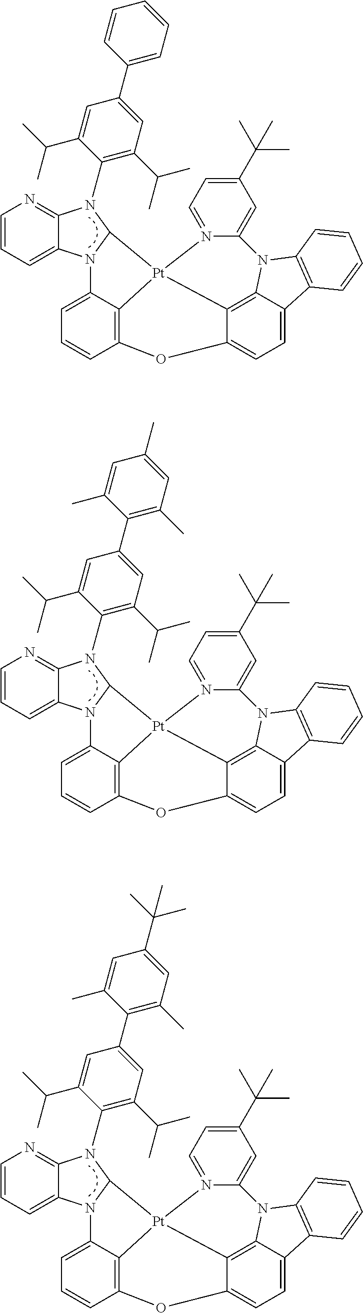

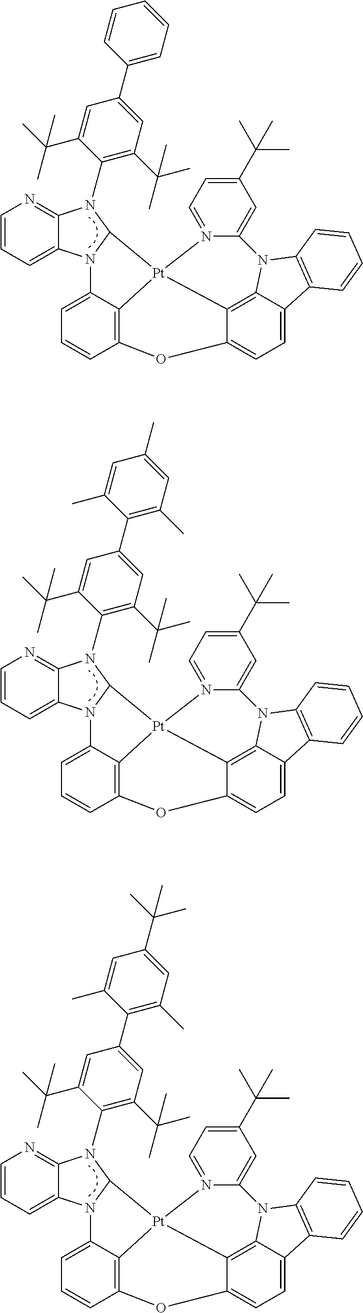

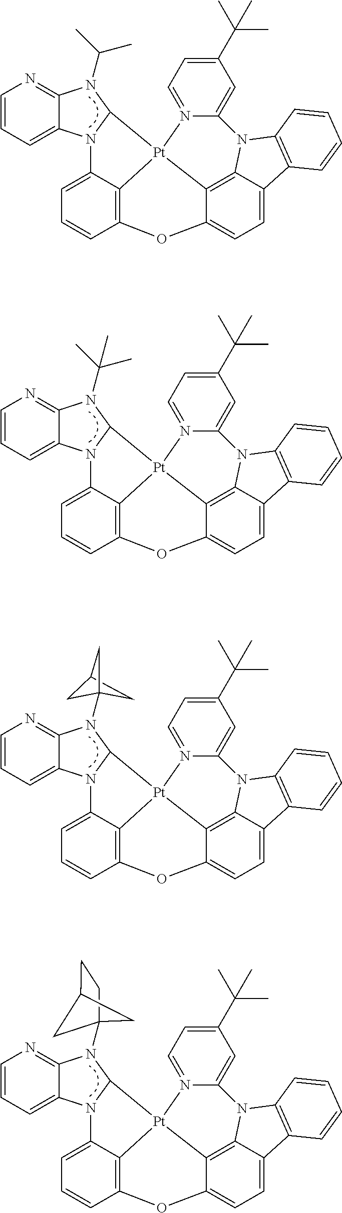

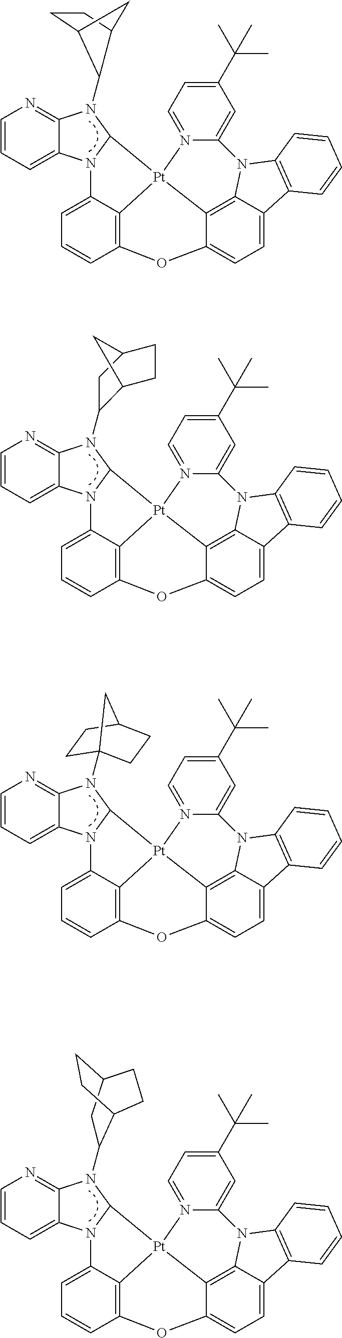

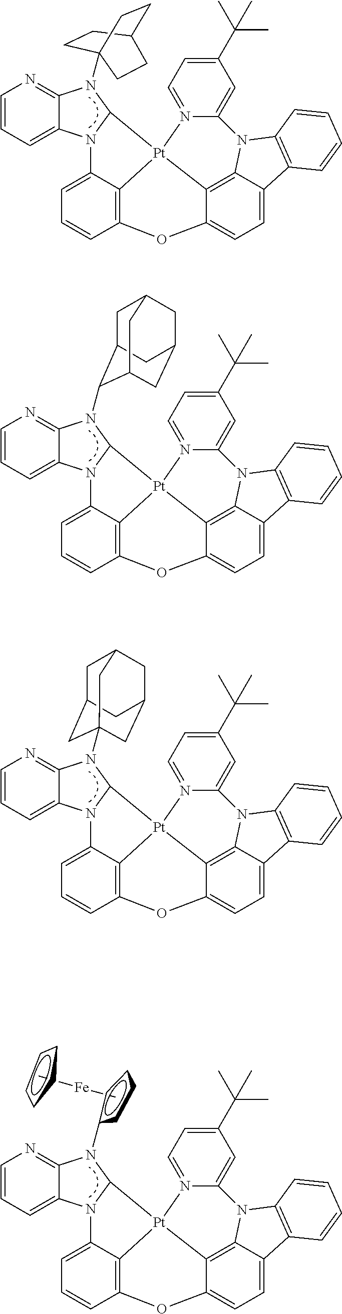

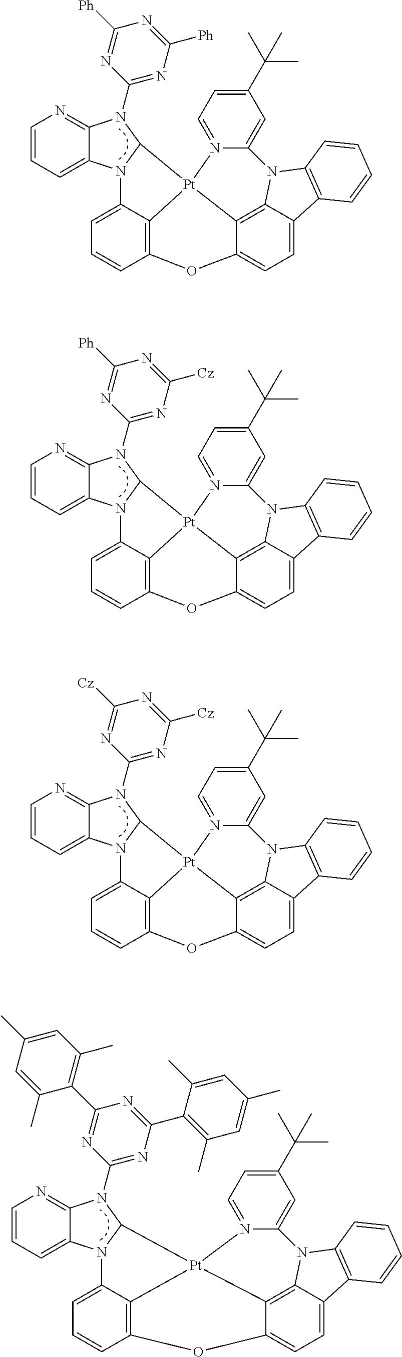

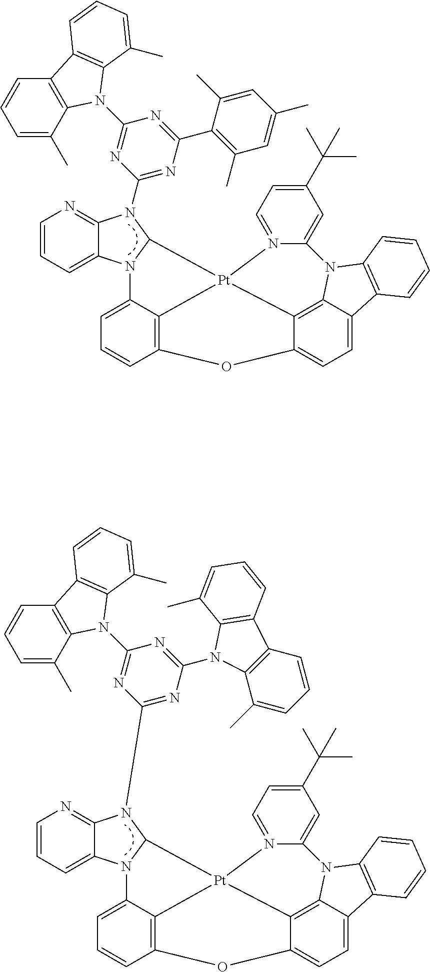

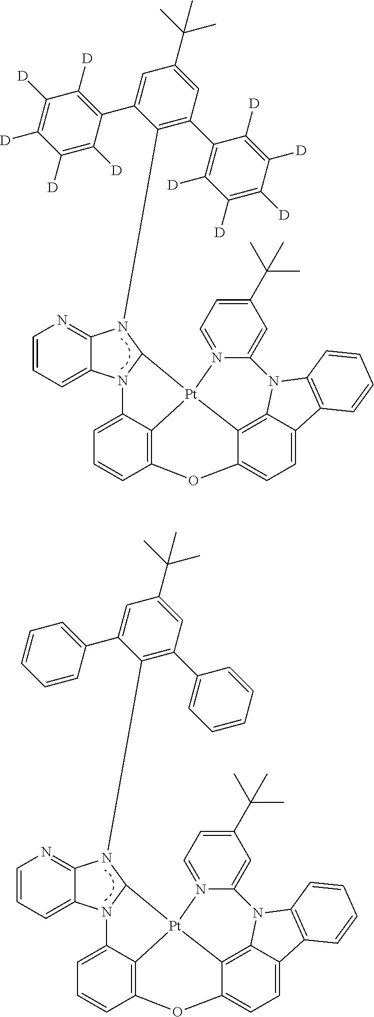

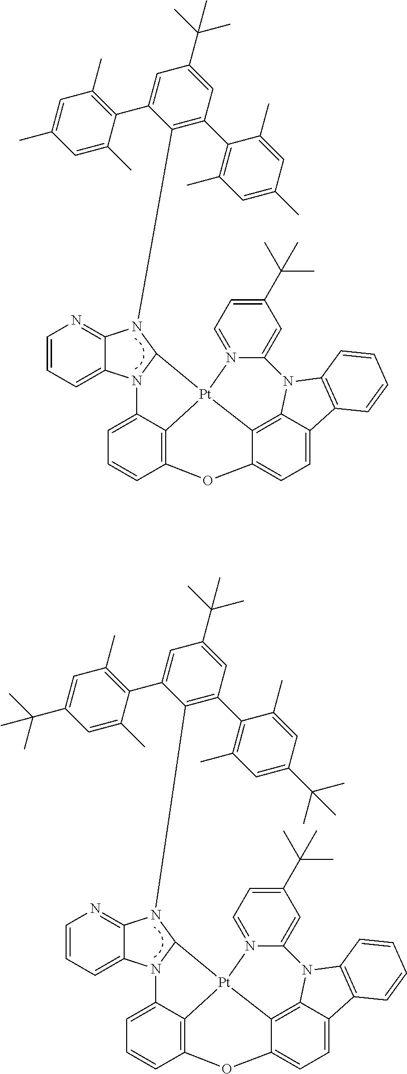

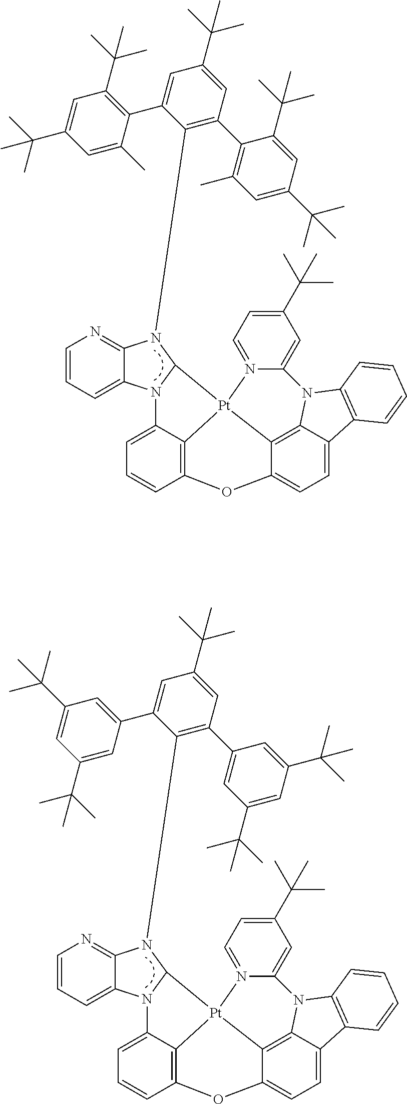

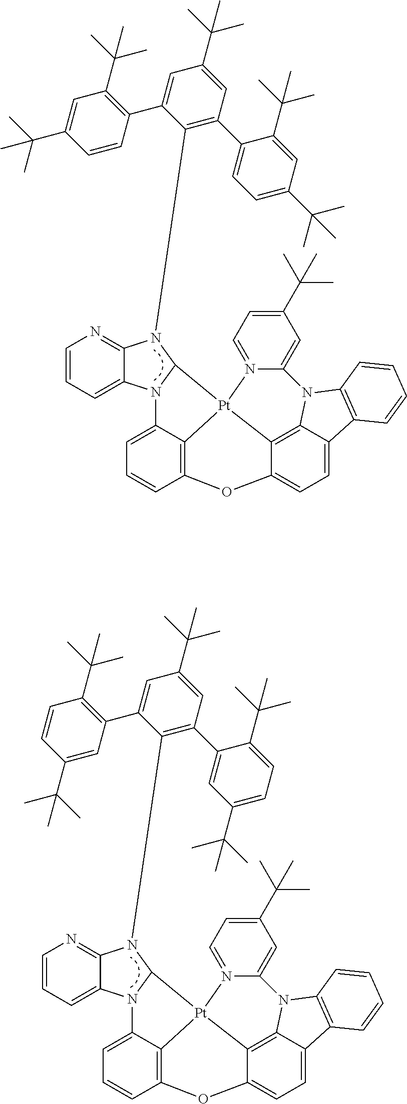

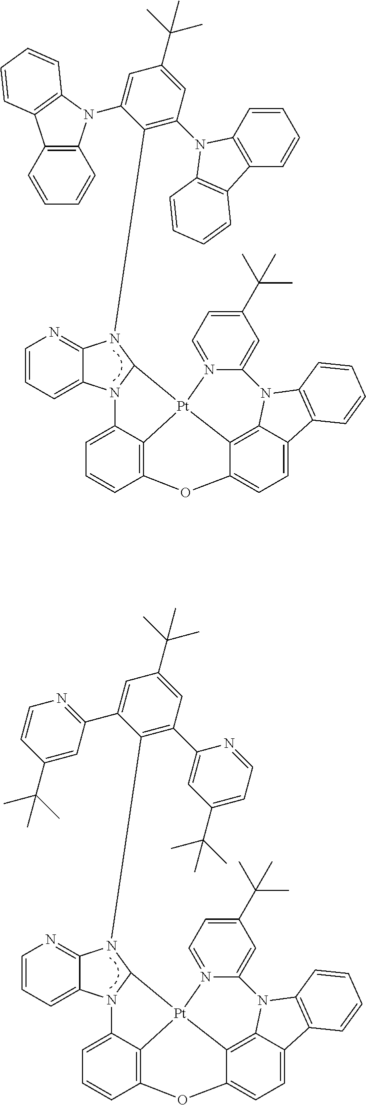

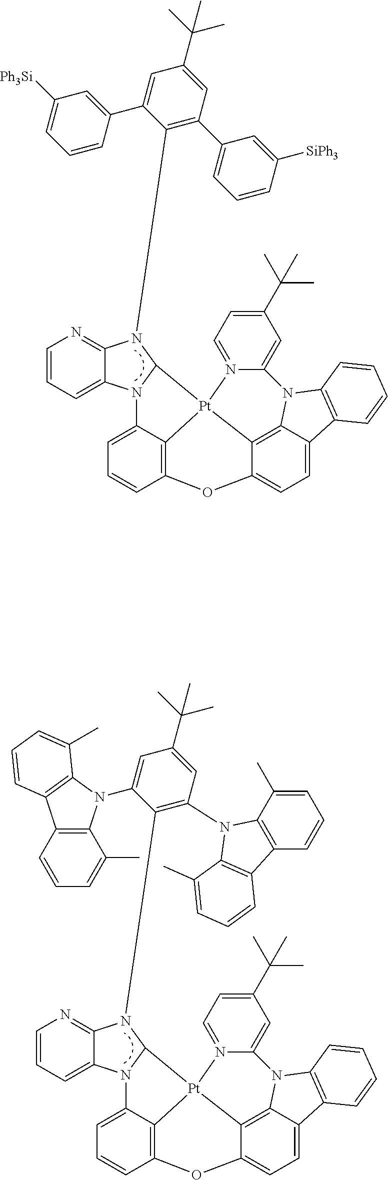

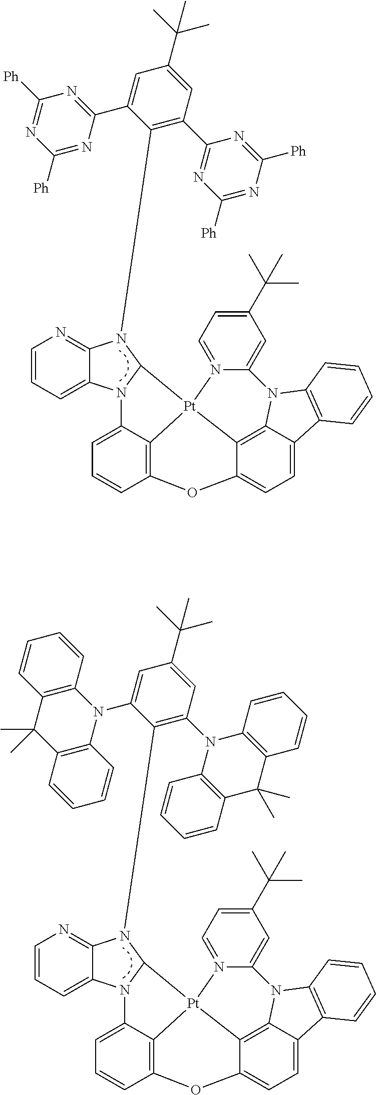

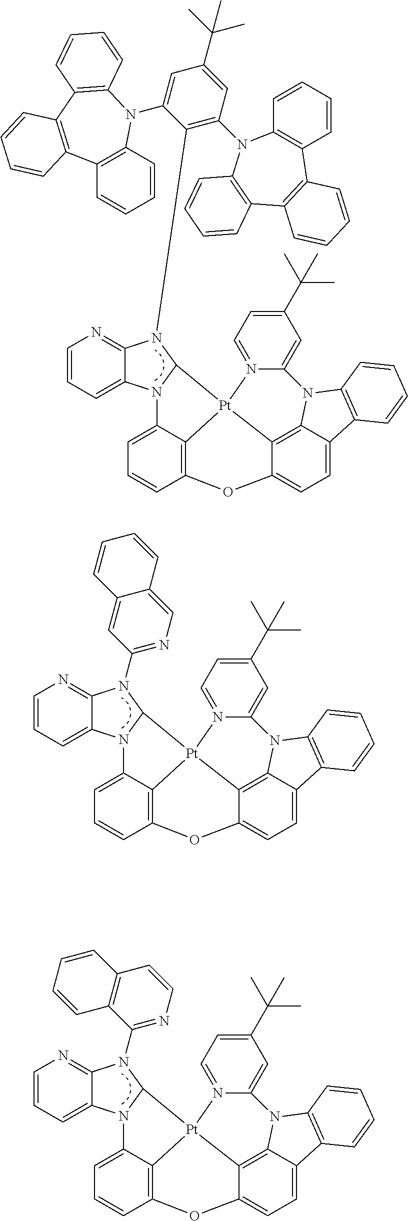

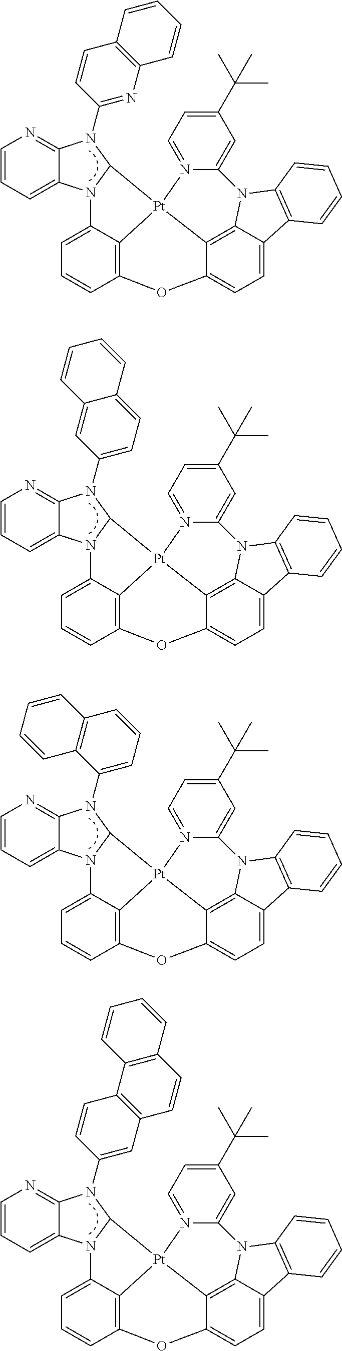

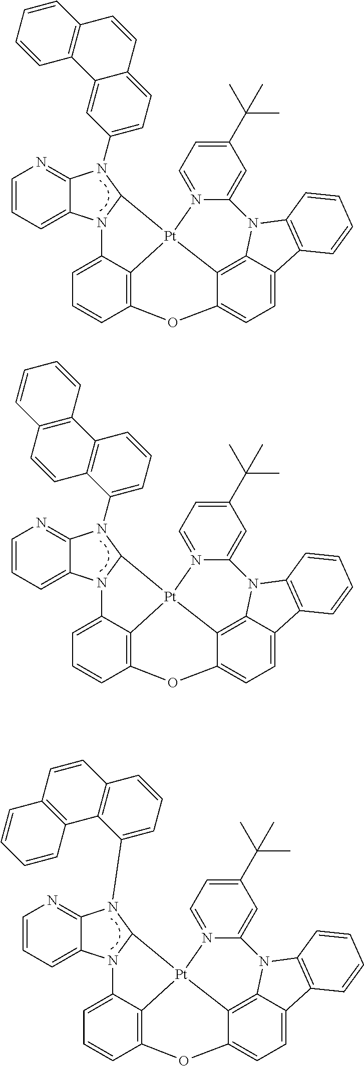

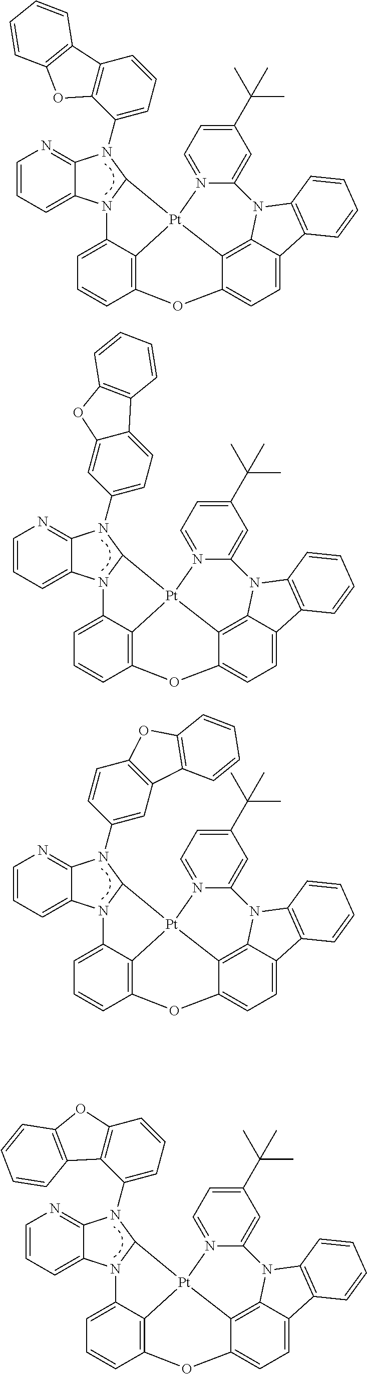

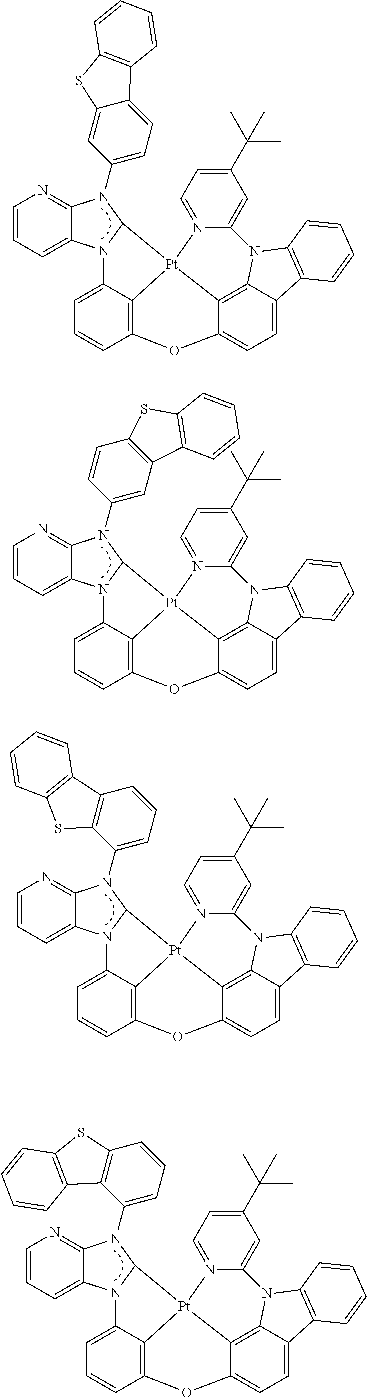

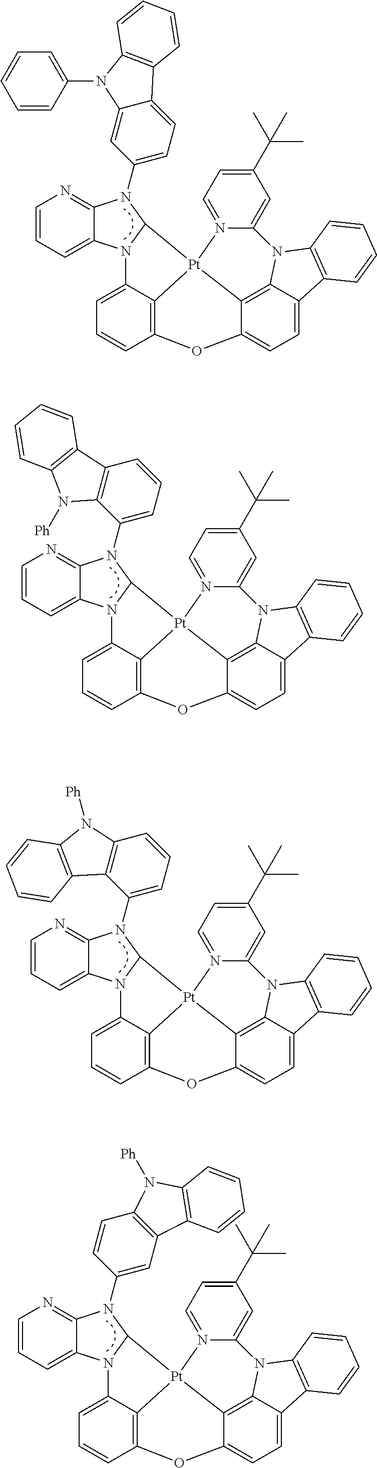

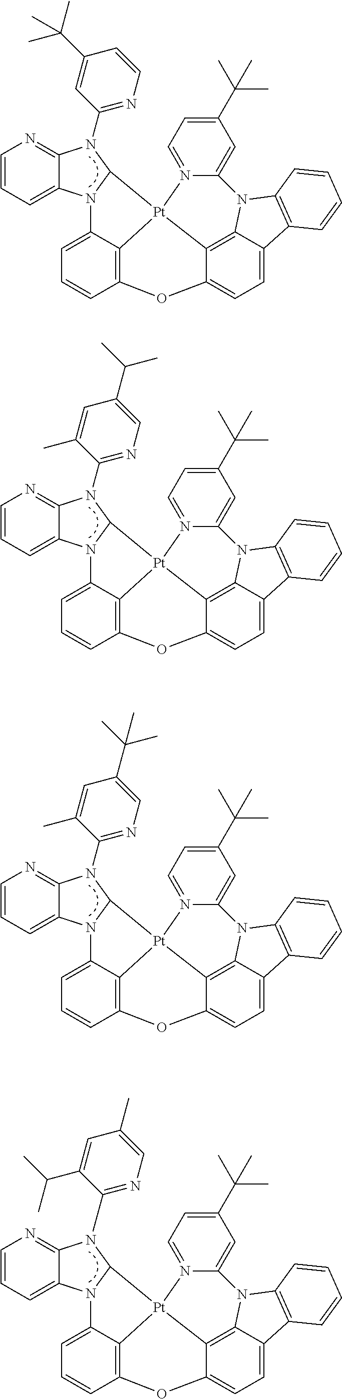

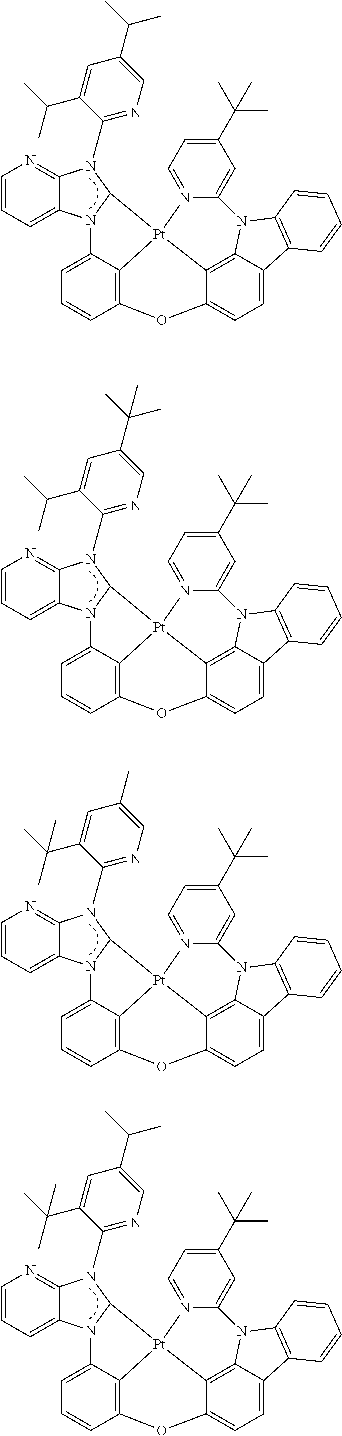

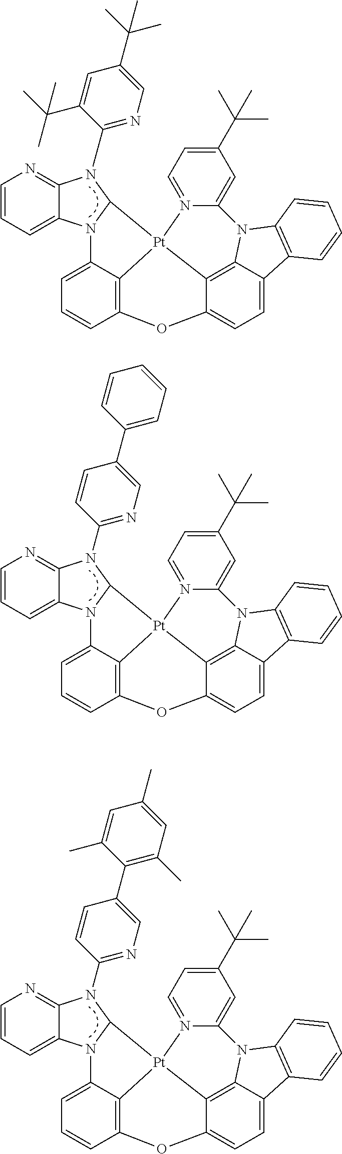

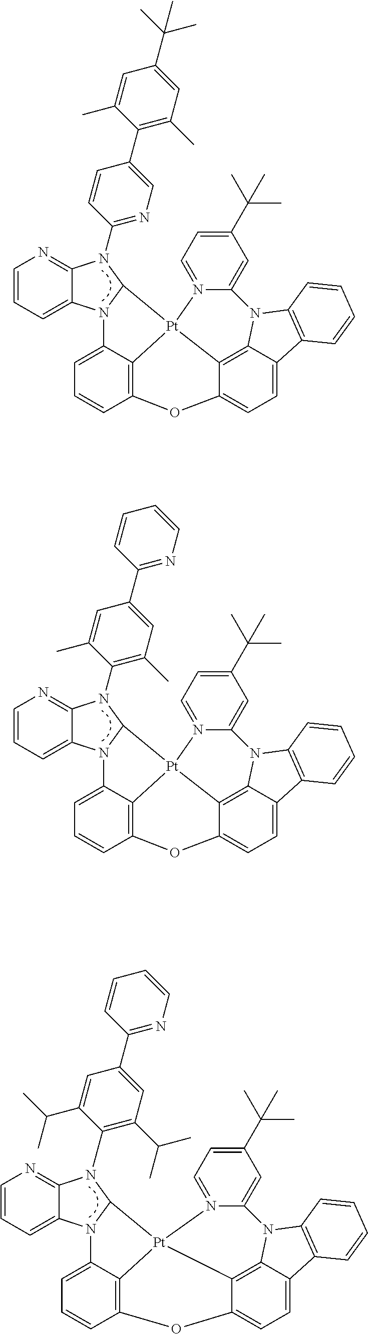

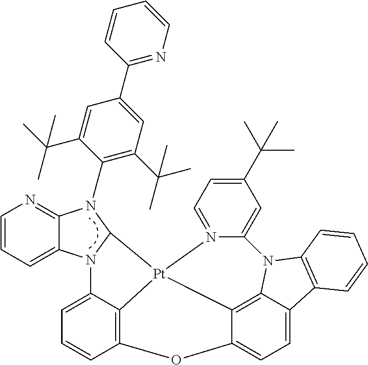

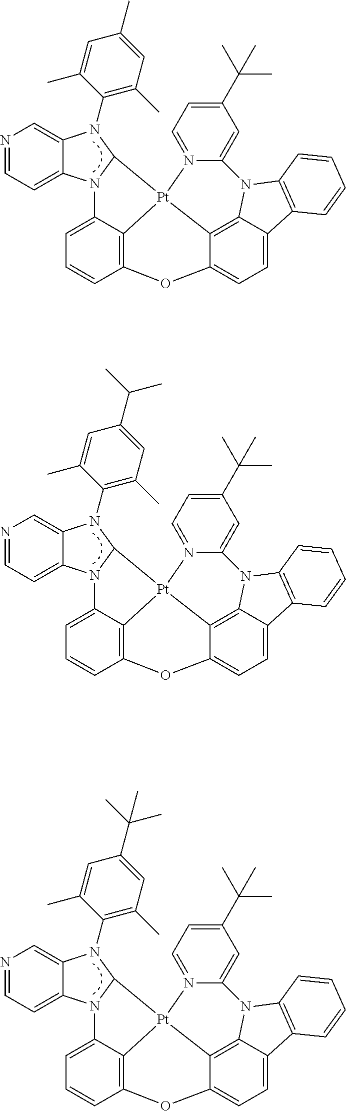

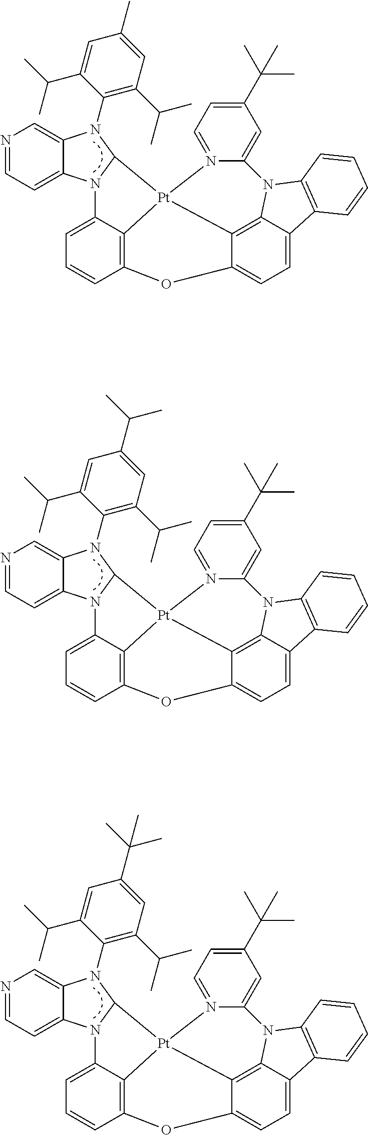

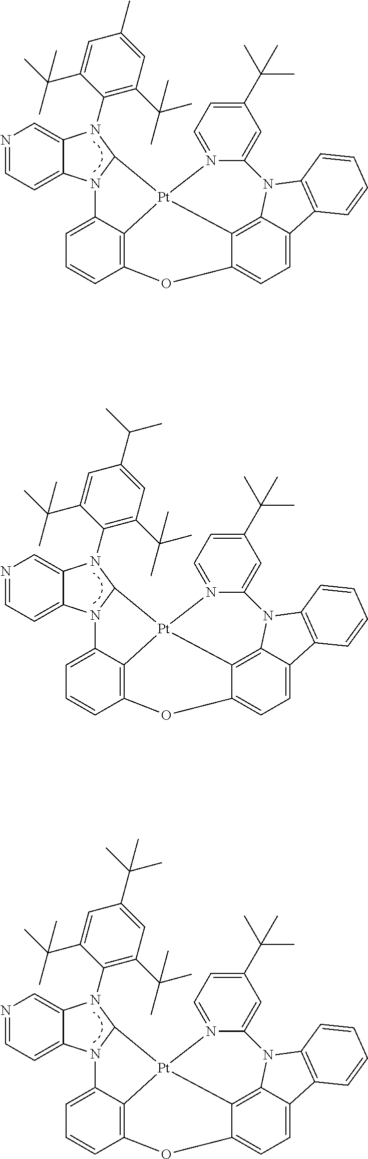

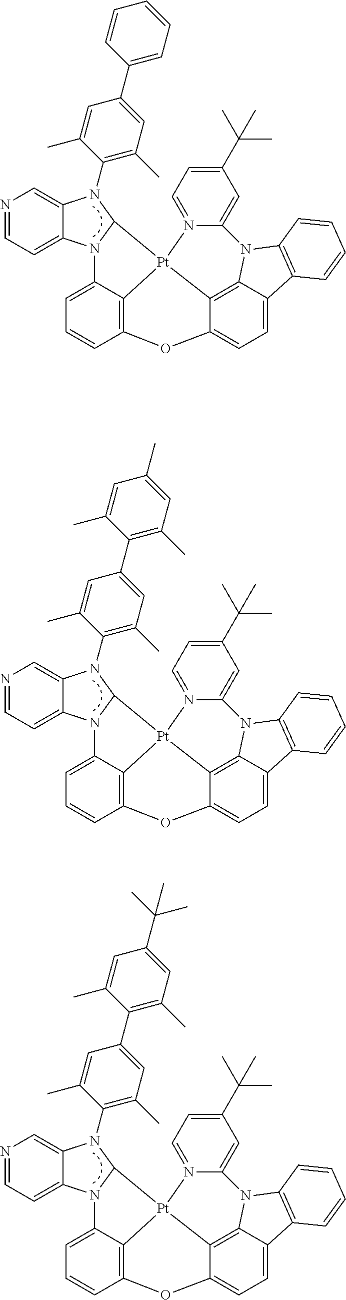

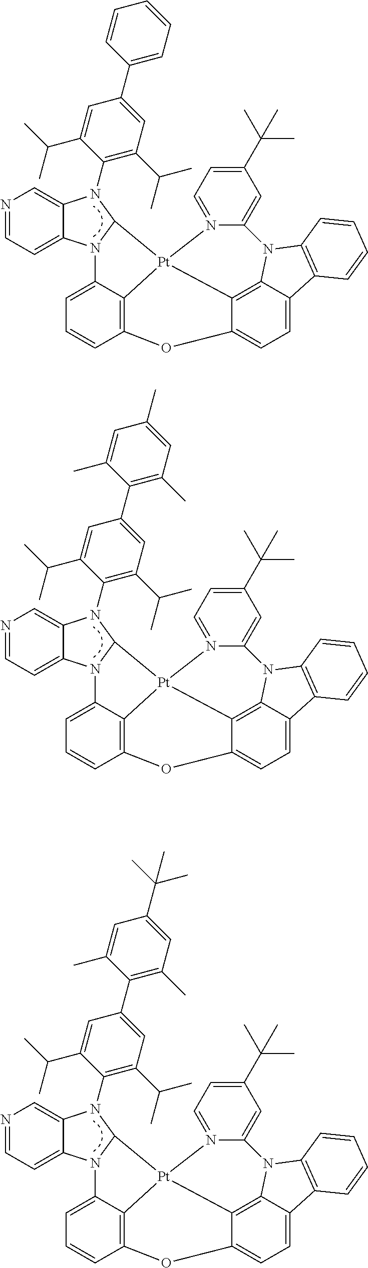

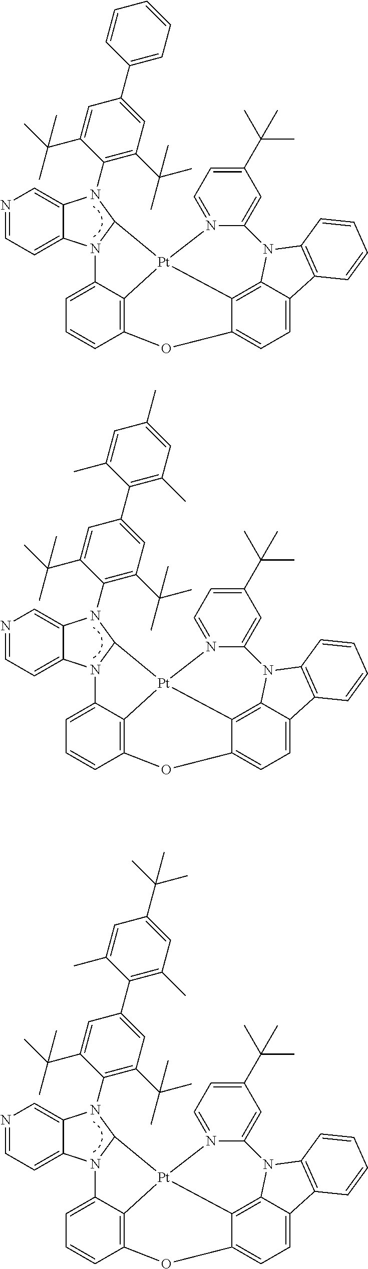

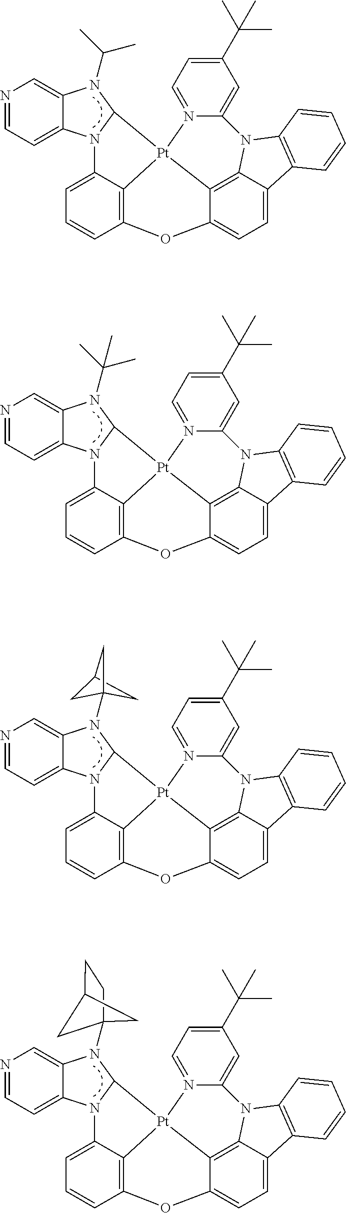

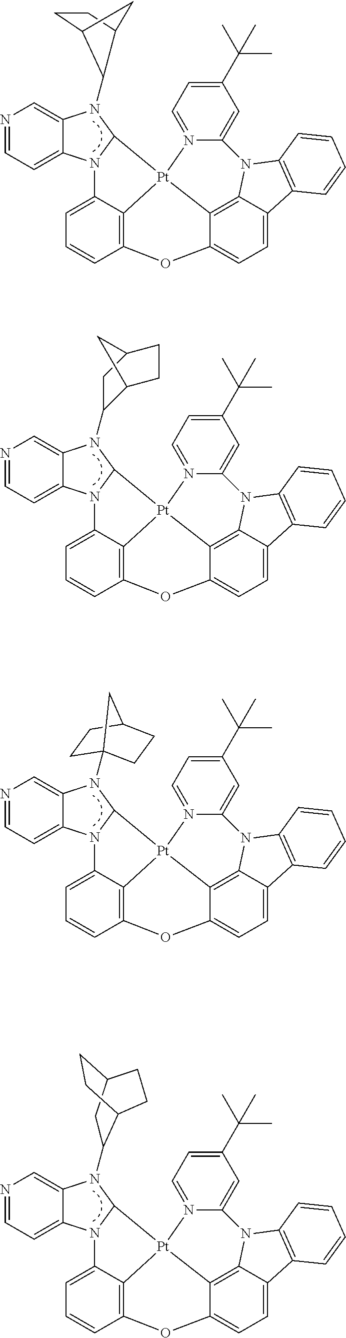

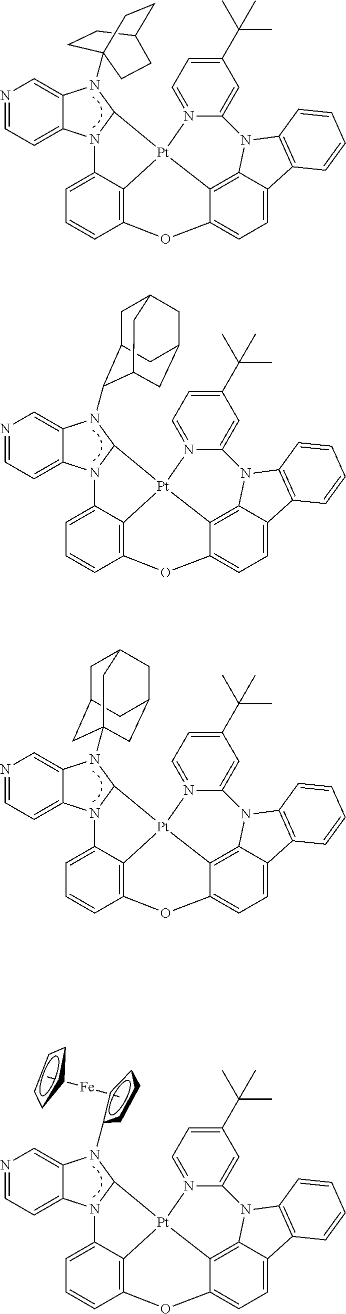

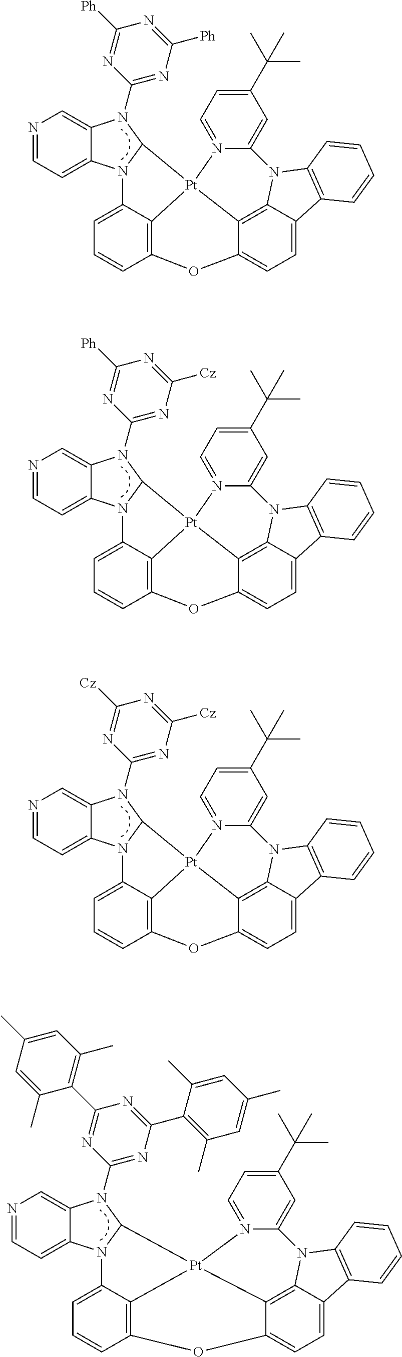

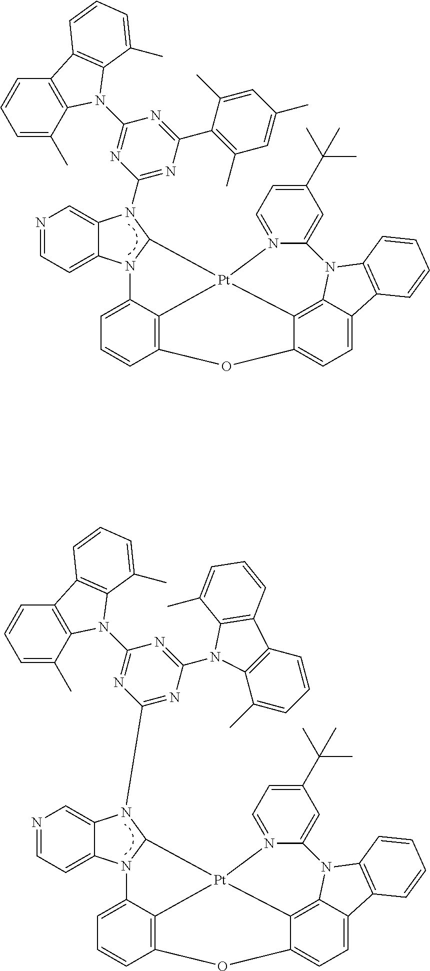

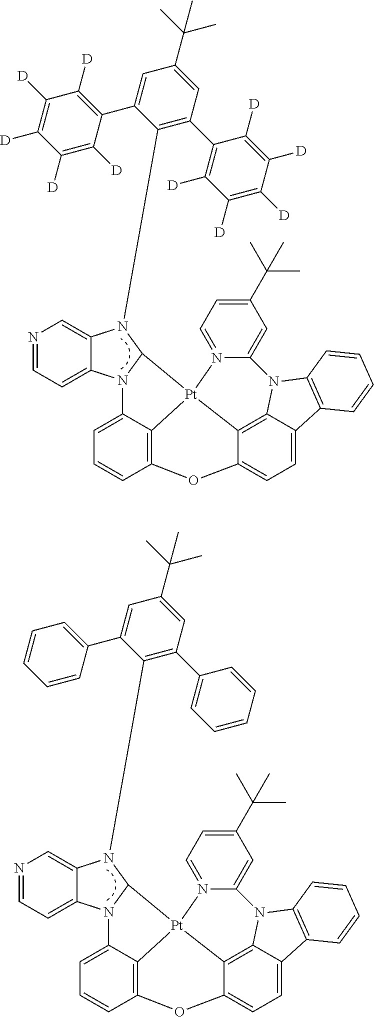

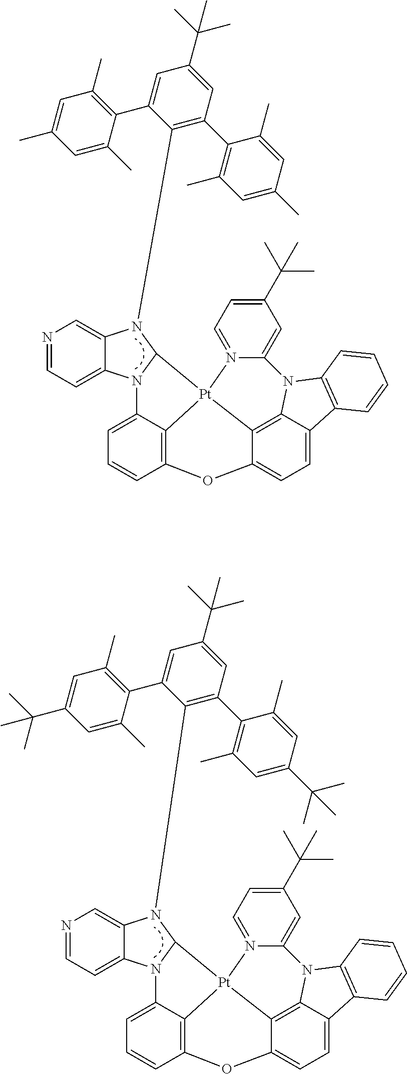

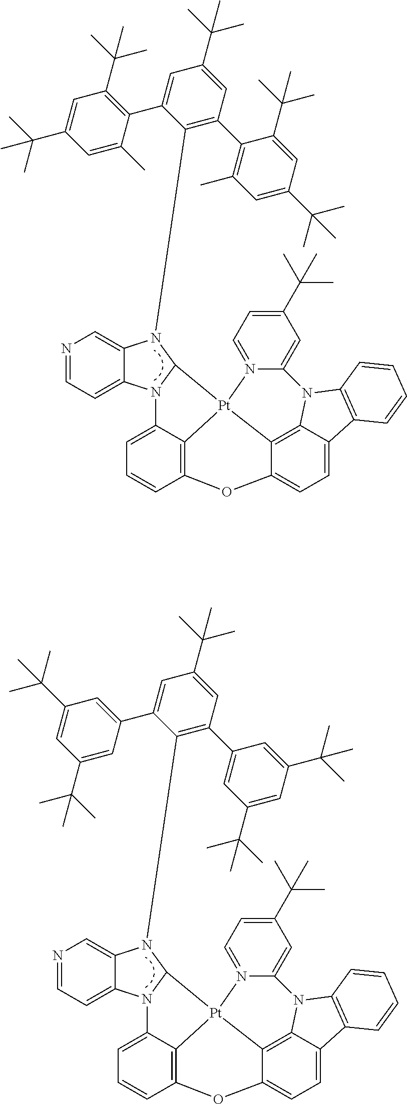

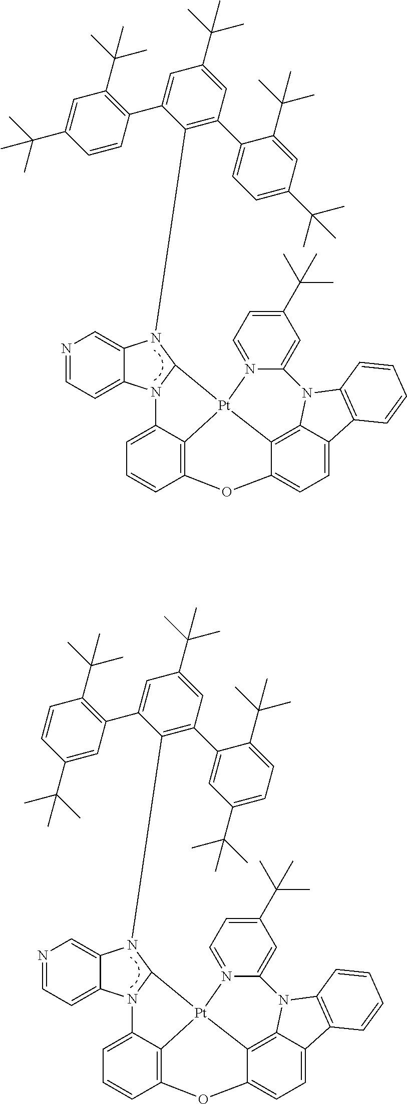

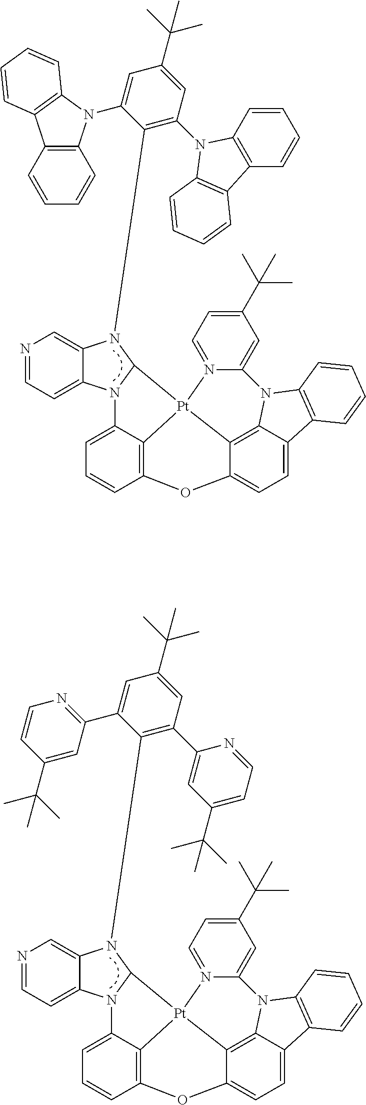

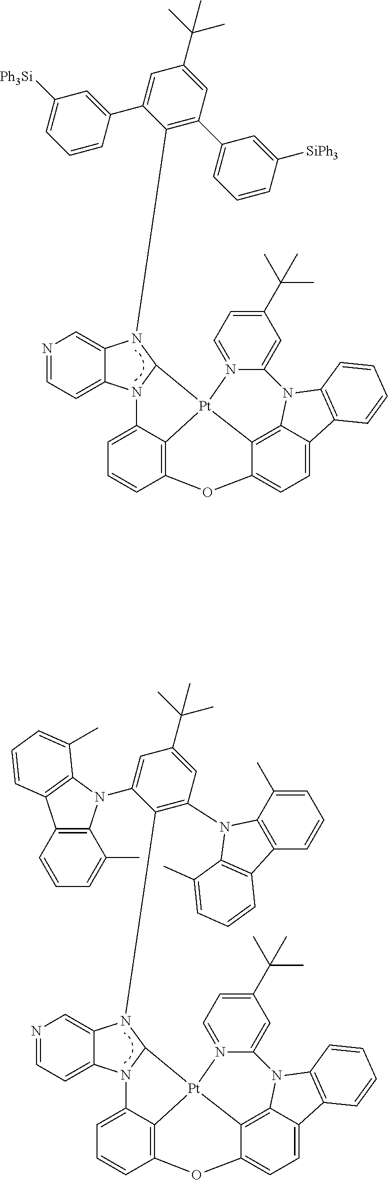

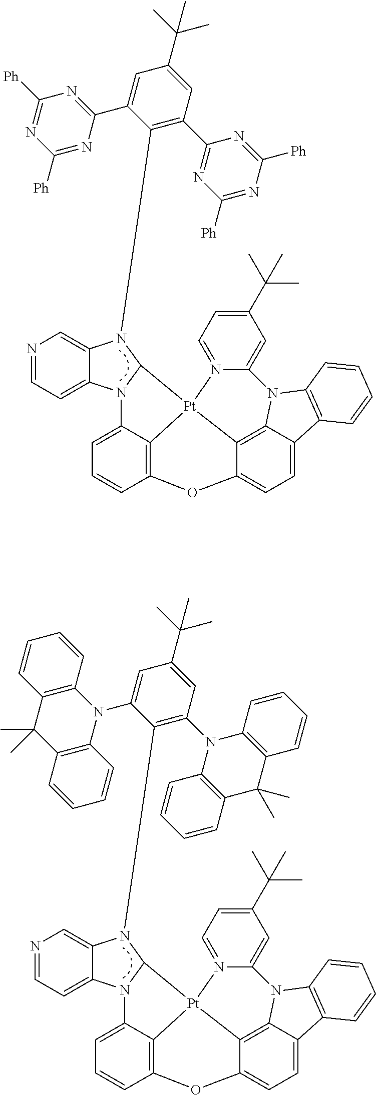

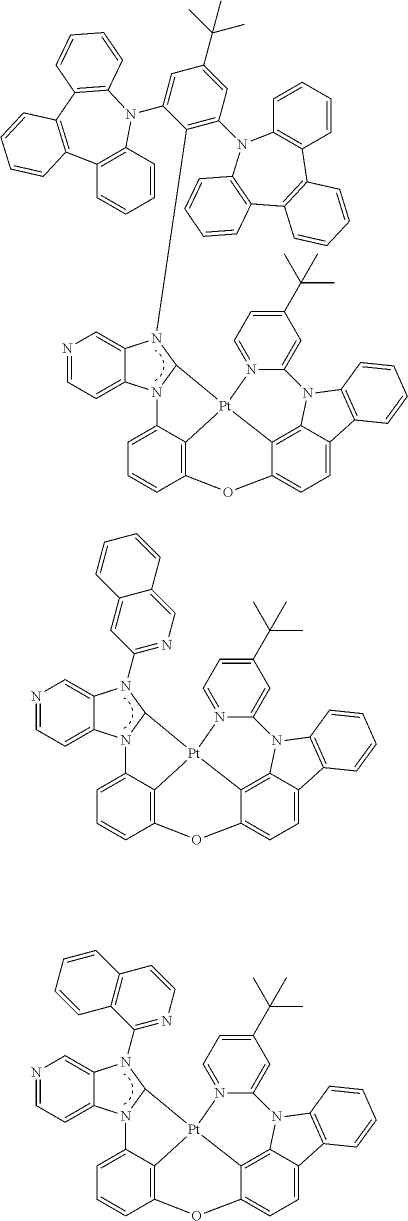

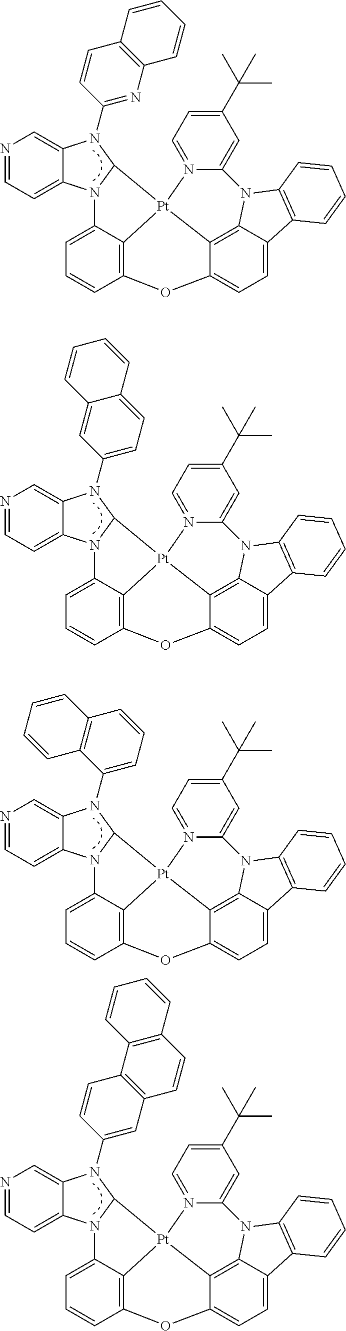

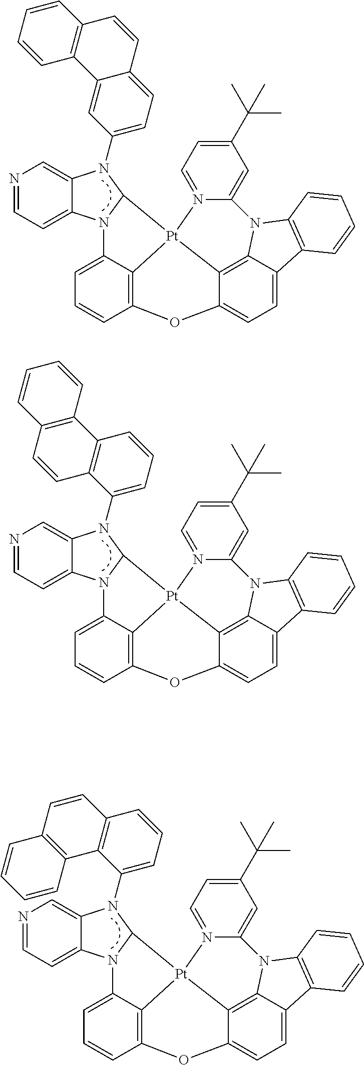

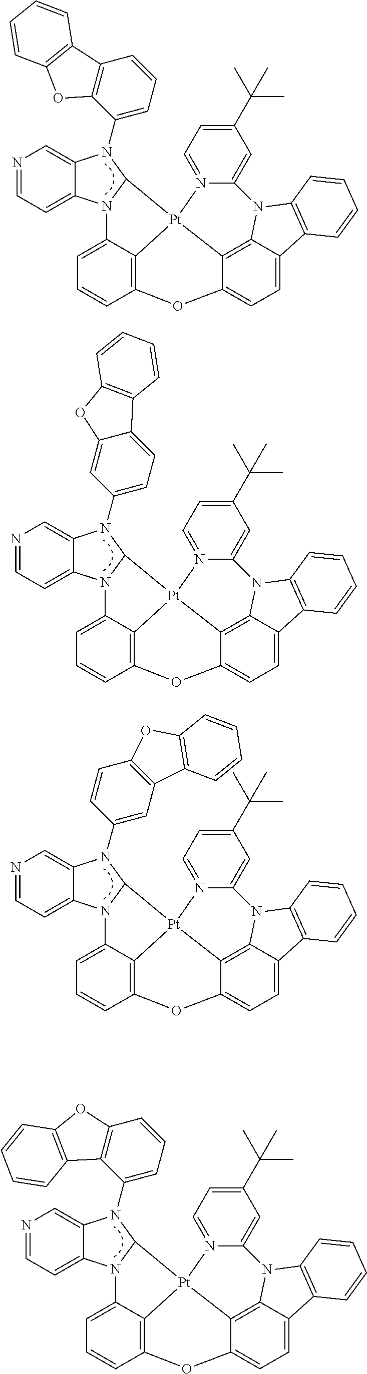

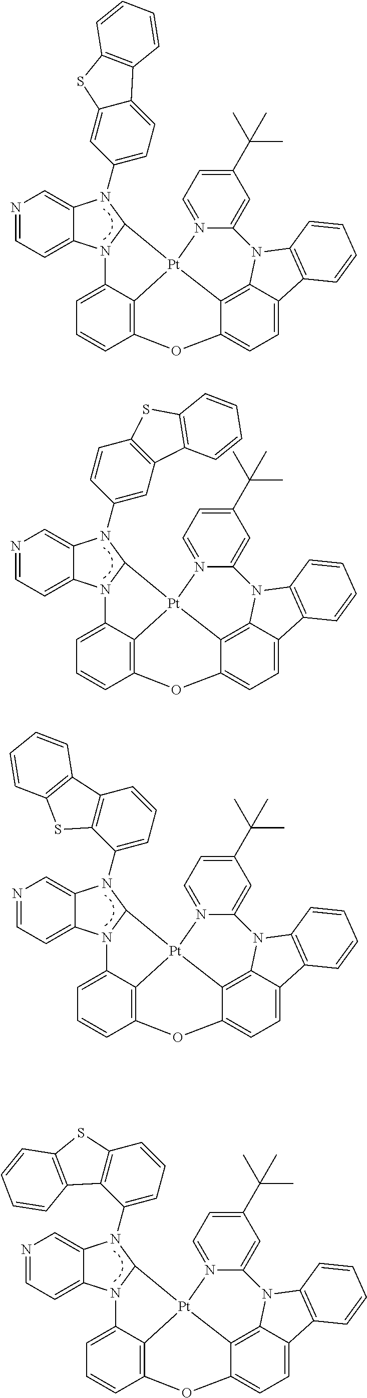

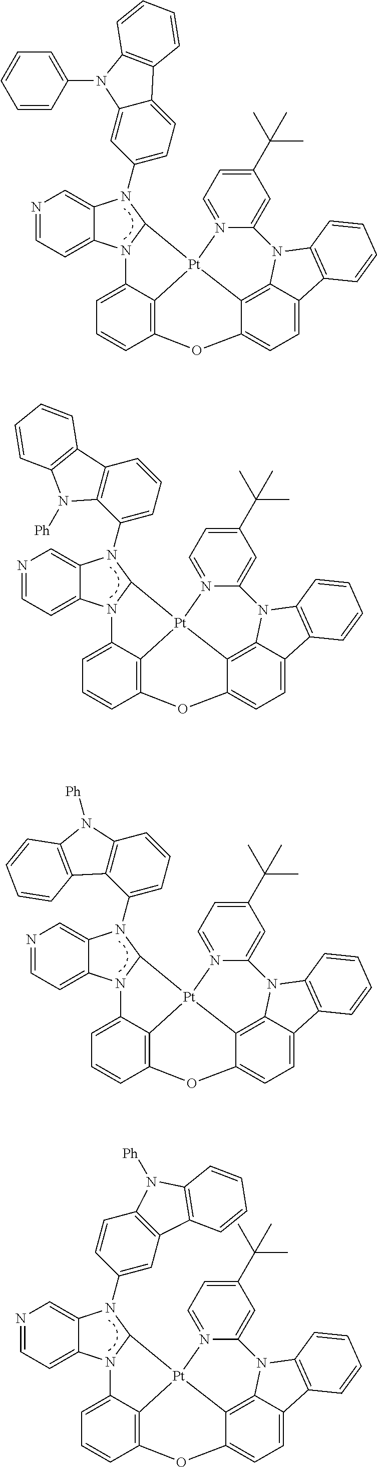

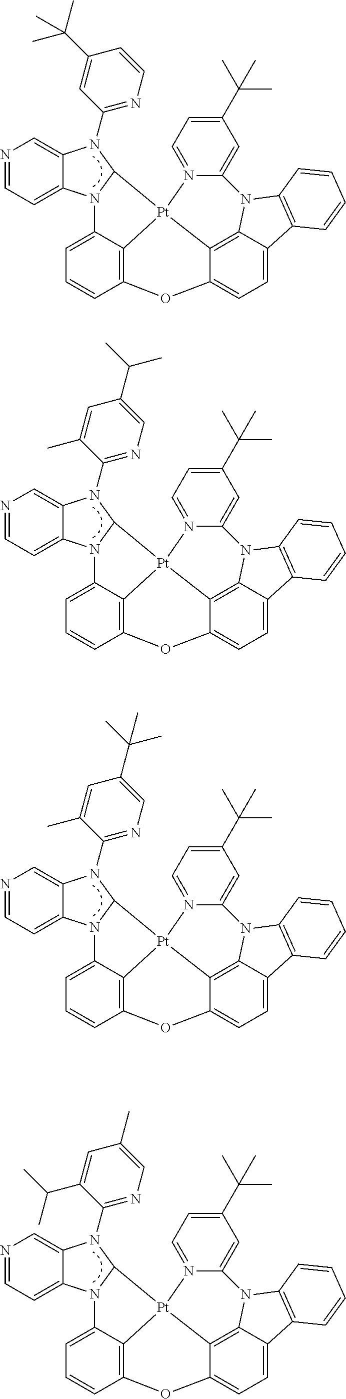

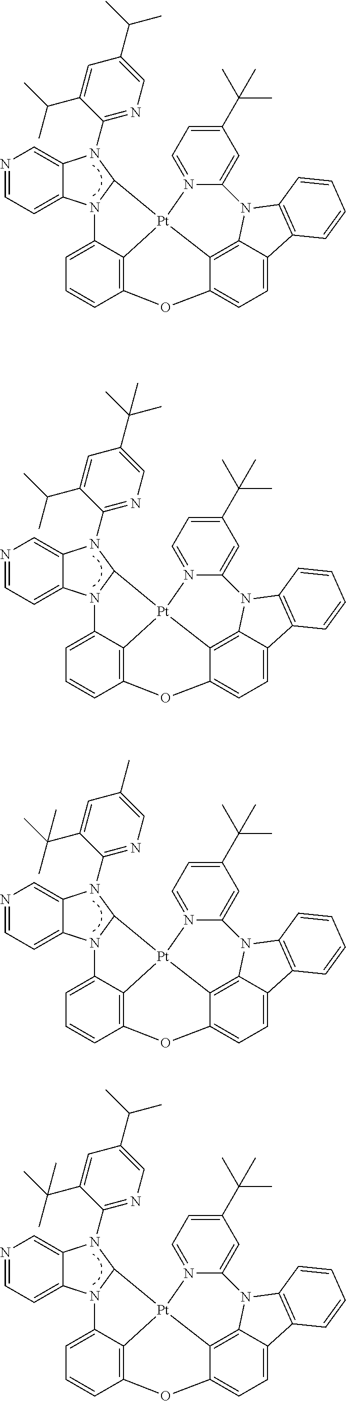

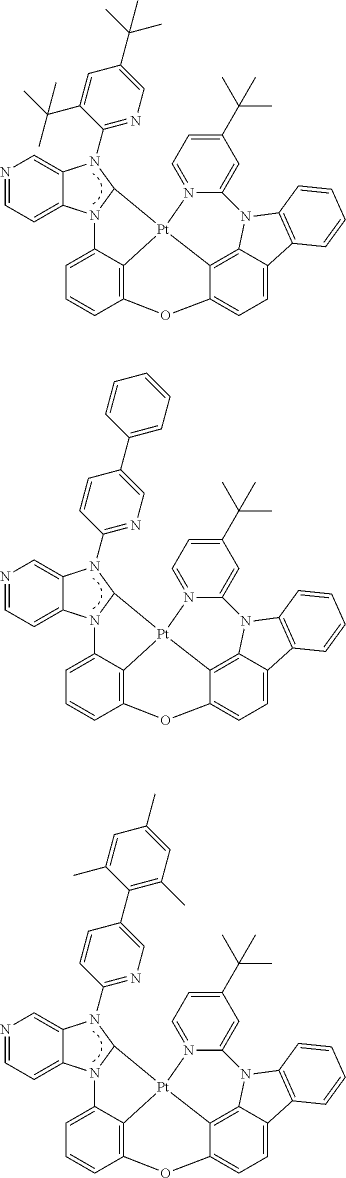

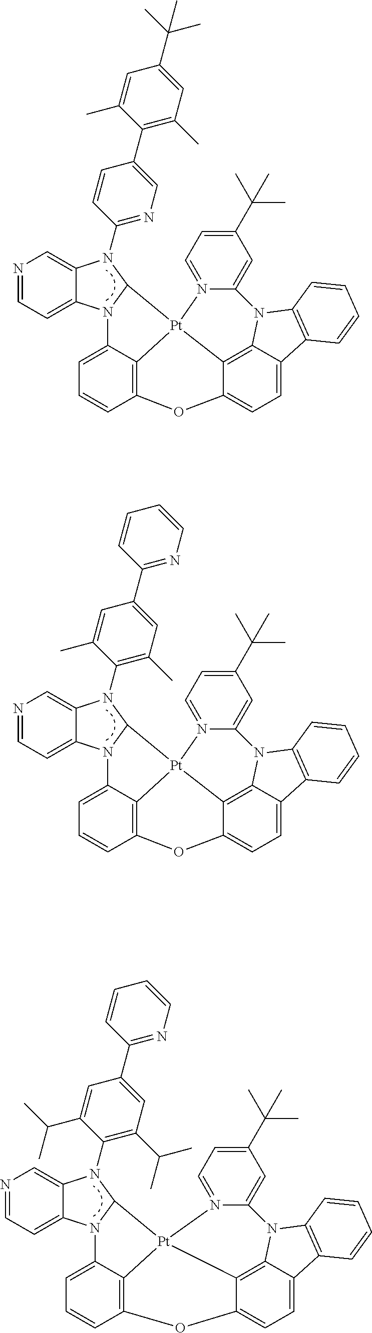

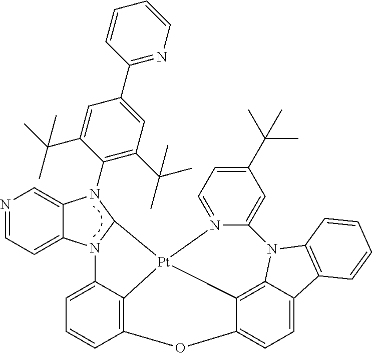

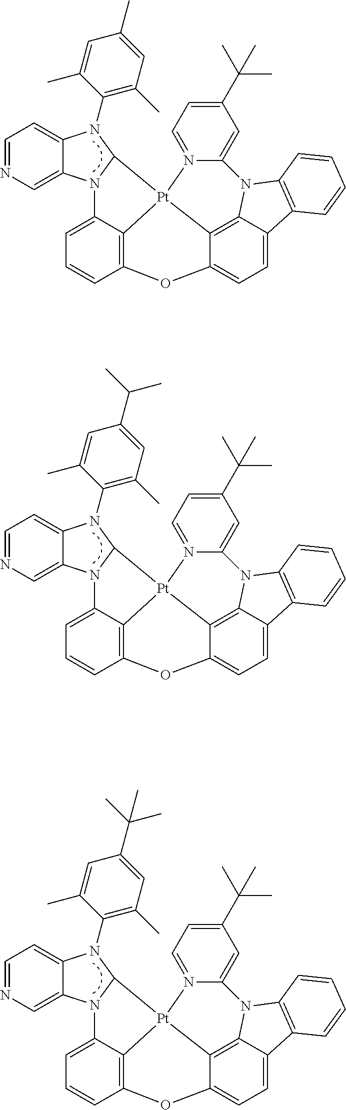

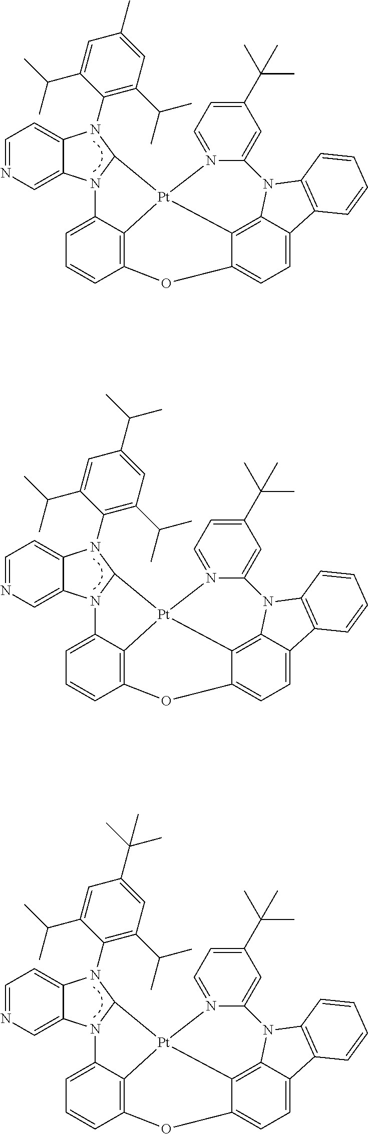

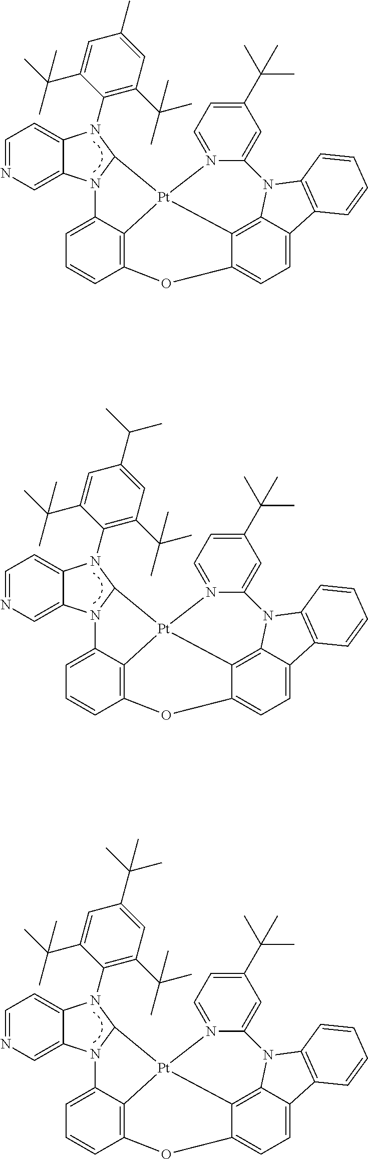

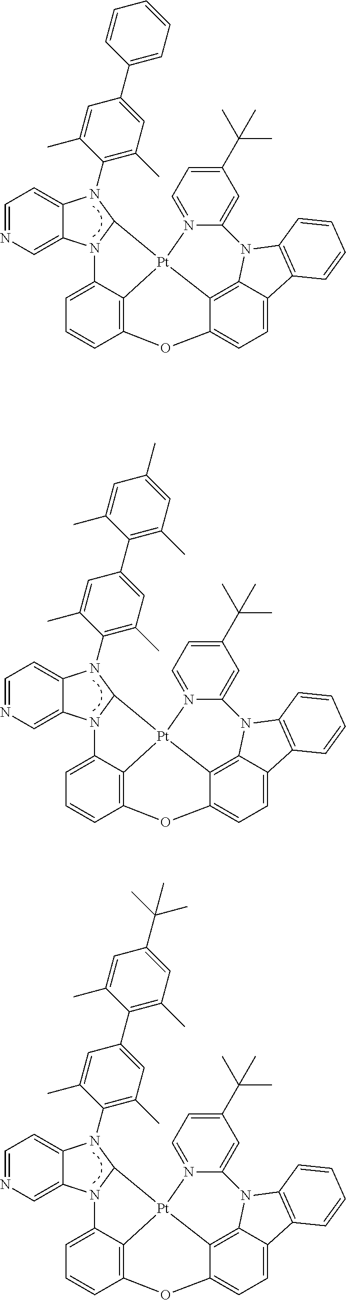

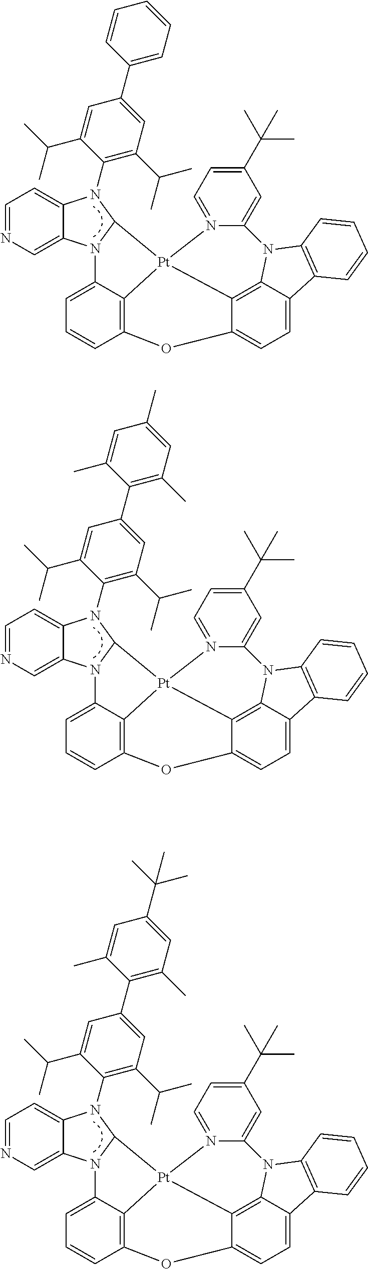

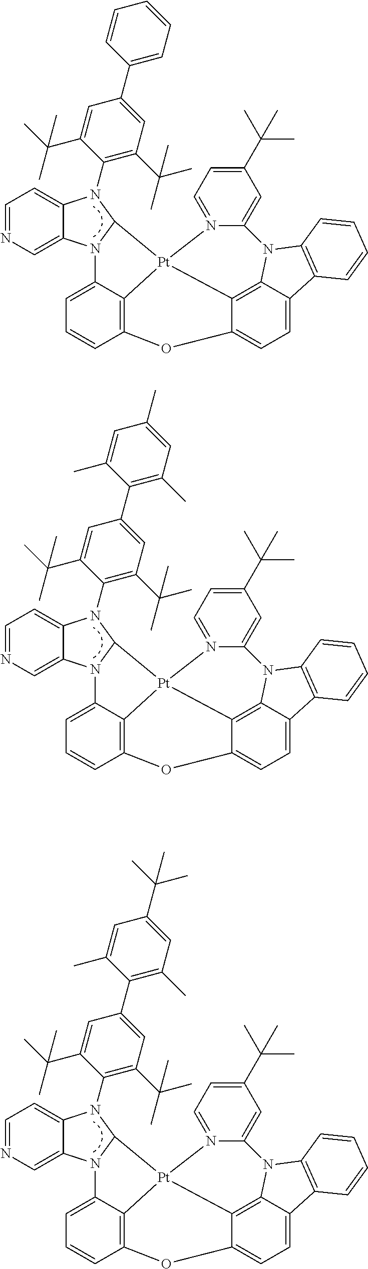

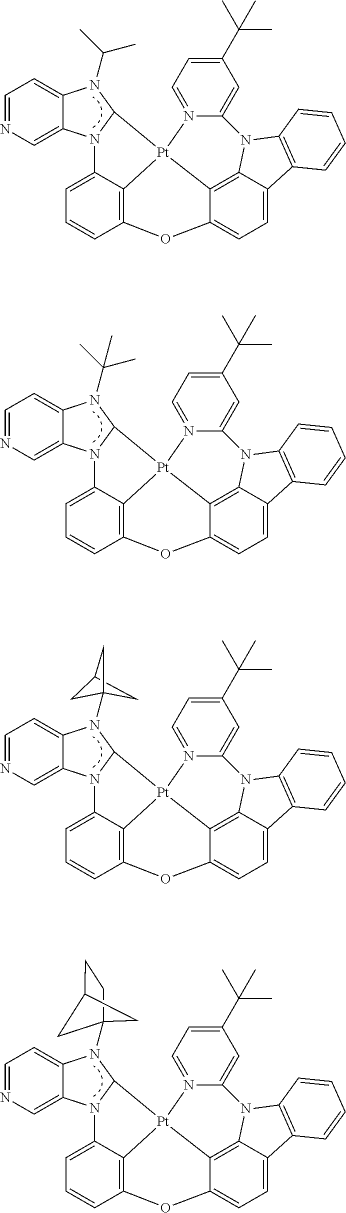

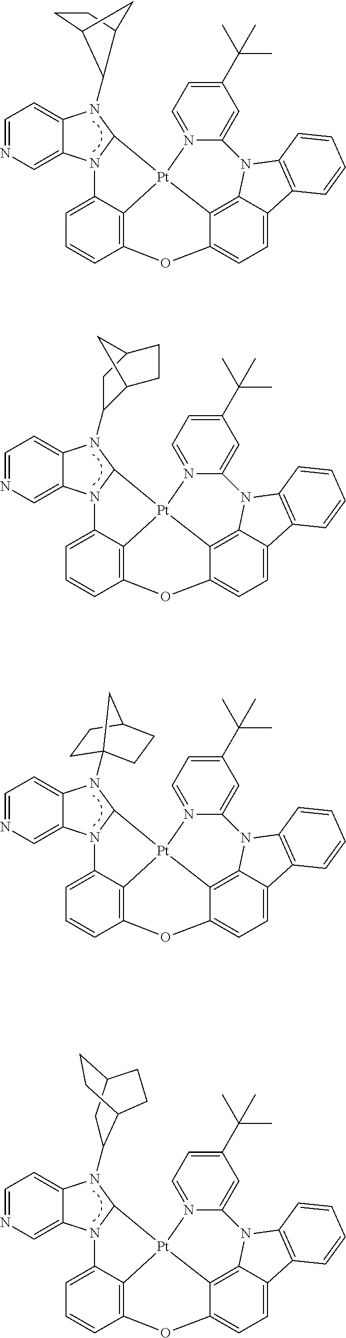

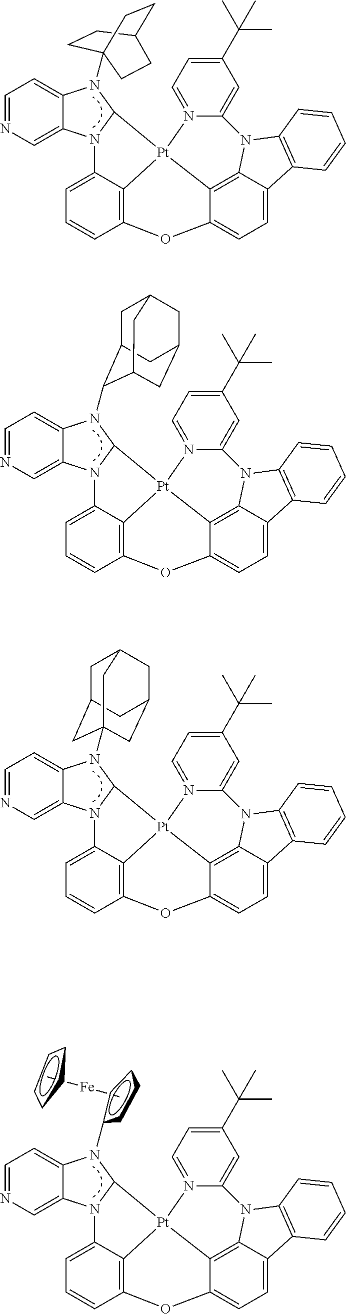

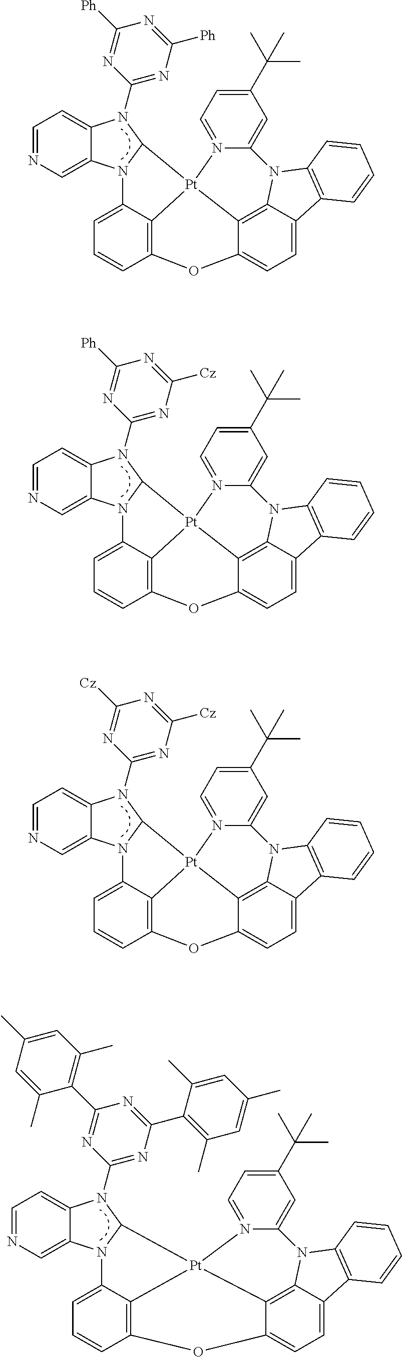

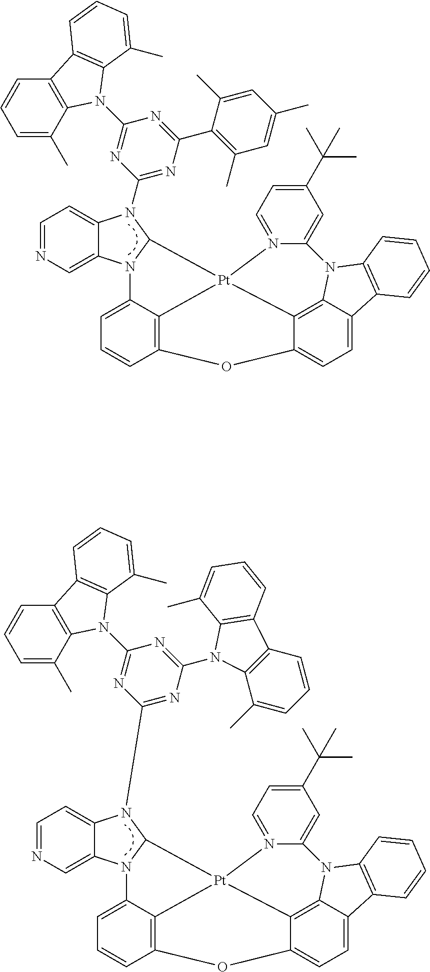

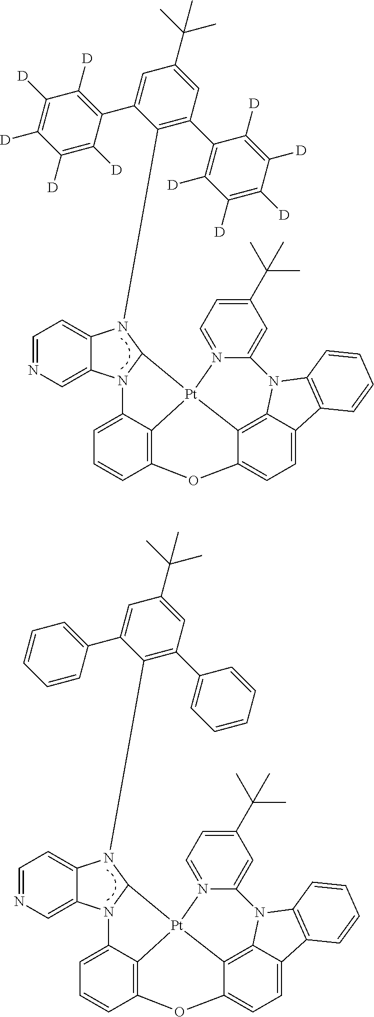

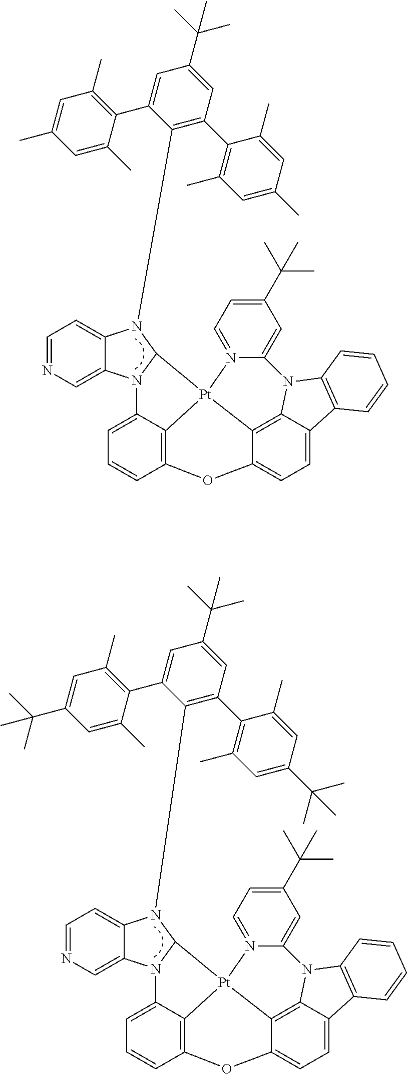

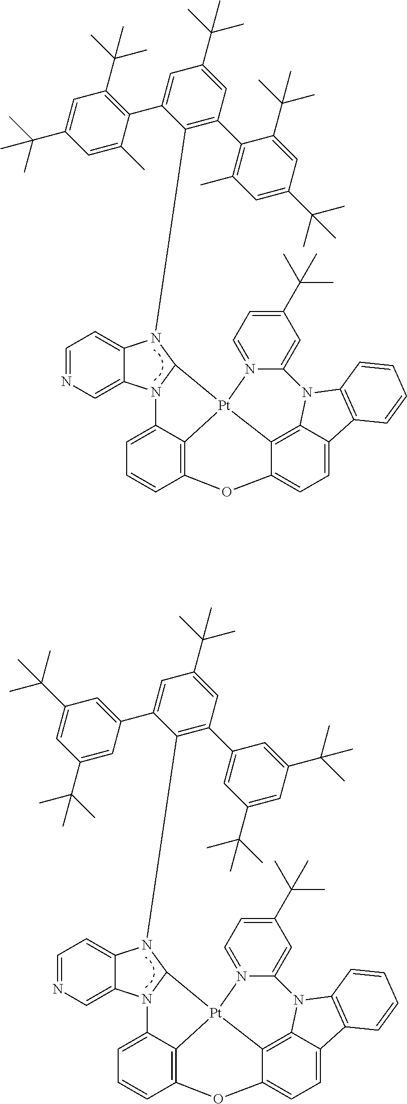

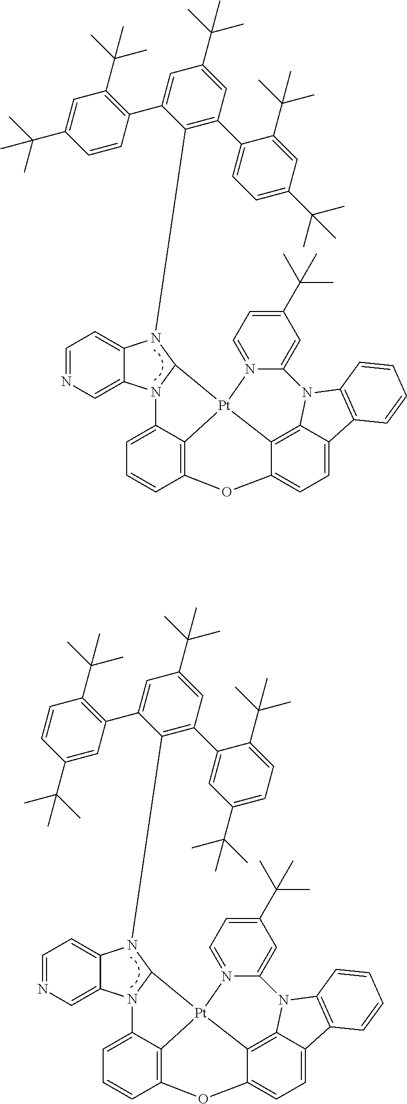

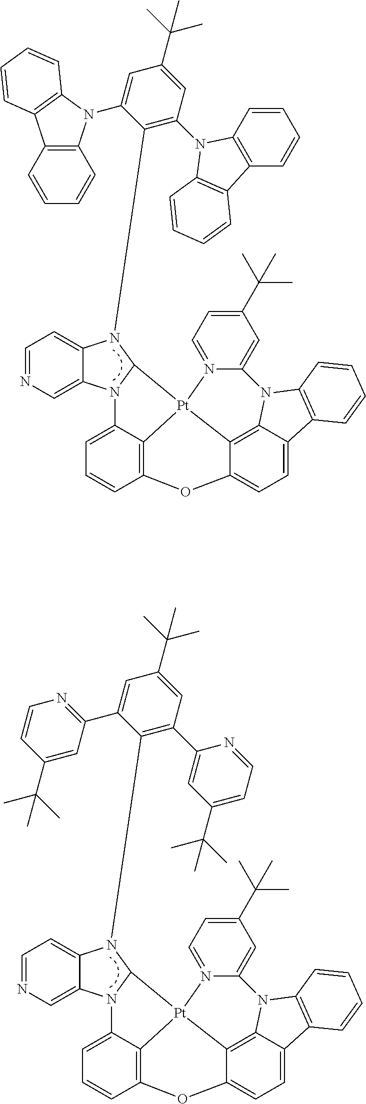

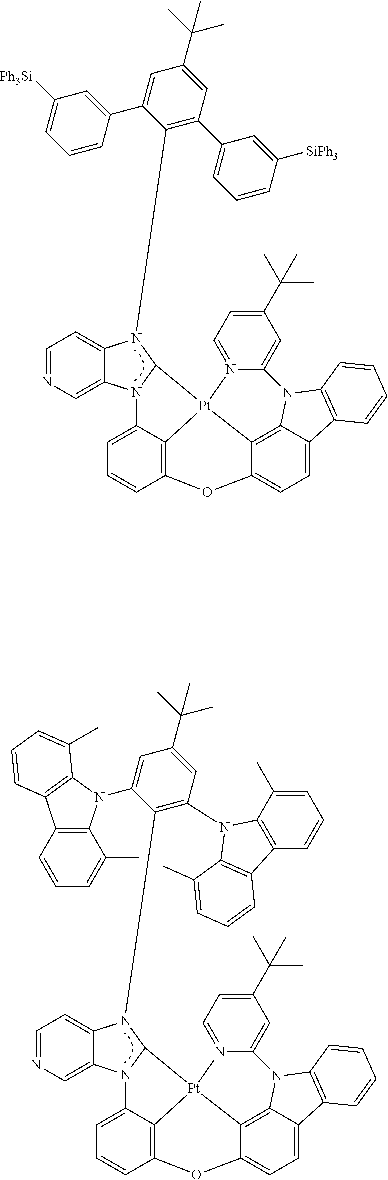

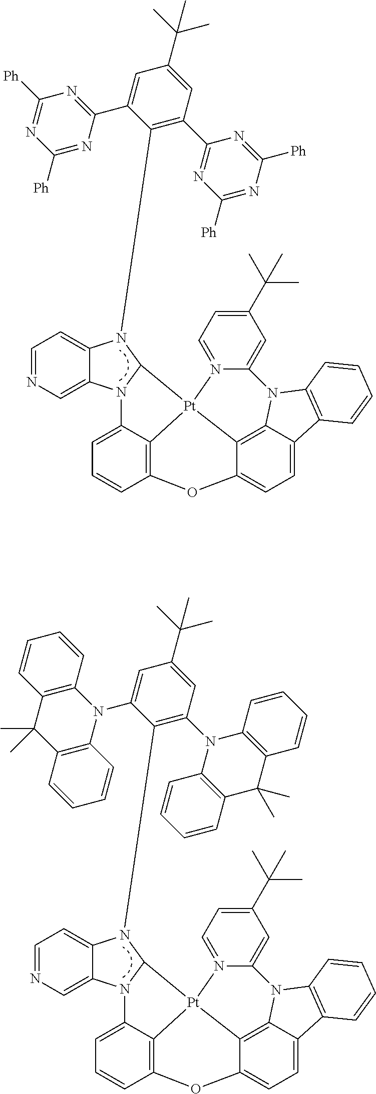

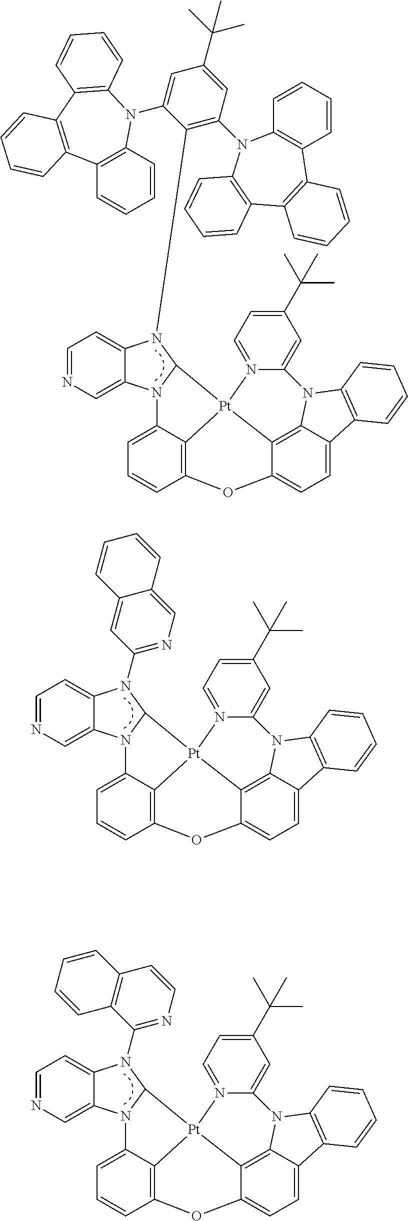

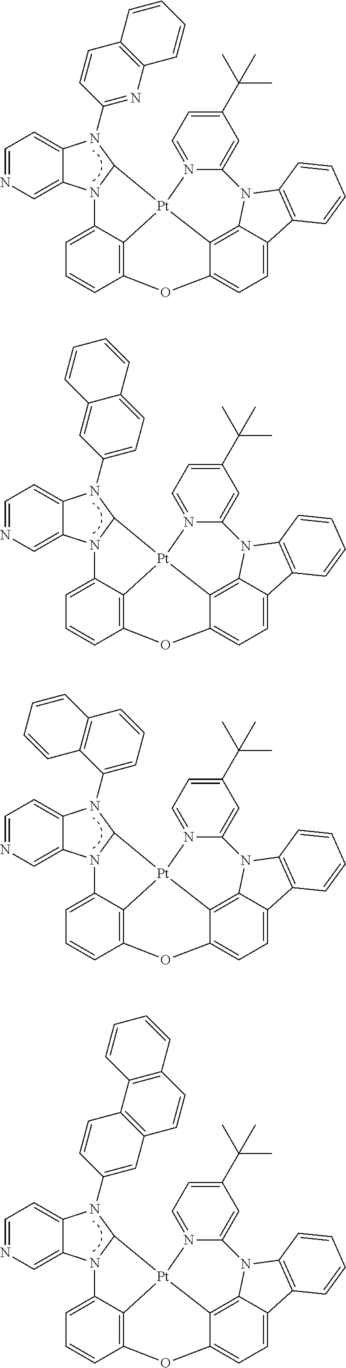

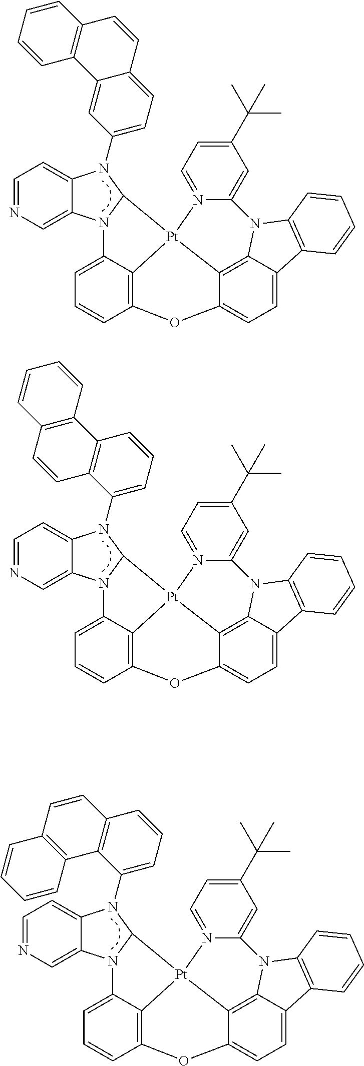

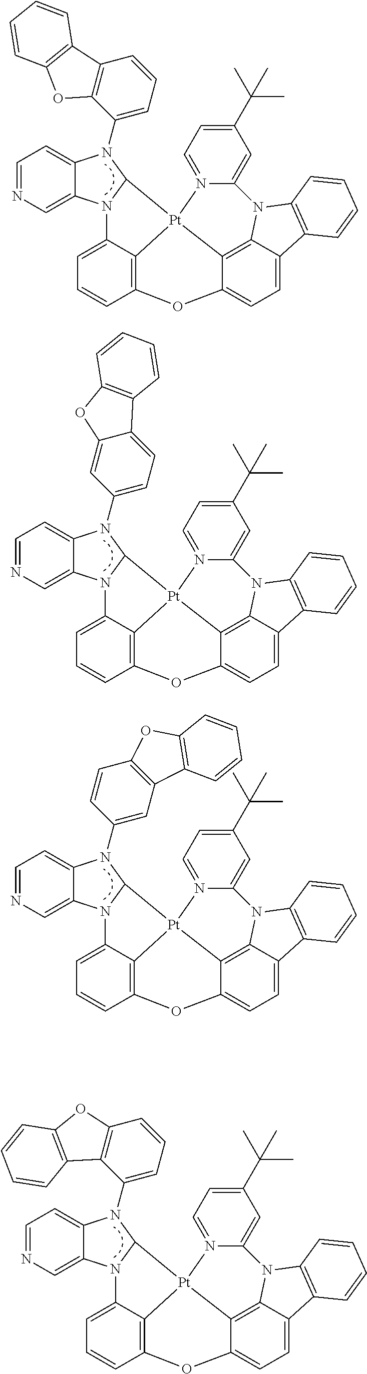

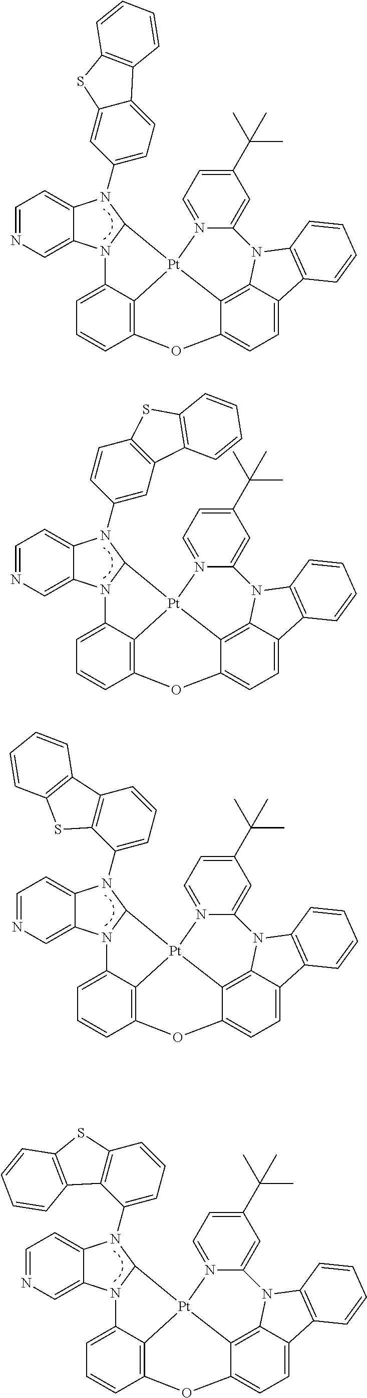

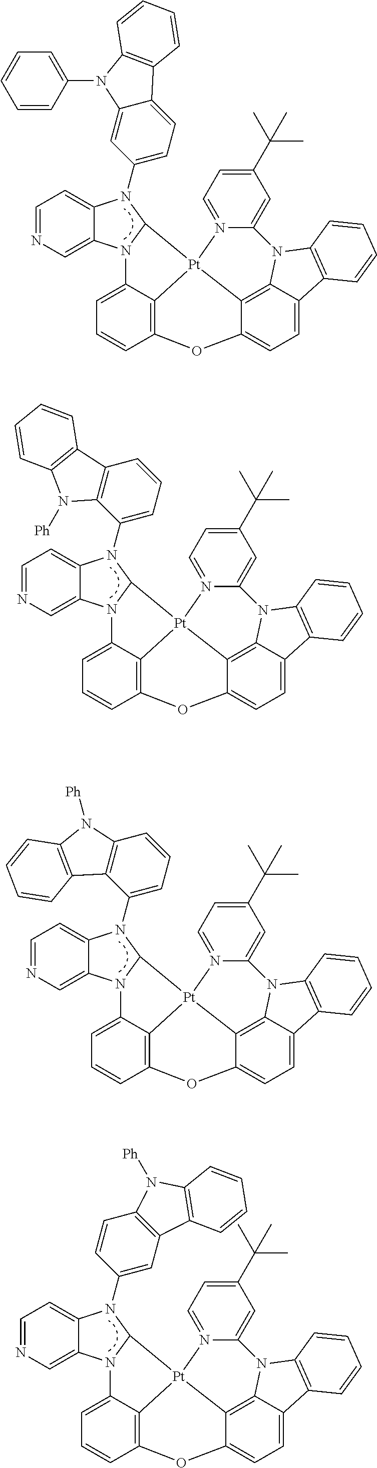

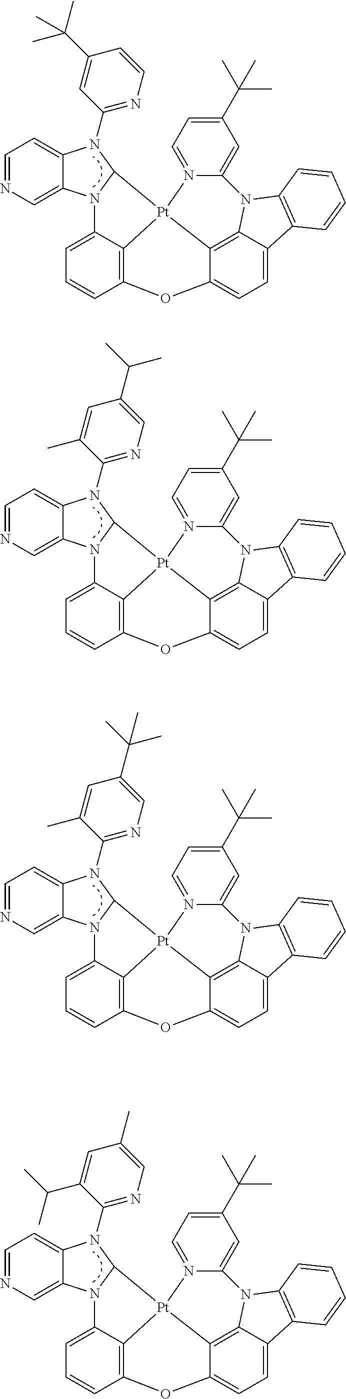

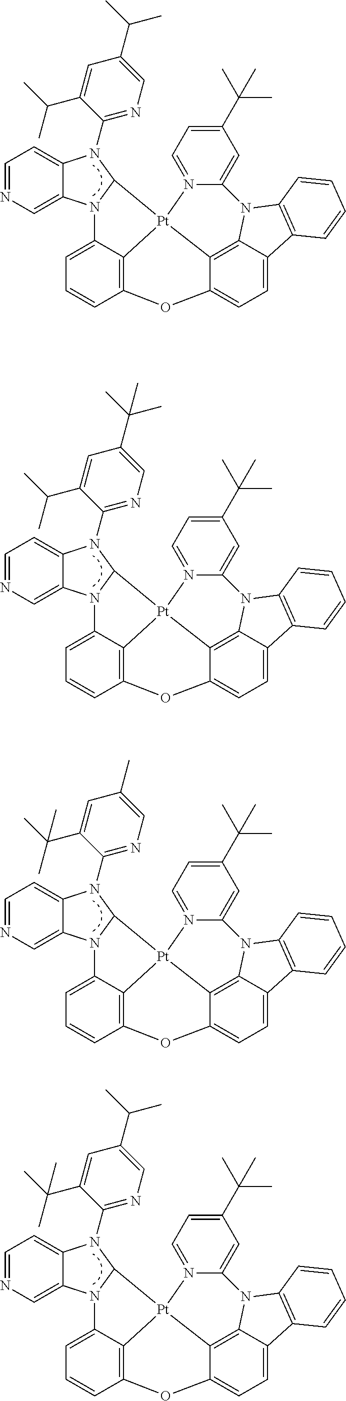

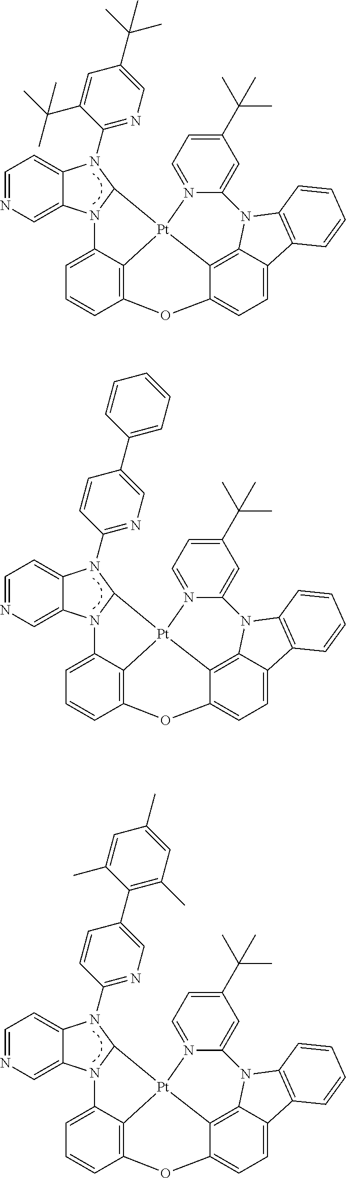

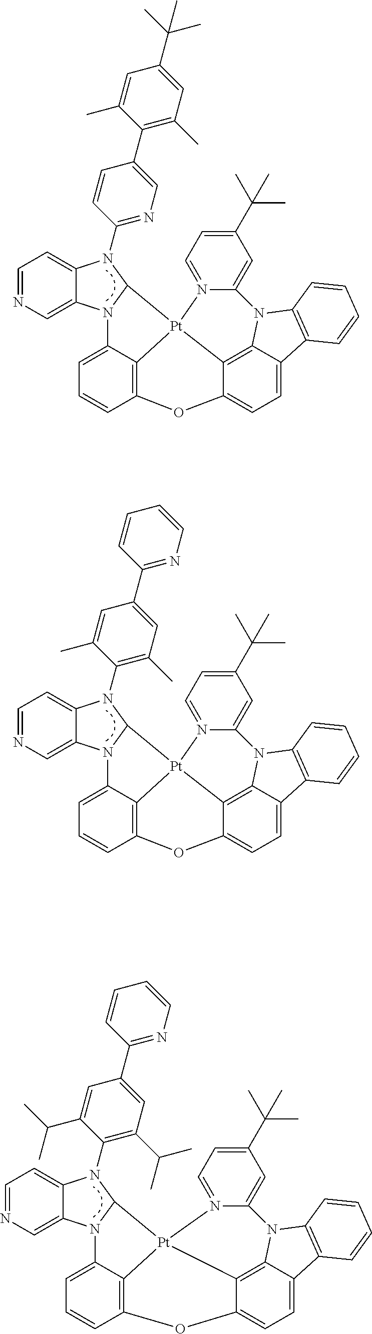

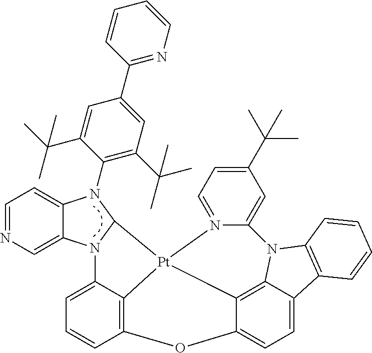

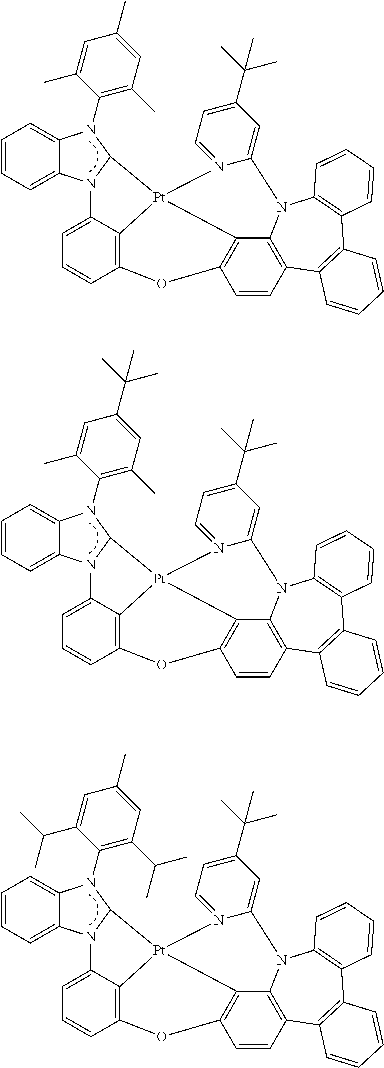

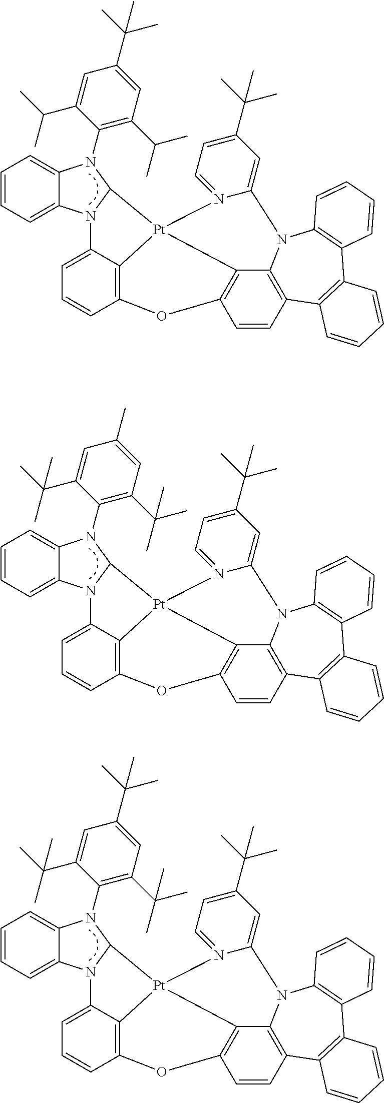

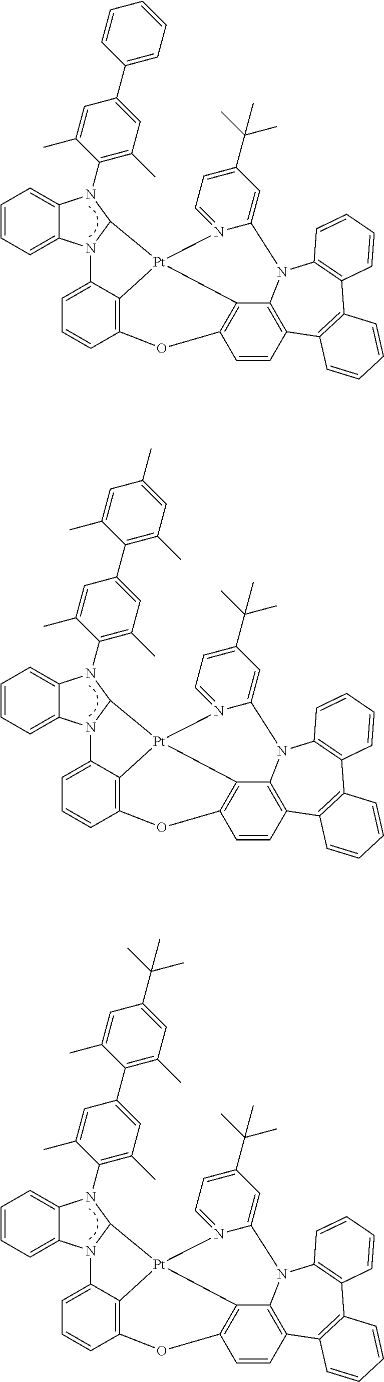

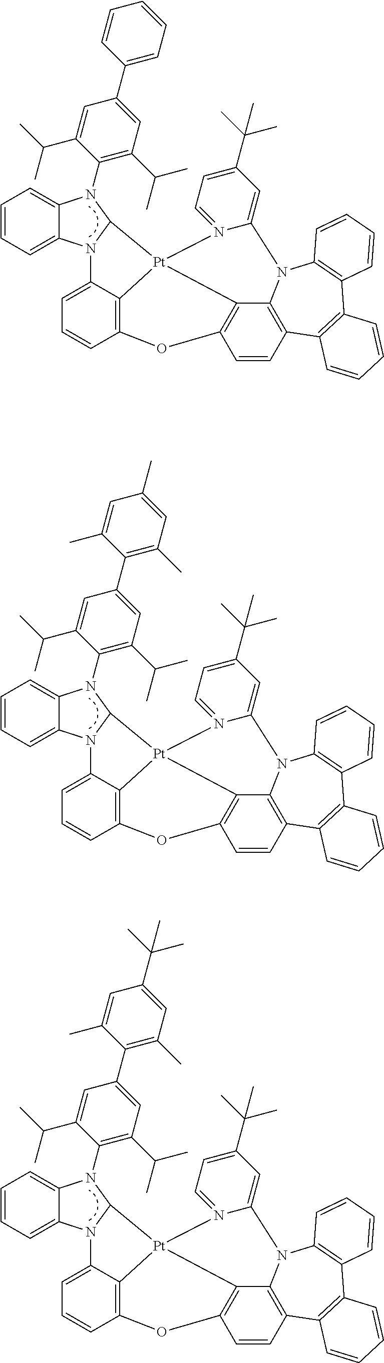

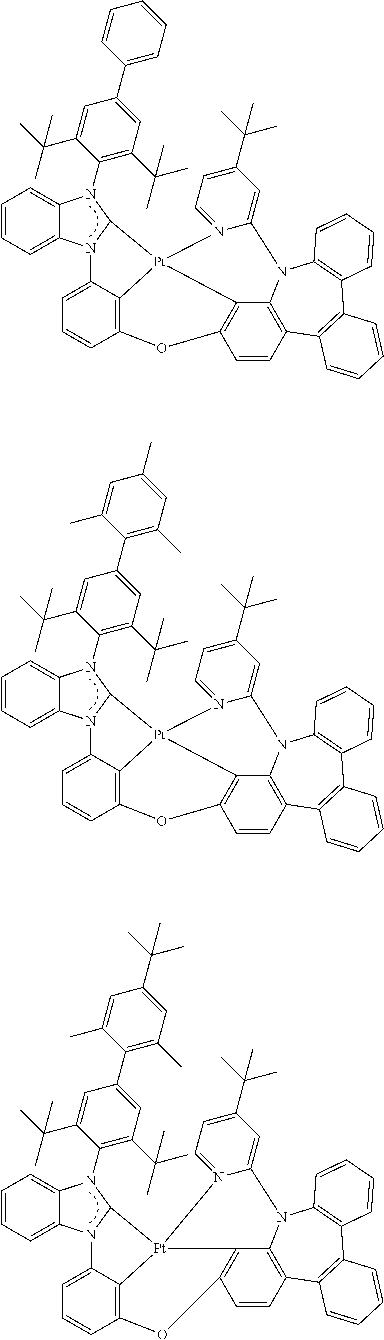

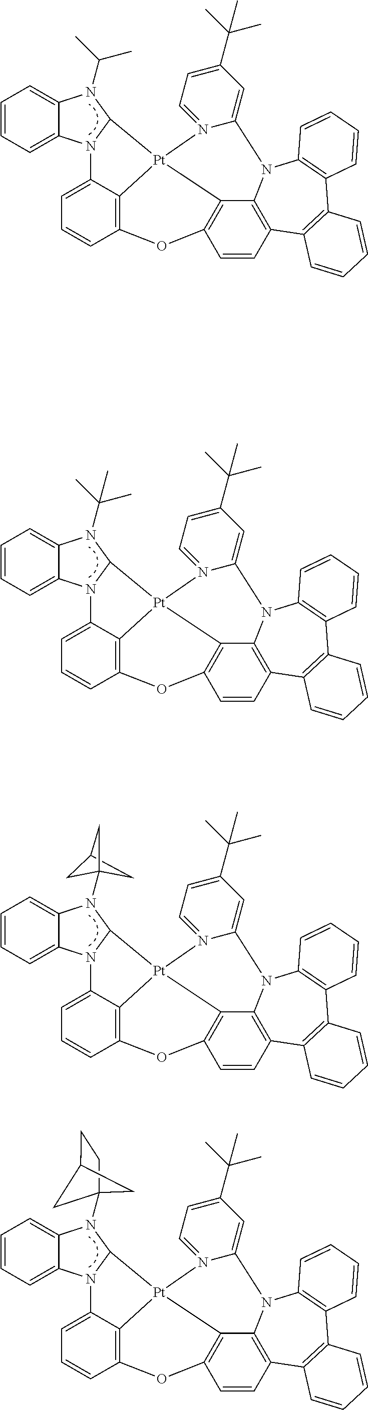

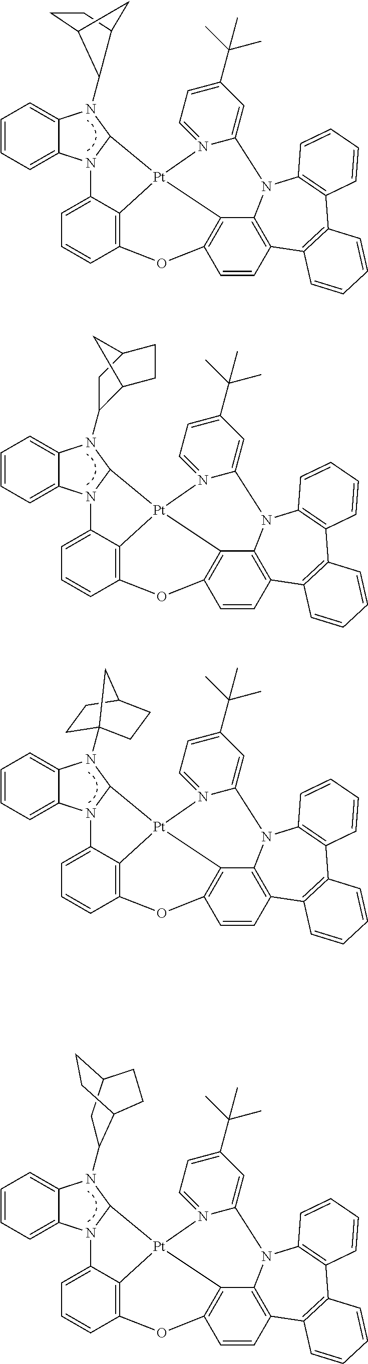

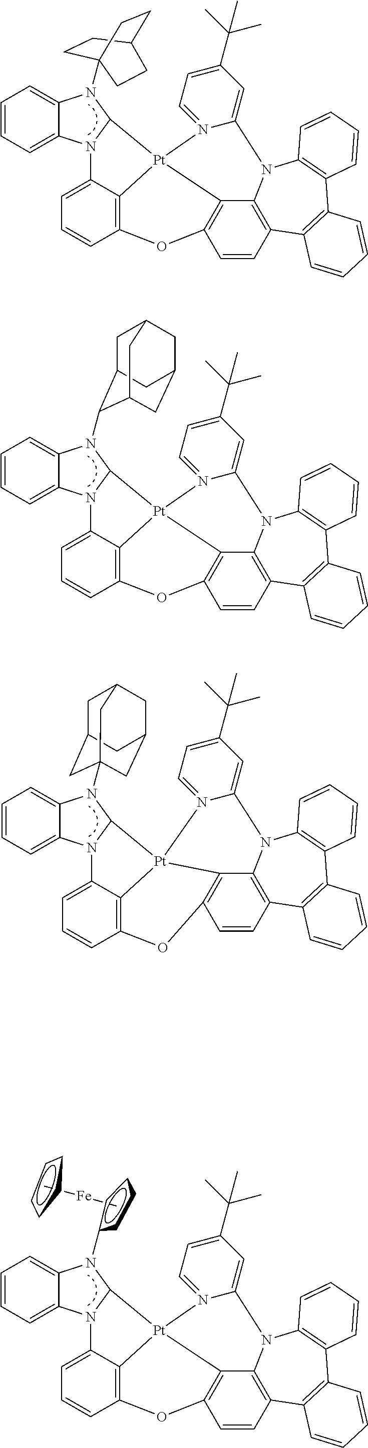

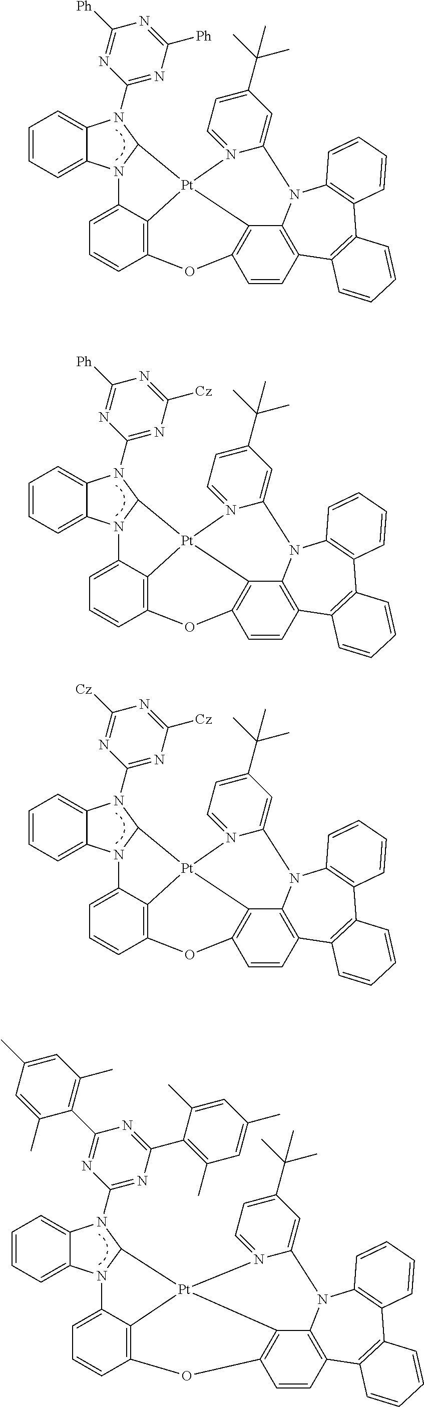

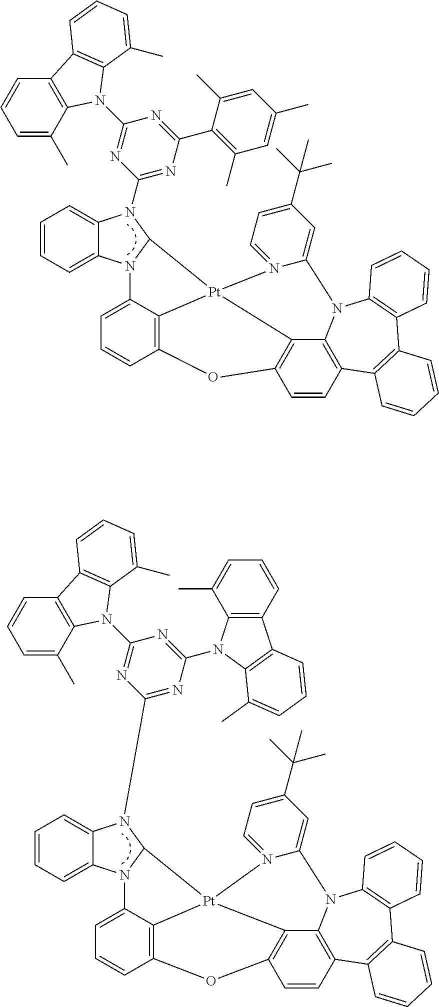

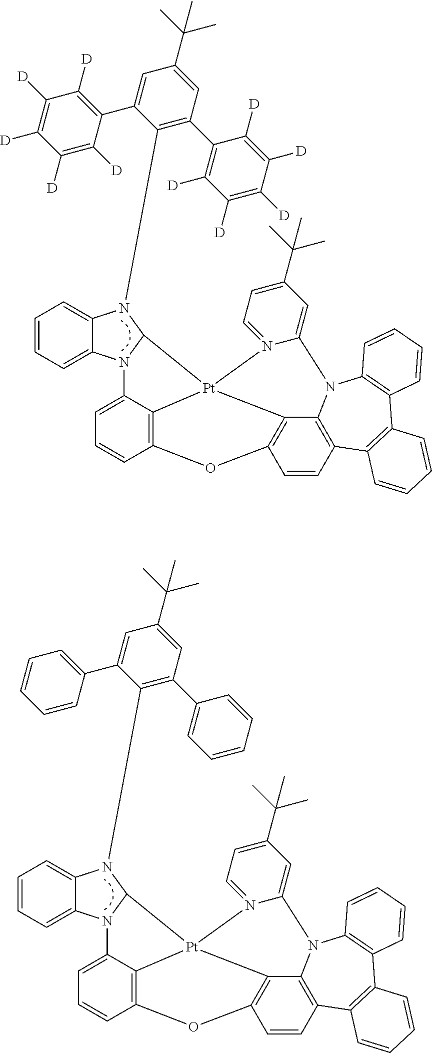

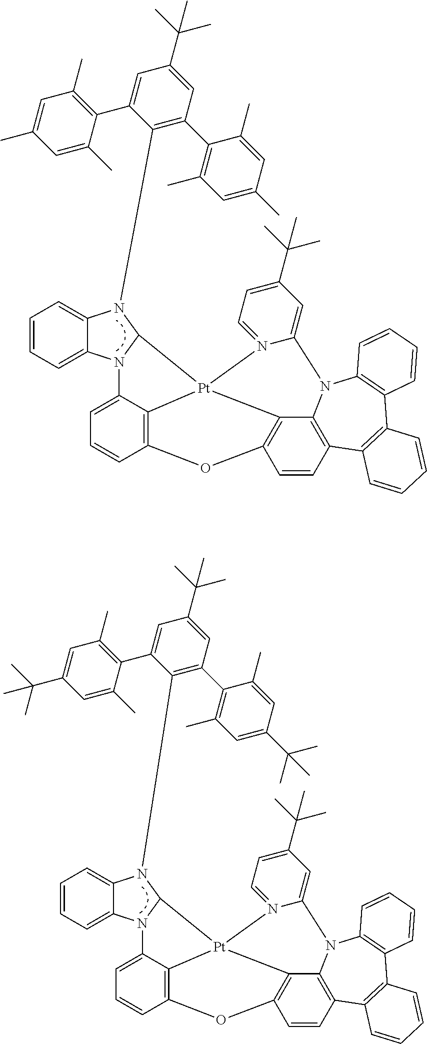

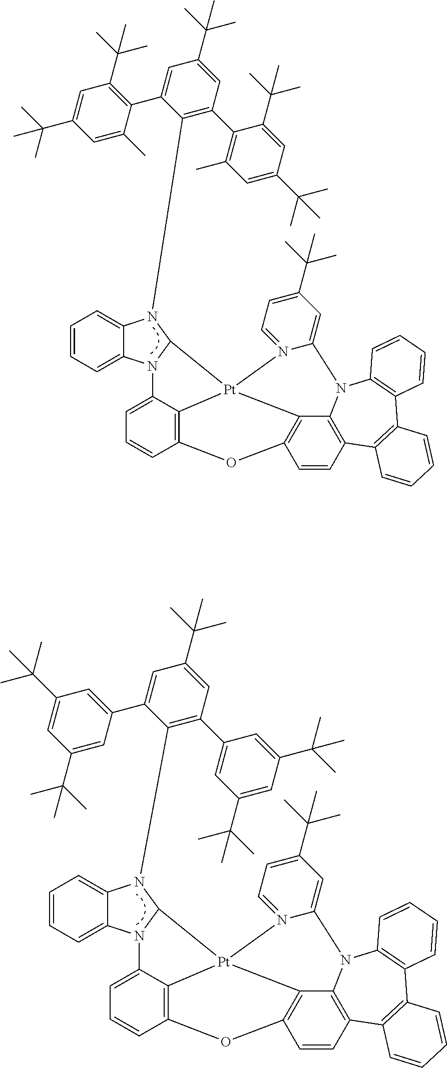

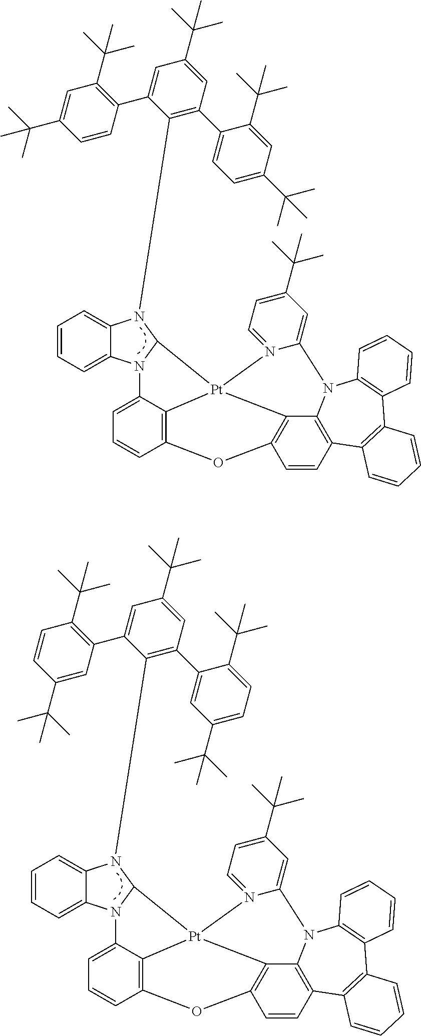

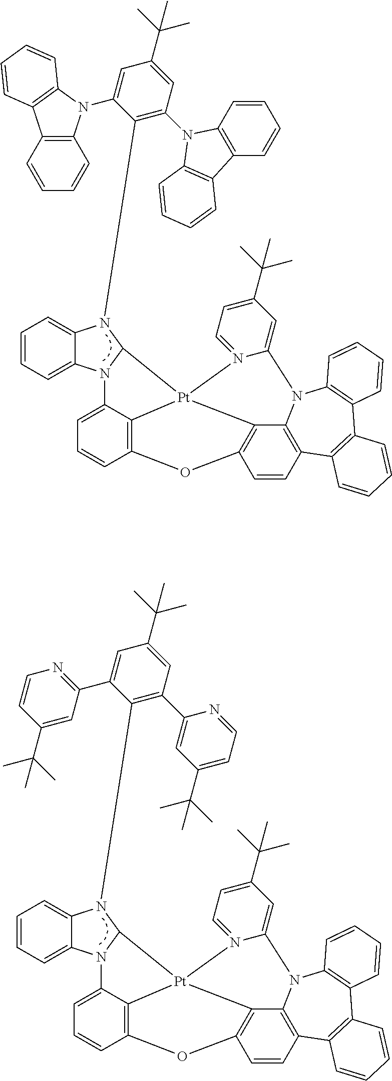

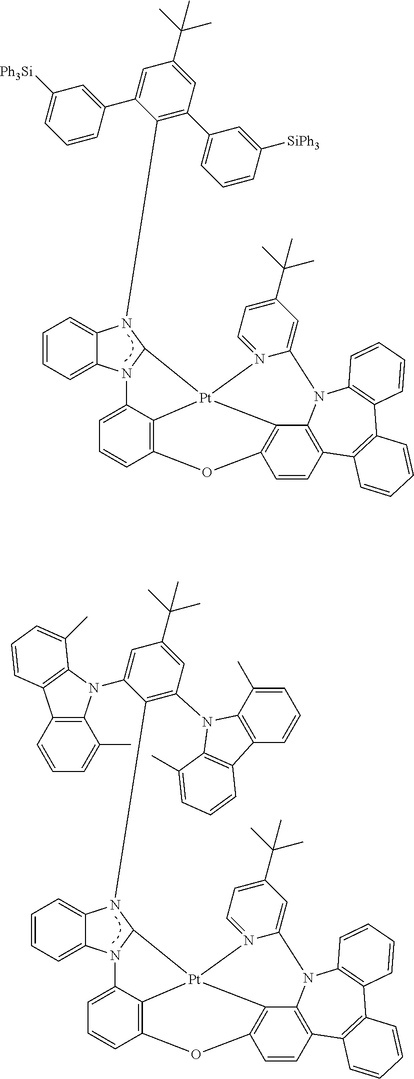

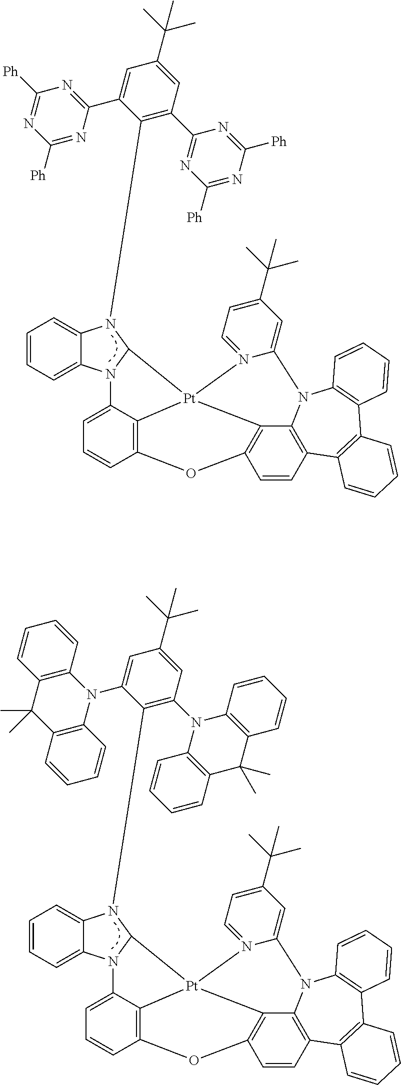

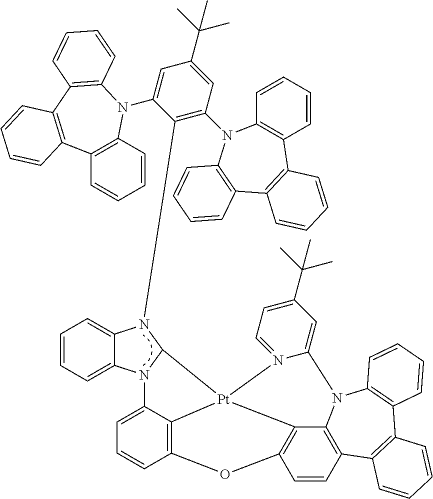

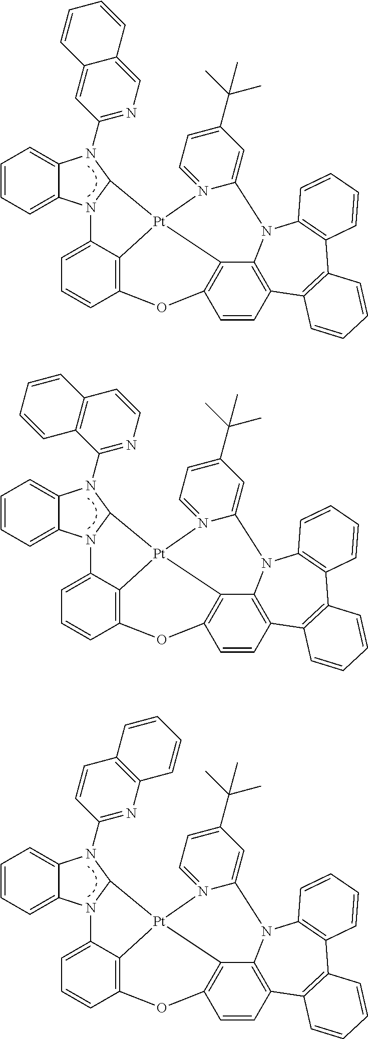

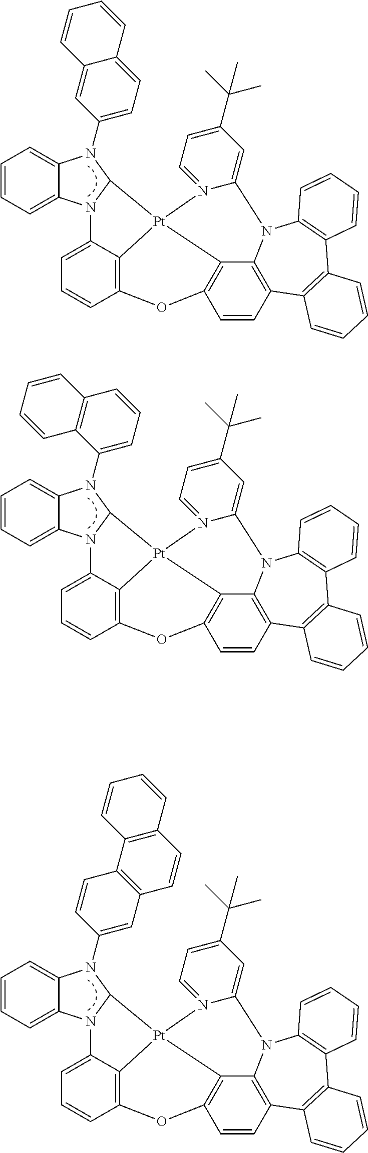

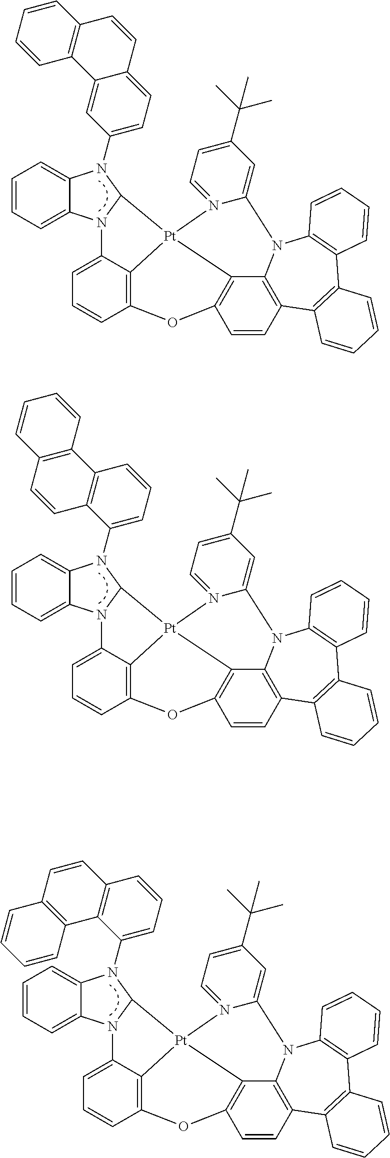

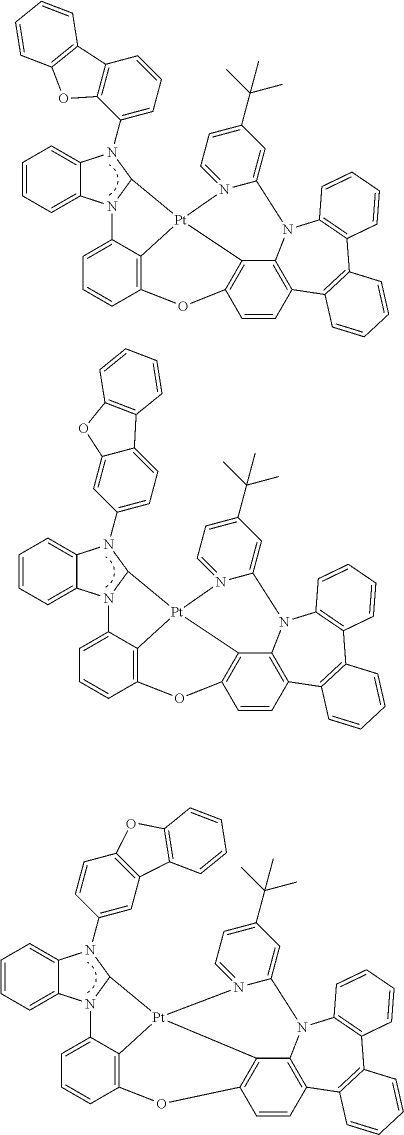

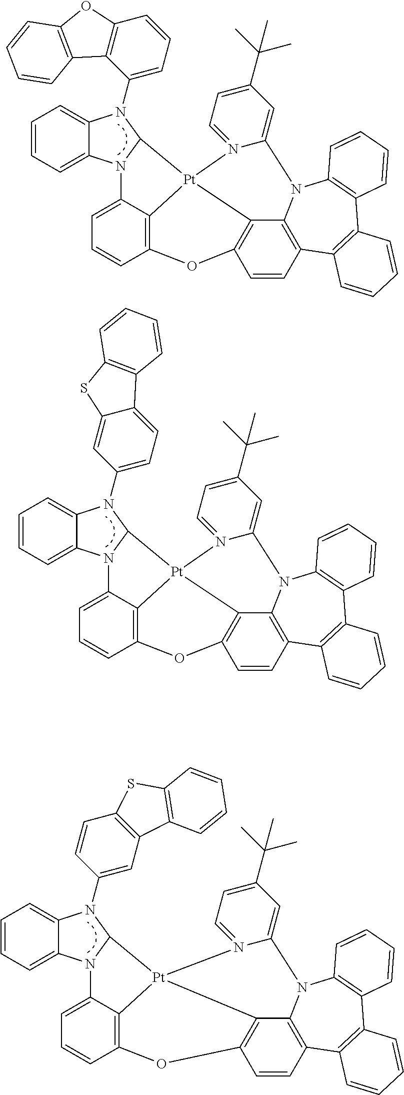

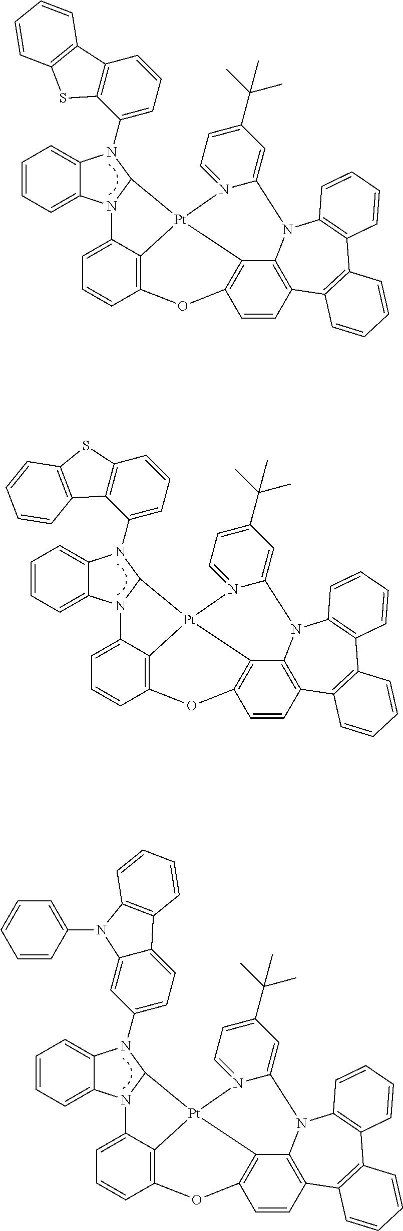

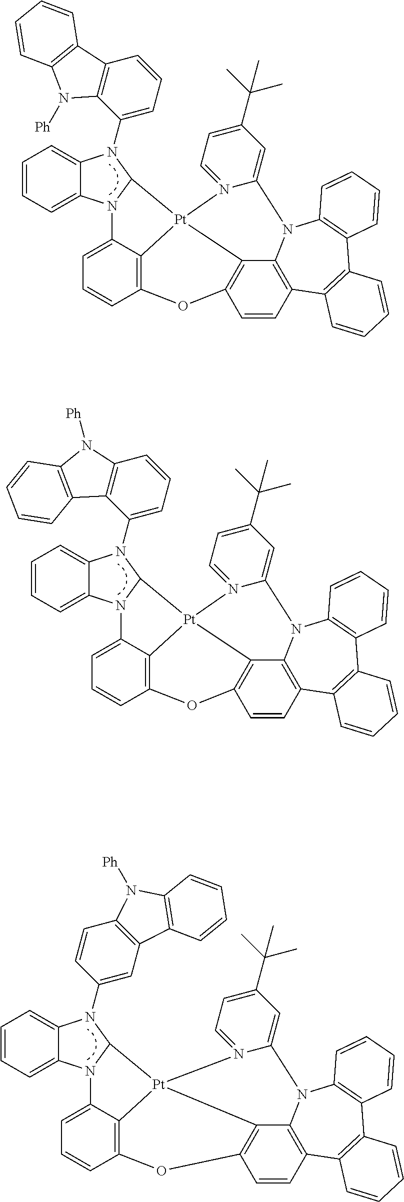

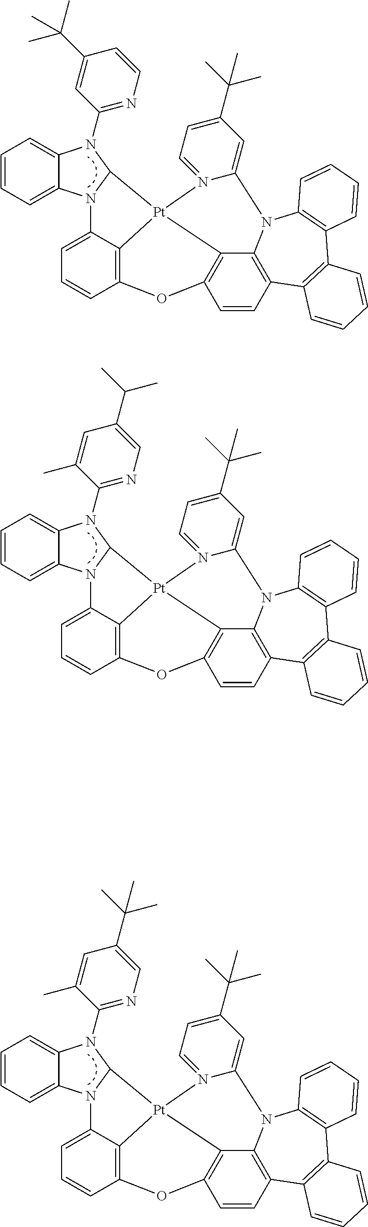

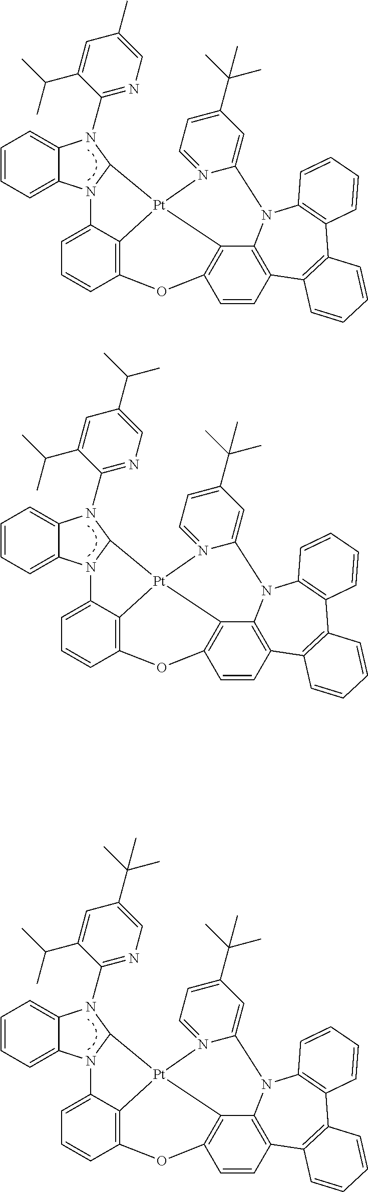

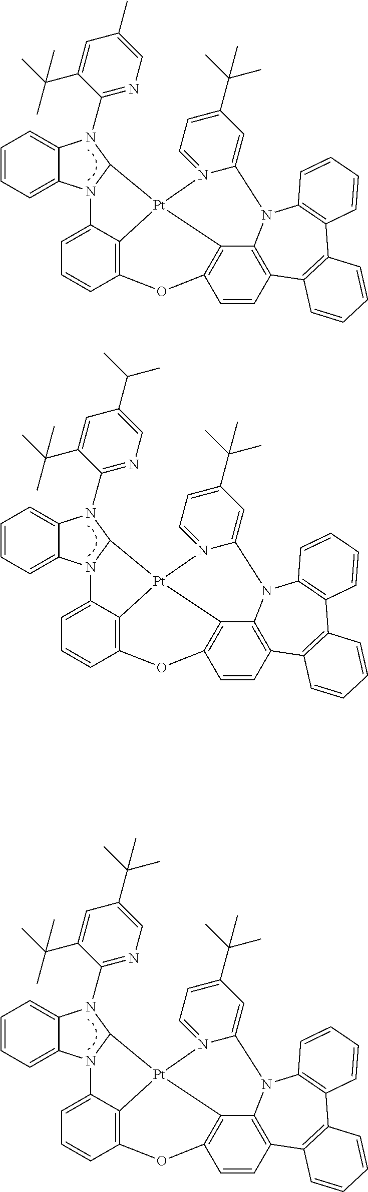

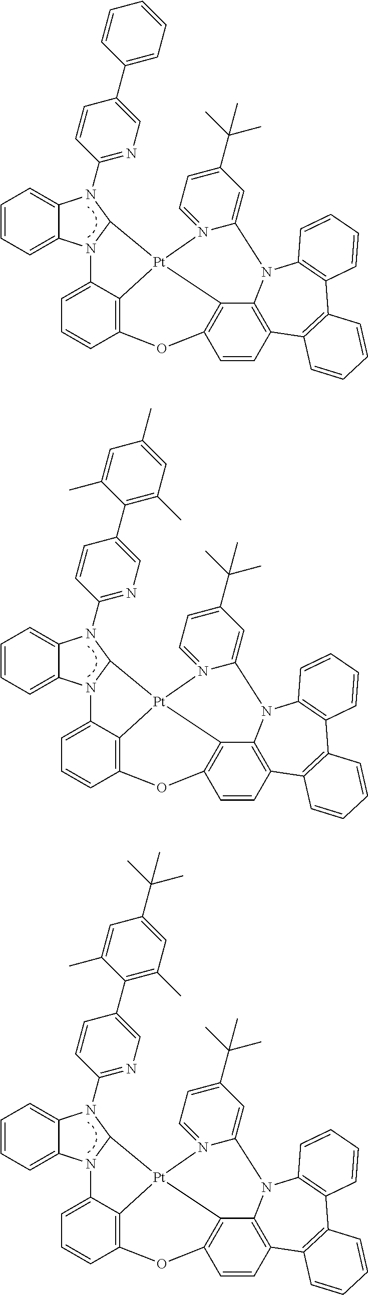

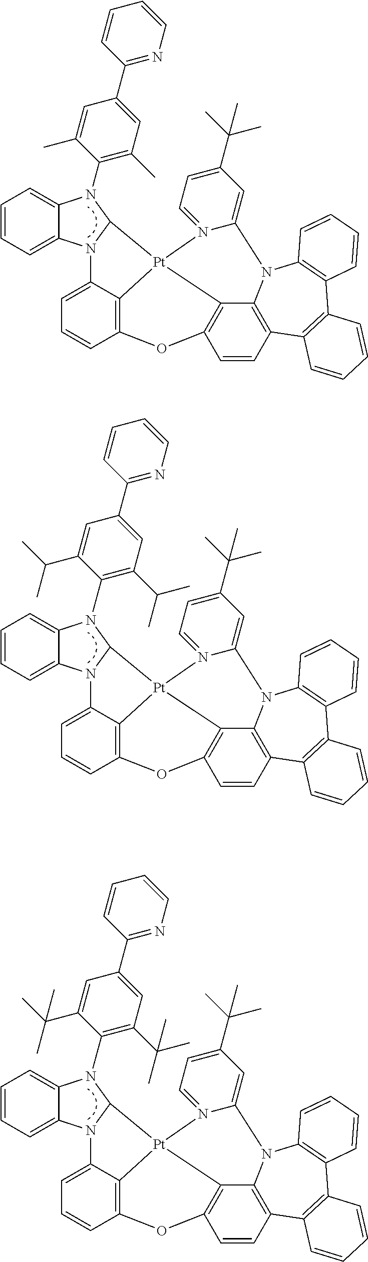

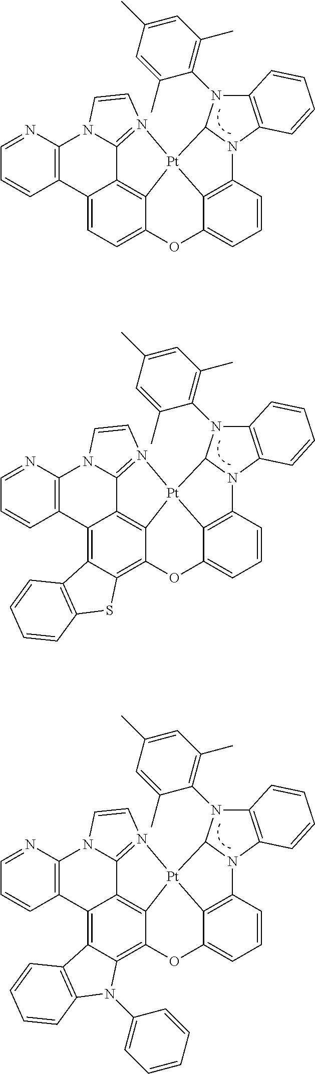

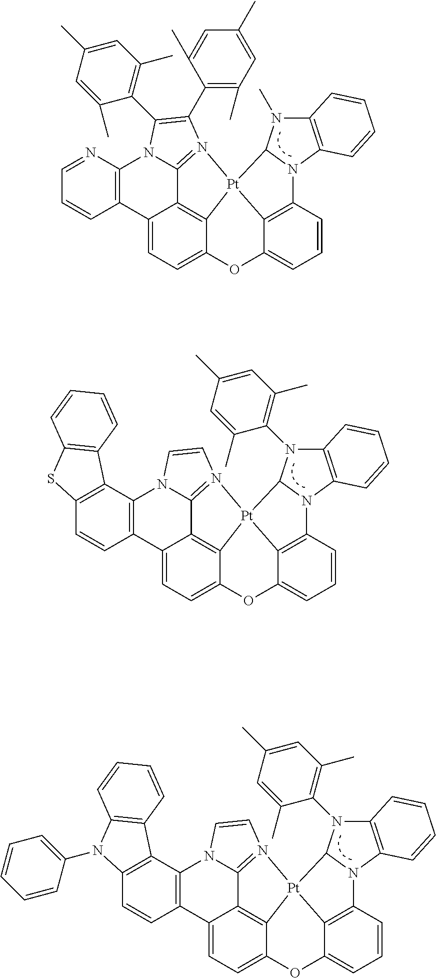

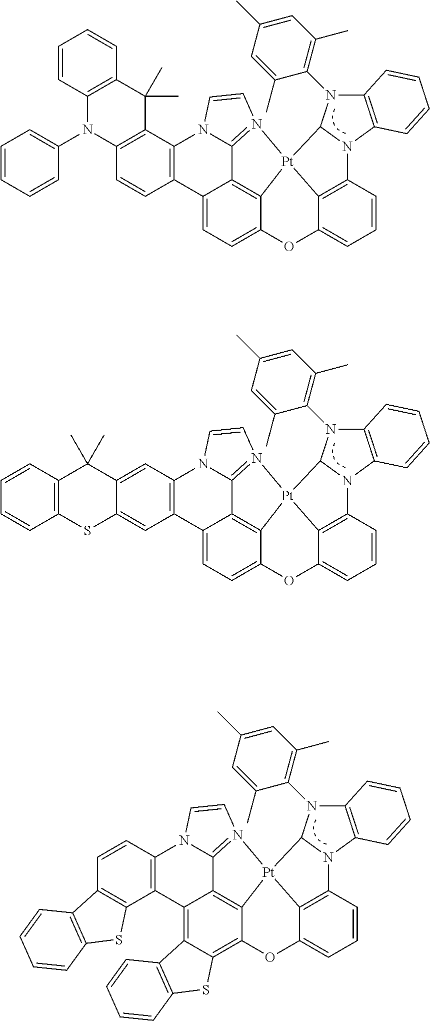

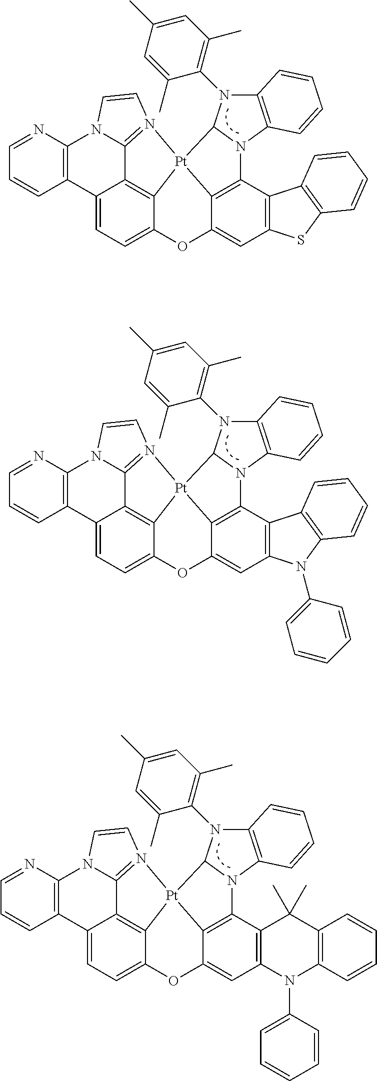

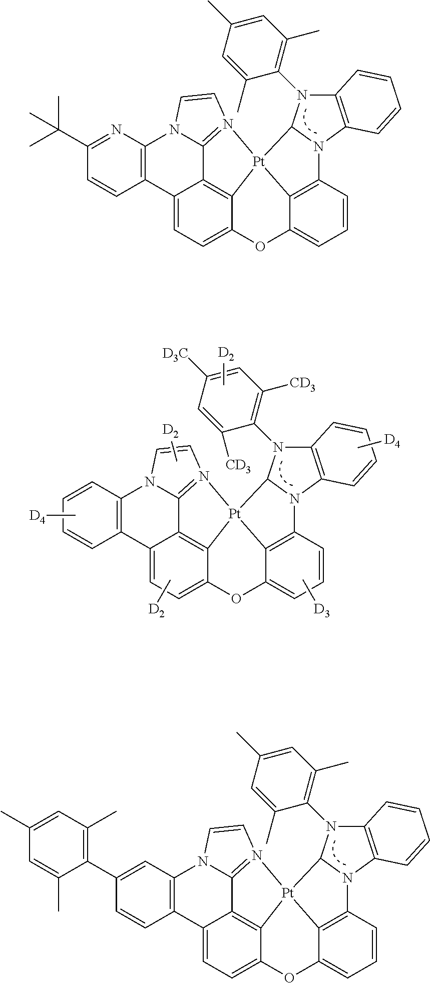

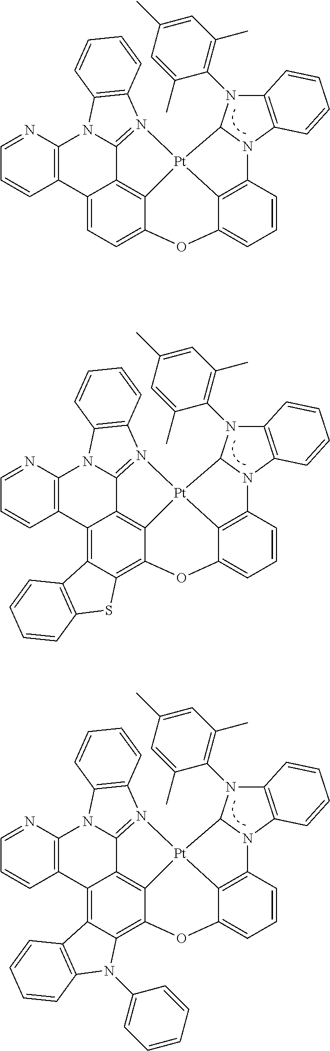

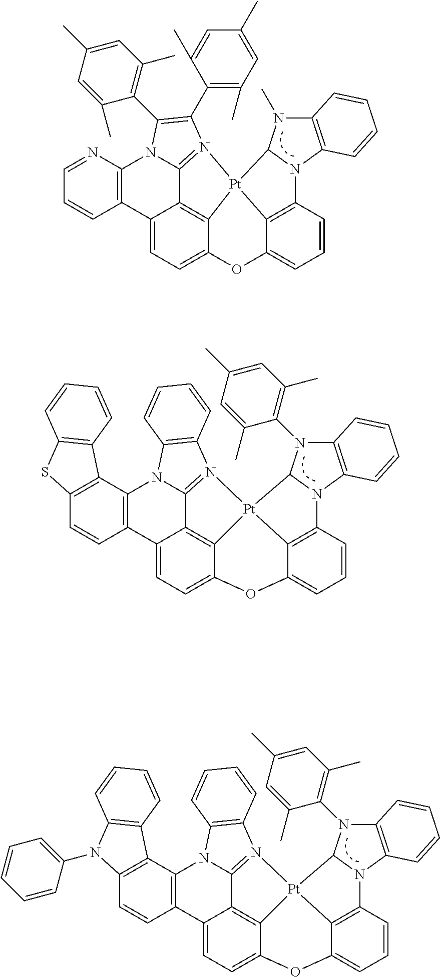

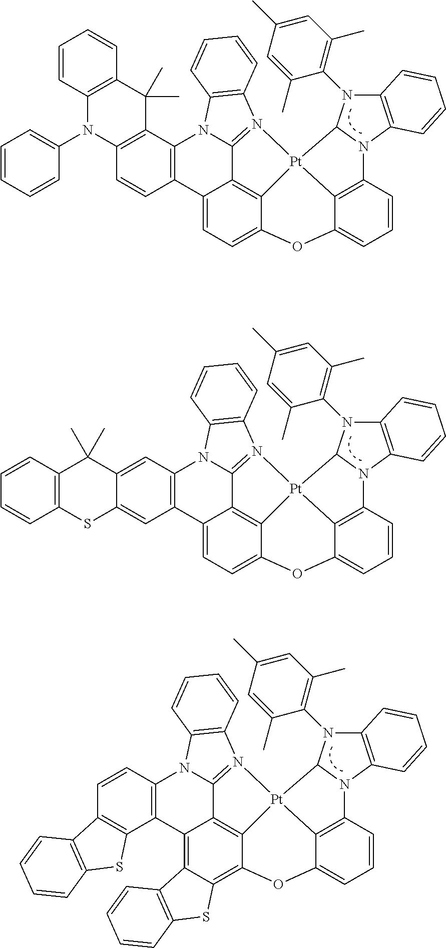

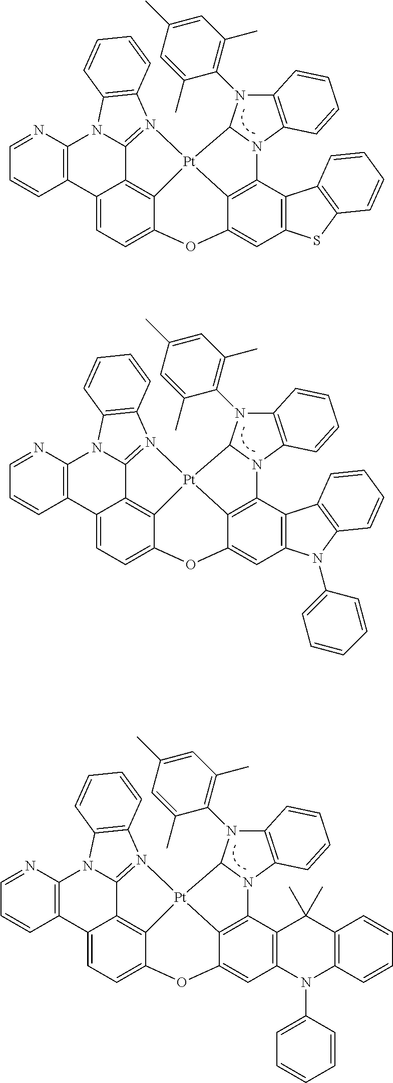

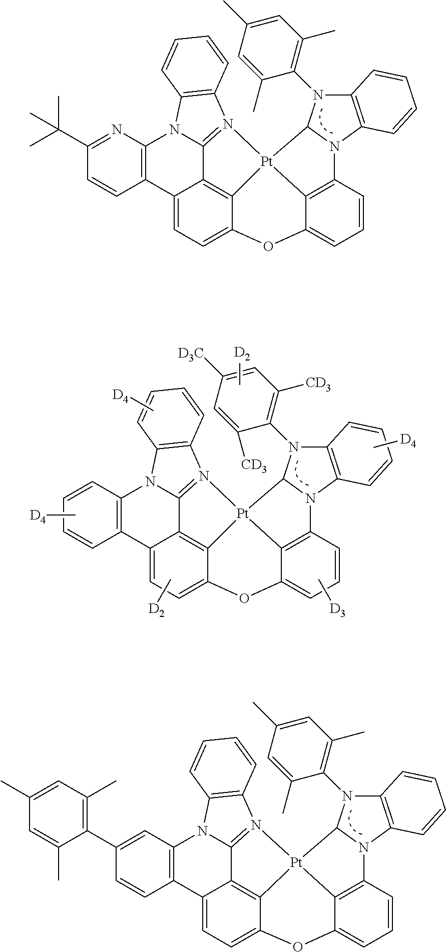

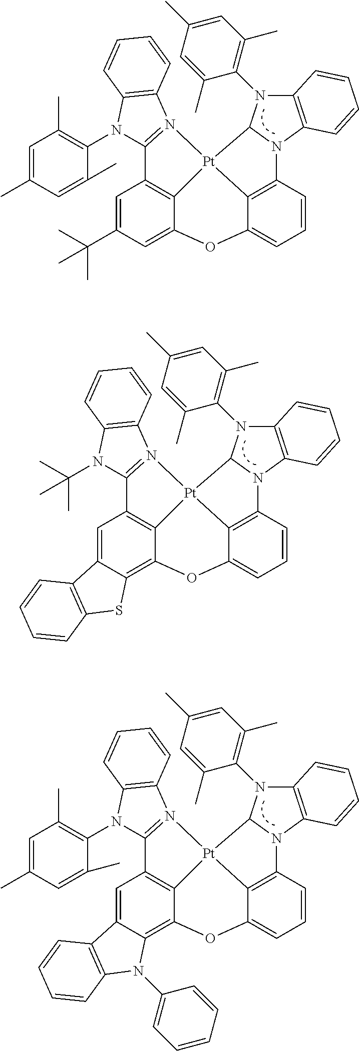

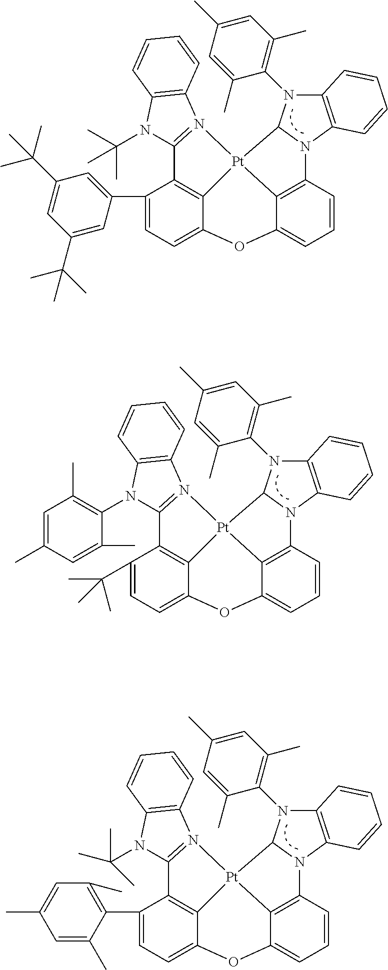

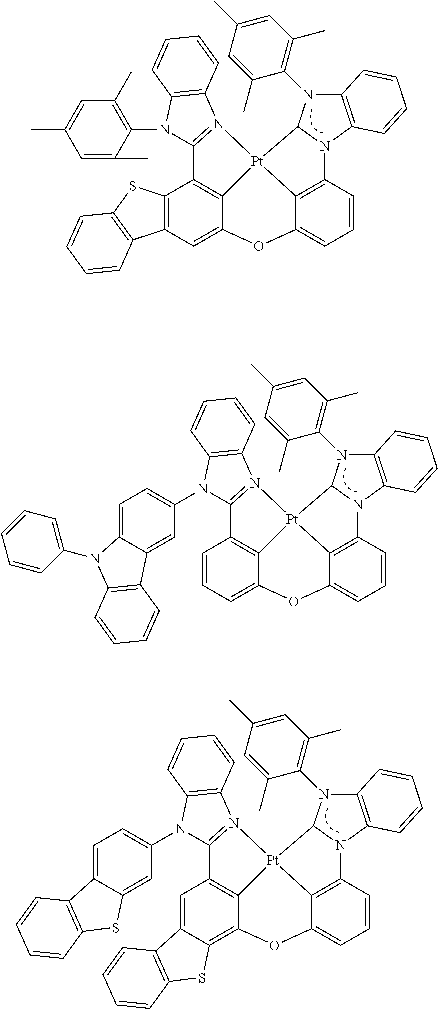

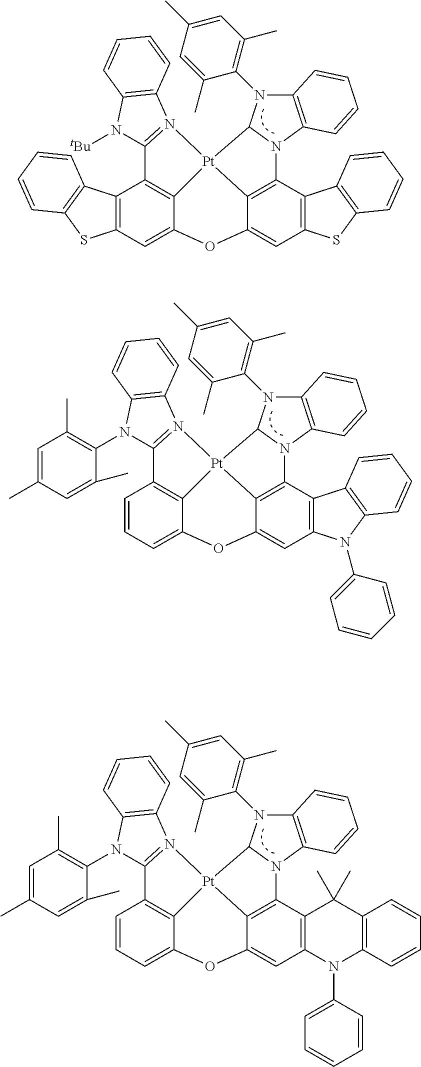

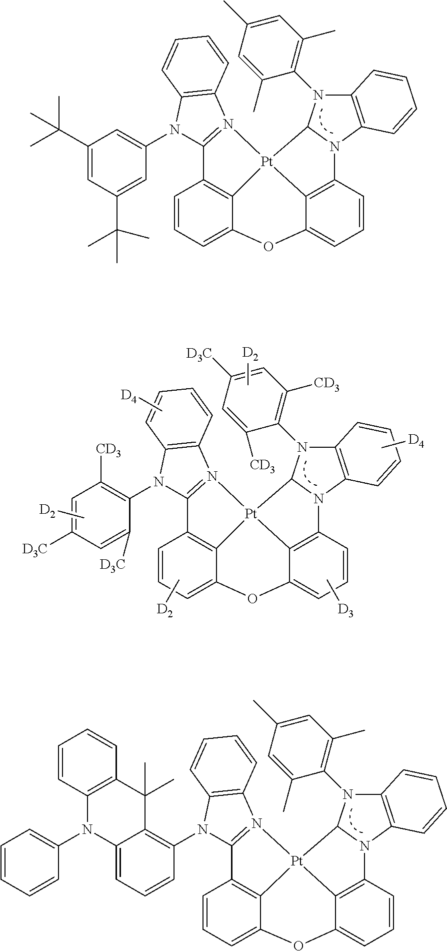

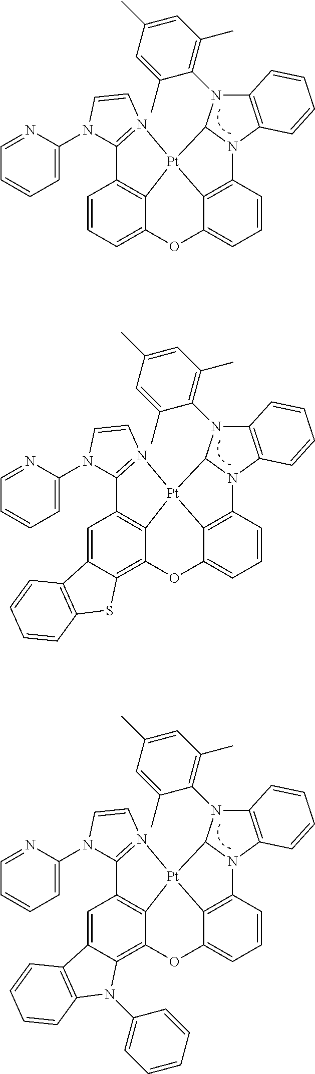

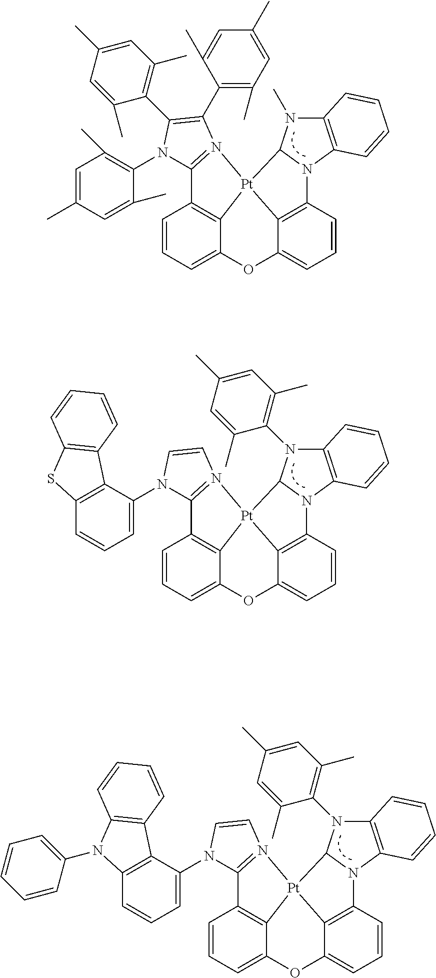

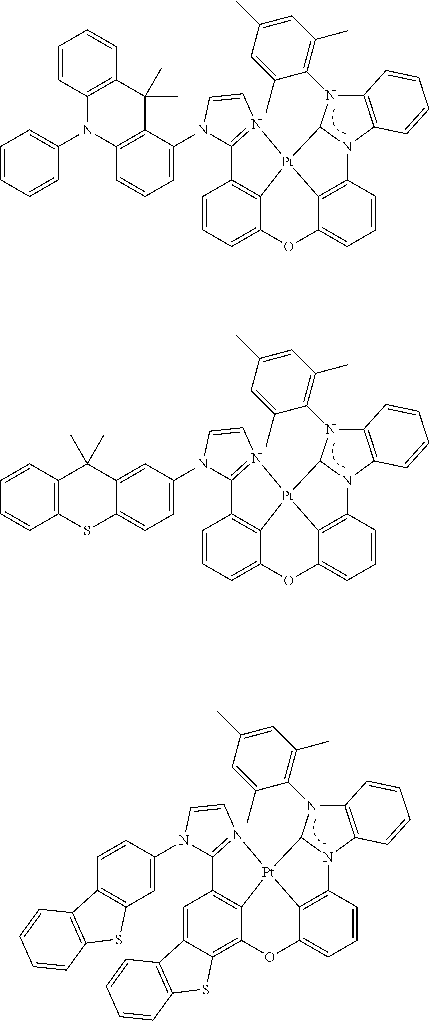

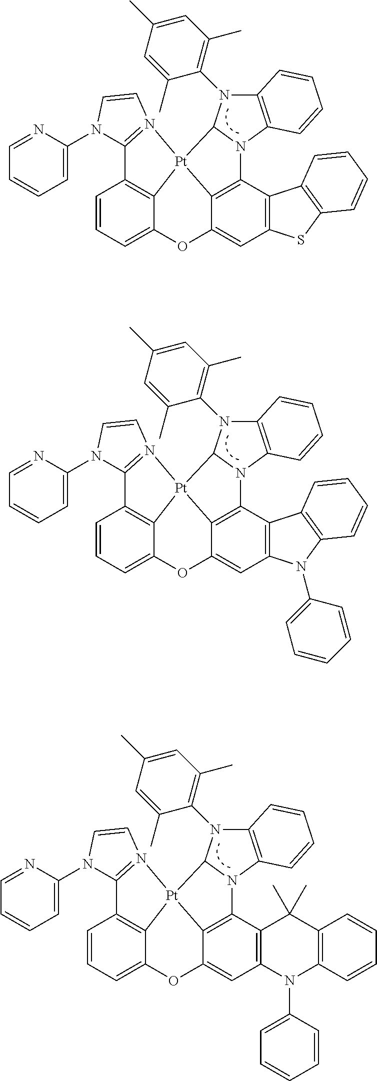

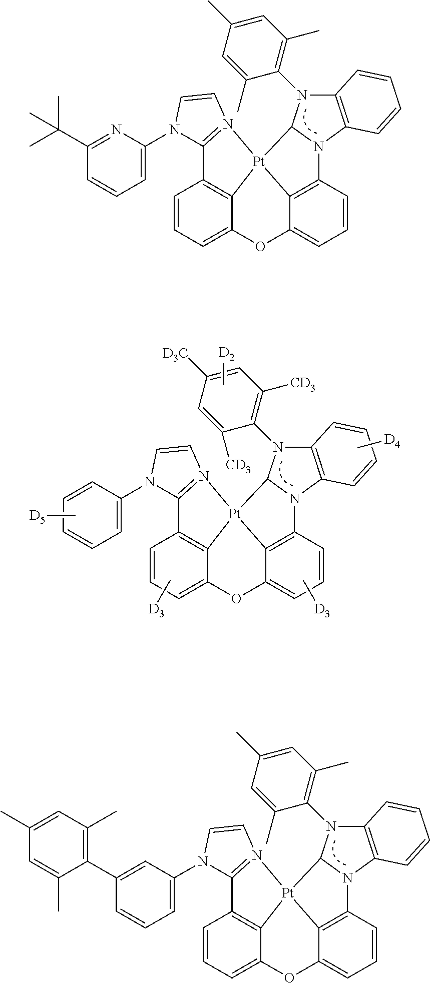

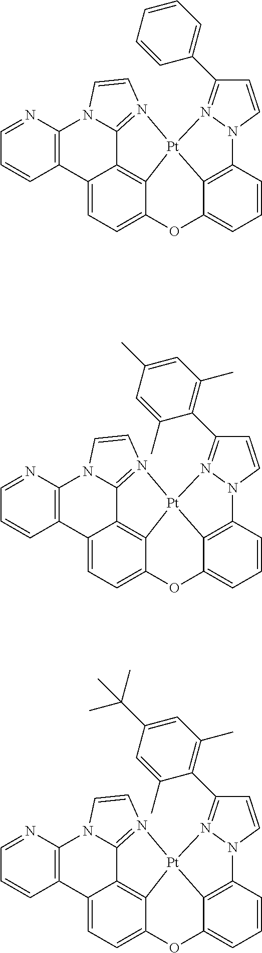

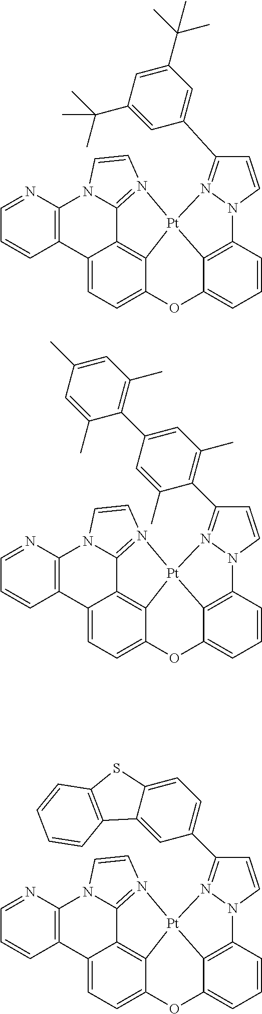

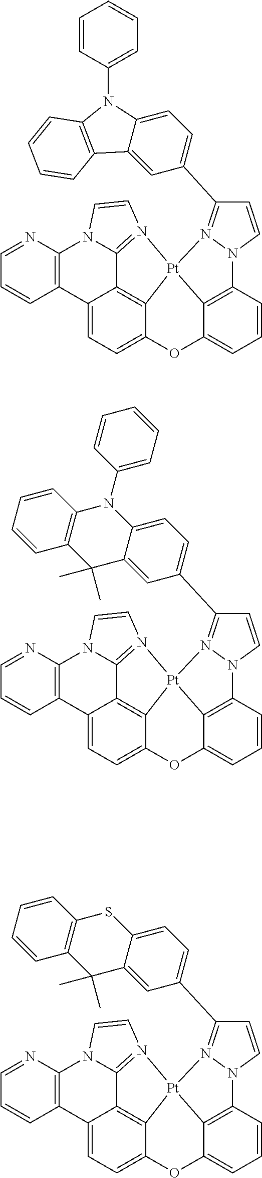

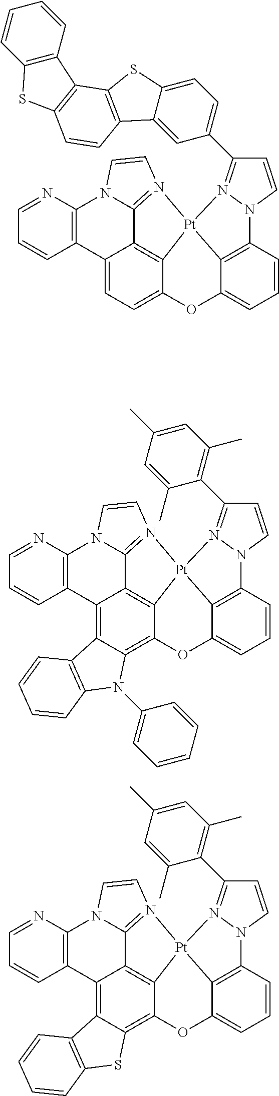

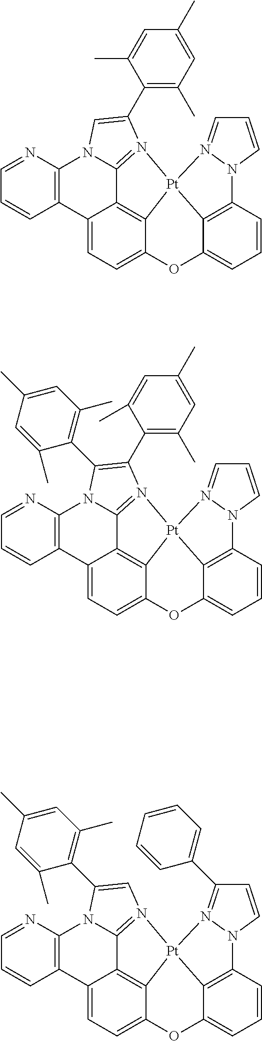

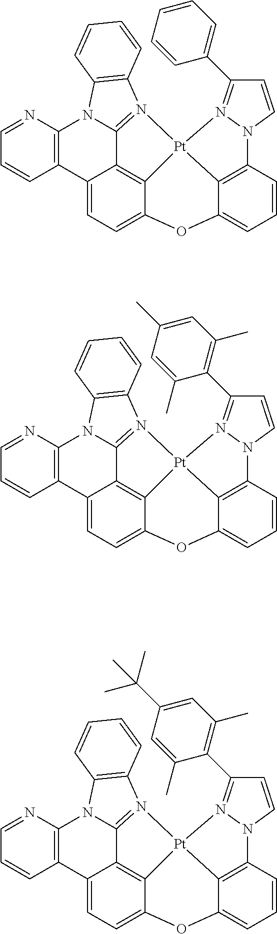

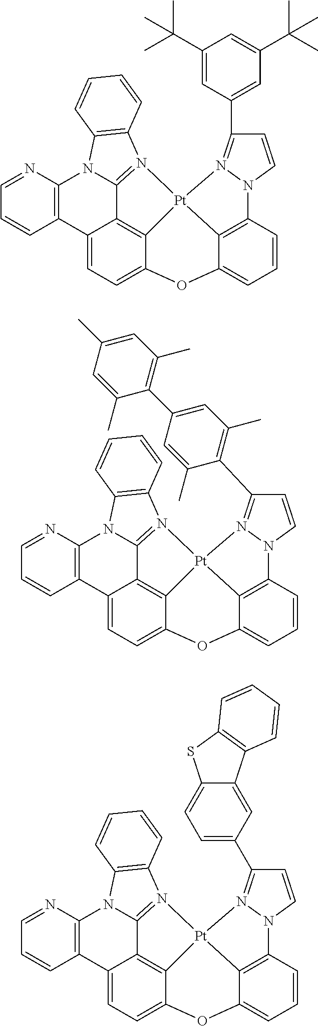

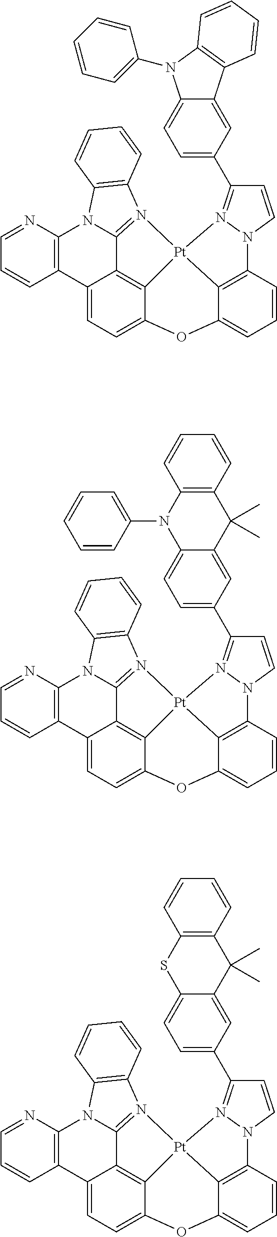

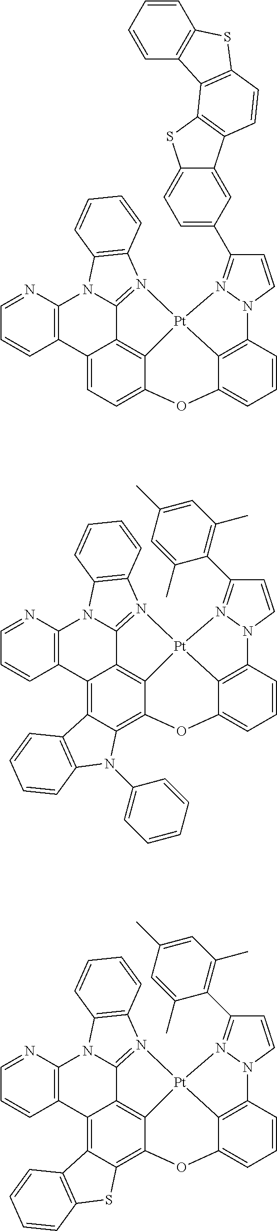

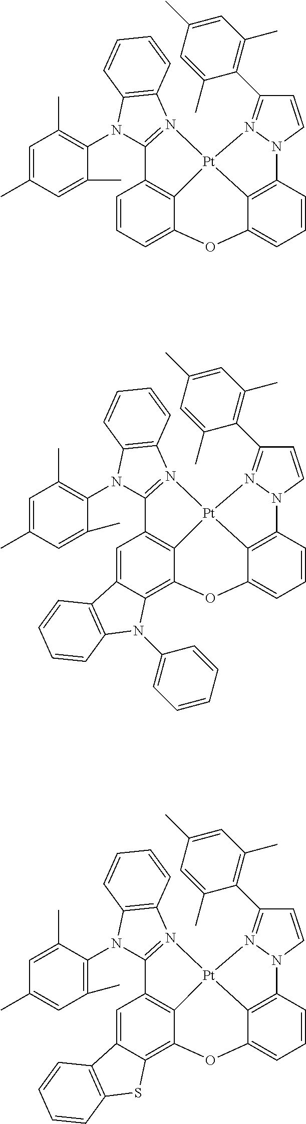

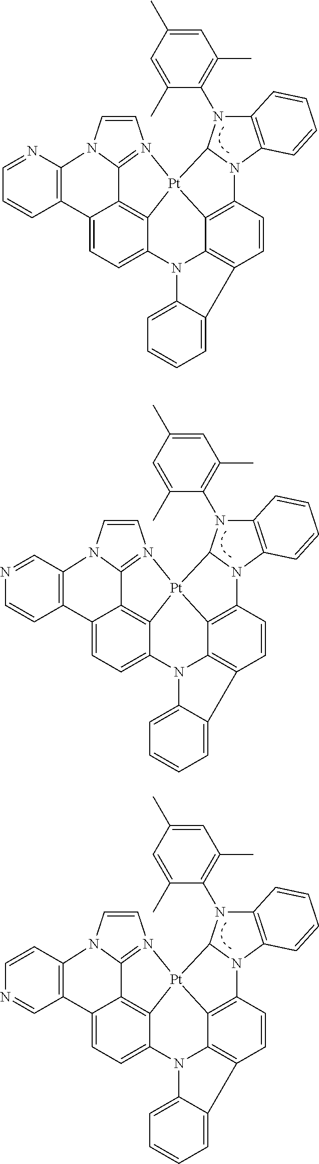

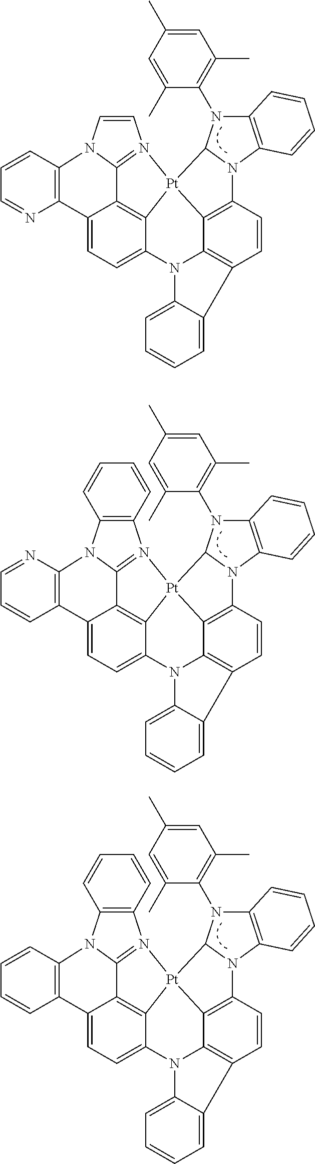

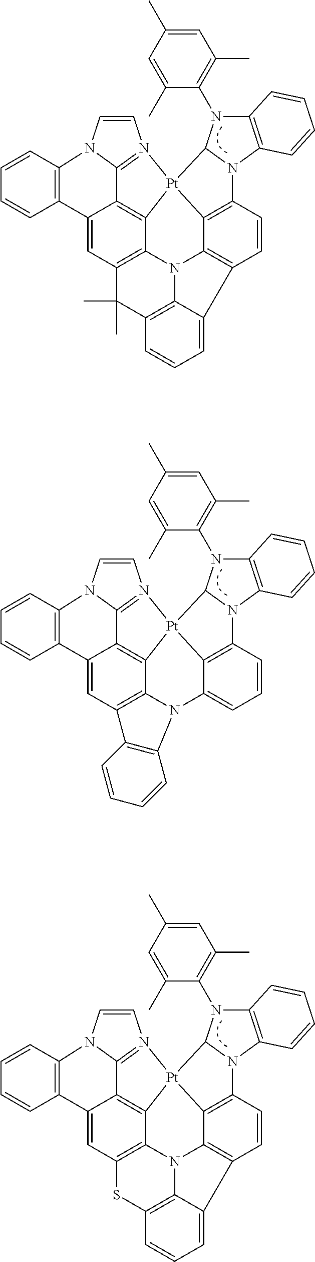

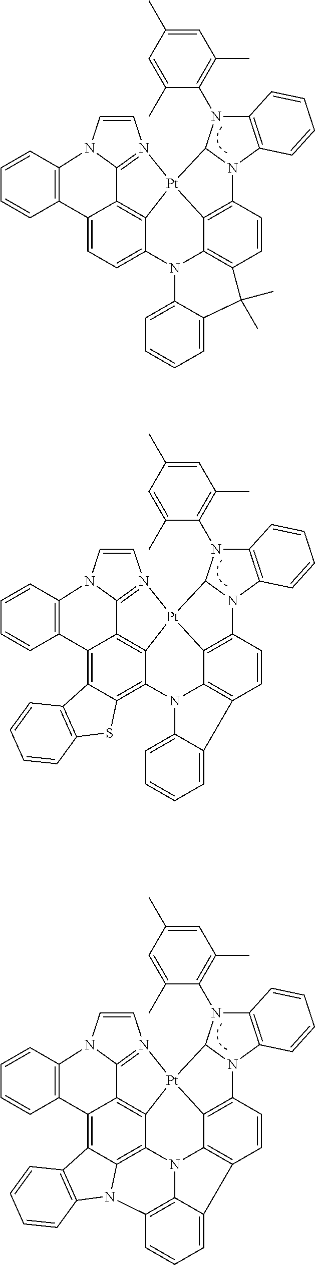

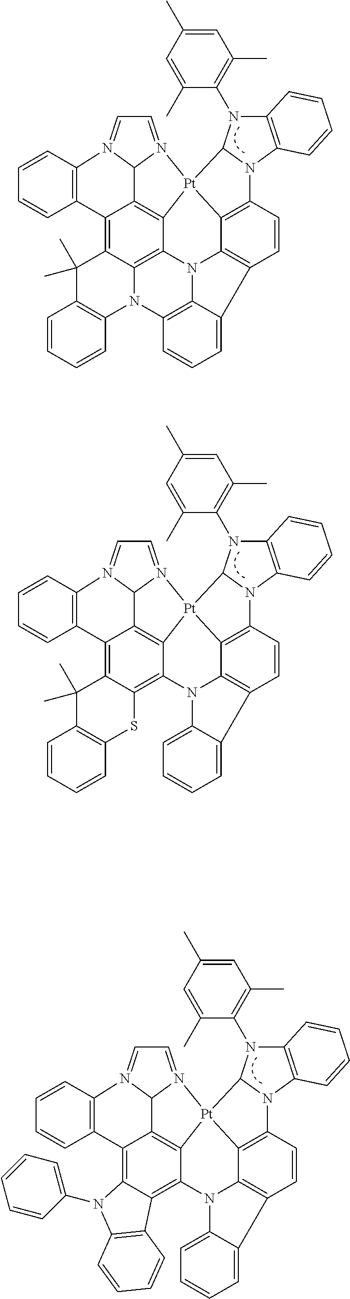

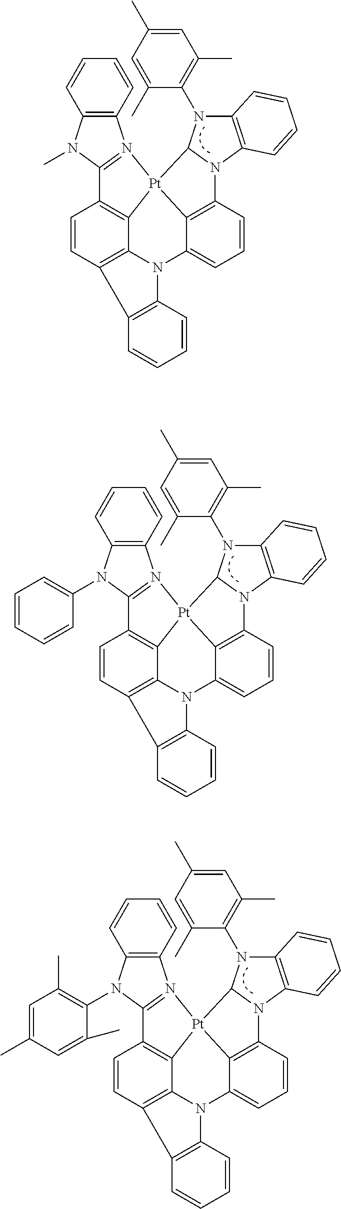

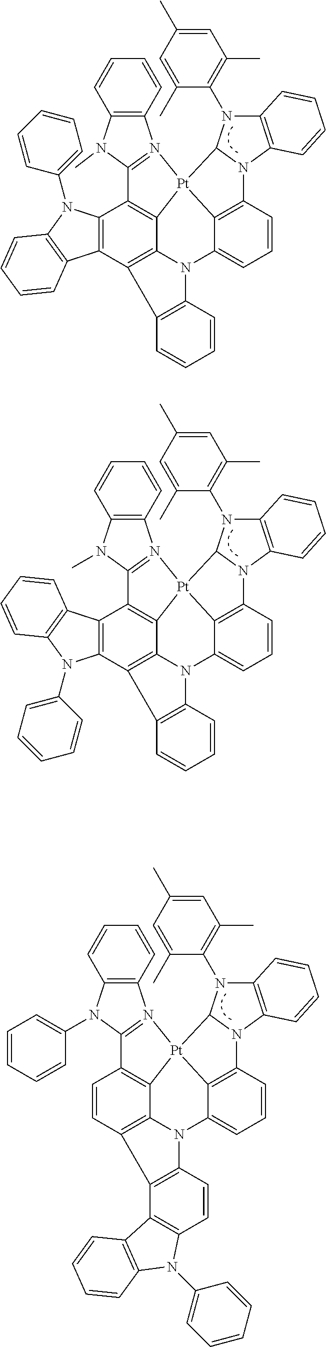

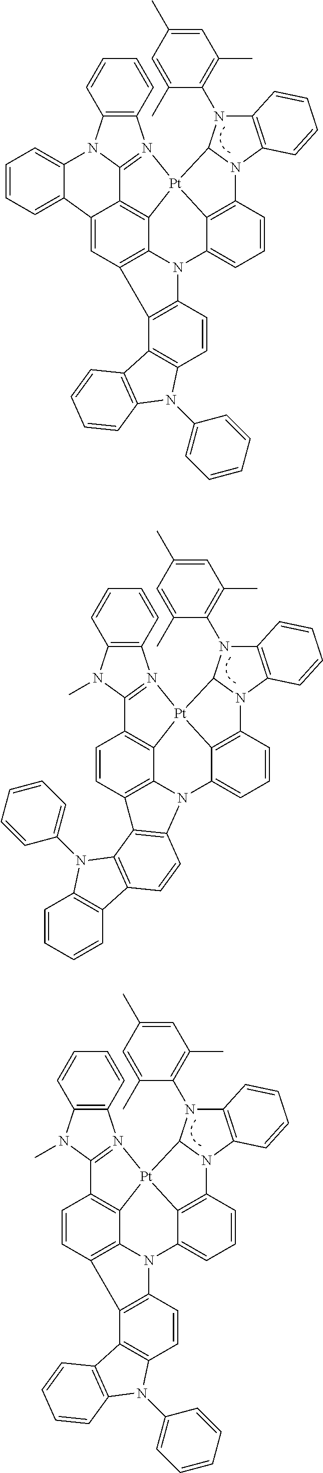

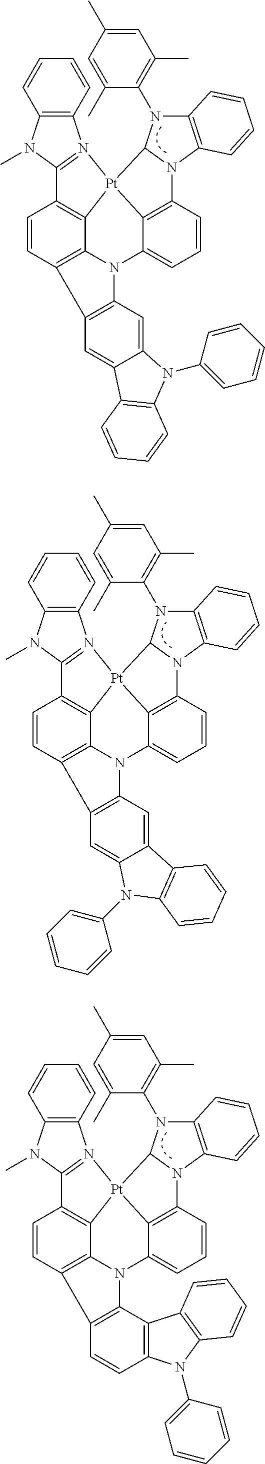

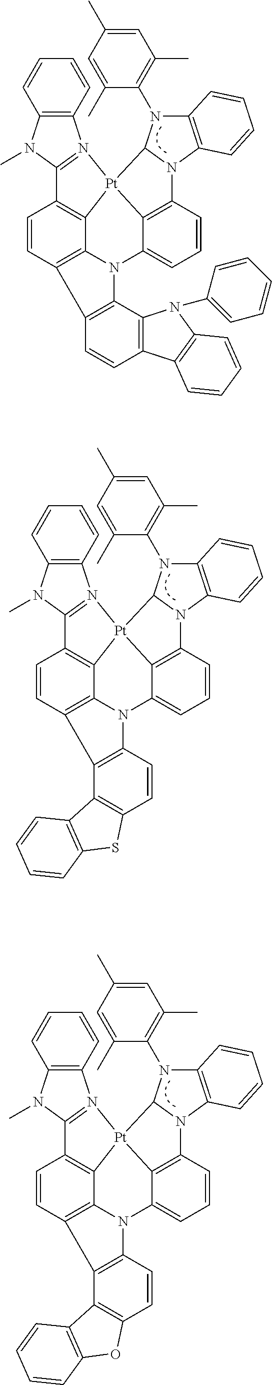

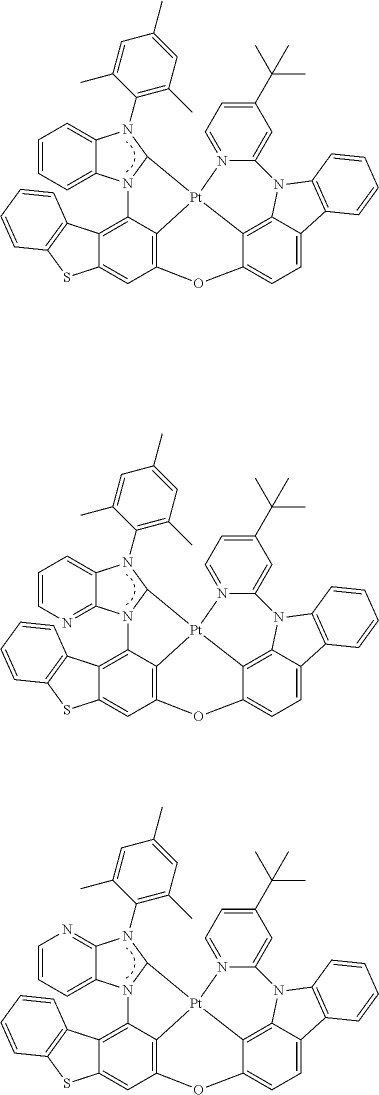

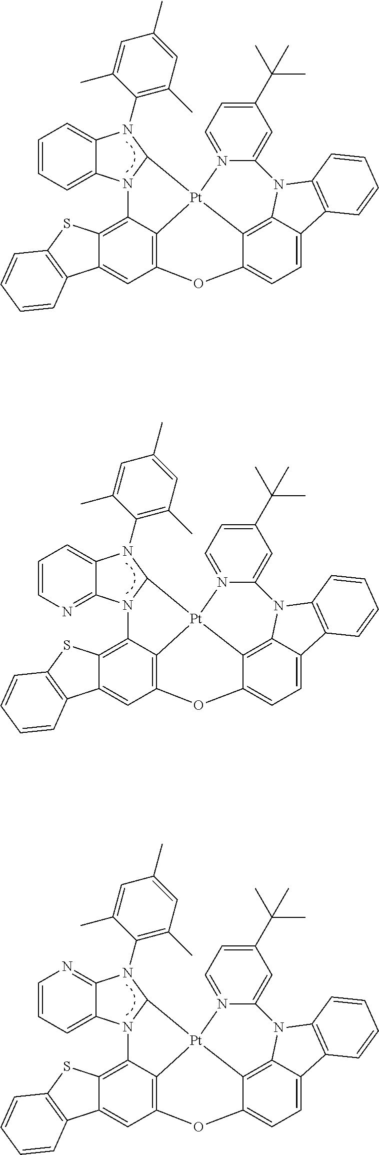

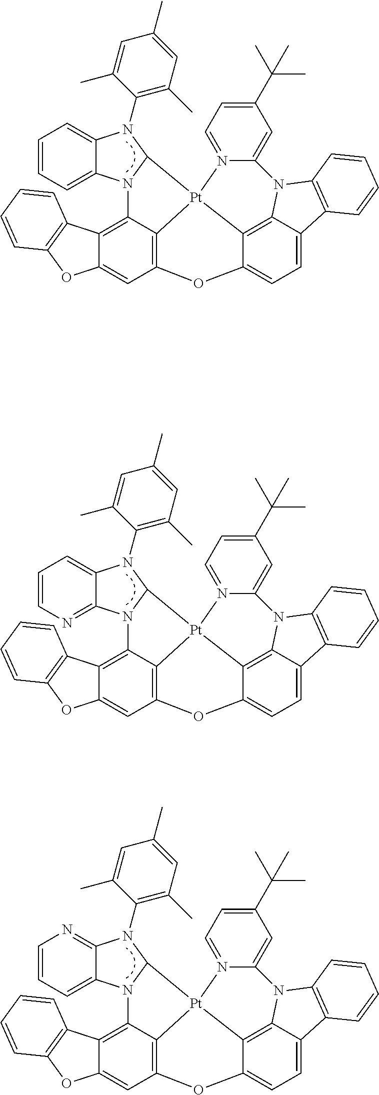

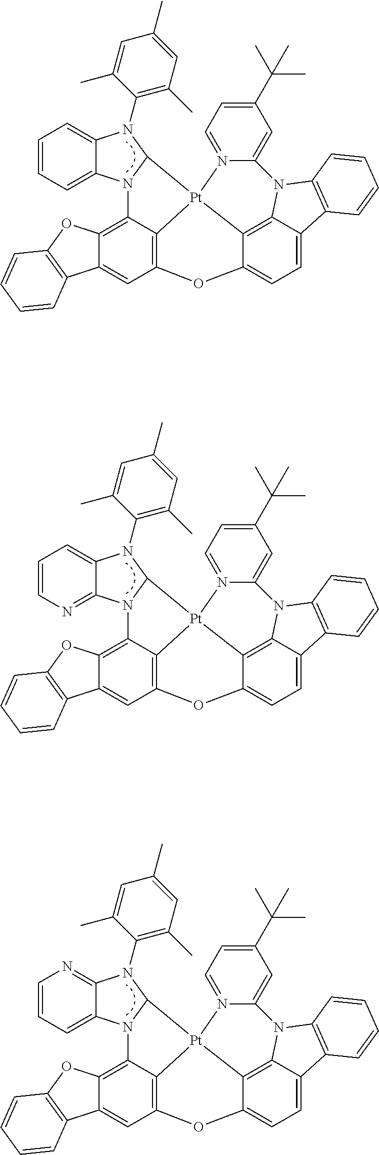

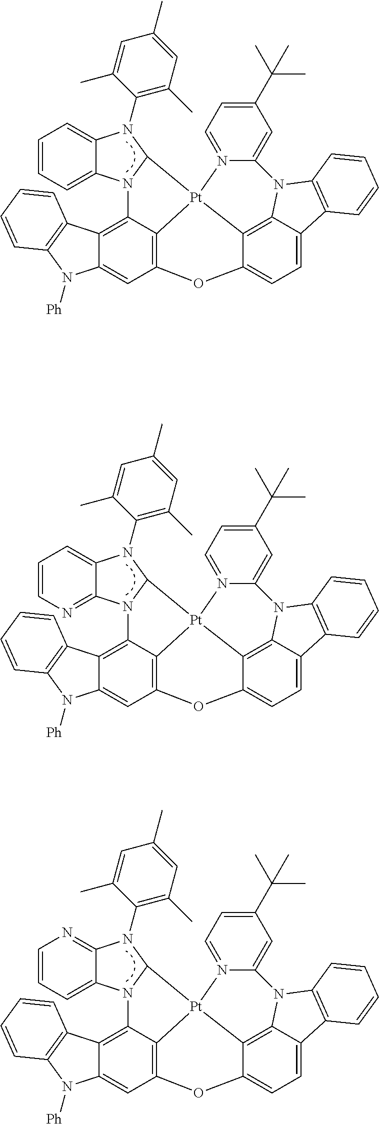

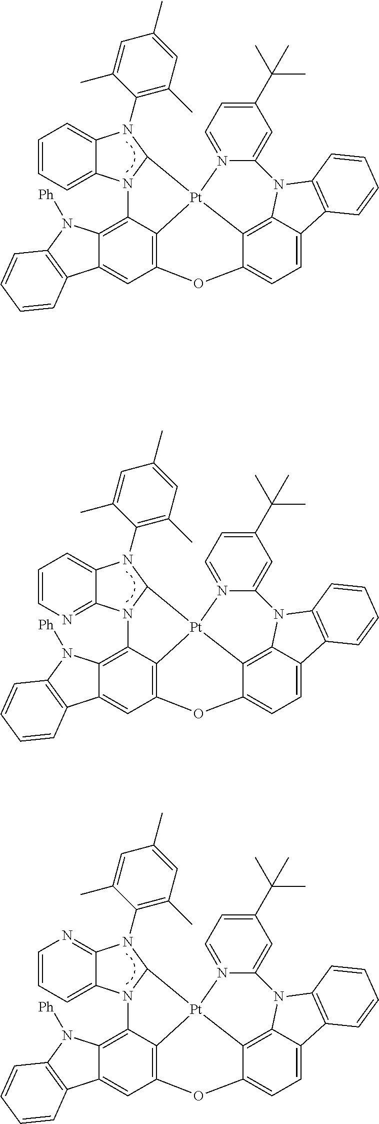

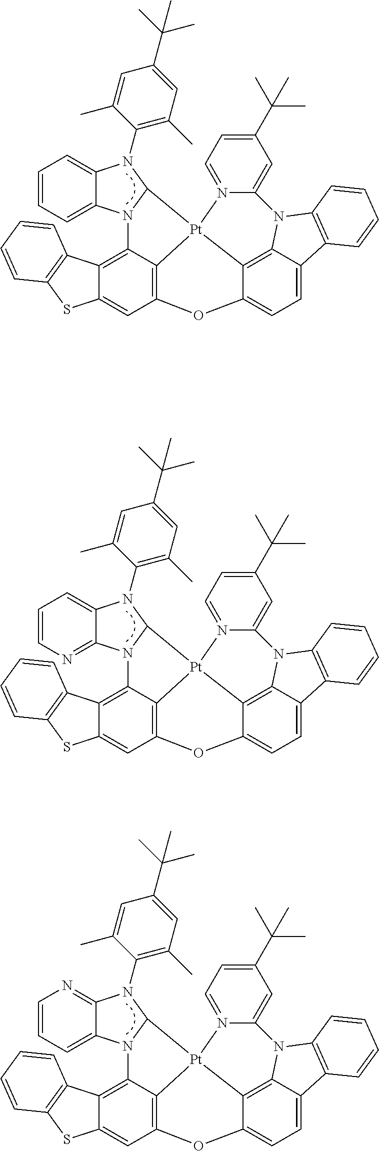

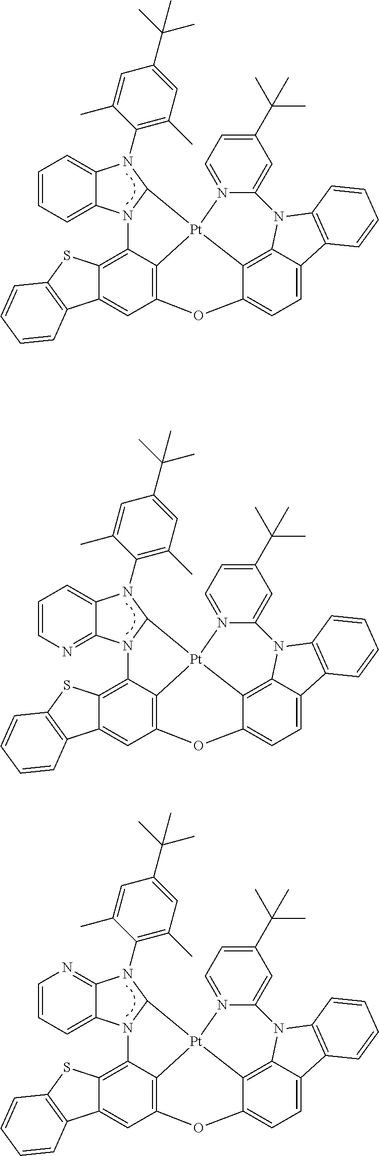

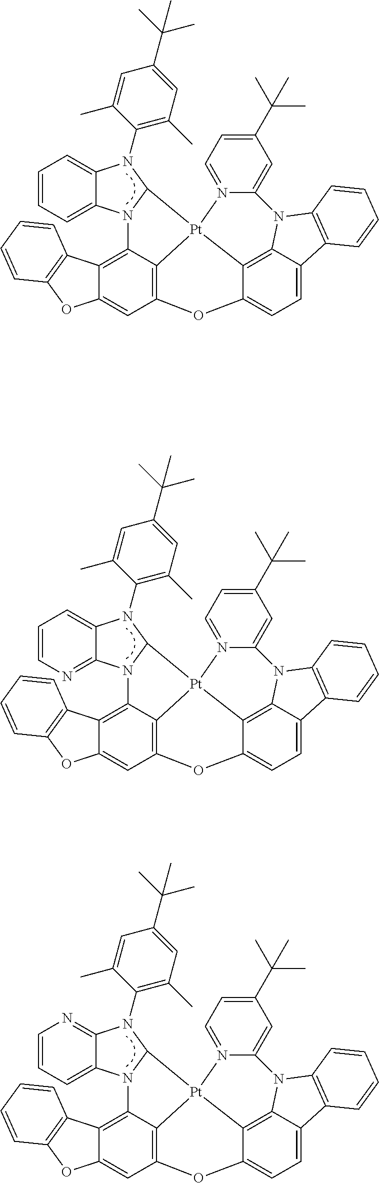

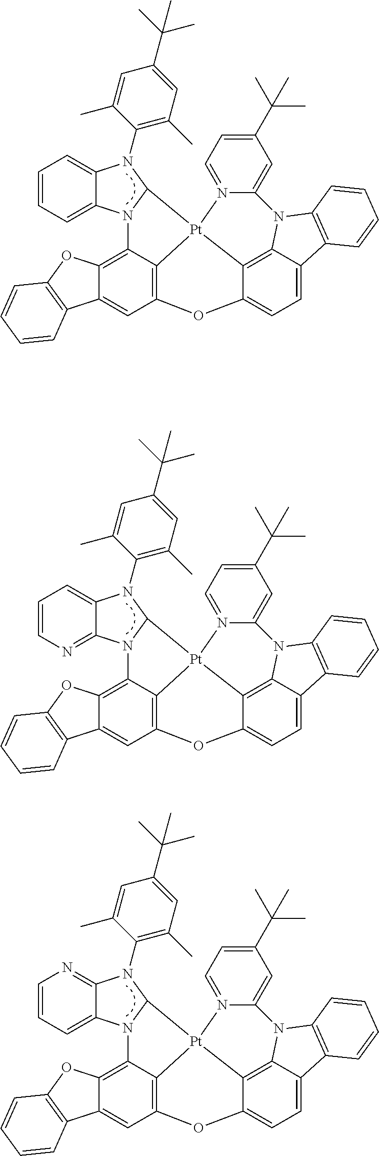

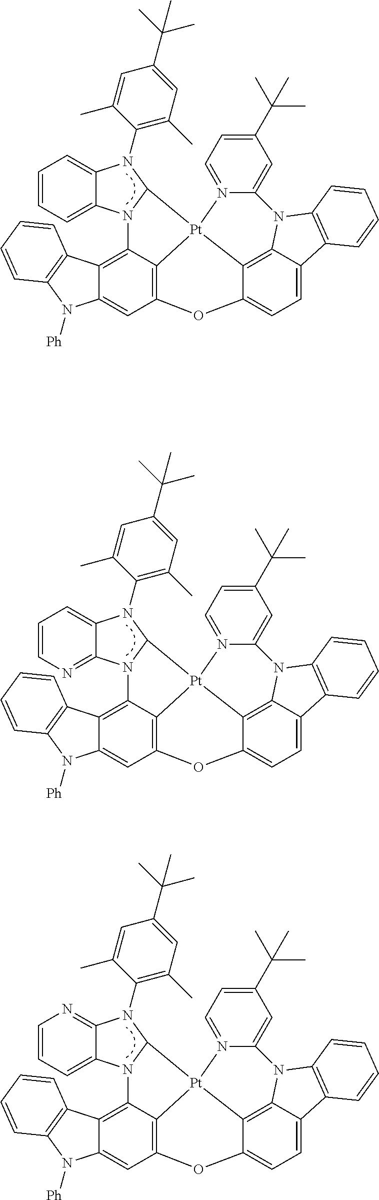

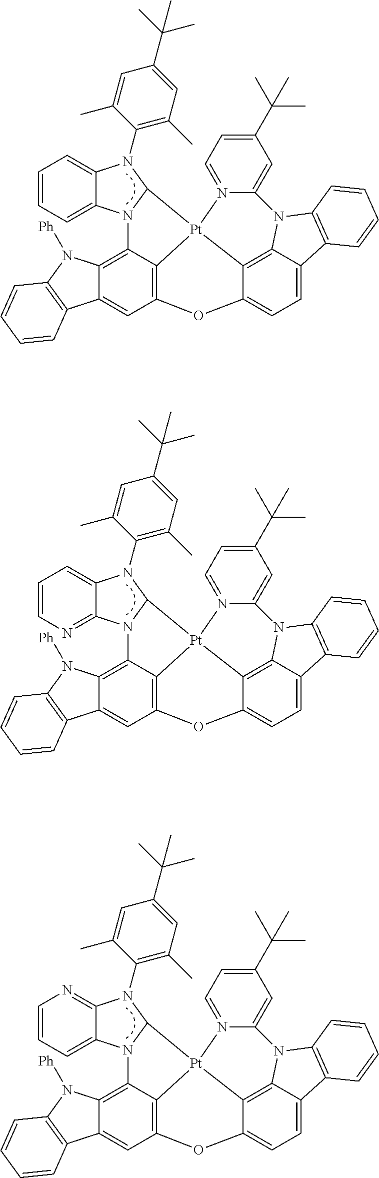

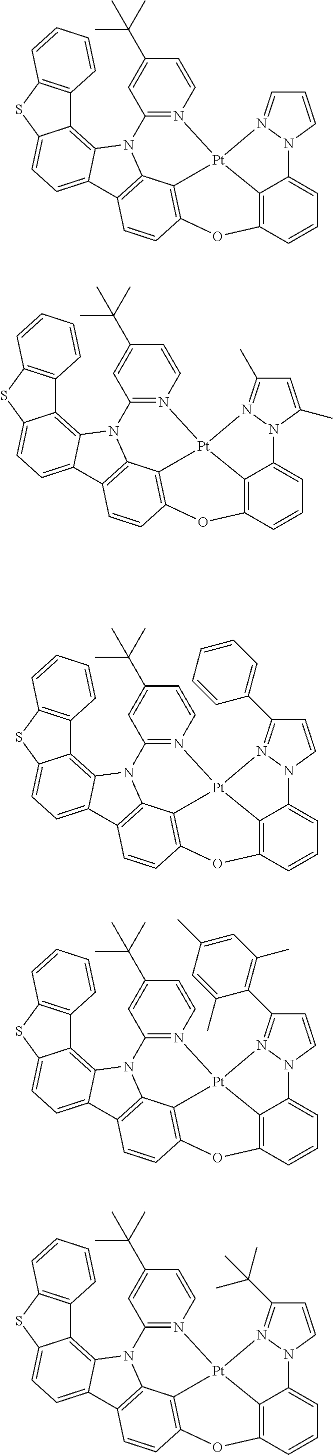

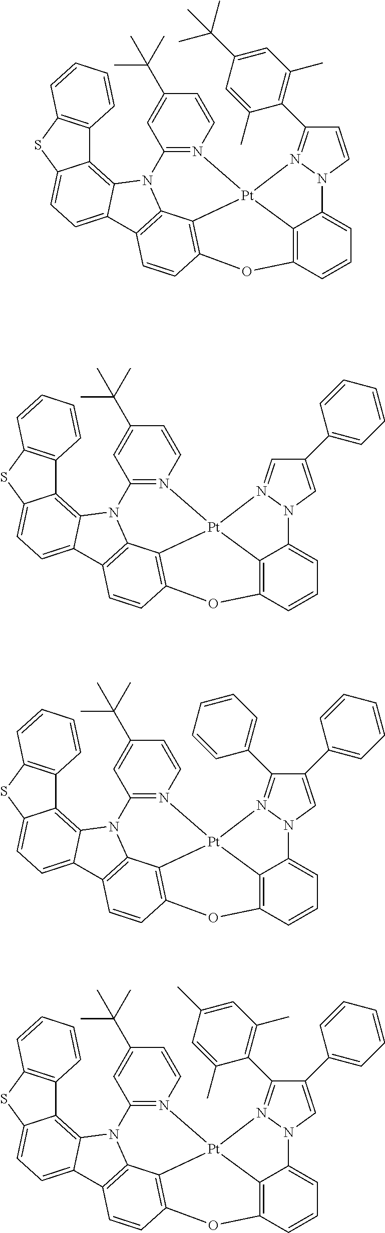

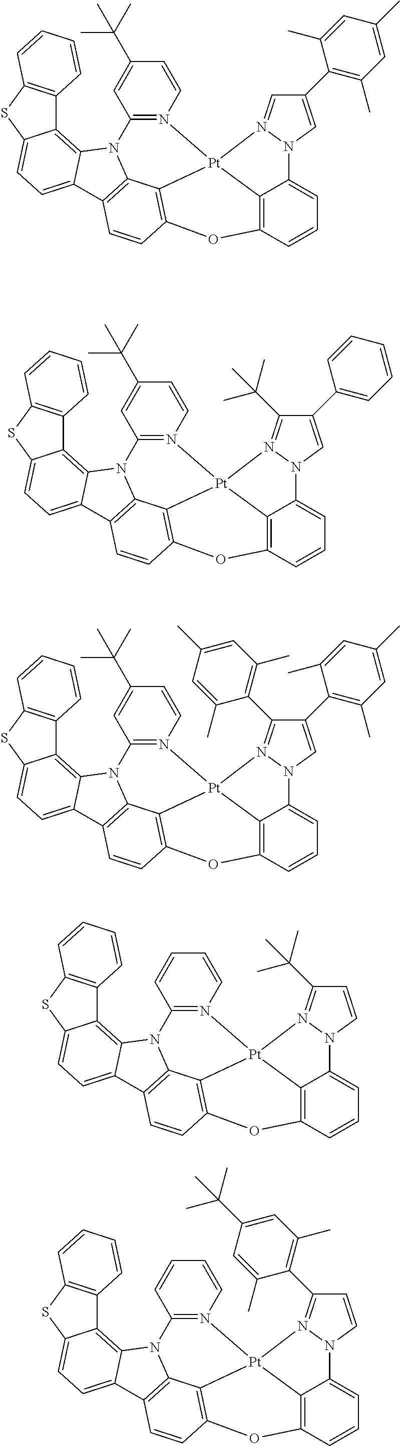

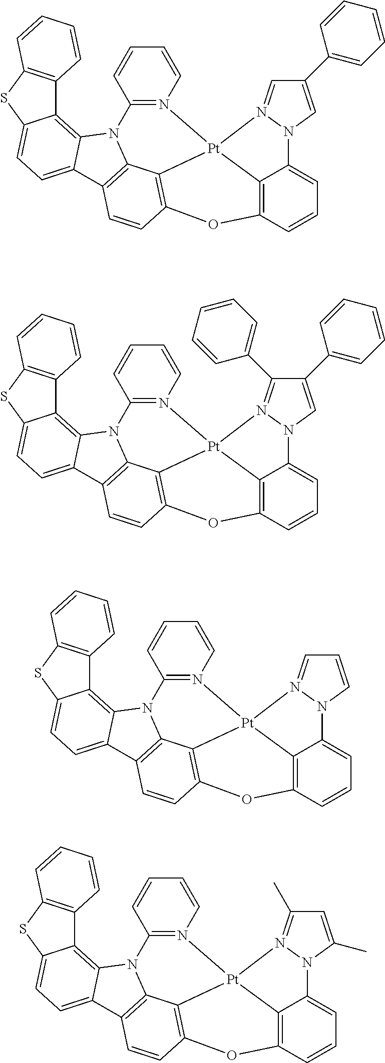

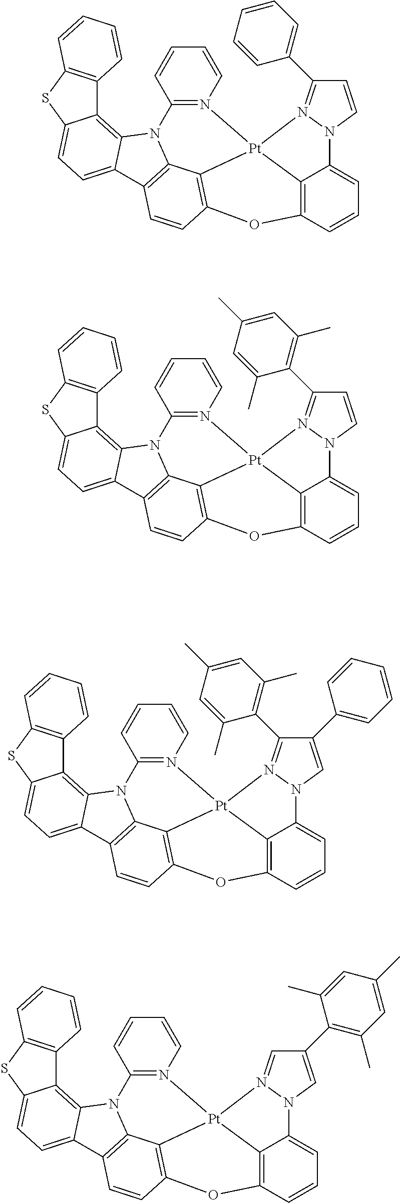

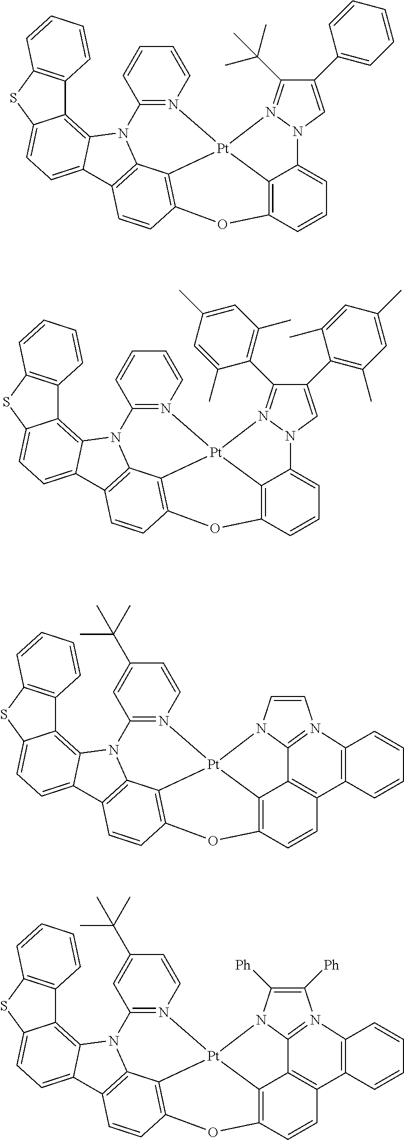

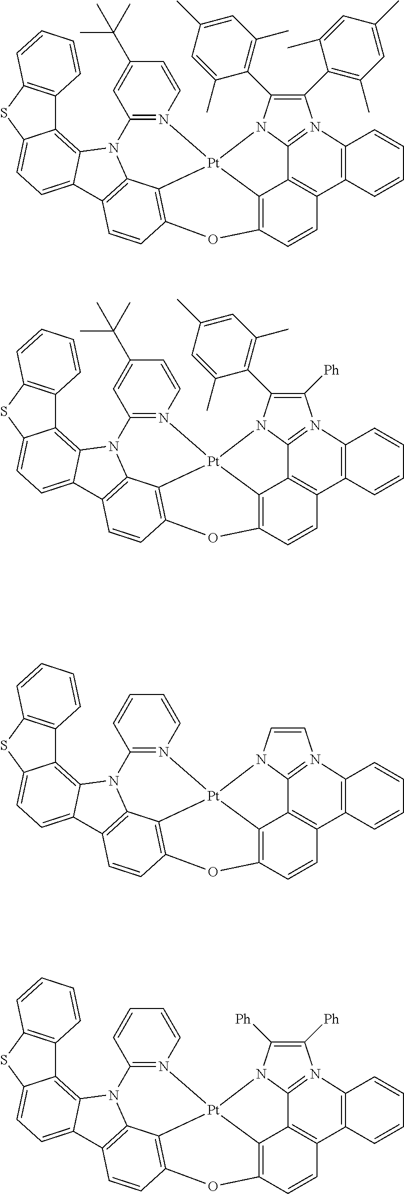

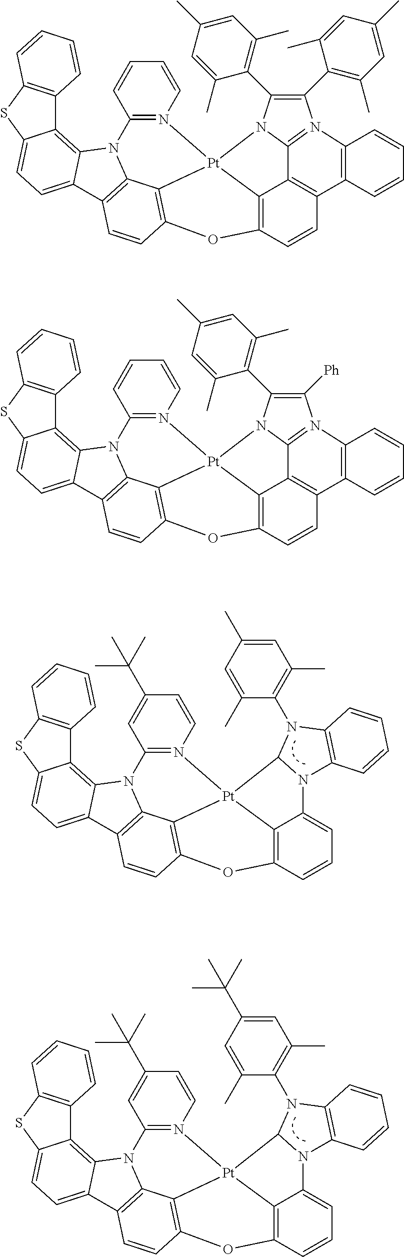

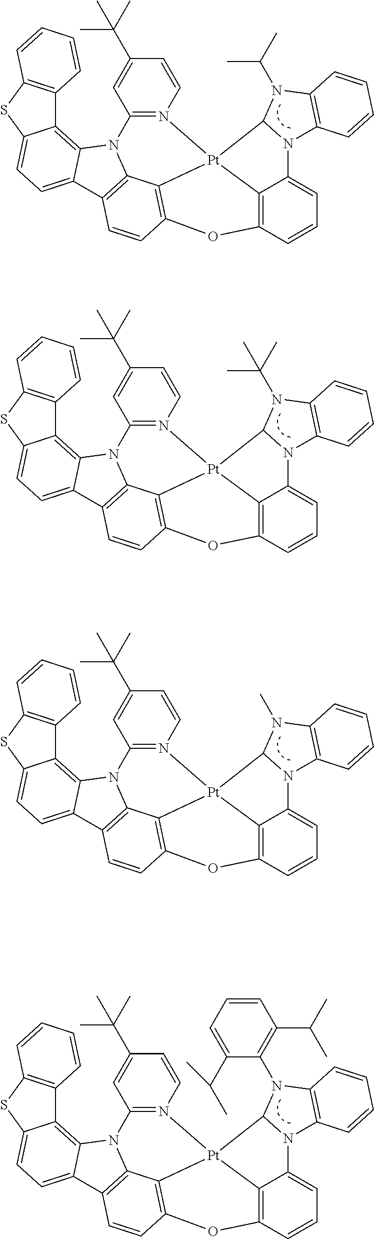

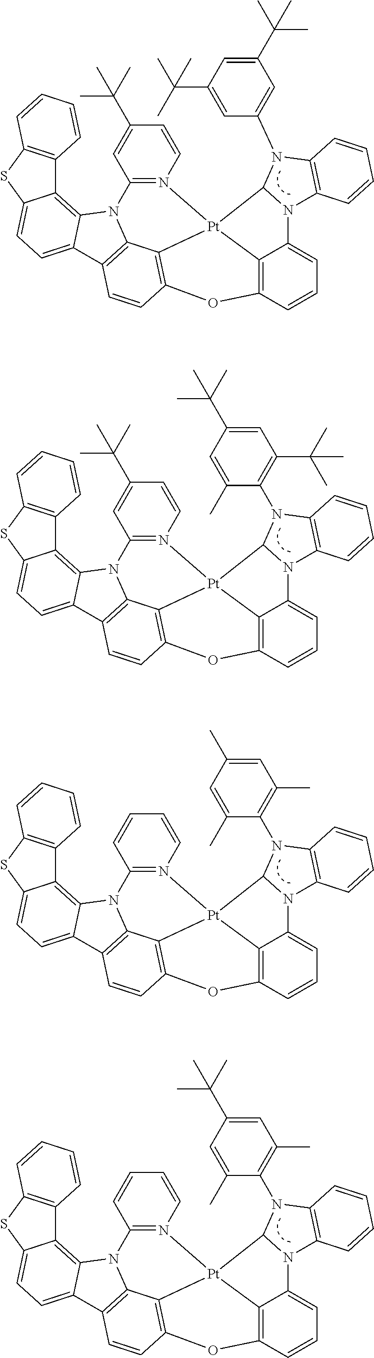

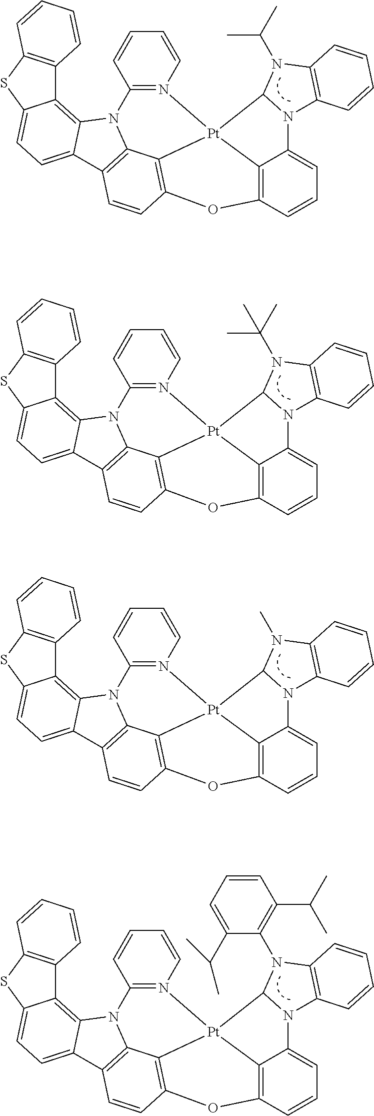

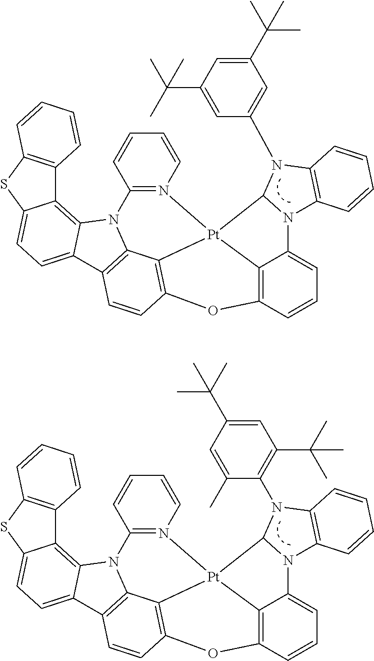

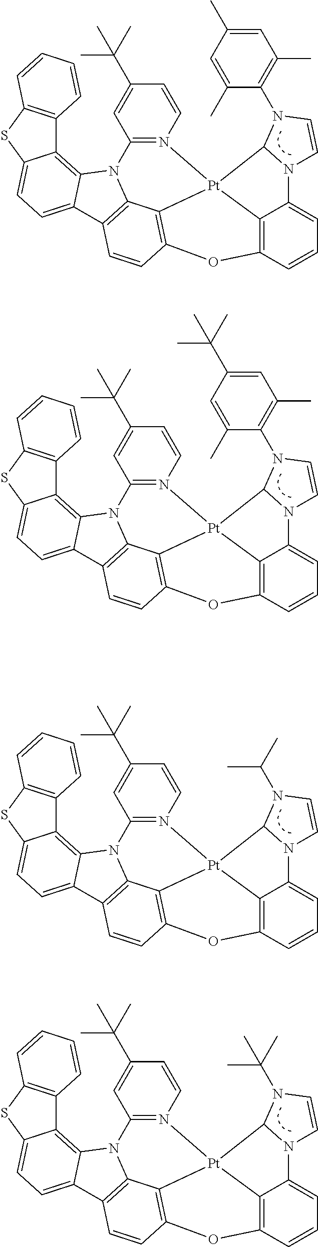

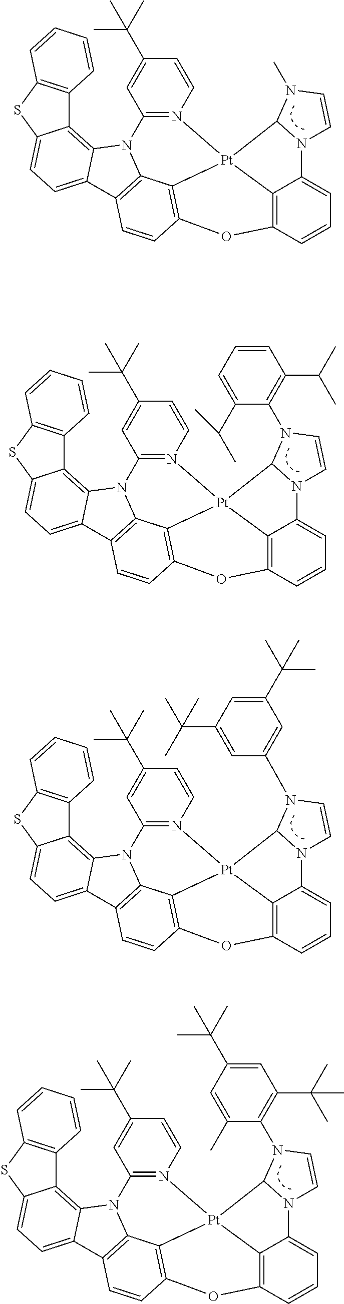

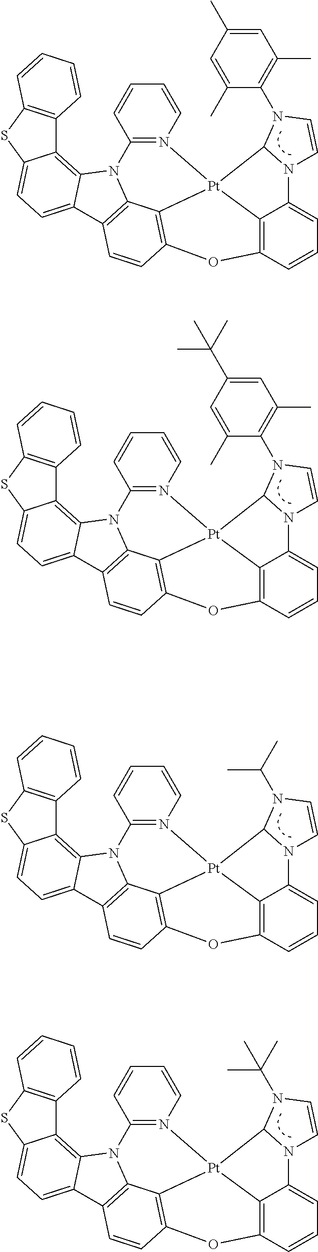

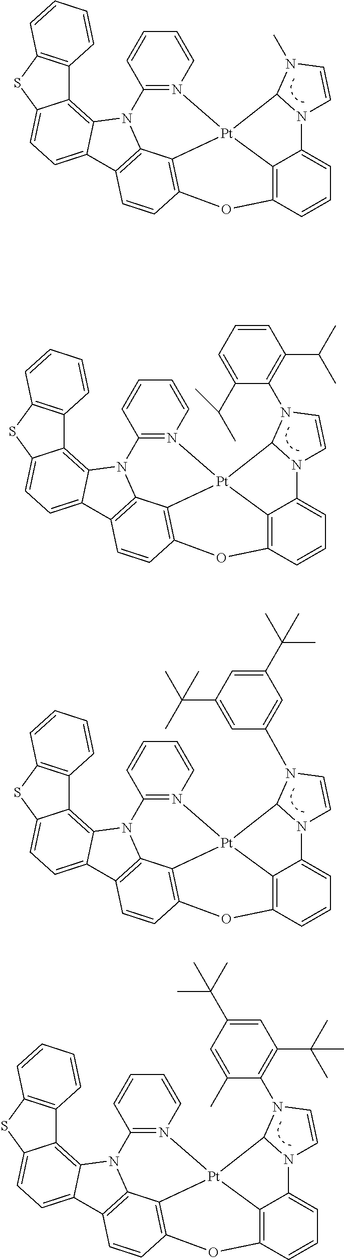

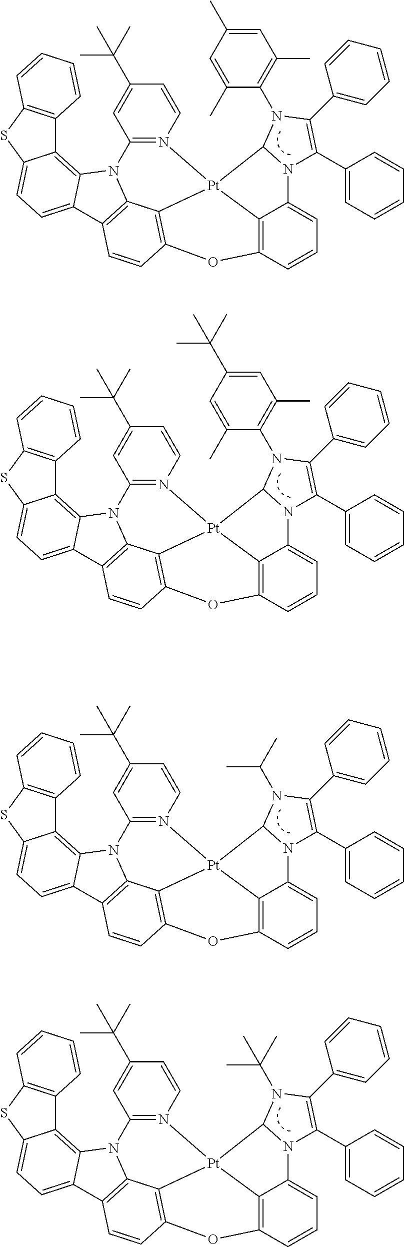

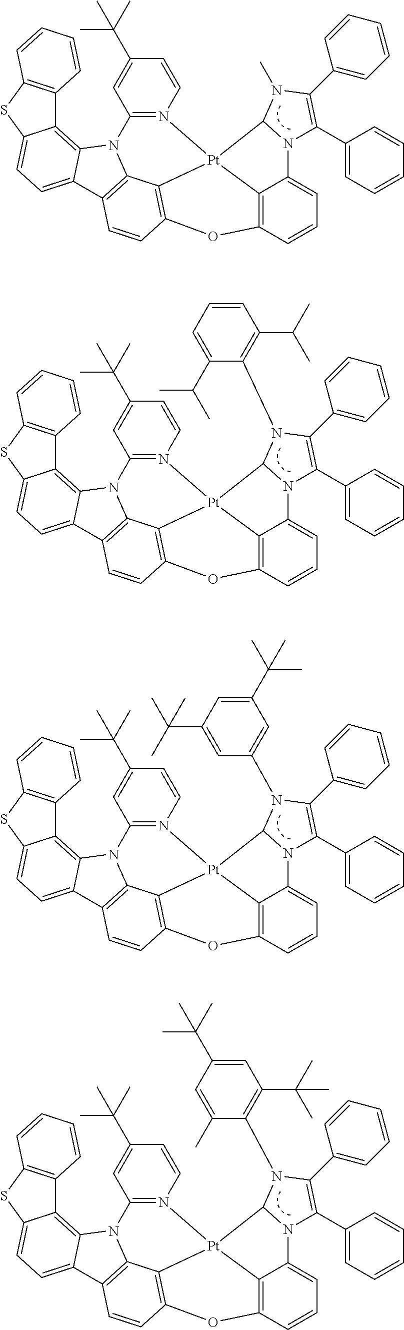

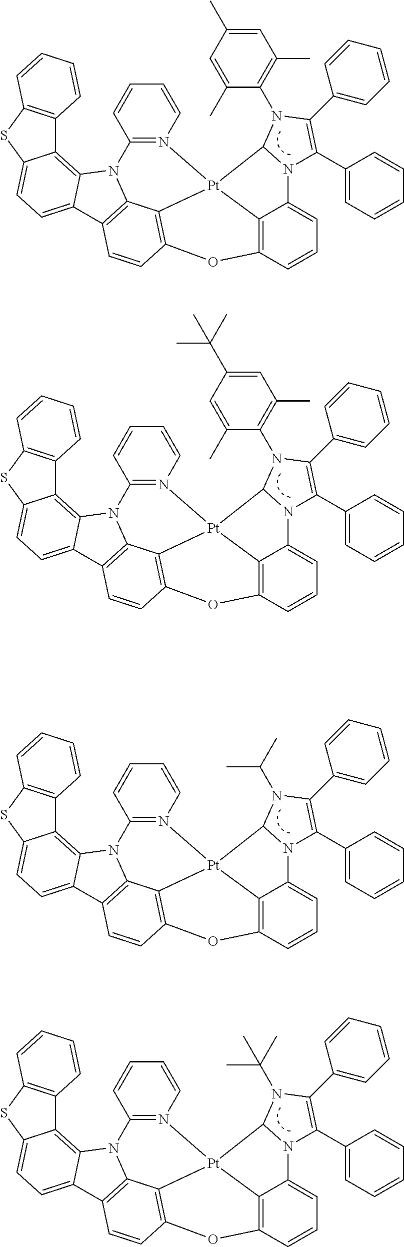

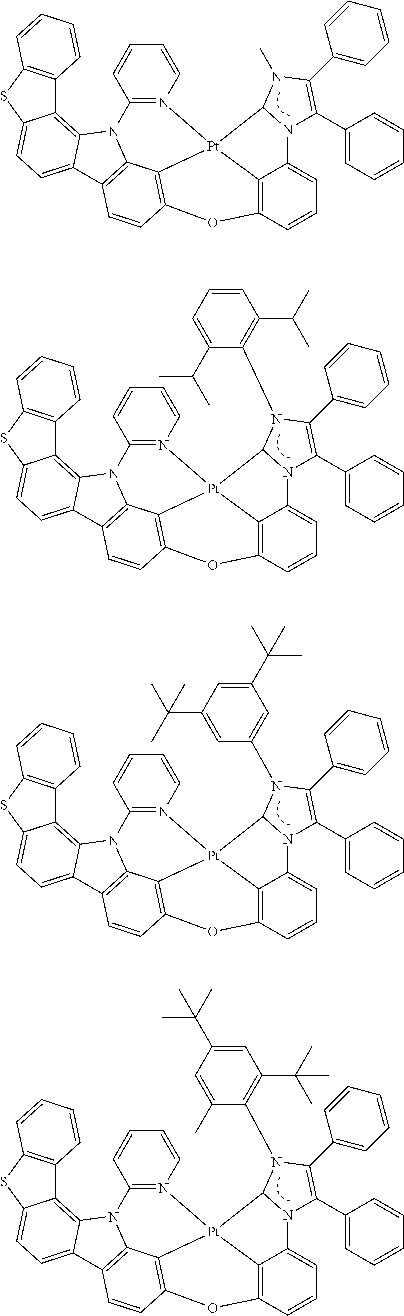

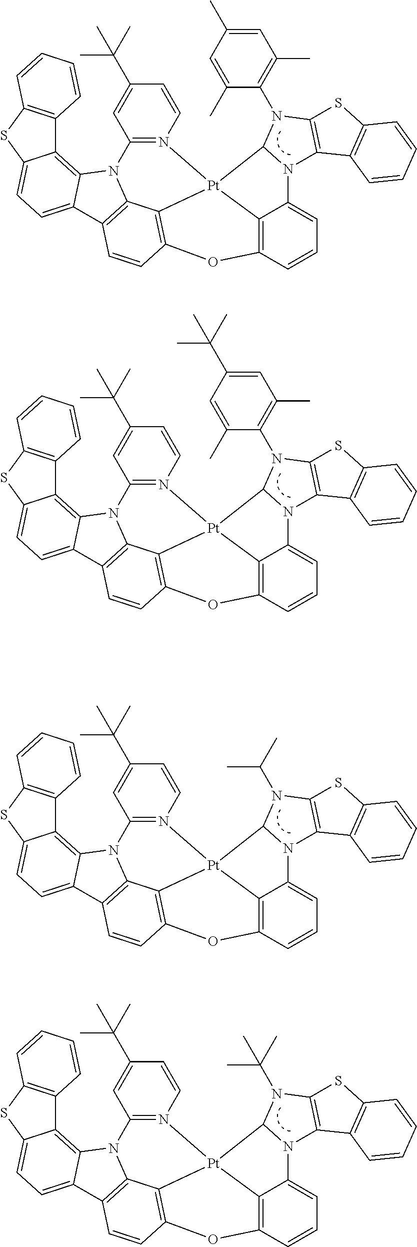

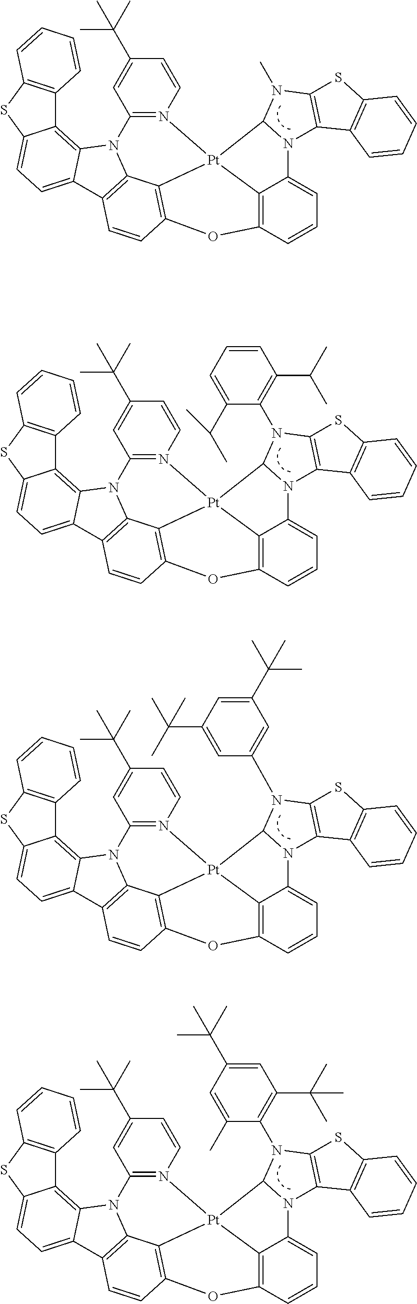

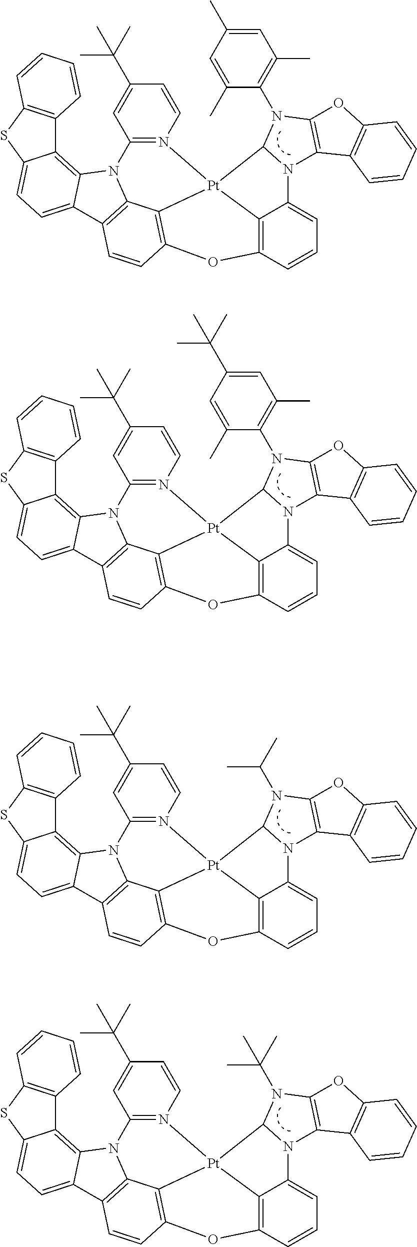

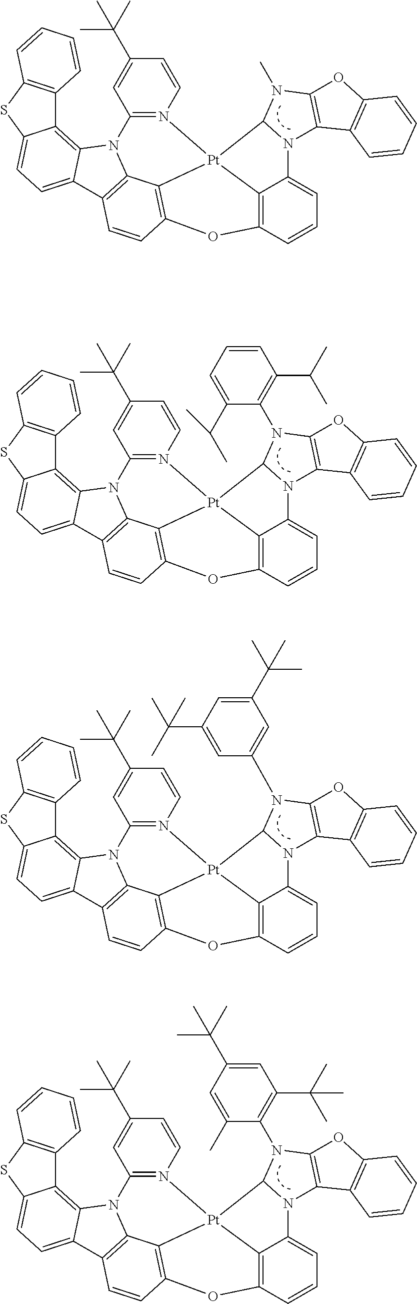

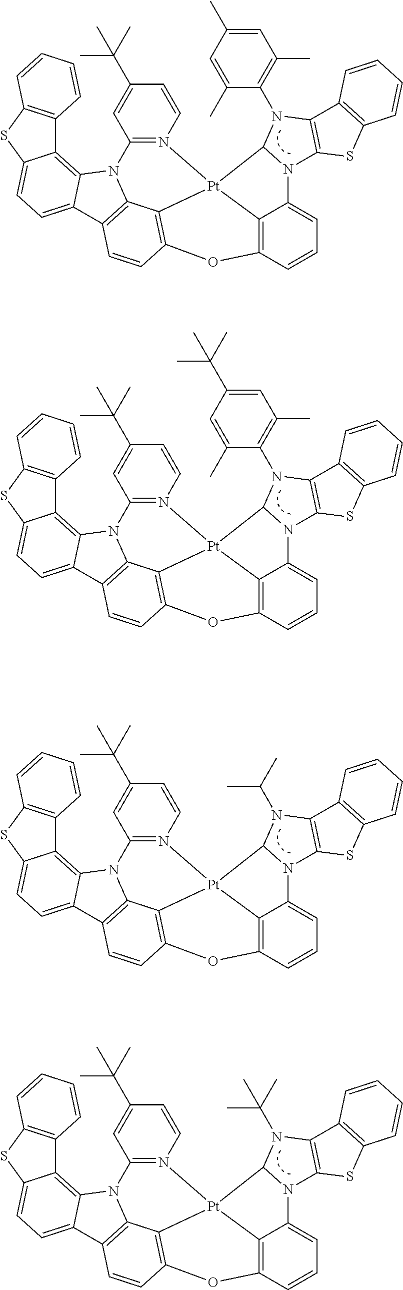

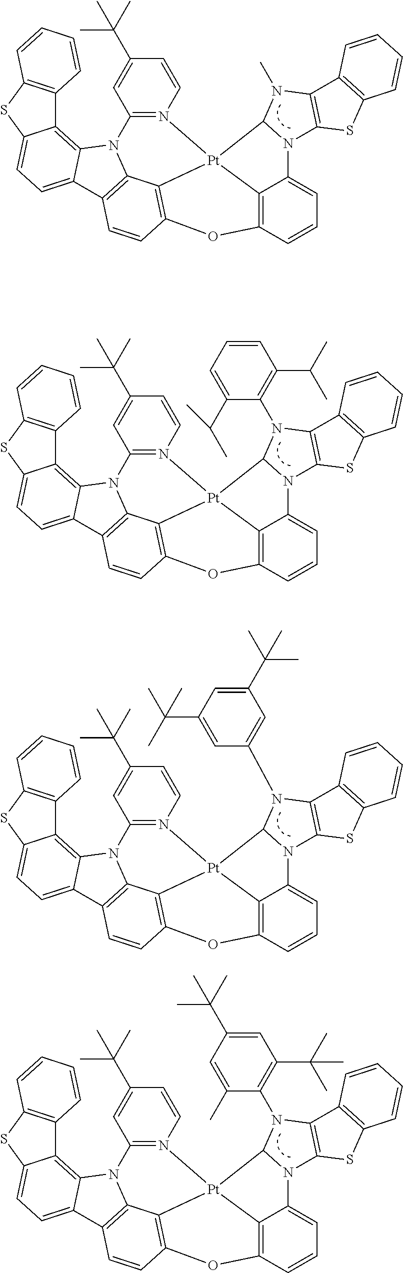

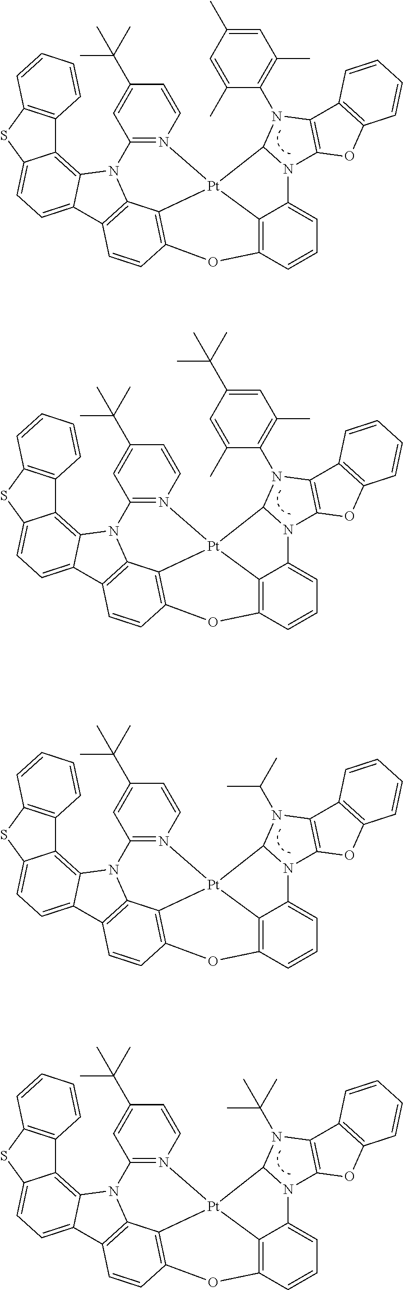

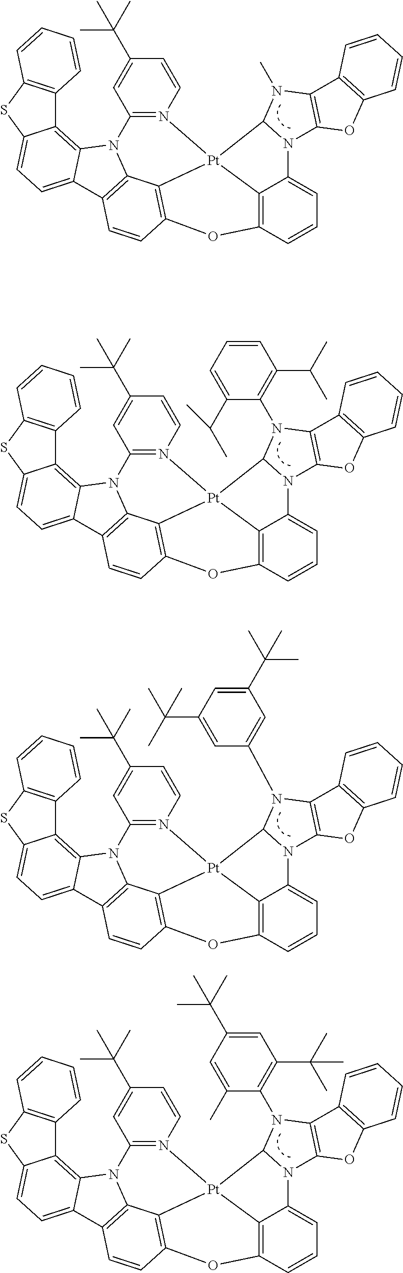

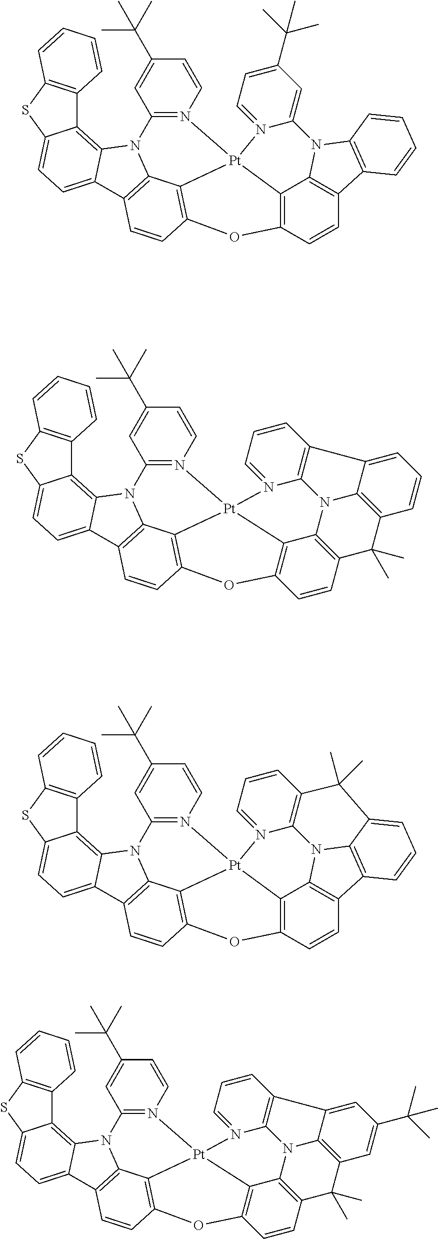

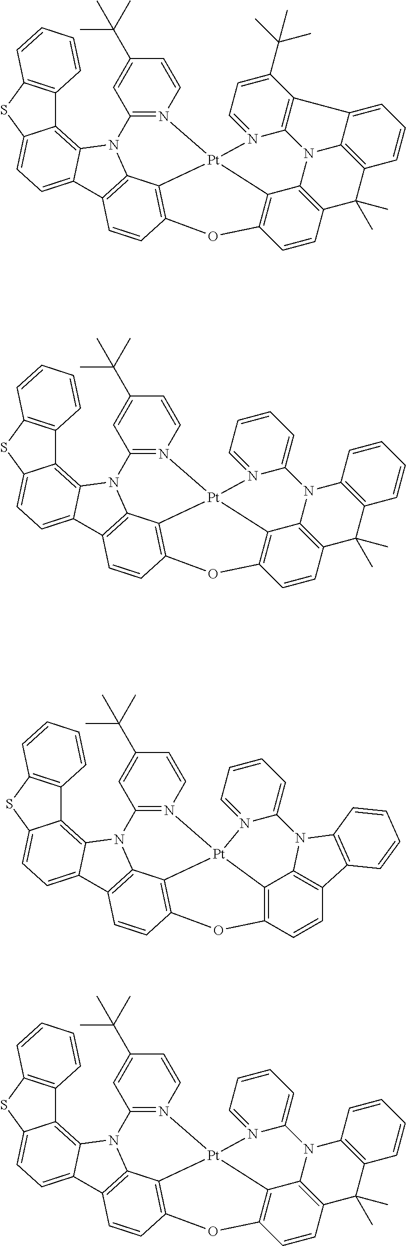

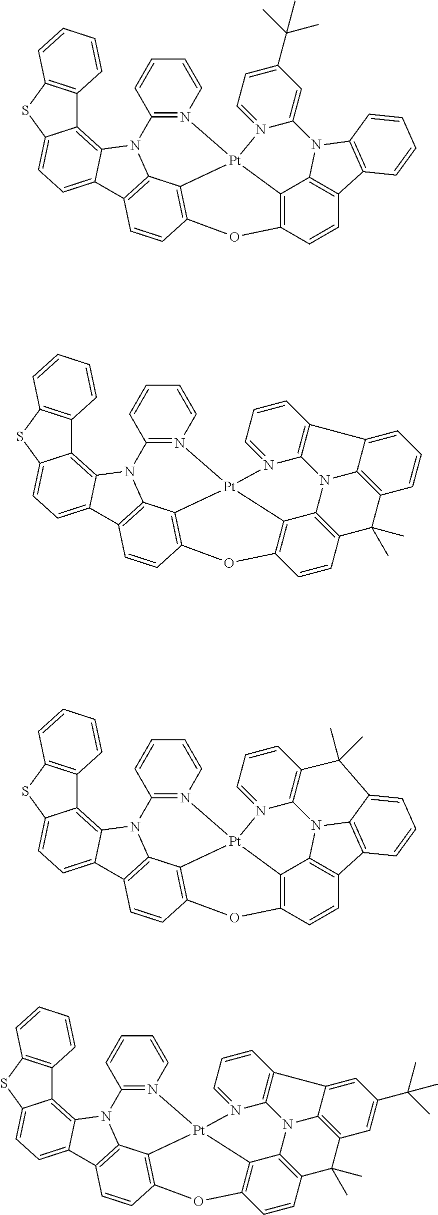

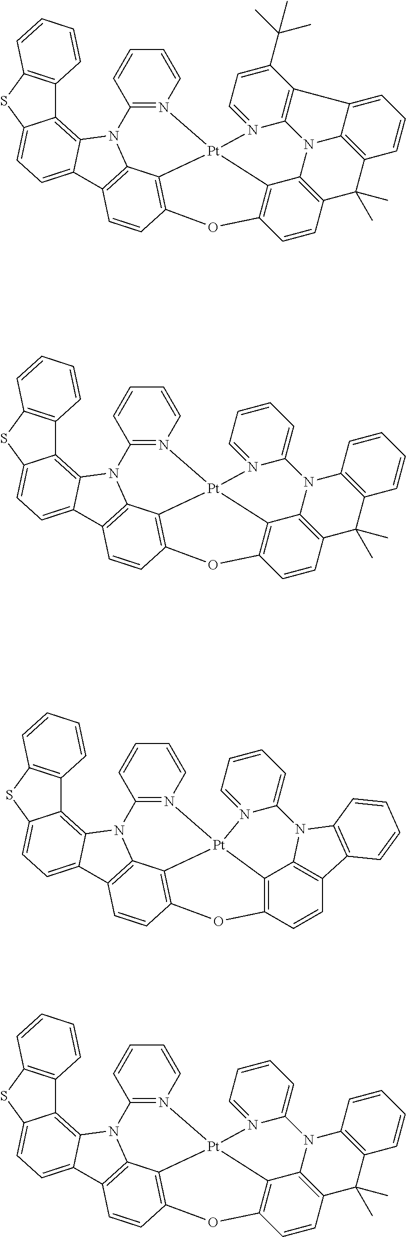

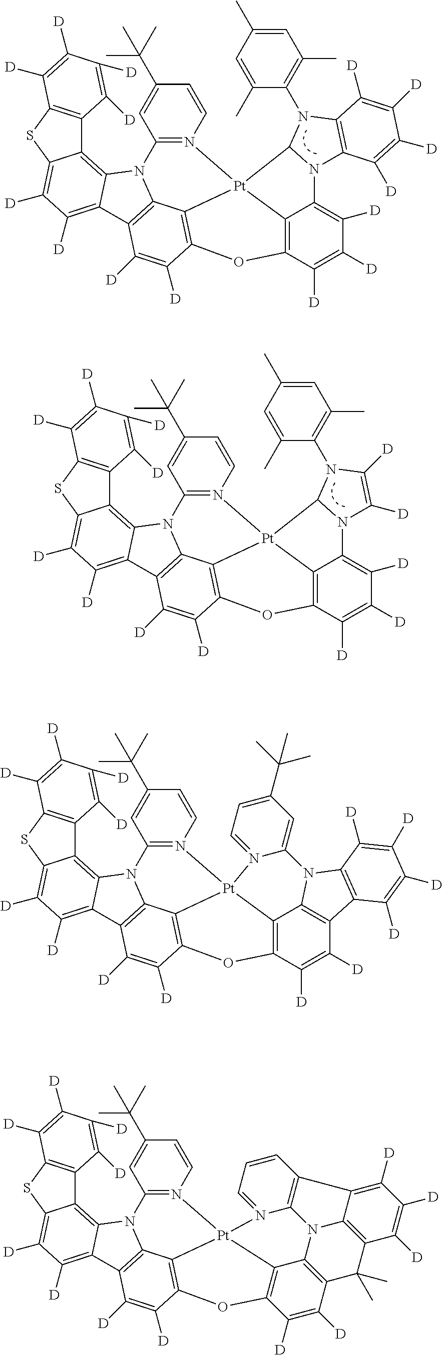

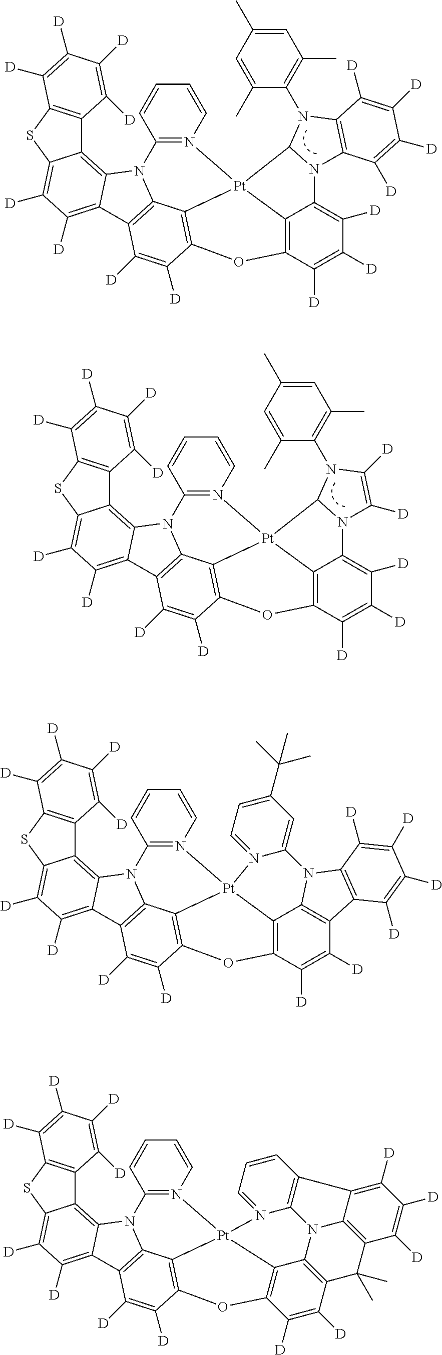

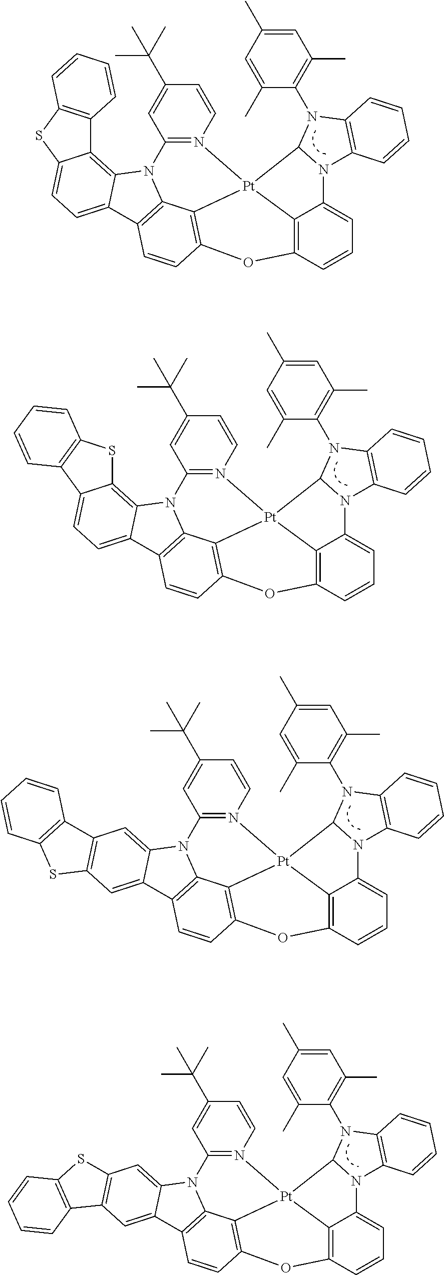

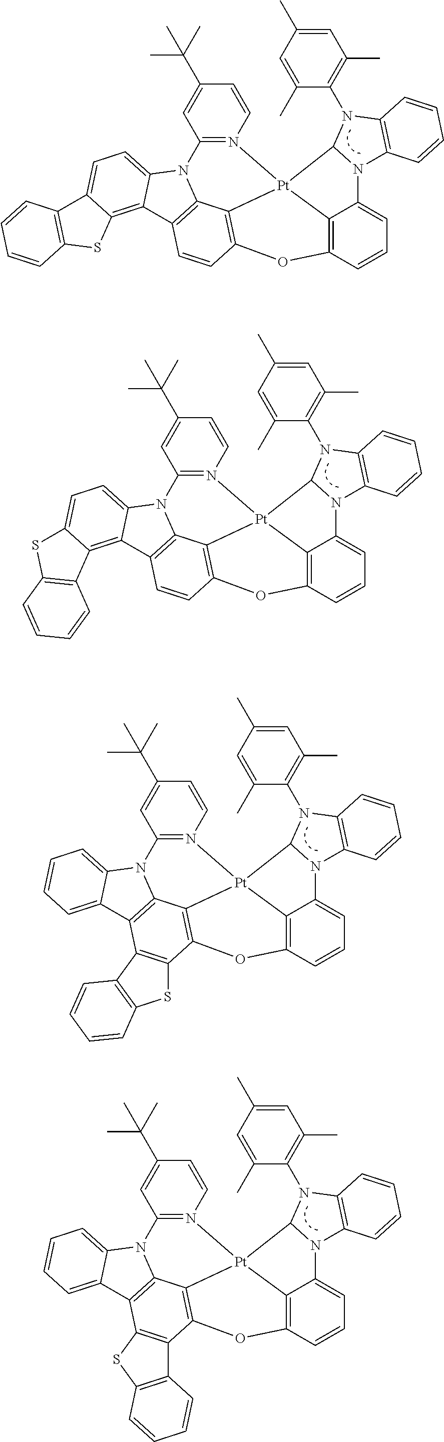

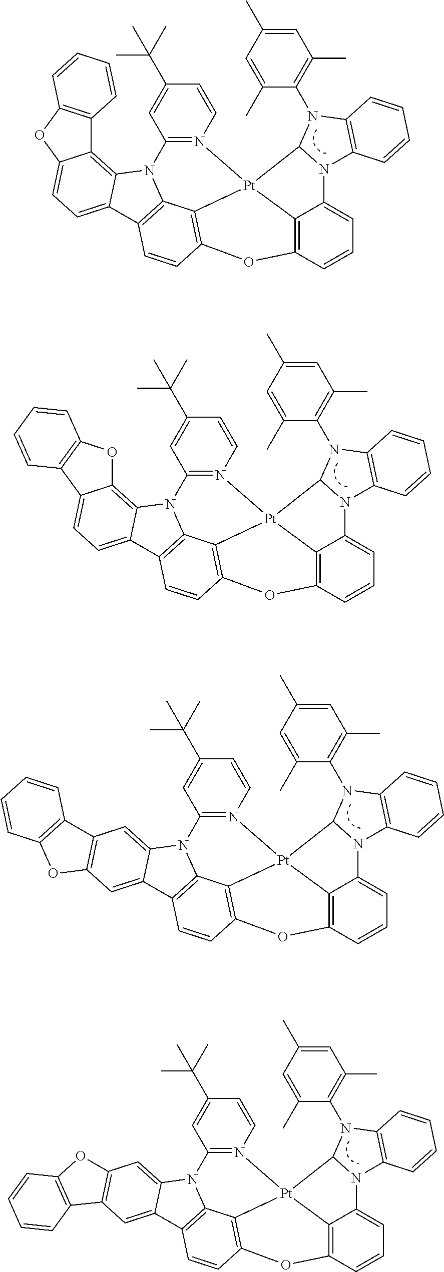

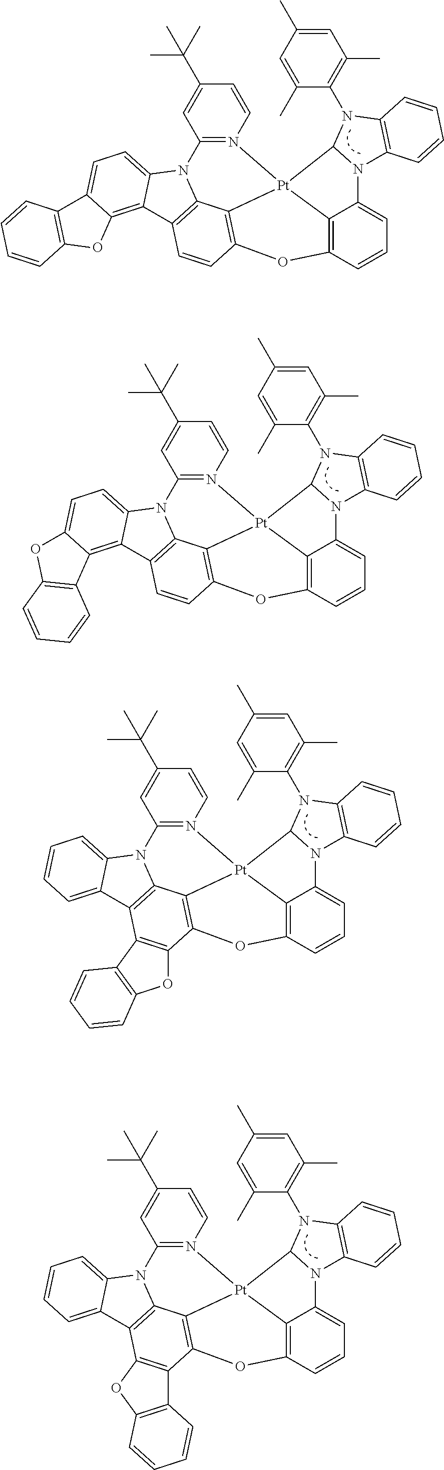

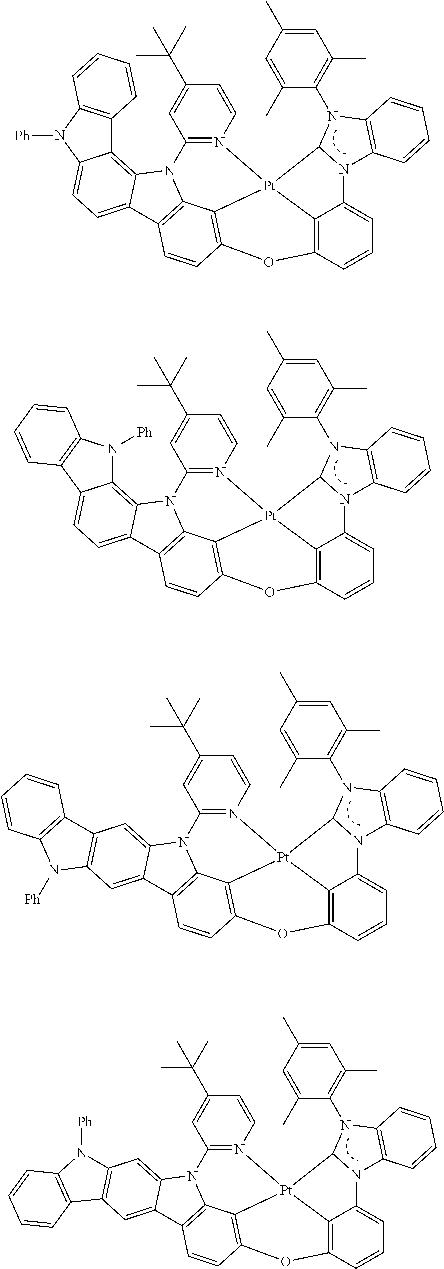

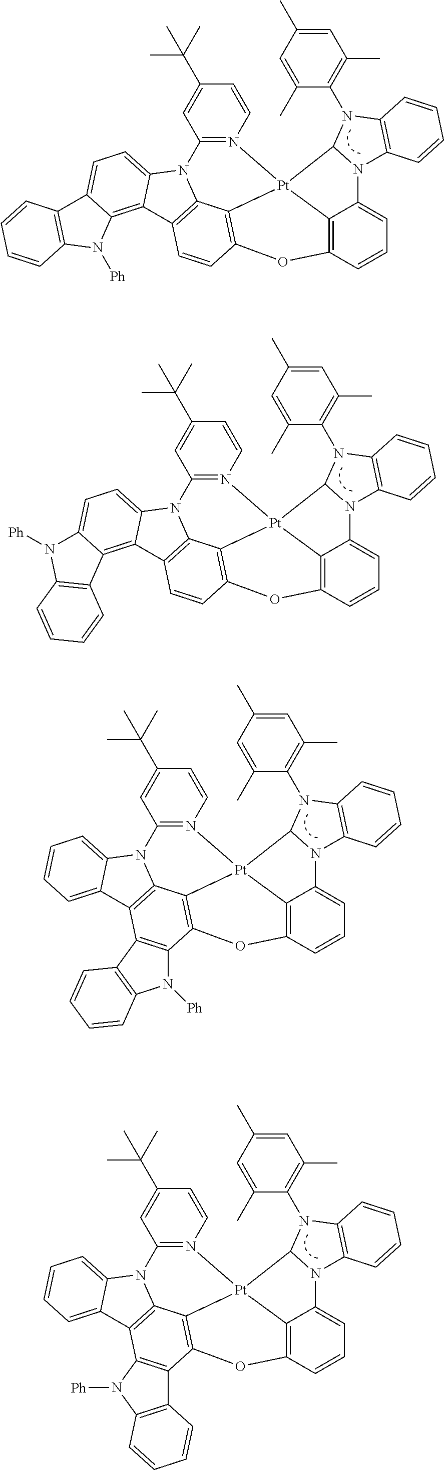

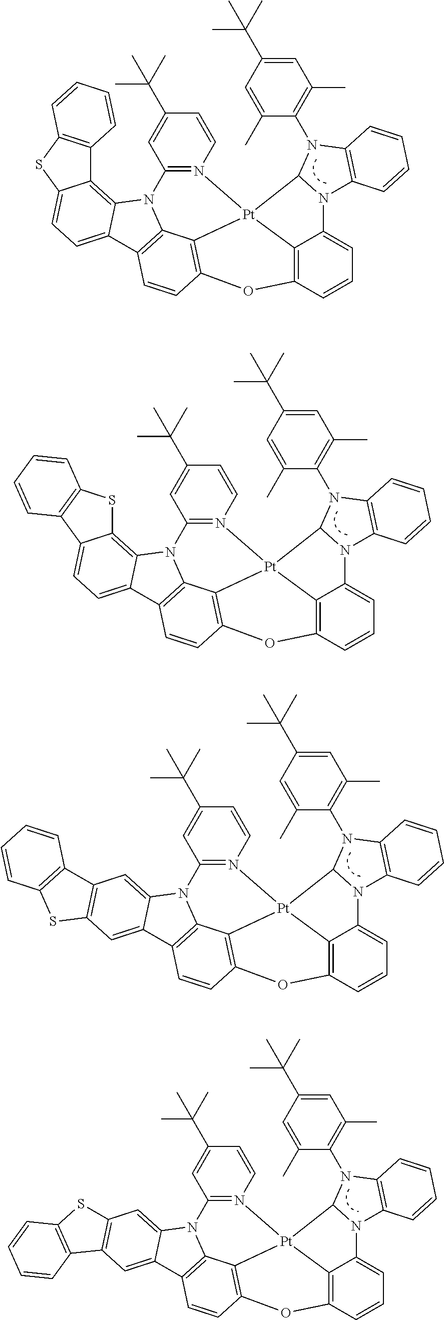

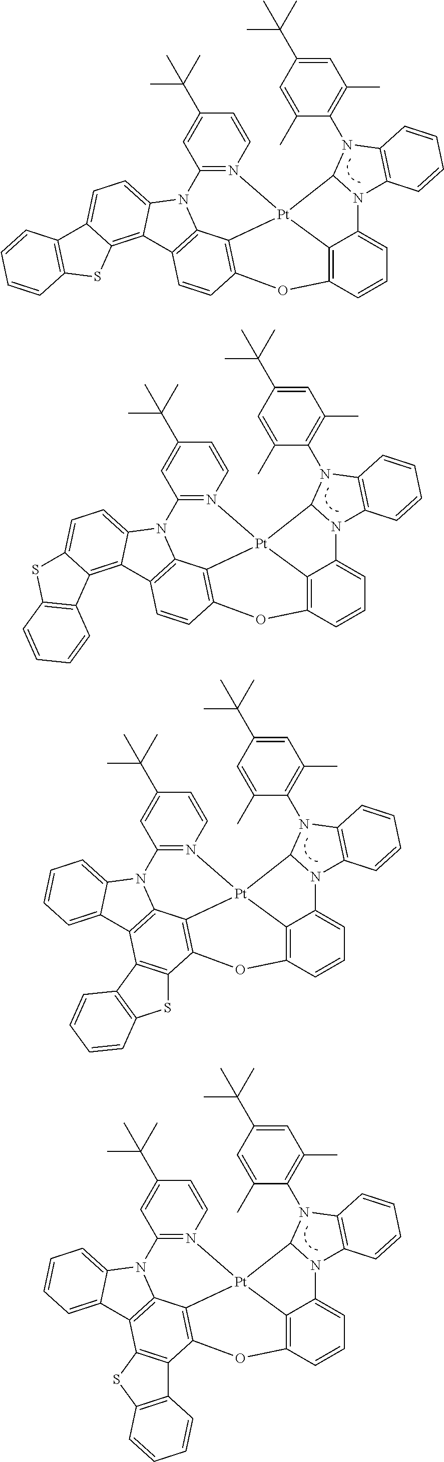

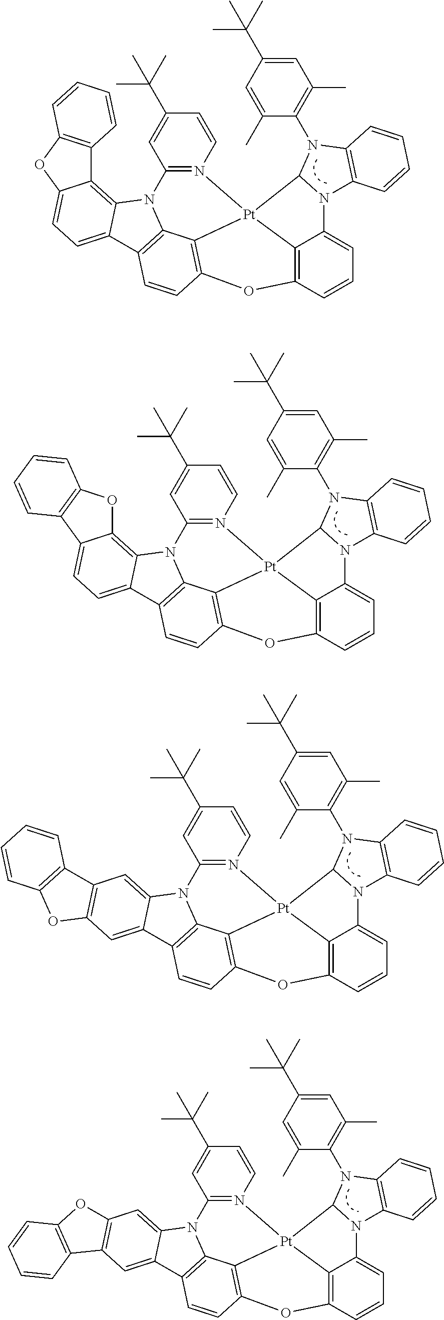

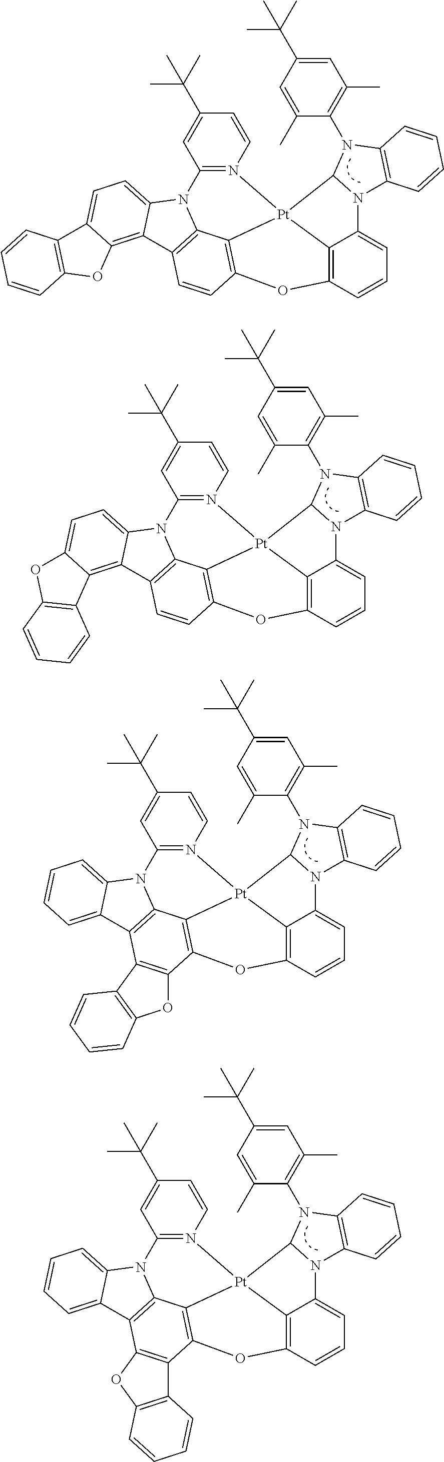

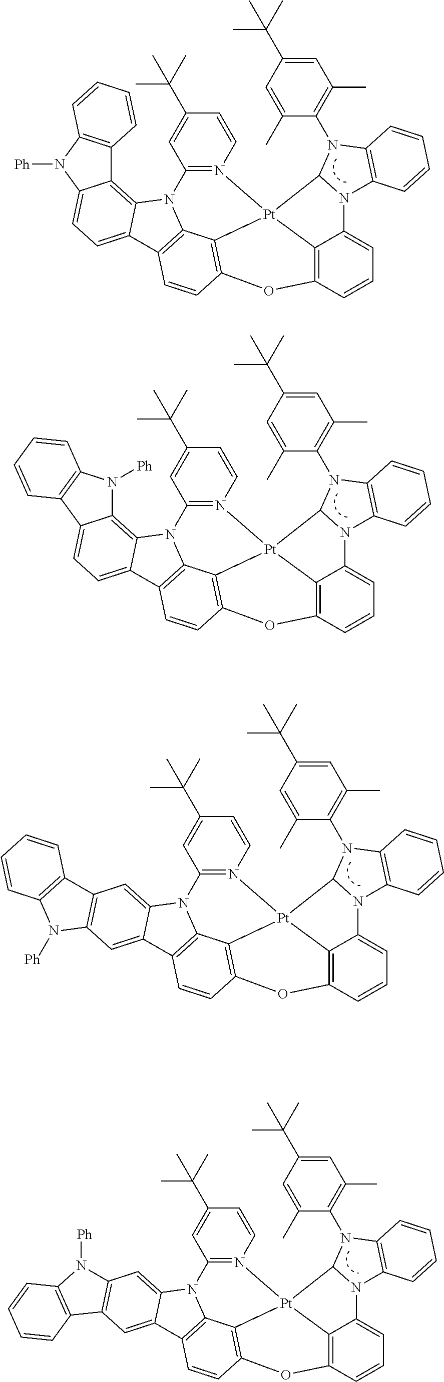

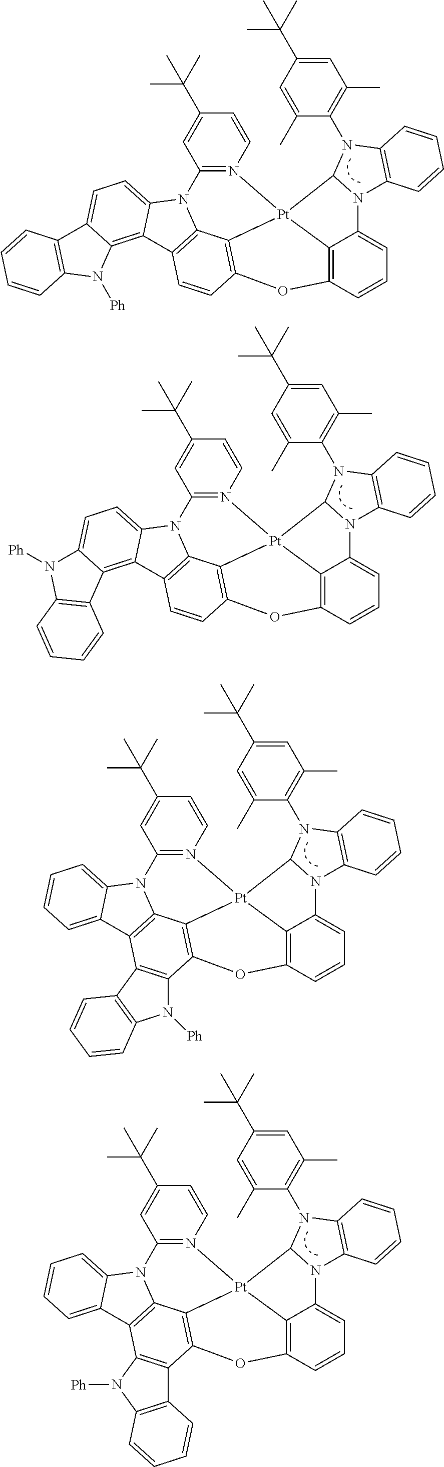

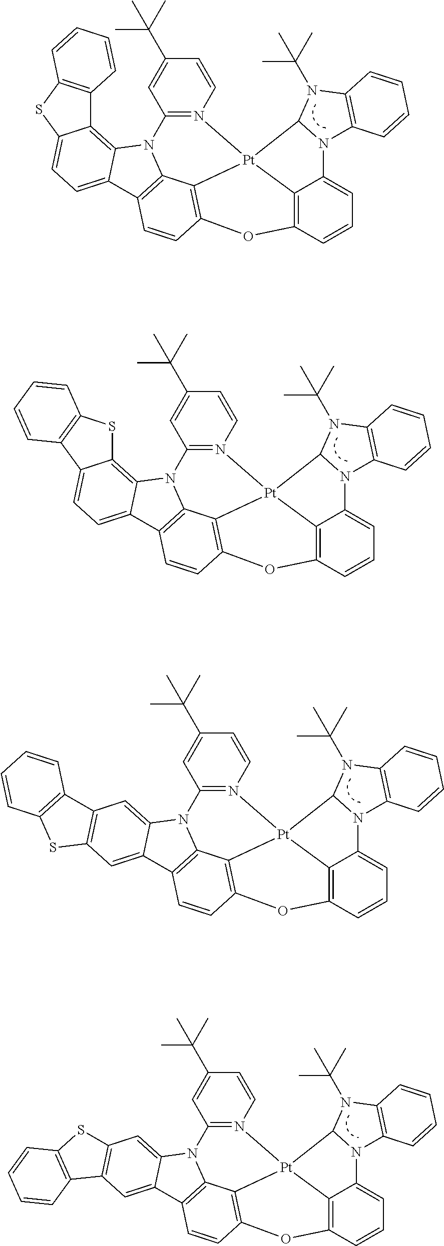

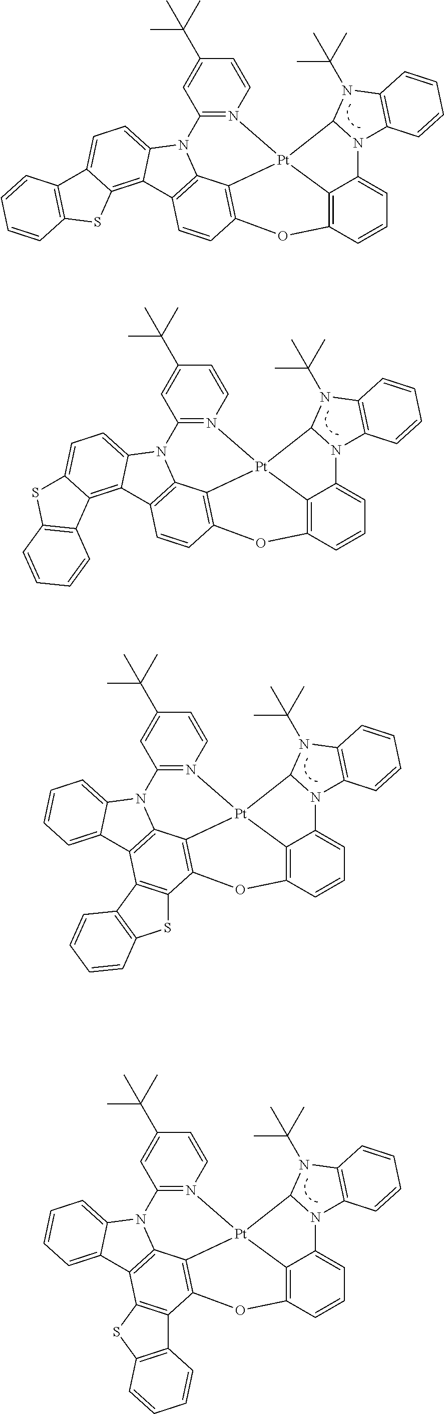

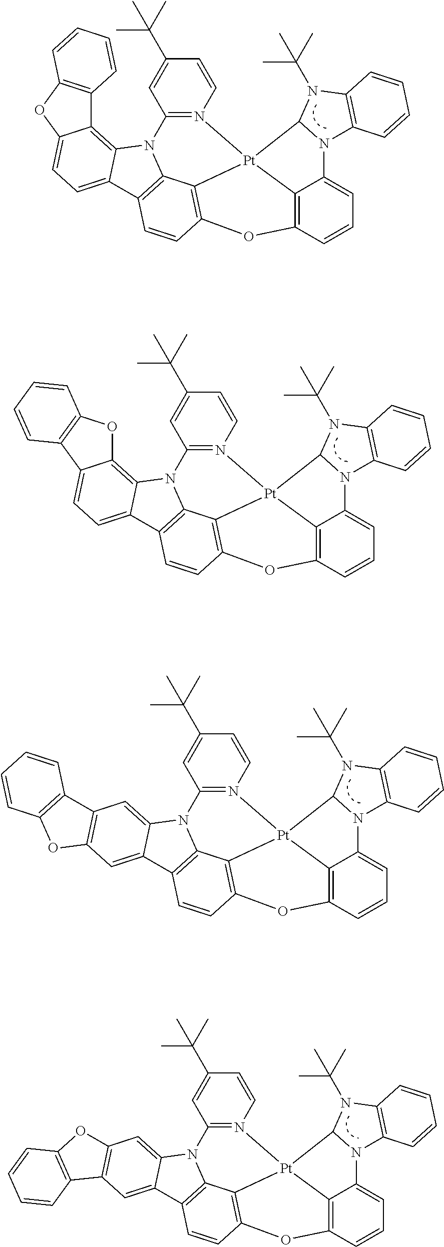

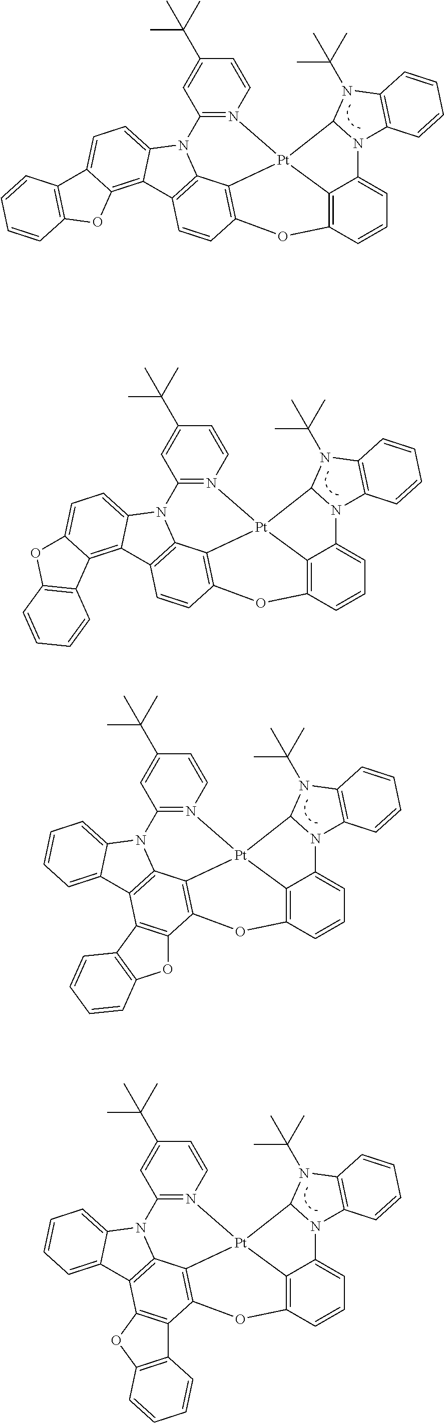

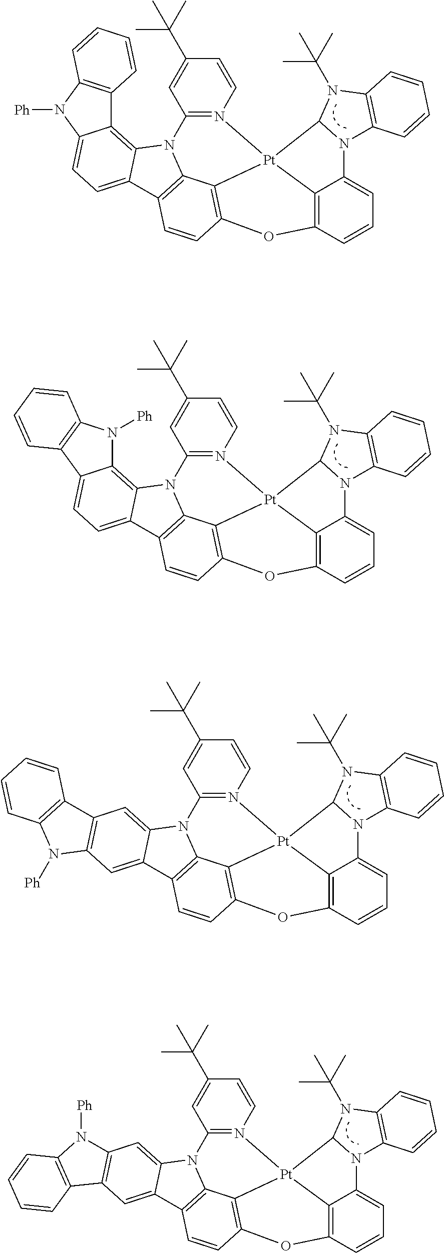

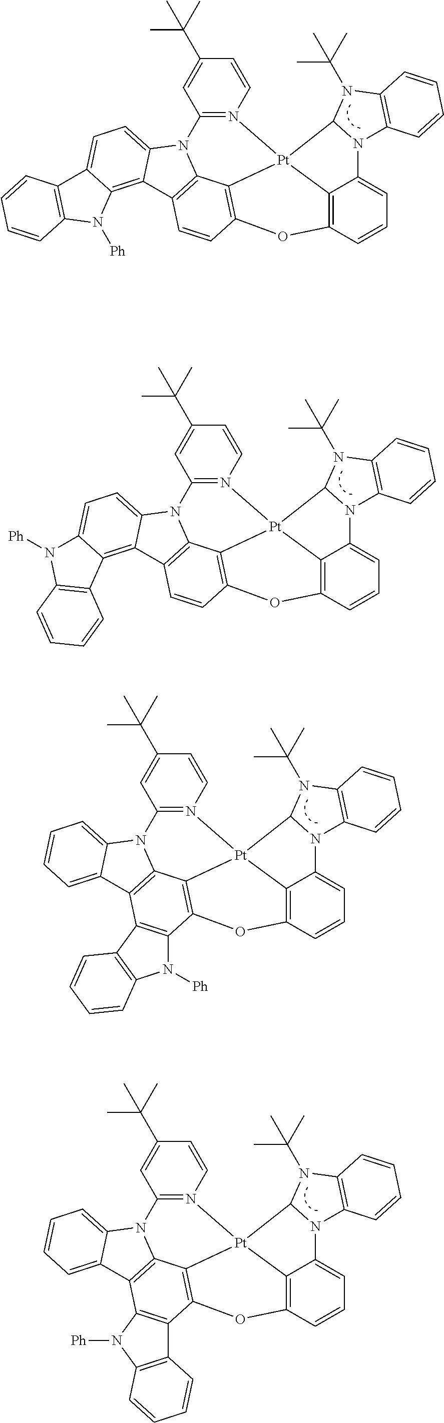

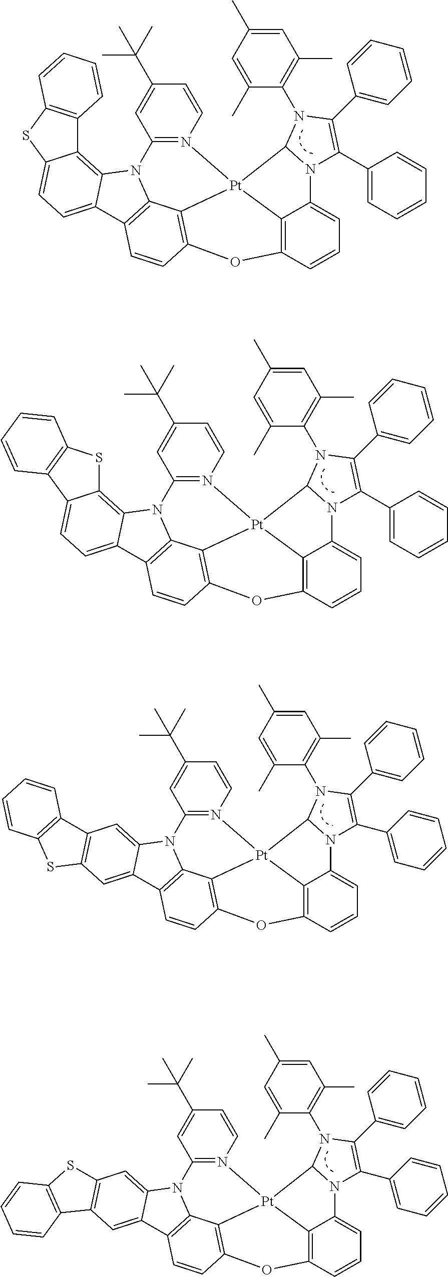

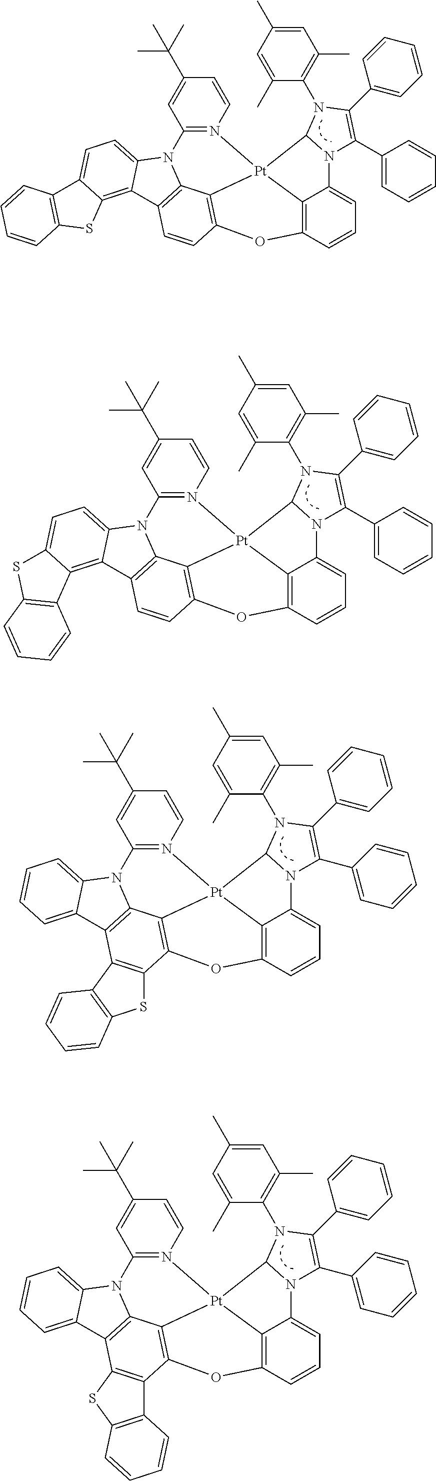

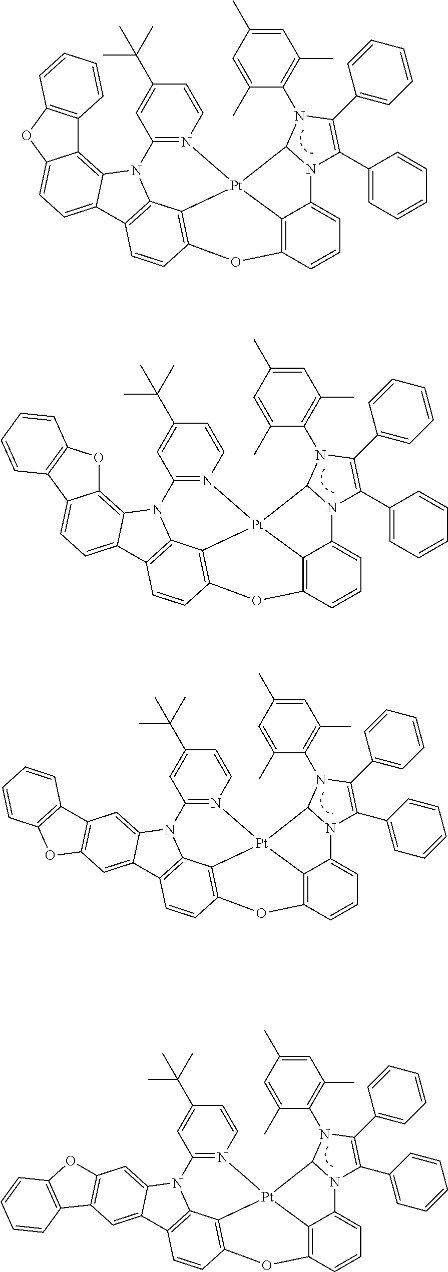

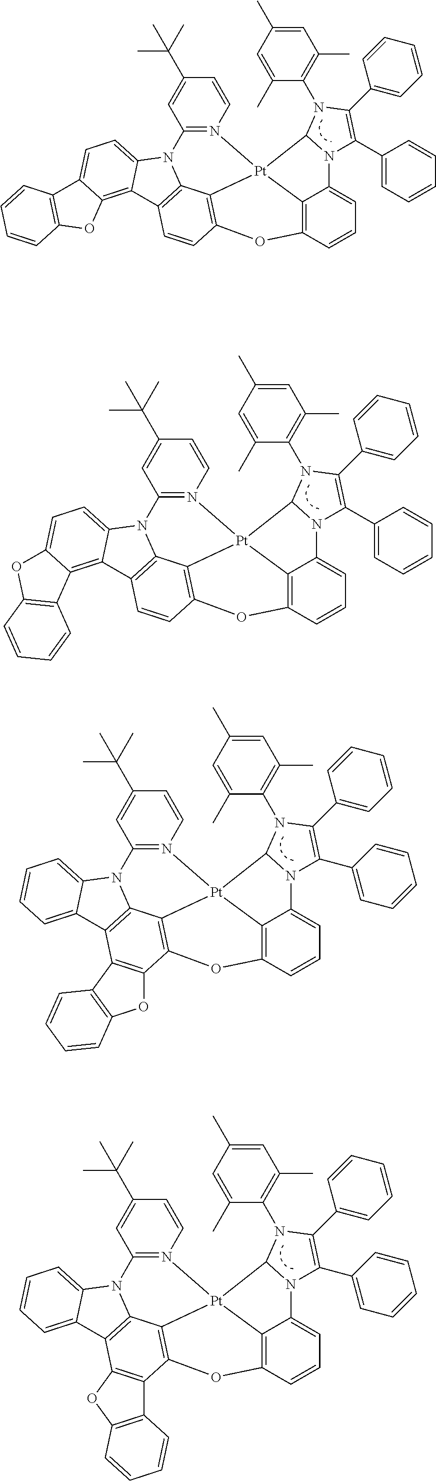

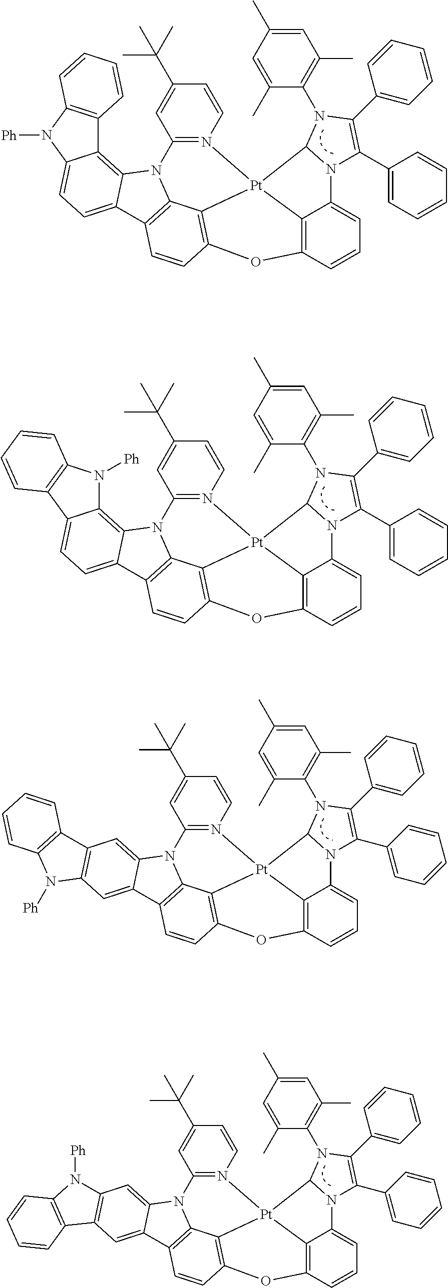

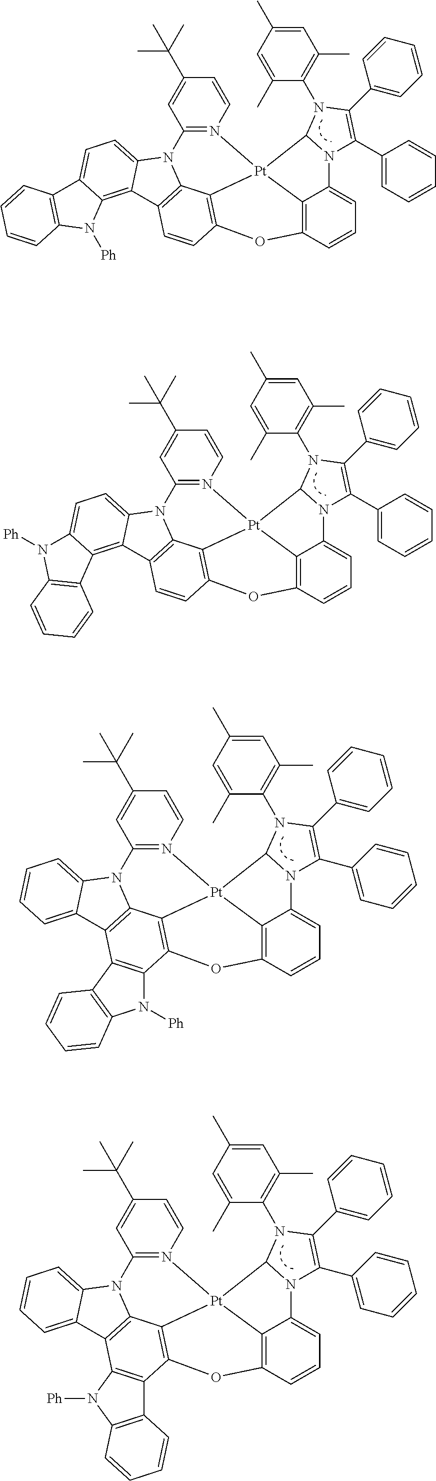

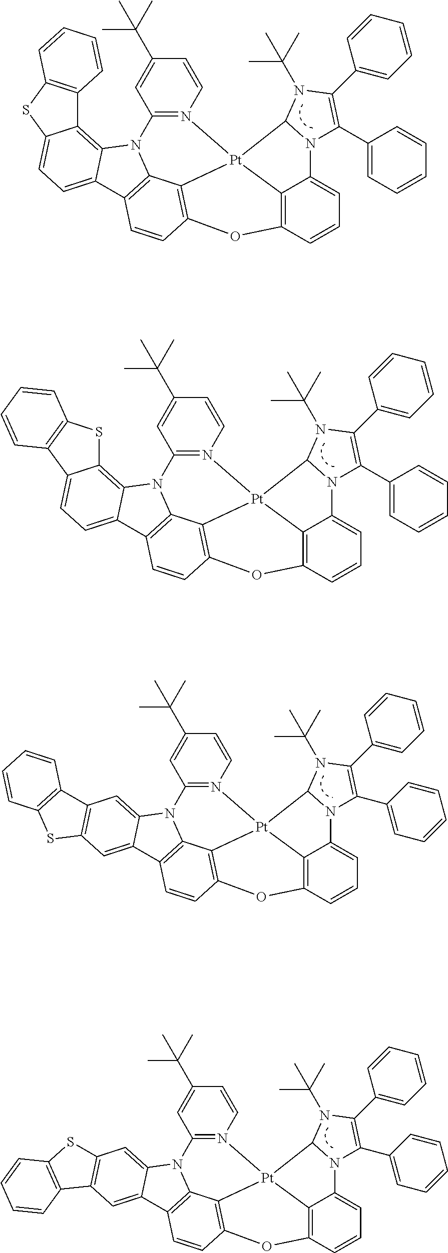

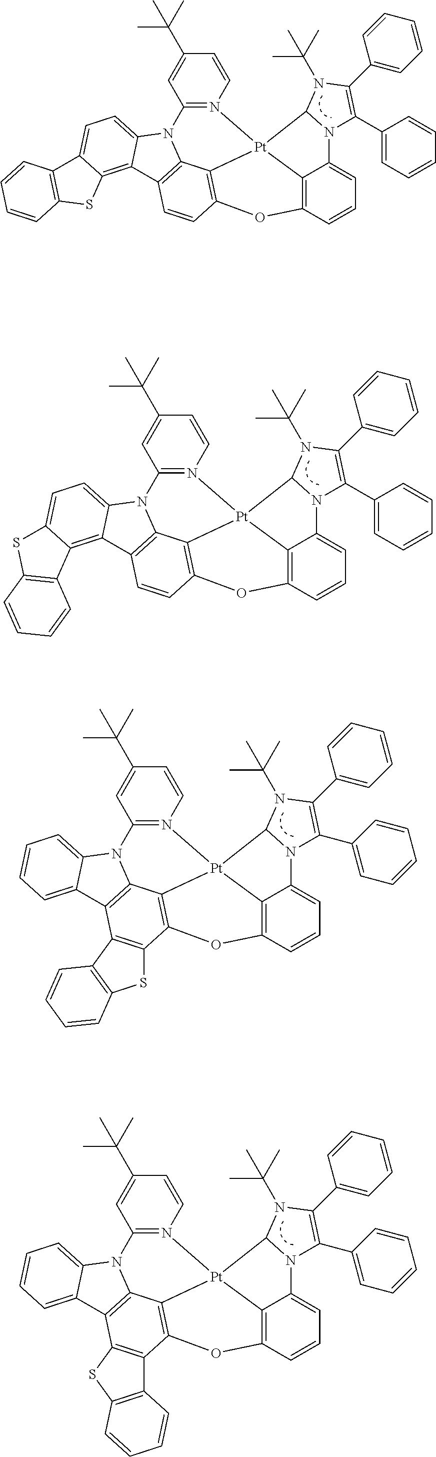

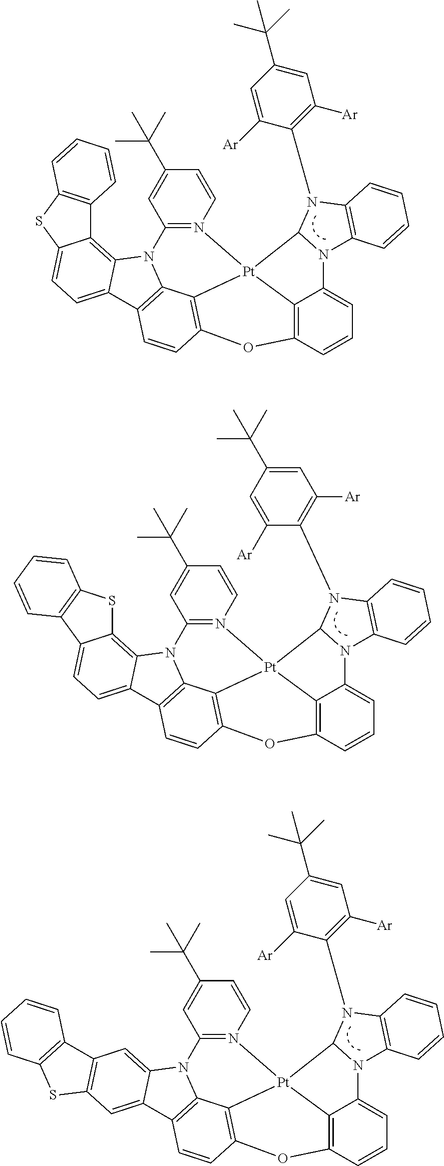

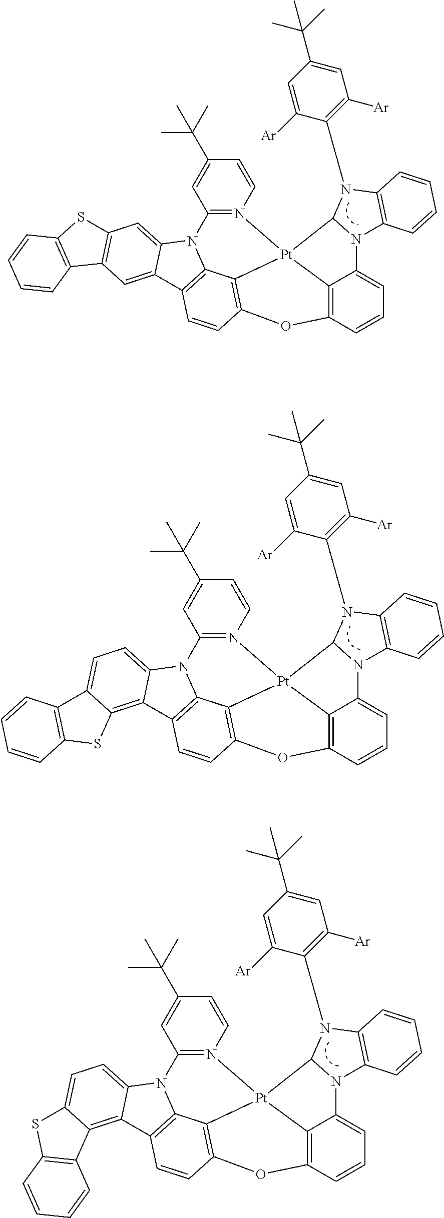

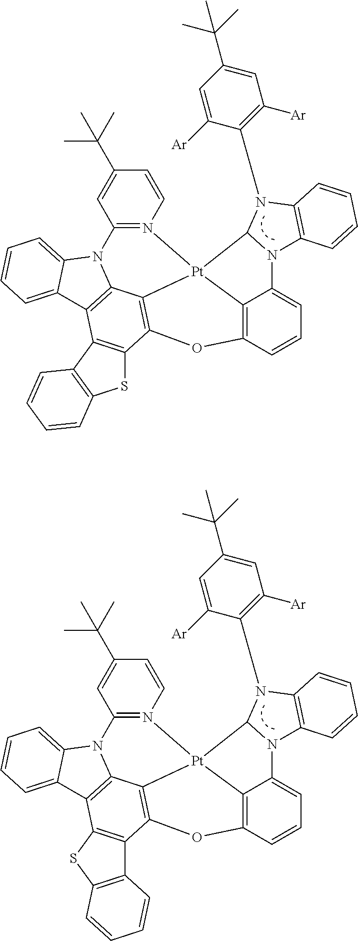

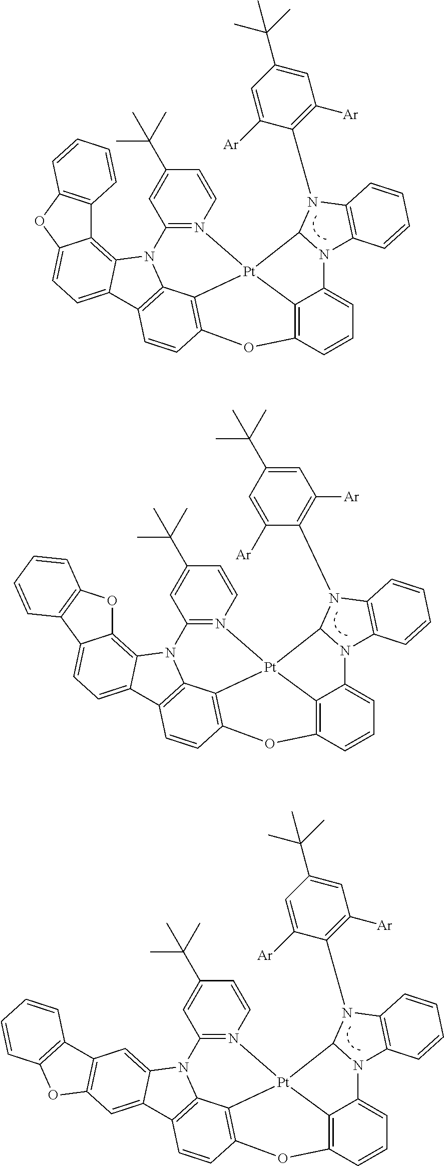

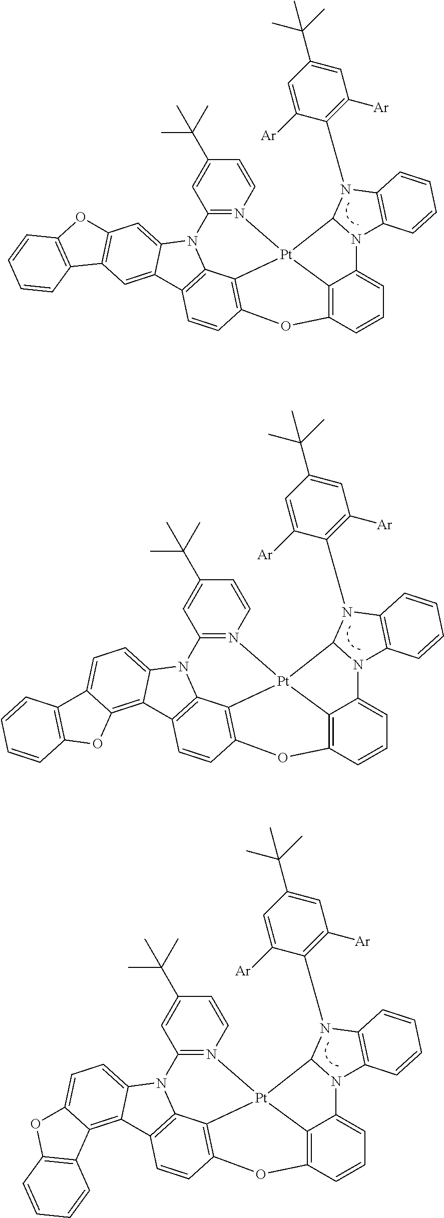

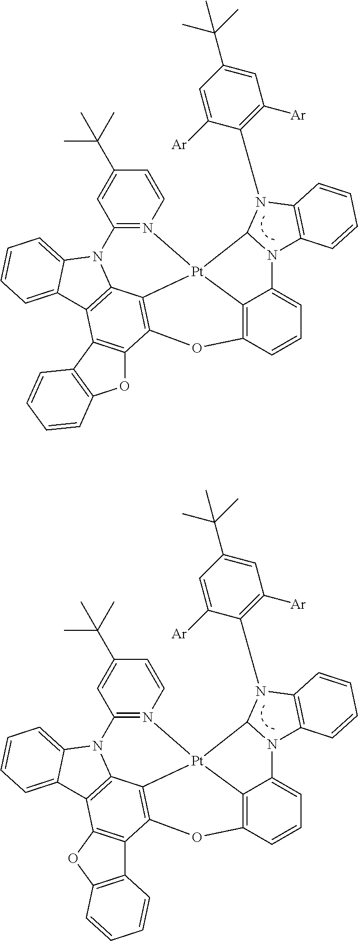

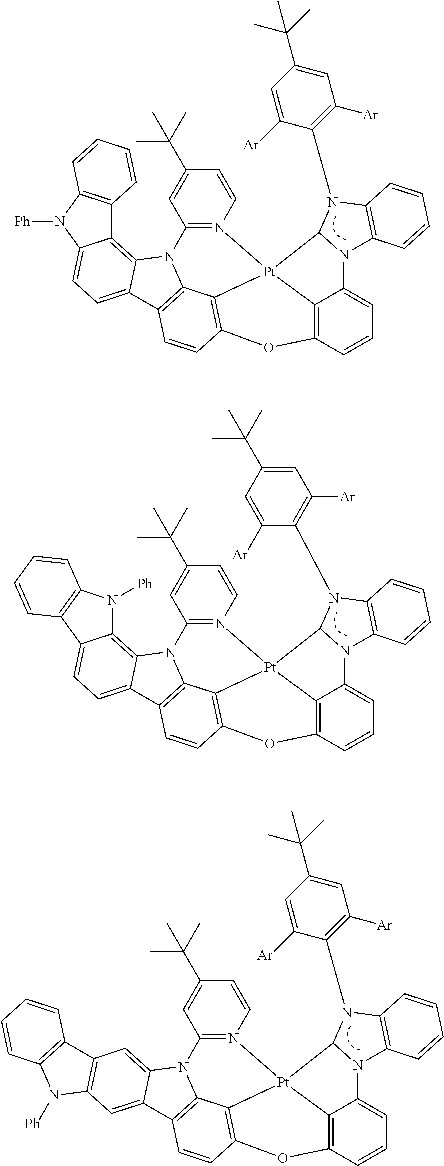

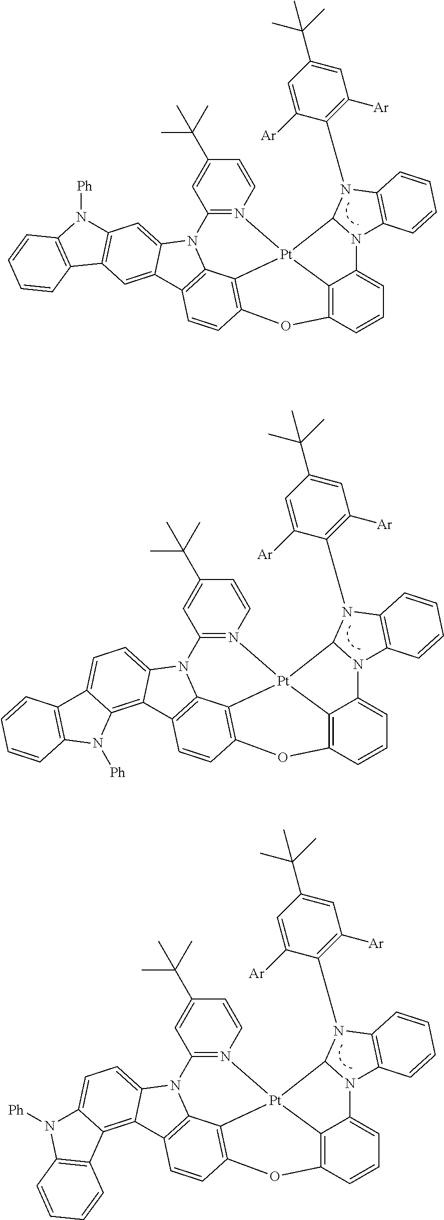

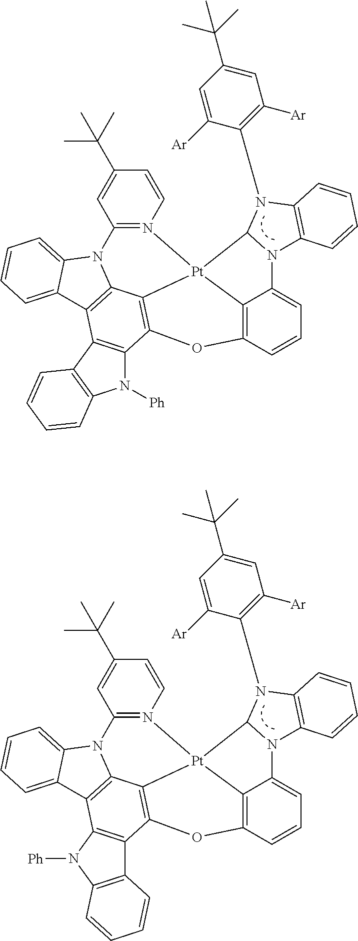

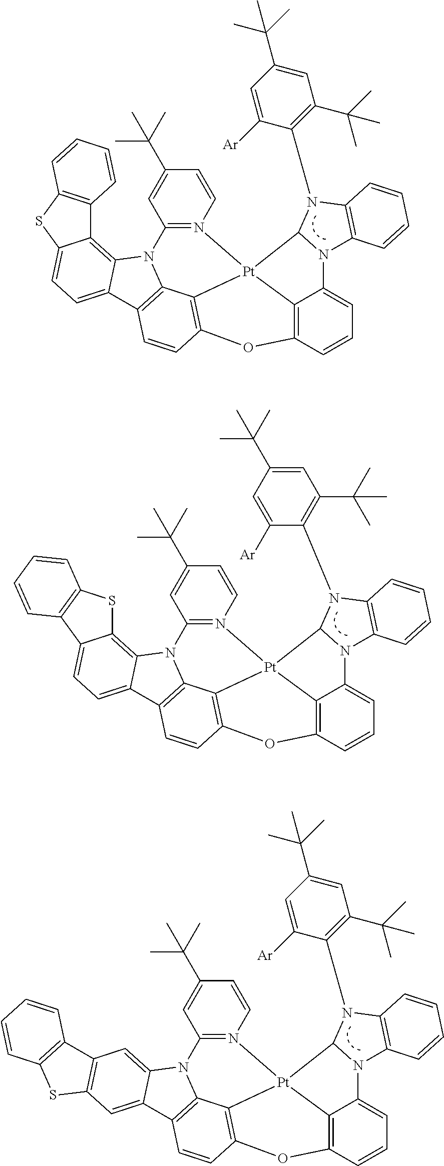

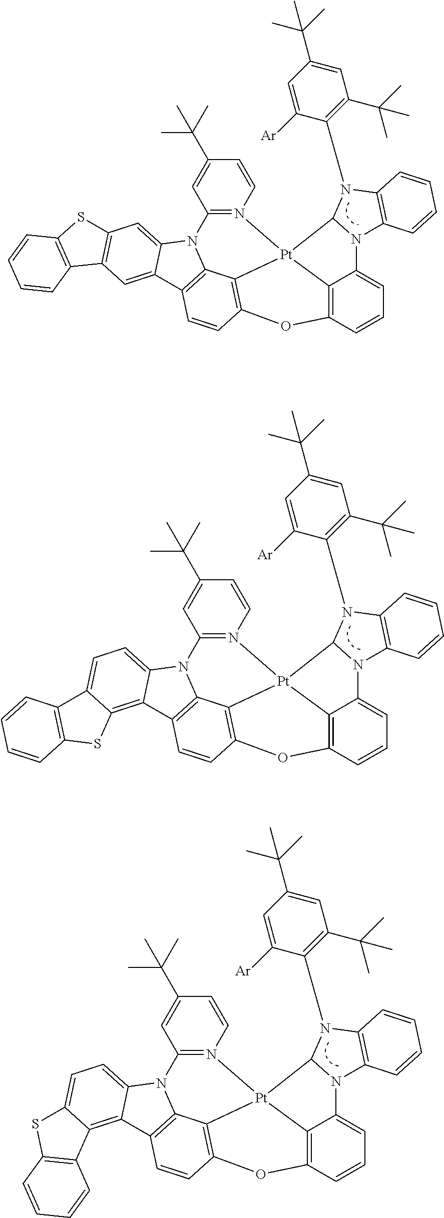

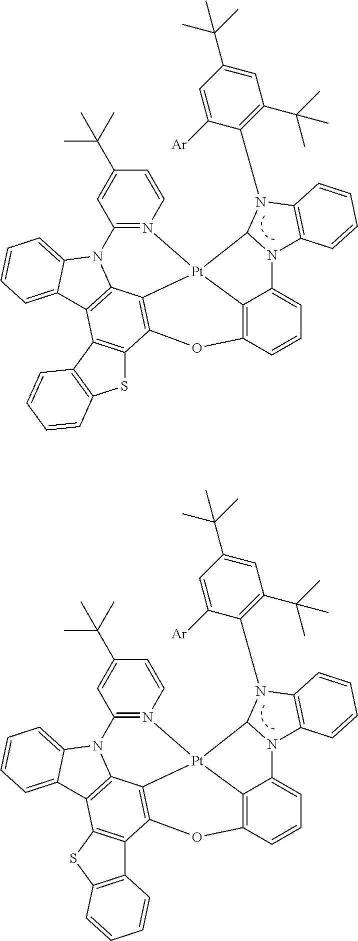

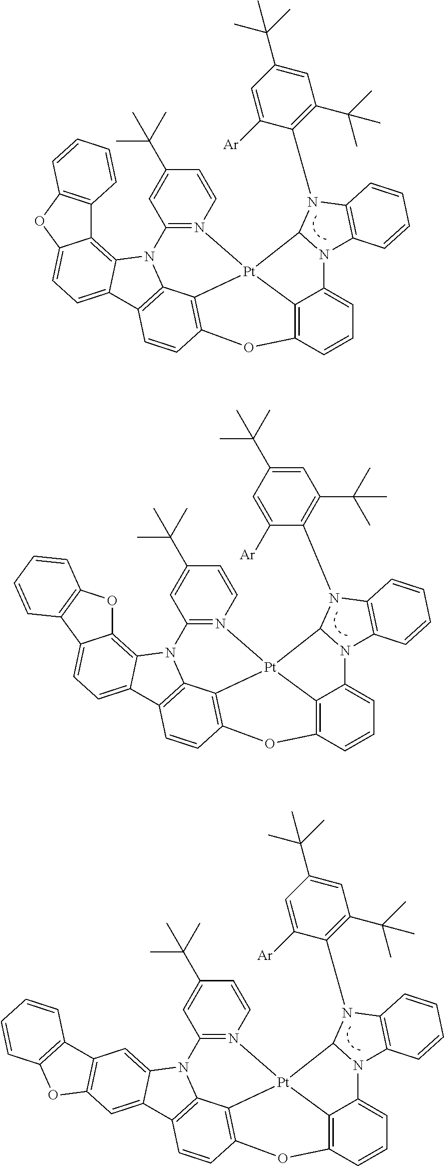

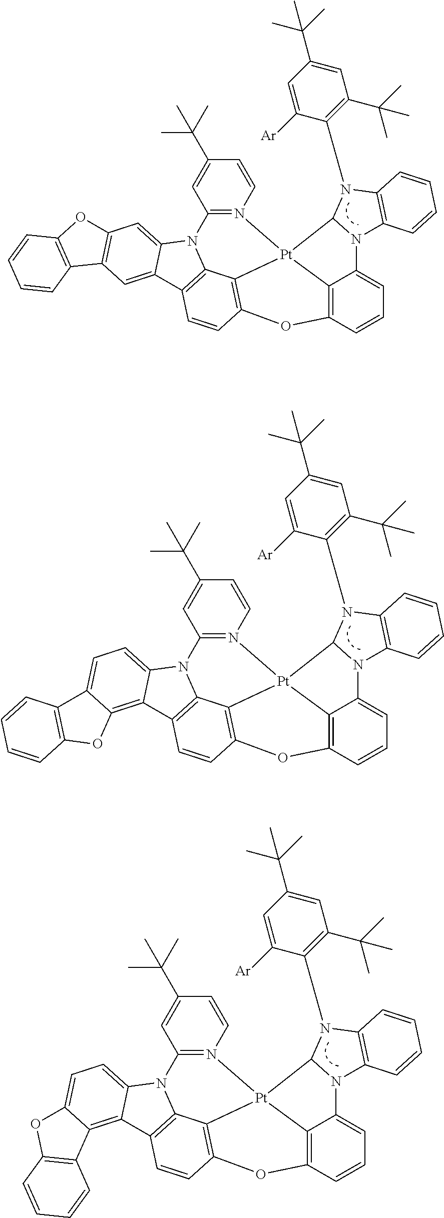

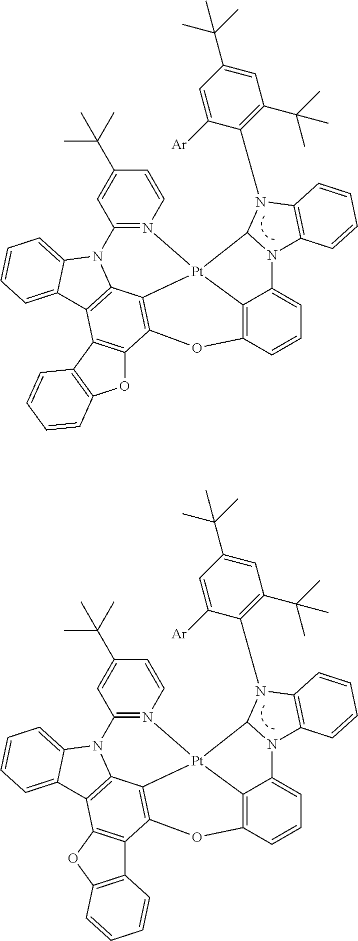

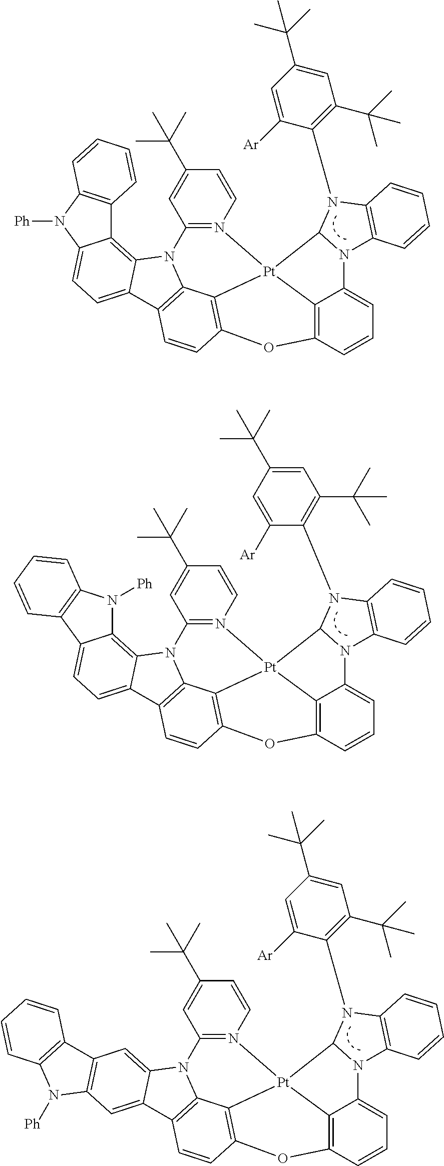

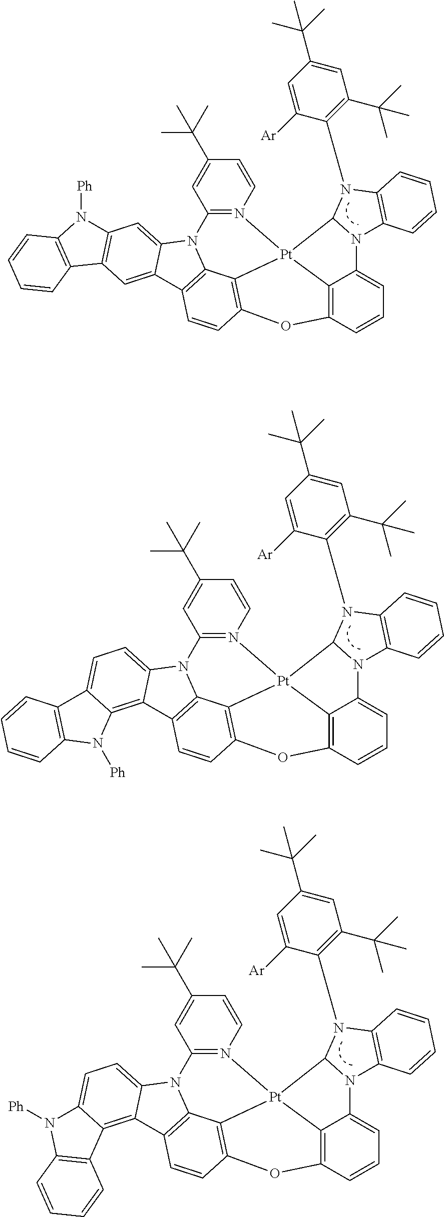

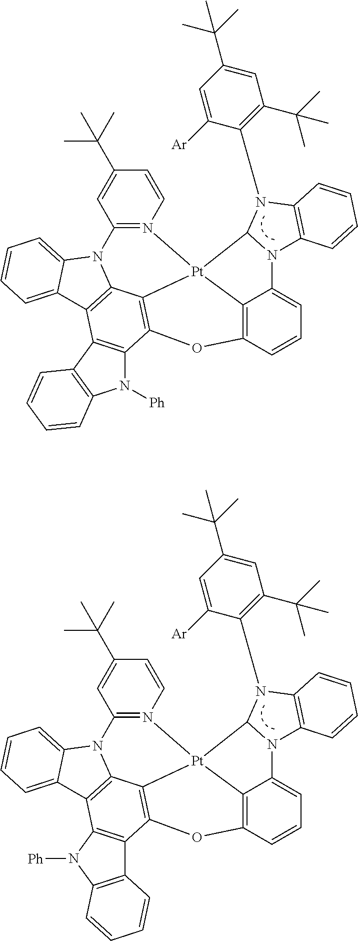

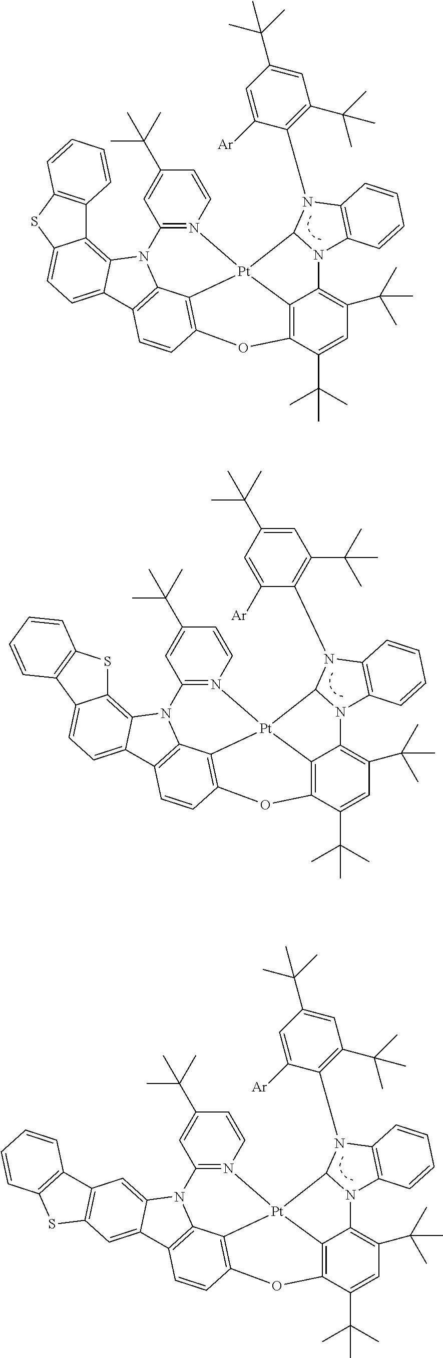

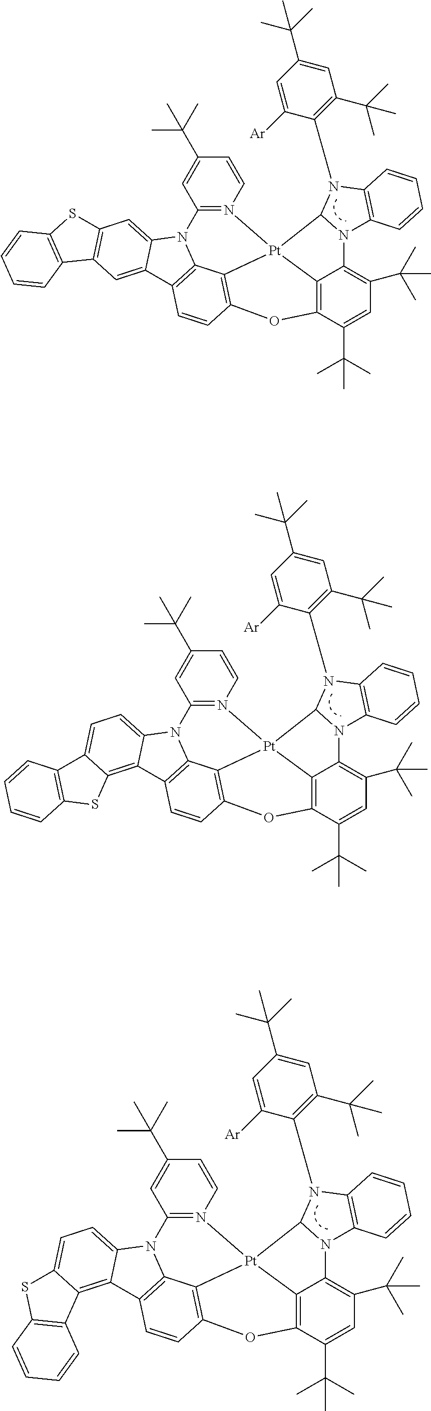

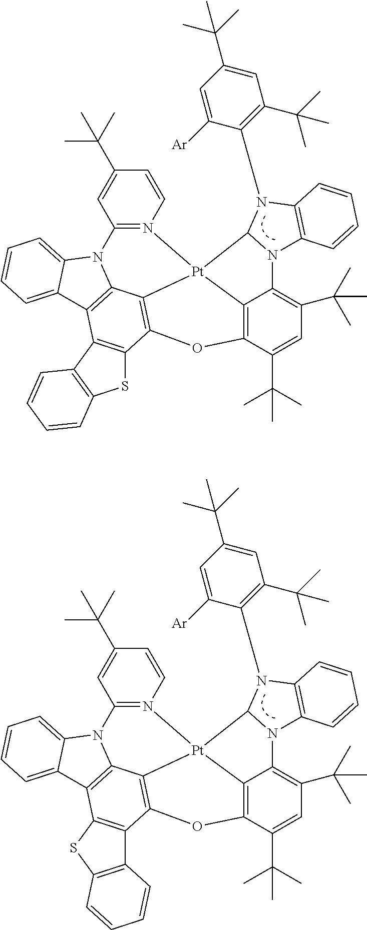

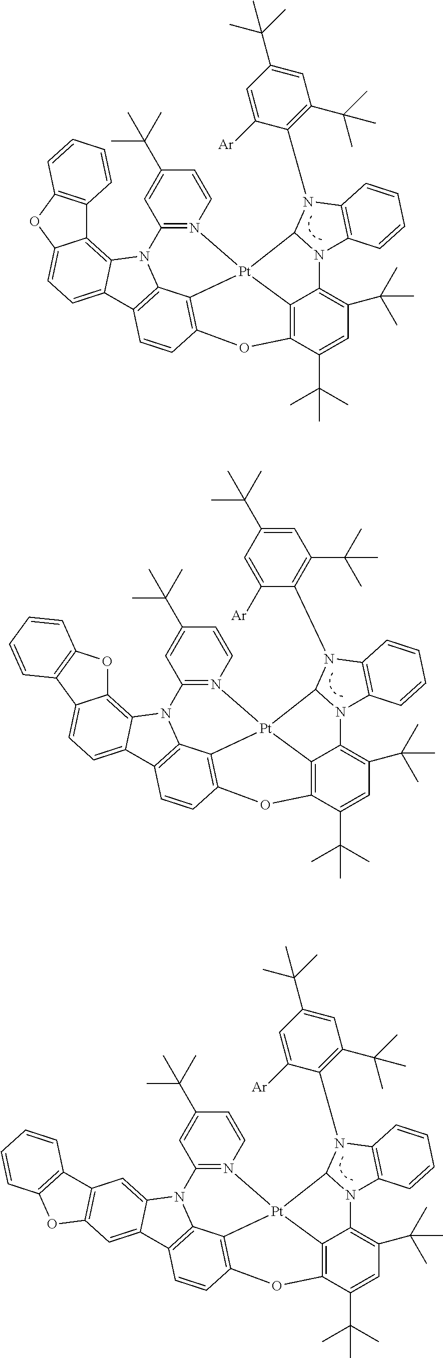

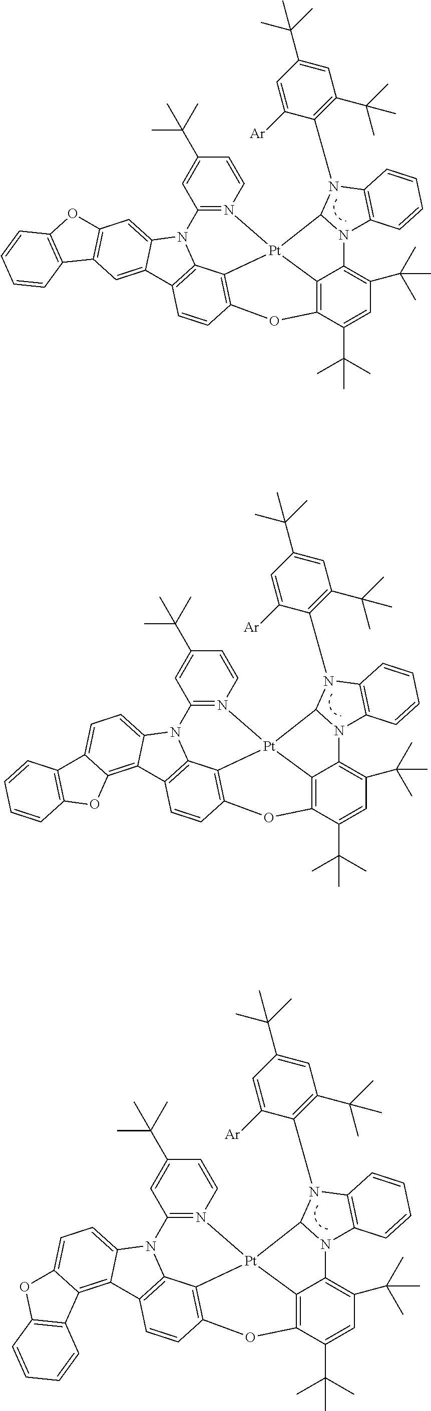

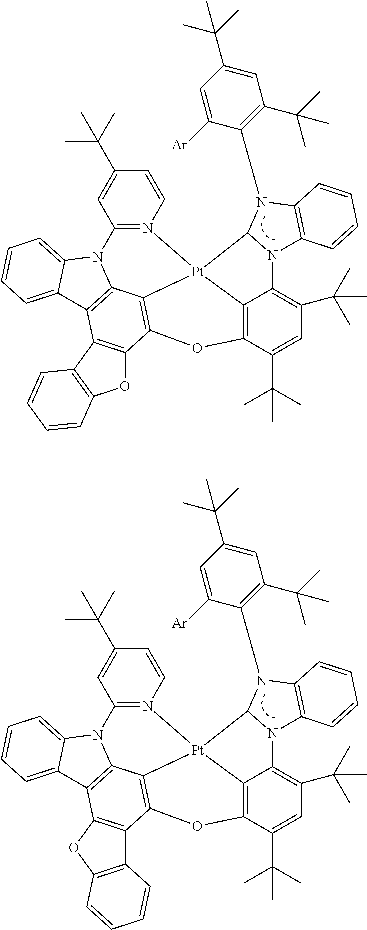

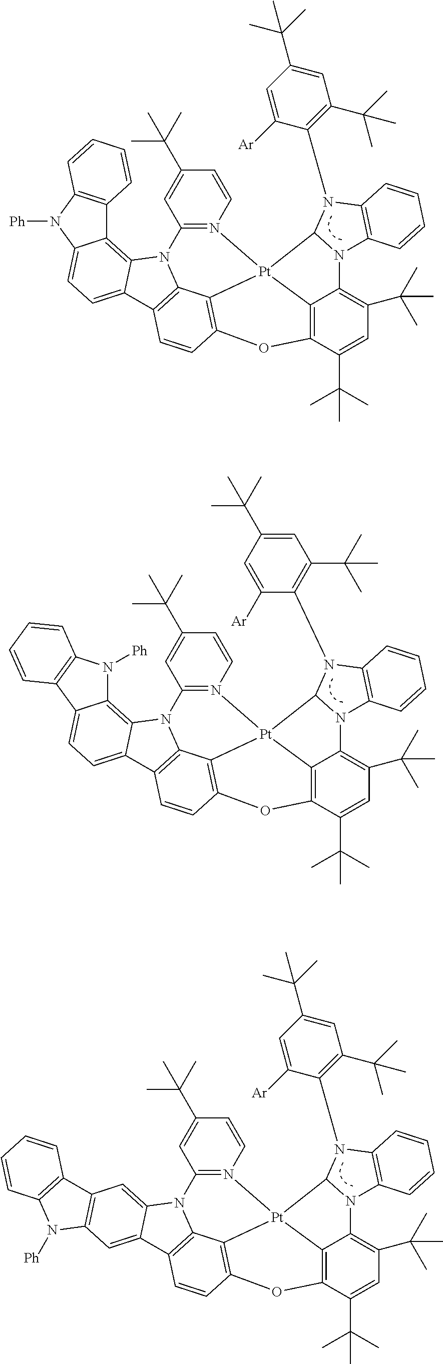

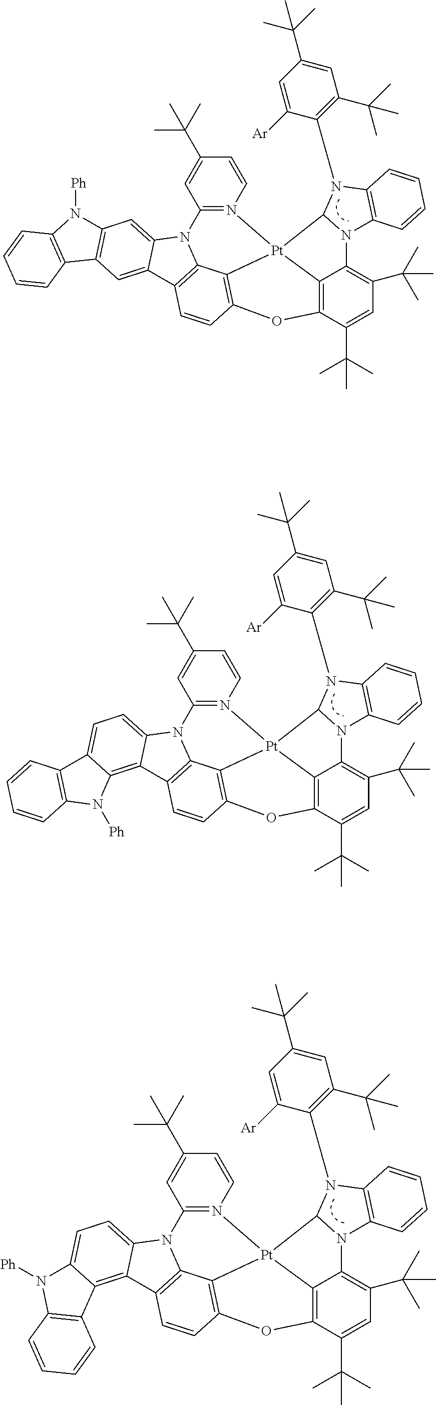

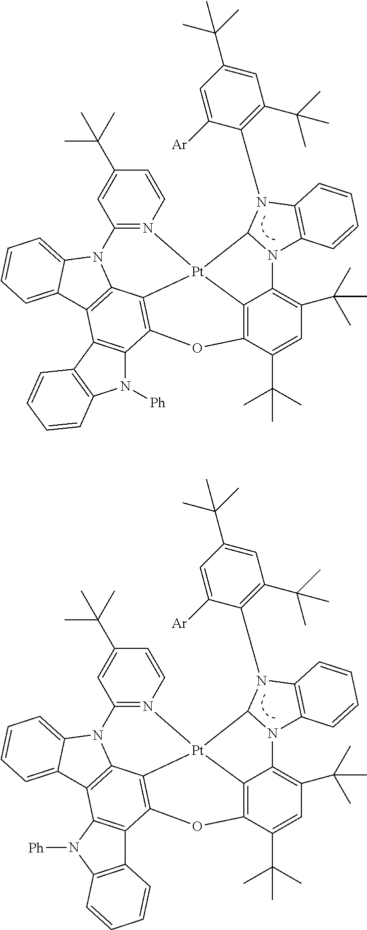

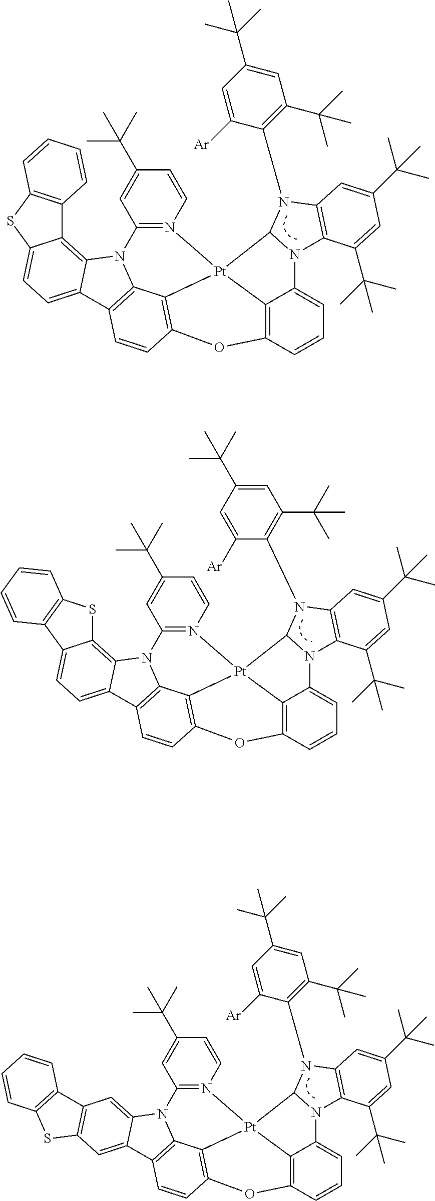

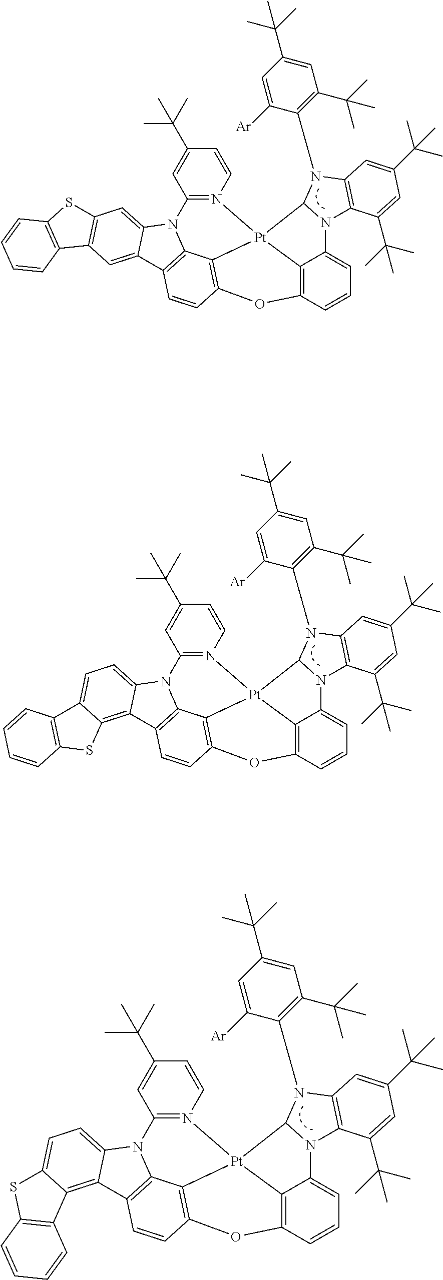

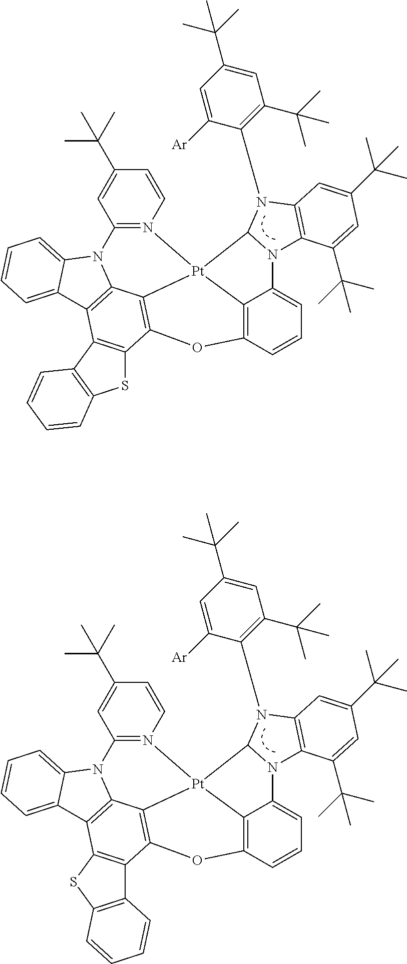

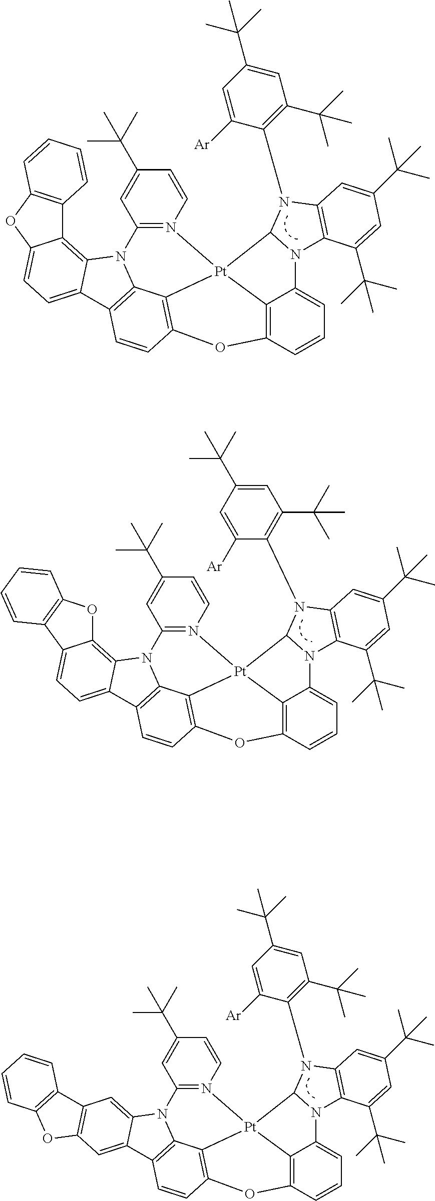

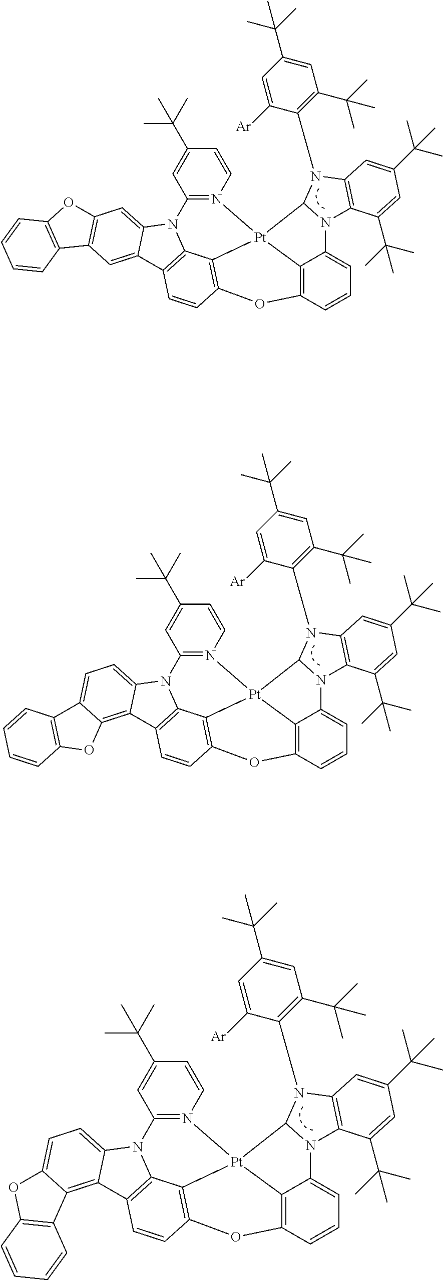

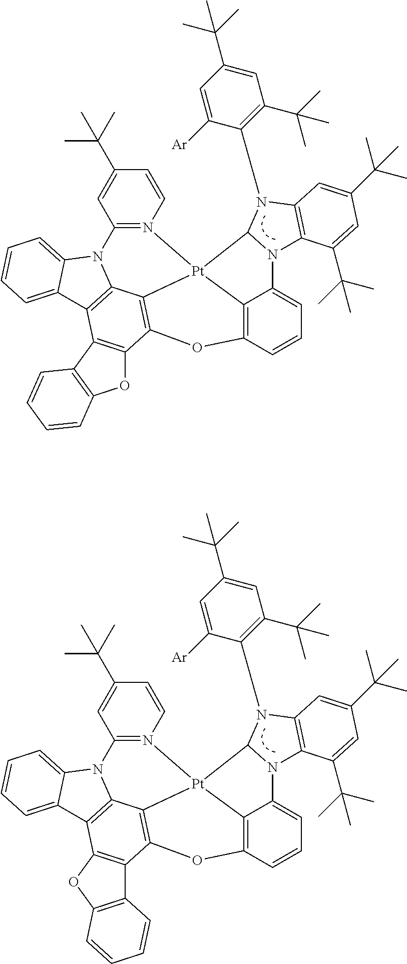

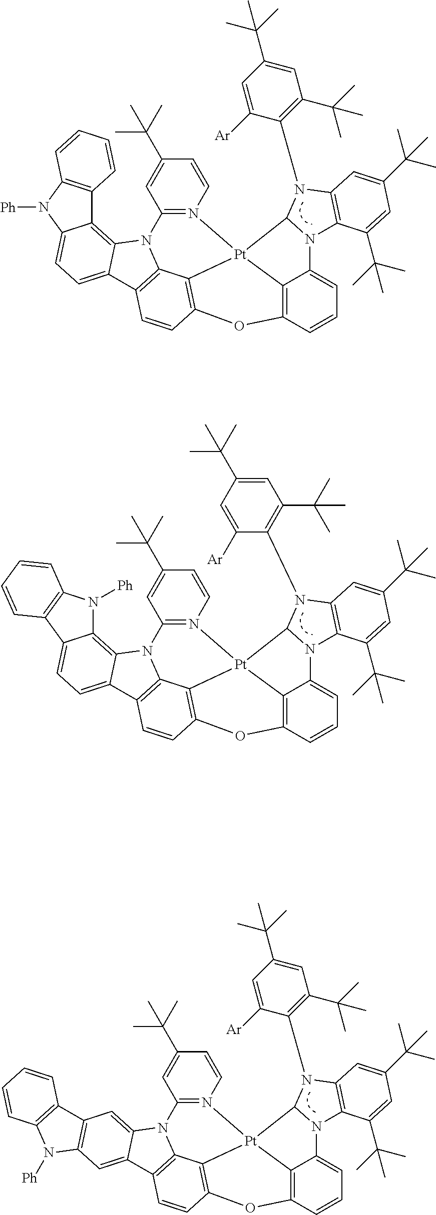

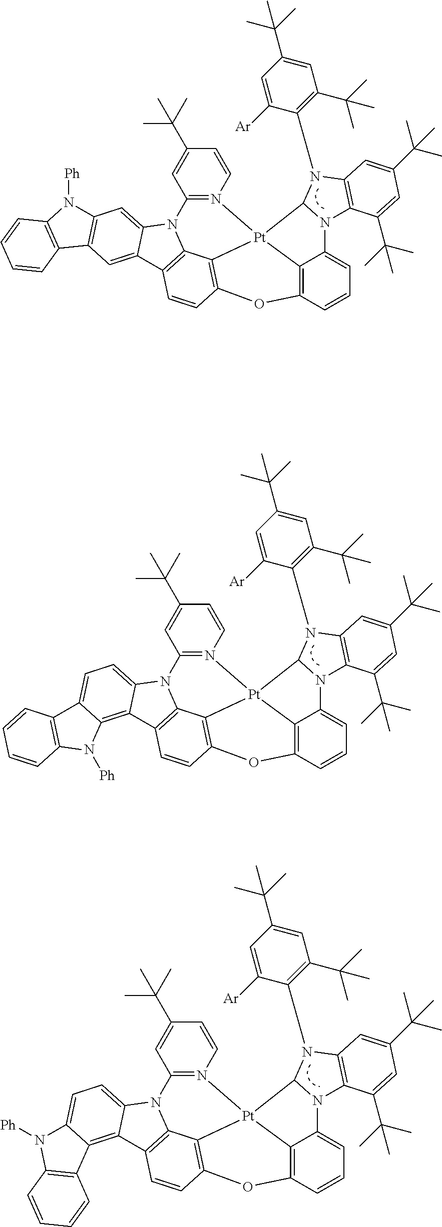

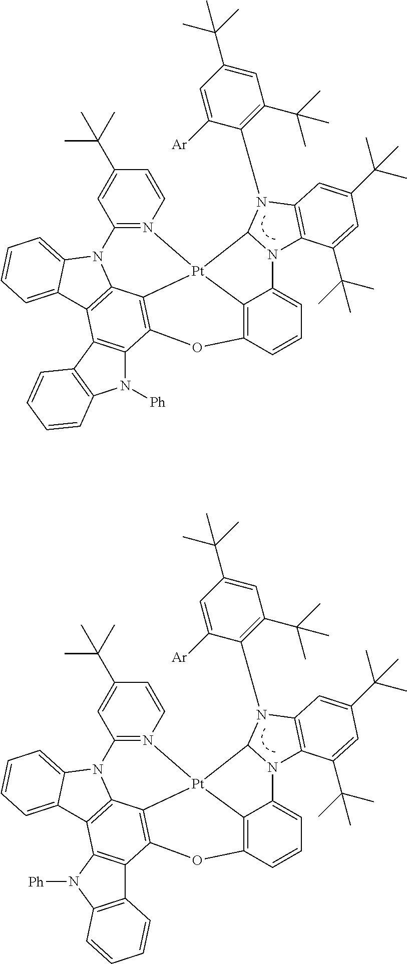

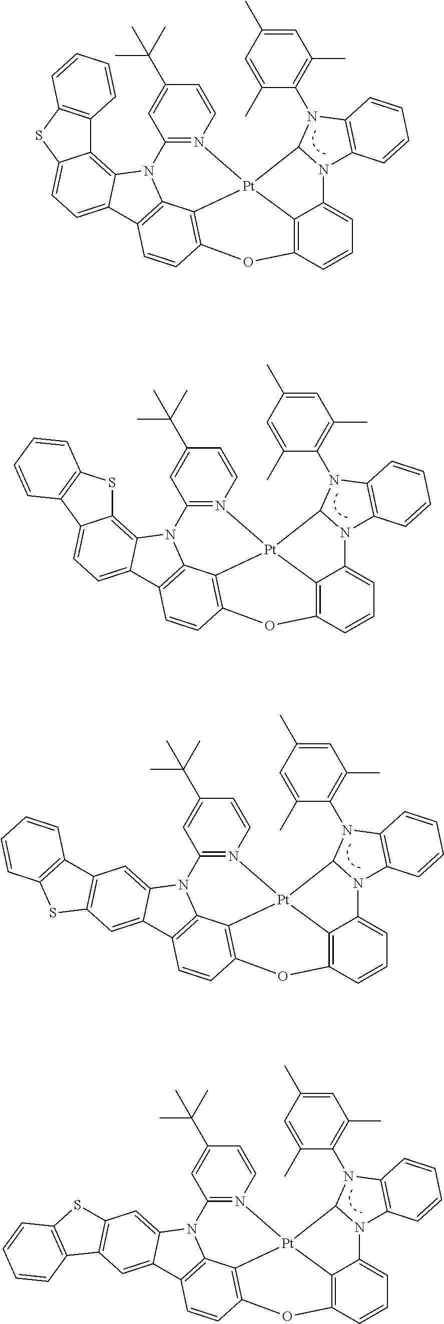

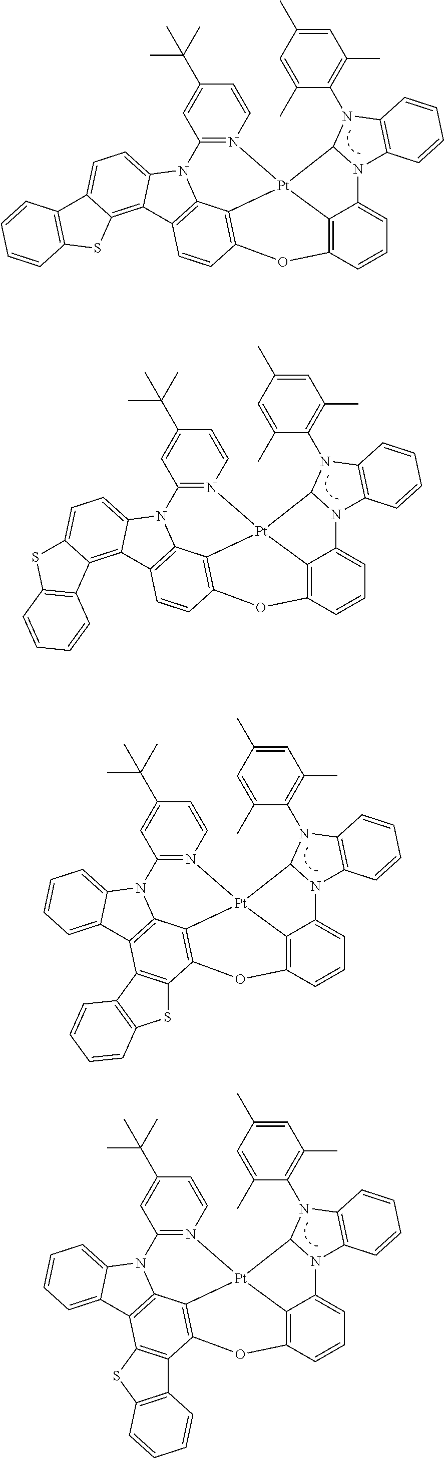

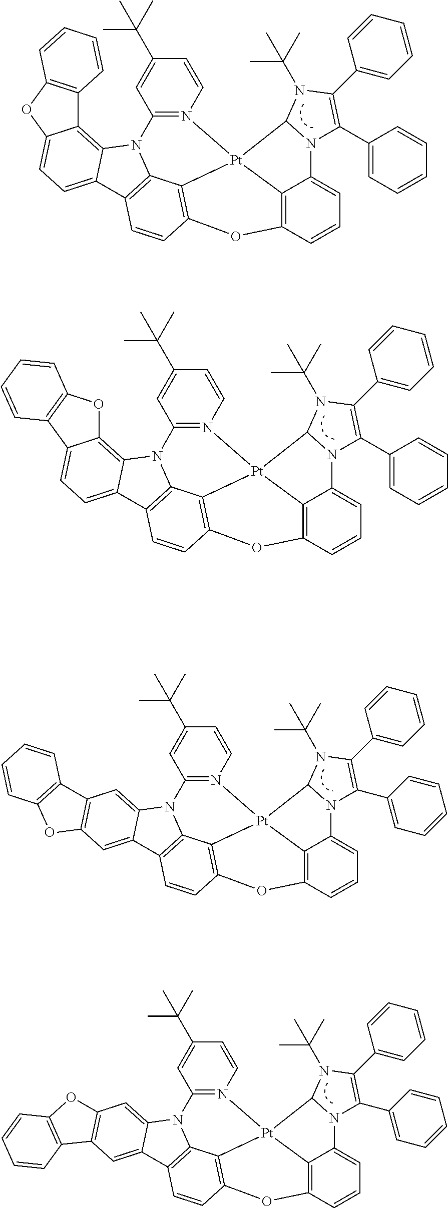

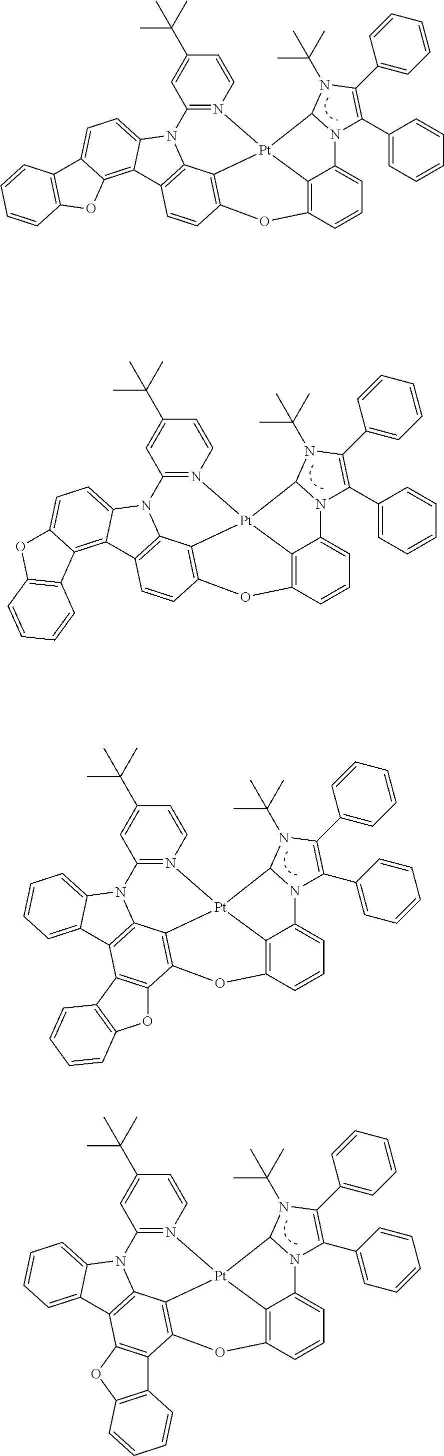

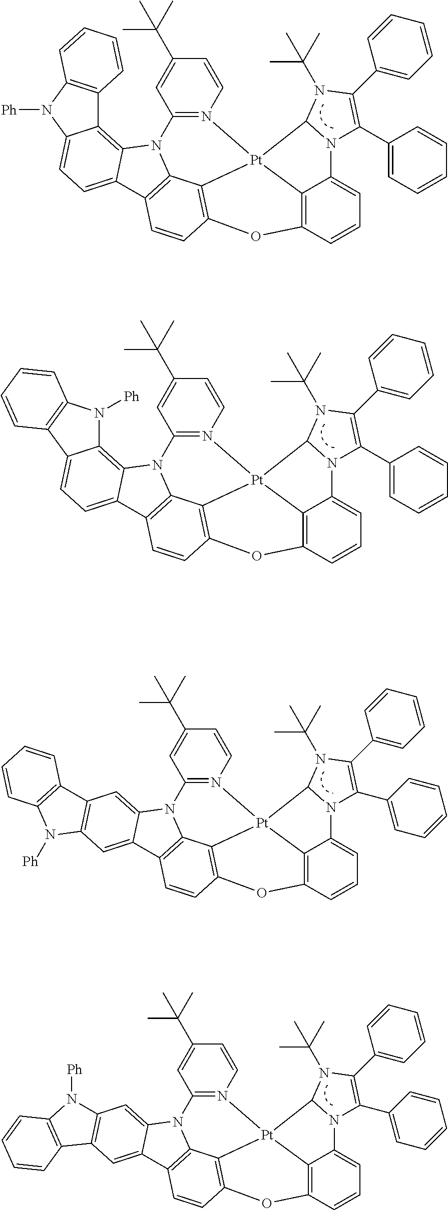

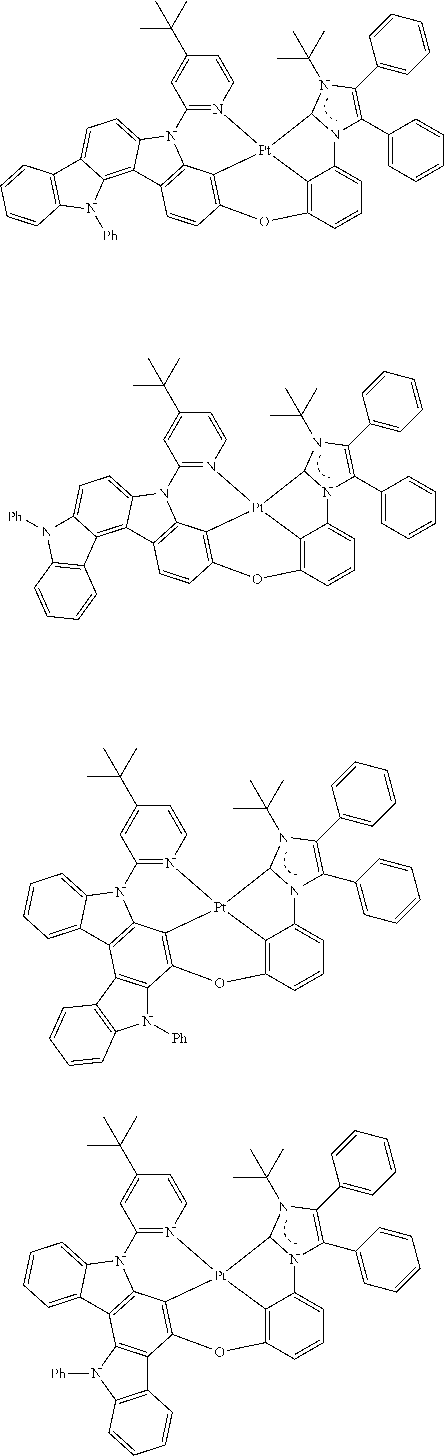

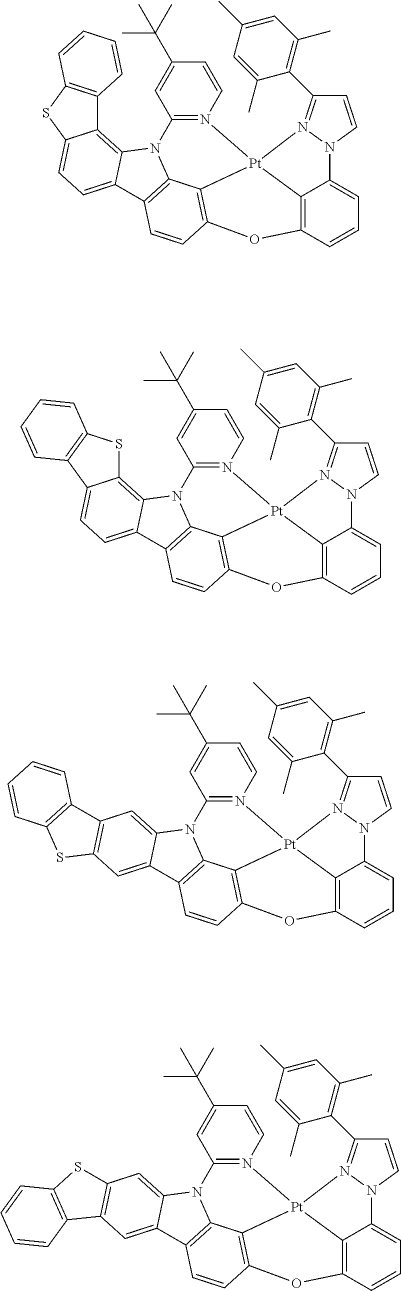

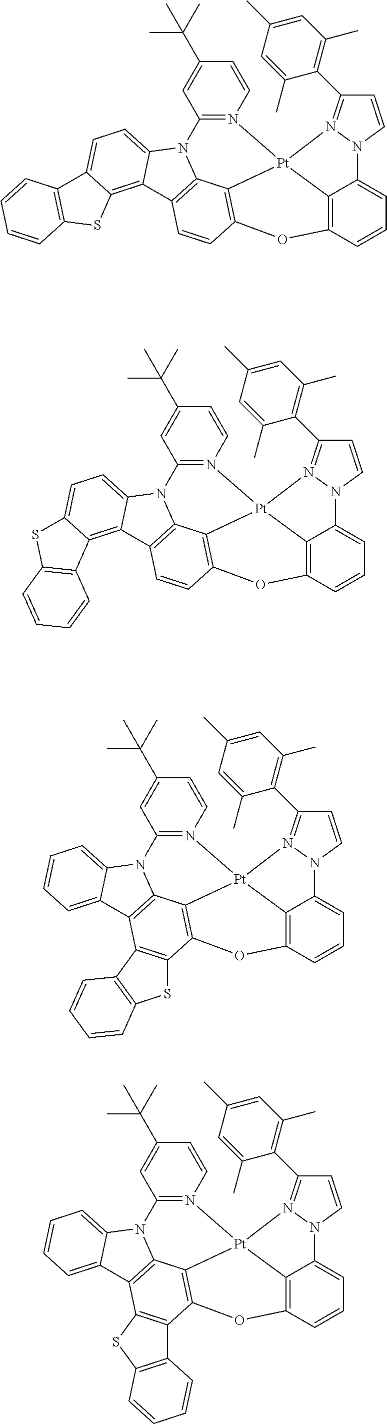

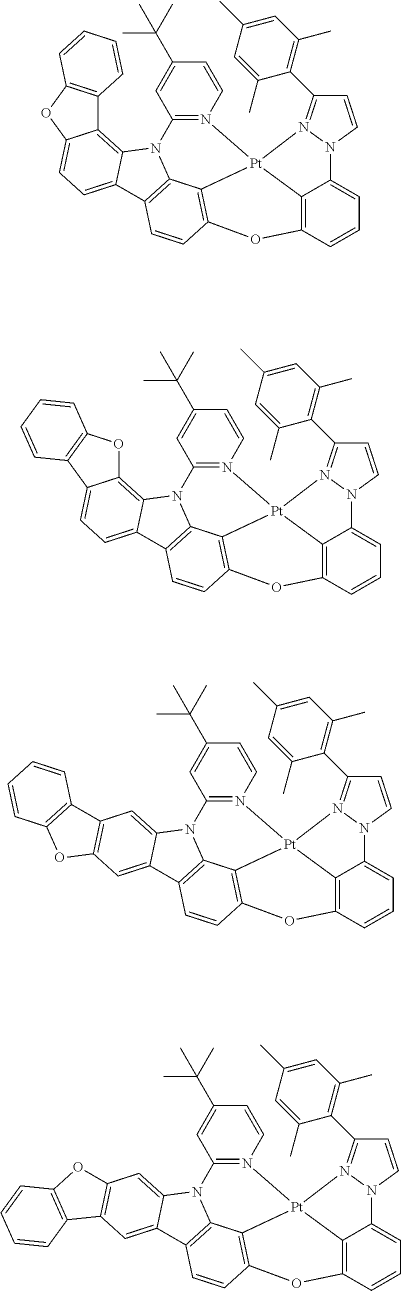

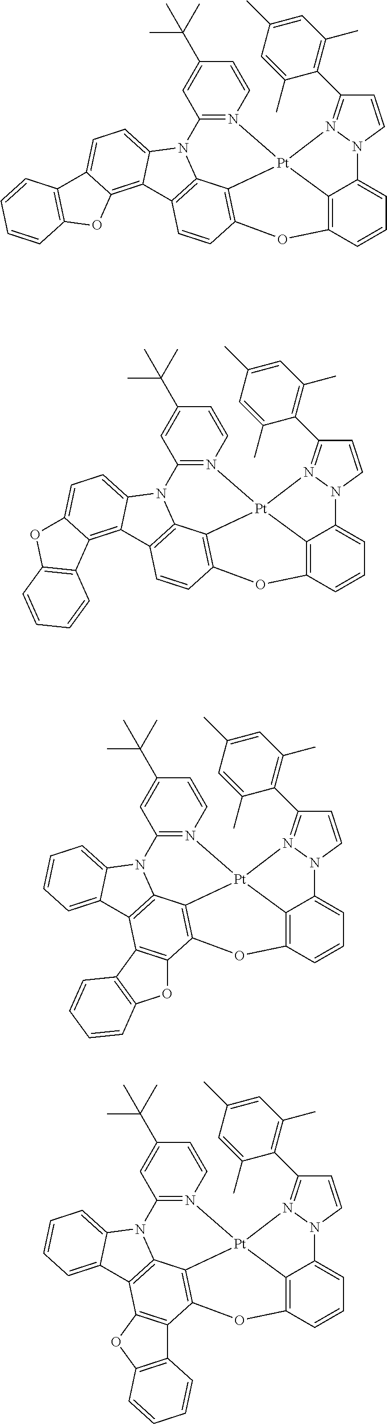

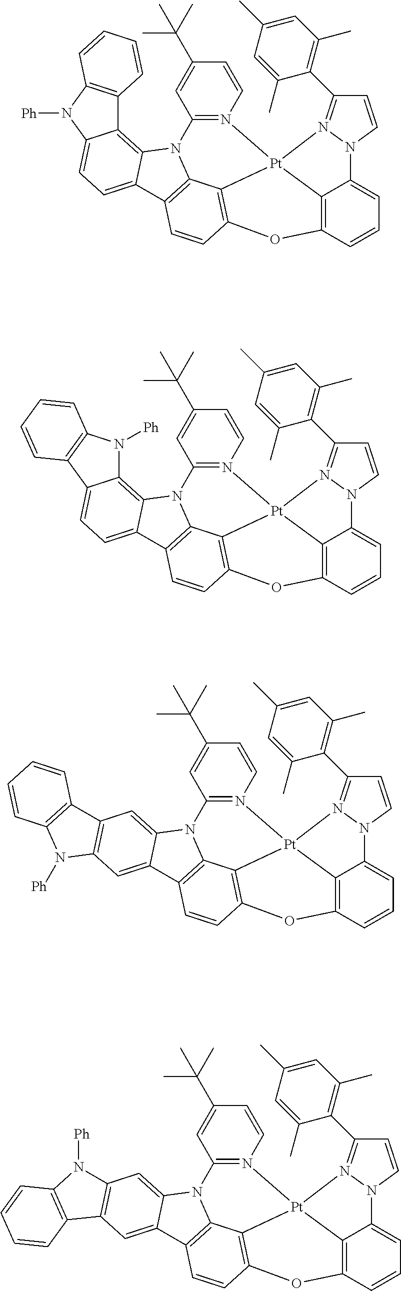

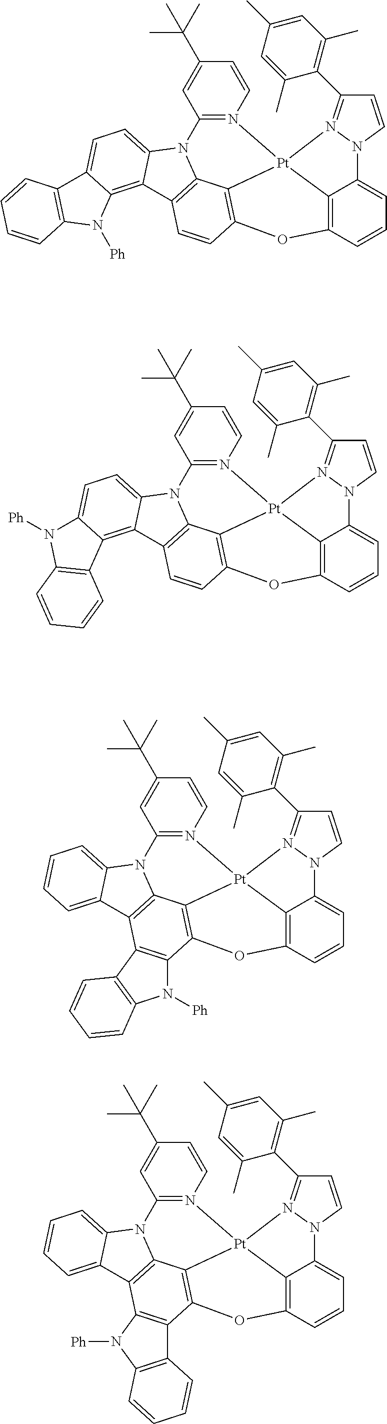

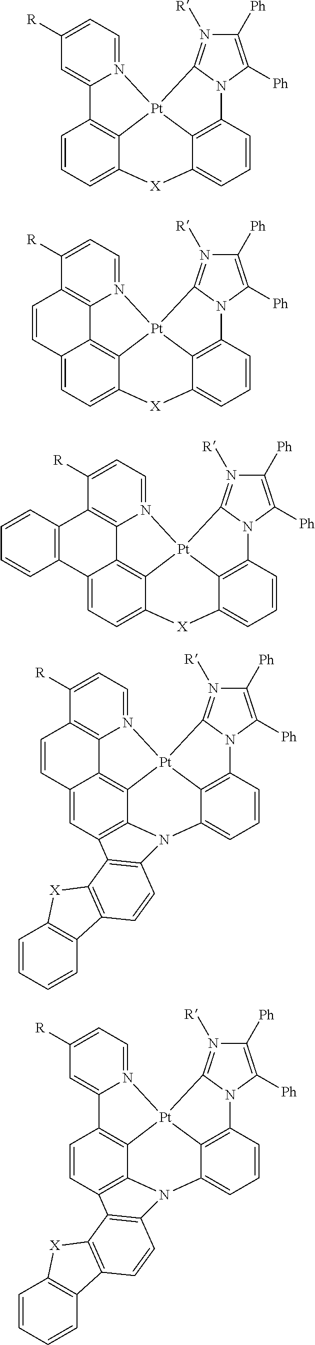

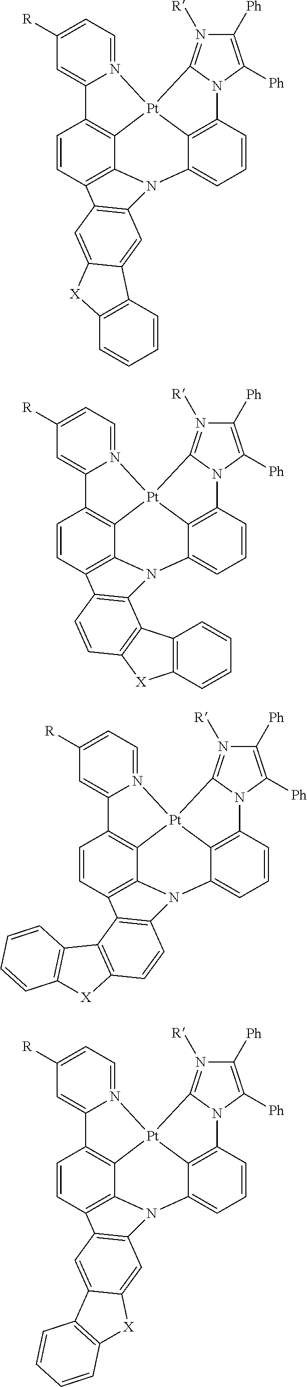

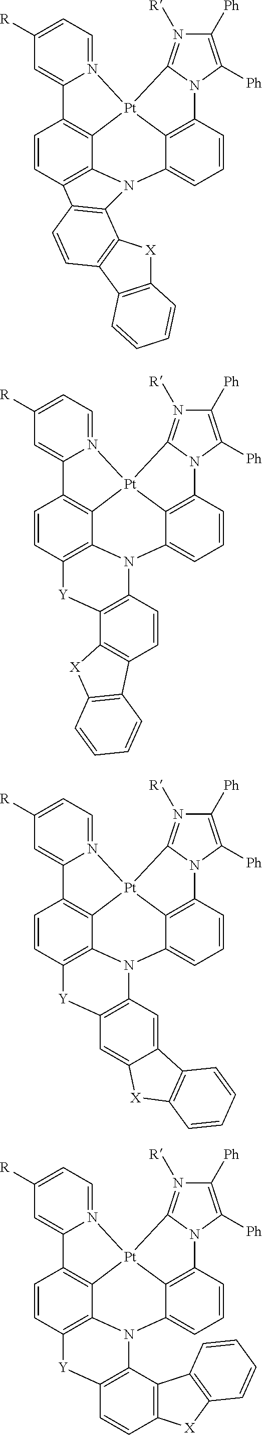

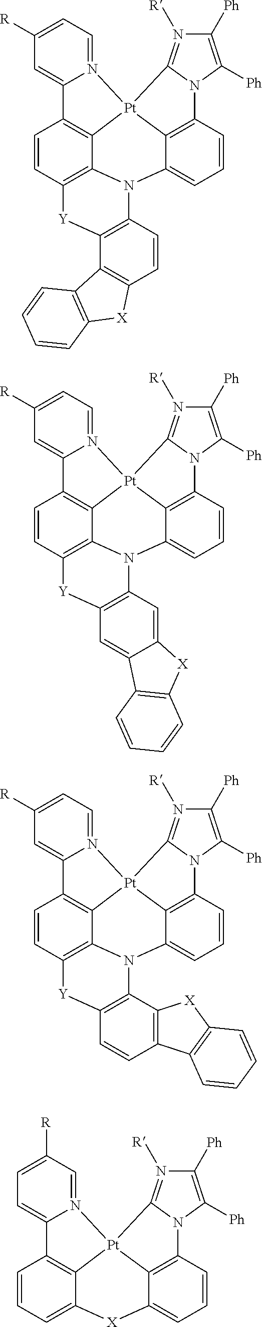

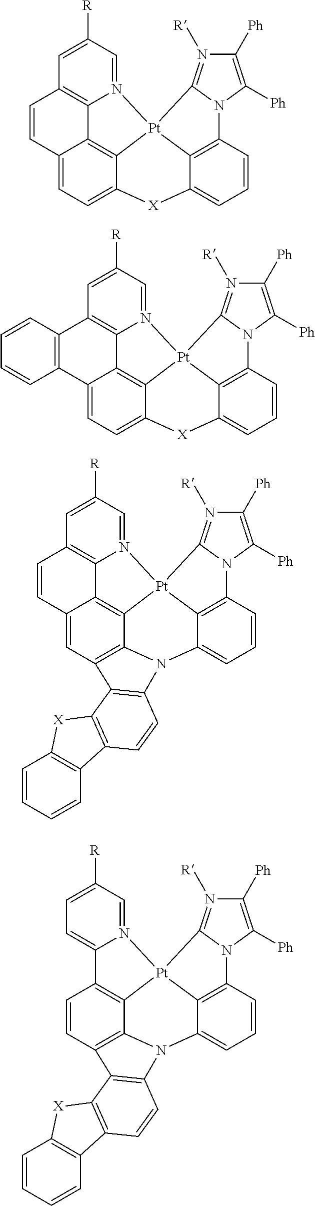

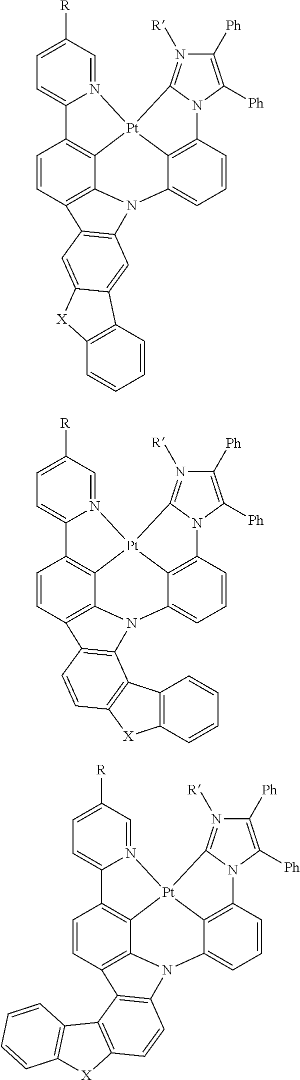

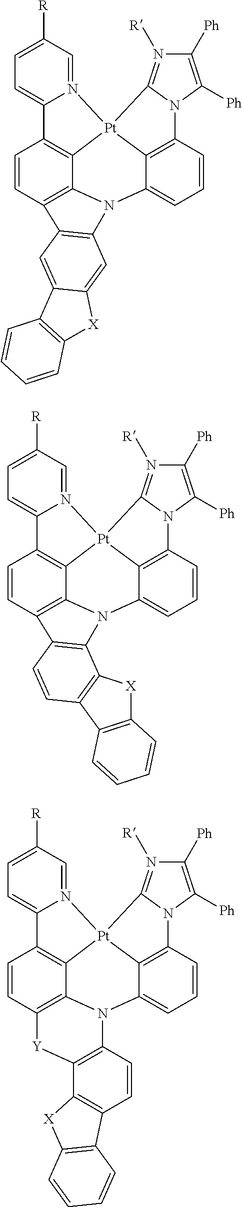

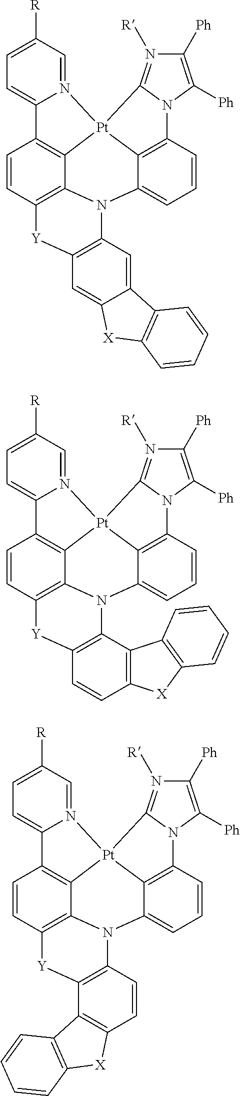

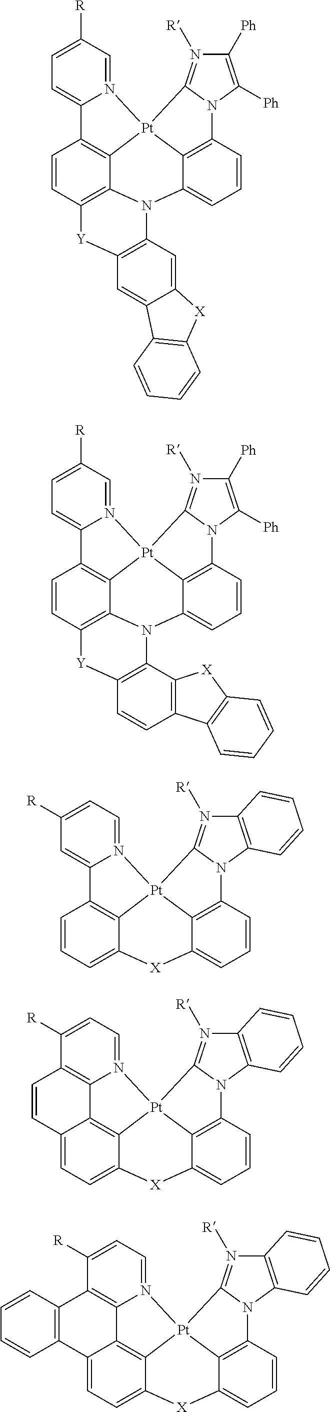

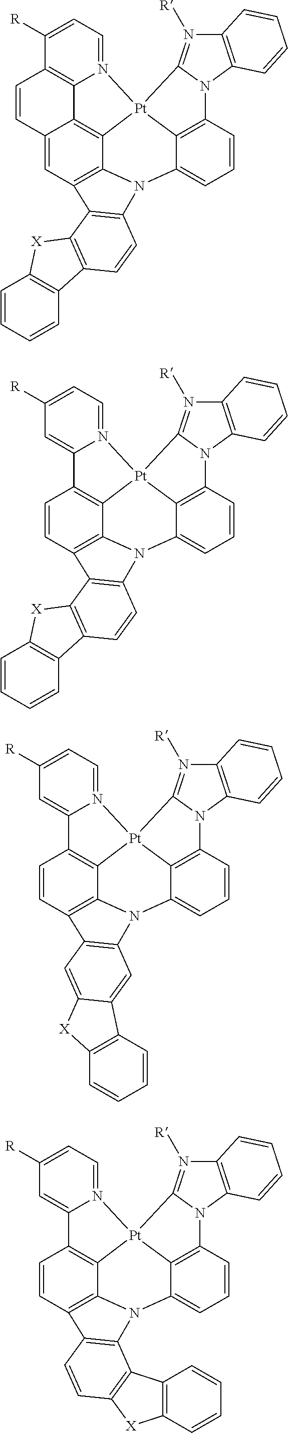

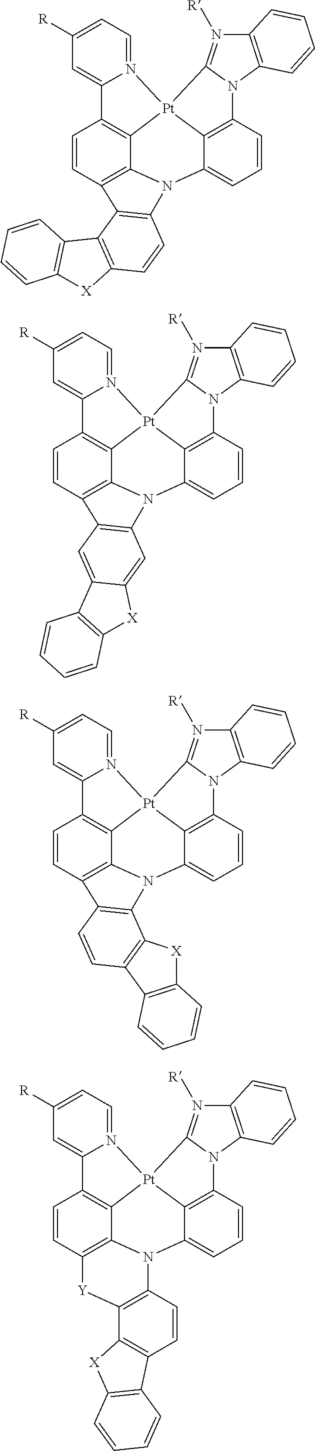

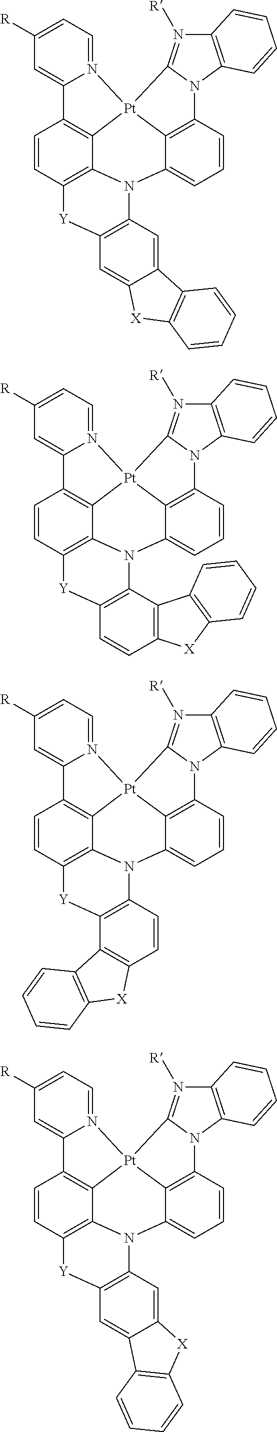

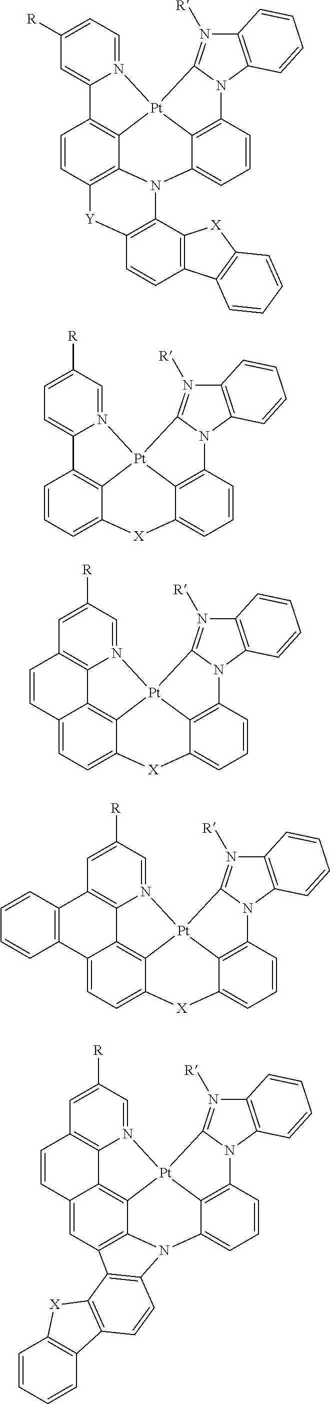

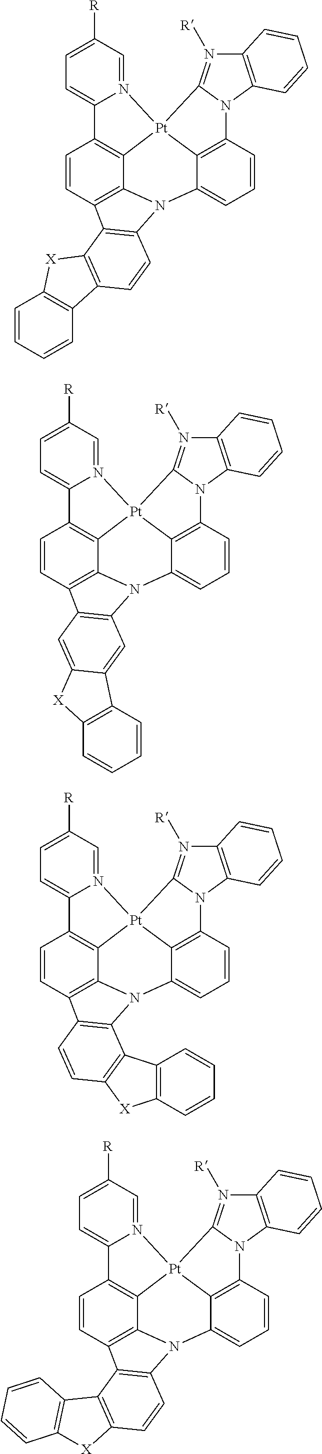

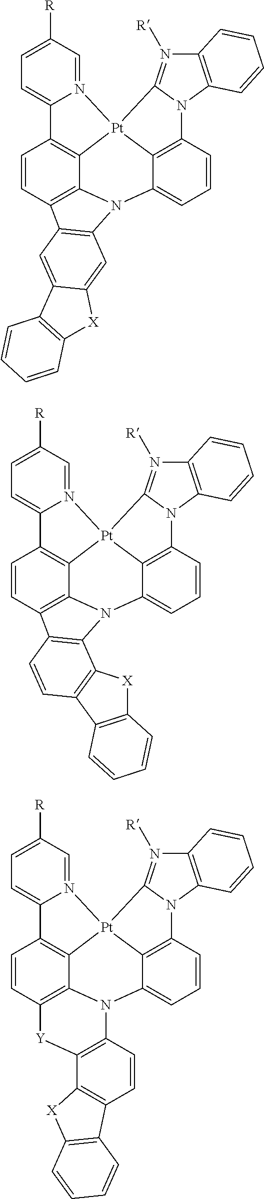

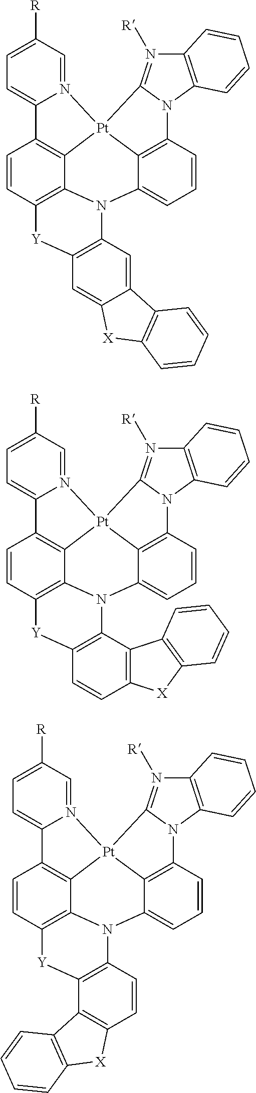

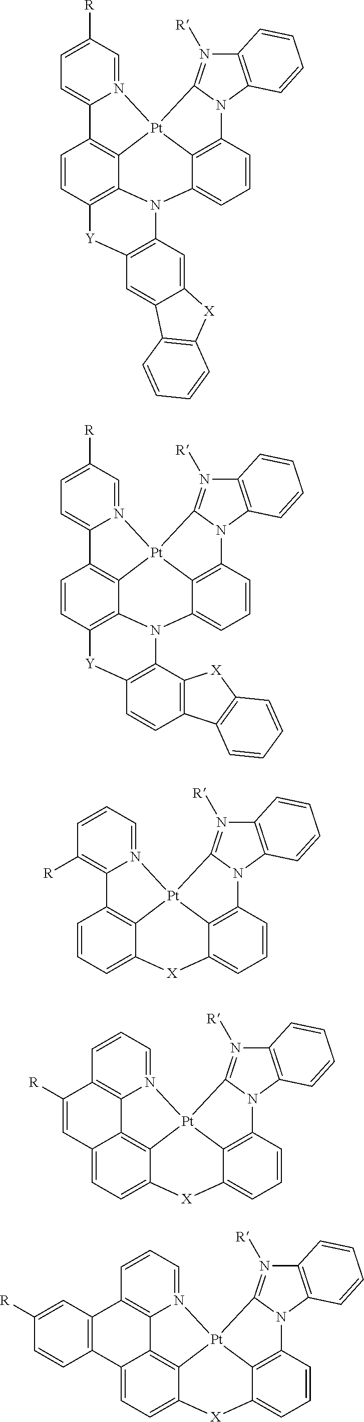

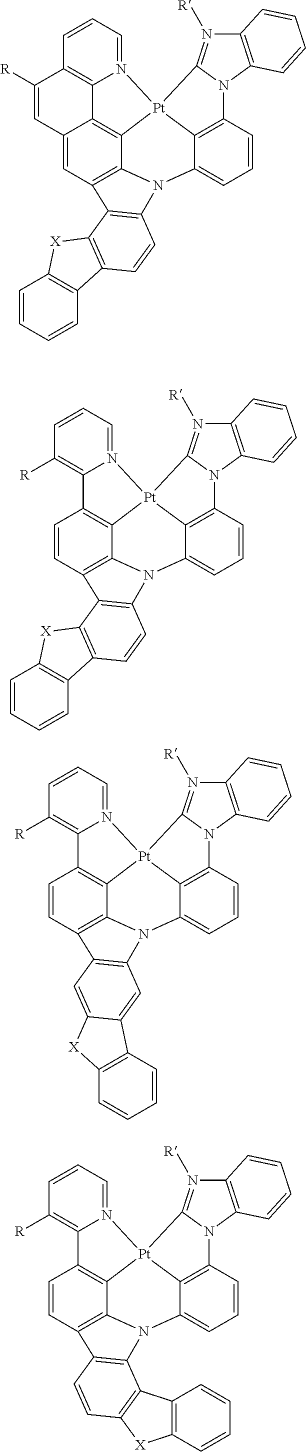

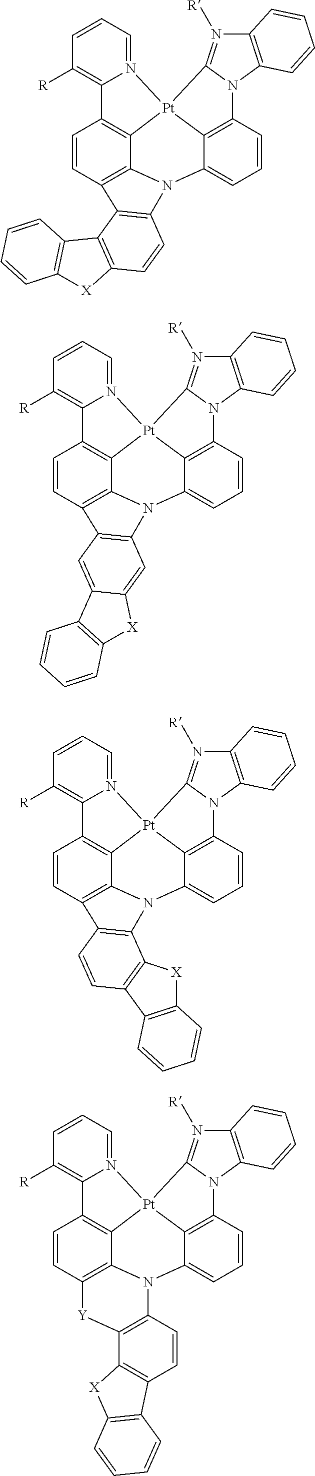

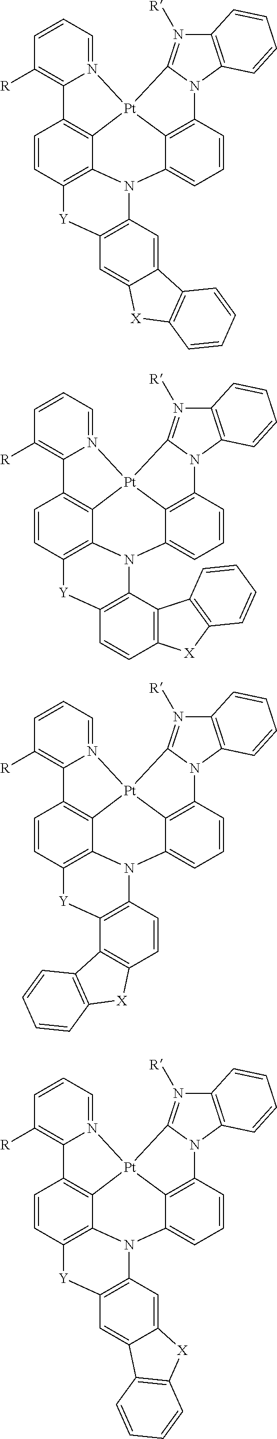

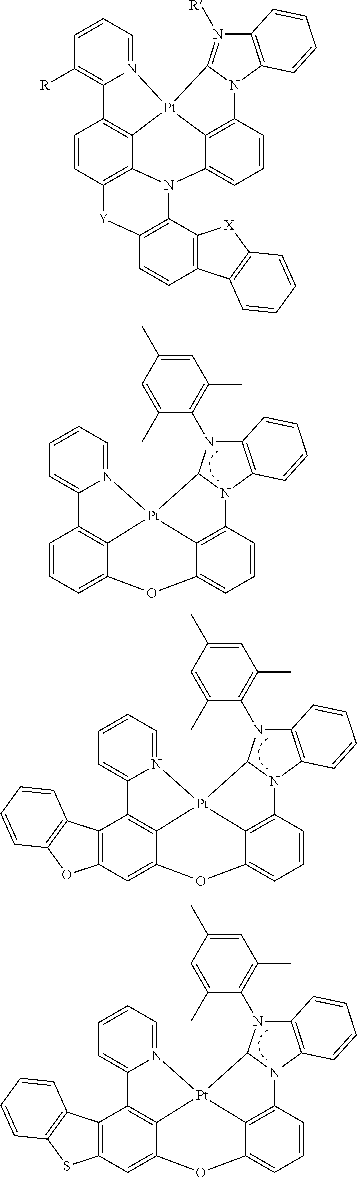

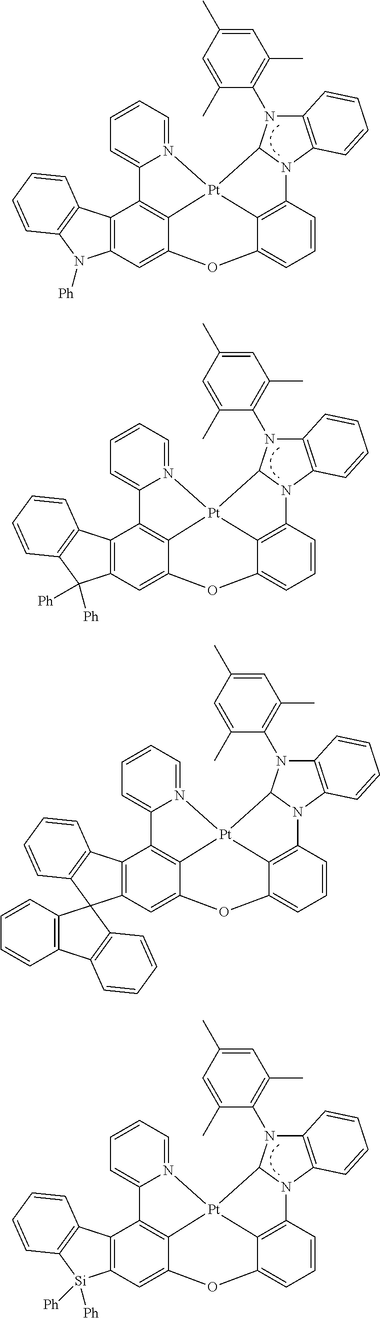

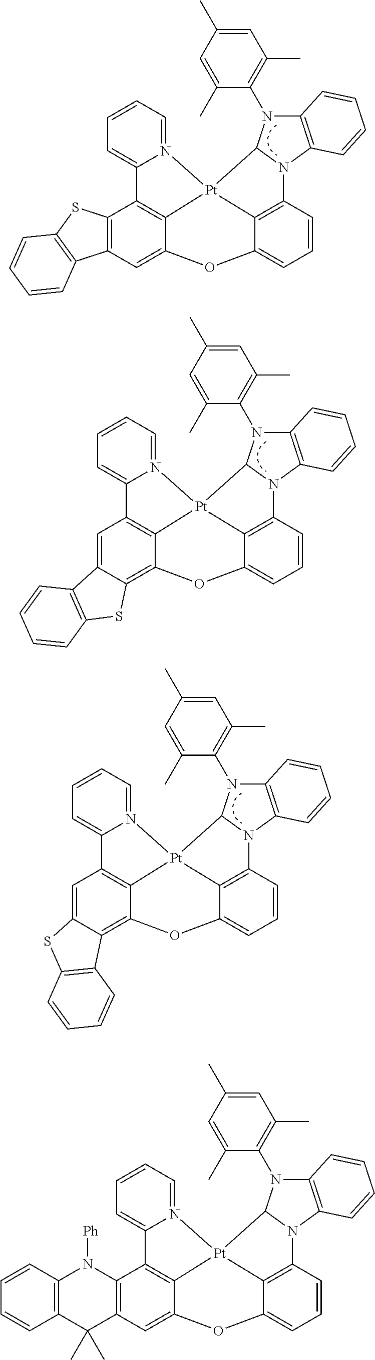

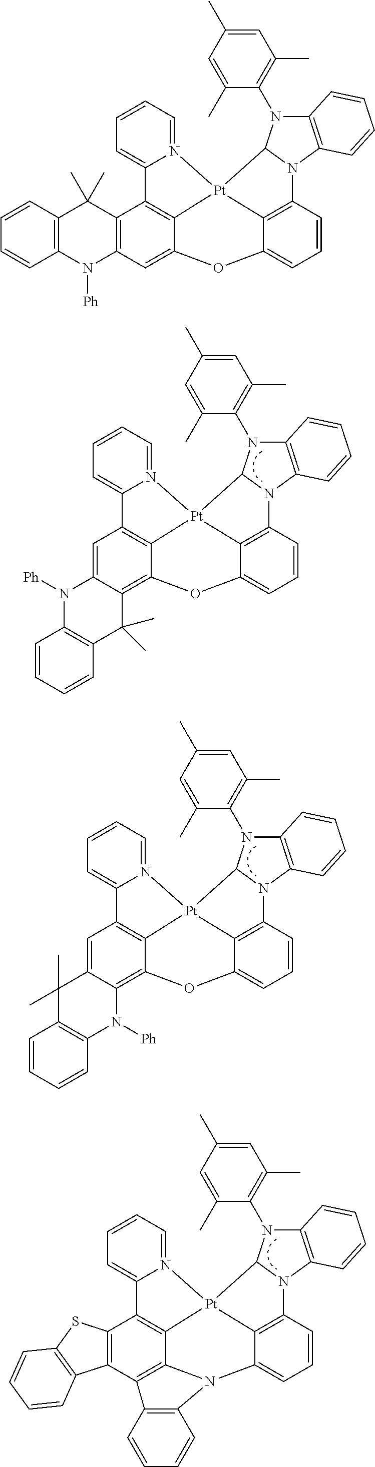

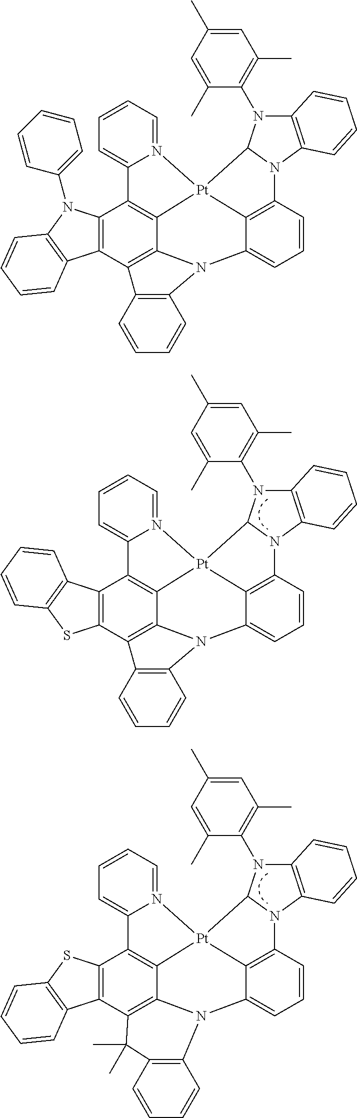

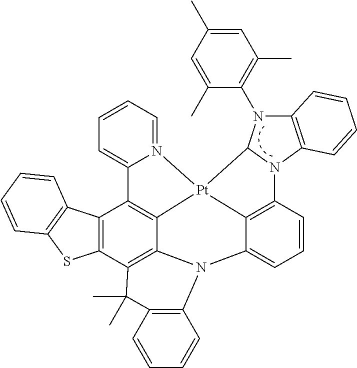

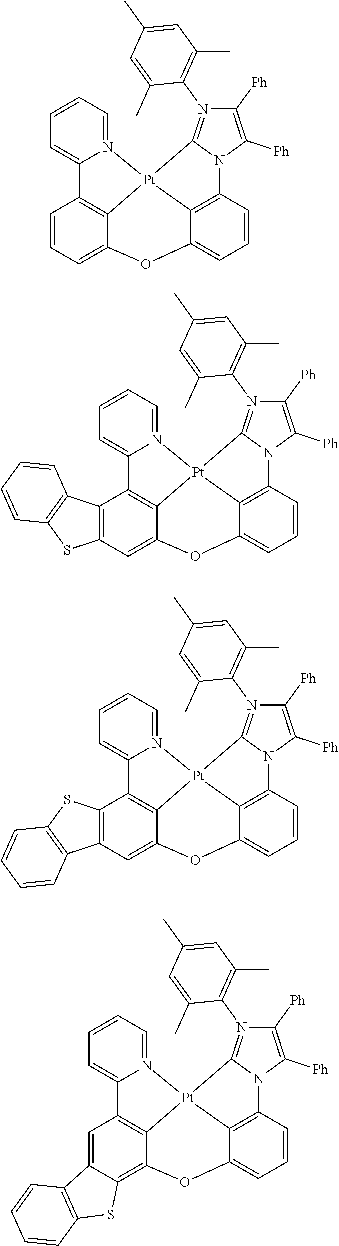

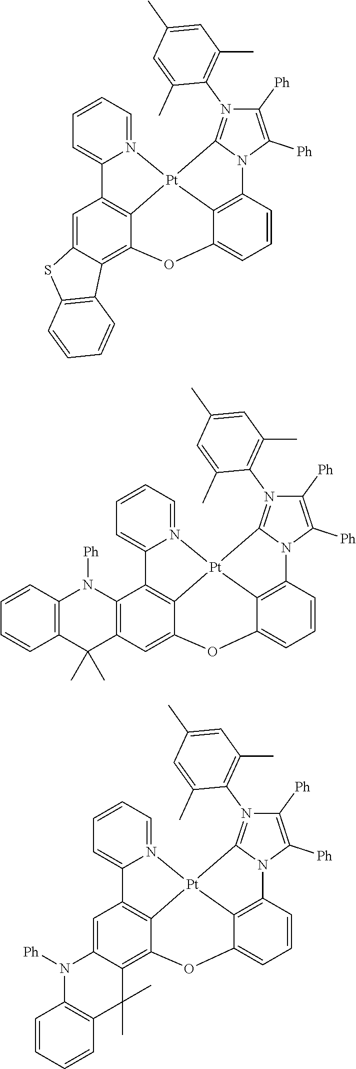

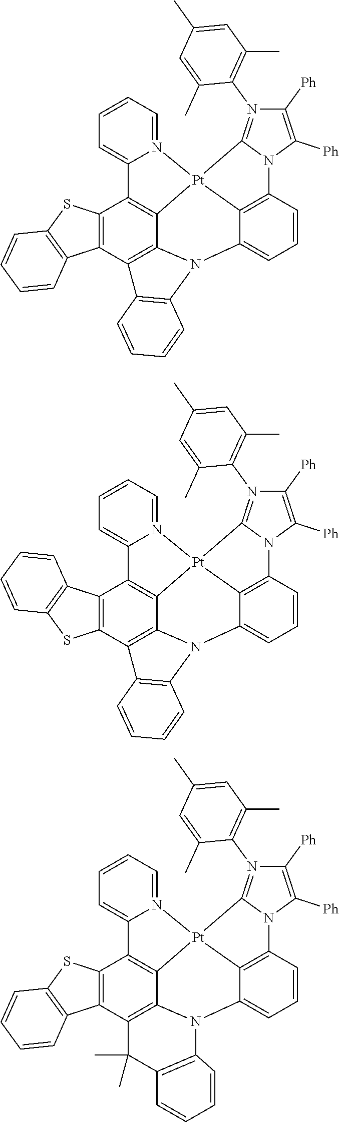

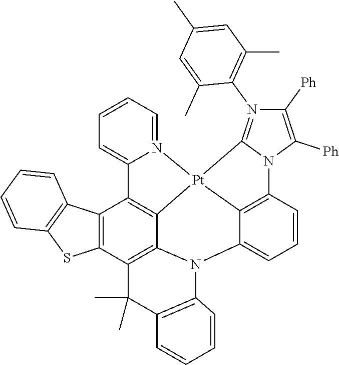

wherein each occurrence of R is methyl, isopropyl. t-butyl, phenyl and their analogs;
each occurrence of R′ is methyl, isopropyl, t-butyl,

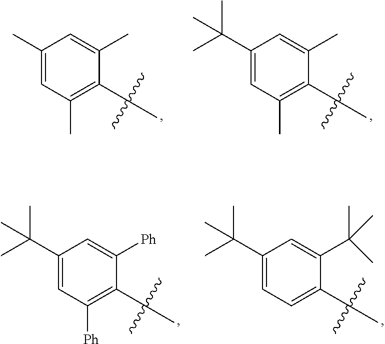

and their analogs;

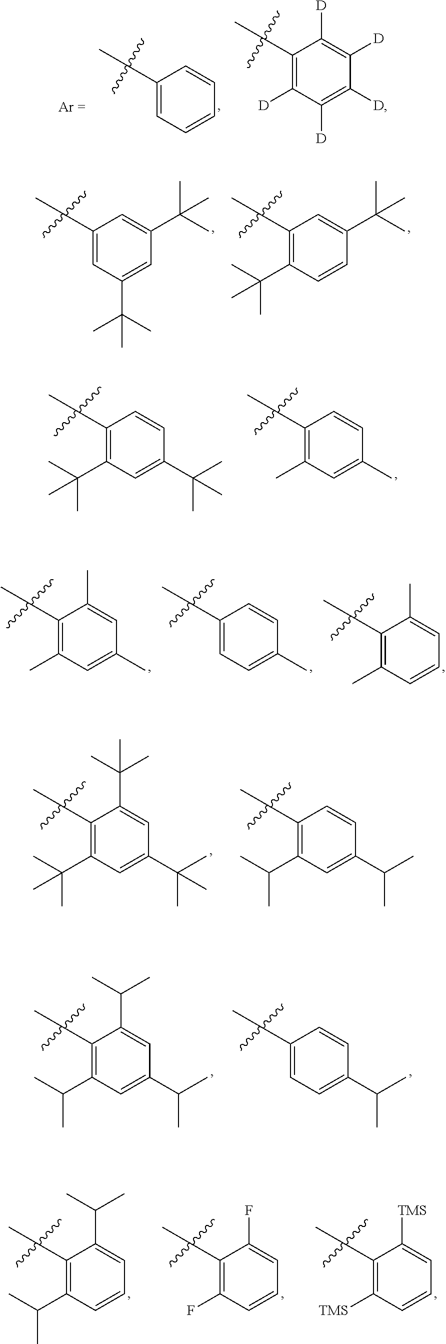

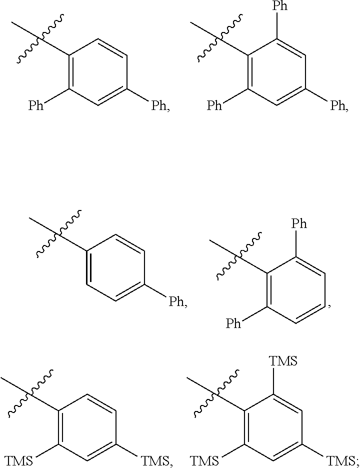

X is O, S, N—R¹, Si(R¹)R², C(R¹)R²,

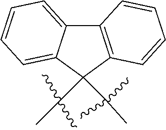 [SMILES: *C1(*)c2ccccc2-c2ccccc21]

and their analogs; and
Y is O, S, N—R¹, Si(R¹)R², C(R¹)R²,

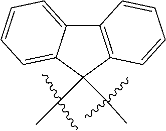 [SMILES: *C1(*)c2ccccc2-c2ccccc21]

and their analogs.

In one embodiment, the compound is represented by one of the following structures, which together represent LIST 11A:

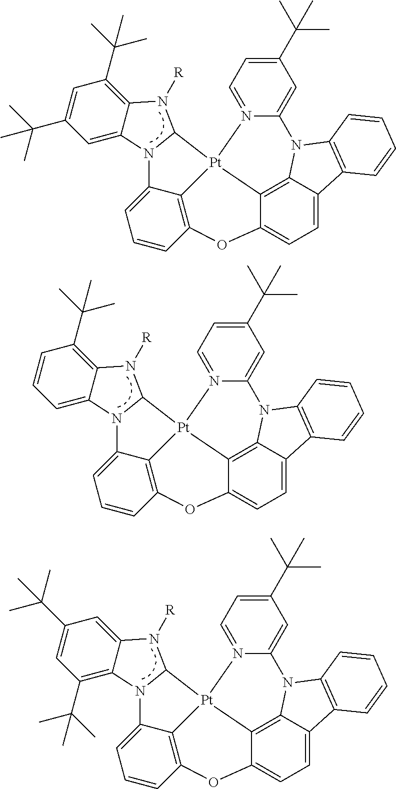

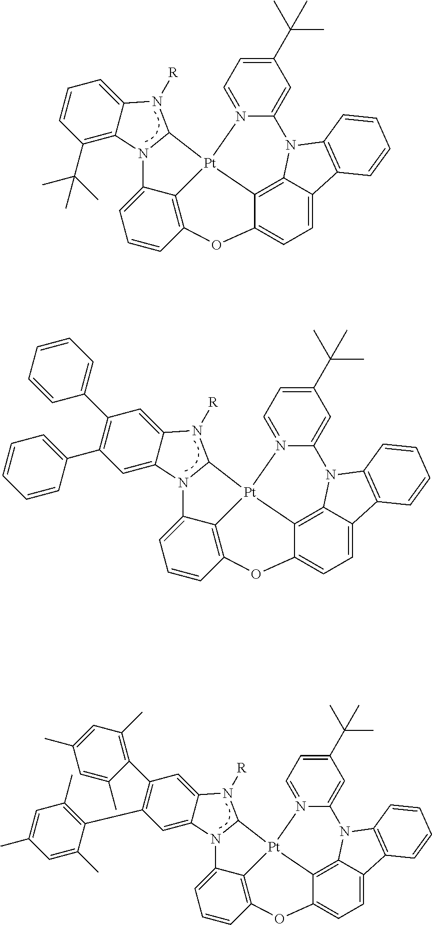

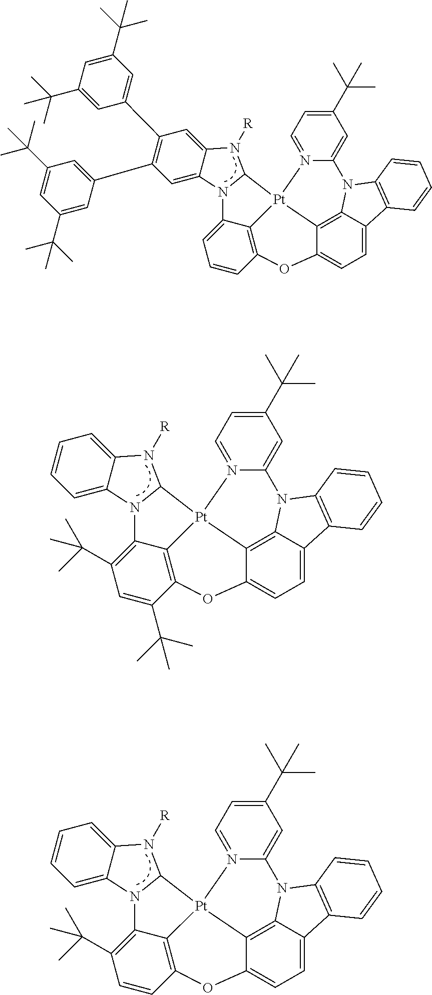

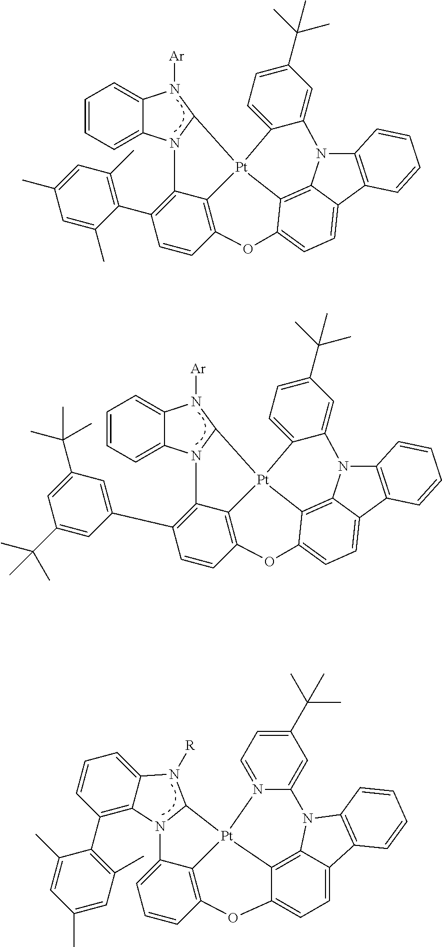

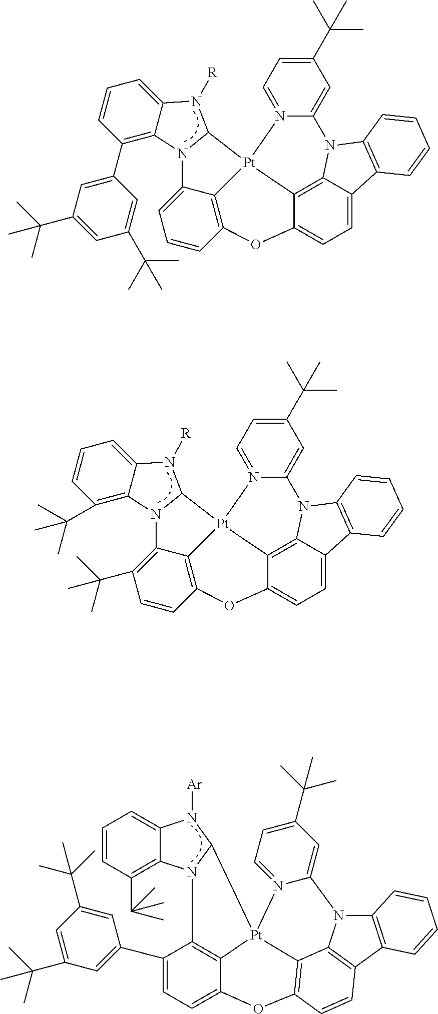

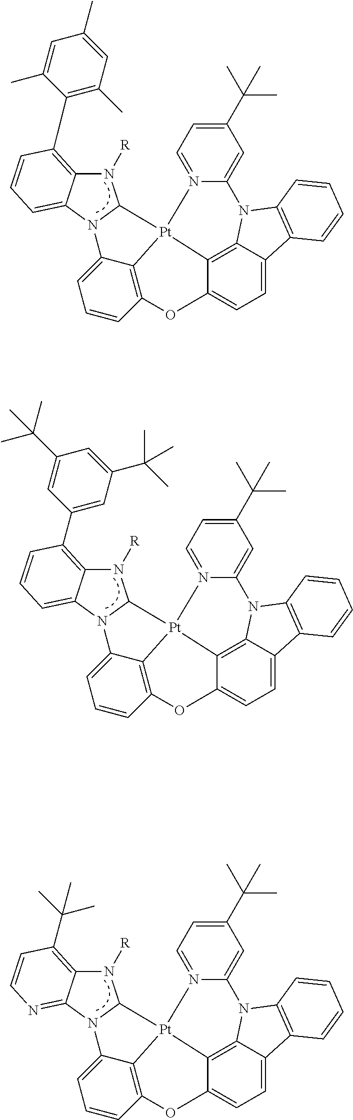

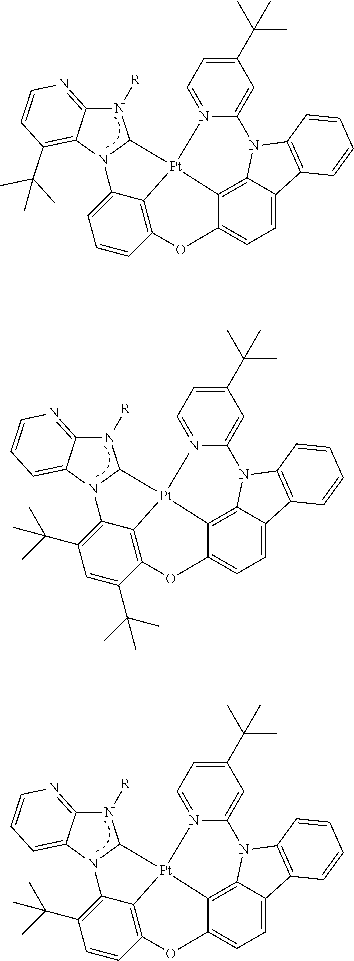

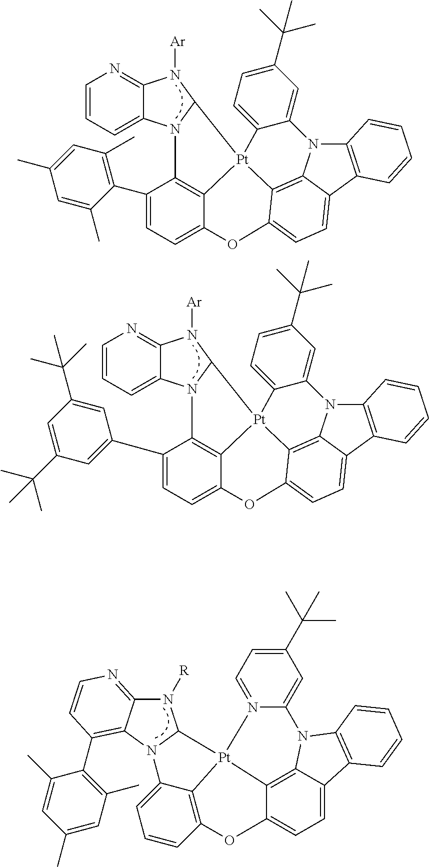

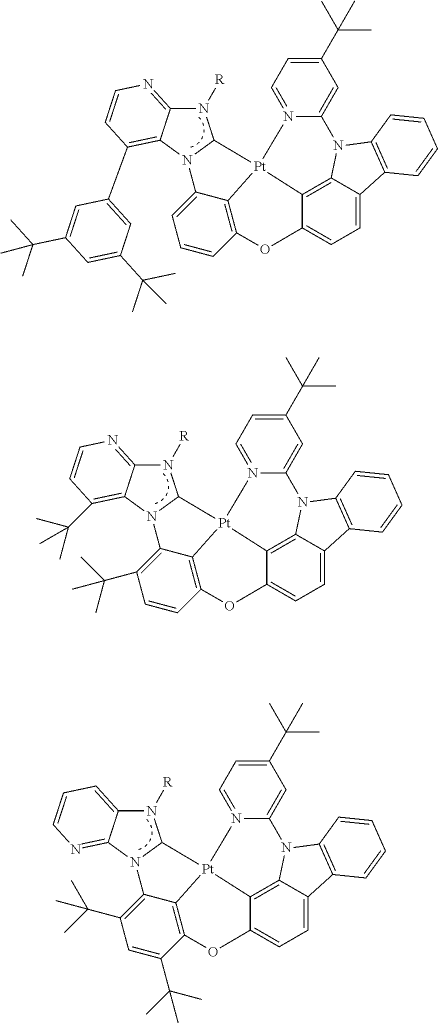

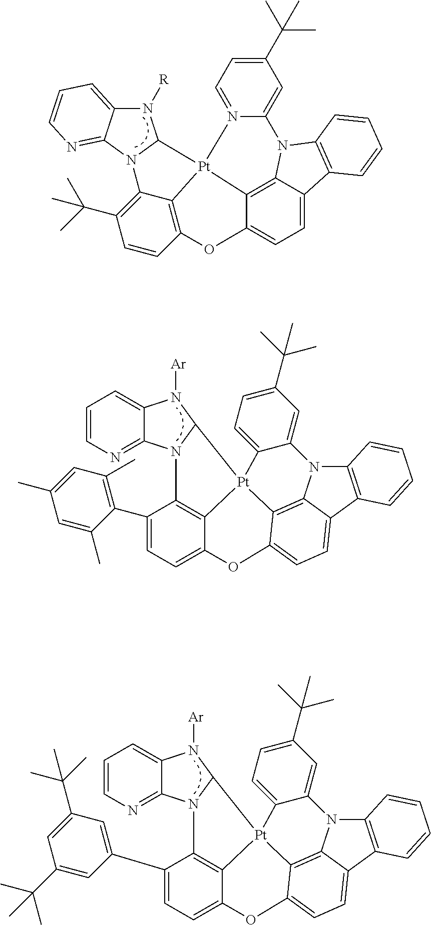

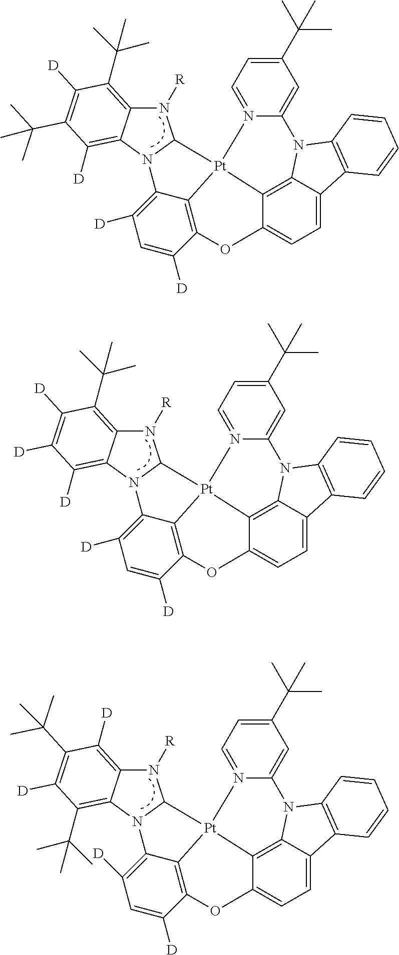

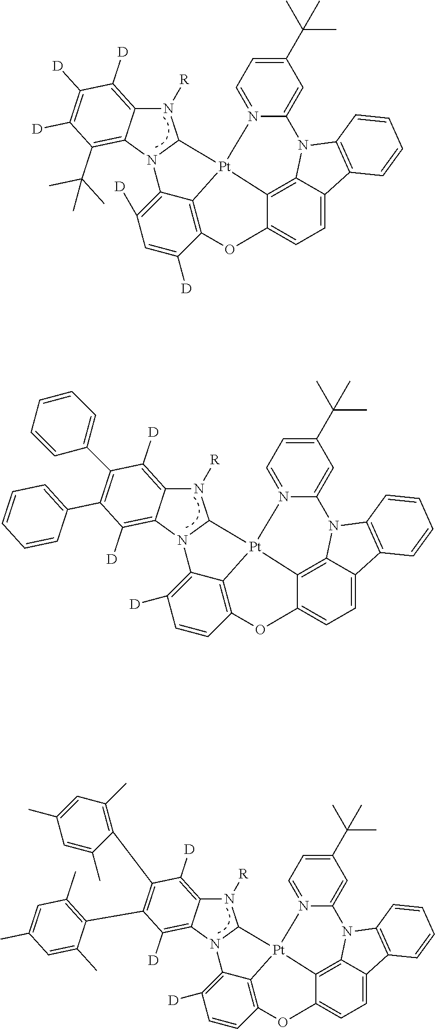

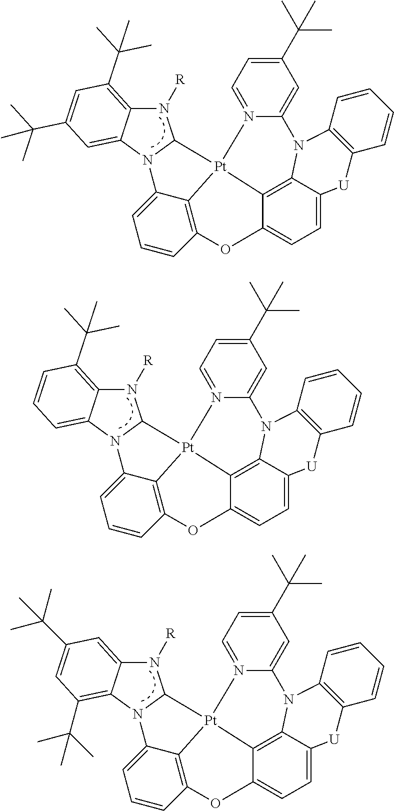

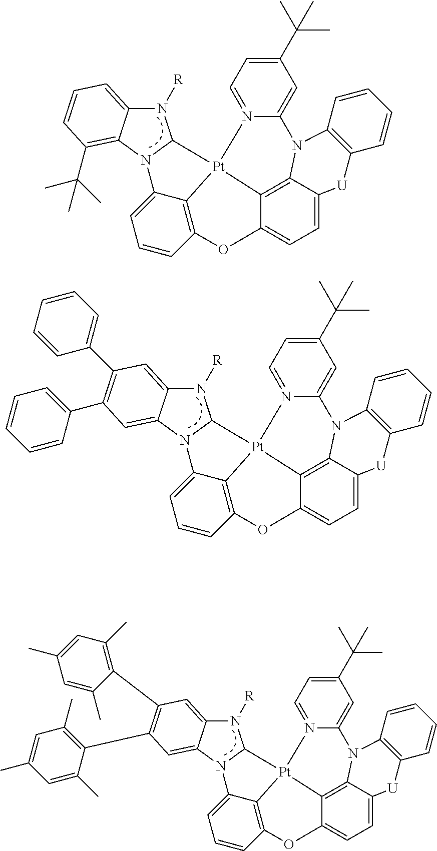

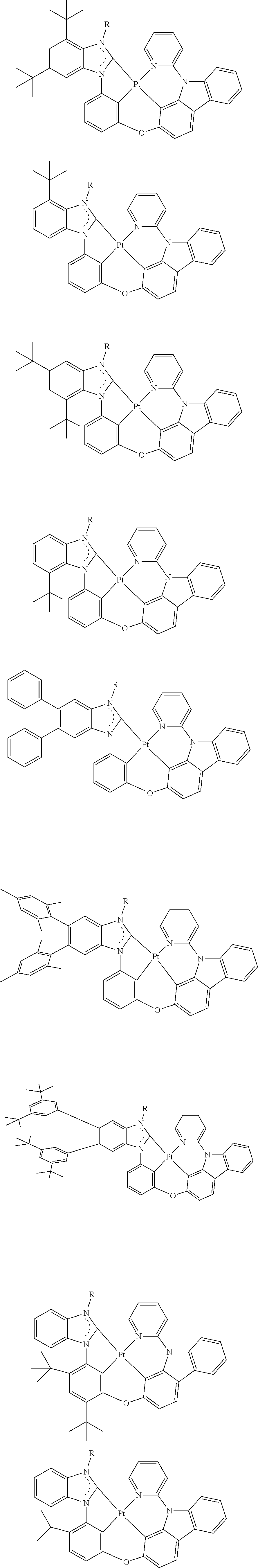

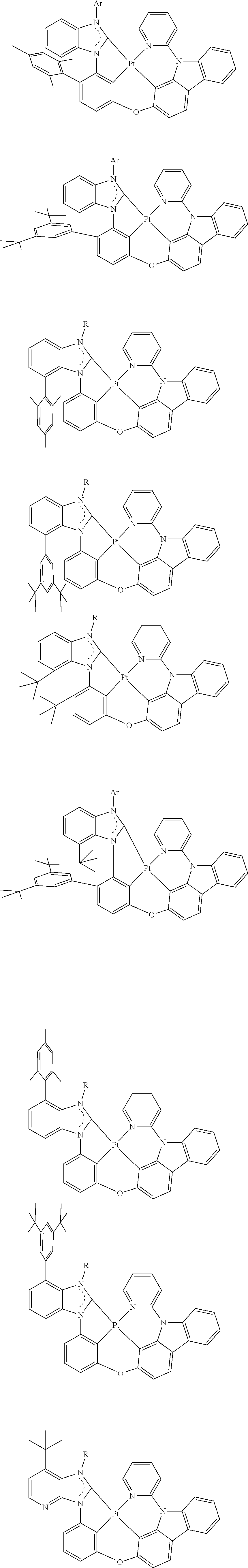

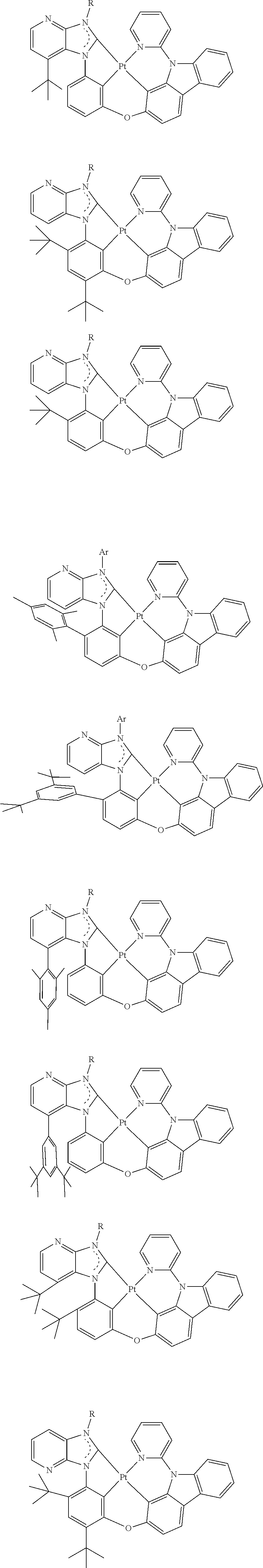

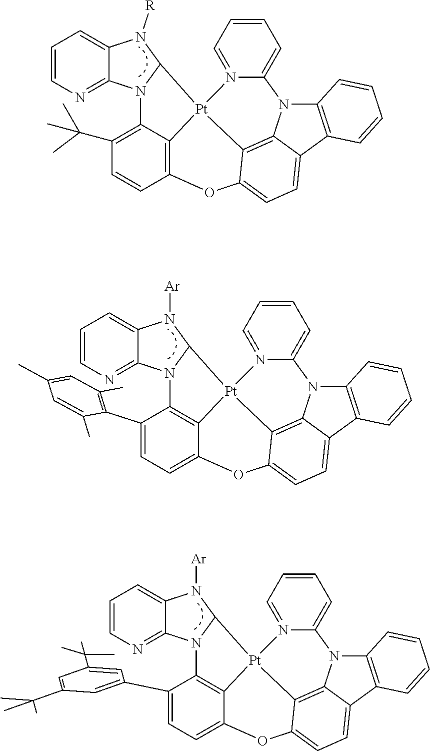

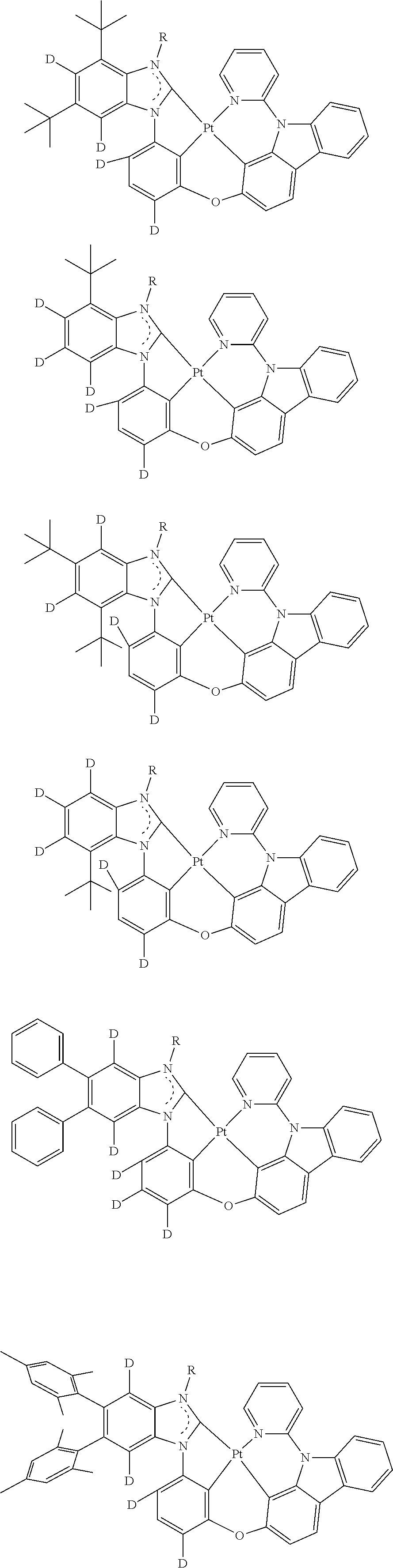

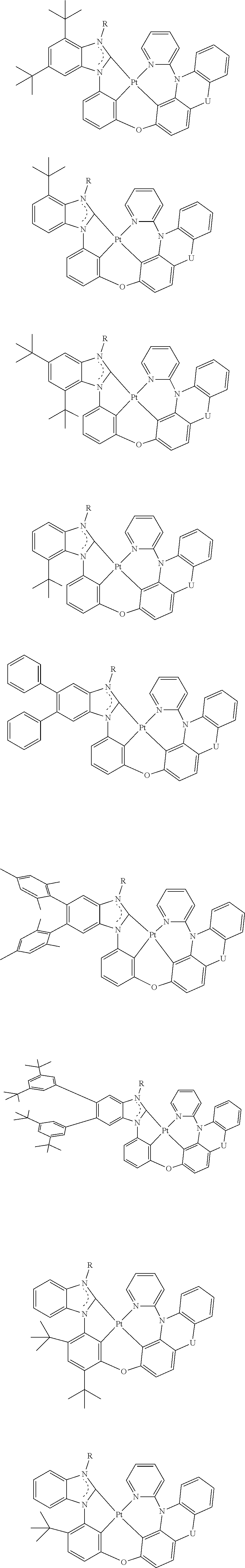

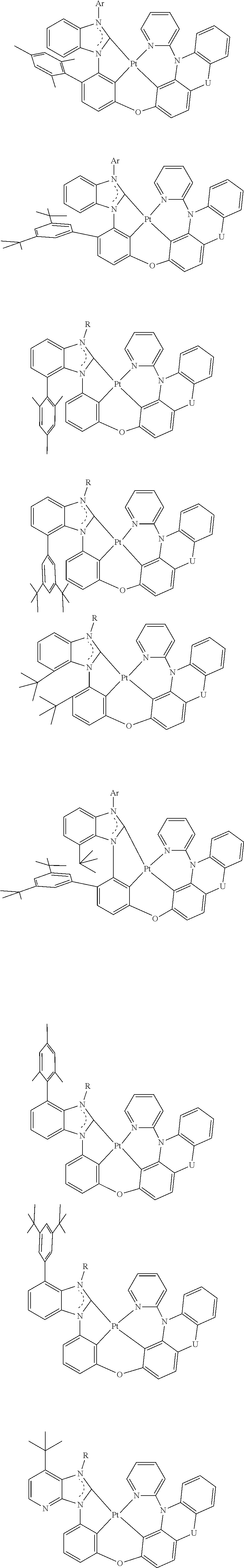

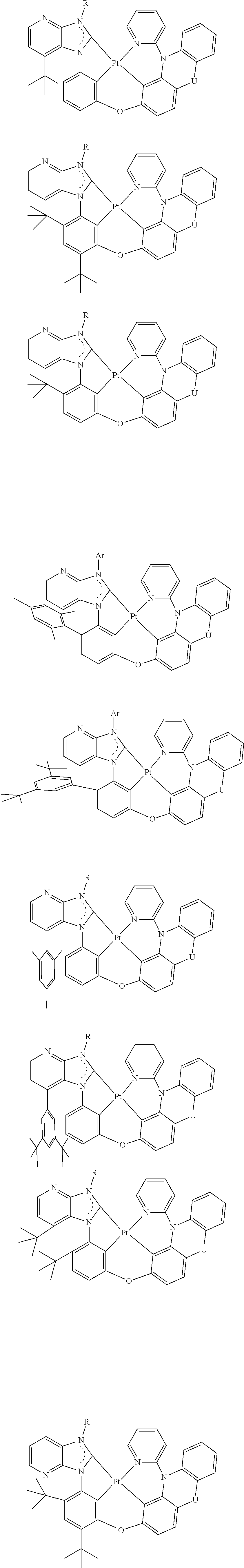

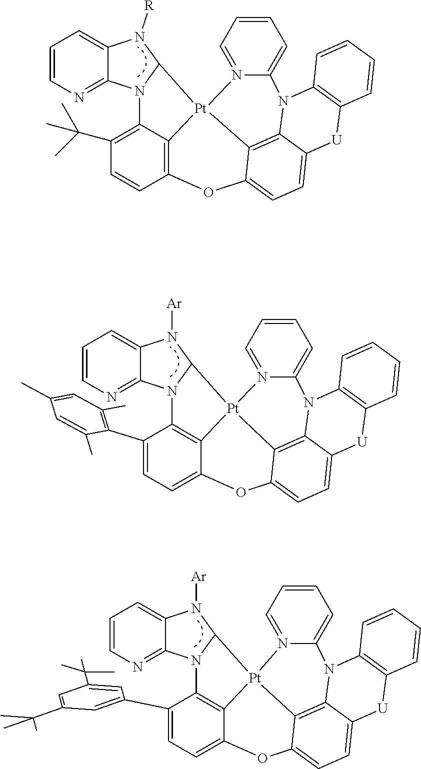

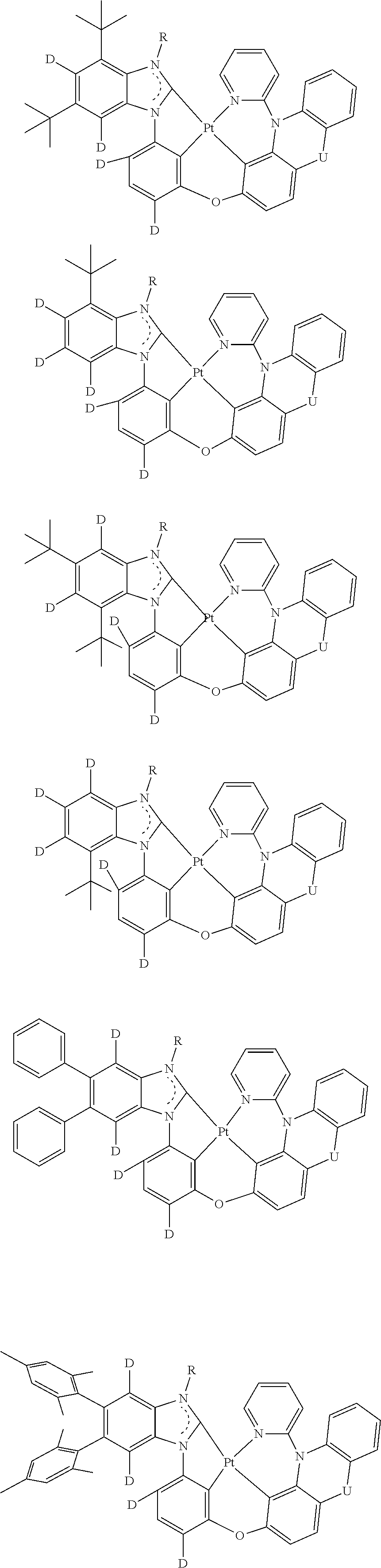

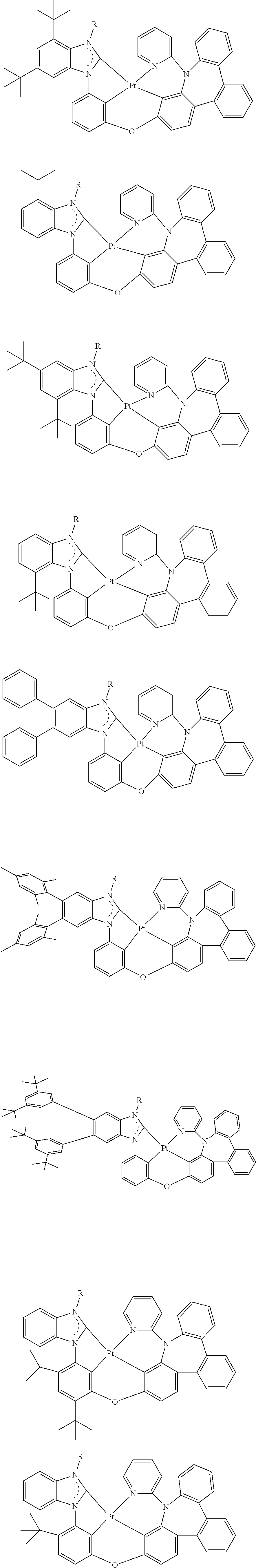

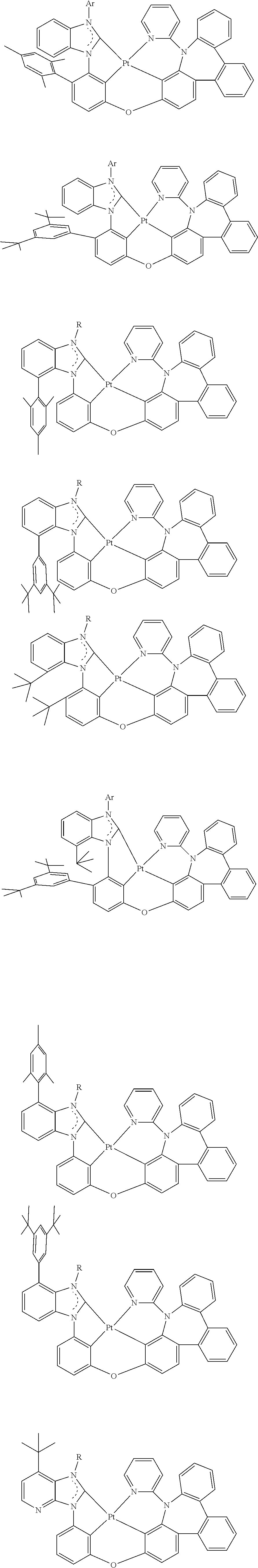

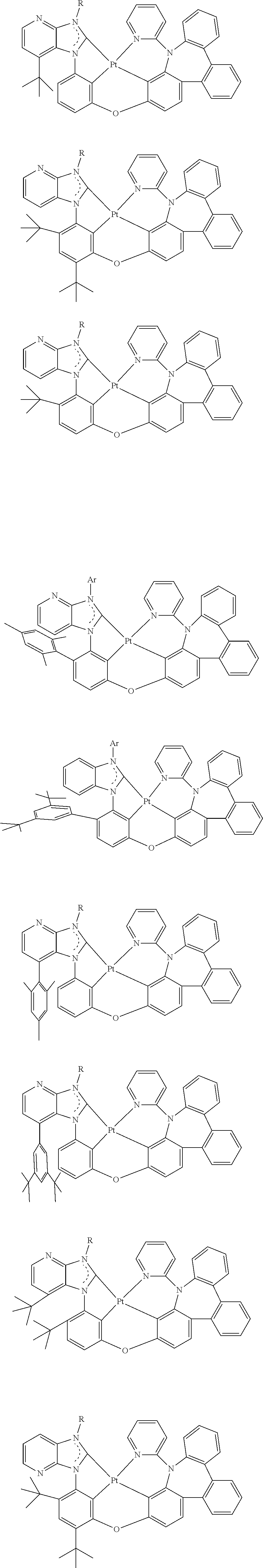

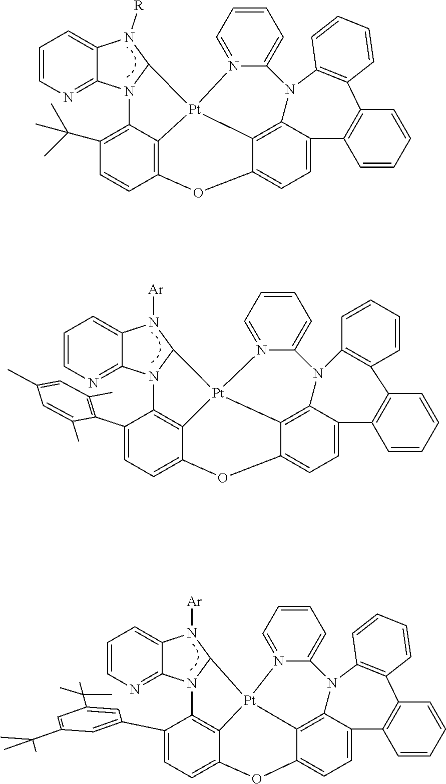

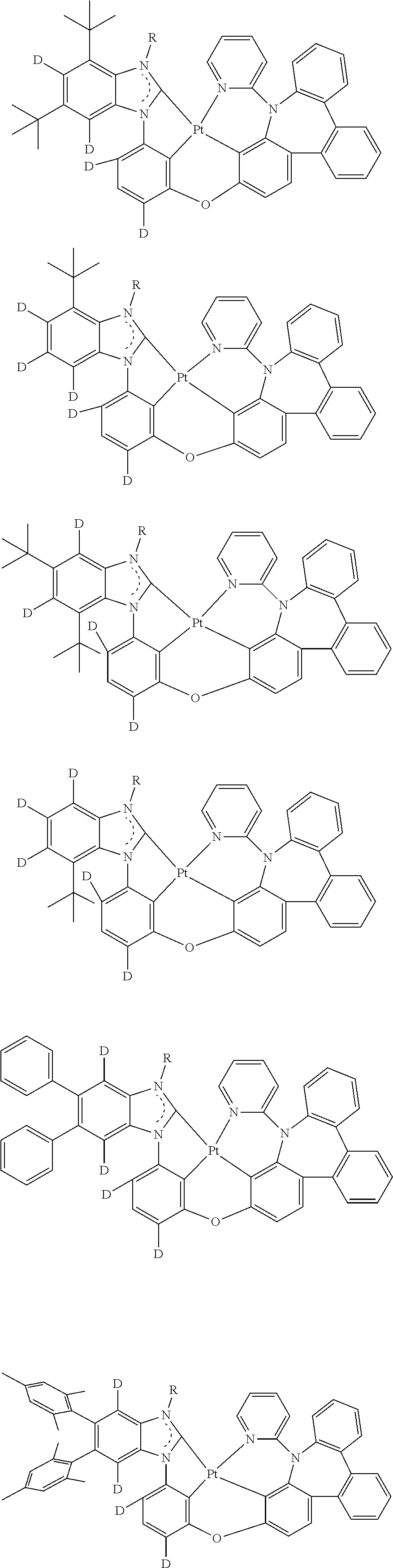

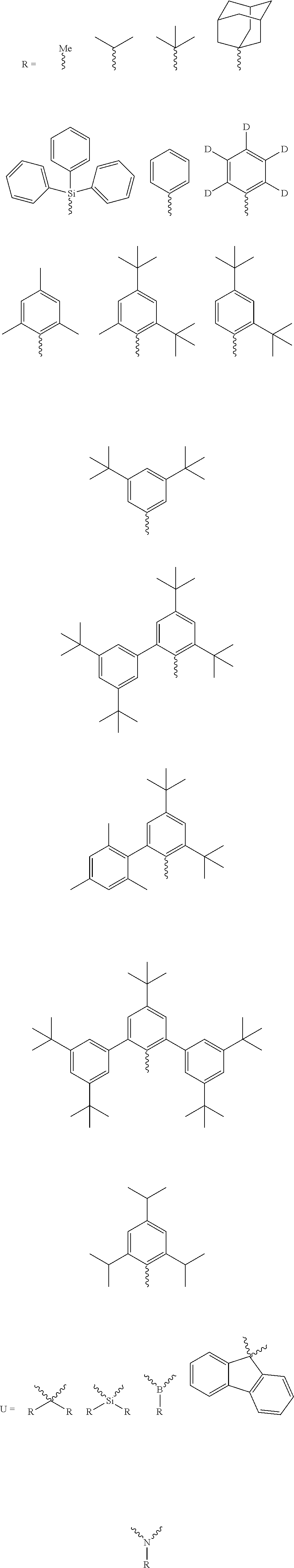

### Compositions and Devices of the Invention

Also disclosed herein are organic emitting diodes or organic light emitting devices comprising one or more compound and/or compositions disclosed herein.

In one embodiment, the device comprises an anode; a cathode; and at least one organic layer, disposed between the anode and the cathode, comprising at least one compound disclosed herein.

In one embodiment, the device comprises a first emissive layer comprising one or more phosphorescent or fluorescent emitters and a second emissive layer comprising one or more phosphorescent or fluorescent emitters; wherein the first emissive layer is disposed between the anode and the second emissive layer; and wherein the second emissive layer is disposed between the first emissive layer and the cathode.

In one aspect, the device is an electro-optical device. Electro-optical devices include, but are not limited to, photo-absorbing devices such as solar- and photo-sensitive devices, organic light emitting devices, photo-emitting devices, or devices capable of both photo-absorption and emission and as markers for bio-applications. For example, the device can be an OLED.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art. Such devices are disclosed herein which comprise one or more of the compounds or compositions disclosed herein.

In one embodiment, the device is a white OLED. In one embodiment, the device emits amber light and blue light, which when combined is received as white light. In one embodiment, the color (i.e., warmth) of the white light can be adjusted by varying the thickness and concentration of the various emissive layers.

OLEDs can be produced by methods known to those skilled in the art. In general, the OLED is produced by successive vapor deposition of the individual layers onto a suitable substrate. Suitable substrates include, for example, glass, inorganic materials such as ITO or IZO or polymer films. For the vapor deposition, customary techniques may be used, such as thermal evaporation, chemical vapor deposition (CVD), physical vapor deposition (PVD) and others.

In an alternative process, the organic layers may be coated from solutions or dispersions in suitable solvents, in which case coating techniques known to those skilled in the art are employed. Suitable coating techniques are, for example, spin-coating, the casting method, the Langmuir-Blodgett (“LB”) method, the inkjet printing method, dip-coating, letterpress printing, screen printing, doctor blade printing, slit-coating, roller printing, reverse roller printing, offset lithography printing, flexographic printing, web printing, spray coating, coating by a brush or pad printing, and the like. Among the processes mentioned, in addition to the aforementioned vapor deposition, preference is given to spin-coating, the inkjet printing method and the casting method since they are particularly simple and inexpensive to perform. In the case that layers of the OLED are obtained by the spin-coating method, the casting method or the inkjet printing method, the coating can be obtained using a solution prepared by dissolving the composition in a concentration of 0.0001 to 90% by weight in a suitable organic solvent such as benzene, toluene, xylene, tetrahydrofuran, methyltetrahydrofuran, N,N-dimethylformamide, acetone, acetonitrile, anisole, dichloromethane, dimethyl sulfoxide, water and mixtures thereof.

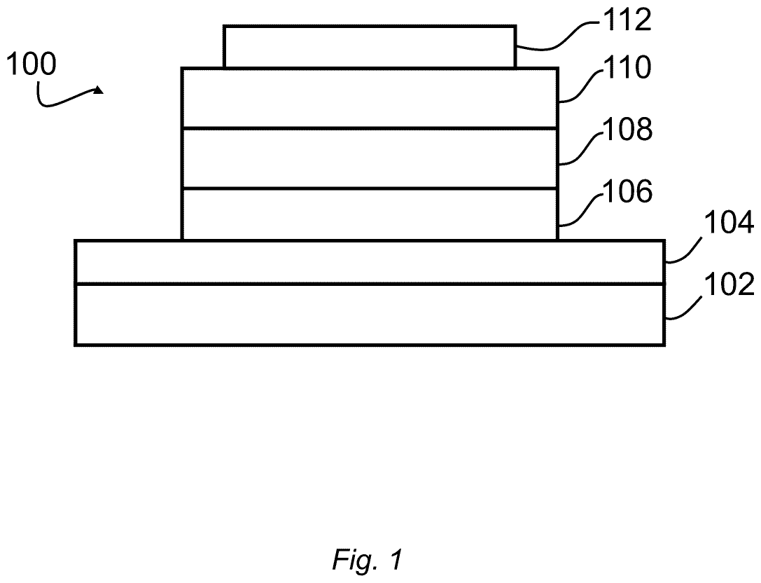

Compounds described herein can be used in a light emitting device such as an OLED. FIG. 1 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′ diamine (NPD), 1,1-bis((di-4-tolylamino)phenyl)cyclohexane (TAPC), 2,6-Bis(N-carbazolyl)pyridine (mCpy), 2,8-bis(diphenylphosphoryl) dibenzothiophene (PO15), LiF, Al, or a combination thereof.

Light processing material 108 may include one or more compounds of the present disclosure optionally together with a host material. The host material can be any suitable host material known in the art. The emission color of an OLED is determined by the emission energy (optical energy gap) of the light processing material 108, which can be tuned by tuning the electronic structure of the emitting compounds, the host material, or both. Both the hole-transporting material in the HTL layer 106 and the electron-transporting material(s) in the ETL layer 110 may include any suitable hole-transporter known in the art.

Compounds described herein may exhibit phosphorescence. Phosphorescent OLEDs (i.e., OLEDs with phosphorescent emitters) typically have higher device efficiencies than other OLEDs, such as fluorescent OLEDs. Light emitting devices based on electrophosphorescent emitters are described in more detail in WO2000/070655 to Baldo et al., which is incorporated herein by this reference for its teaching of OLEDs, and in particular phosphorescent OLEDs.

As contemplated herein, an OLED of the present invention may include an anode, a cathode, and an organic layer disposed between the anode and the cathode. The organic layer may include a host and a phosphorescent dopant. The organic layer can include a compound of the invention and its variations as described herein.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In one embodiment, the consumer product is selected from the group consisting of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, and a sign.

In some embodiments of the emissive region, the emissive region further comprises a host, wherein the host comprises at least one selected from the group consisting of metal complex, triphenylene, carbazole, dibenzothiophene, dibenzofuran, dibenzoselenophene, aza-triphenylene, aza-carbazole, aza-dibenzothiophene, aza-dibenzofuran, and aza-dibenzoselenophene.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be a triphenylene containing benzo-fused thiophene or benzo-fused furan. Any substituent in the host can be an unfused substituent independently selected from the group consisting of CₙH₂ₙ₊₁, OCₙH₂ₙ₊₁, OAr¹, N(CₙH₂ₙ₊₁)₂, N(Ar¹)(Ar²), CH═CH—CₙH₂ₙ₊₁, C≡C—CₙH₂ₙ₊₁, Ar¹, Ar¹—Ar², and CₙH₂ₙ—Ar¹, or the host has no substitutions. In the preceding substituents n can range from 1 to 10; and Ar¹ and Ar² can be independently selected from the group consisting of benzene, biphenyl, naphthalene, triphenylene, carbazole, and heteroaromatic analogs thereof. The host can be an inorganic compound. For example, a Zn containing inorganic material e.g. ZnS.

Suitable hosts may include, but are not limited to, mCP (1,3-bis(carbazol-9-yl)benzene), mCPy (2,6-bis(N-carbazolyl)pyridine), TCP (1,3,5-tris(carbazol-9-yl)benzene), TCTA (4,4′,4″-tris(carbazol-9-yl)triphenylamine), TPBi (1,3,5-tris(1-phenyl-1-H-benzimidazol-2-yl)benzene), mCBP (3,3-di(9H-carbazol-9-yl) biphenyl), pCBP (4,4′-bis(carbazol-9-yl) biphenyl), CDBP (4,4′-bis(9-carbazolyl)-2,2′-dimethylbiphenyl), DMFL-CBP (4,4′-bis(carbazol-9-yl)-9,9-dimethylfluorene), FL-4CBP (4,4′-bis(carbazol-9-yl)-9,9-bis(9-phenyl-9H-carbazole) fluorene), FL-2CBP (9,9-bis(4-carbazol-9-yl)phenyl) fluorene, also abbreviated as CPF), DPFL-CBP (4,4′-bis(carbazol-9-yl)-9,9-ditolylfluorene), FL-2CBP (9,9-bis(9-phenyl-9H-carbazole) fluorene), Spiro-CBP (2,2′,7,7′-tetrakis(carbazol-9-yl)-9,9′-spirobifluorene), ADN (9,10-di(naphth-2-yl) anthracene), TBADN (3-tert-butyl-9,10-di(naphth-2-yl) anthracene), DPVBi (4,4′-bis(2,2-diphenylethen-1-yl)-4,4′-dimethylphenyl), p-DMDPVBi (4,4′-bis(2,2-diphenylethen-1-yl)-4,4′-dimethylphenyl), TDAF (tert (9,9-diarylfluorene)), BSBF (2-(9,9′-spirobifluoren-2-yl)-9,9′-spirobifluorene), TSBF (2,7-bis(9,9′-spirobifluoren-2-yl)-9,9′-spirobifluorene), BDAF (bis(9,9-diarylfluorene)), p-TDPVBi (4,4′-bis(2,2-diphenylethen-1-yl)-4,4′-di-(tert-butyl)phenyl), TPB3 (1,3,5-tri (pyren-1-yl)benzene, PBD (2-(4-biphenylyl)-5-(4-tert-butylphenyl)-1,3,4-oxadiazole), BCP (2,9-dimethyl-4,7-diphenyl-1,10-phenanthroline), BP-OXD-Bpy (6,6′-bis [5-(biphenyl-4-yl)-1,3,4-oxadiazo-2-yl]-2,2′-bipyridyl), NTAZ (4-(naphth-1-yl)-3,5-diphenyl-4H-1,2,4-triazole), Bpy-OXD (1,3-bis [2-(2,2′-bipyrid-6-yl)-1,3,4oxadiazo-5-yl]benzene), BPhen (4,7-diphenyl-1,10-phenanthroline), TAZ (3-(4-biphenylyl)-4-phenyl-5-tert-butylphenyl-1,2,4-triazole), PADN (2-phenyl-9,10-di(naphth-2-yl) anthracene), Bpy-FOXD (2,7-bis [2-(2,2′-bipyrid-6-yl)-1,3,4-oxadiazol-5-yl]-9,9-dimethylfluorene), OXD-7 (1,3-bis [2-(4-tert-butylphenyl)-1,3,4-oxadiazol-5-yl]benzene), HNBphen (2-(naphth-2-yl)-4,7-diphenyl-1,10-phenanthroline), NBphen (2,9-bis(naphth-2-yl)-4,7-diphenyl-1,10-phenanthroline), 3TPYMB (tris(2,4,6-trimethyl-3-(pyrid-3-yl)phenyl) borane), 2-NPIP (1-methyl-2-(4-(naphth-2-yl)phenyl)-1H-imidazo [4,5-f]-[1,10] phenanthroline), Liq (8-hydroxyquinolinolatolithium), and Alq (bis(2-methyl-8-quinolinolate)-4-(phenylphenolato)aluminum), and also of mixtures of the aforesaid substances.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified in references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

A hole injecting/transporting material to be used in the present invention is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOx; a p-type semiconducting organic compound, such as 1,4,5,8,9,12-Hexaazatriphenylenehexacarbonitrile; a metal complex, and a cross-linkable compounds.

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

An emitter example is not particularly limited, and any compound may be used as long as the compound is typically used as an emitter material. Examples of suitable emitter materials include, but are not limited to, compounds which can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, metal-assisted delayed fluorescence (MADF), or combinations of these processes. In some embodiments, the emissive dopant can be a racemic mixture, or can be enriched in one enantiomer.

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

In yet another aspect of the present disclosure, a formulation that comprises the novel compound disclosed herein is described. The formulation can include one or more components selected from the group consisting of a solvent, a host, a hole injection material, hole transport material, and an electron transport layer material, disclosed herein.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the composite materials of the present invention and practice the claimed methods. The following working examples therefore, specifically point out the preferred embodiments of the present invention, and are not to be construed as limiting in any way the remainder of the disclosure.

### Example 1: Tetradentate Platinum and Palladium Complex Emitters Employing Benzo-Carbene with Bulky Substituents and its Analogues

OLED (Organic Light Emitting Diodes) is a flat light emitting technology, consisting of a series of organic thin films between two conductors. When electricity is applied by adjacent electrodes, a bright light is emitted. OLED displays have found their way into many handheld products since their onset and continue to be popular in the mobile market. The field of OLED has seen a consistent growth with a steady introduction of productive modifications and new materials design strategies. Despite the great progress has been achieved in this field, many challenges remain, particularly, the development of stable, narrow and efficient blue emitters remains a substantial deficit for the on-going efforts in the field of organic displays and lighting. In this invention, a series of platinum (II) and palladium (II) complexes with bulky substituents based on benzocarbene and their analogues have been designed. This class of emitters could be found utilization for full color displays and lighting applications.

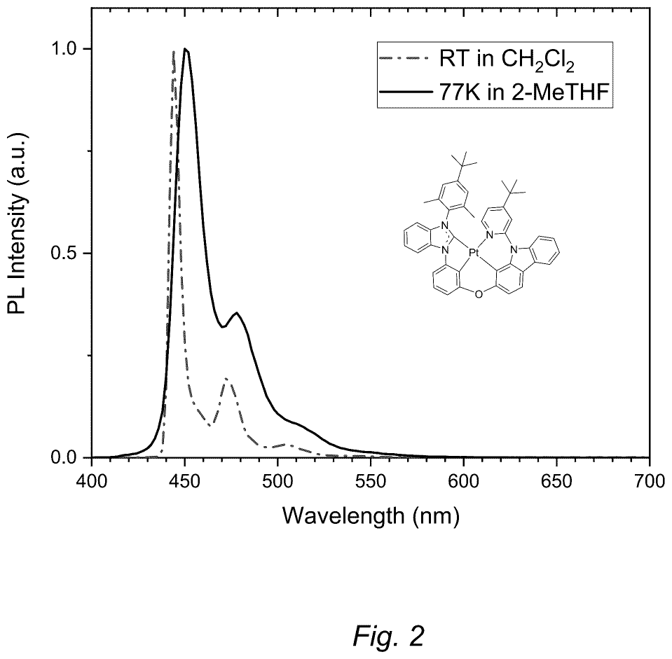

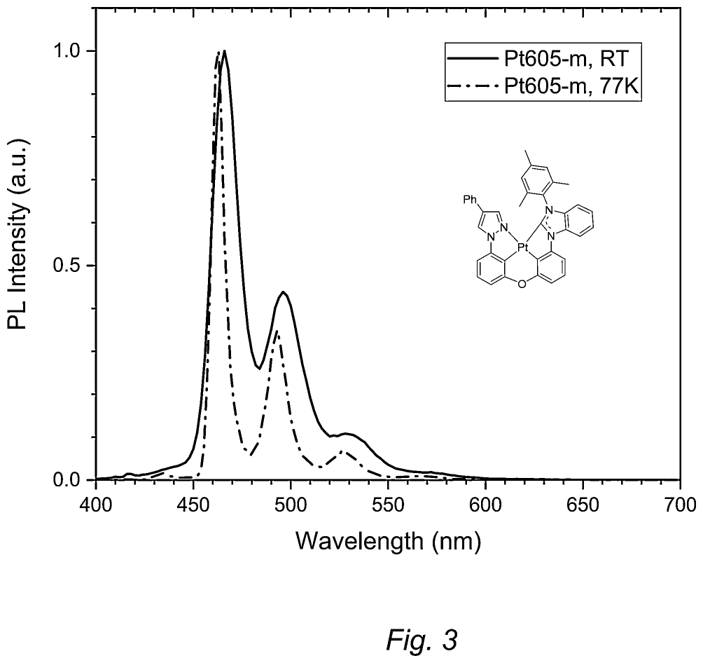

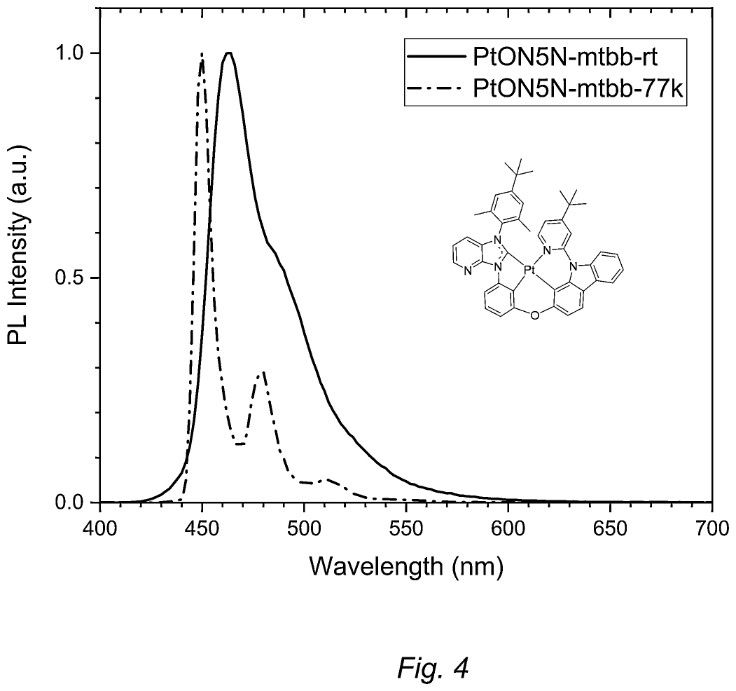

The phospholuminescent spectra of exemplary compounds are shown in FIGS. 2, 3, and 4.

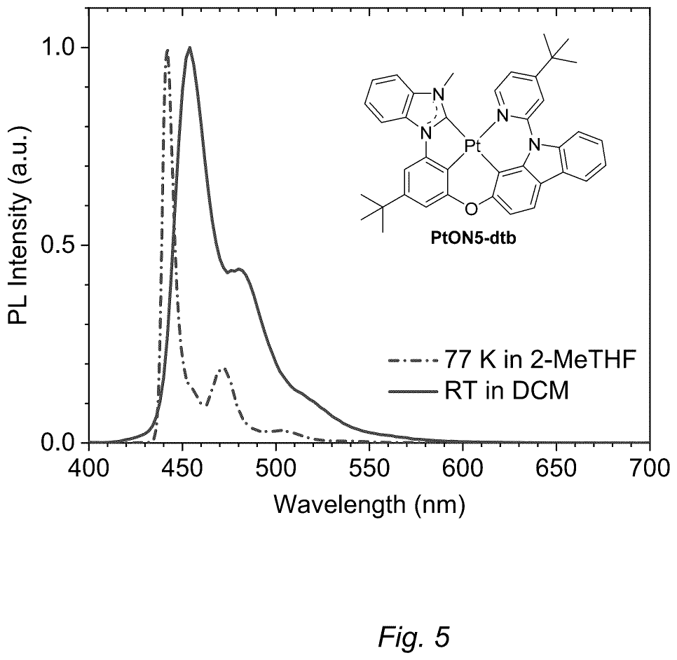

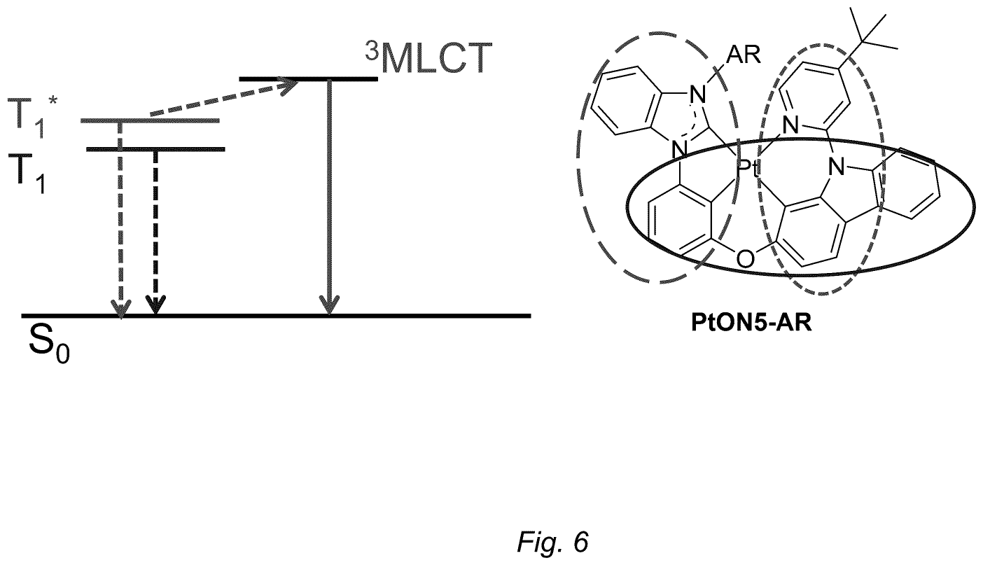

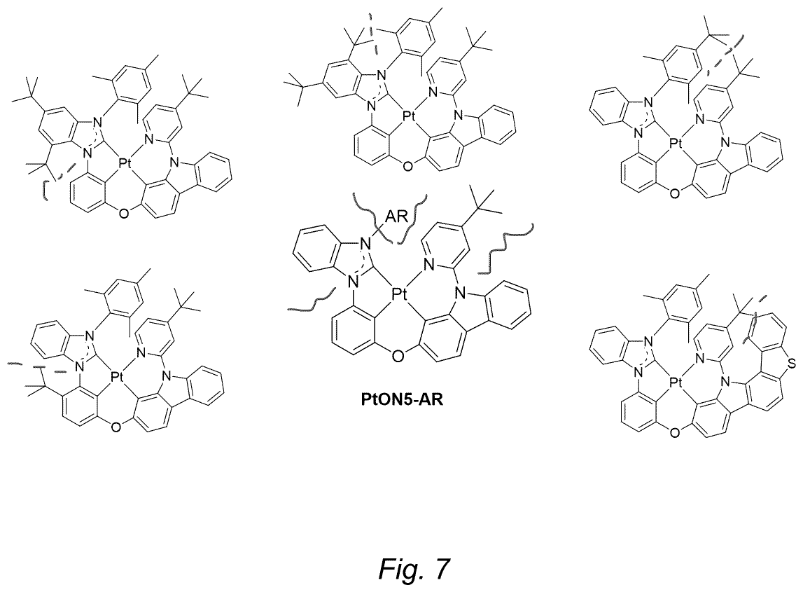

Tetradentate Pt complexes are potentially emitter candidates for display applications. However, compared to its 77 K emission spectrum, PtON5-dtb demonstrates a significantly enhanced emission vibronic sidebands at room temperature (FIG. 5), which can be attributed to potential mixing both T₁ and T₁* states (FIG. 6) at the room temperature. Thus, it will be desirable to stabilize T₁* state or stabilize T₁ state to increase the energy splitting between T₁ and T₁* states and suppress the emission vibronic sideband. Such molecular design principles are illustrated in FIG. 2, which proposes to narrow emission spectra of Pt complexes by destabilizing the T₁* state through creating intramolecular interactions between phenyl and benzo-imidazole-carbene groups, between benzo-imidazole-carbene group and carbene-bonded aryl group, between carbene-bonded aryl group and pyridyl groups or stabilizing the T₁ state through extending conjugation level of carbazolyl groups (FIG. 7).

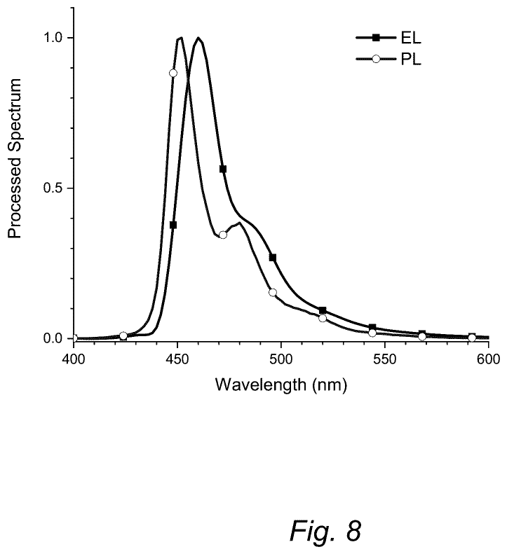

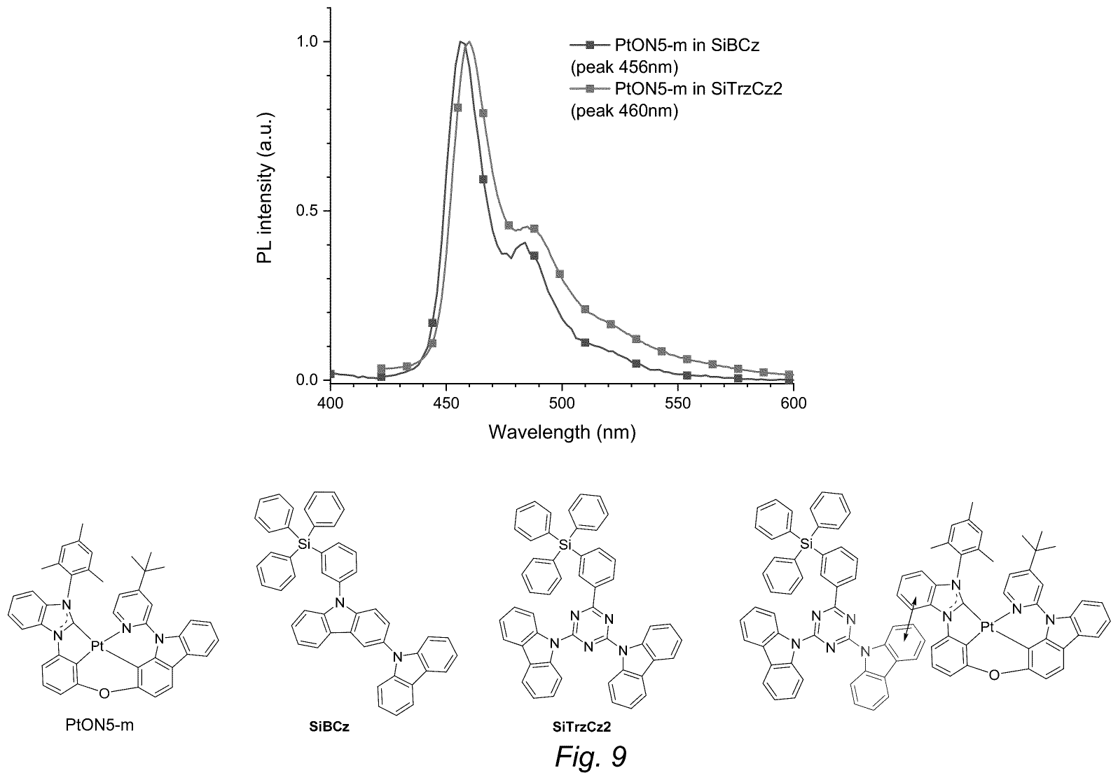

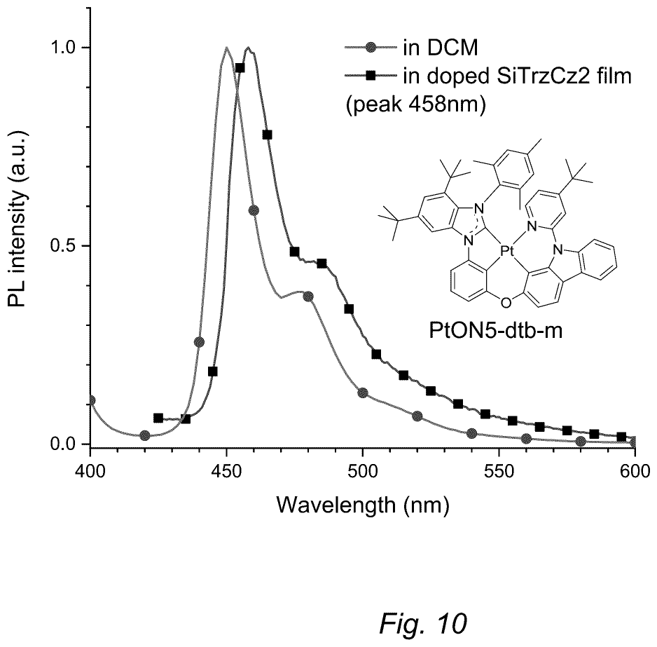

Moreover, the random intramolecular interactions between emitter and host, e.g. electron-rich carbazolyl group from SiTrzCz2 and electron-deficient benzo-imidazole carbene group from PtON5-m (FIG. 8), results in a red-shifted emission spectrum (FIG. 5) which could compromise color quality of blue phosphorescent OLEDs and affect the device operational stabilities with various level of host-emitter interactions. Thus, it will be also desirable to suppress such an intramolecular interaction between Pt complexes and host materials by adding bulky groups on the phenyl benzo-imidazole-carbene group. As an additional benefit, emission peak of PtON5-dtb-m in SiTrzCz2 film (FIG. 10) is 2 nm blue-shifted compared to the emission peak of PtON5-m in SiTrzCz2 film (FIG. 9).

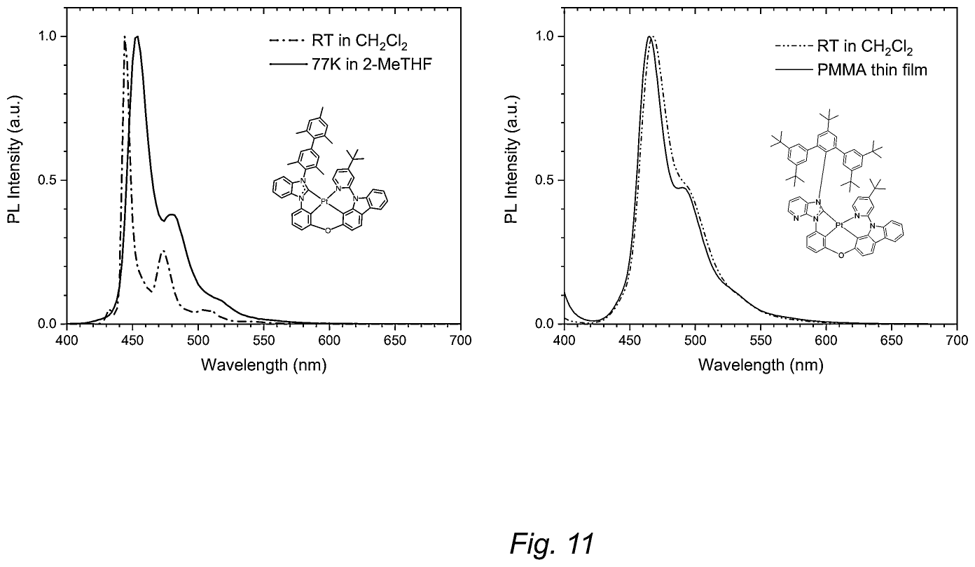

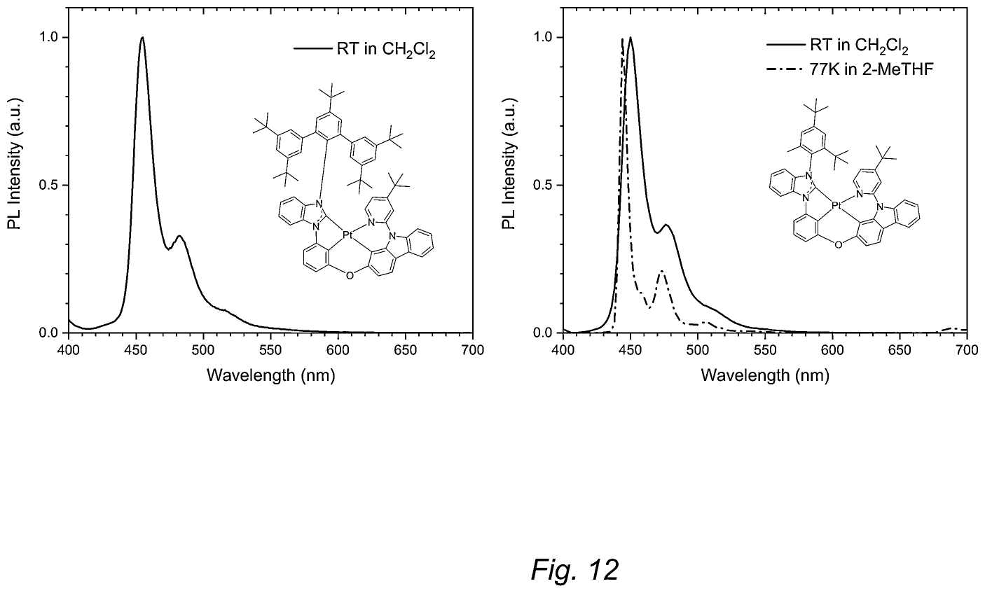

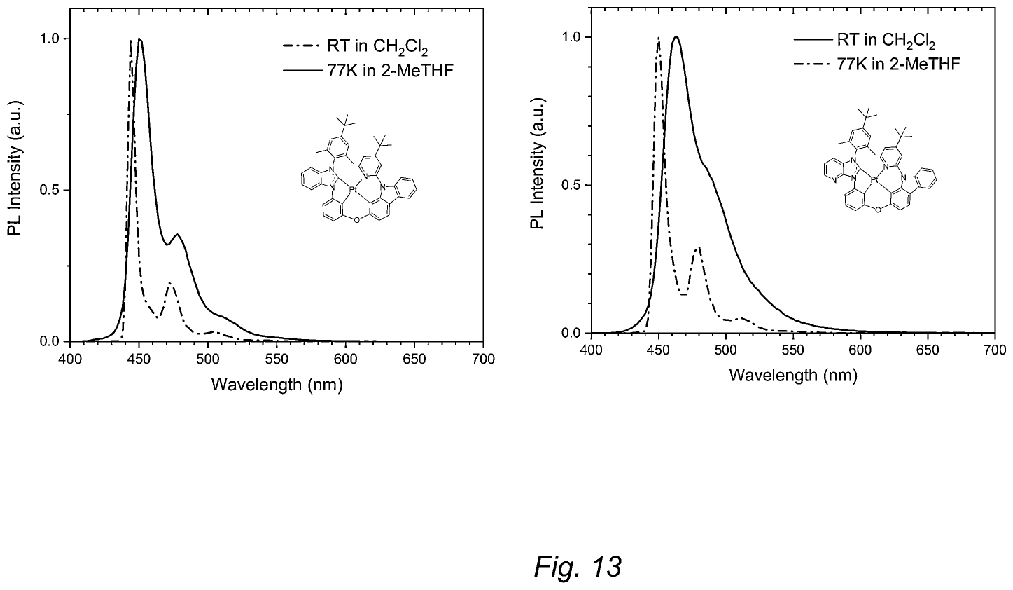

Further phospholuminescent spectra of exemplary compounds are shown in FIGS. 11, 12, and 13.

Inventive compounds are prepared in the following manner:

### Ex. 1

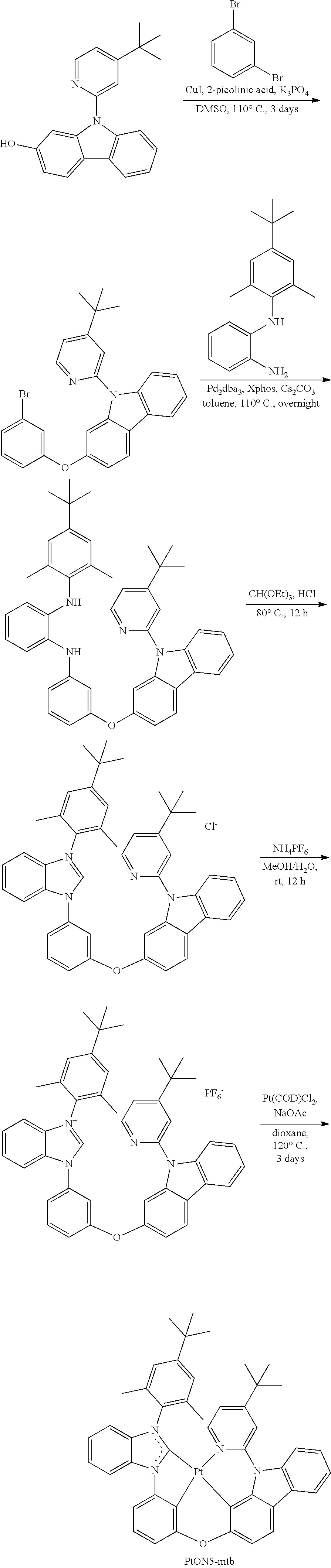

### Ex. 2

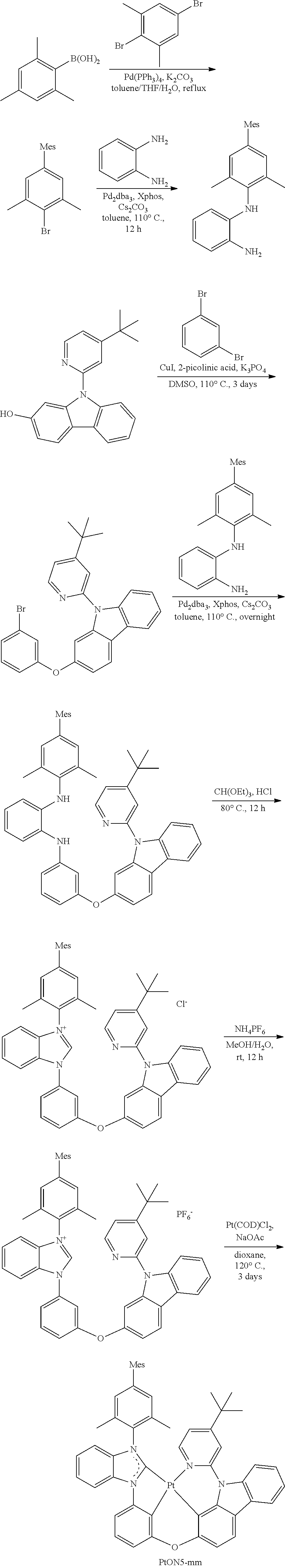

### Ex. 3

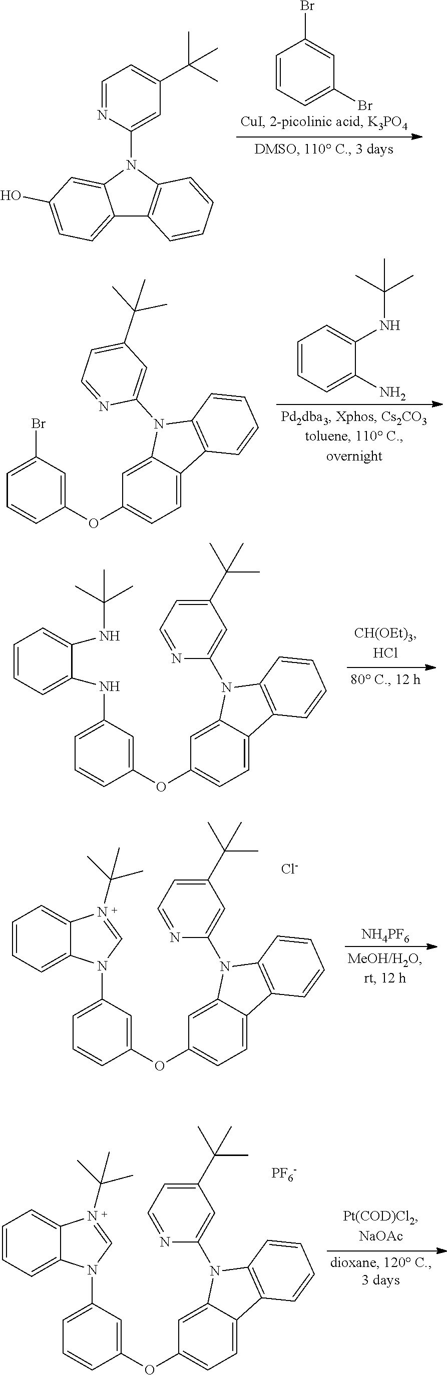

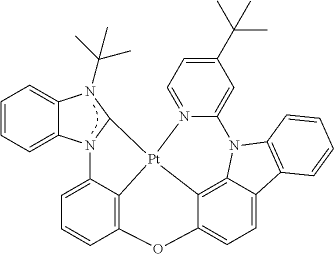

### Ex. 4

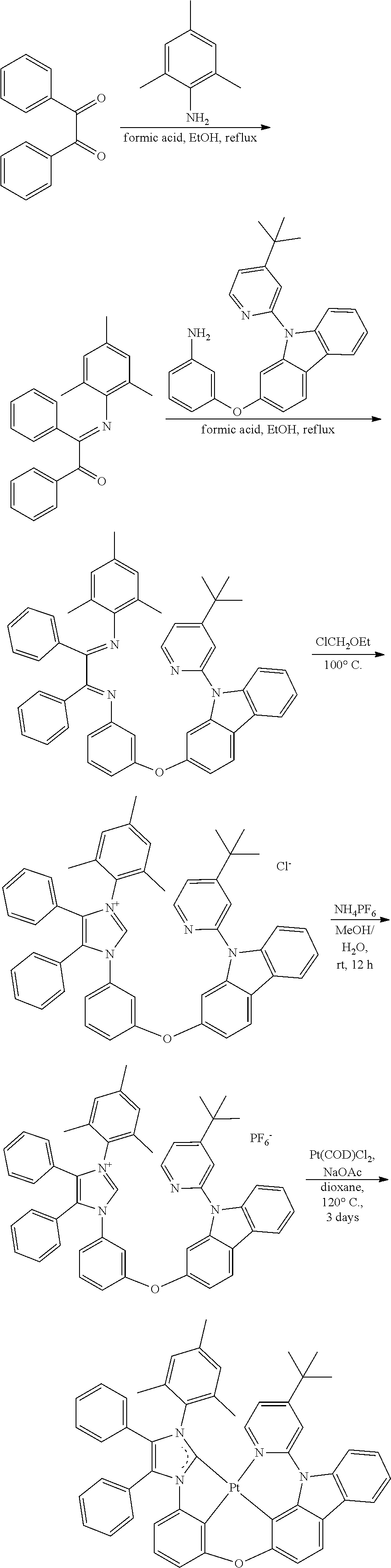

### Ex. 5

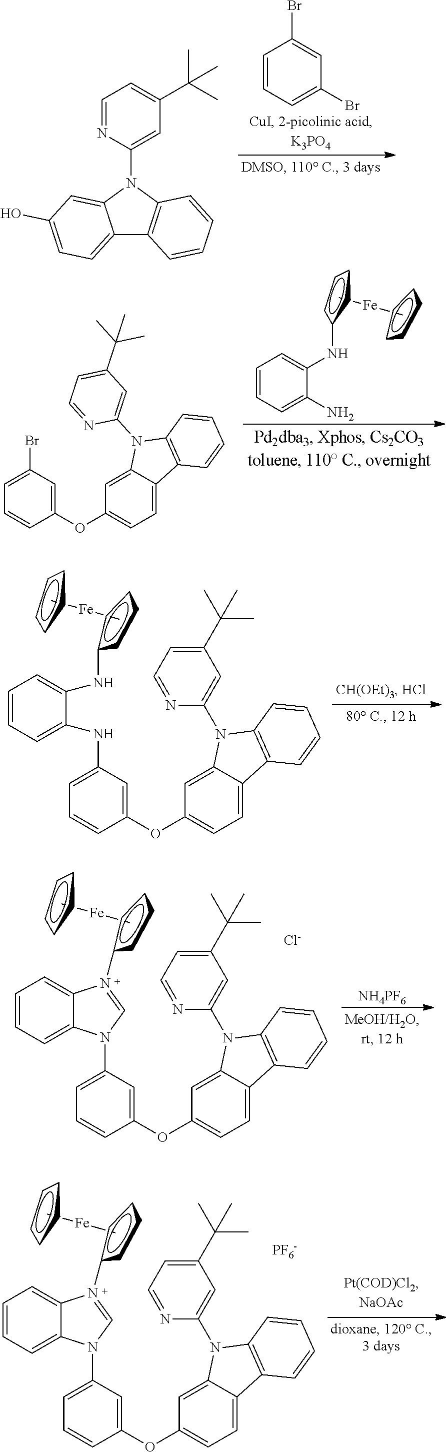

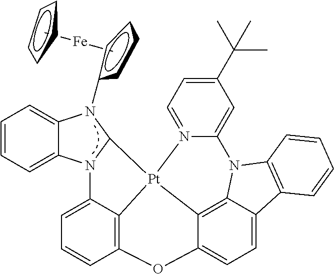

### Ex. 6

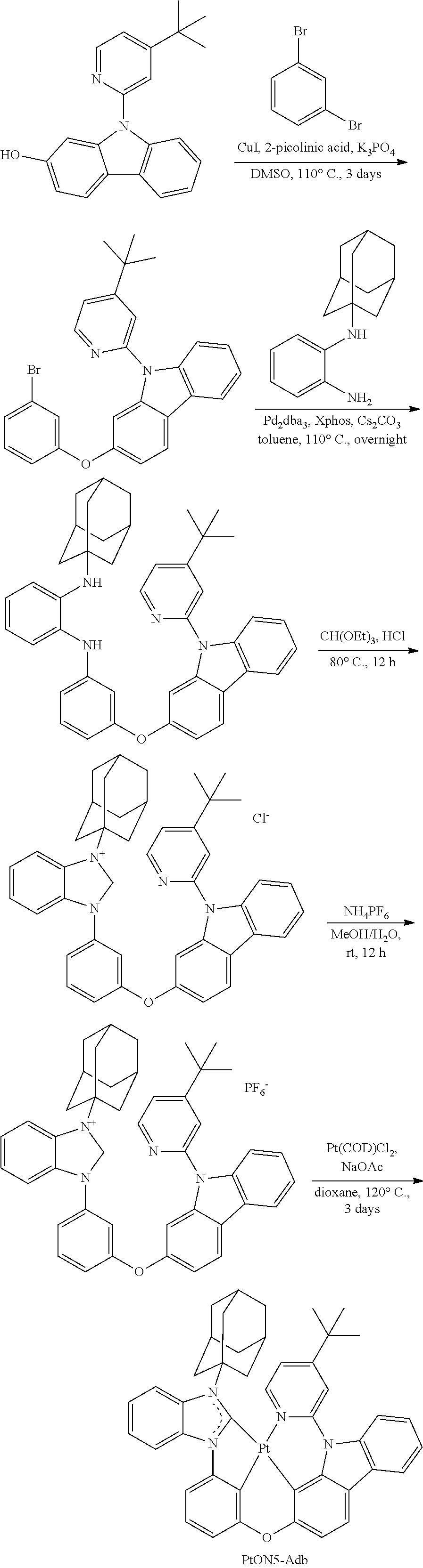

### Ex. 7

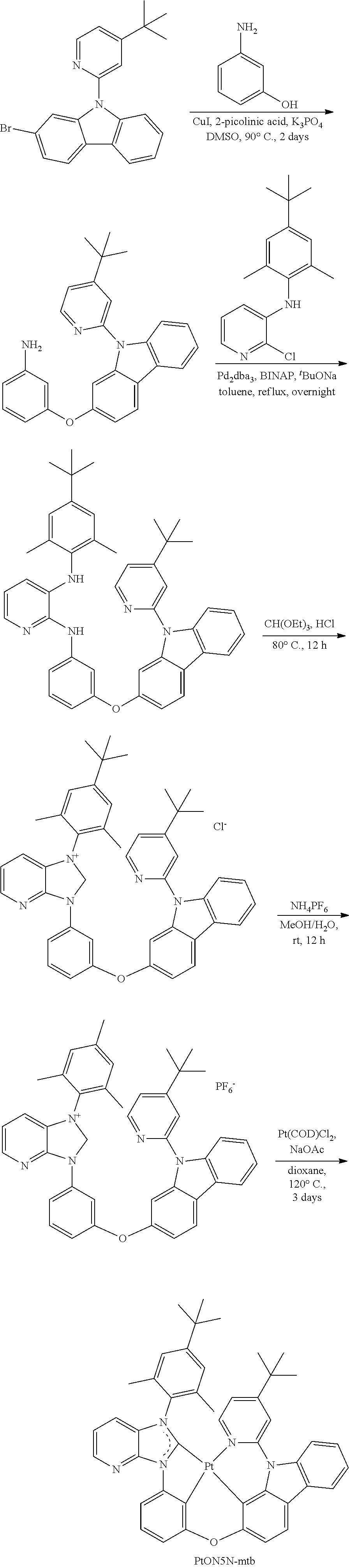

### Ex. 8

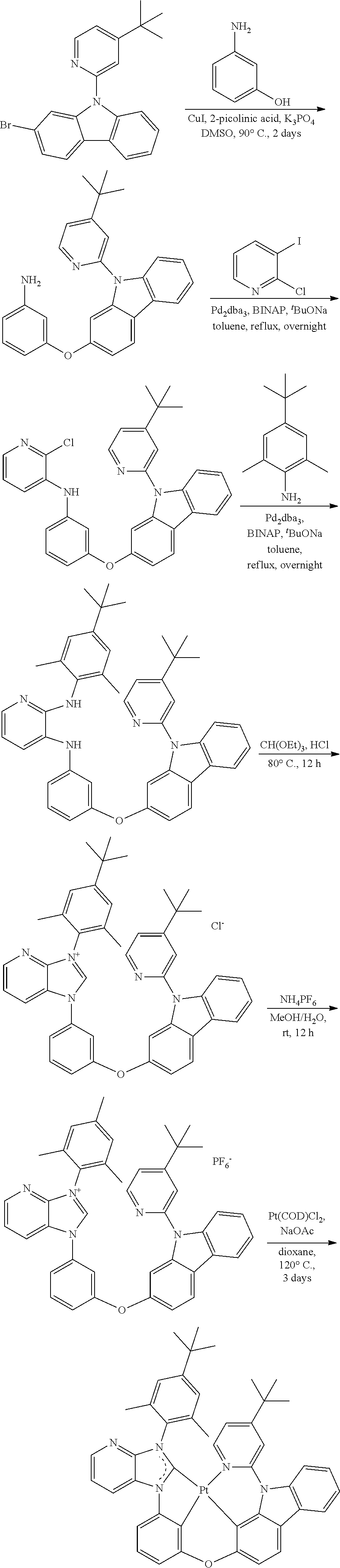

### Ex. 9

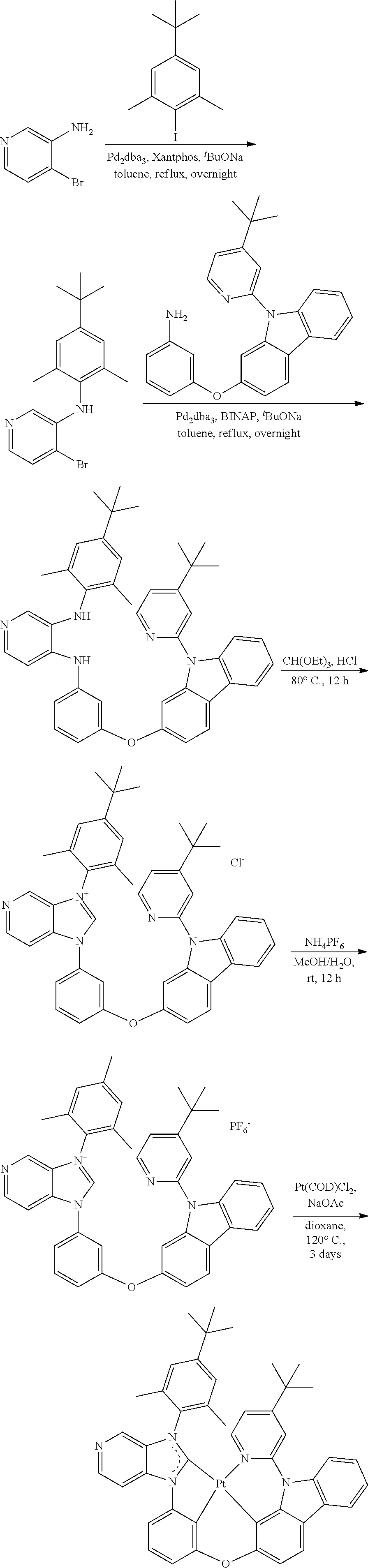

### Ex. 10

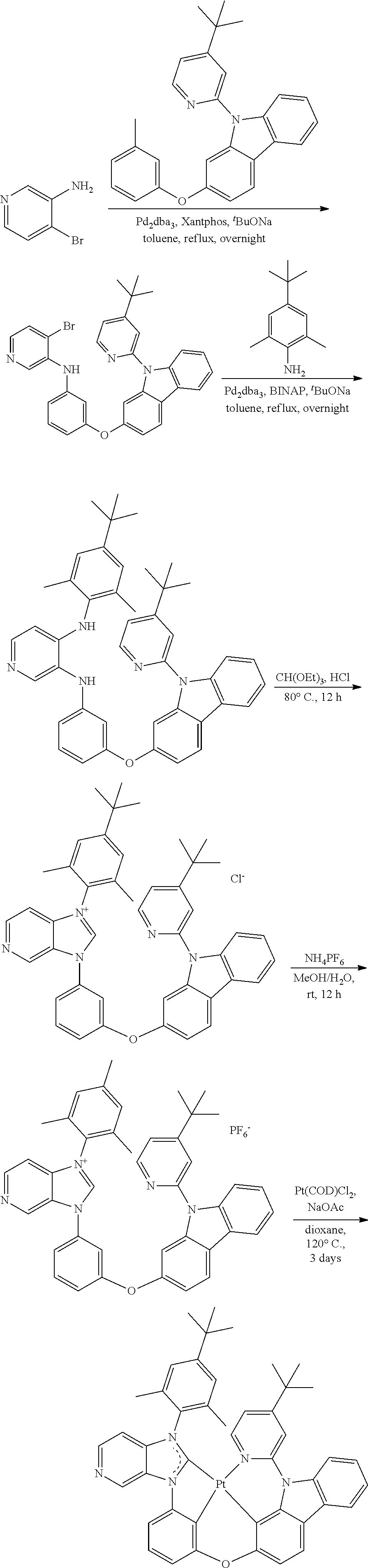

### Ex. 11

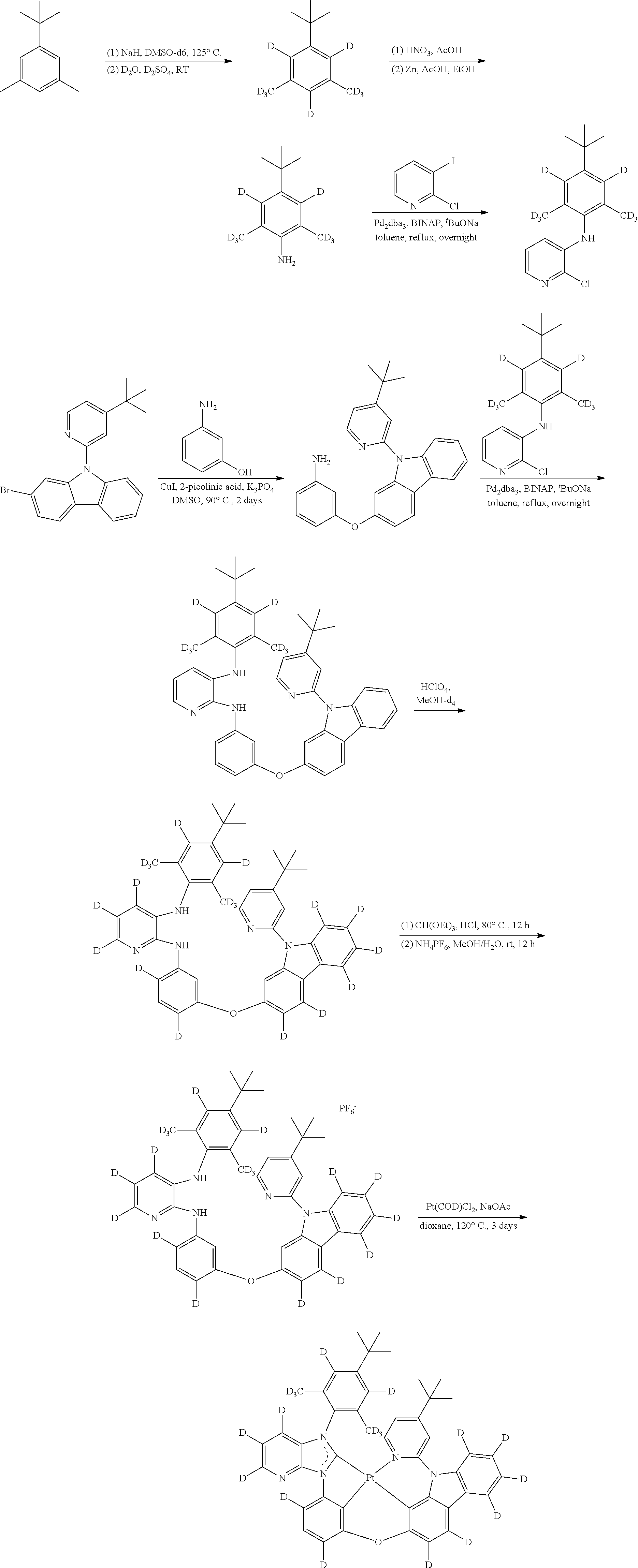

### Ex. 12

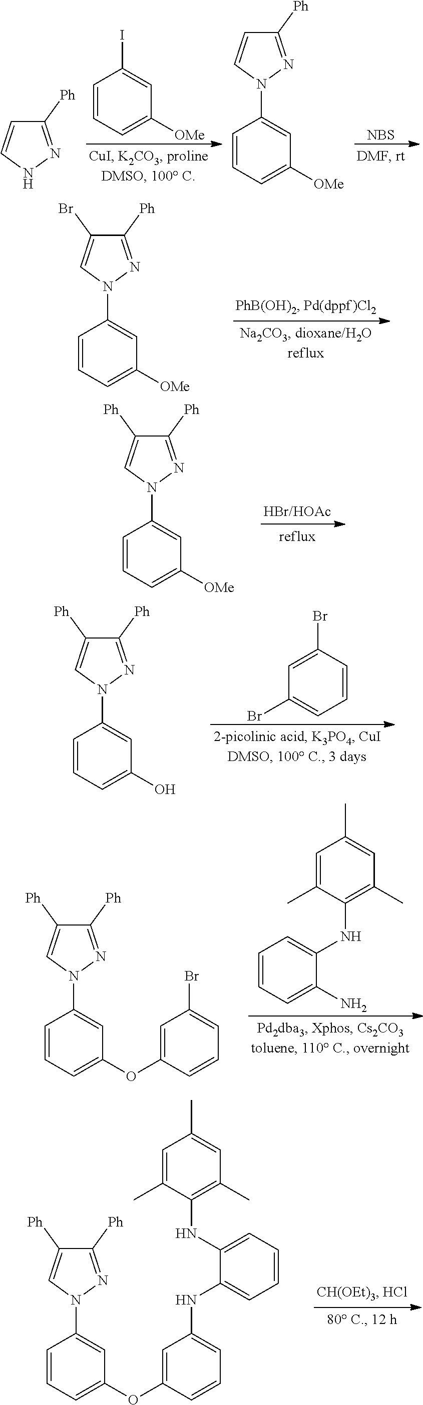

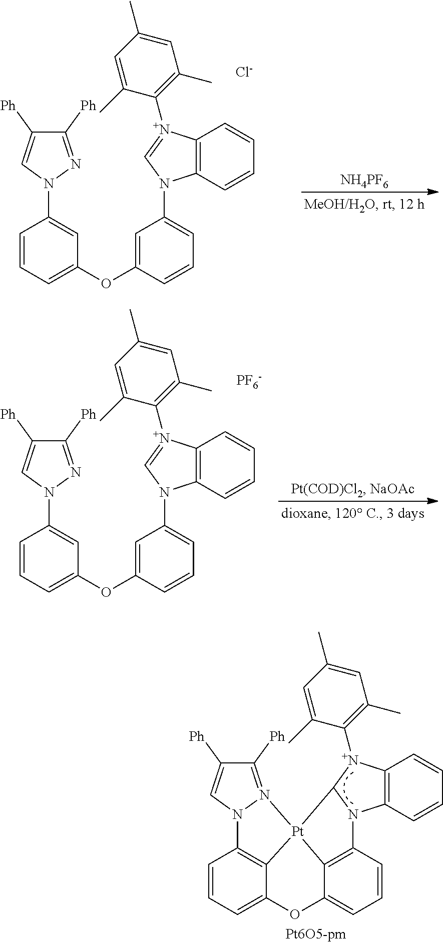

### Ex. 13

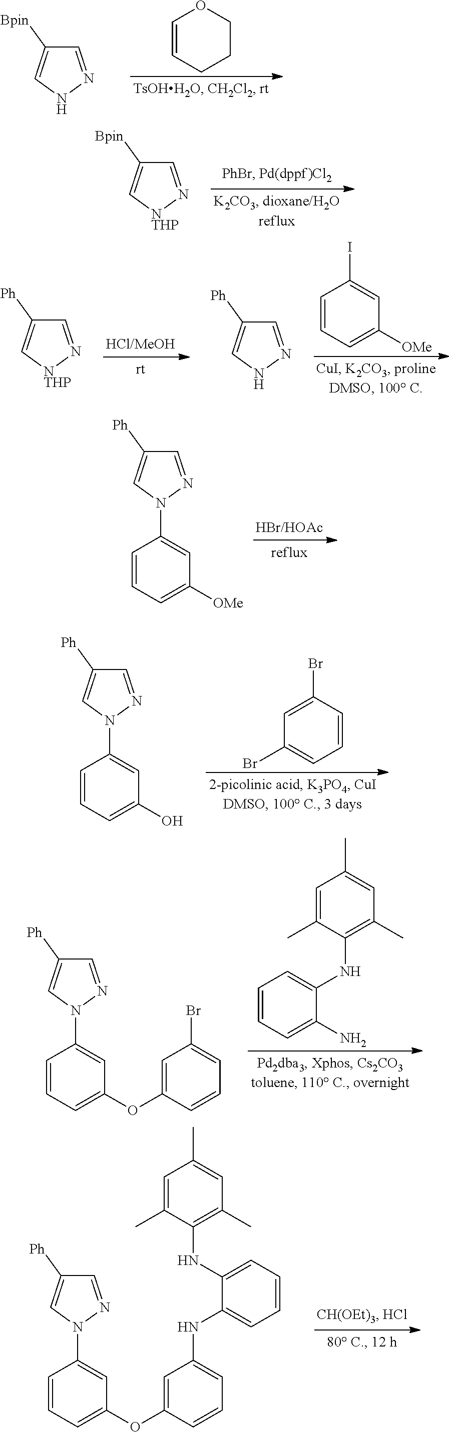

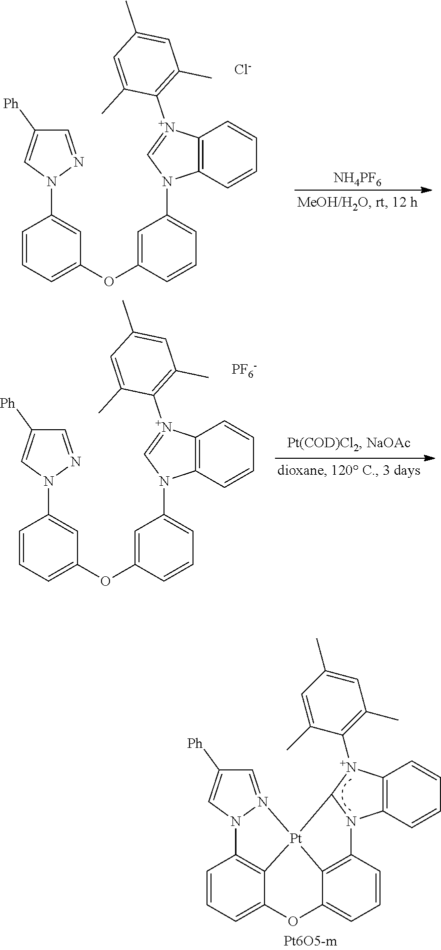

### Ex. 14

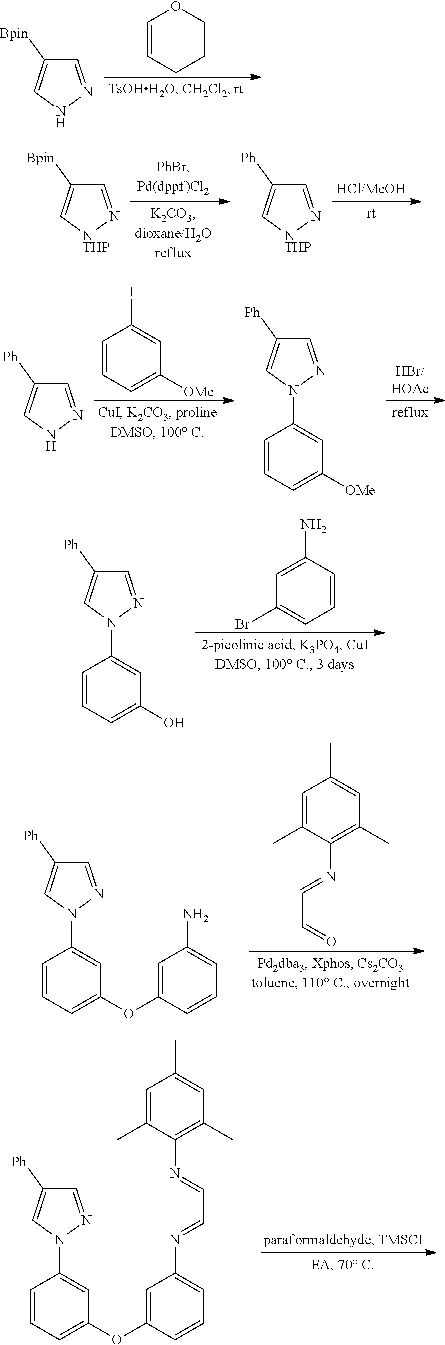

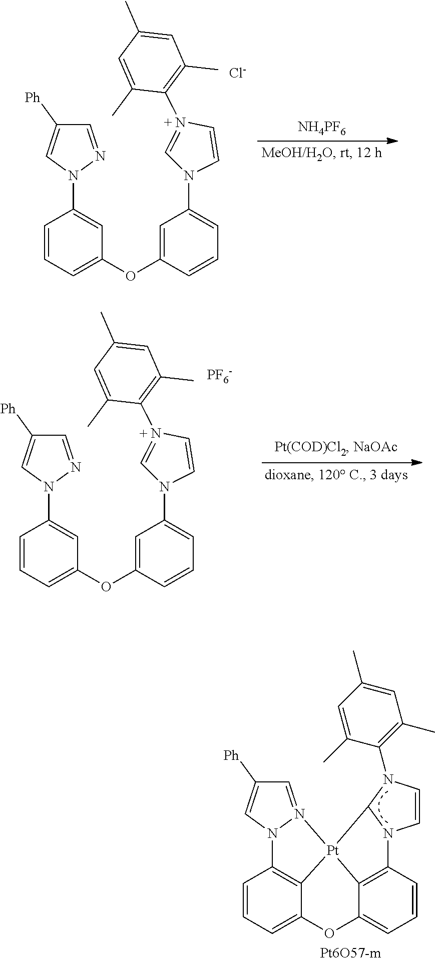

### Ex. 15

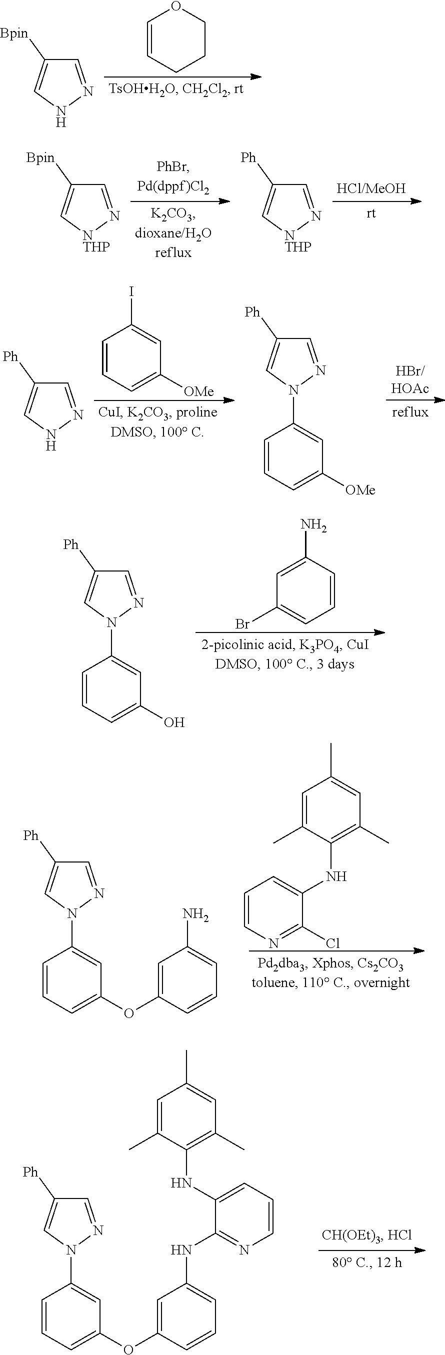

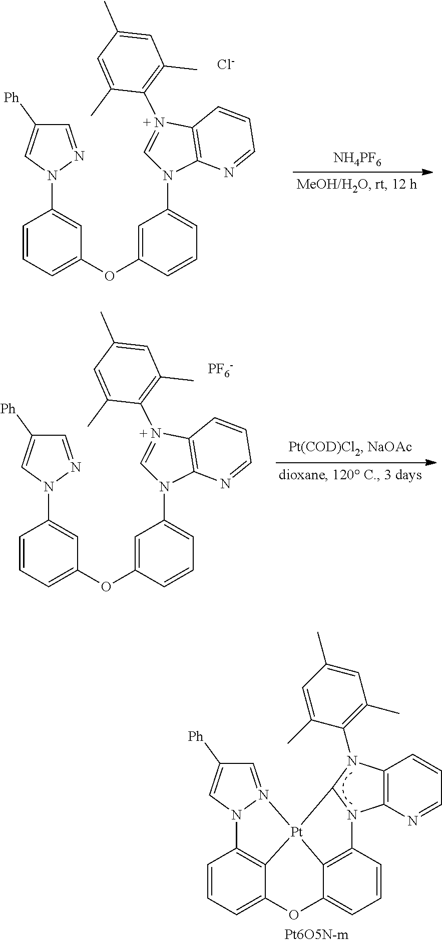

### Ex. 16

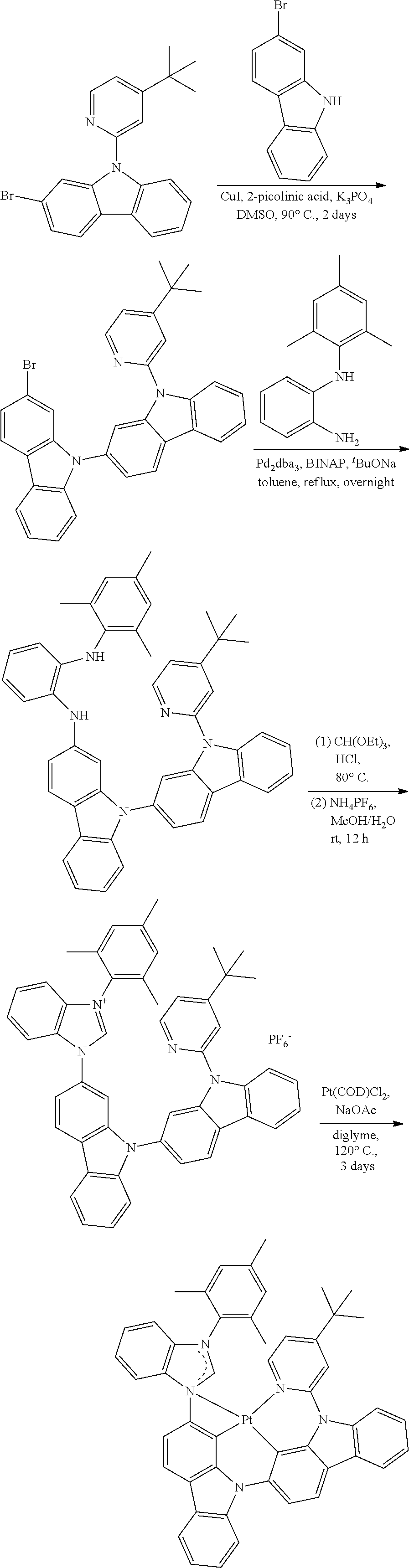

### Ex. 17

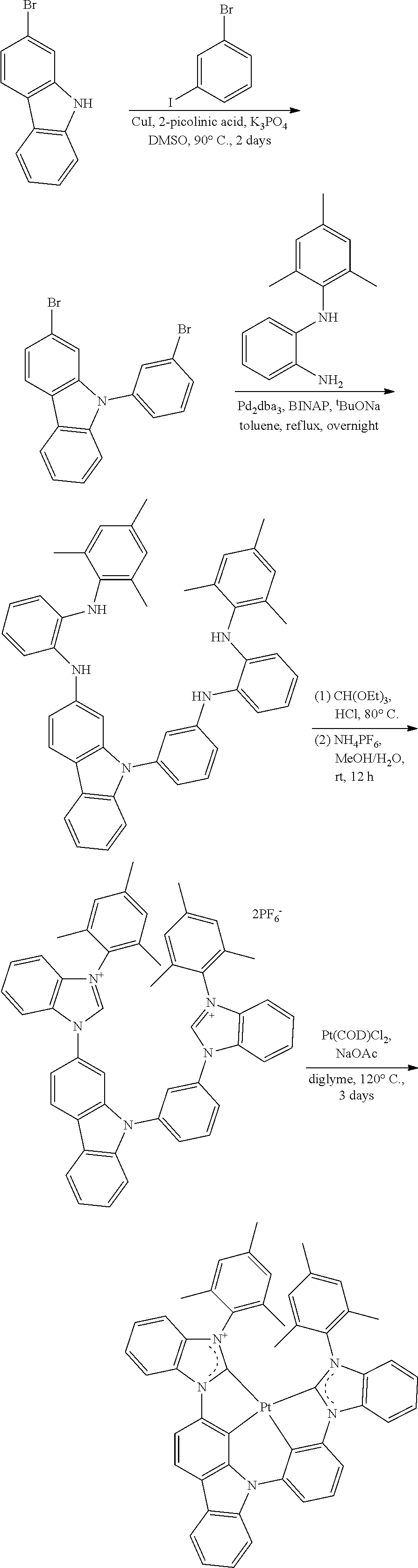

### Ex. 18

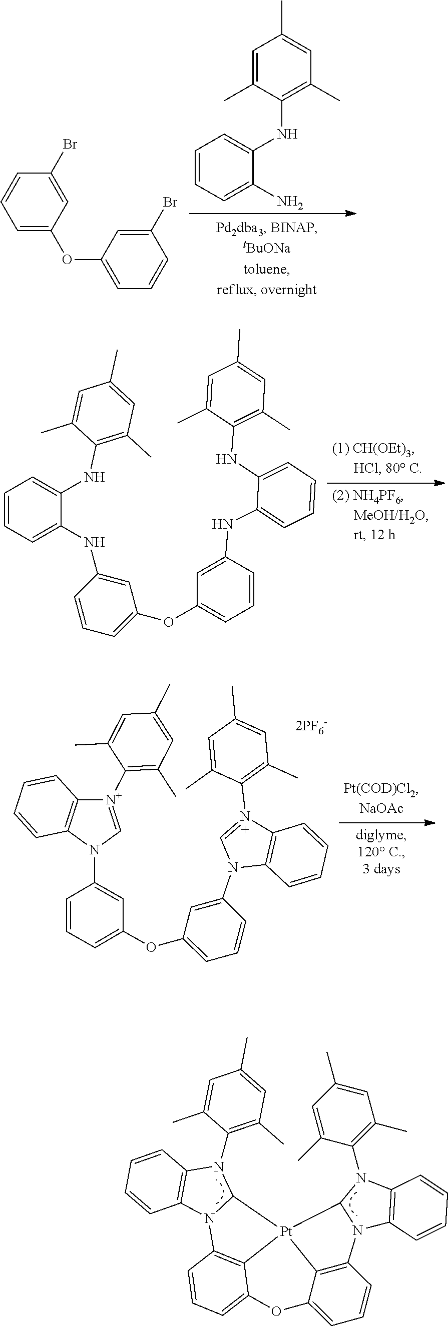

### Ex. 1-1:

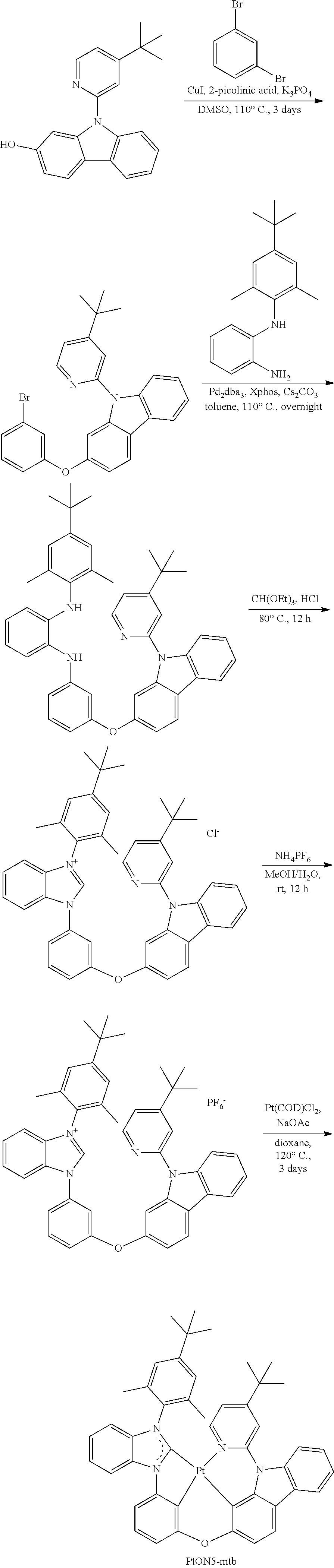

### Ex. 1-2:

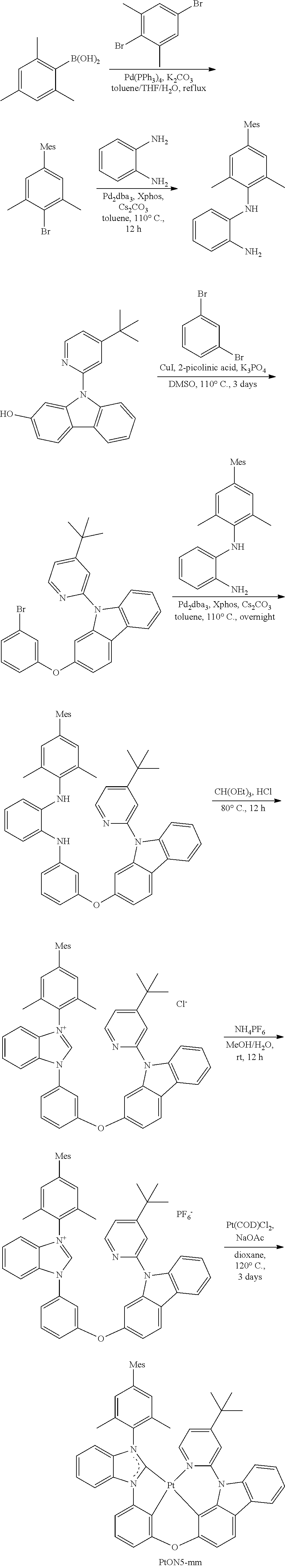

### Ex. 1-3:

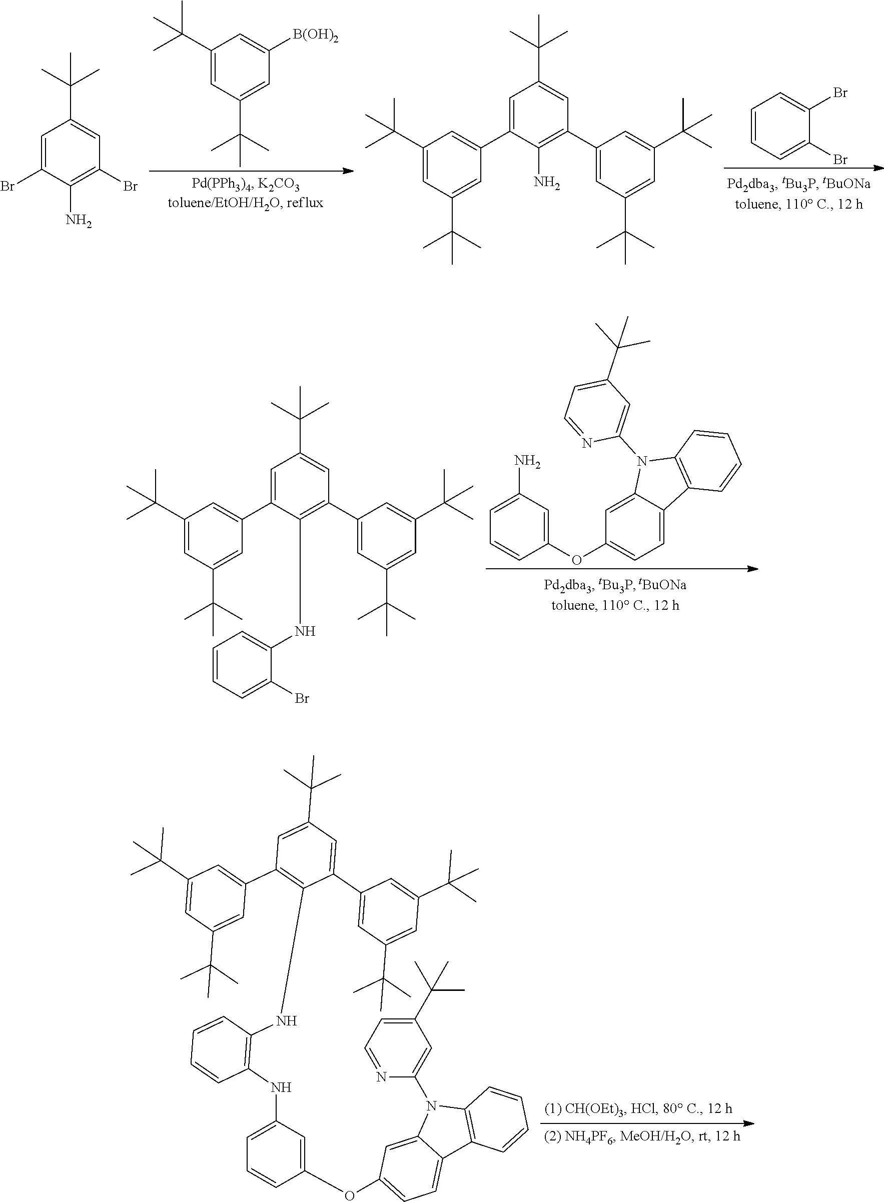

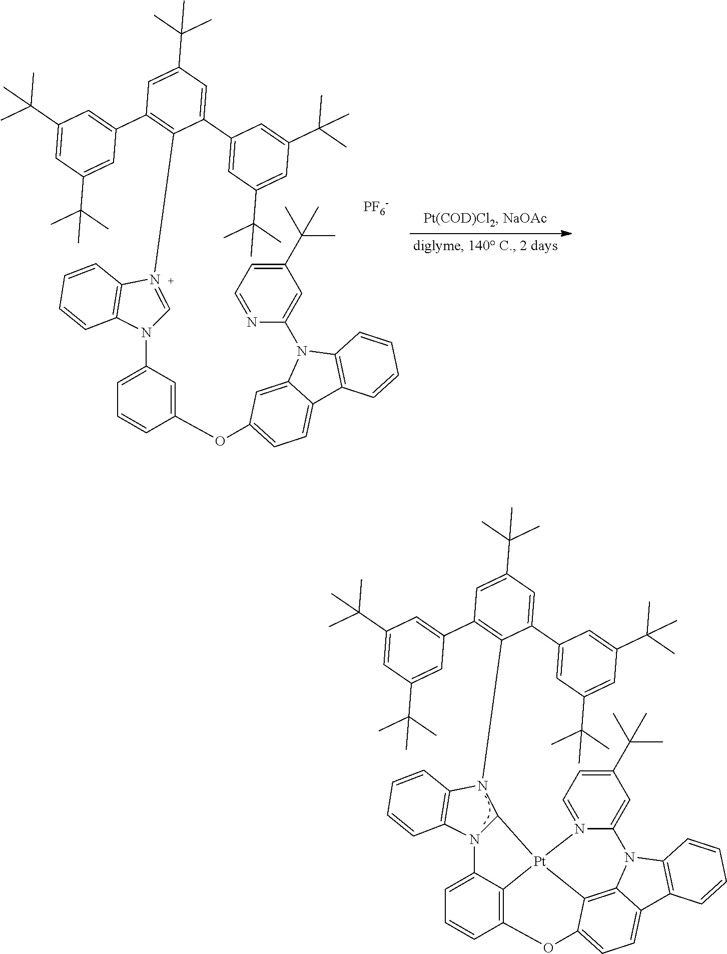

### Ex. 1-4:

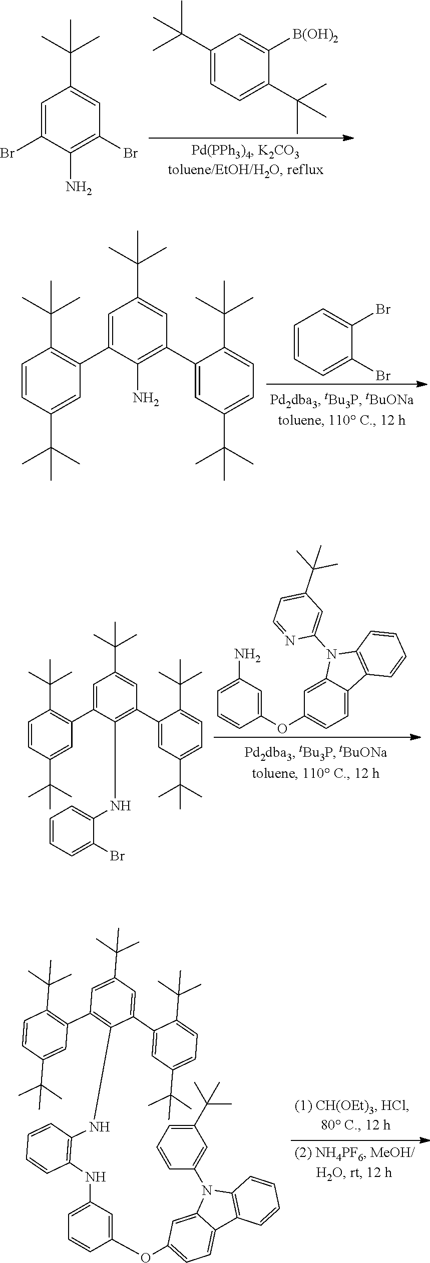

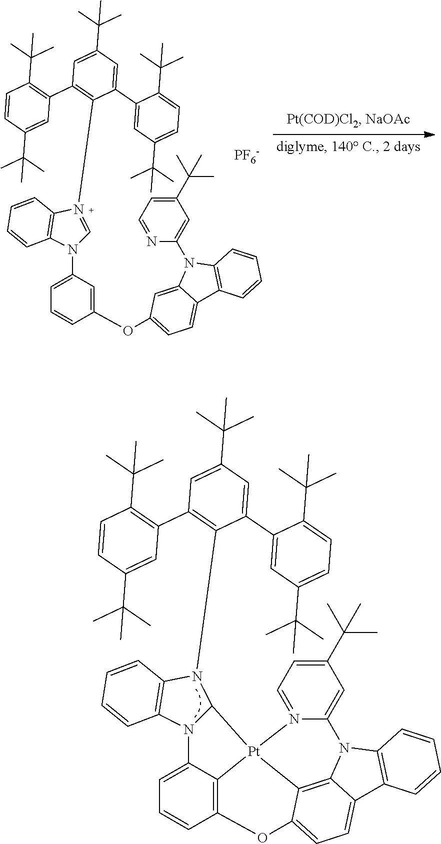

### Ex. 1-5:

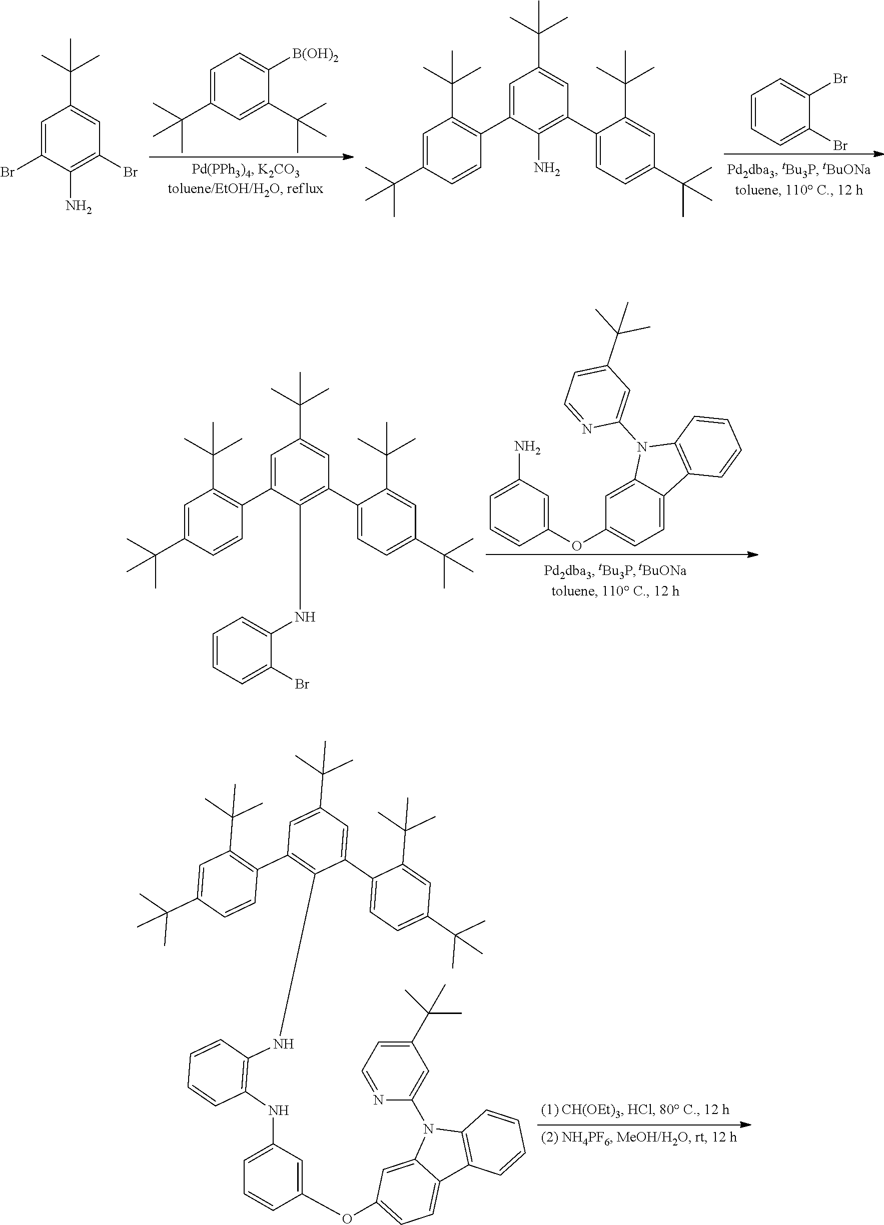

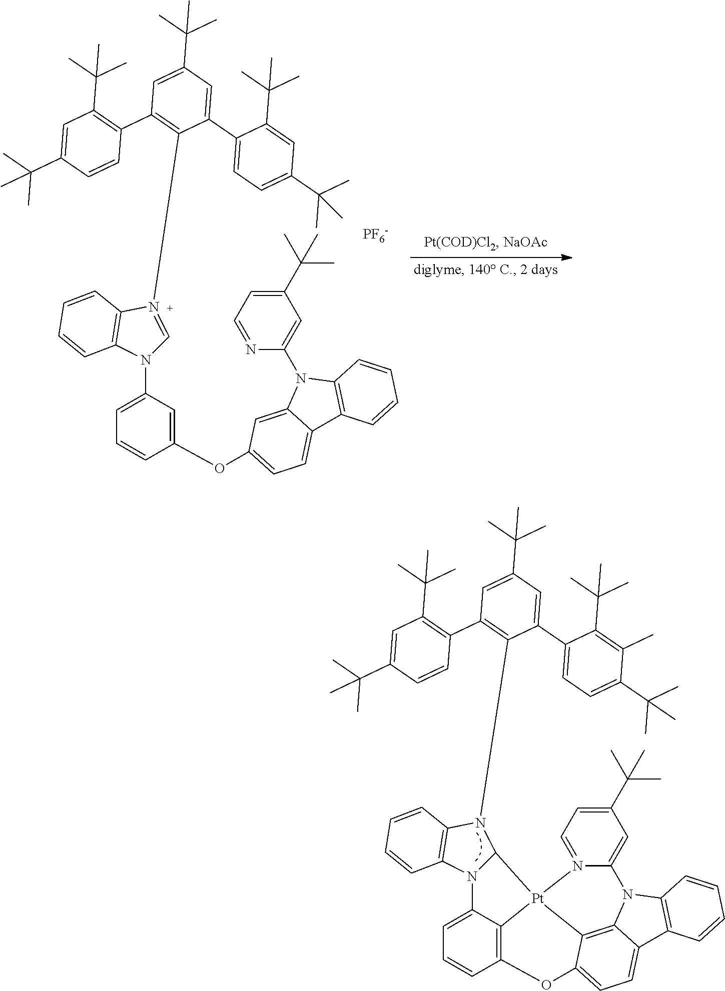

### Ex. 1-6:

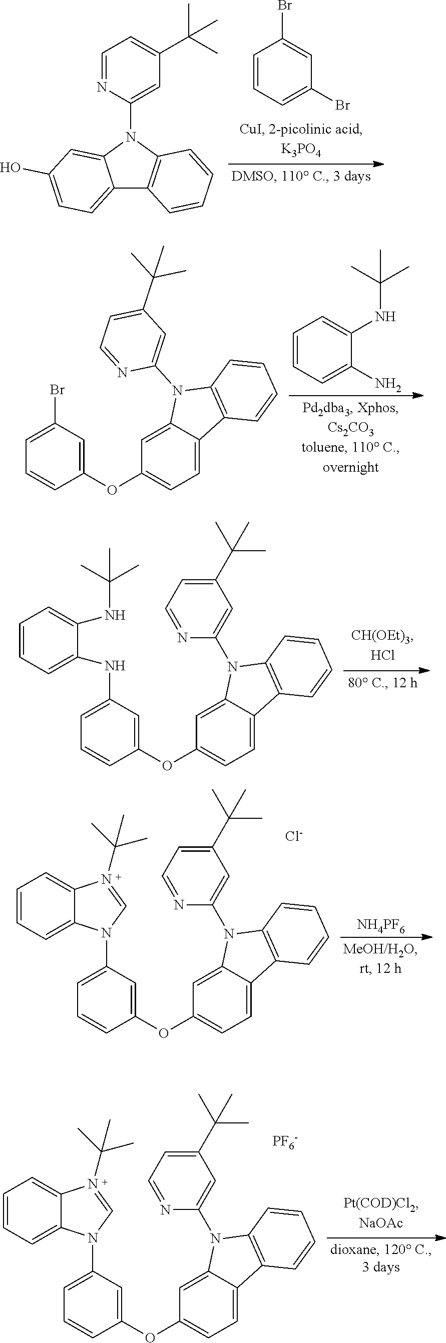

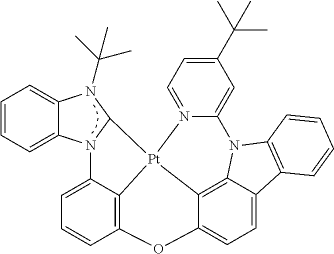

### Ex. 1-7:

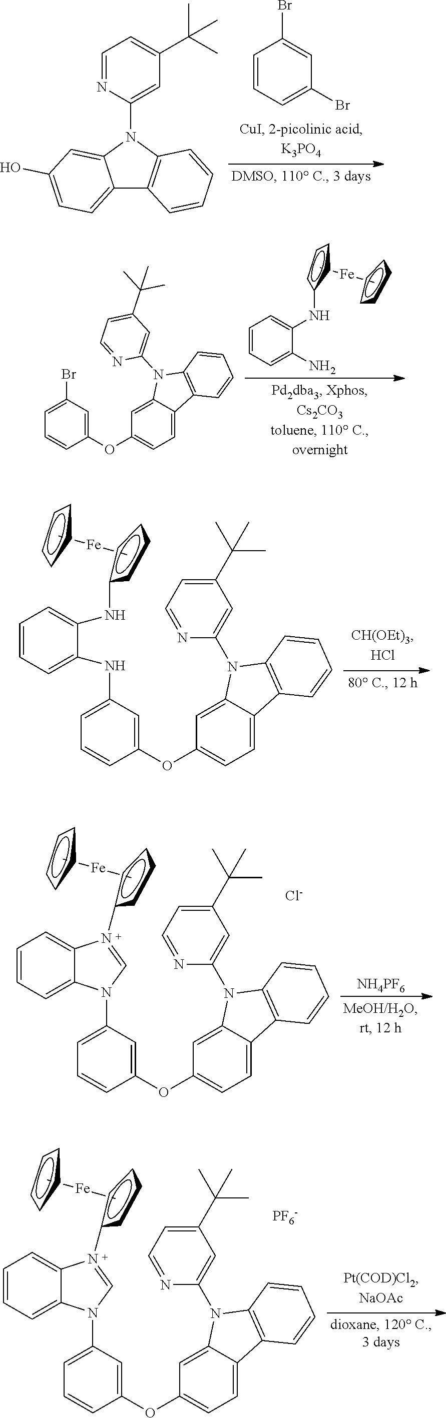

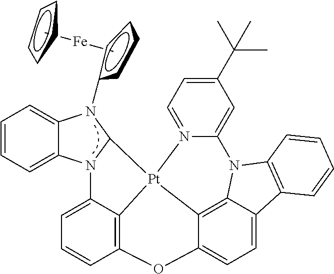

### Ex. 1-8:

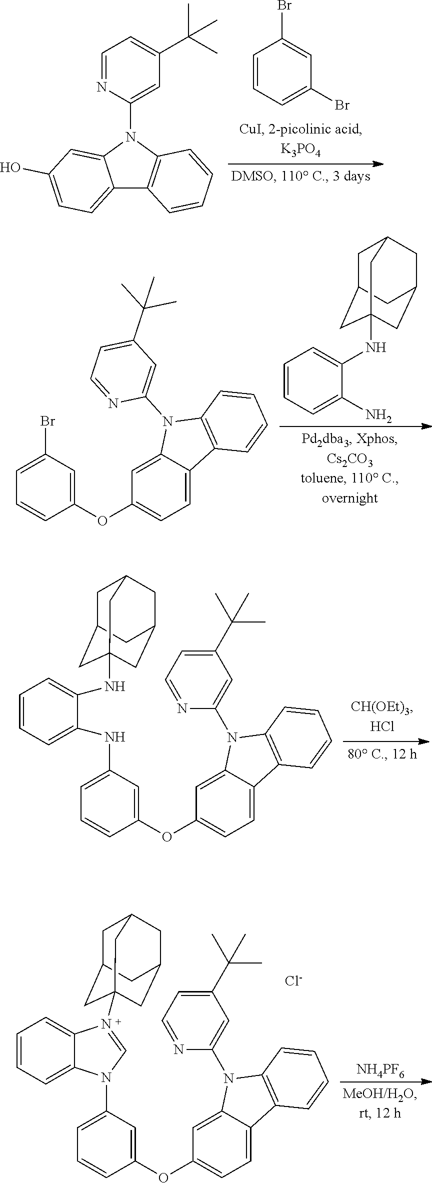

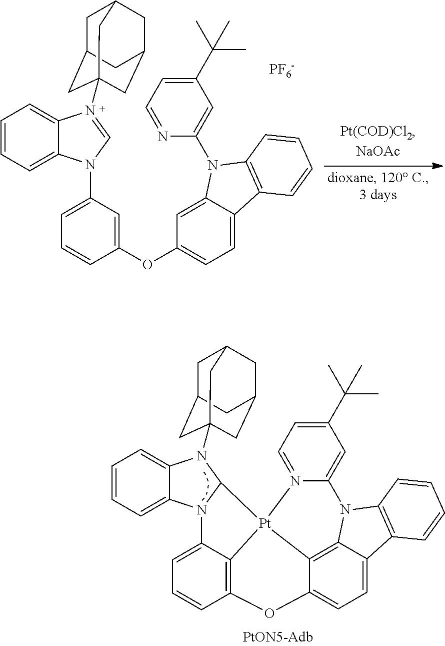

### Ex. 1-9:

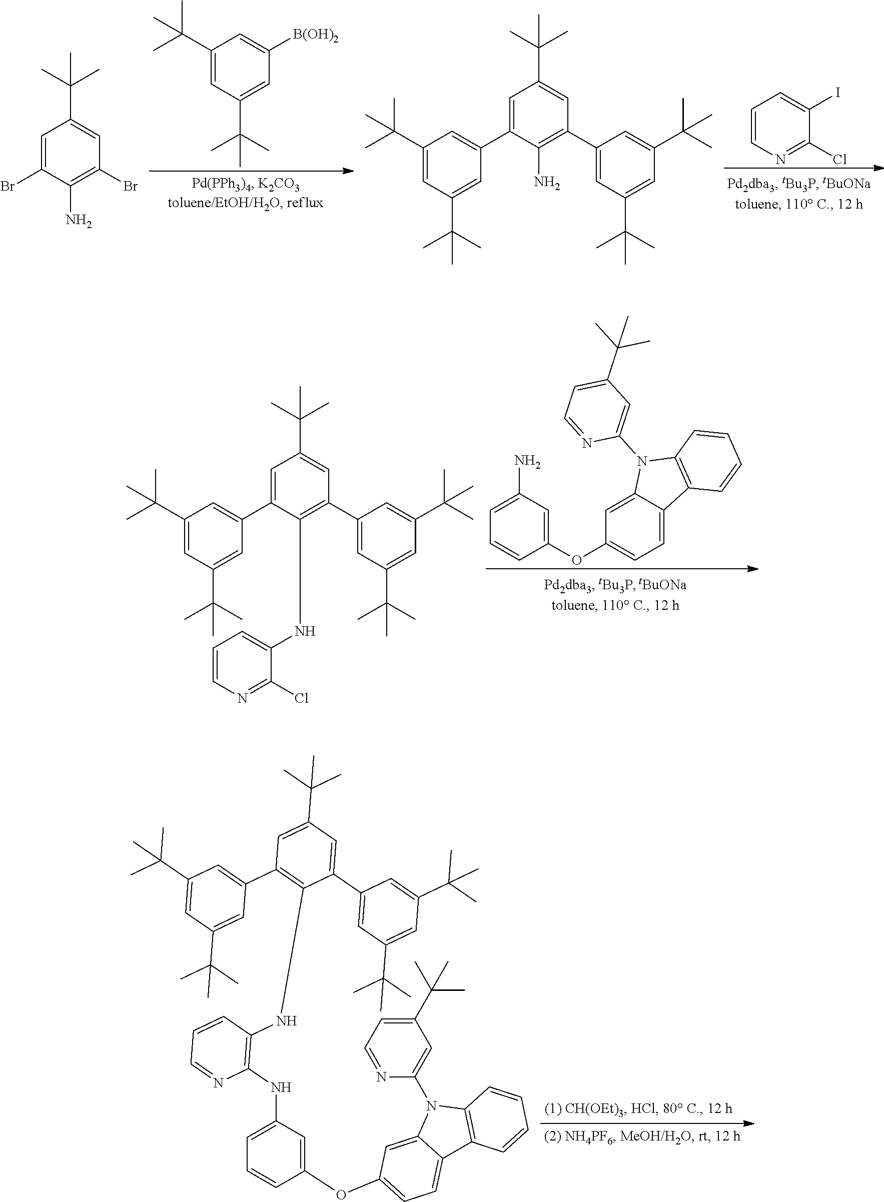

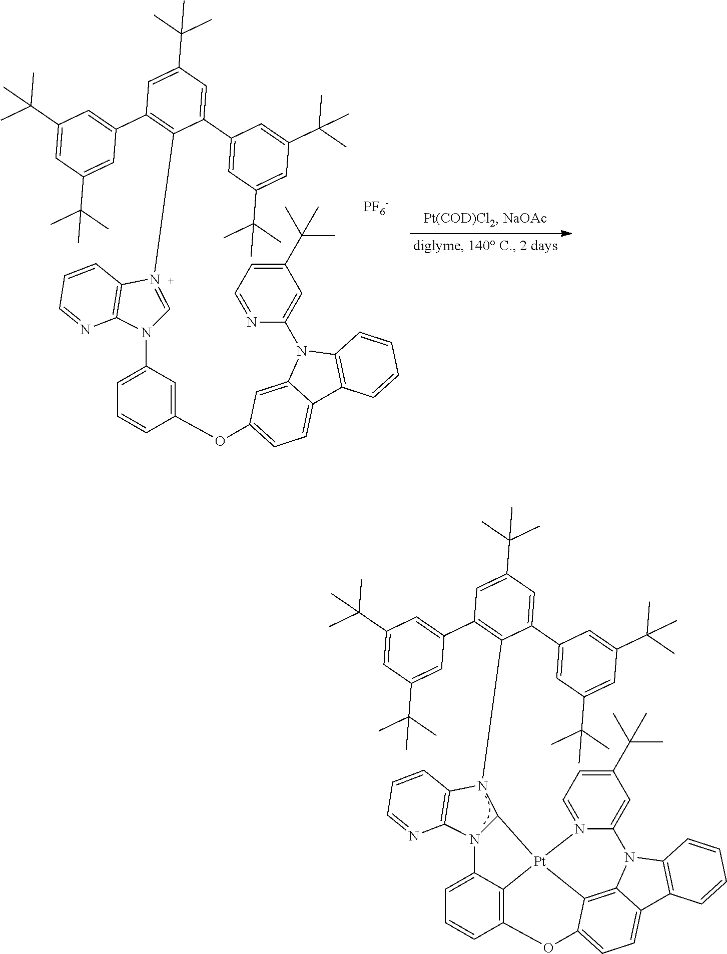

### Ex. 1-10:

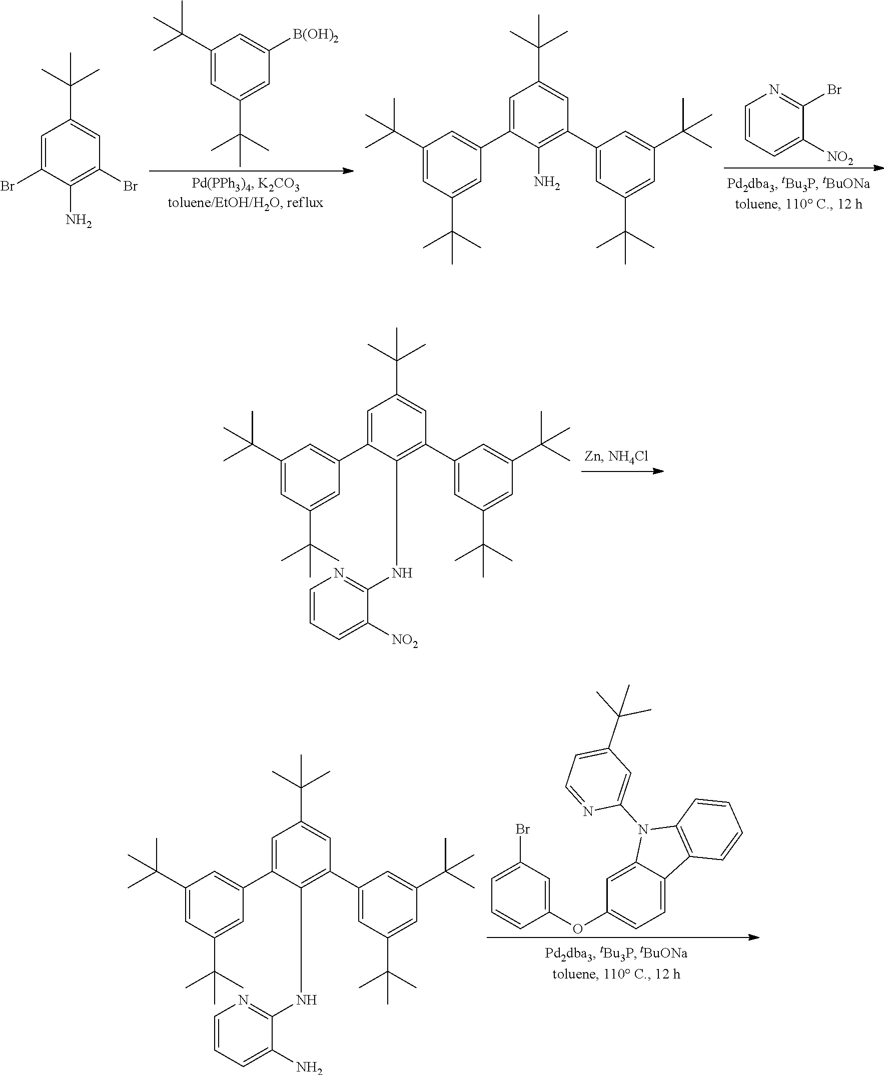

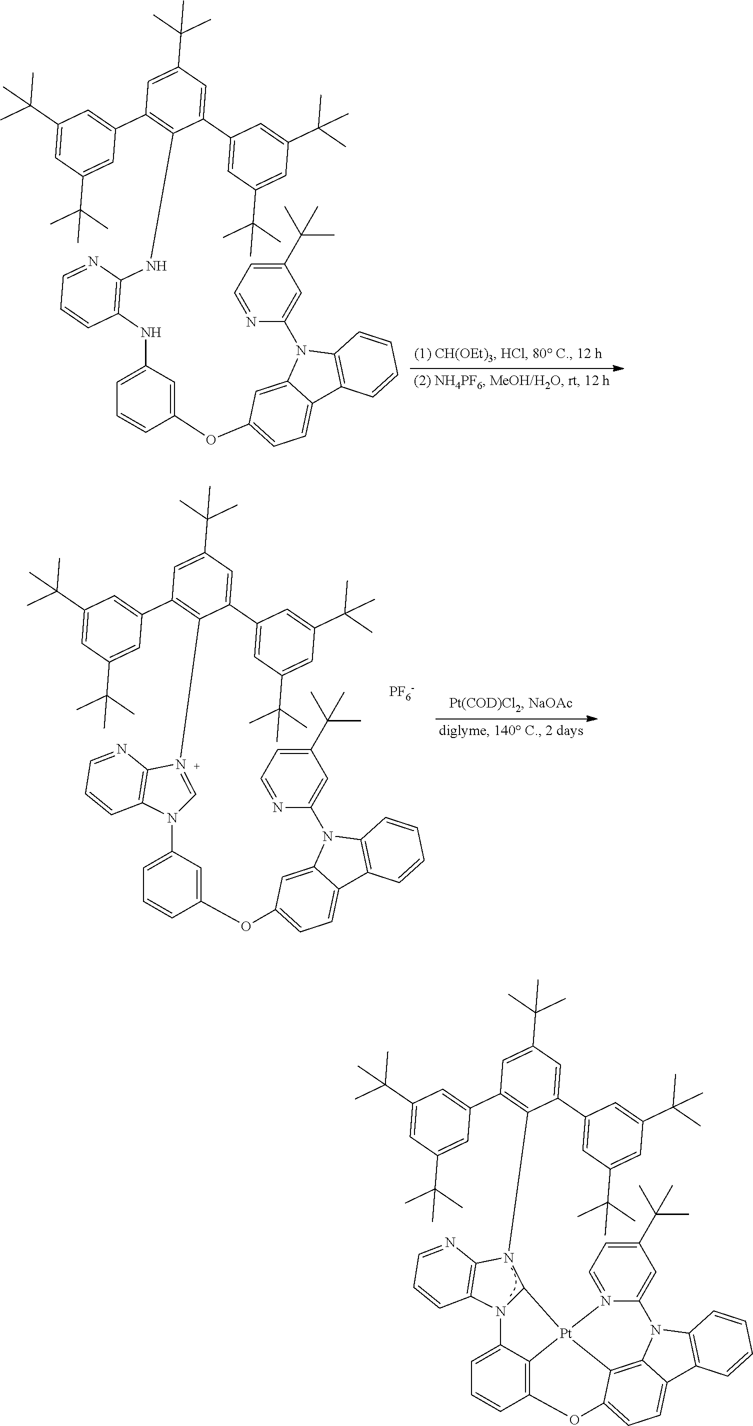

### Ex. 1-11:

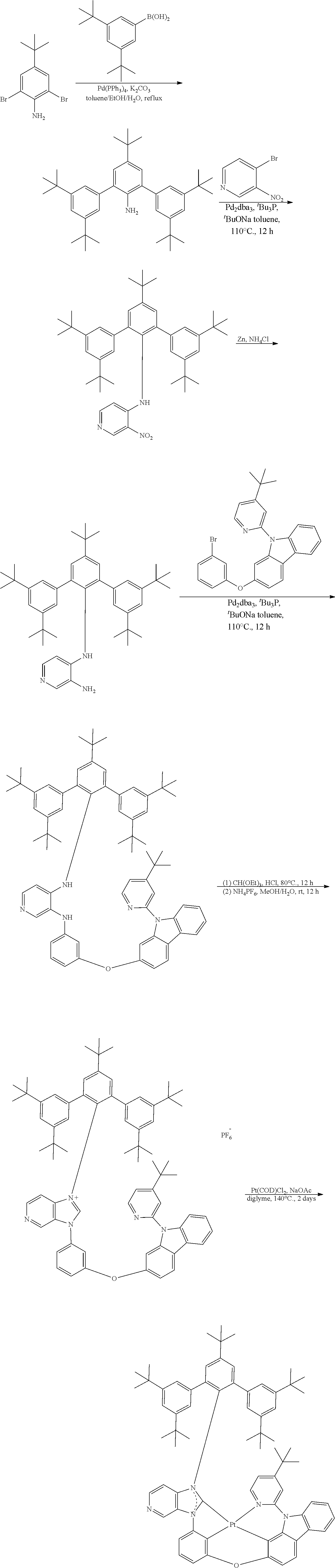

### Ex. 1-12:

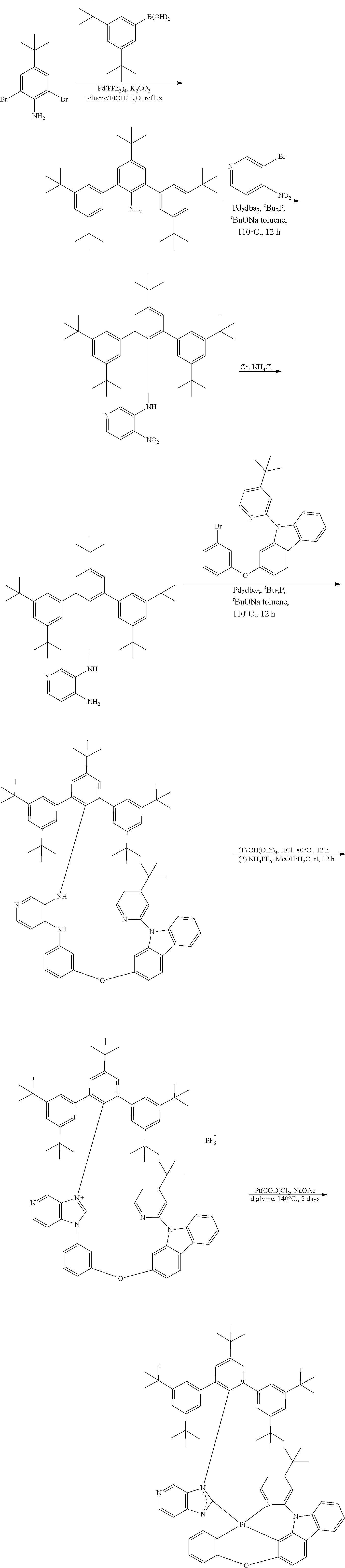

### Ex. 1-13:

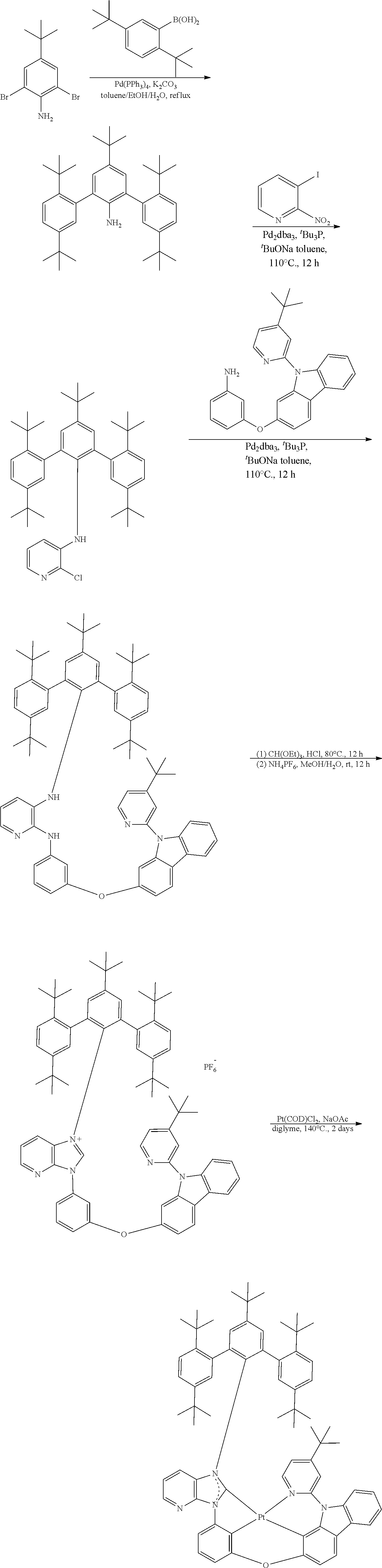

### Ex. 1-14:

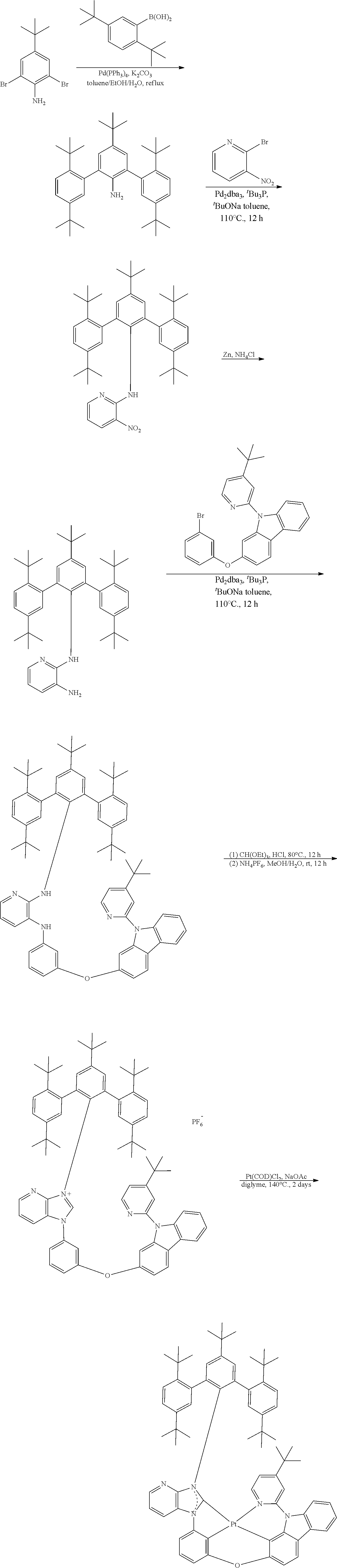

### Ex. 1-15:

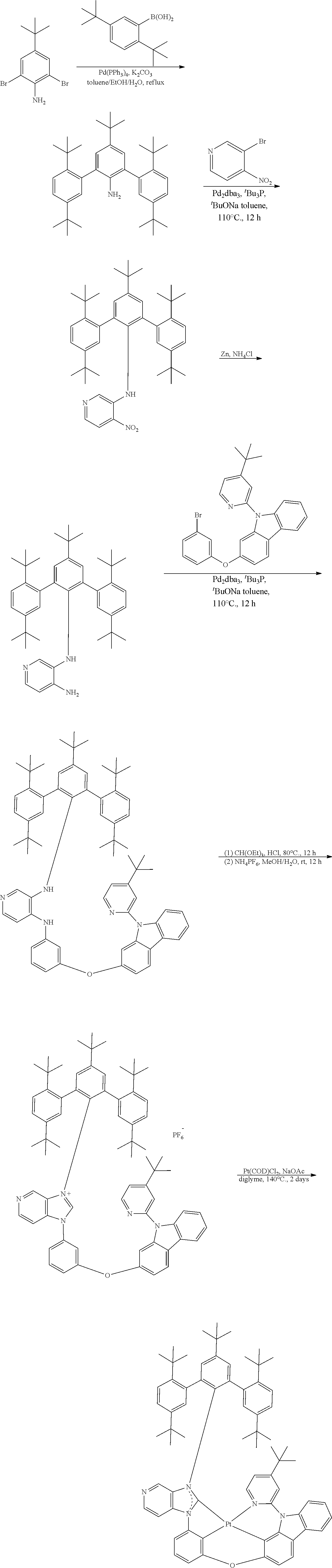

### Ex. 1-16:

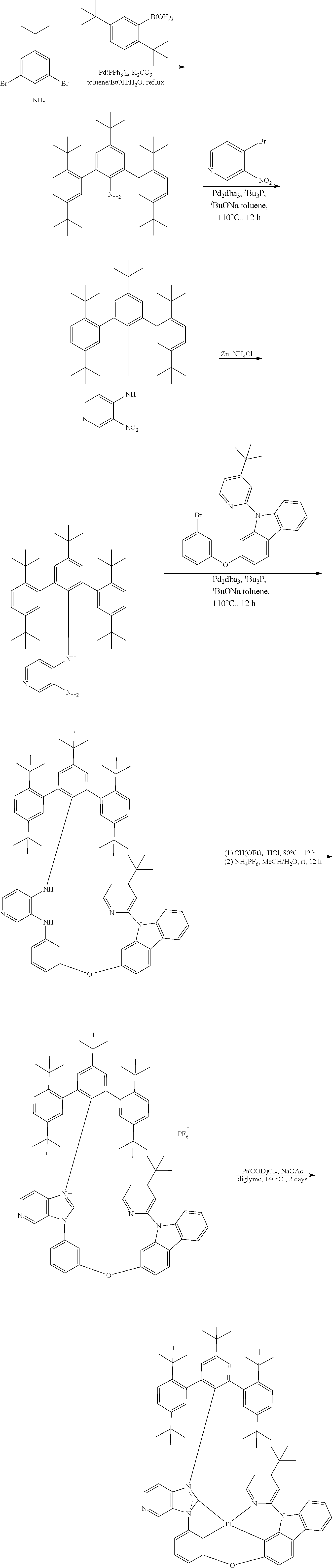

### Ex. 1-17:

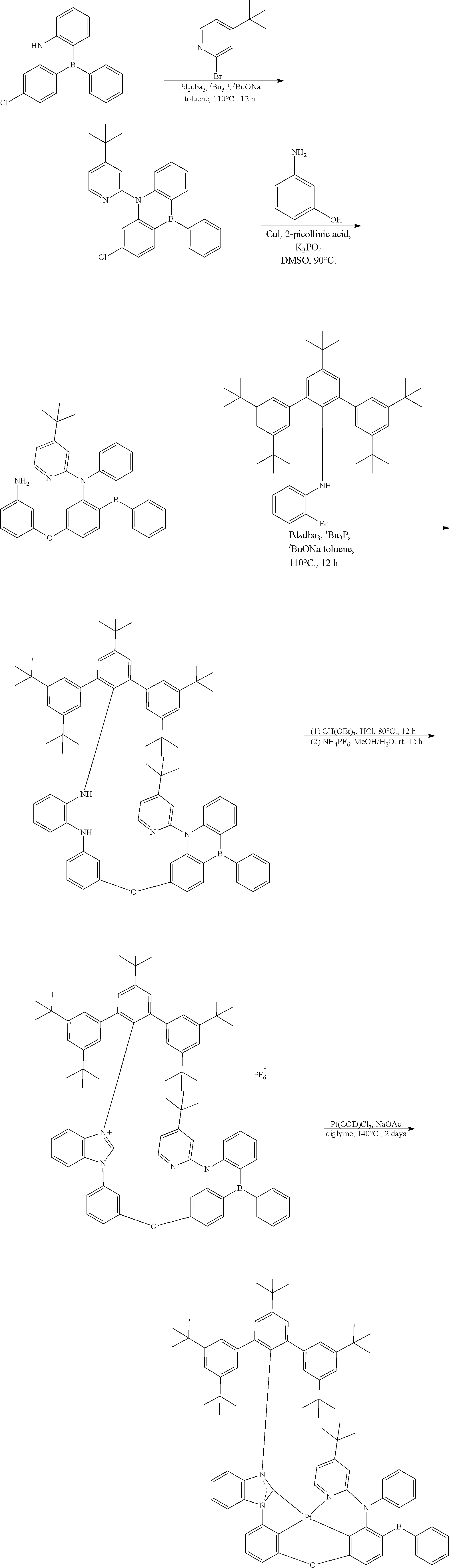

### Ex. 1-18:

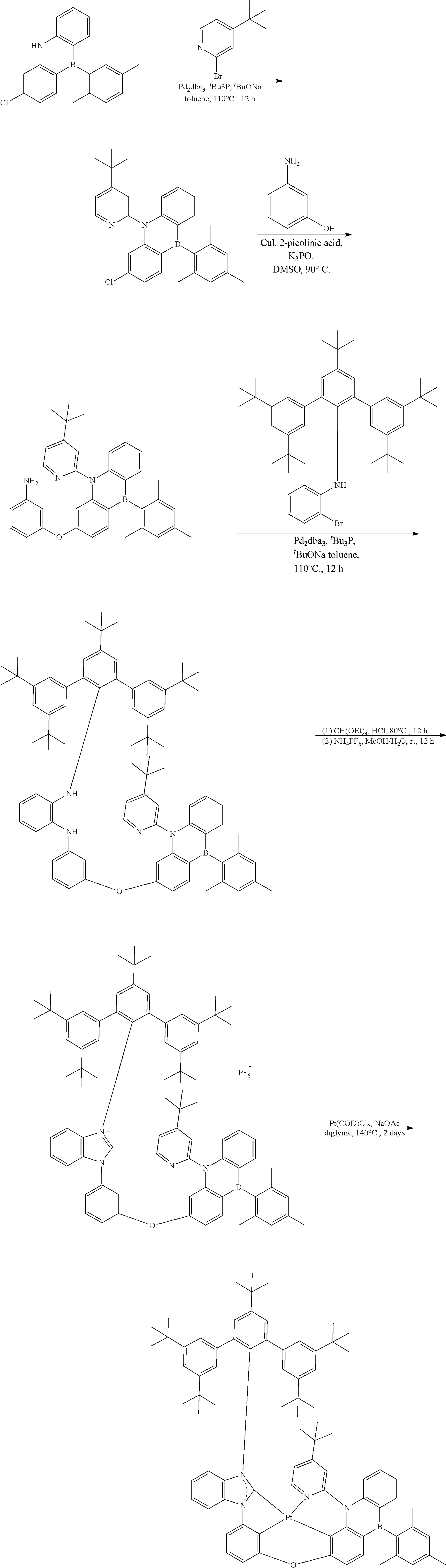

### Ex. 1-19:

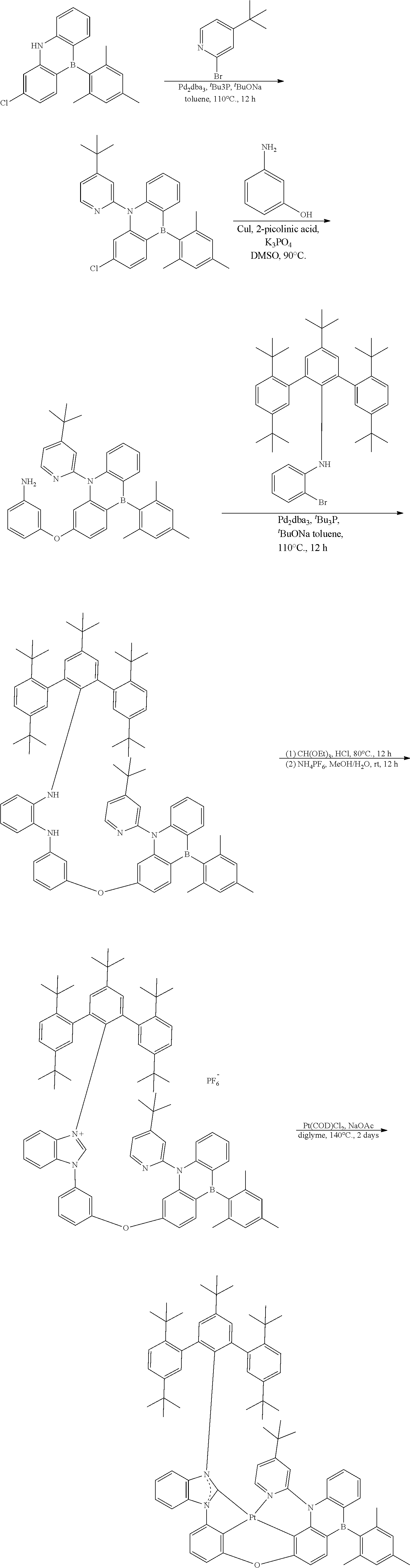

### Ex. 1-20:

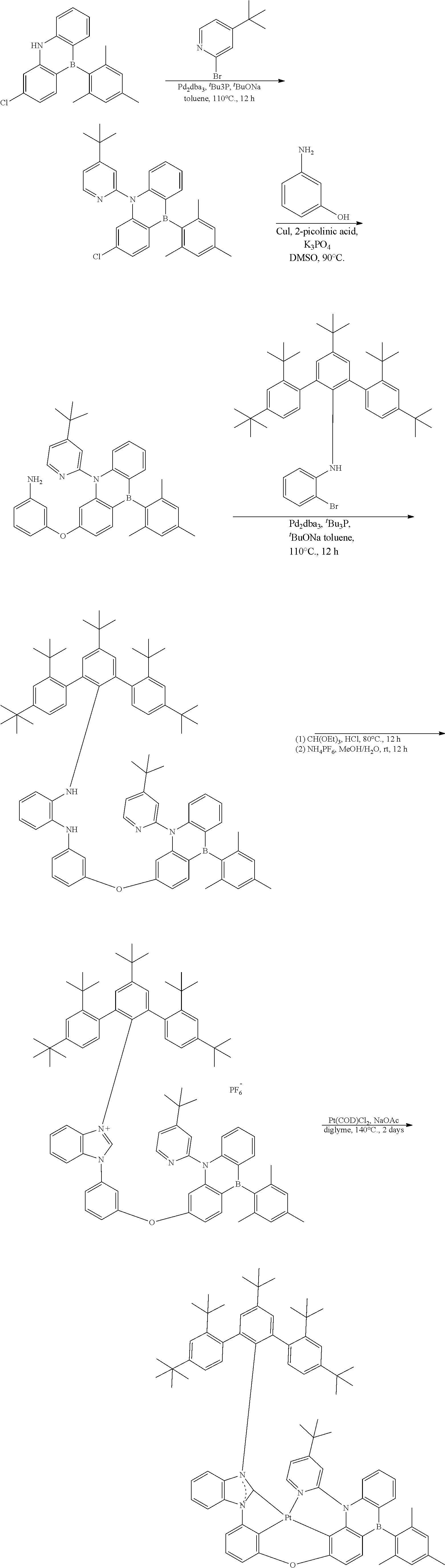

### Ex. 1-21:

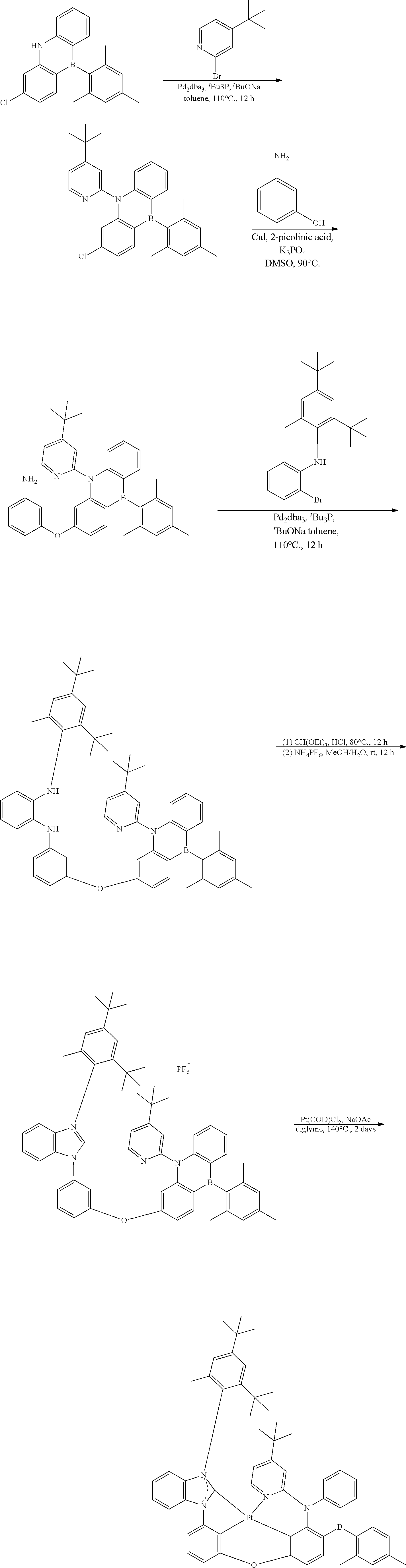

### Ex. 1-22:

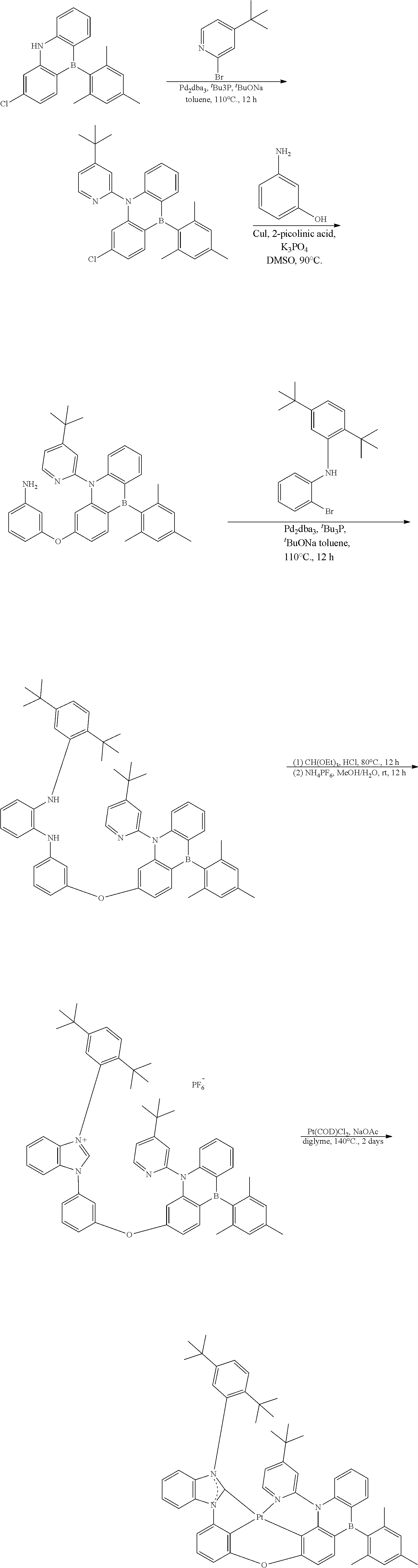

### Ex. 1-23:

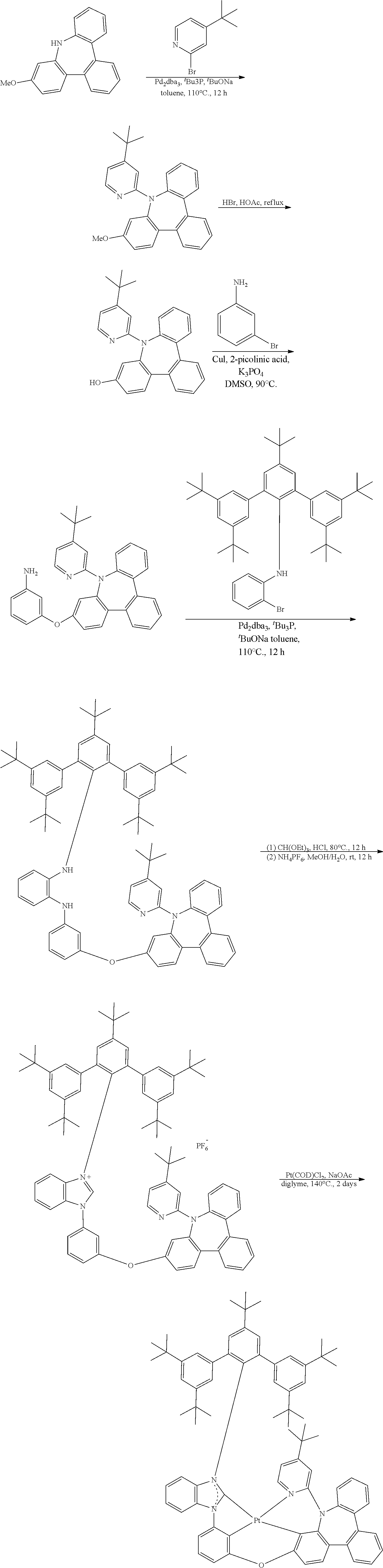

### Ex. 1-24:

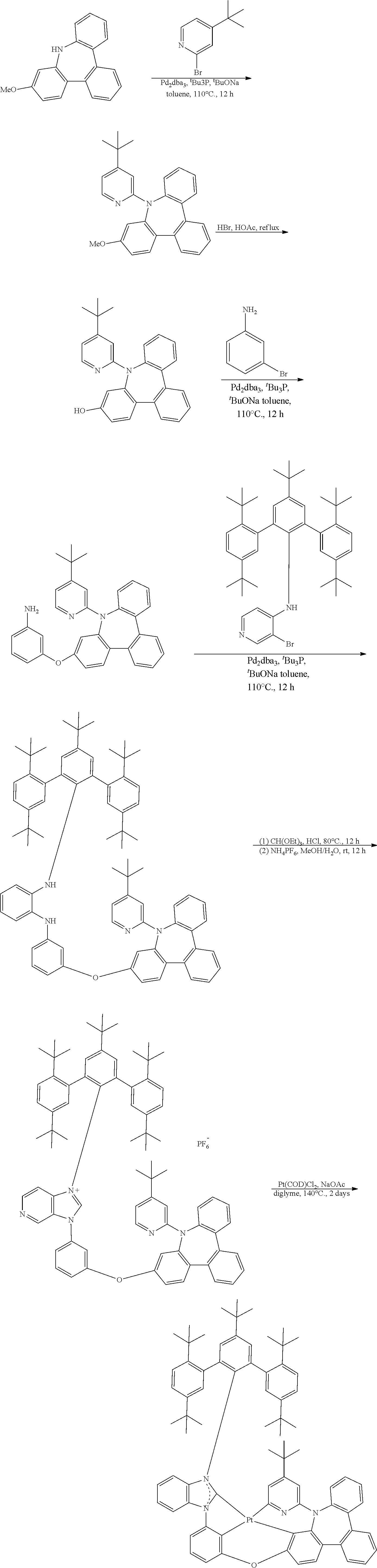

### Ex. 1-25:

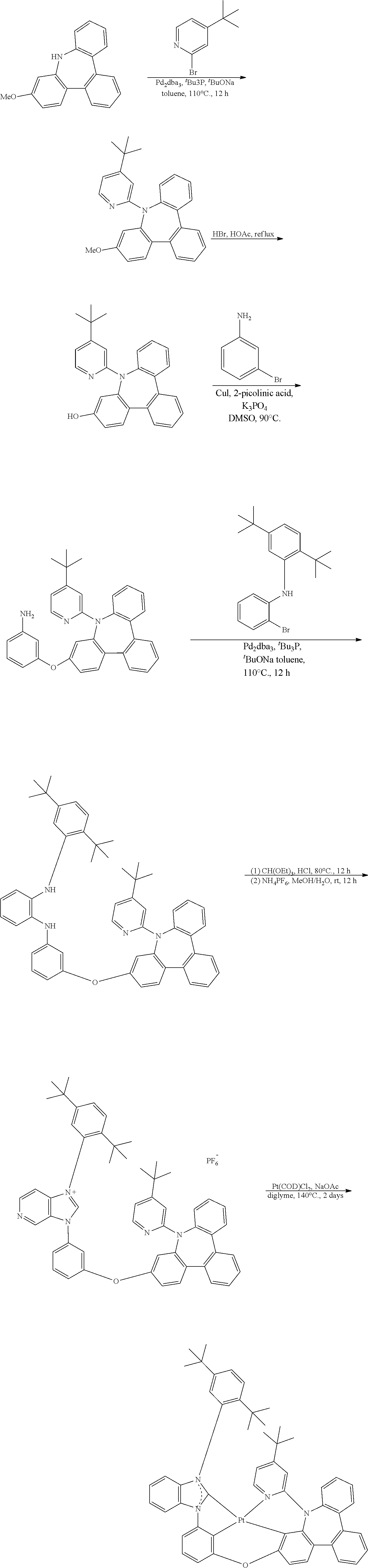

### Ex. 1-26:

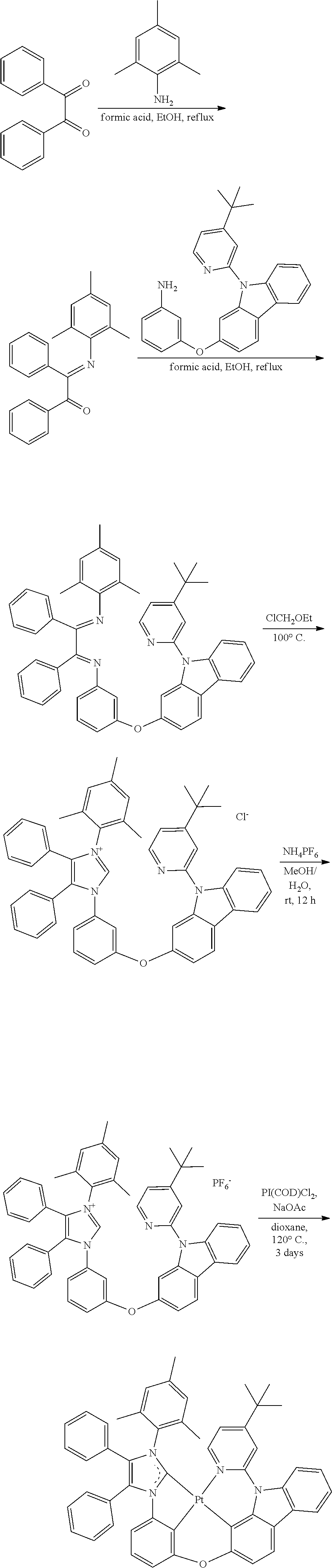

### Ex. 1-27:

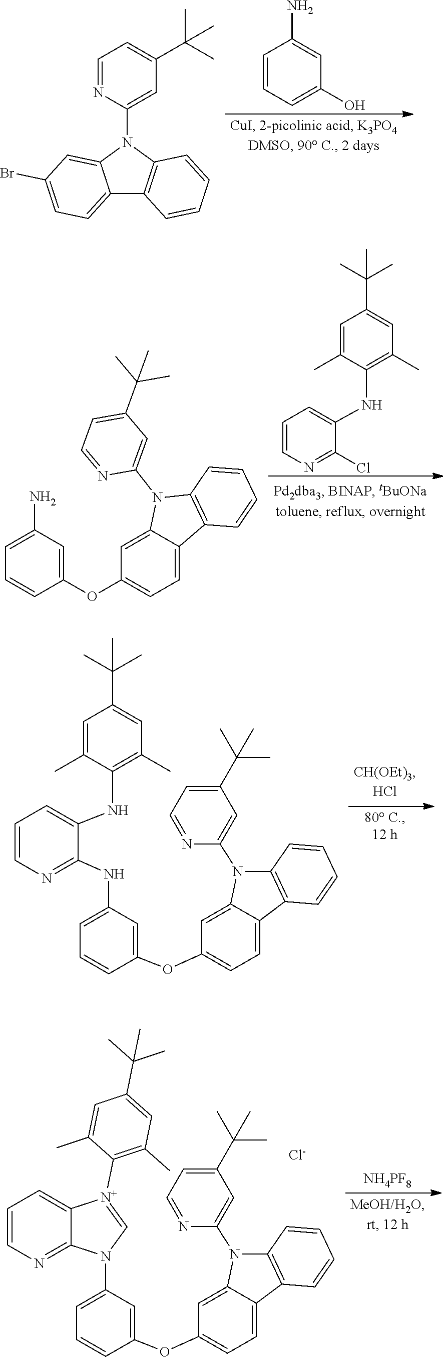

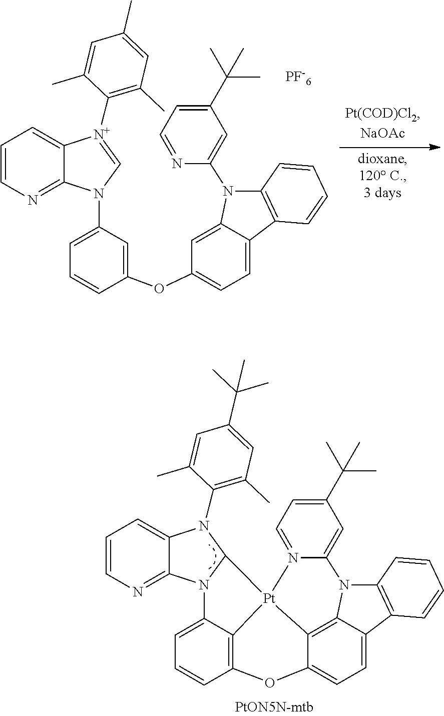

### Ex. 1-28:

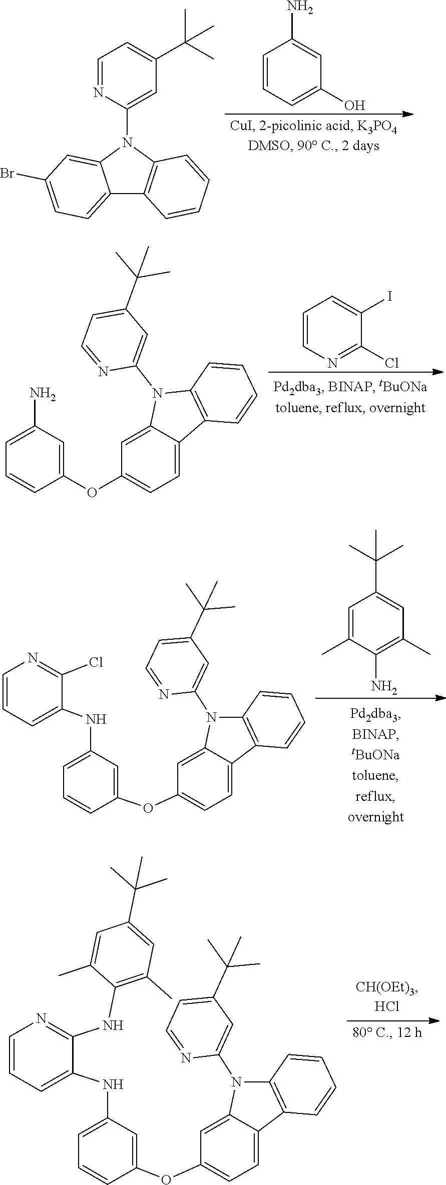

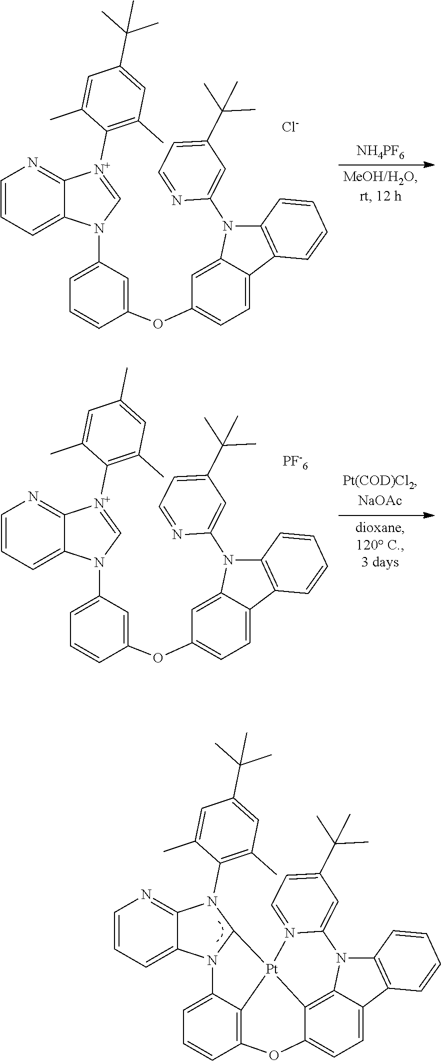

### Ex. 1-29:

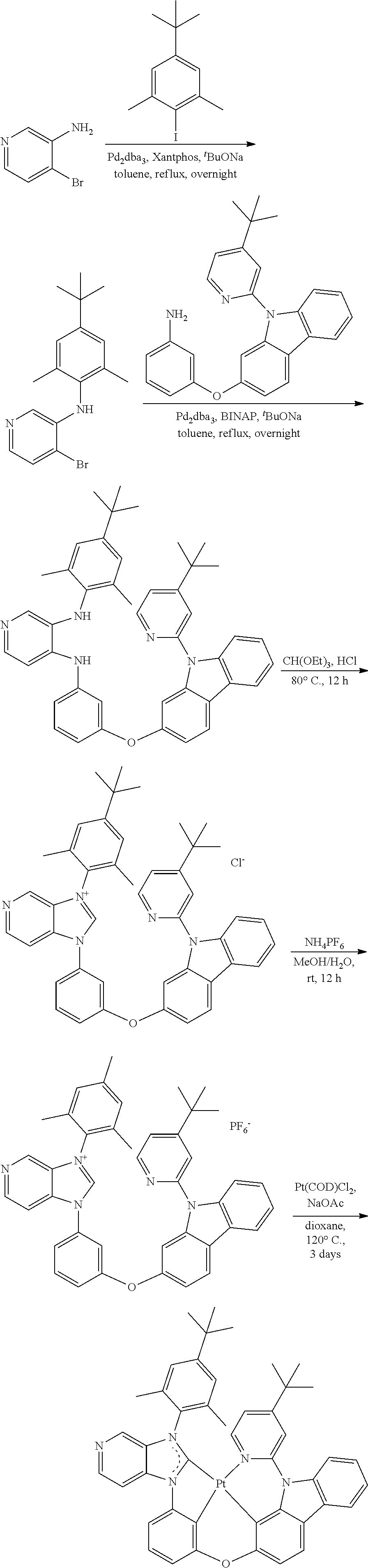

### Ex. 1-30:

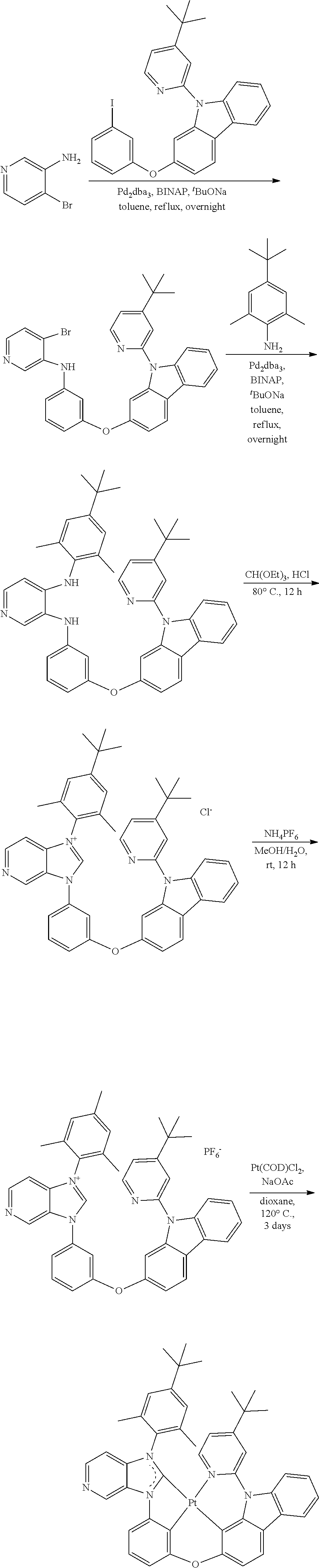

### Ex. 1-31:

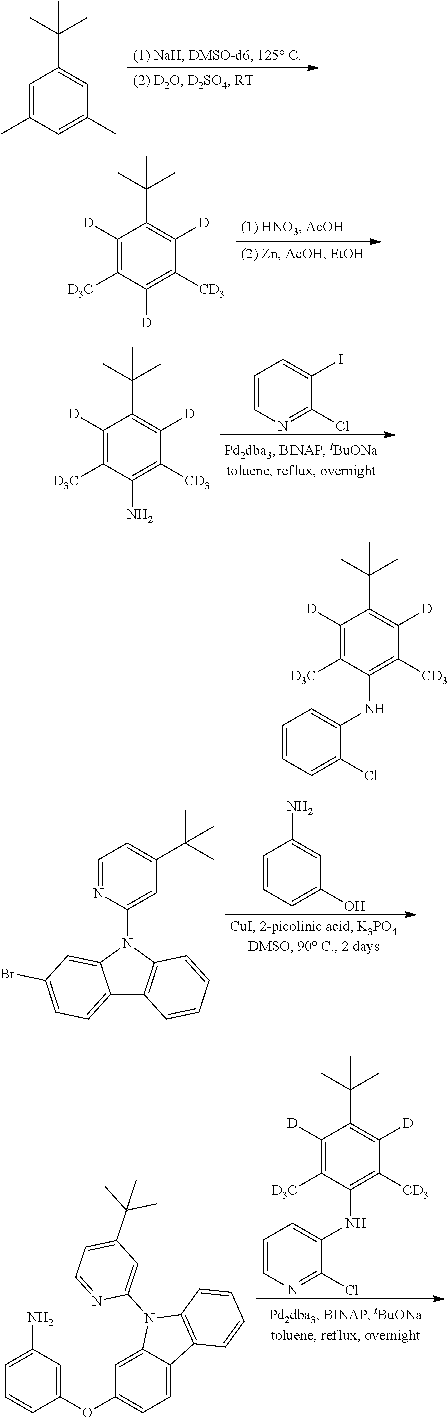

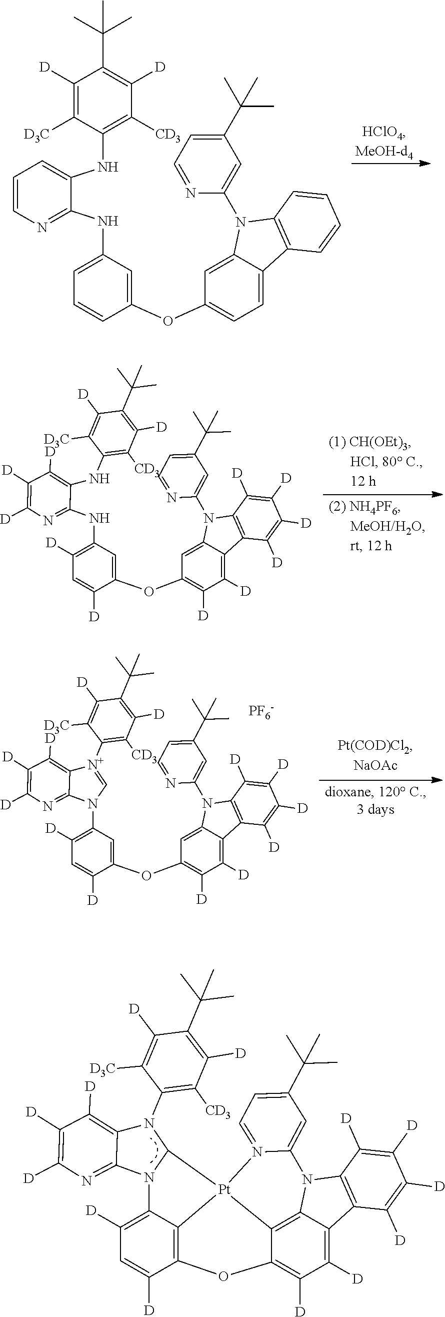

### Ex. 1-32:

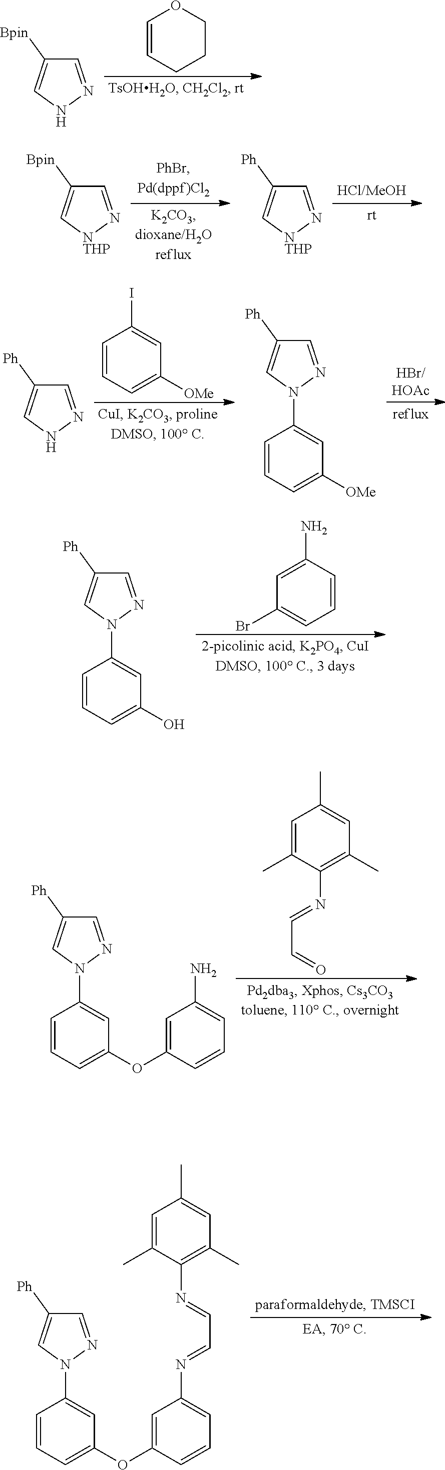

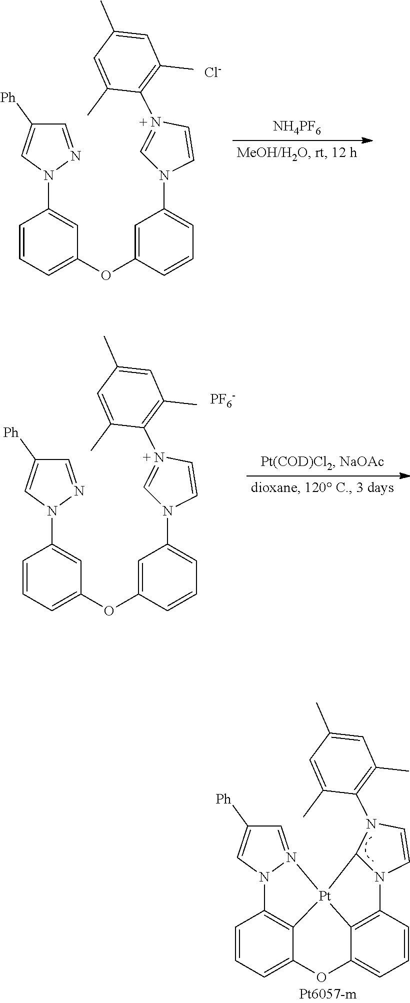

### Ex. 1-33:

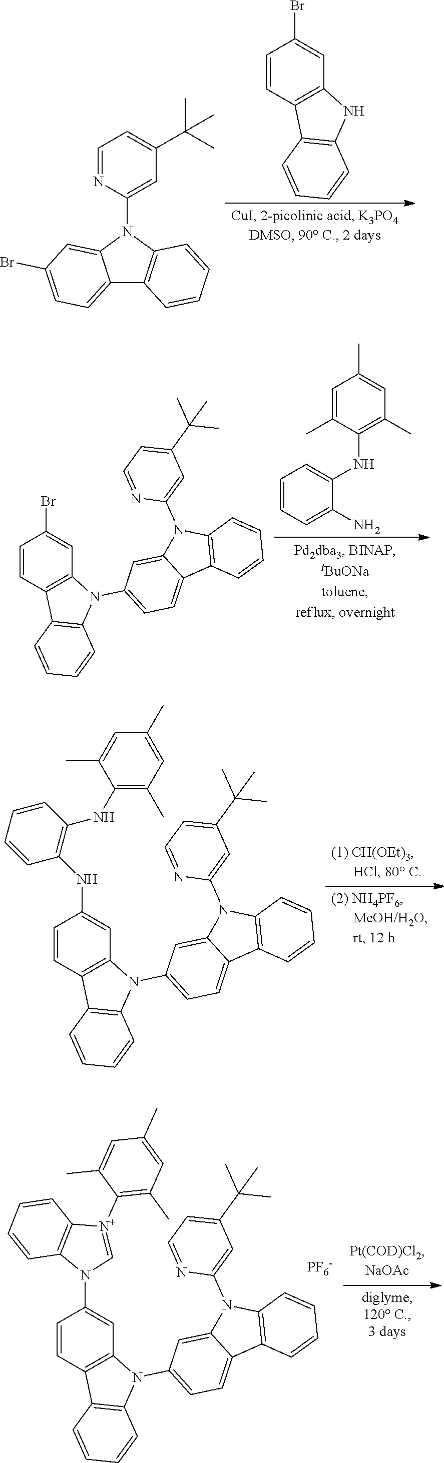

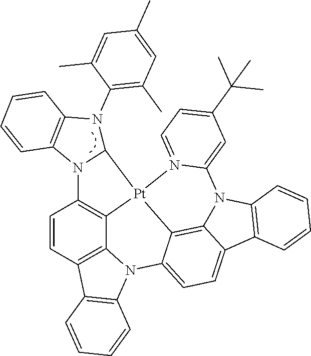

### Ex. 1-34:

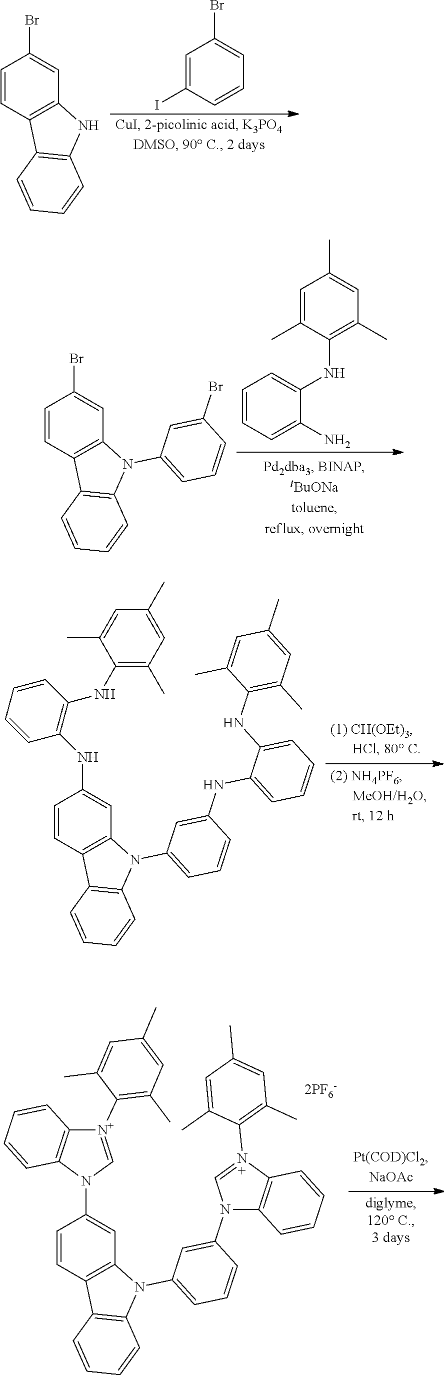

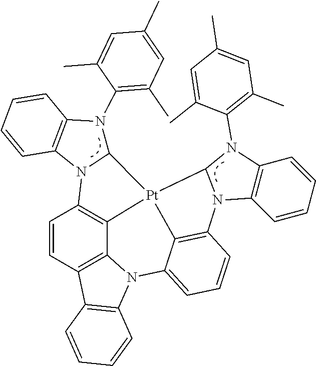

### Ex. 1-35:

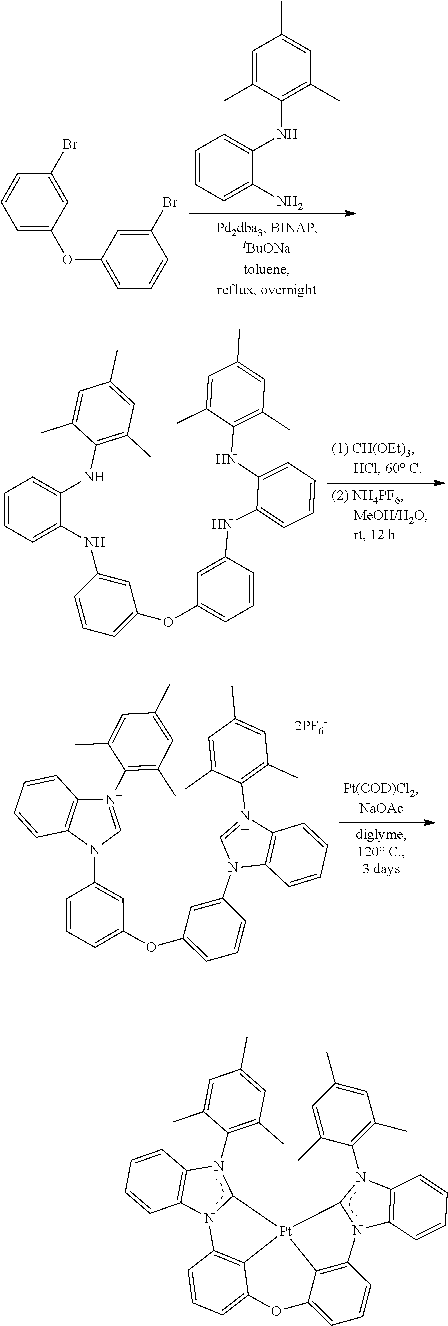

### Ex. 1-36:

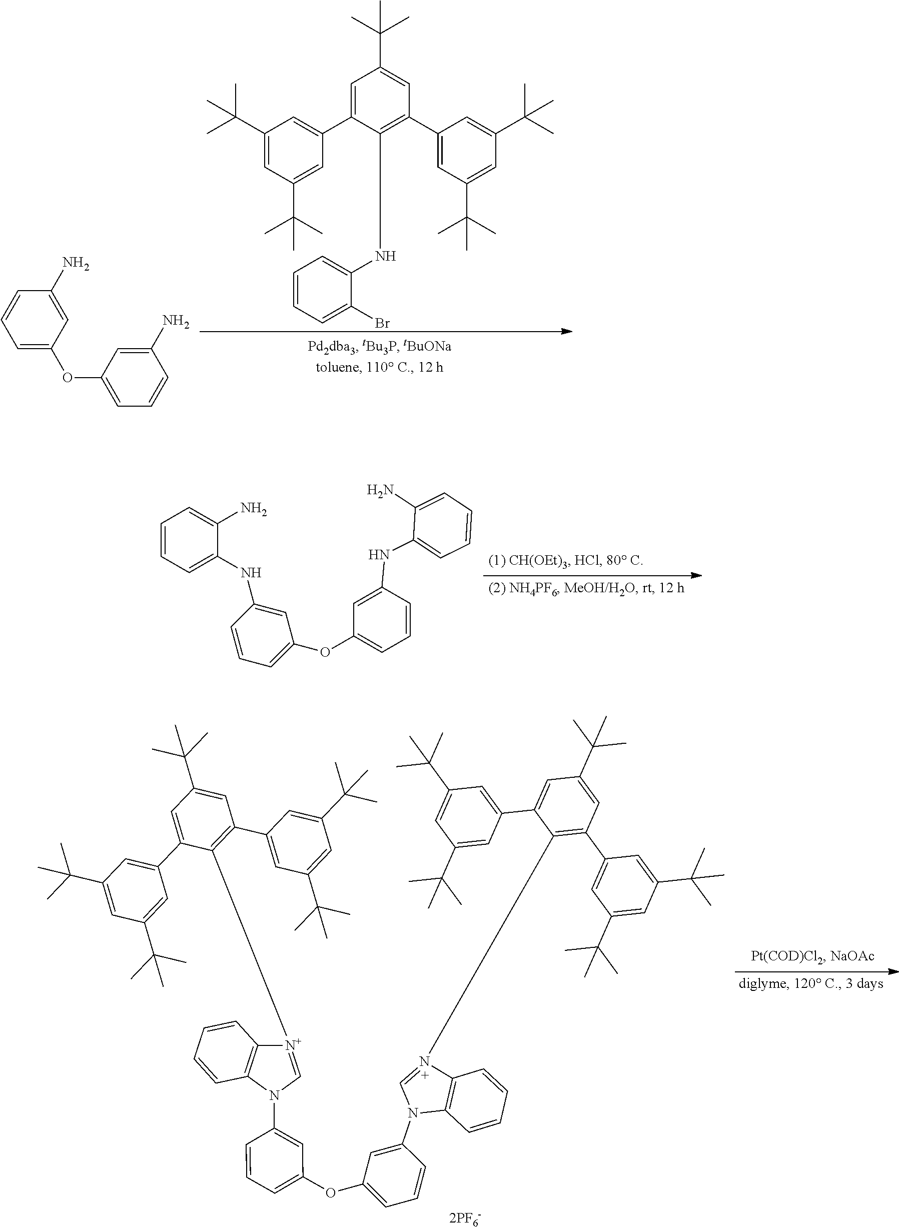

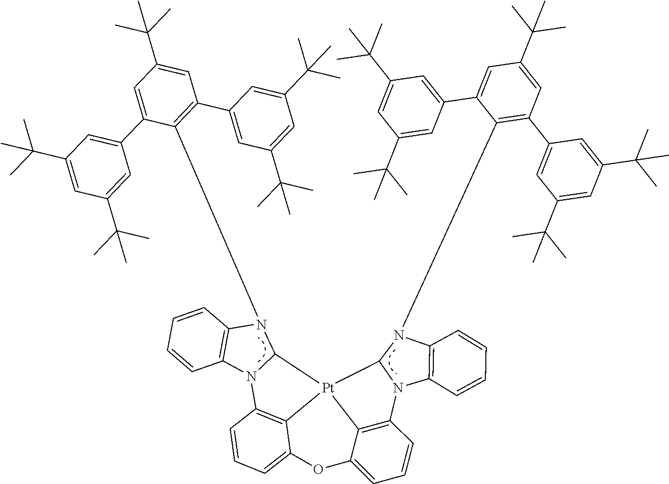

### Example 2: Tetradentate Metal Complex Emitters Based on Functionalized Imidazolyl Group and Its Analogues

Metal complexes employing functionalized imidazolyl and its analogues have been designed. In this innovation, a novel series of tetradentate platinum (II) and palladium (II) complexes, incorporating a functionalized imidazolyl group and their analogues, has been developed. These emitters from this class hold potential for applications in full-color displays and lighting. This class of emitters could be used for full color displays and lighting applications.

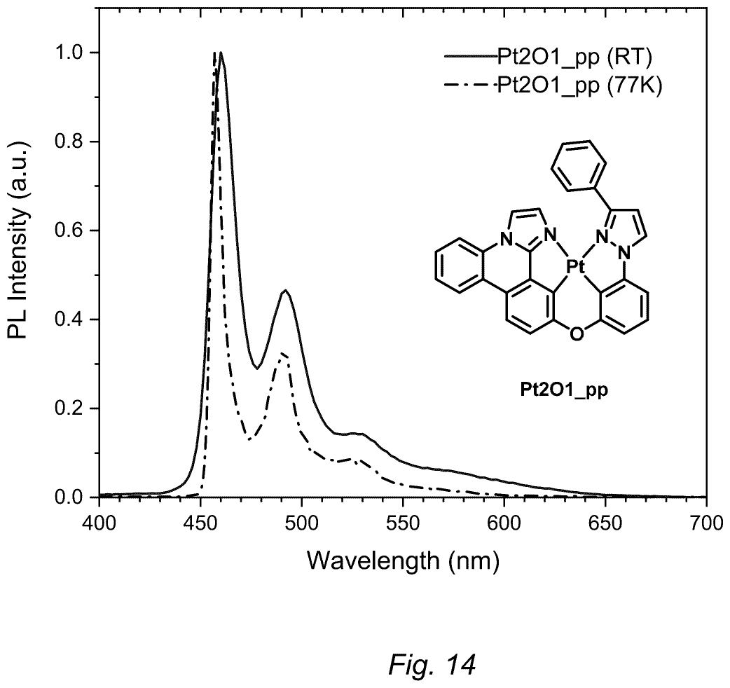

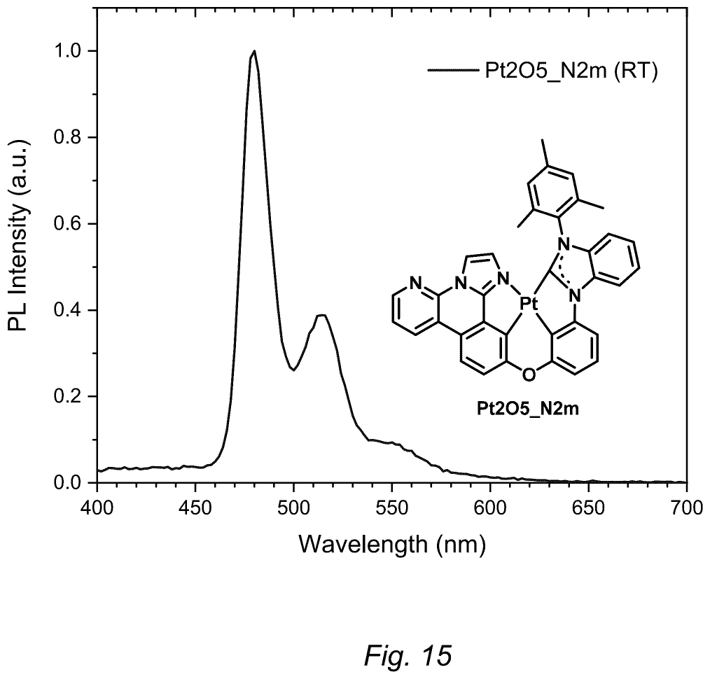

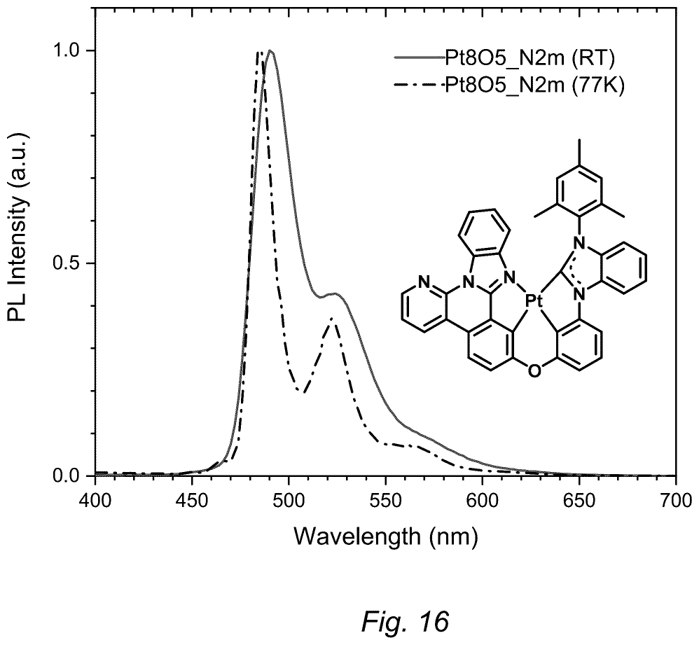

Photoluminescent spectra of exemplary compounds are presented in FIGS. 14, 15, and 16.

These compounds can be synthesized in the following manner:

### Ex. 1

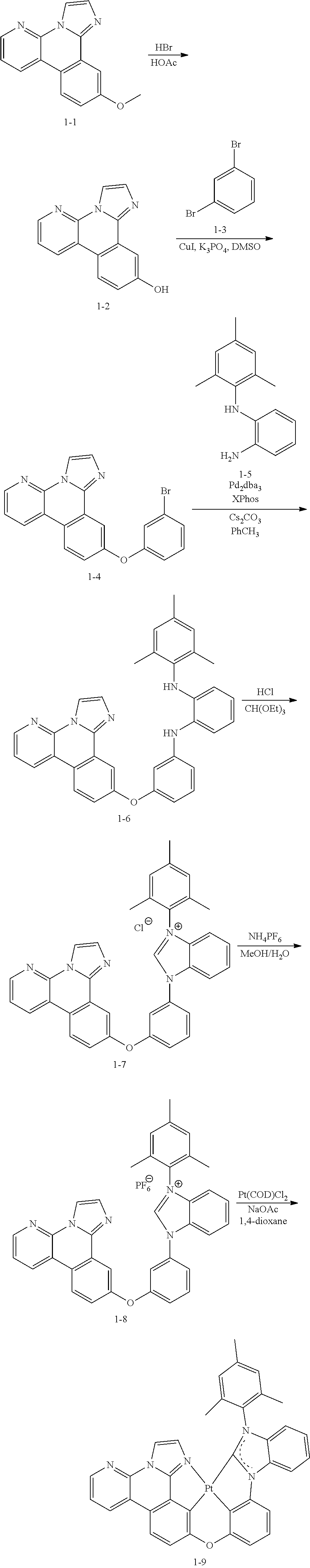

Preparation of 1-2: To a solution of 1-1 in acetic acid (0.1 M) was added aqueous HBr (48 wt %, 10 eq. The mixture was heated with 120° C. by oil bath for 12 hours. The mixture was cooled to room temperature and water (equal volume to acetic acid) was then added. The mixture was neutralized with solid K₂CO₃, to pH 5-6. The precipitate was collected by filtration, rinsed with water 3 times, and dried under reduced pressure. The yield was quantitative.

Preparation of 1-4: To a solution of 1-2 (1 eq) in DMSO (0.1 M) were added 1-3 (1.2 eq), Cul (0.1 eq), 2-picolinic acid (0.2 eq) and K₃PO₄ (2 eq). The reaction mixture was heated to reflux for 24 hours. The mixture was cooled to room temperature. Water (3 times the volume of DMSO) was then added. The mixture was extracted with EtOAc for 3 times. The combined organic phase was then concentrated. Purification by column chromatography (Hexane: EtOAc=8:1 to 3:1) gave the 1-4.

Preparation of 1-6: To an oven-dried flask were added 1-4 (1 eq), 1-5 (1.1 eq), Pd₂(dba)₃ (0.1 eq), XPhos (0.2 eq) and t-BuONa (2 eq). The flask was then evacuated and backfilled with nitrogen 3 times, following which toluene (0.1 M) was added by syringe. The mixture was heated to reflux for 12 hours. The mixture was cooled to room temperature and the product was isolated by column chromatography (Hexane:EtOAc 5:1 to 3:1) in 85% yield.

Preparation of 1-7: To a solution of 1-6 in CH(OEt)₃ (50 eq) was added aqueous HCl (a.q.) (37 wt %, 5 eq). The mixture was heated with 100° C. by oil bath for 12 hours. The mixture was cooled to room temperature and water (equal volume to HCl (aq.)) was then added. The mixture was neutralized with solid K₂CO₃, to pH 7-8. The precipitate was collected by filtration, rinsed with water 3 times, and dried under reduced pressure. The product 1-7 was isolated by column chromatography (DCM: MeOH 25:1 to 15:1) in 81% yield.

Preparation of 1-8: To a solution of 1-7 in MeOH/H₂O (2/1) was added NH₄PF₆ (2 eq). The mixture was stirred at R.T. for or 12 hours. The precipitate was collected by filtration, rinsed with water 3 times, and dried under reduced pressure. The yield was quantitative.

Preparation of 1-9: To a solution of 1-8 (1 eq) in 1,4-dioxane (0.2 M) were added Pt(COD)Cl₂ (1.1 eq) and NaOAc (2 eq). The mixture was heated to reflux for 3 days. The reaction mixture was cooled to room temperature and filtered through a short pad of silica gel. The filtrate was concentrated under reduced pressure. Purification by column chromatography (Hexane: DCM=1:2 to 1:3) gave the 1-9 in 48% yield.

### Ex. 2

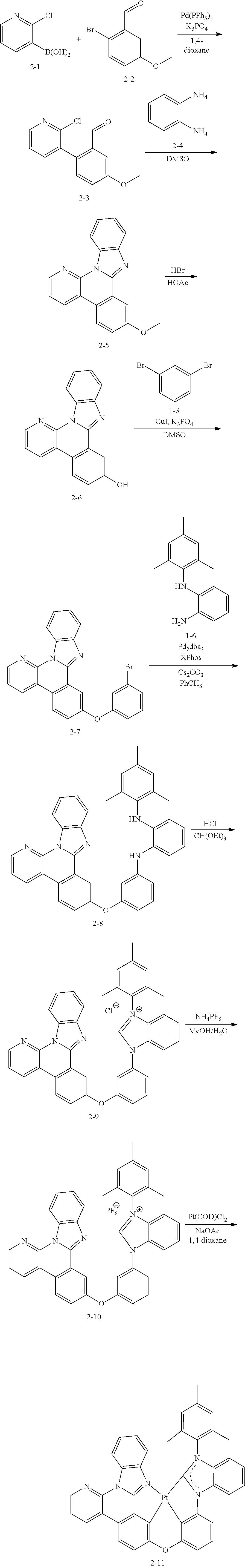

### Procedure:

Preparation of 2-3: To an oven-dried flask were added 2-1 (1.1 eq), 2-2 (1 eq), and Pd(PPh₃)₄, (0.05 eq). The flask was then evacuated and backfilled with nitrogen 3 times. Aqueous K₃PO₄ (2 M, 3 eq) and 1,4-dioxane (0.2 M) were then added. The mixture was heated with 100° C. by oil bath for about 10 hours. The mixture was cooled to room temperature and the product was isolated by column chromatography (Hexane:EtOAc=5:1 to 1:1) in 80% yield.

Preparation of 2-3: To a solution of 2-3 (1 eq) in DMSO (0.1 M) were added 2-4 (1.2 eq). The reaction mixture was heated to 130° C. for 24 hours. The mixture was cooled to room temperature. Water (3 times the volume of DMSO) was then added. The mixture was extracted with EtOAc for 3 times. The combined organic phase was then concentrated. Purification by column chromatography (Hexane: EtOAc=8:1 to 3:1) gave the 2-5.

Preparation of 2-6: To a solution of 2-5 in acetic acid (0.1 M) was added aqueous HBr (48 wt %, 10 eq. The mixture was heated with 120° C. by oil bath for 12 hours. The mixture was cooled to room temperature and water (equal volume to acetic acid) was then added. The mixture was neutralized with solid K₂CO₃, to pH 5-6. The precipitate was collected by filtration, rinsed with water 3 times, and dried under reduced pressure. The yield was quantitative.

Preparation of 2-7: To a solution of 2-6 (1 eq) in DMSO (0.1 M) were added 1-3 (1.2 eq), Cul (0.1 eq), 2-picolinic acid (0.2 eq) and K₃PO₄ (2 eq). The reaction mixture was heated to reflux for 24 hours. The mixture was cooled to room temperature. Water (3 times the volume of DMSO) was then added. The mixture was extracted with EtOAc for 3 times. The combined organic phase was then concentrated. Purification by column chromatography (Hexane: EtOAc=8:1 to 3:1) gave the 2-7.

Preparation of 2-8: To an oven-dried flask were added 2-7 (1 eq), 1-5 (1.1 eq), Pd₂(dba)₃ (0.1 eq), XPhos (0.2 eq) and t-BuONa (2 eq). The flask was then evacuated and backfilled with nitrogen 3 times, following which toluene (0.1 M) was added by syringe. The mixture was heated to reflux for 12 hours. The mixture was cooled to room temperature and the product was isolated by column chromatography (Hexane:EtOAc 5:1 to 3:1) in 85% yield.

Preparation of 2-9: To a solution of 2-8 in CH(OEt)₃ (50 eq) was added aqueous HCl (a.q.) (37 wt %, 5 eq). The mixture was heated with 100° C. by oil bath for 12 hours. The mixture was cooled to room temperature and water (equal volume to HCl (aq.)) was then added. The mixture was neutralized with solid K₂CO₃, to pH 7-8. The precipitate was collected by filtration, rinsed with water 3 times, and dried under reduced pressure. The product 2-9 was isolated by column chromatography (DCM: MeOH 25:1 to 15:1) in 81% yield.

Preparation of 2-10: To a solution of 2-9 in MeOH/H₂O (2/1) was added NH₄PF₆ (2 eq). The mixture was stirred at R.T. for or 12 hours. The precipitate was collected by filtration, rinsed with water 3 times, and dried under reduced pressure. The yield was quantitative.

Preparation of 2-11: To a solution of 2-10 (1 eq) in 1,4-dioxane (0.2 M) were added Pt(COD)Cl₂ (1.1 eq) and NaOAc (2 eq). The mixture was heated to reflux for 3 days. The reaction mixture was cooled to room temperature and filtered through a short pad of silica gel. The filtrate was concentrated under reduced pressure. Purification by column chromatography (Hexane: DCM=1:2 to 1:3) gave the 2-11 in 48% yield.

### Ex. 3

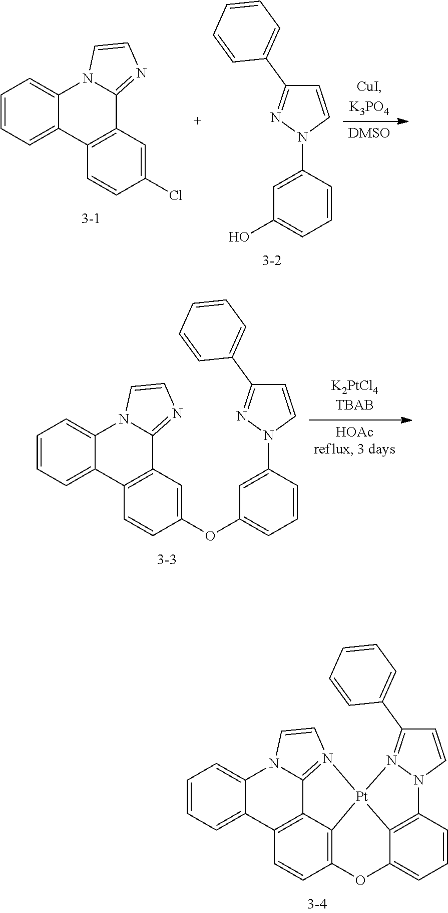

Preparation of 3-3: To a solution of 3-1 (1 eq) in DMSO (0.1 M) were added 3-2 (1.2 eq), Cul (0.1 eq), 2-picolinic acid (0.2 eq) and K₃PO₄ (2 eq). The reaction mixture was heated to reflux for 24 hours. The mixture was cooled to room temperature. Water (3 times the volume of DMSO) was then added. The mixture was extracted with EtOAc for 3 times. The combined organic phase was then concentrated. Purification by column chromatography (Hexane: EtOAc=3:1 to 1:1) gave the 3-3.

Preparation of 3-4: To a solution of 3-3 (1 eq) in HOAc (0.2 M) were added K₂PtCl₄ (1.1 eq) and TBAB (0.2 eq). The mixture was heated to reflux for 3 days. The reaction mixture was cooled to room temperature and filtered through a short pad of silica gel. The filtrate was concentrated under reduced pressure. Purification by column chromatography (Hexane: DCM=1:2 to 1:3) gave the 3-4 in 52% yield.

### Ex. 4

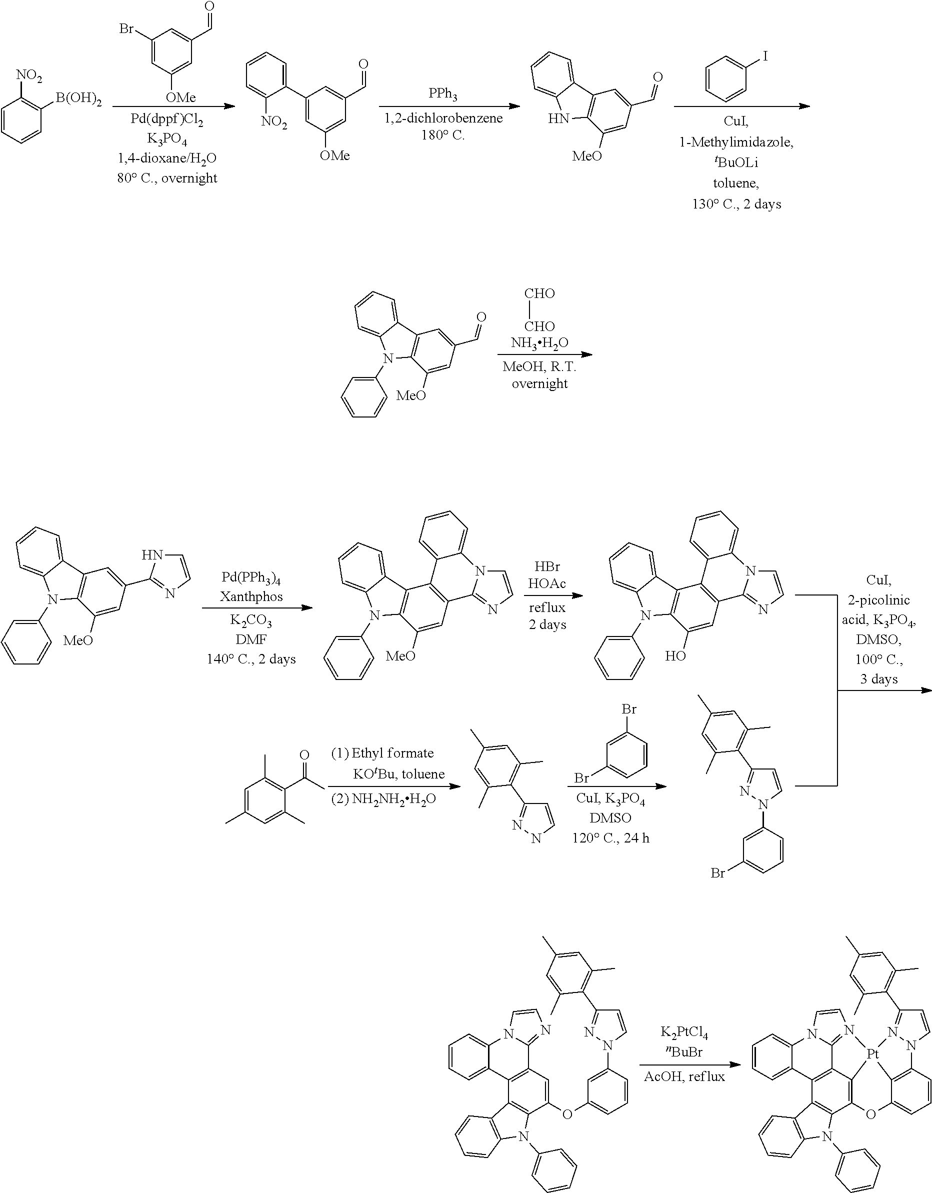

### Ex. 5

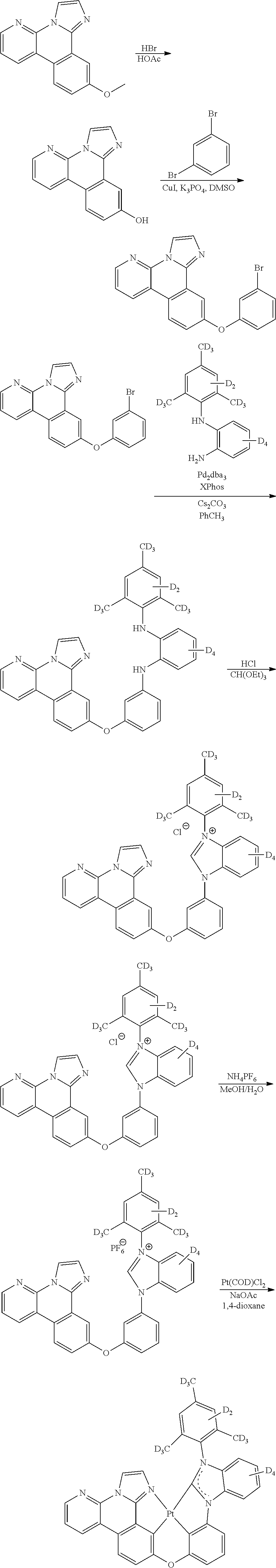

### Ex. 6

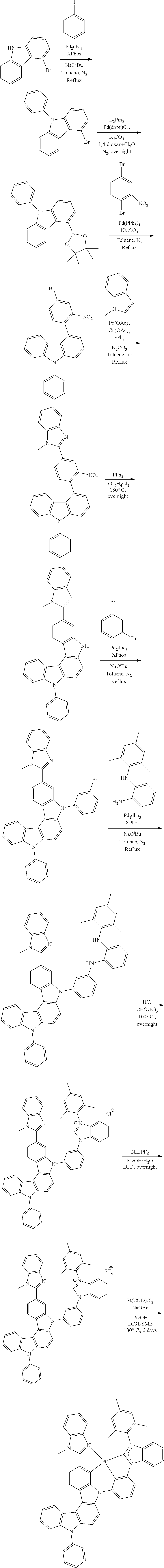

### Example 3: Tetradentate Platinum and Palladium Complex Emitters with Narrow Emission Spectrum Enabled by Rigid Structure Design Based on Phenyl-Benzocarbene and its Analogues

In this invention, a series of tetradentate platinum and palladium complexes enabled by rigid structure design based on phenyl-benzocarbene and its analogues have been designed. This class of emitters could be found utilization for full color displays and lighting applications.

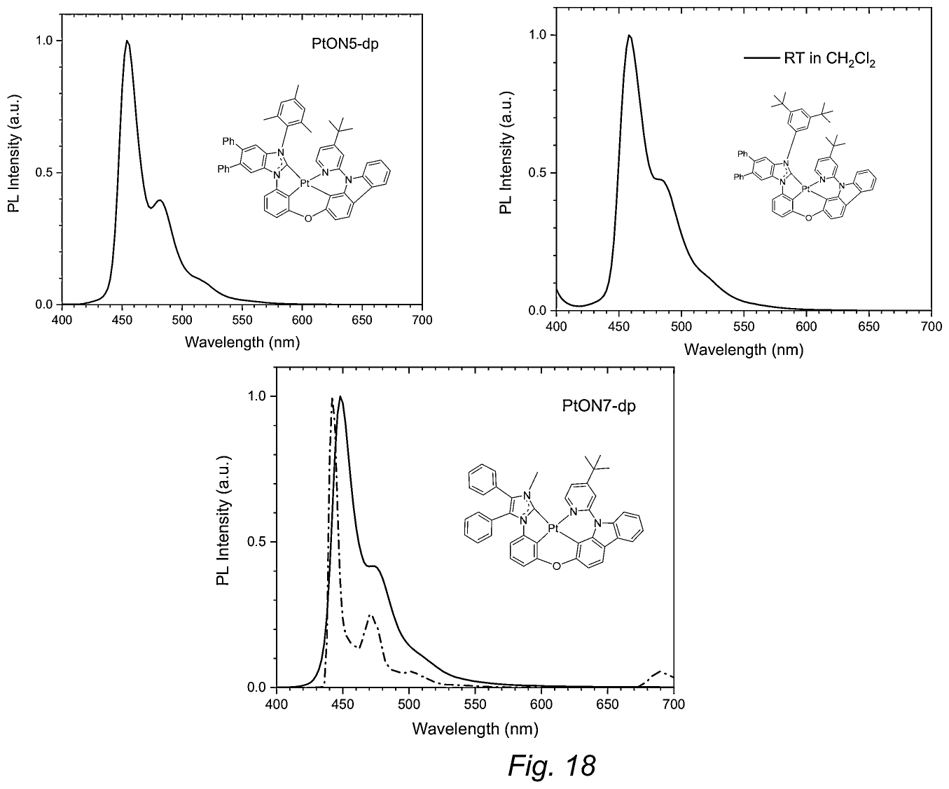

PL spectra of exemplary compounds are shown in FIG. 18.

Inventive compounds can be synthesized in the following manner:

### Ex. 1

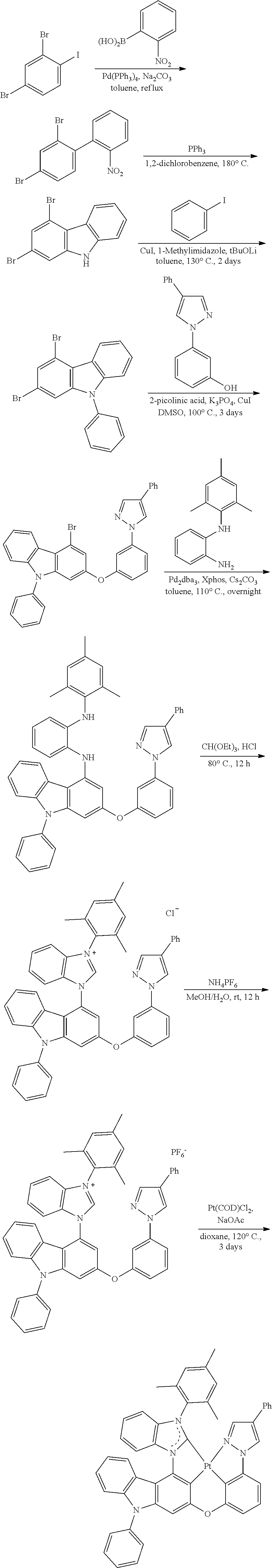

### Ex. 2

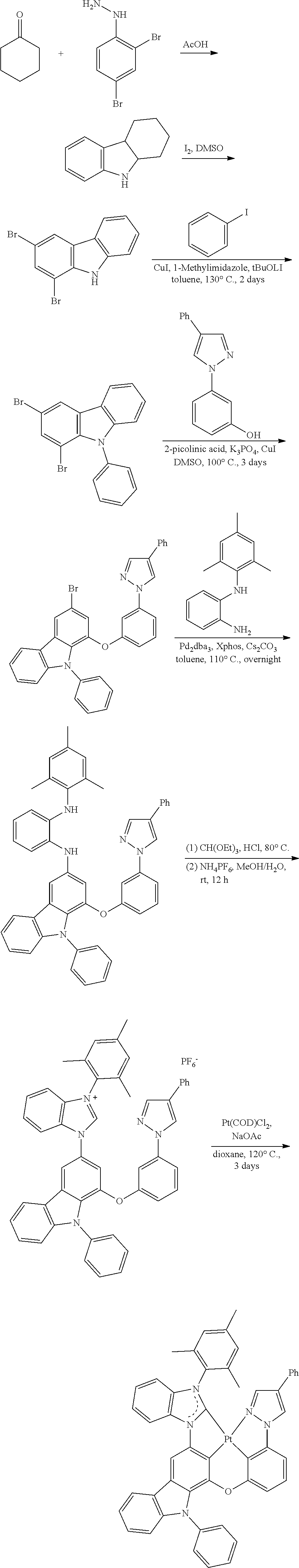

### Ex. 3

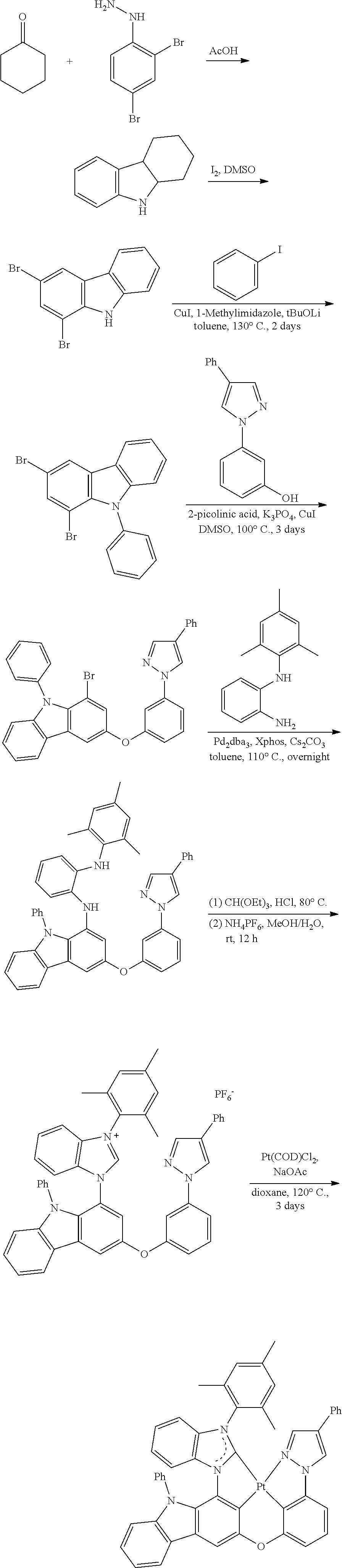

### Ex. 4

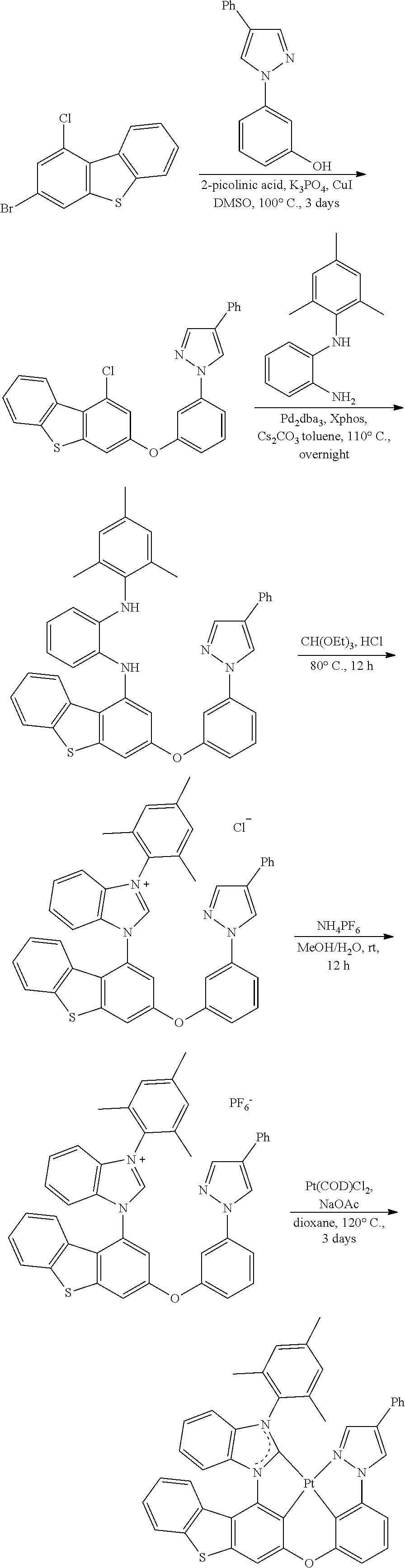

### Ex. 5

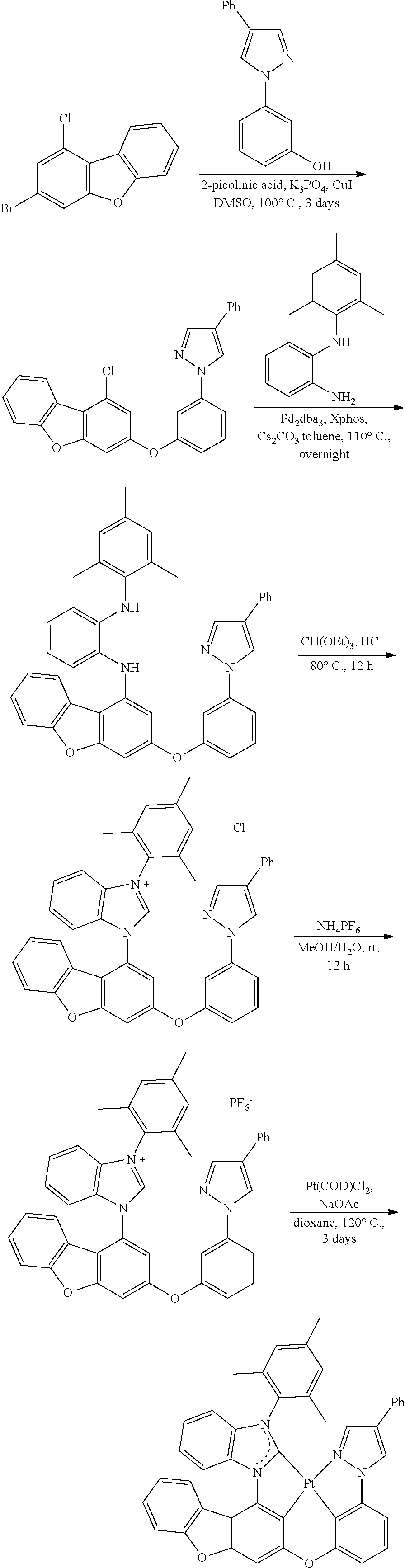

### Ex. 6

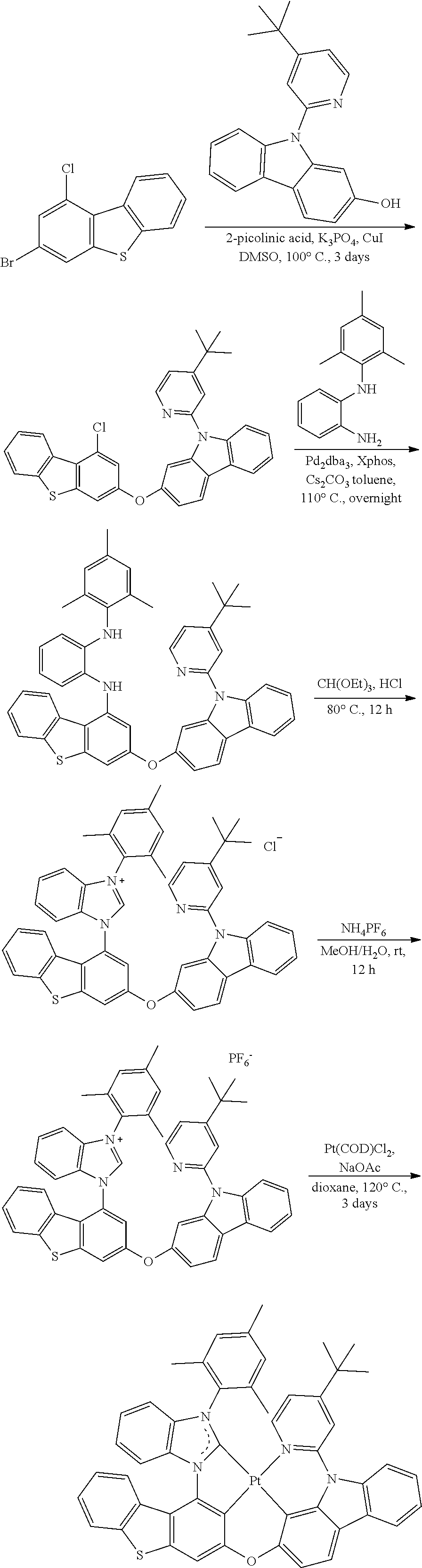

### Ex. 7

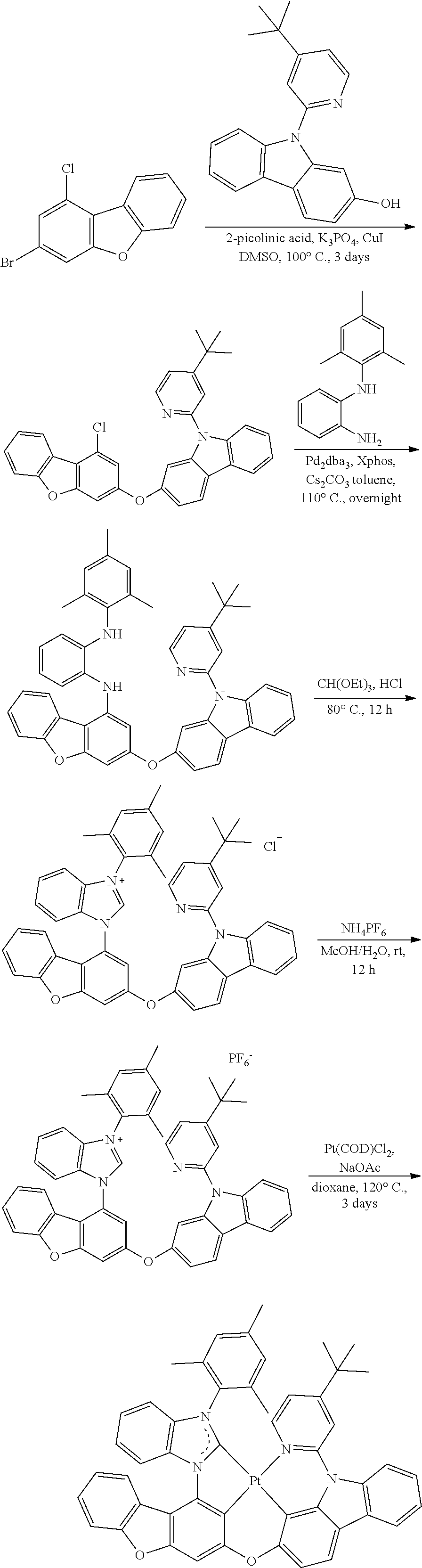

### Ex. 8

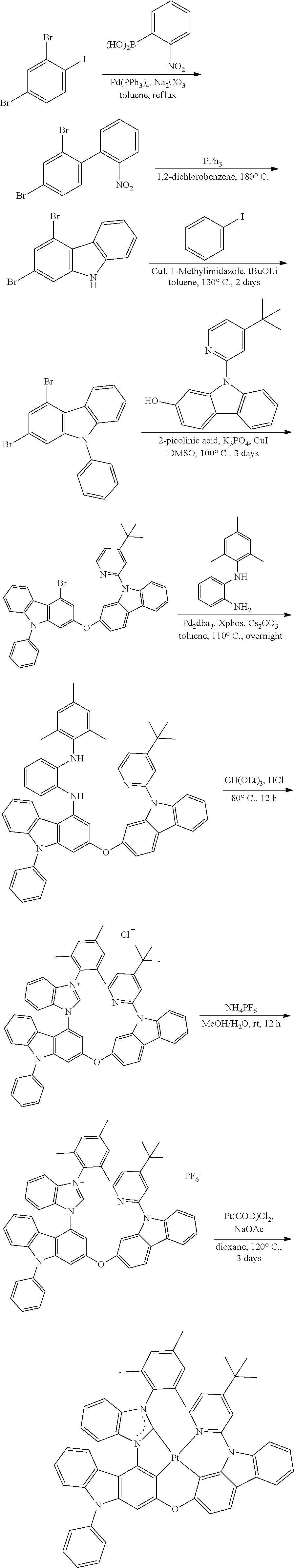

### Ex. 9

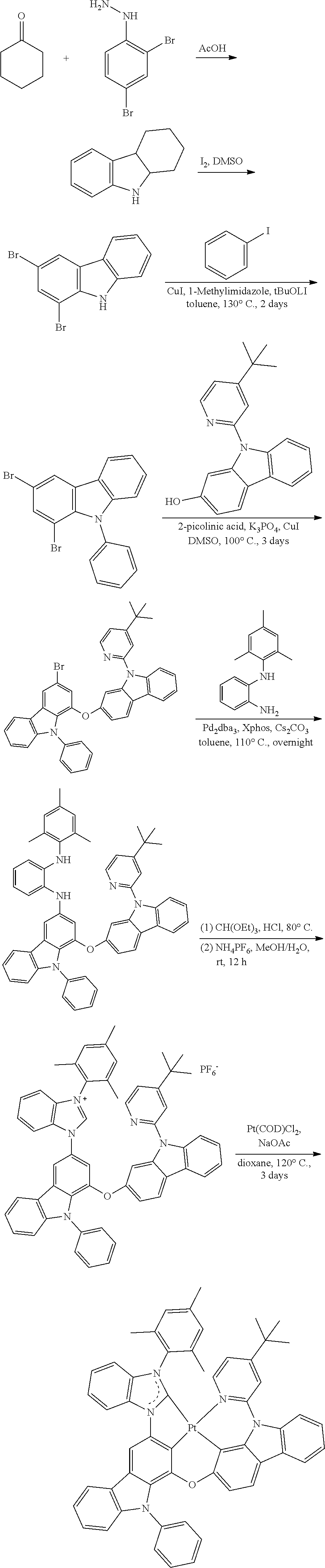

### Ex. 10

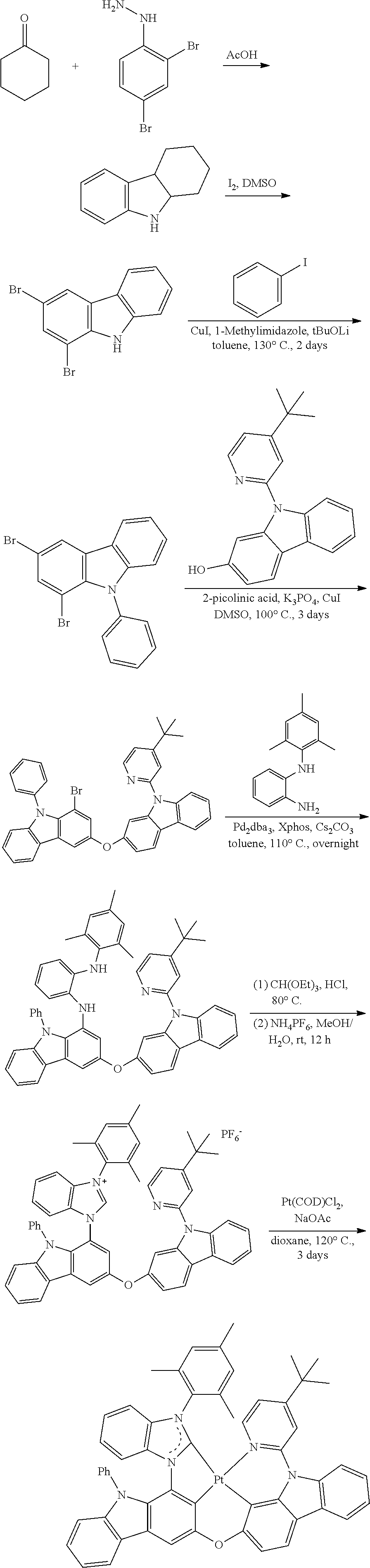

### Ex. 11

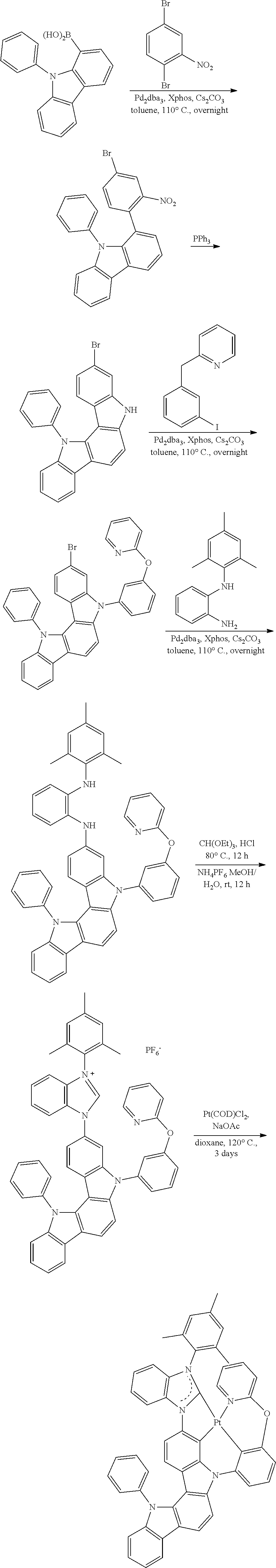

### Ex. 3-1:

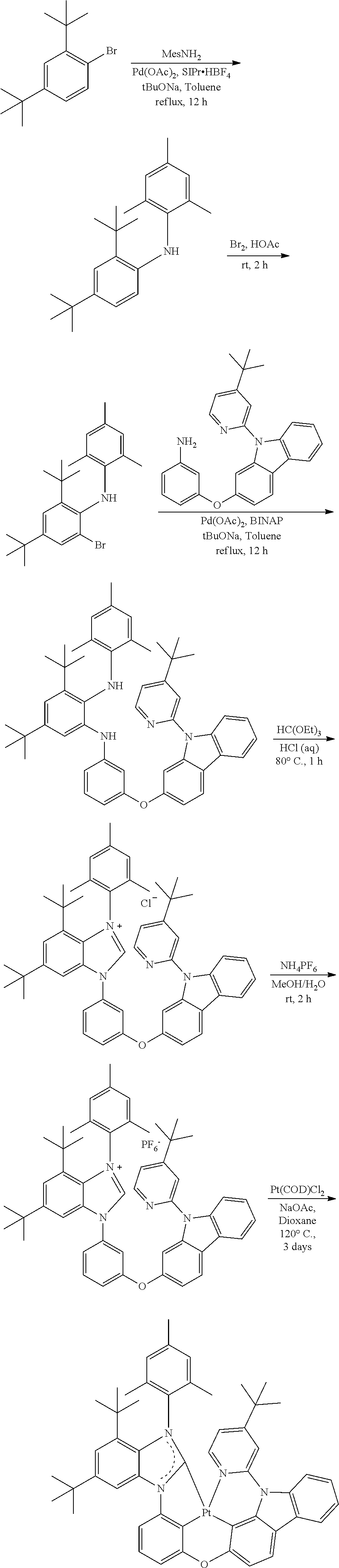

### Ex. 3-2:

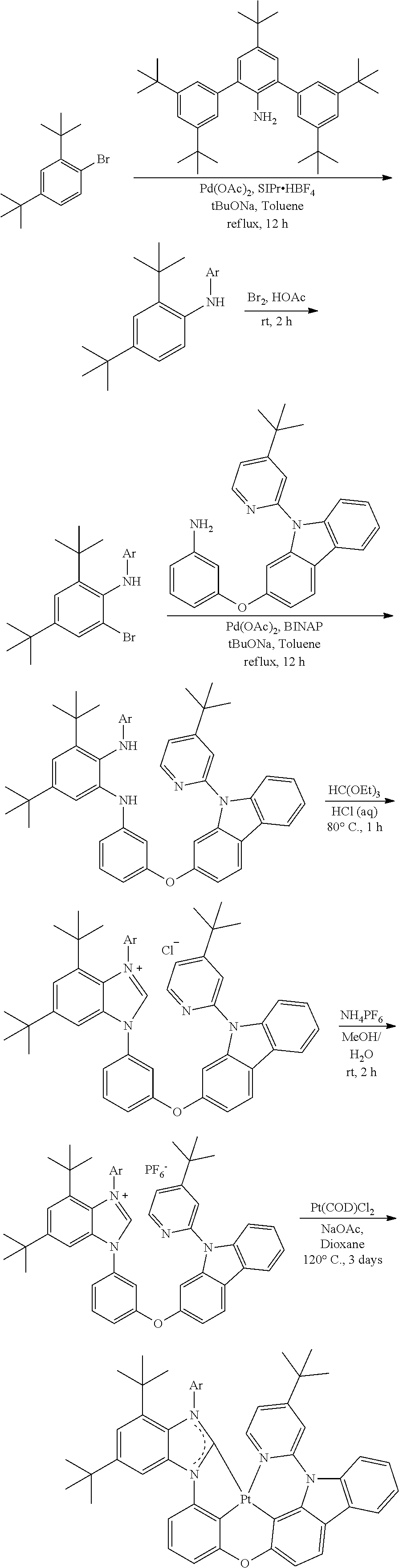

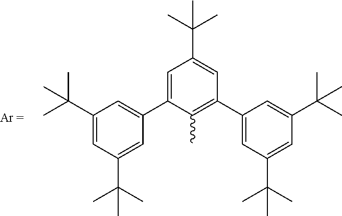

### Ex. 3-3:

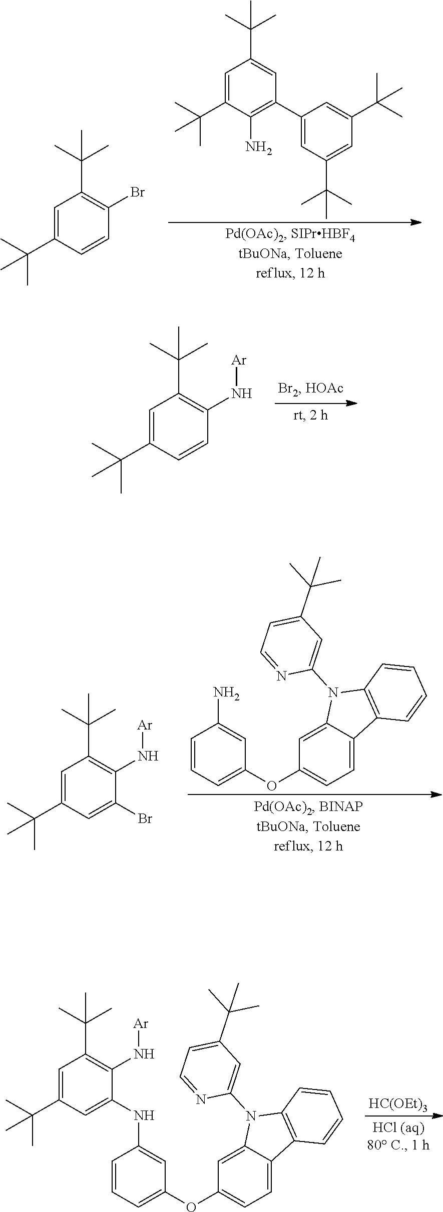

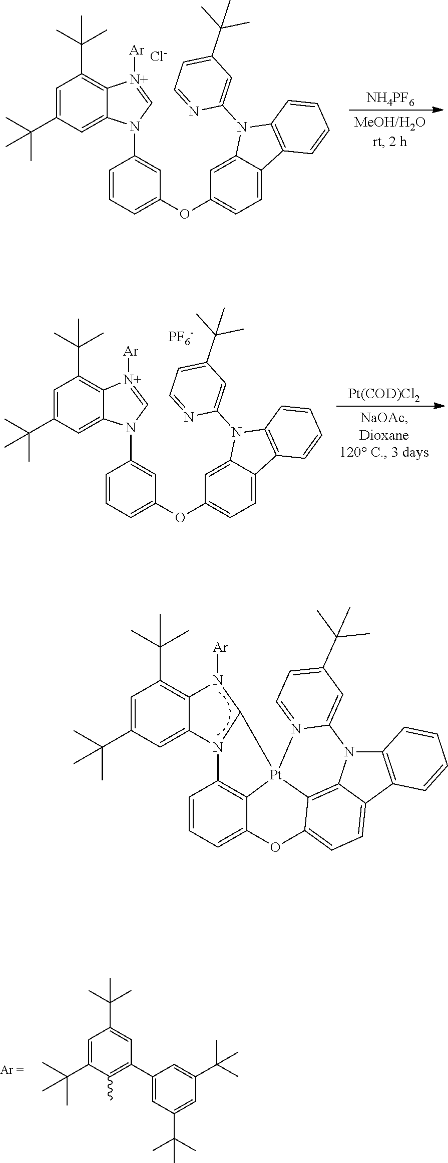

### Ex. 3-4:

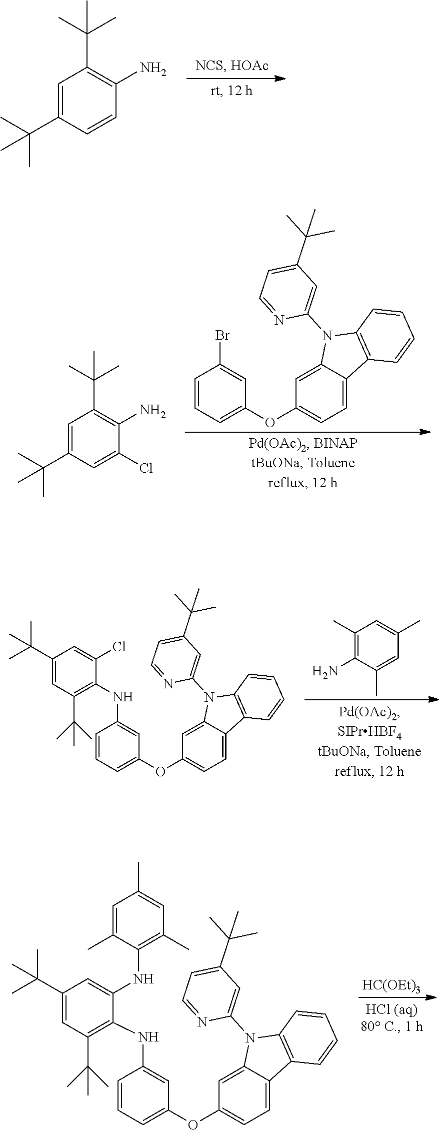

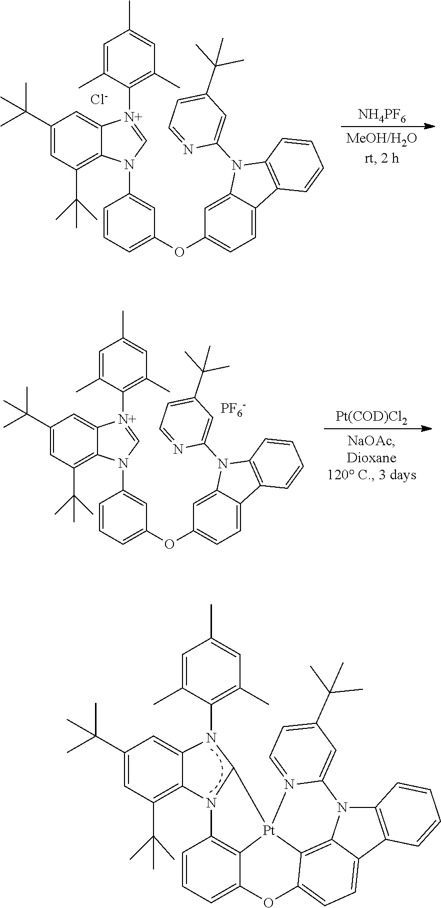

### Ex. 3-5:

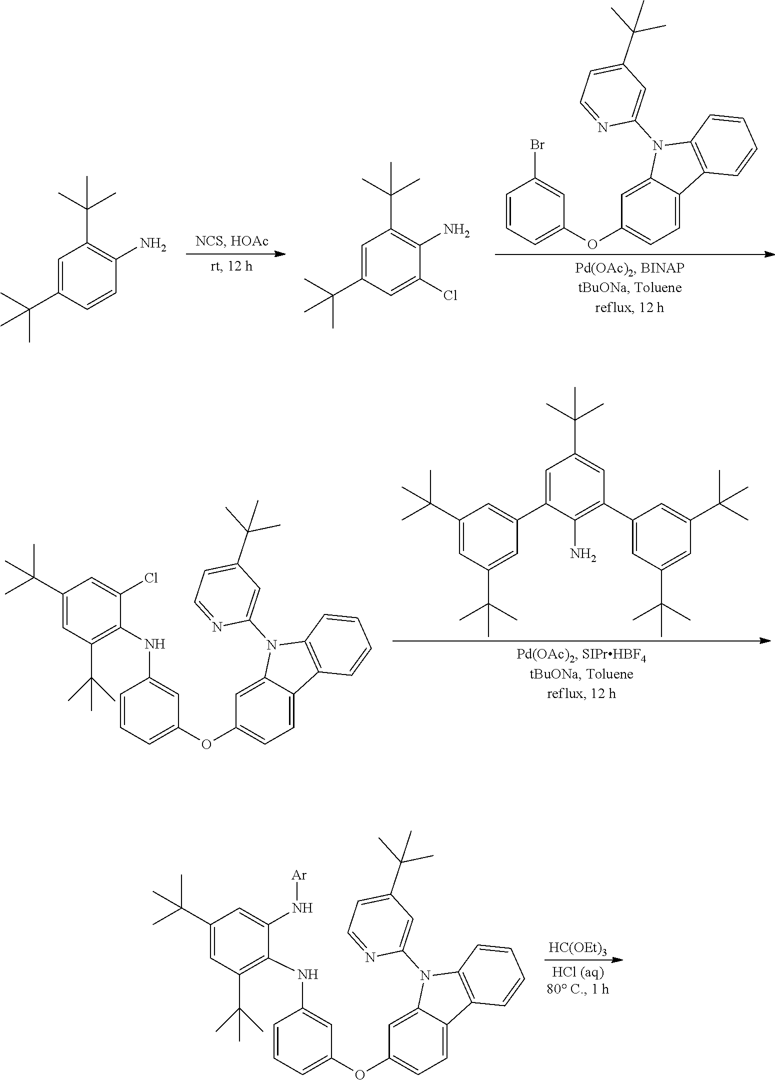

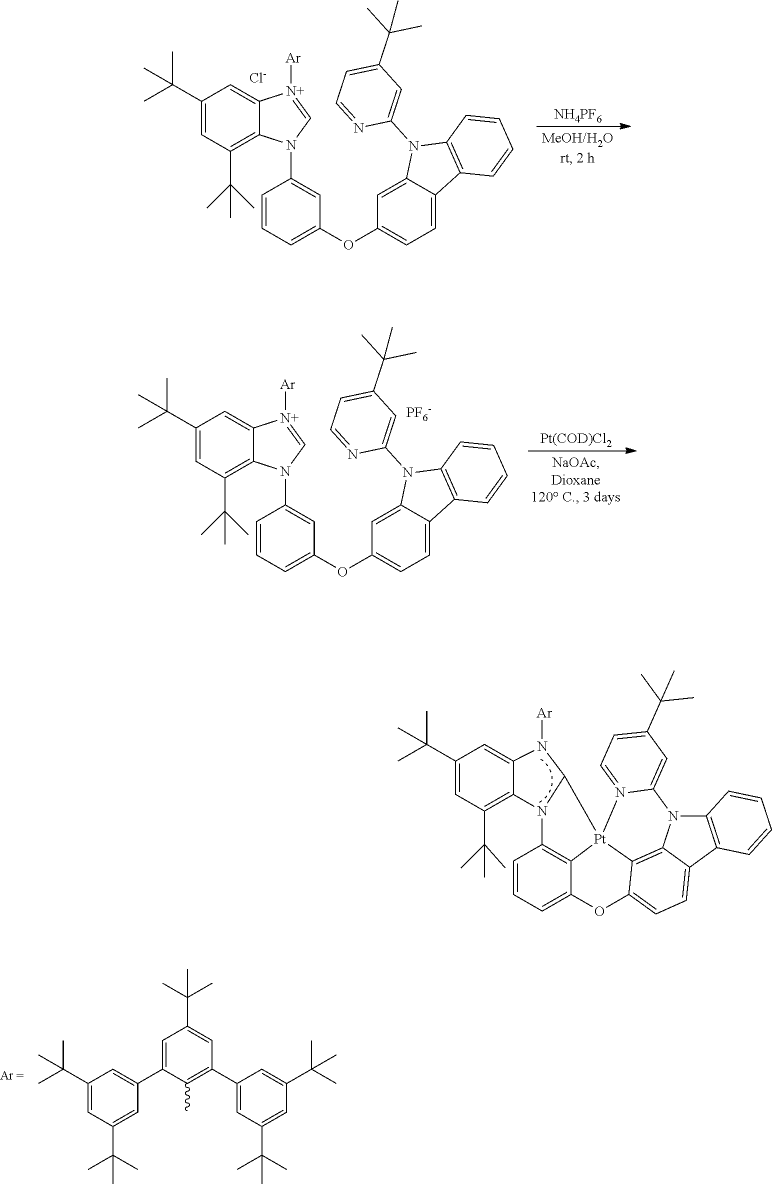

### Ex. 3-6:

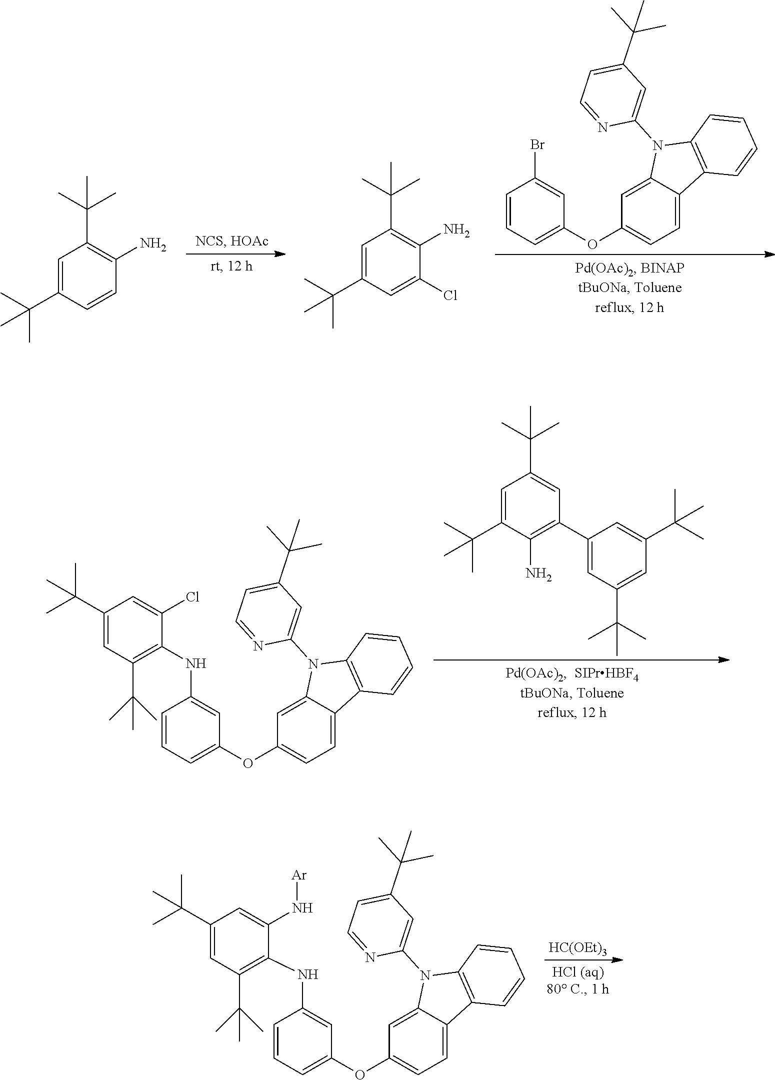

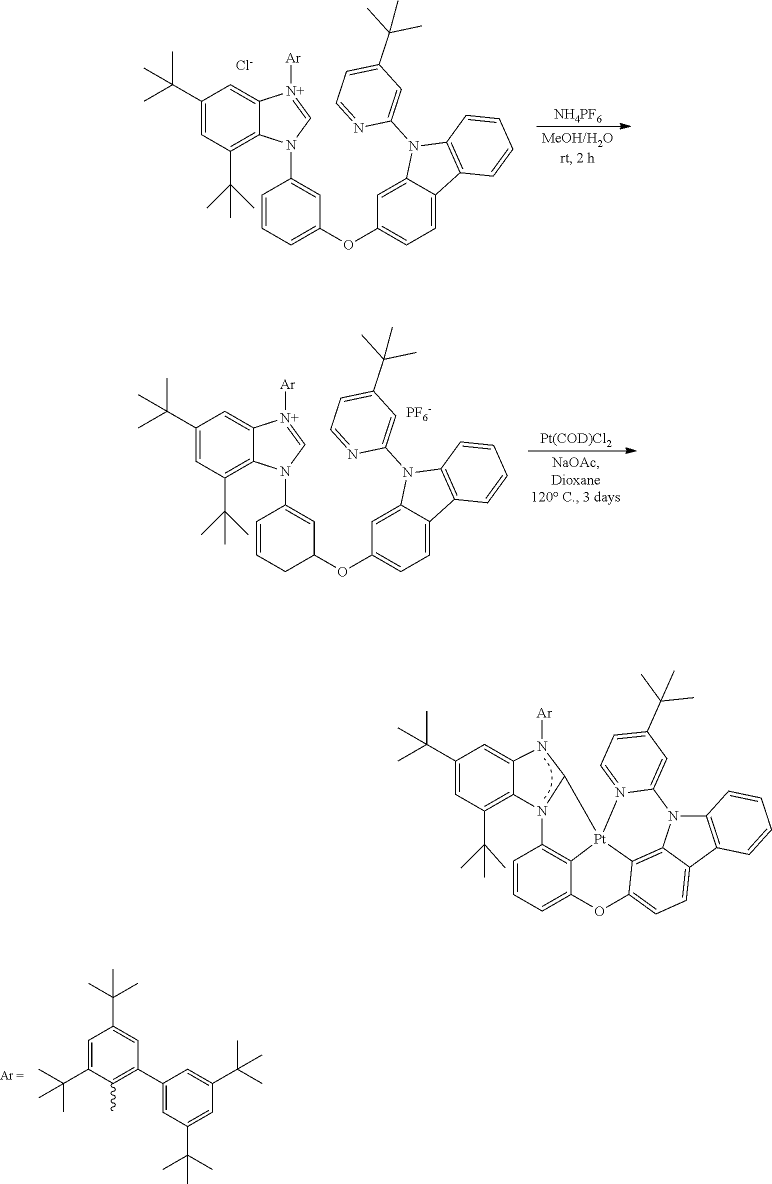

### Ex. 3-7:

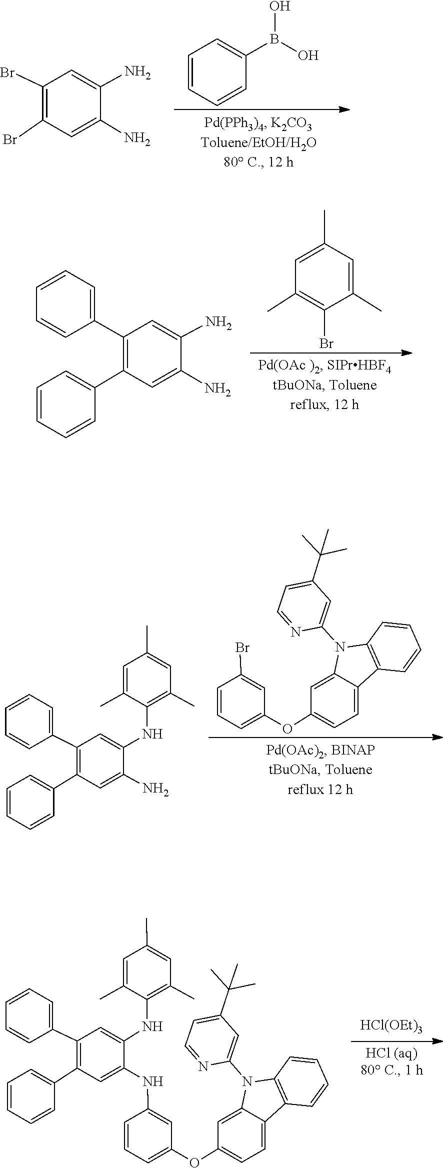

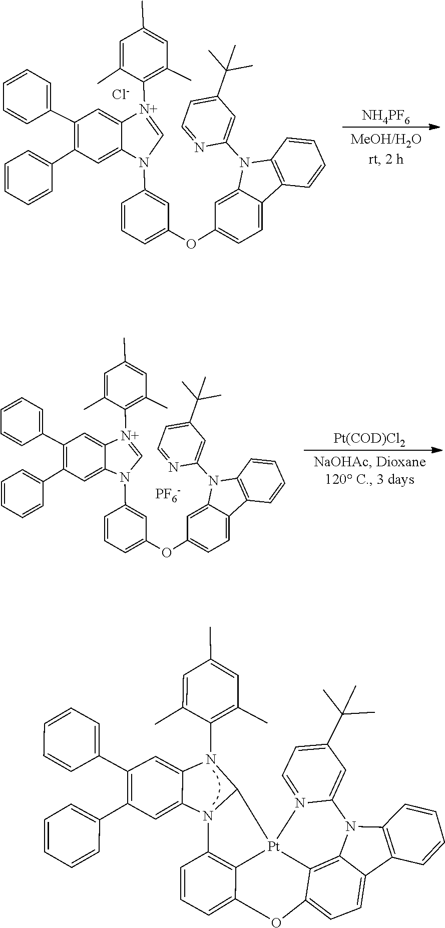

### Ex. 3-8:

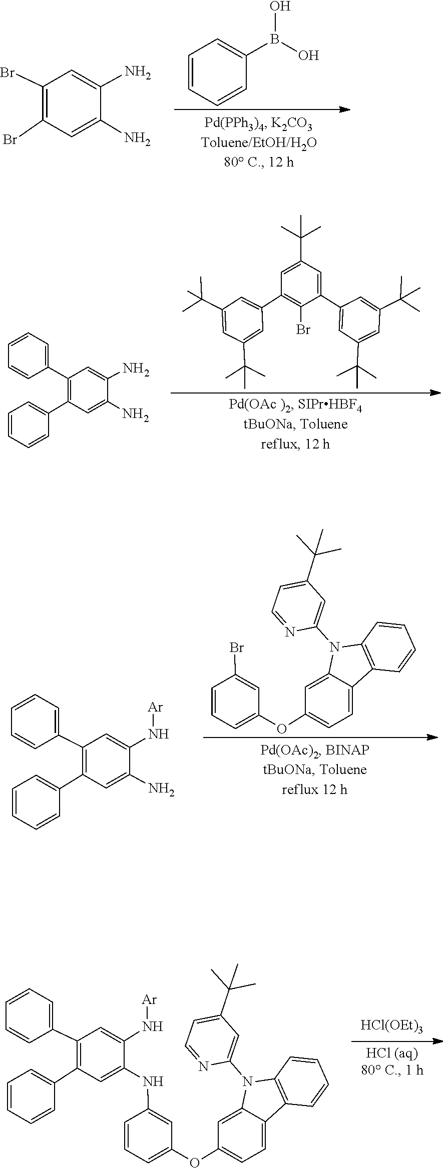

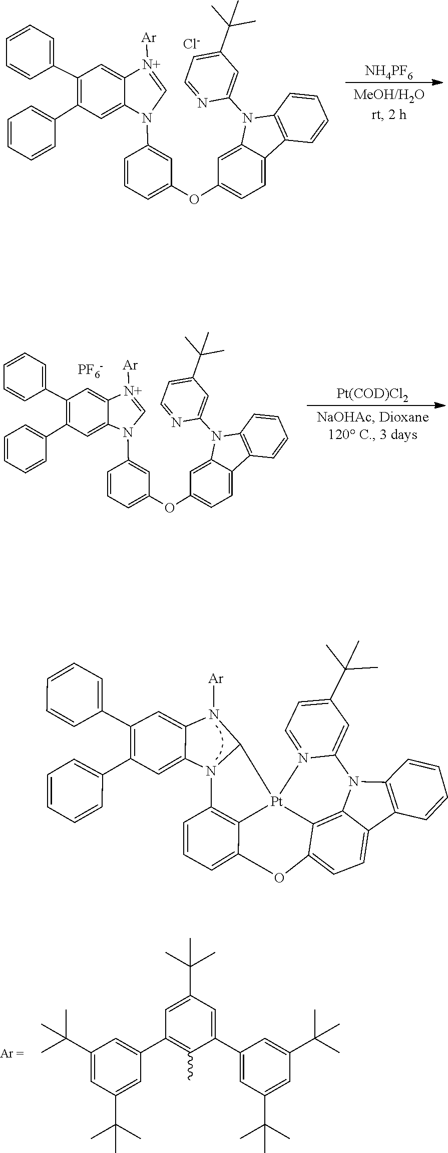

### Ex. 3-9:

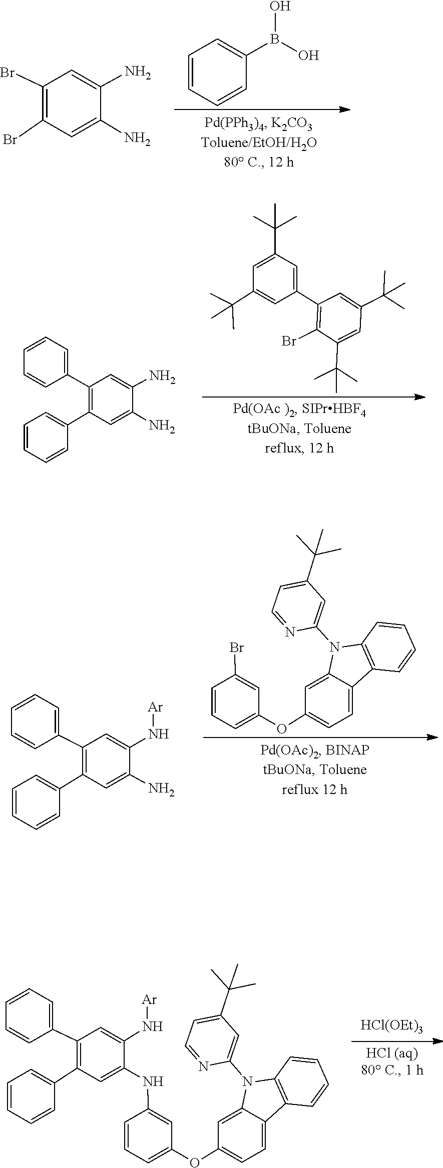

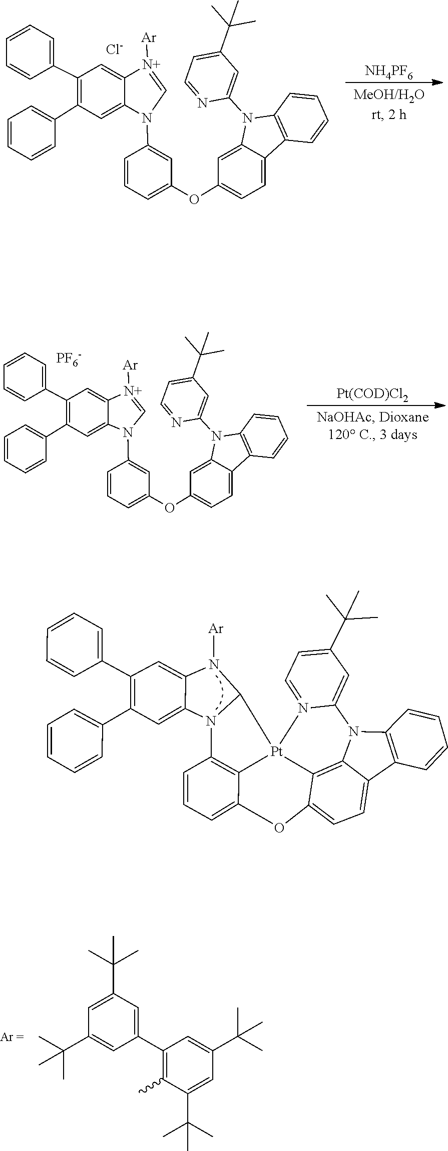

### Ex. 3-10:

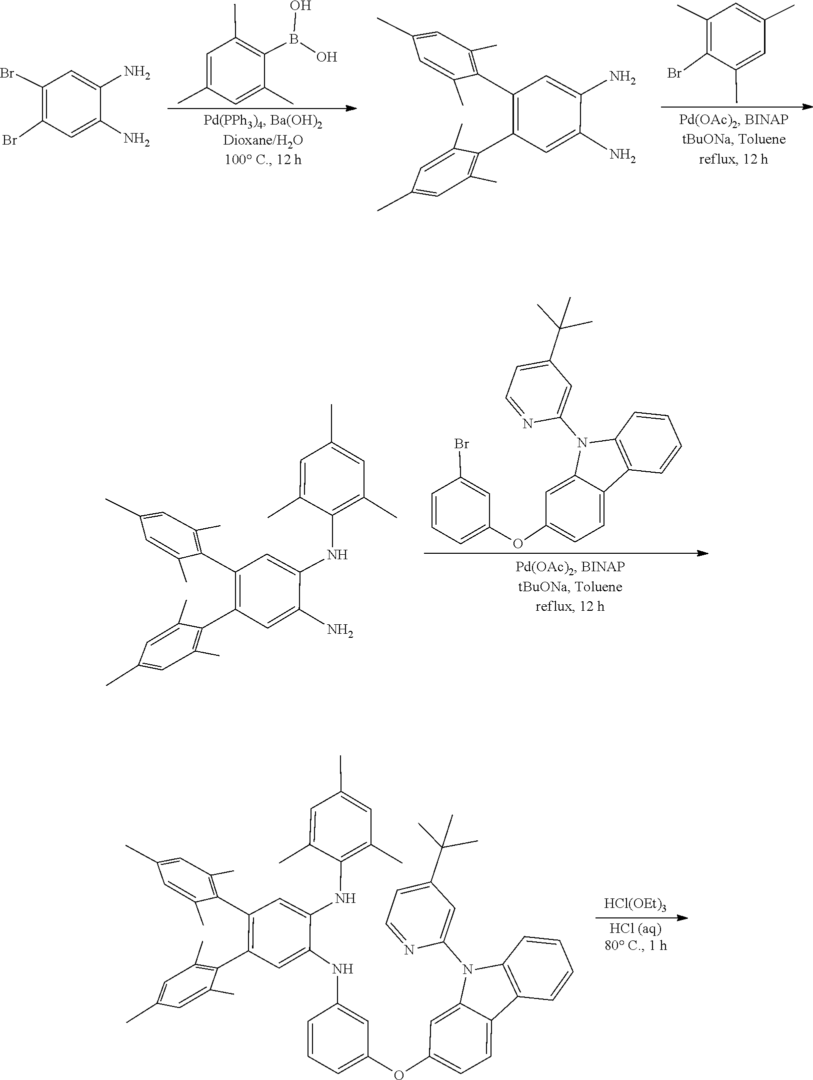

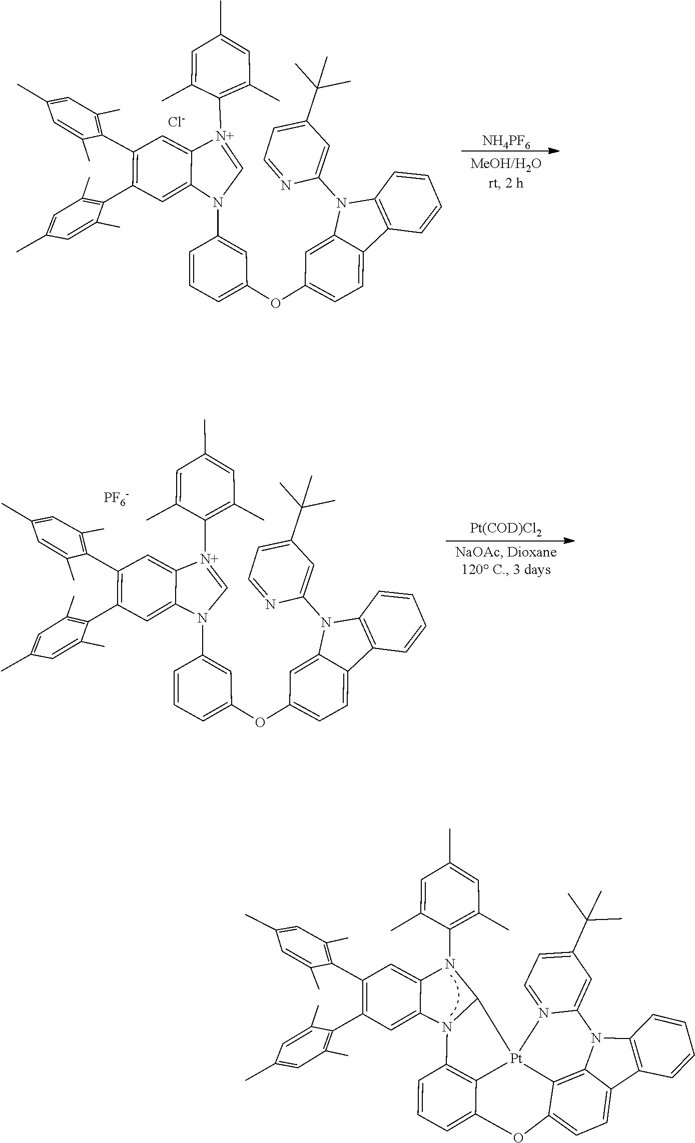

### Ex. 3-11:

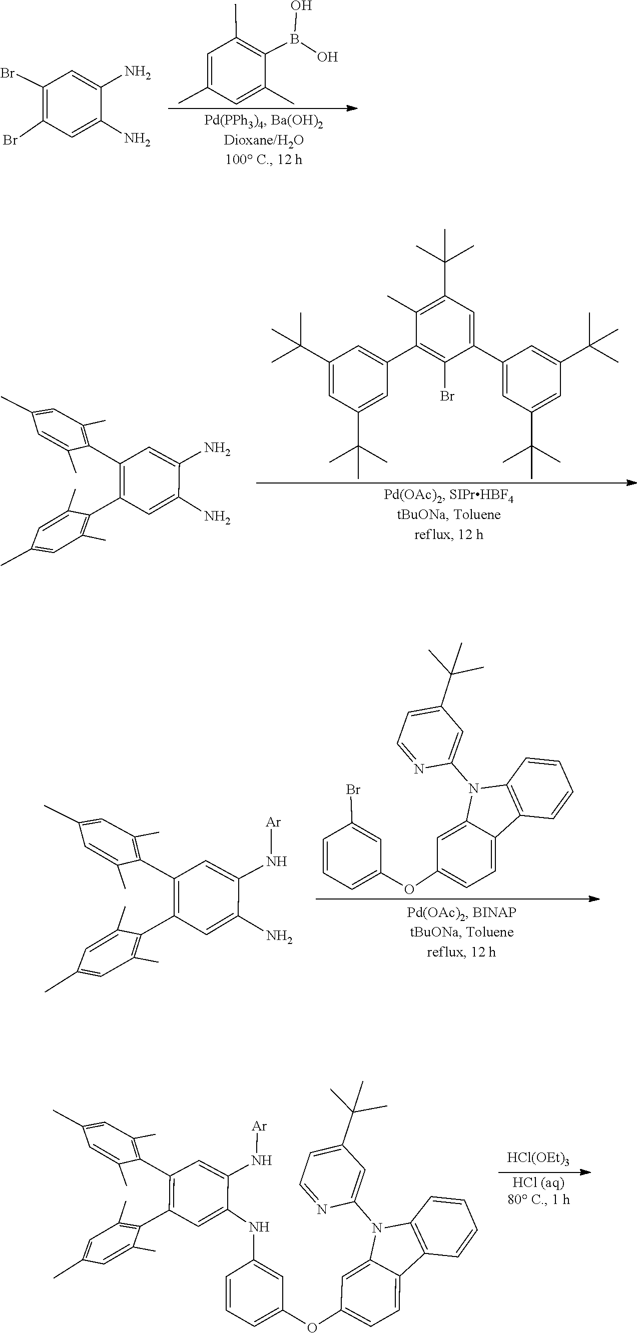

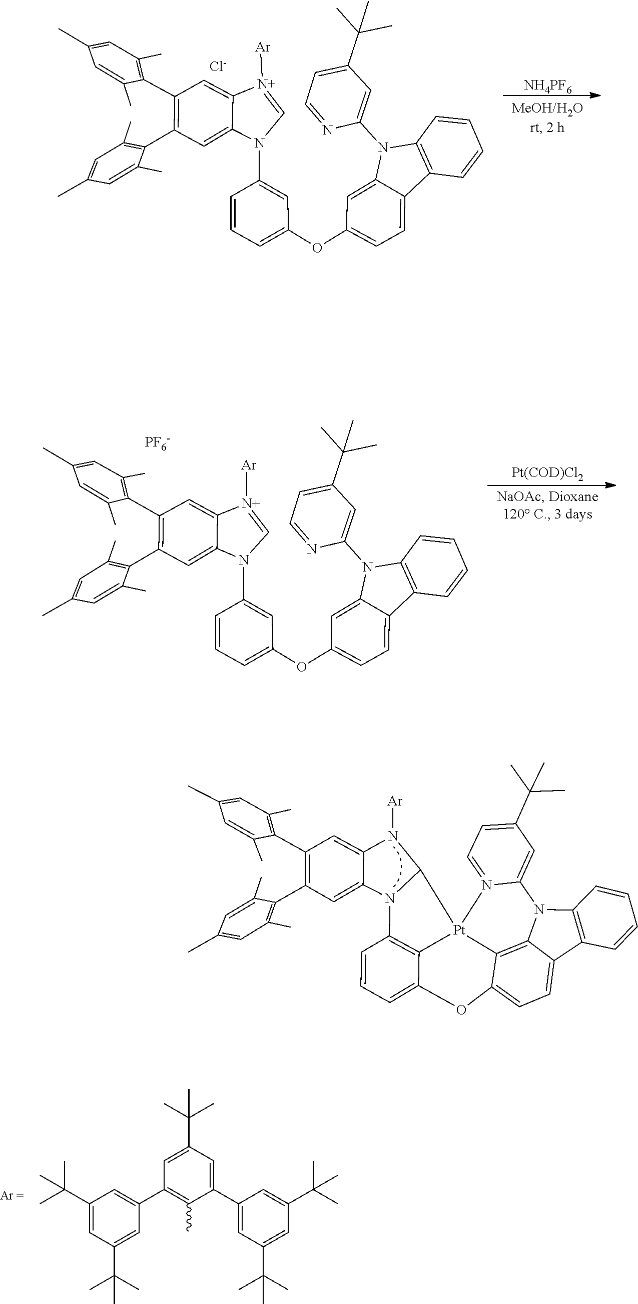

### Ex. 3-12:

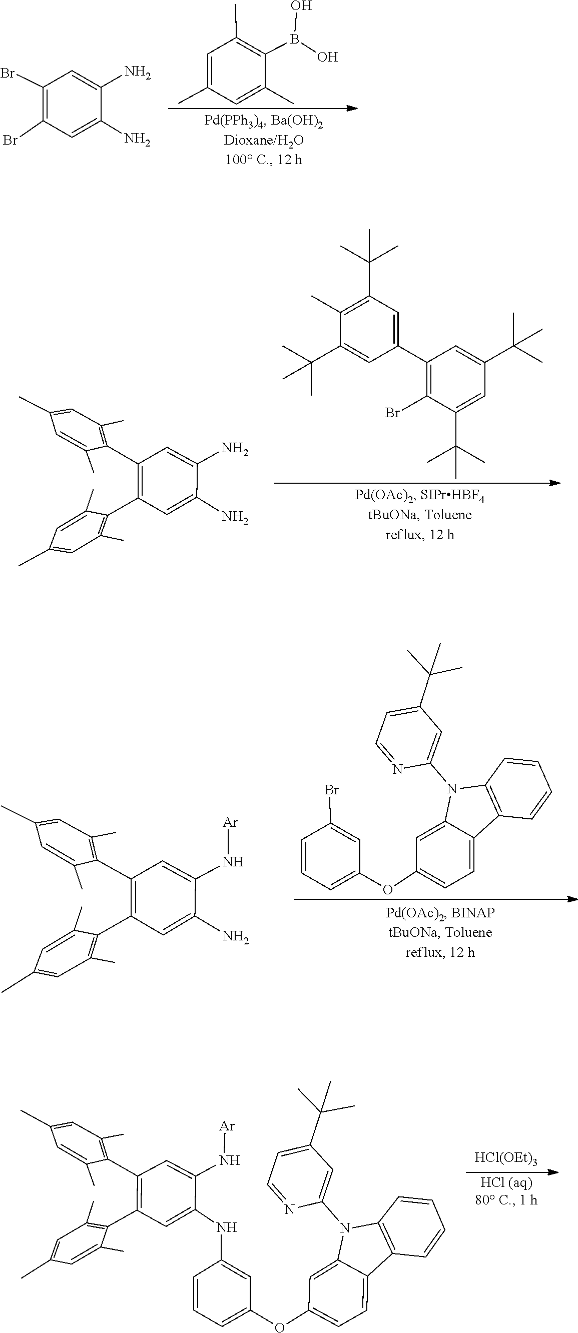

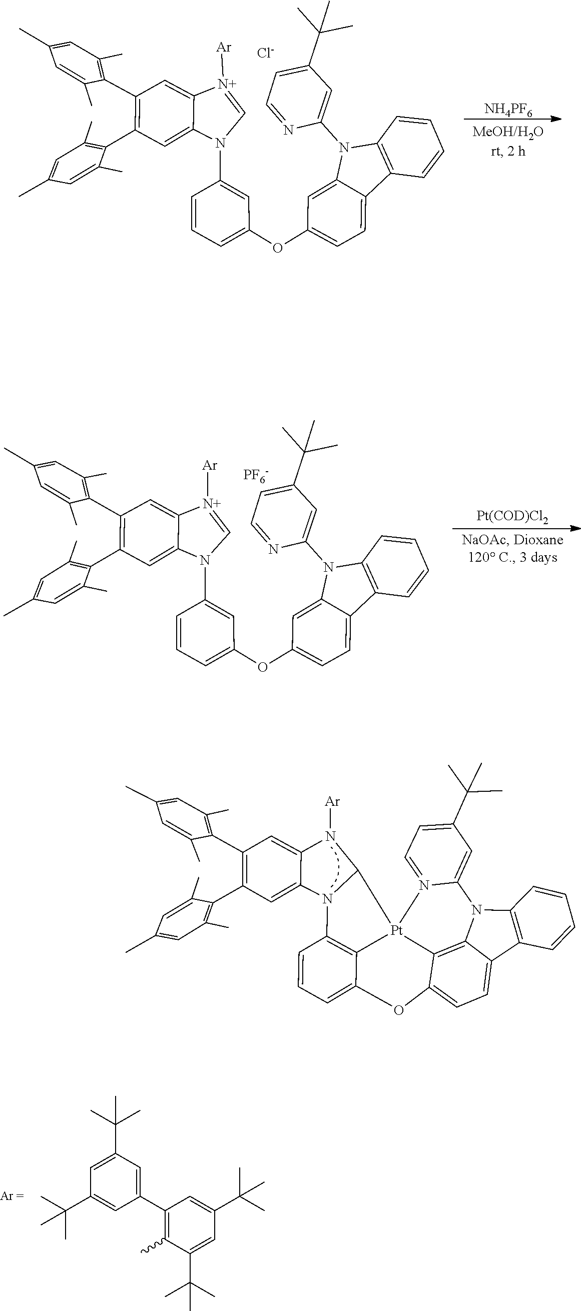

### Ex. 3-13:

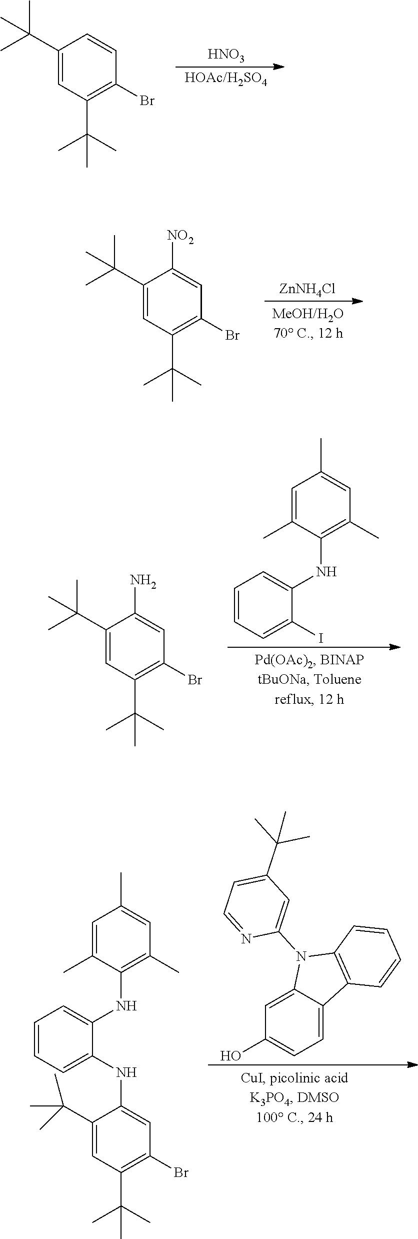

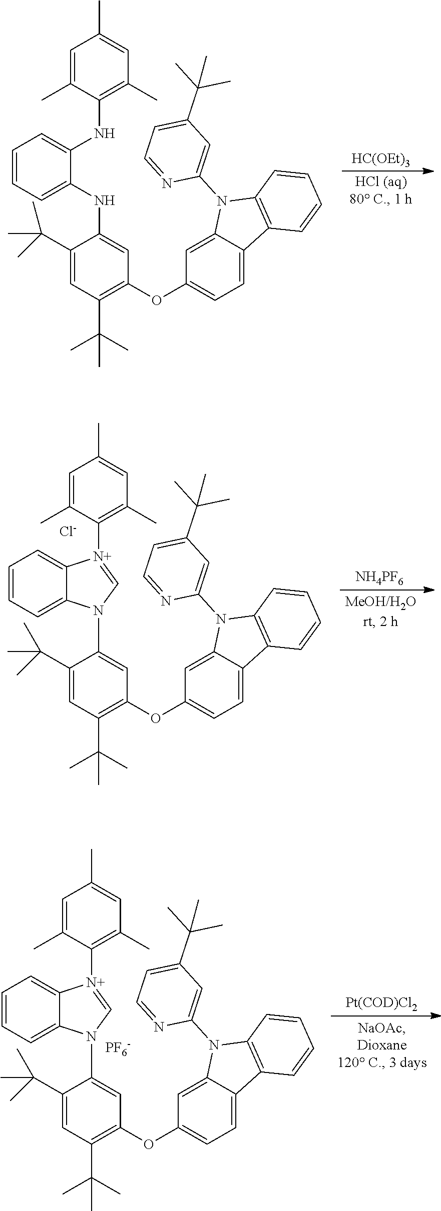

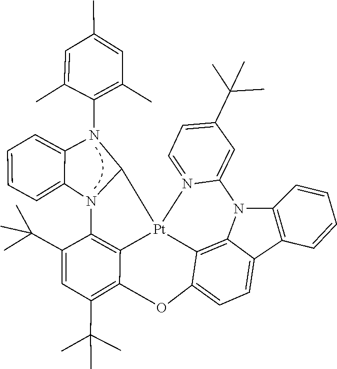

### Ex. 3-14:

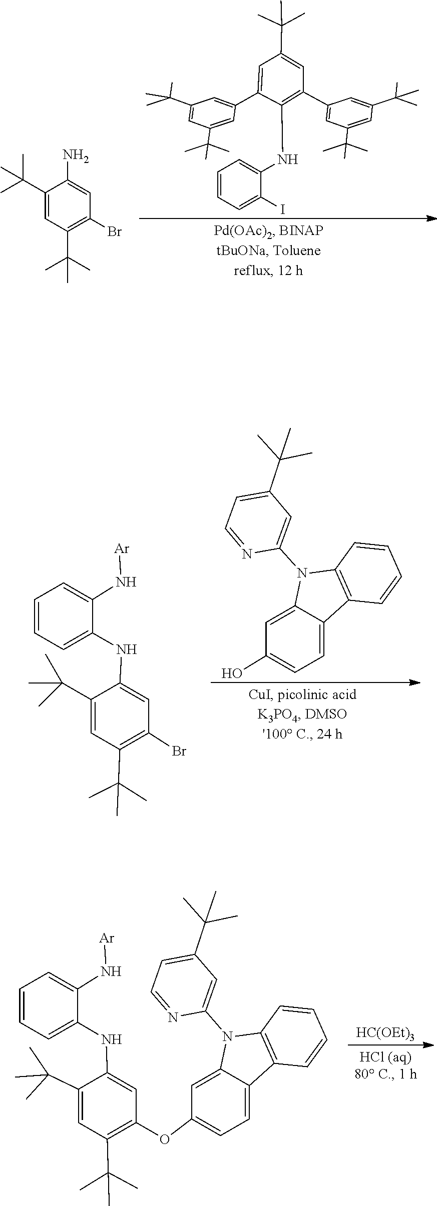

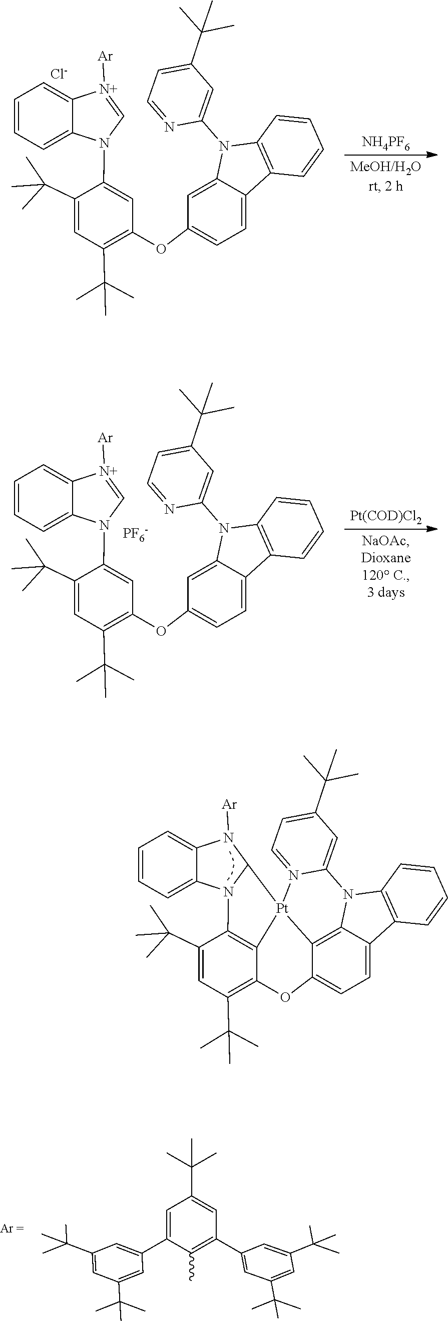

### Ex. 3-15:

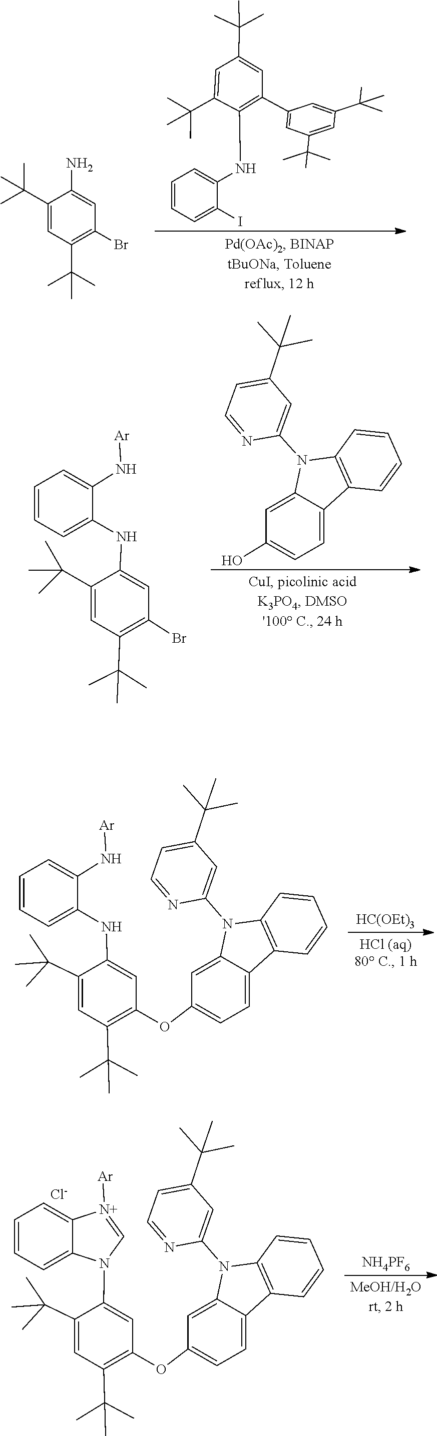

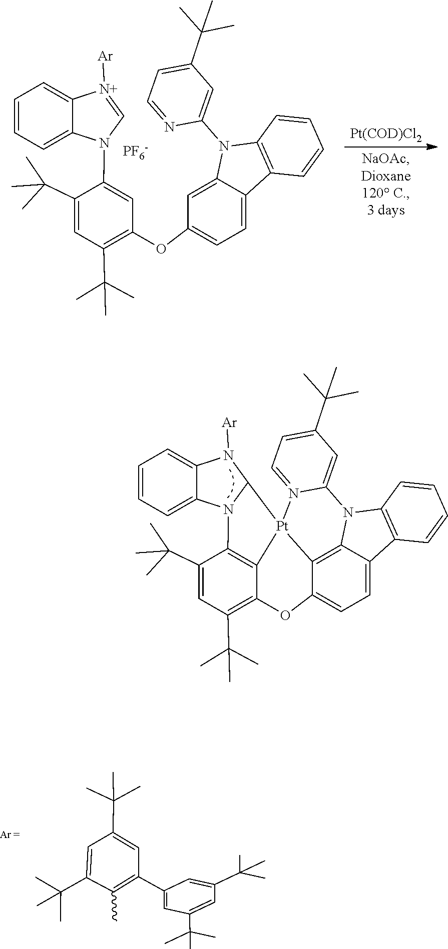

### Ex. 3-16:

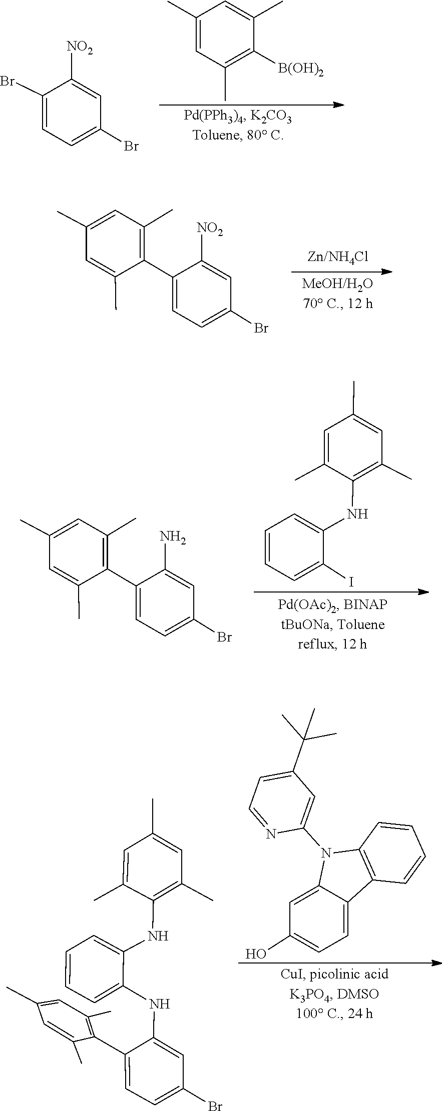

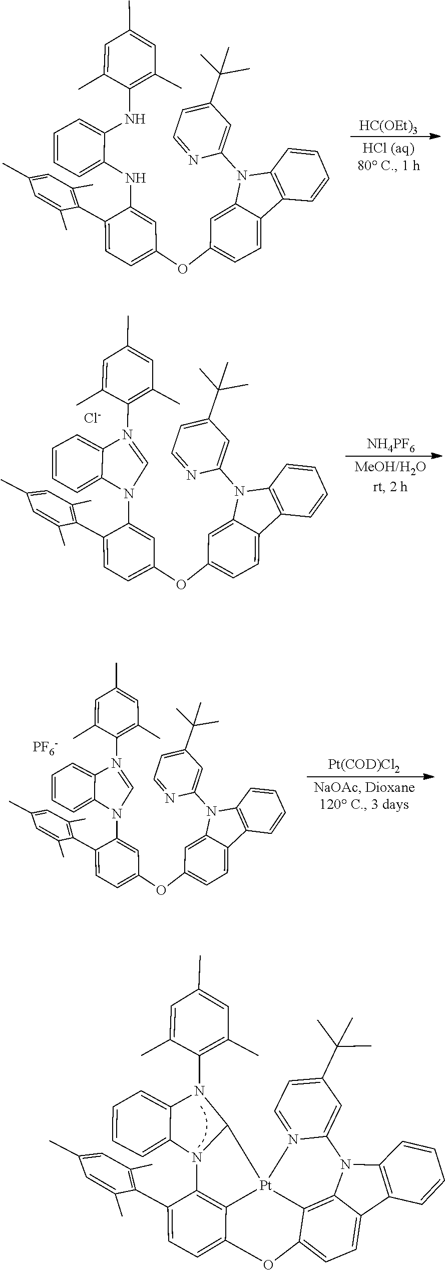

### Ex. 3-17:

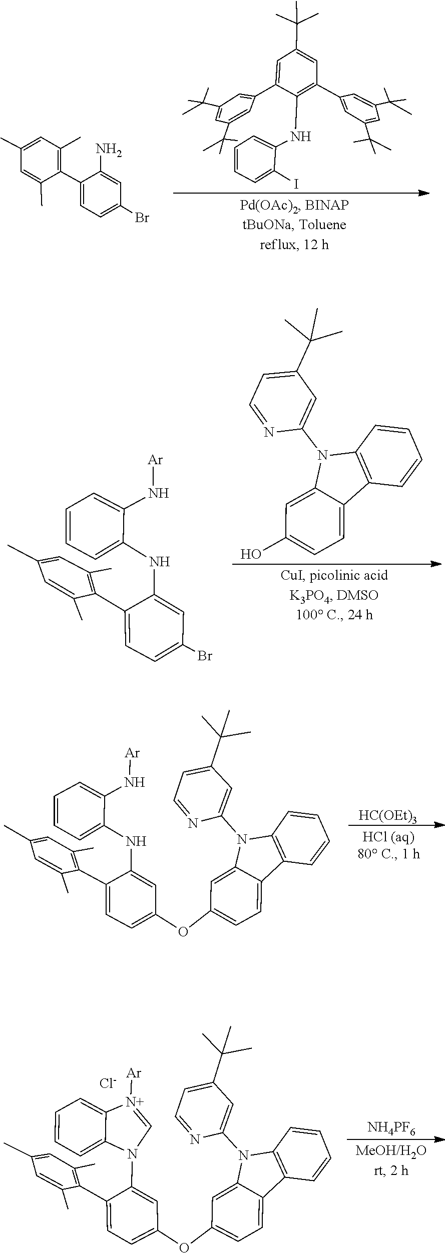

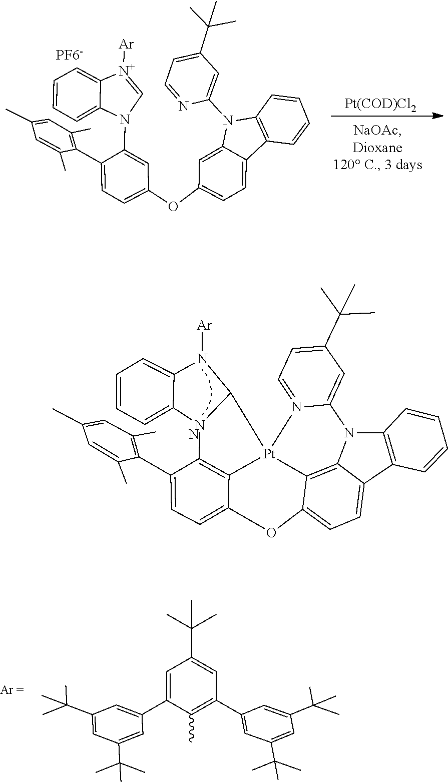

### Ex. 3-18:

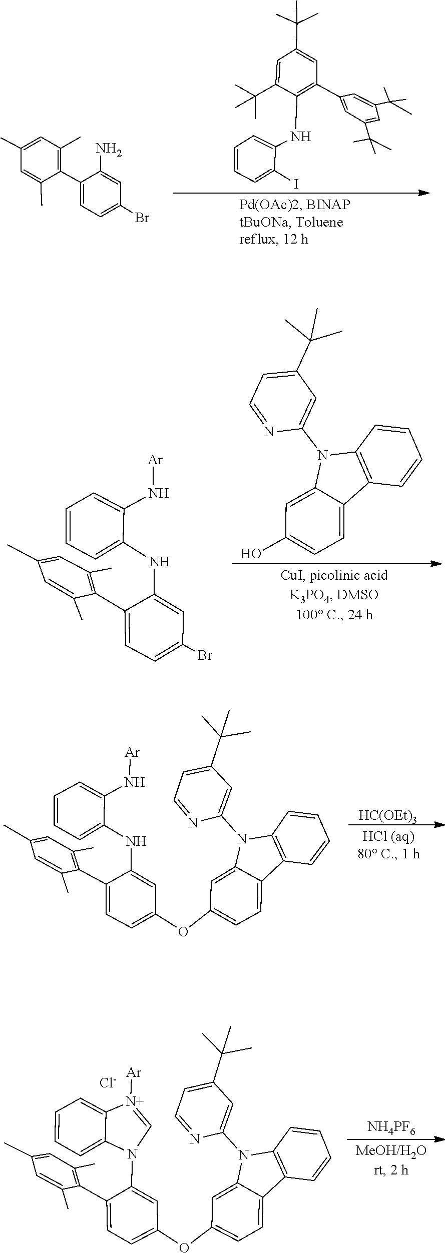

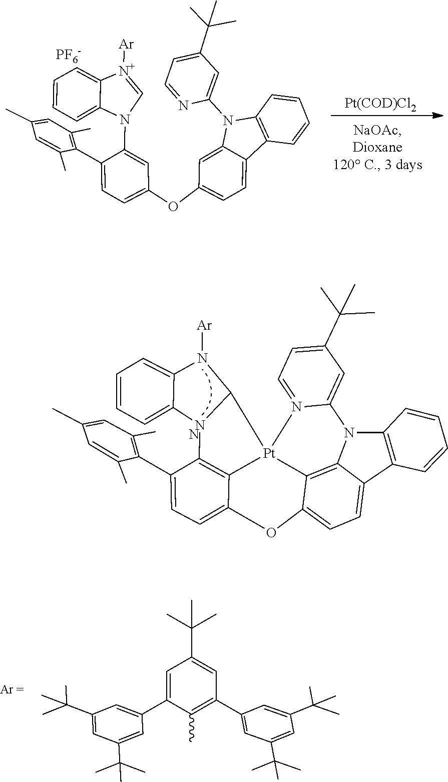

### Ex. 3-19:

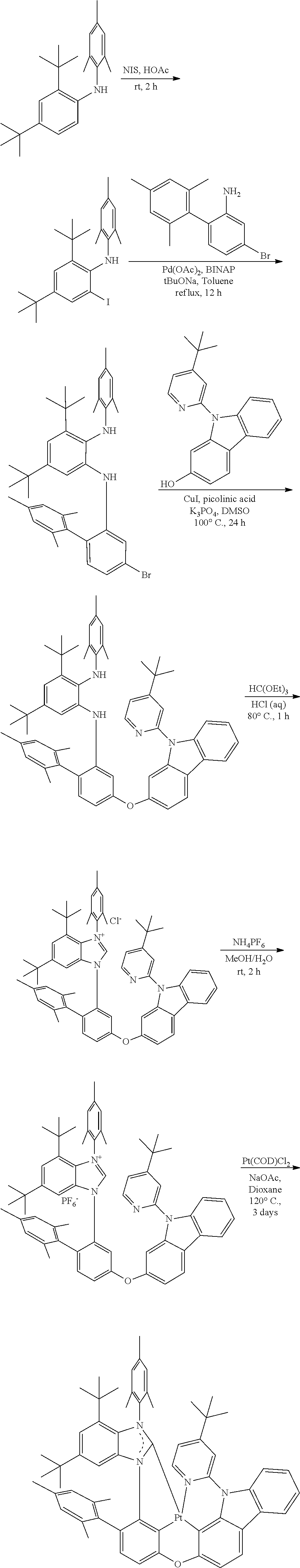

### Ex. 3-20:

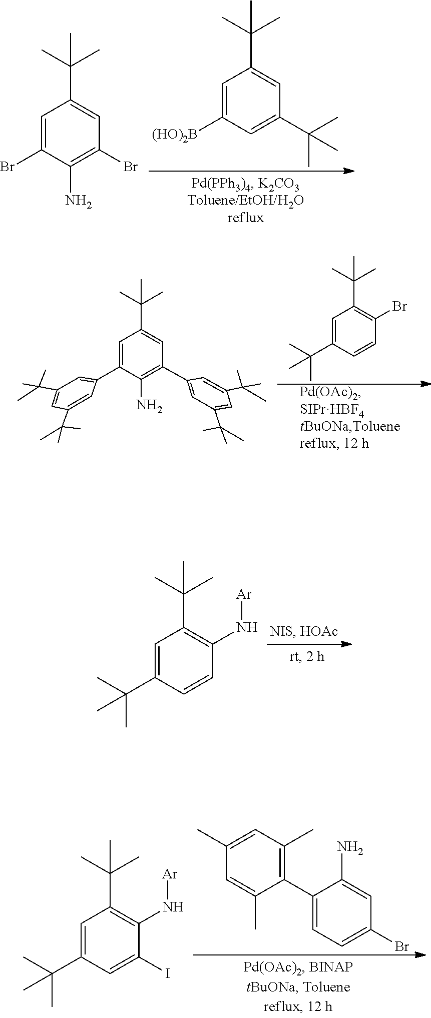

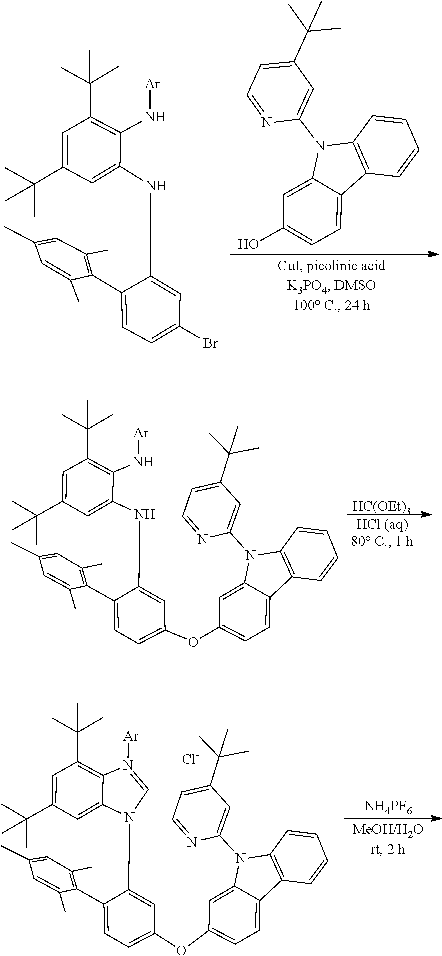

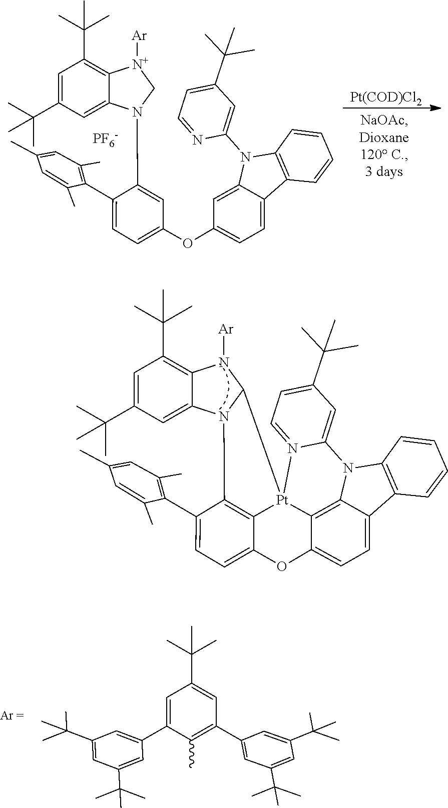

### Ex. 3-21:

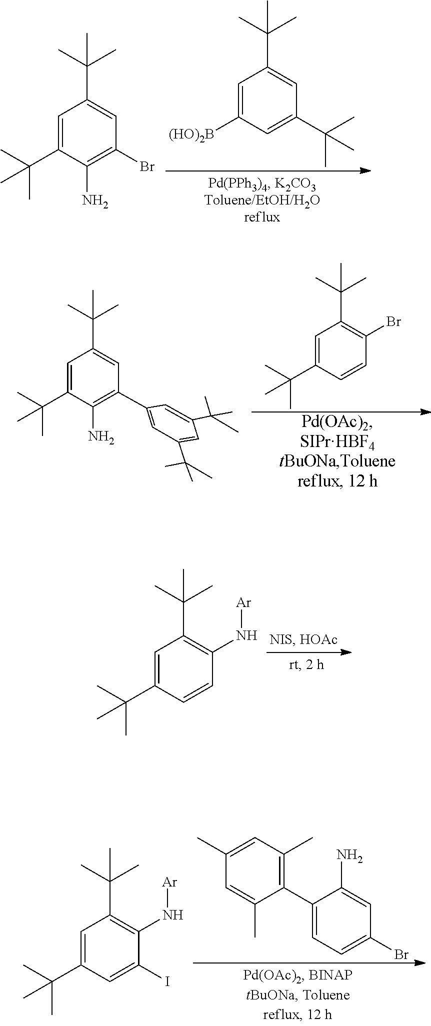

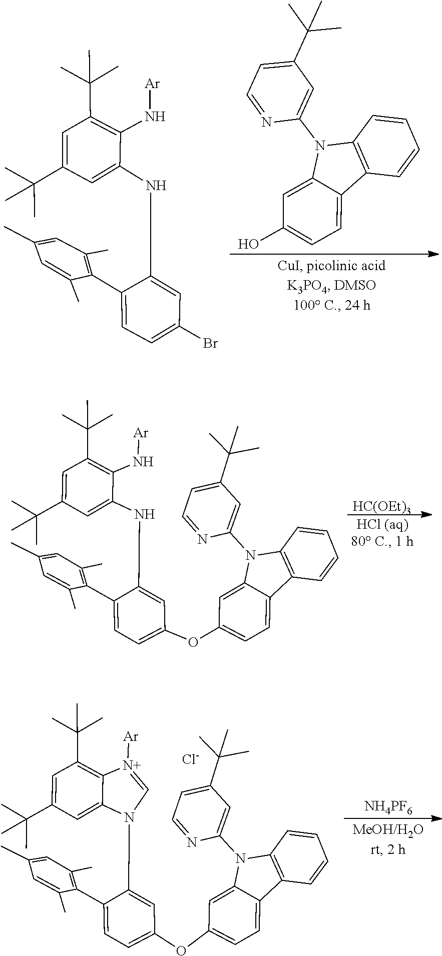

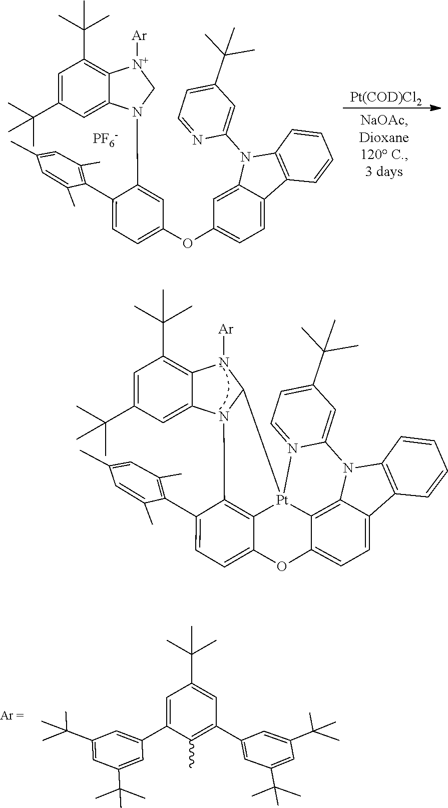

### Ex. 3-22:

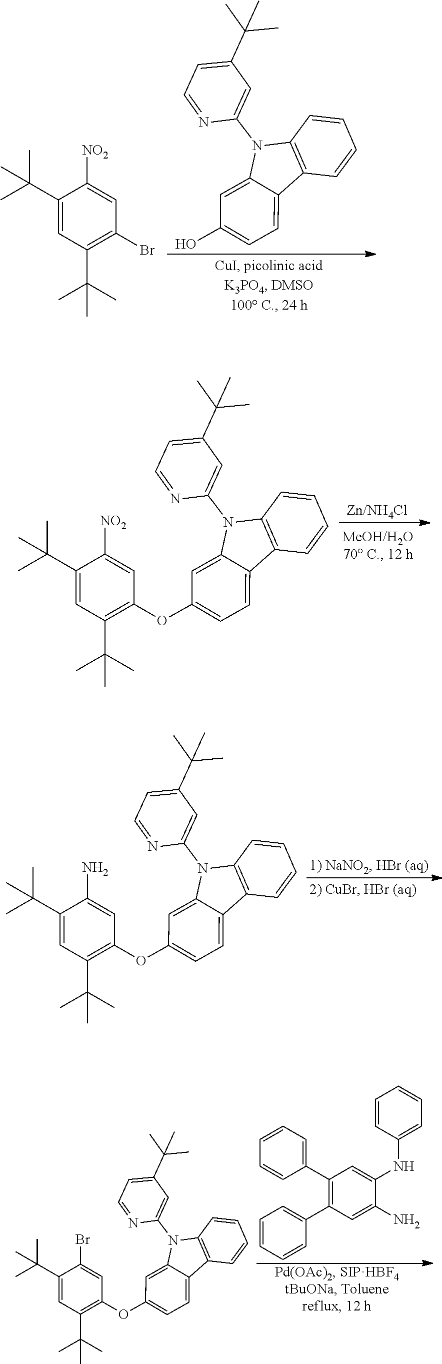

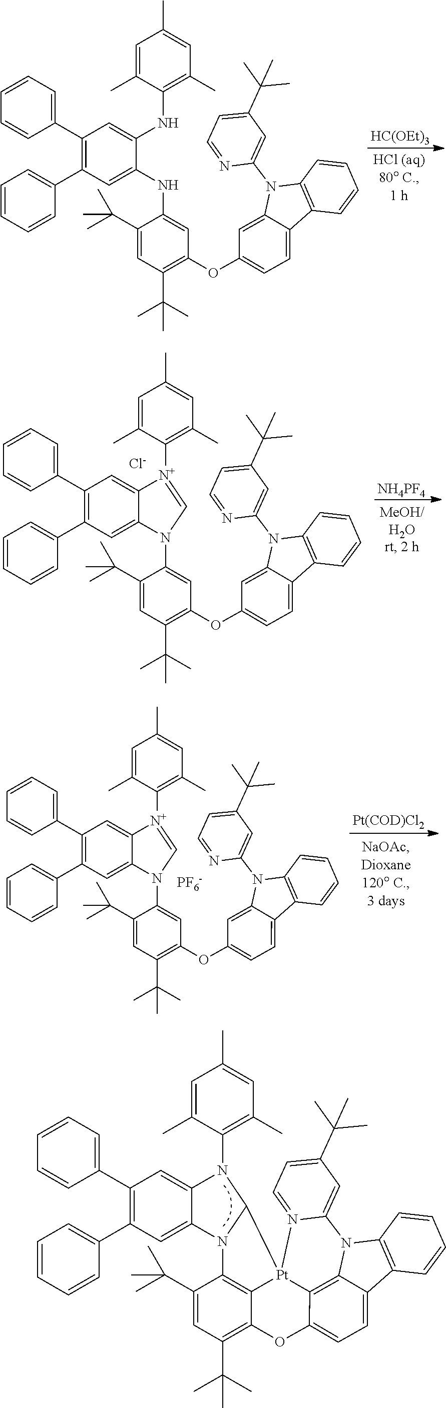

### Ex. 3-23 and 24:

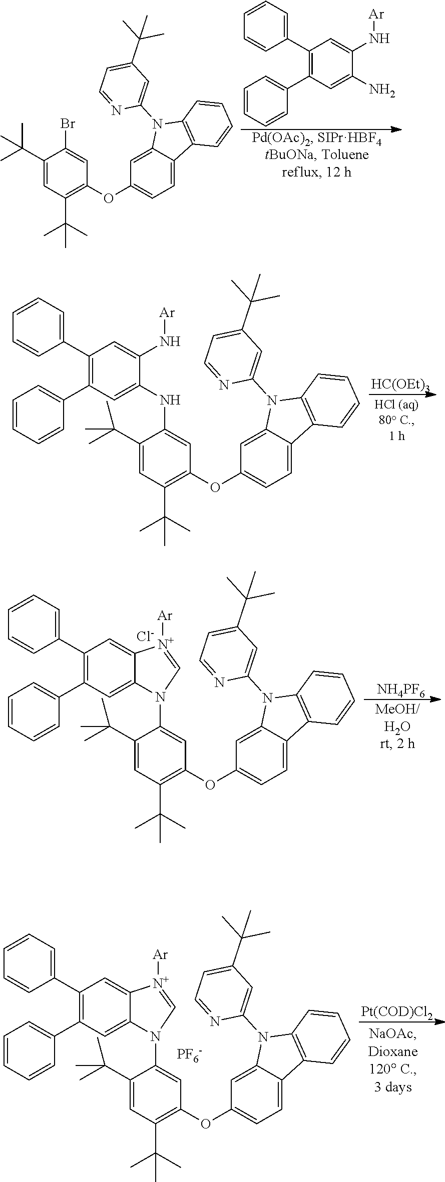

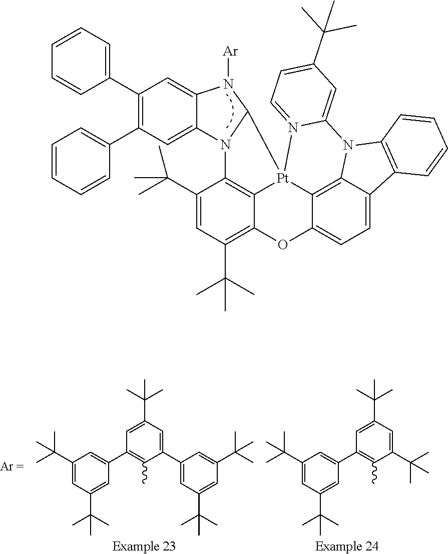

### Ex. 3-25:

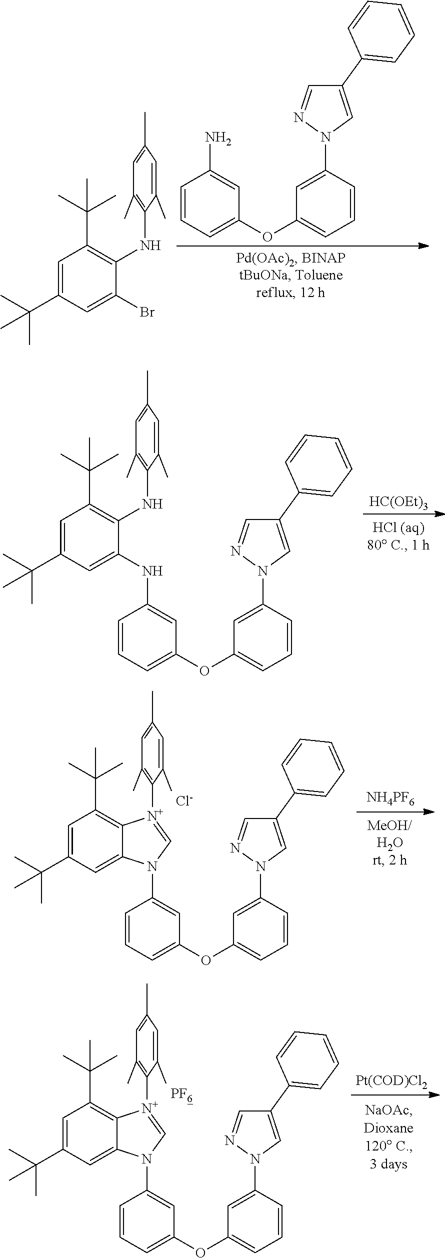

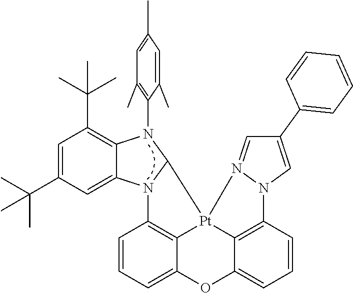

### Ex. 3-26 and 27:

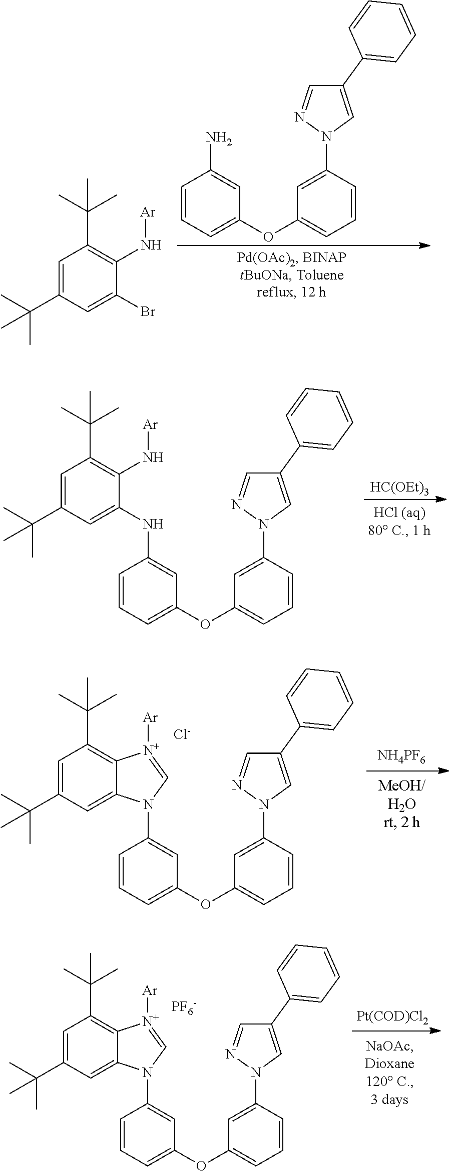

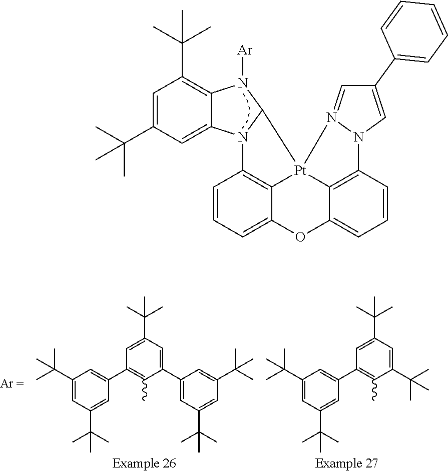

### Ex. 3-28:

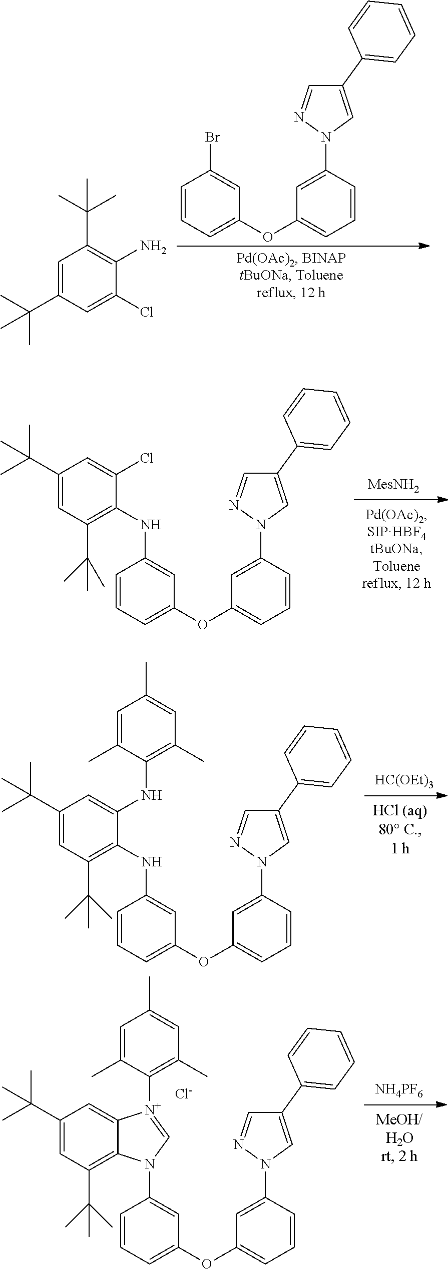

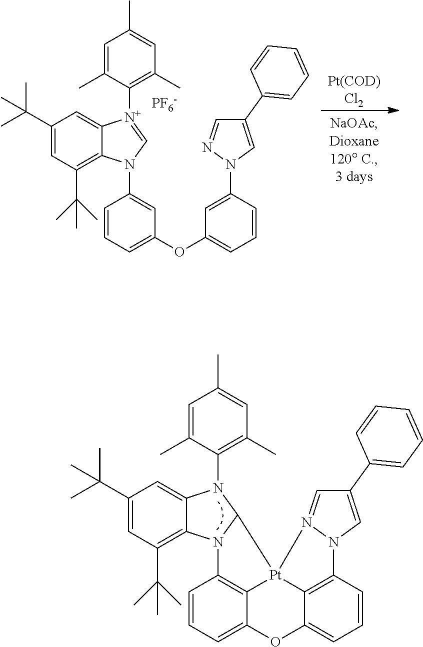

### Ex. 3-29 and 30:

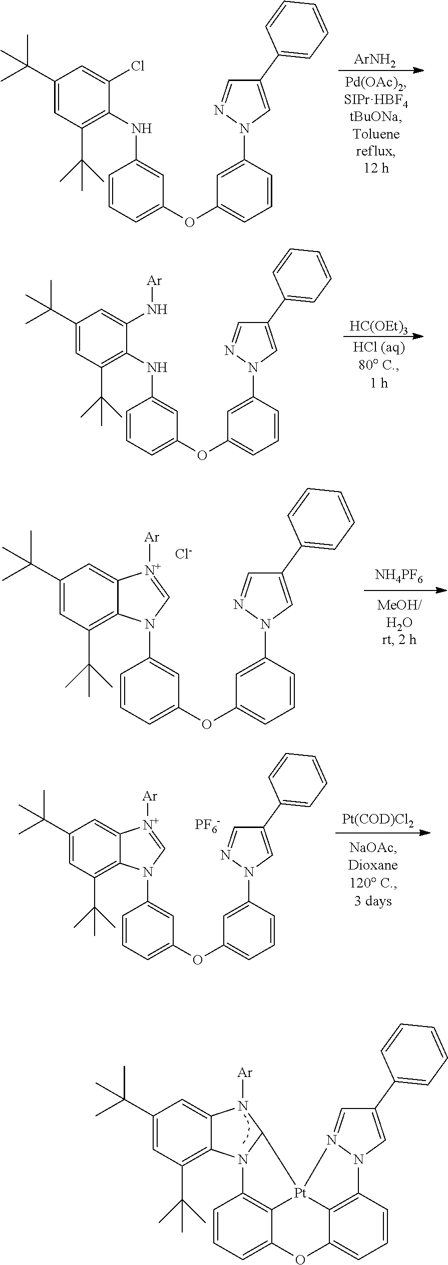

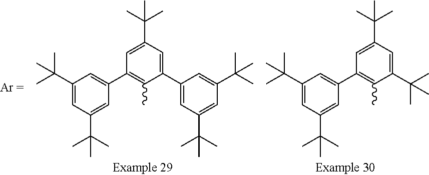

### Ex. 3-31:

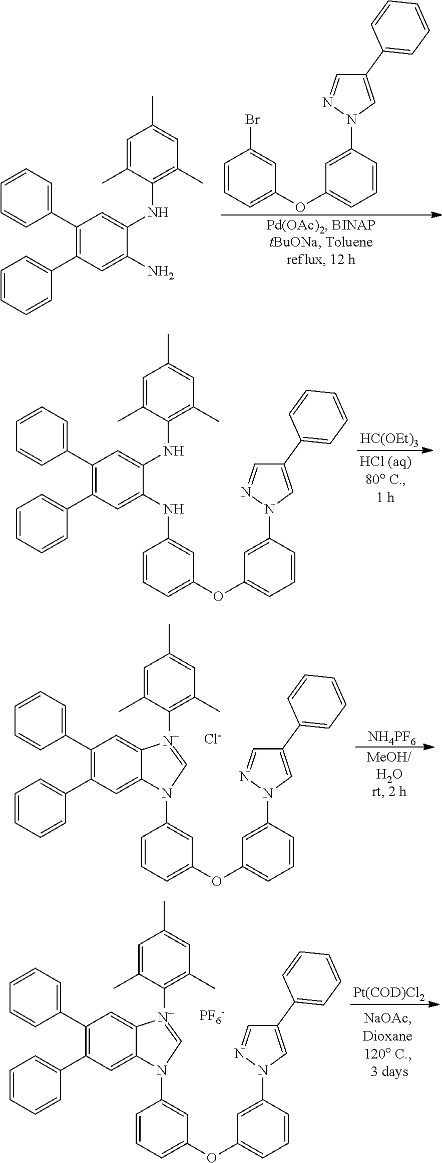

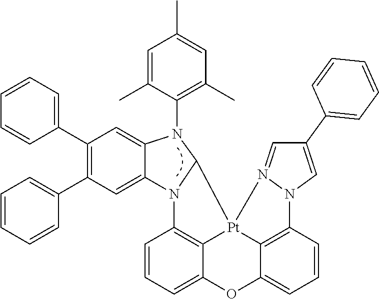

### Ex. 3-32 and 33:

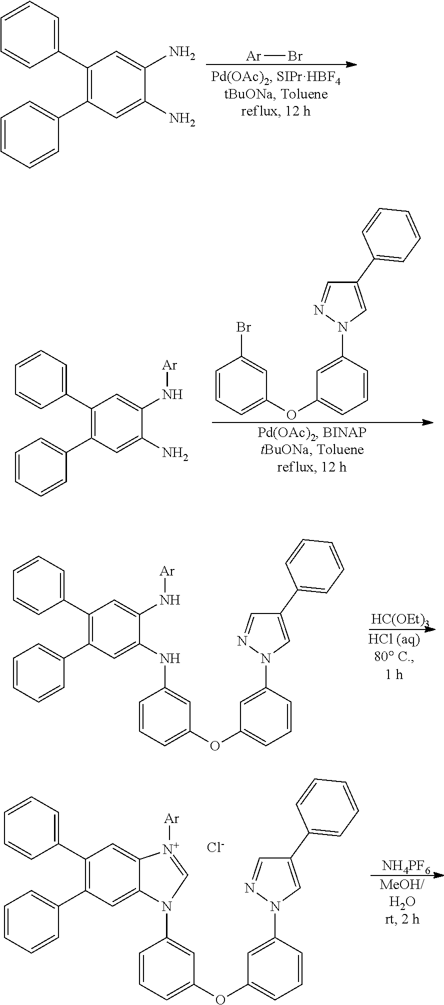

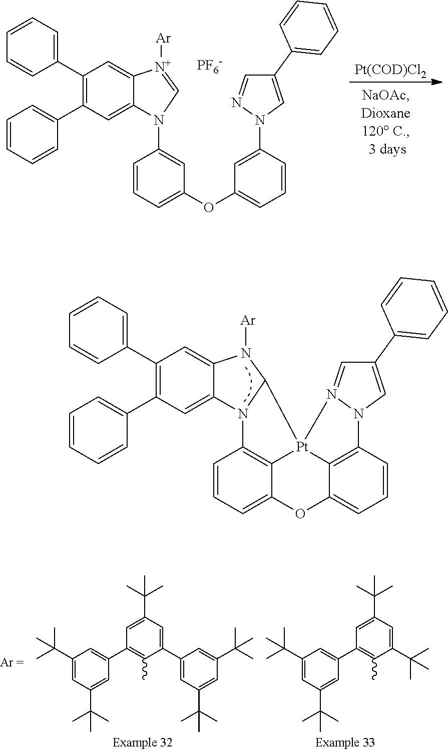

### Ex. 3-34:

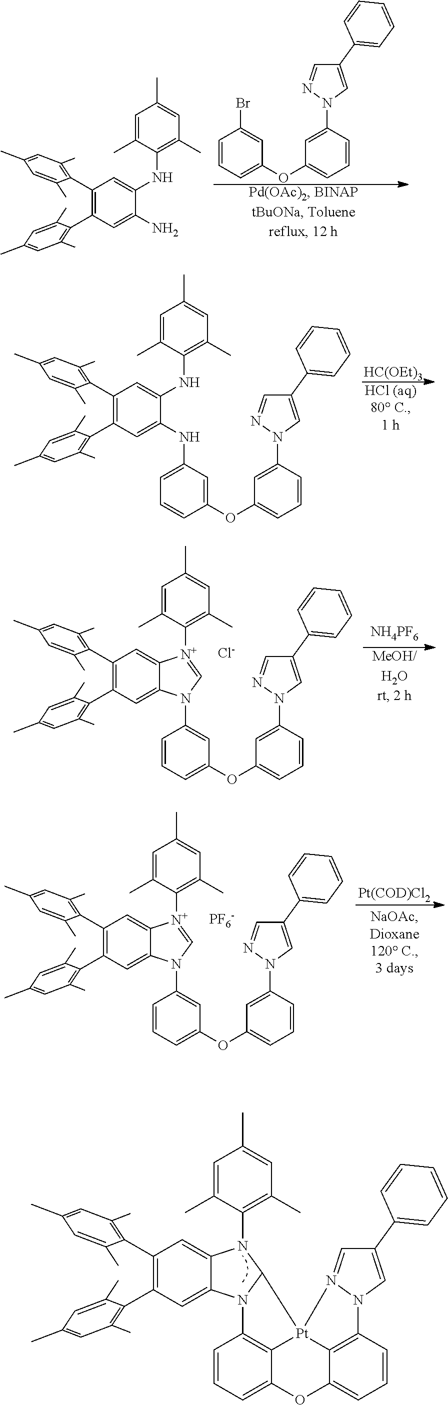

### Ex. 3-35 and 36:

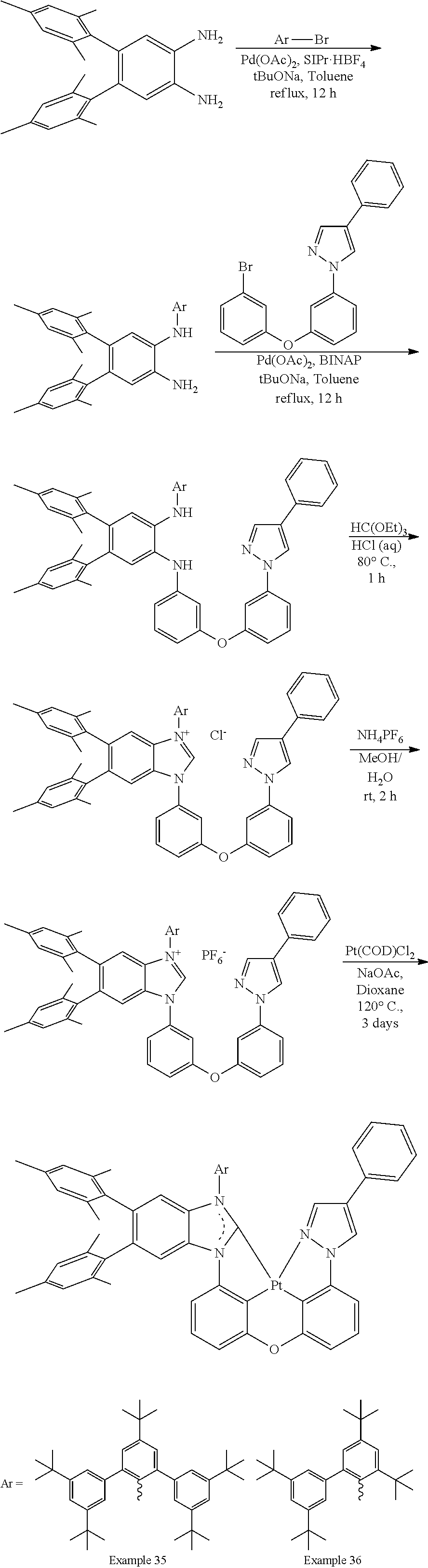

### Ex. 3-37:

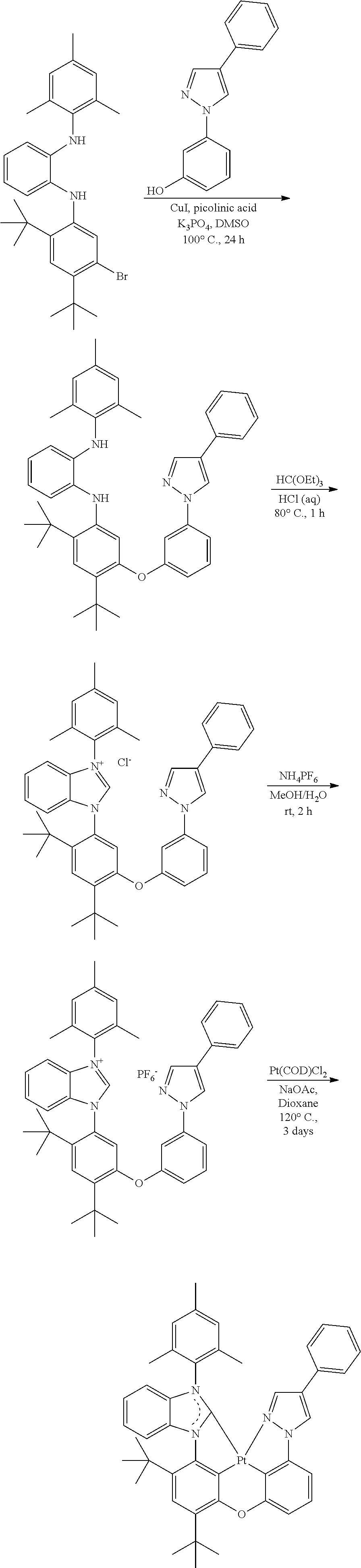

### Ex. 3-38 and 39:

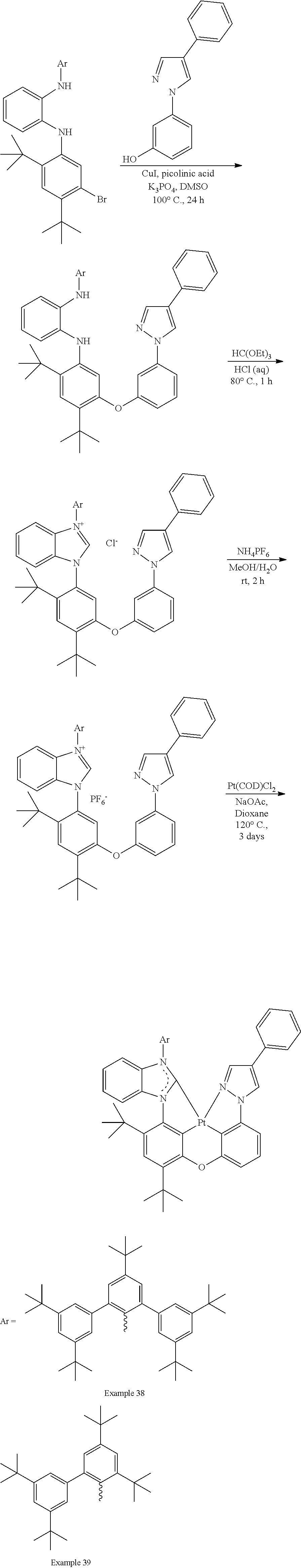

### Ex. 3-40:

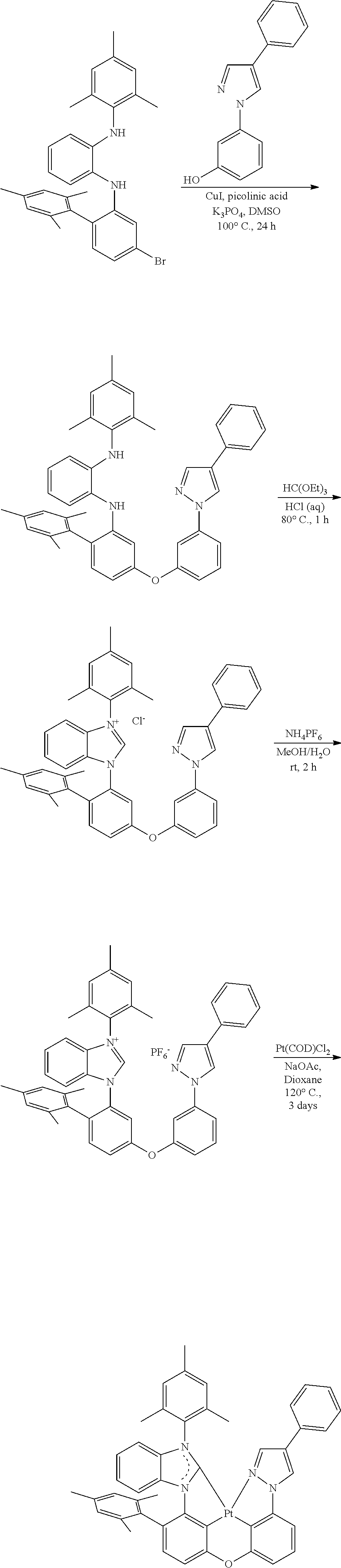

### Ex. 3-41 and 42:

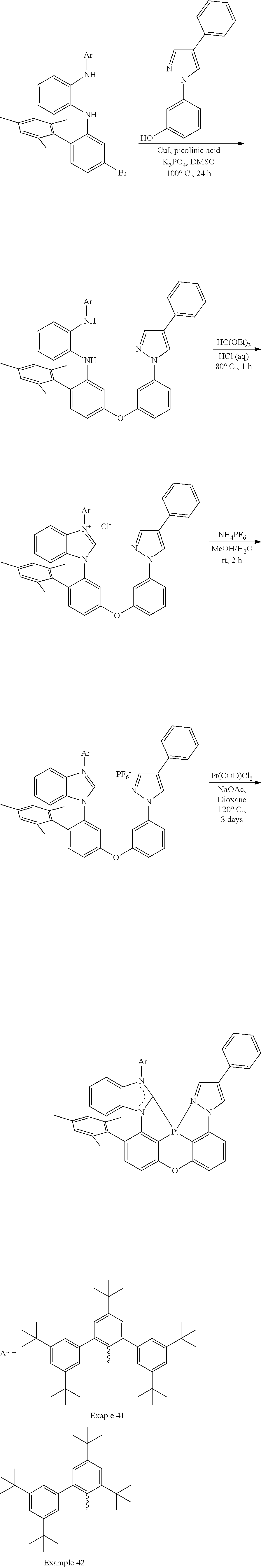

### Ex. 3-43:

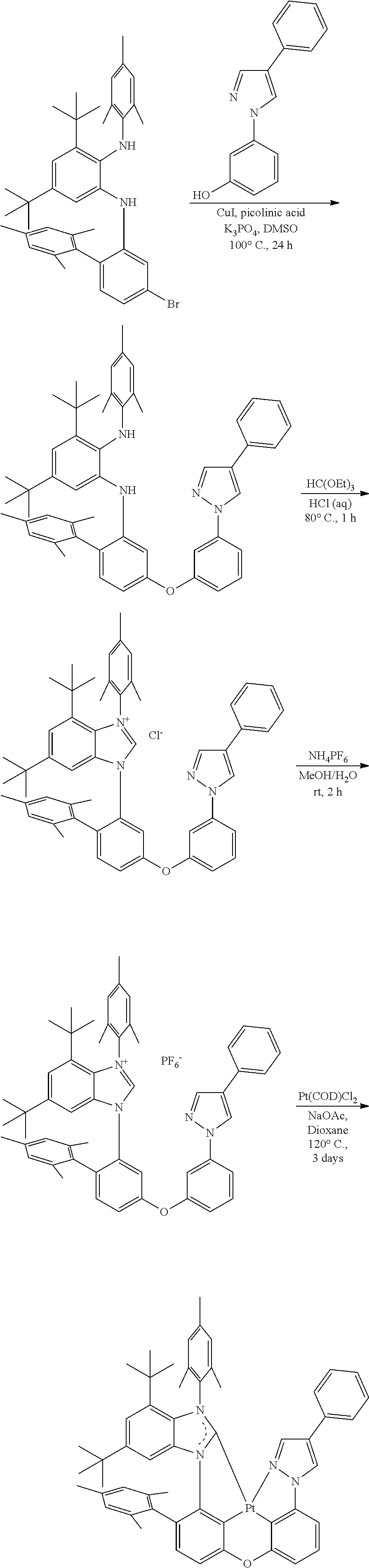

### Ex. 3-44 and 45:

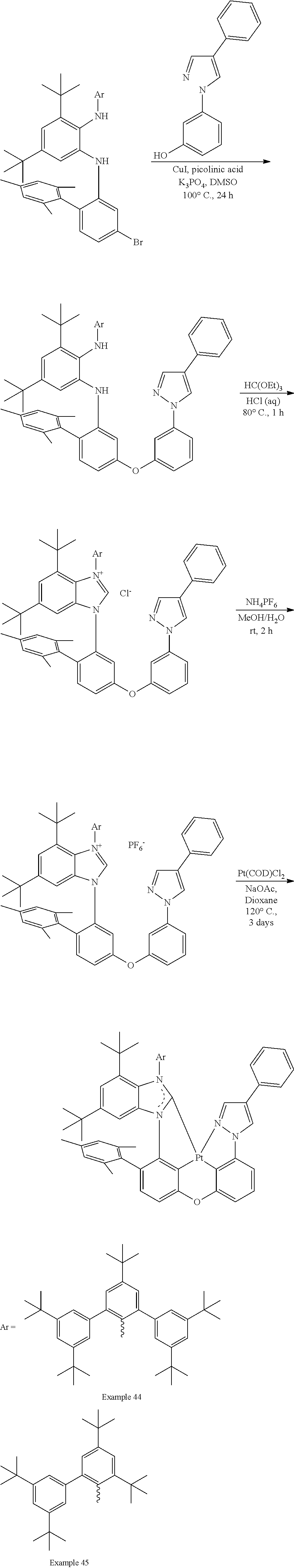

### Ex. 3-46:

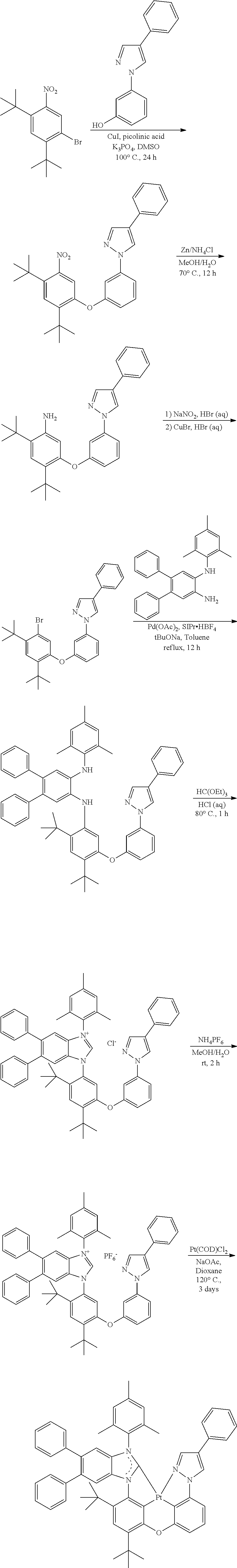

### Ex. 3-47 and 48:

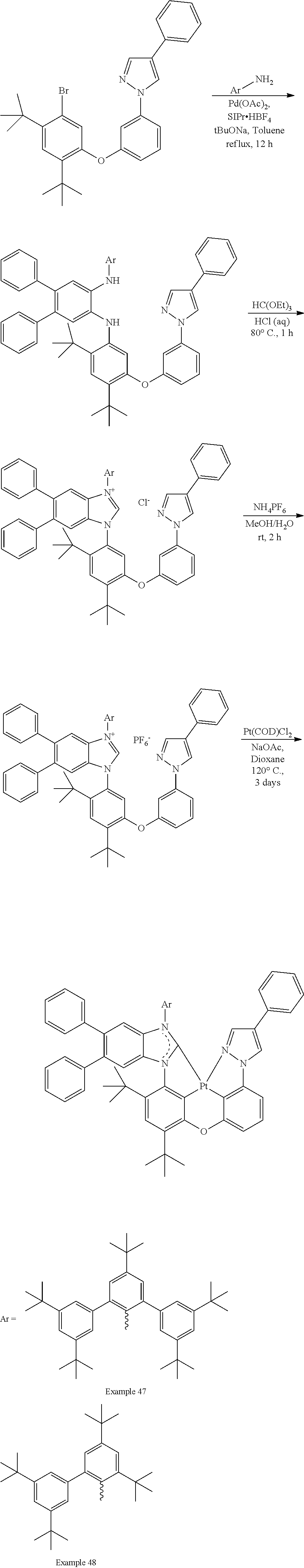

### Ex. 3-49:

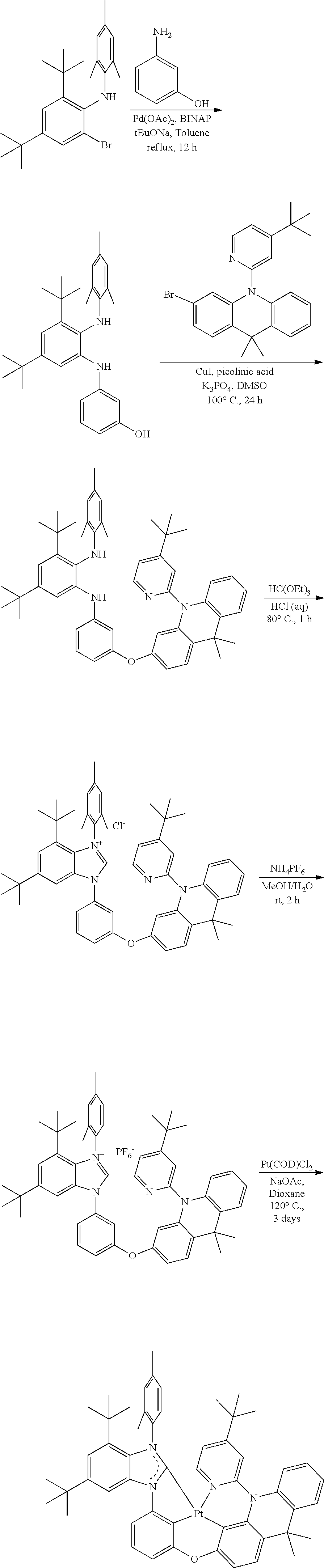

### Ex. 3-50 and 51:

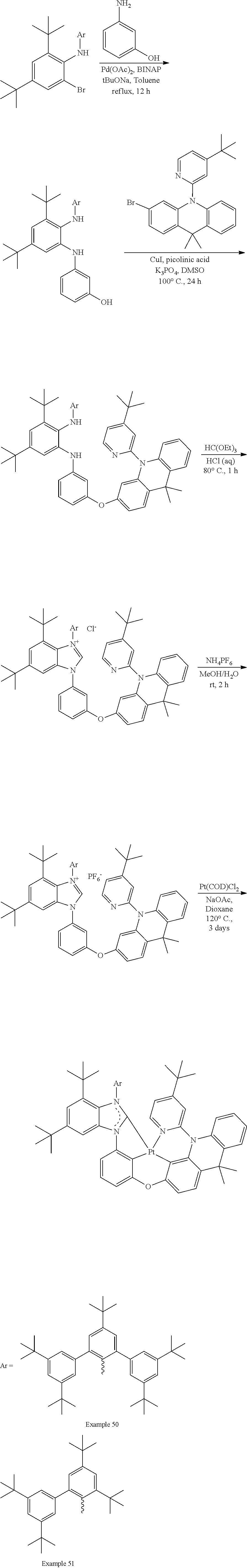

### Ex. 3-52:

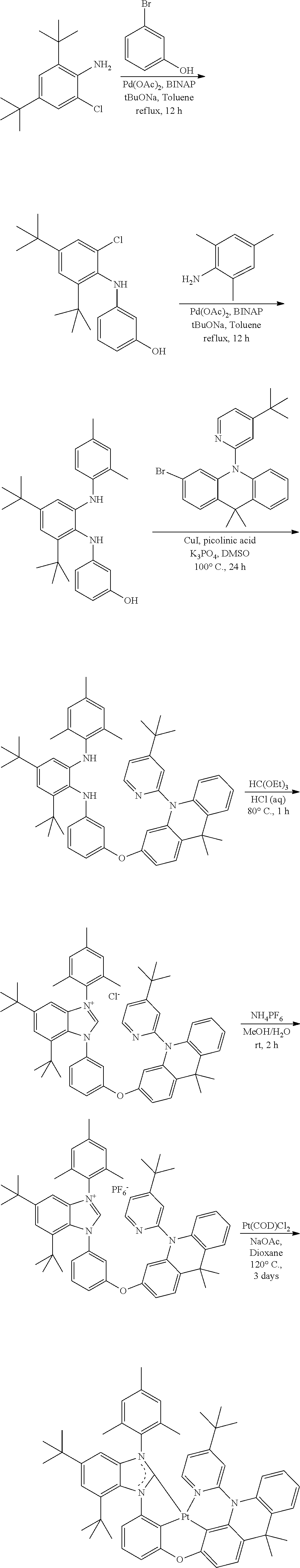

### Ex. 3-53 and 54:

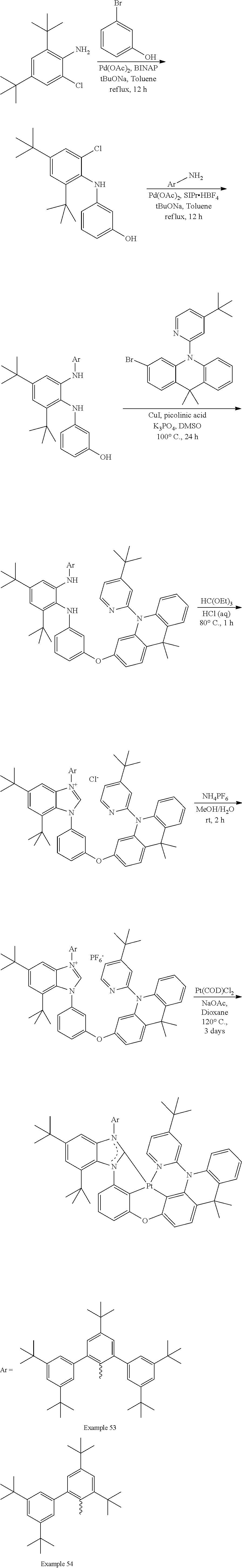

### Ex. 3-55:

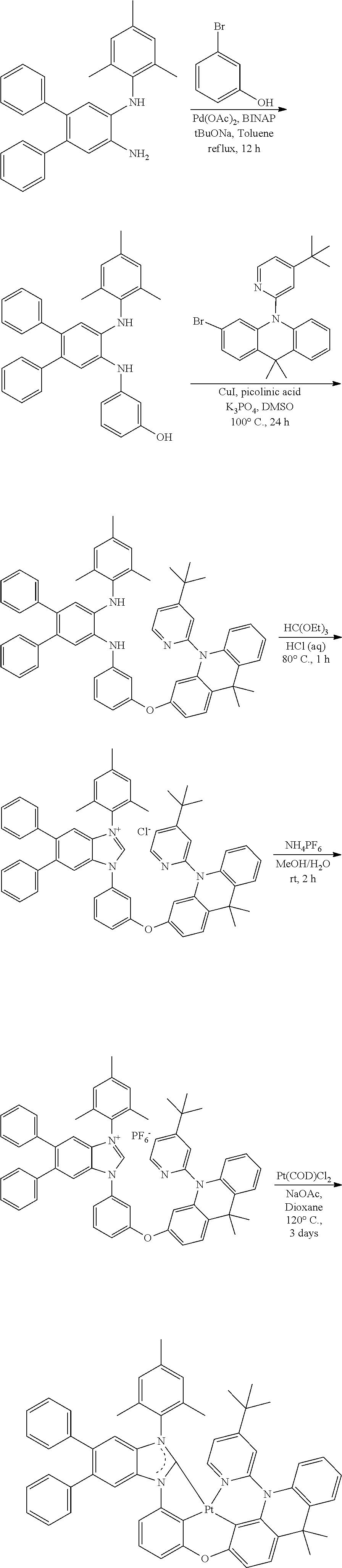

### Ex. 3-56 and 57:

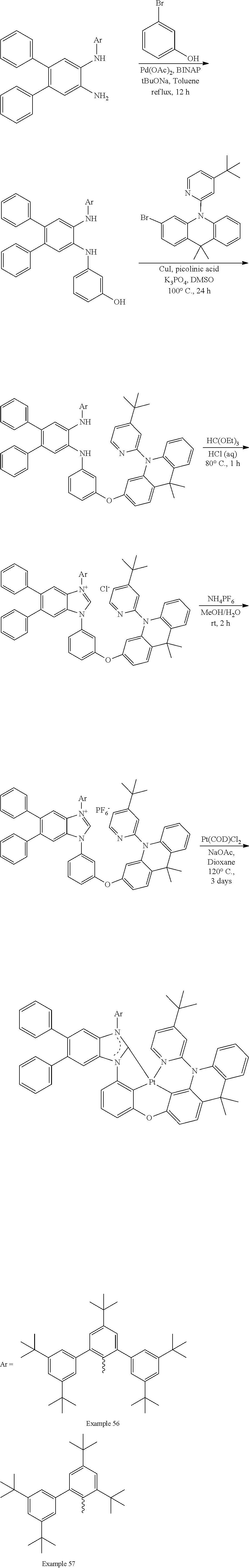

### Ex. 3-58:

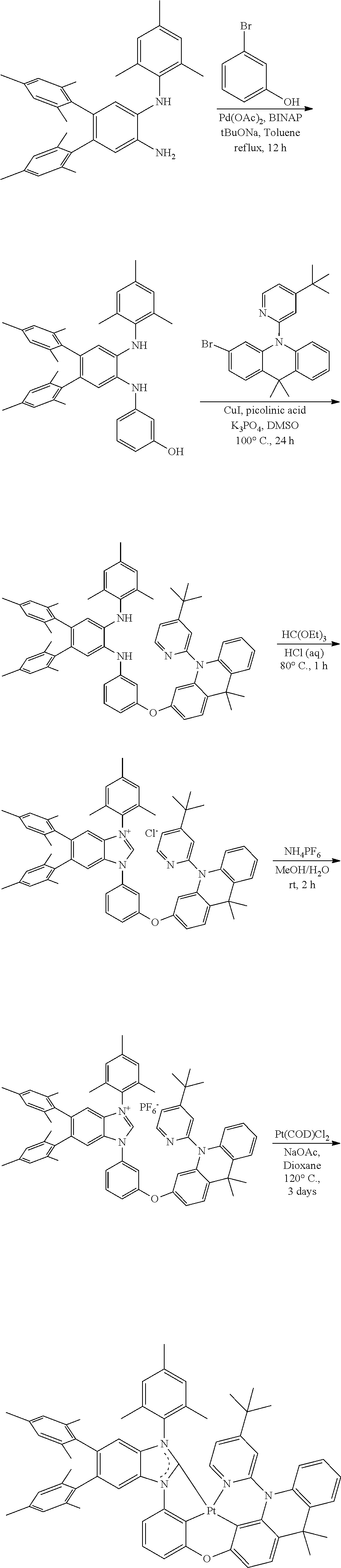

### Ex. 3-59 and 60:

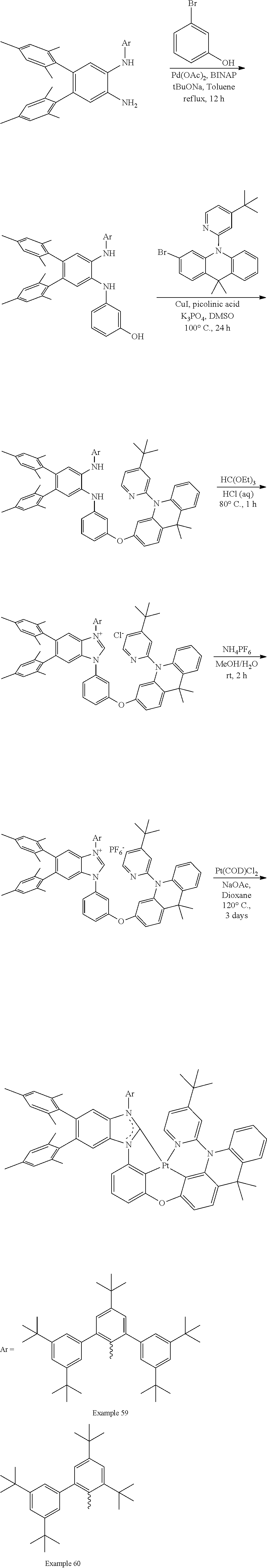

### Ex. 3-61:

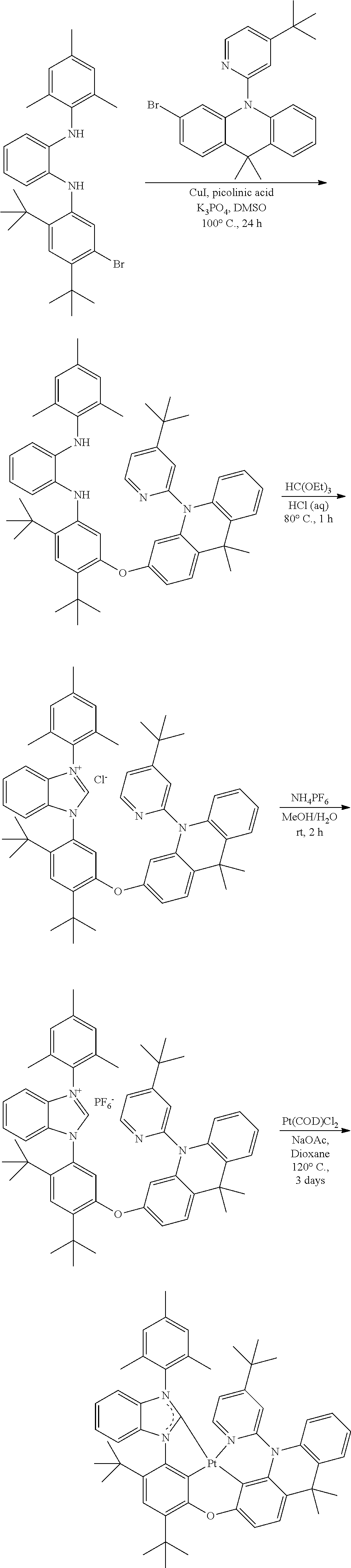

### Ex. 3-62 and 63:

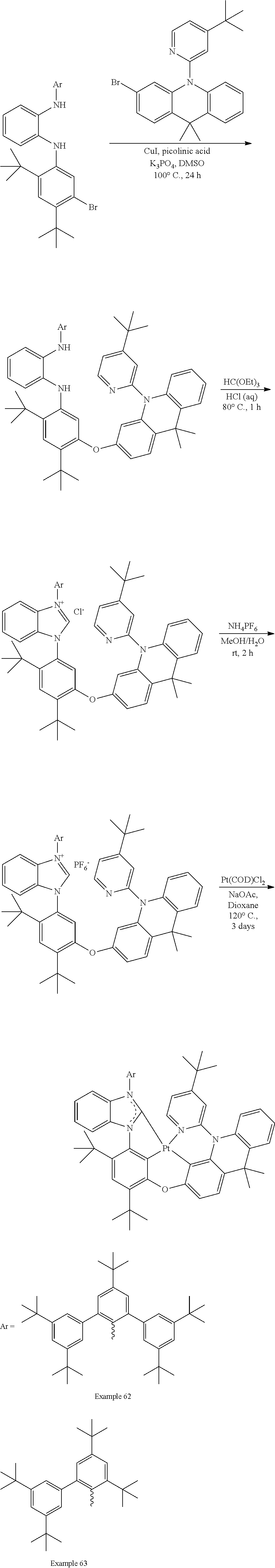

### Ex. 3-64:

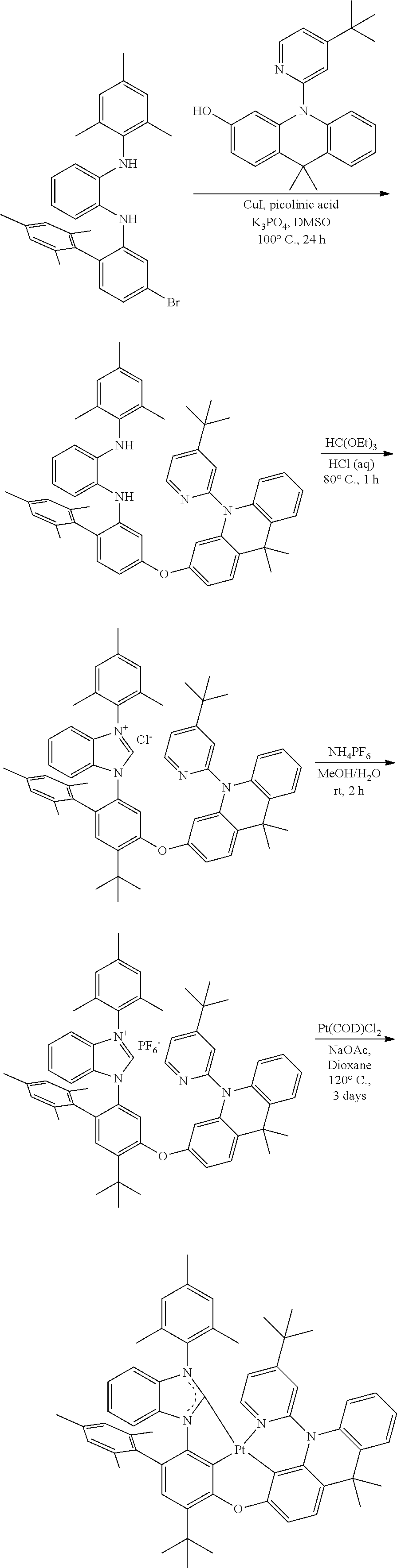

### Ex. 3-65 and 66:

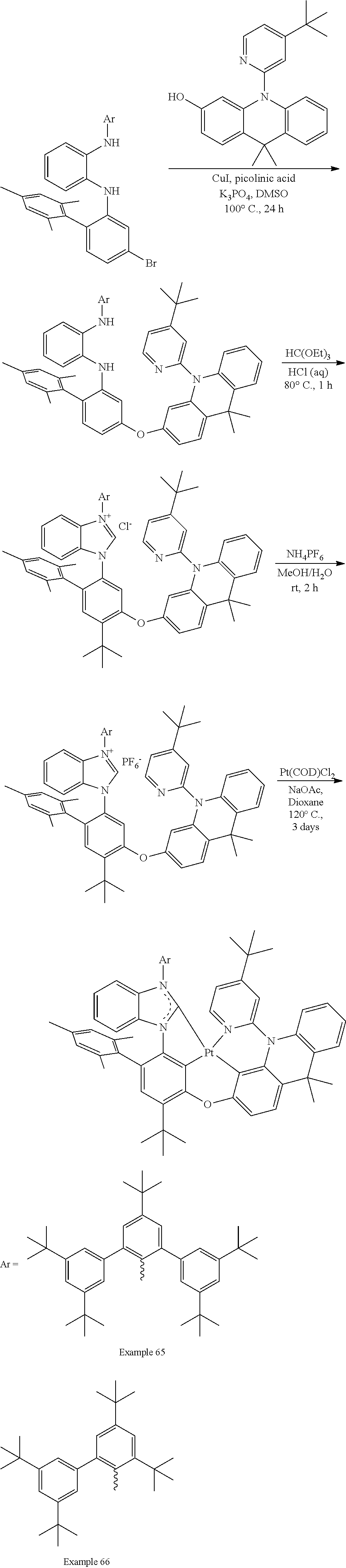

### Ex. 3-67:

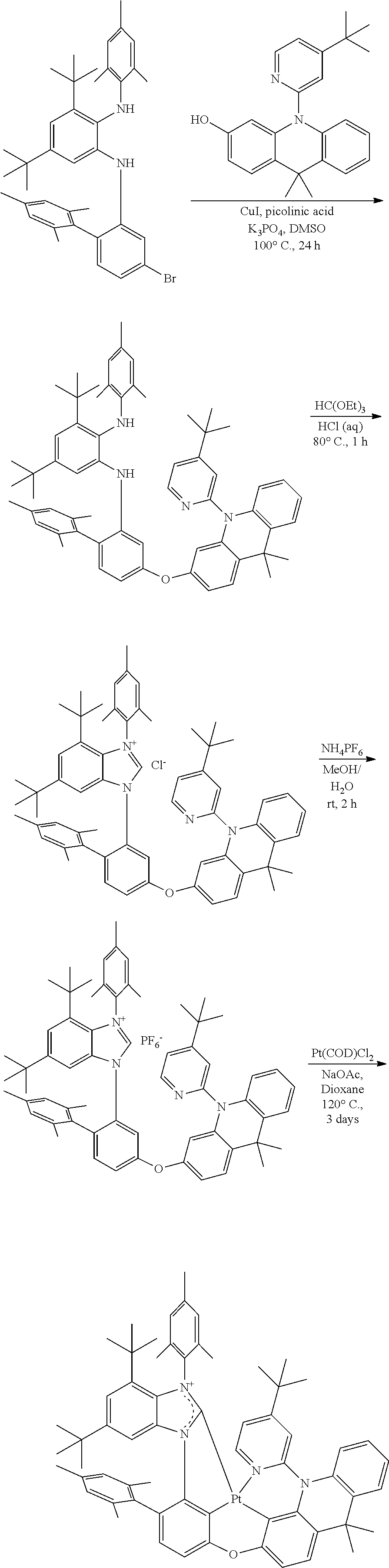

### Ex. 3-68 and 69:

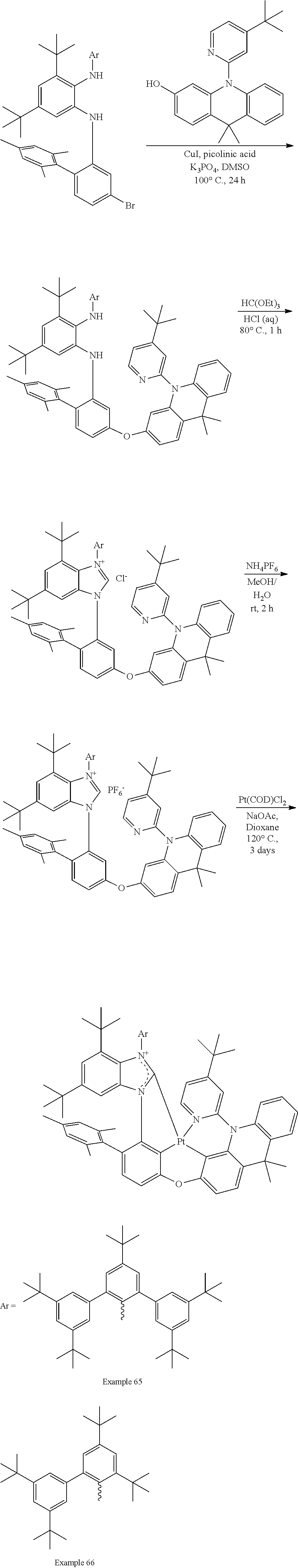

### Ex. 3-70:

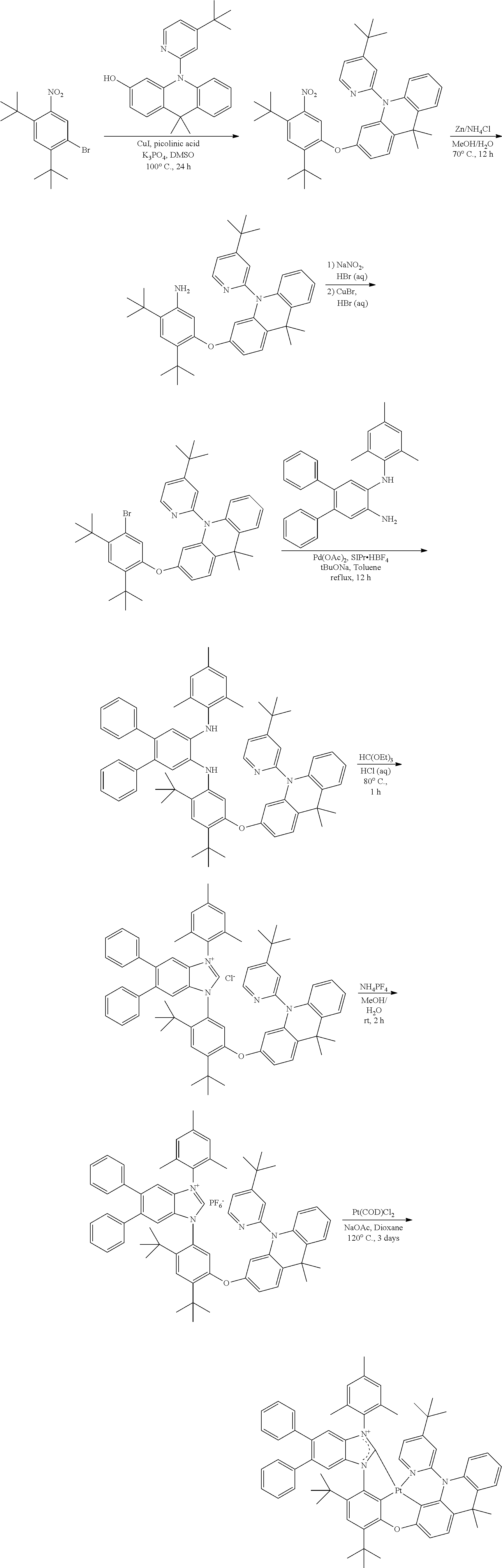

### Ex. 3-71-72:

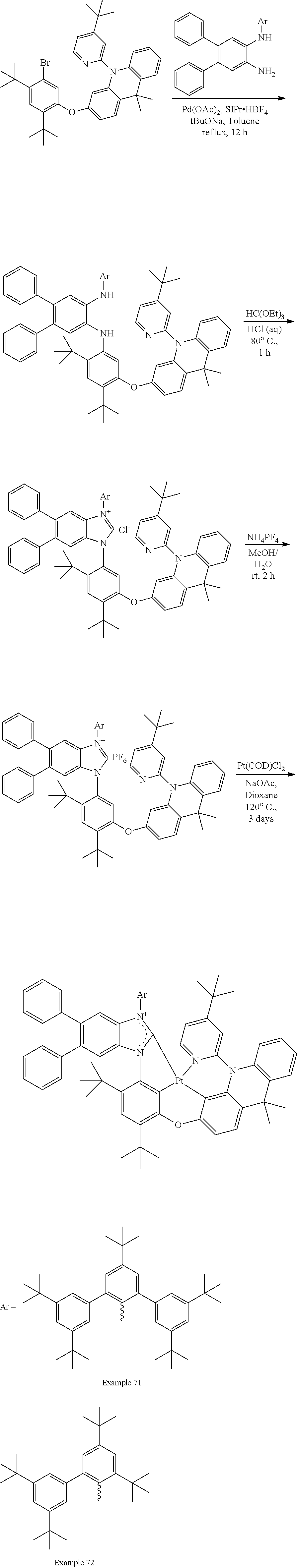

### Ex. 3-73-75:

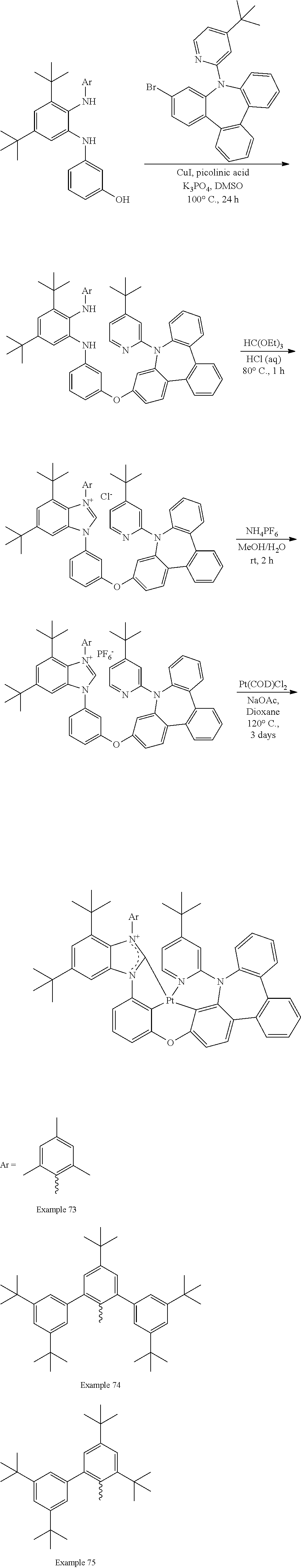

### Ex. 3-76-78:

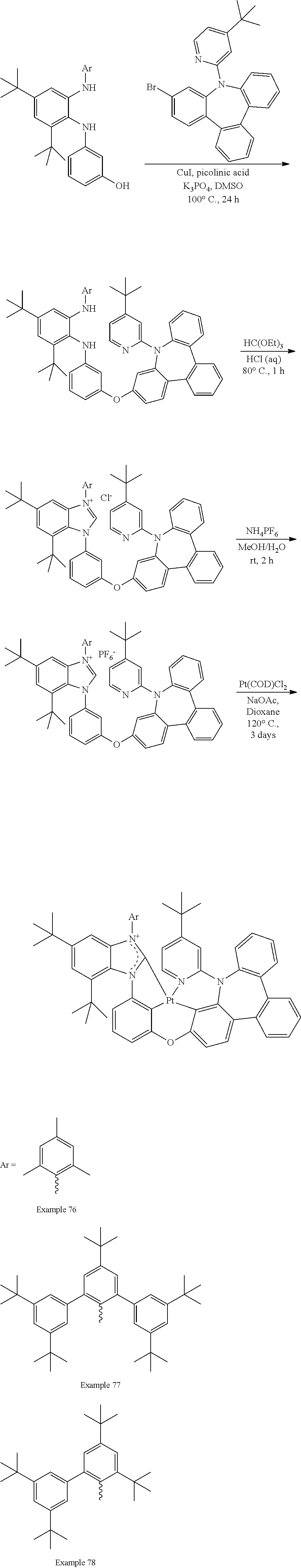

### Ex. 3-79-81:

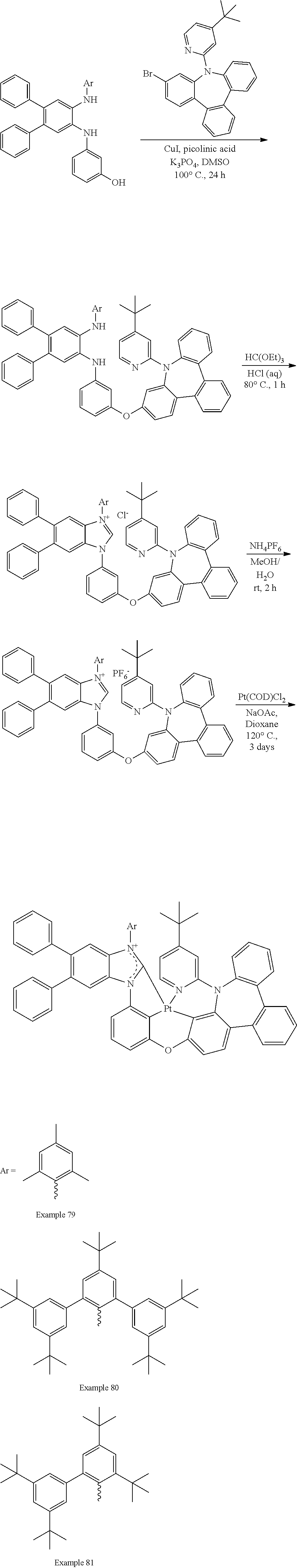

### Ex. 3-82-84:

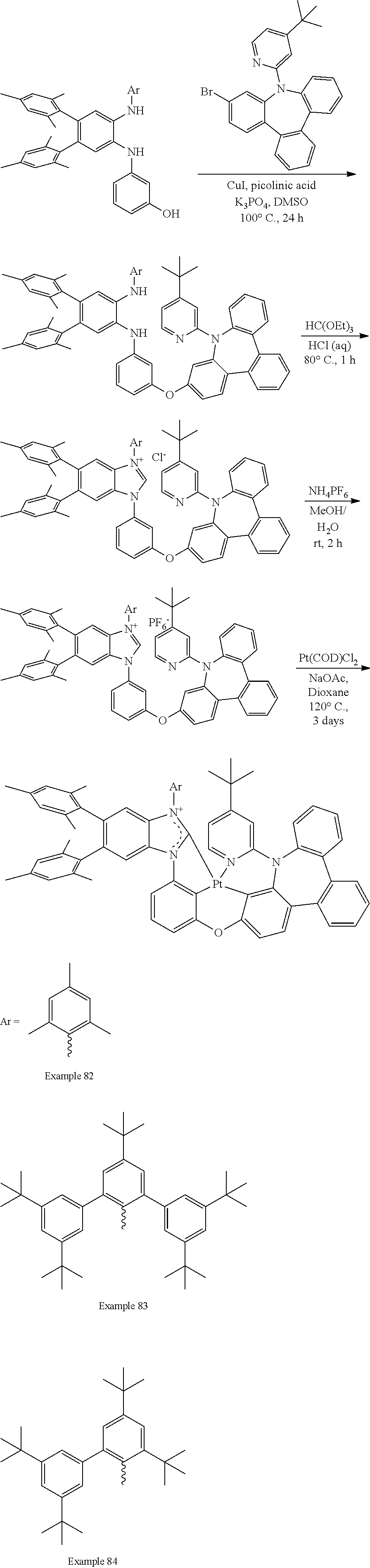

### Ex. 3-85-87:

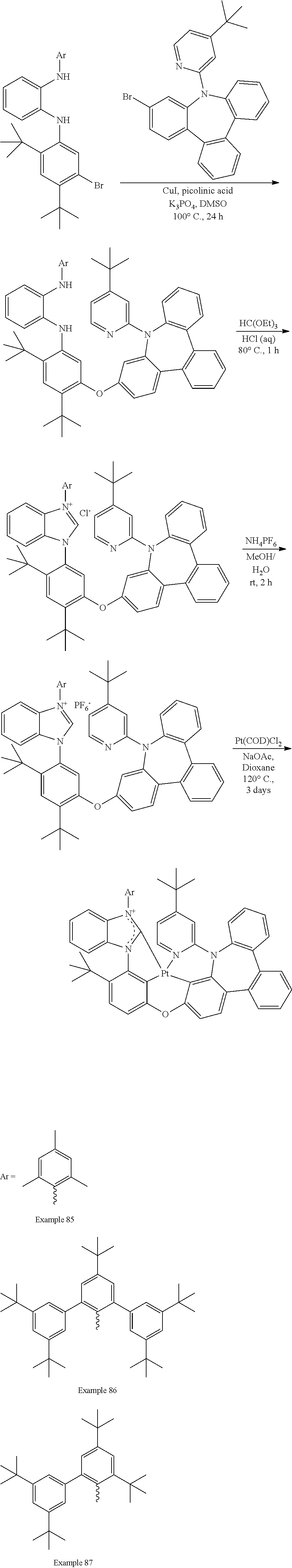

### Ex. 3-88-90:

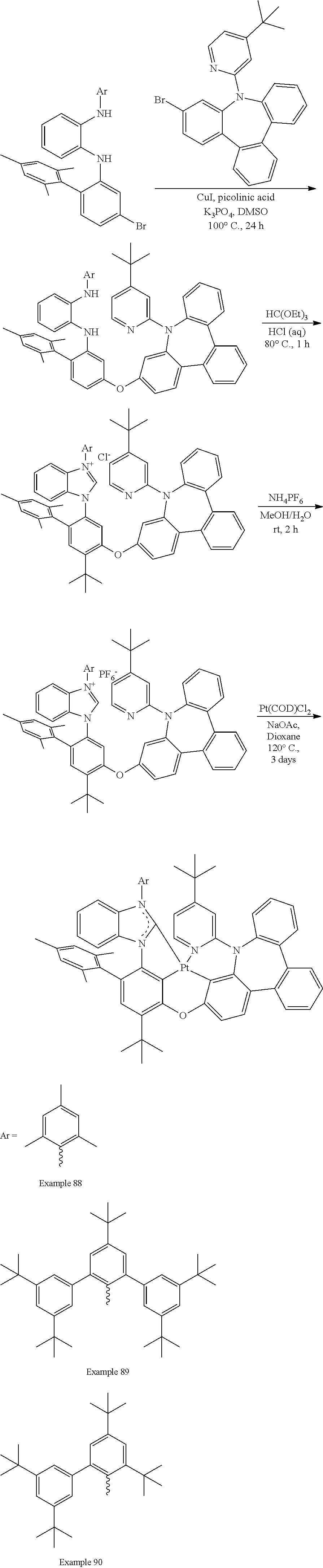

### Ex. 3-91-93:

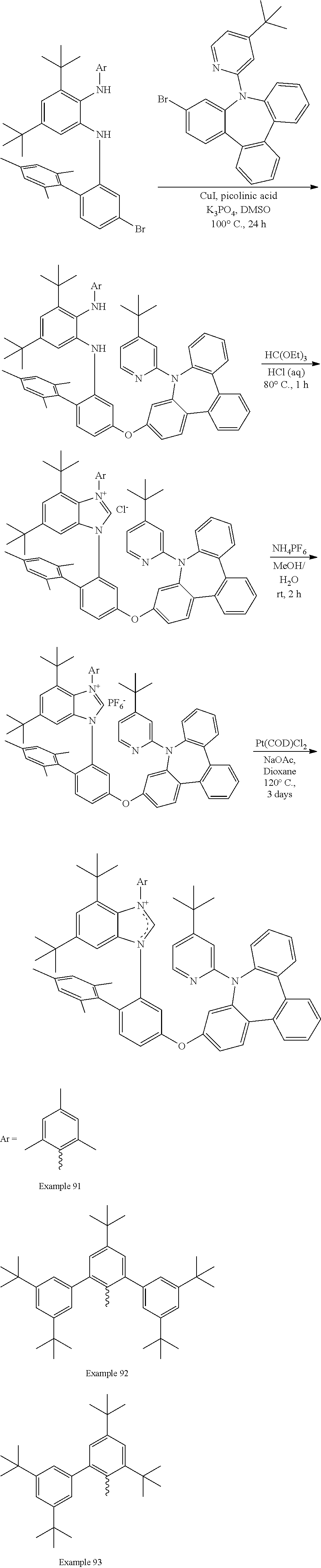

### Ex. 3-94-96:

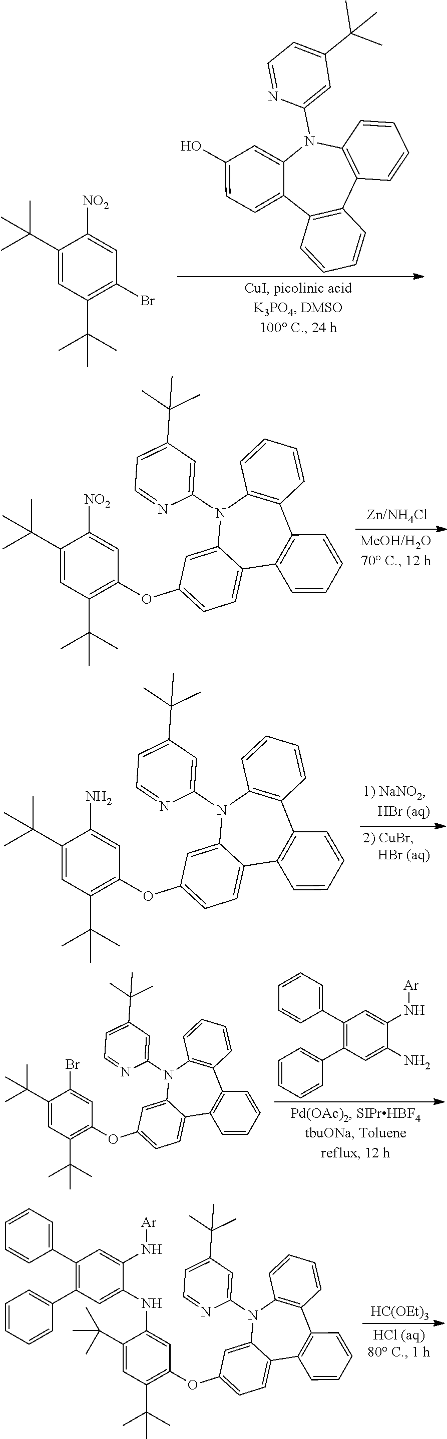

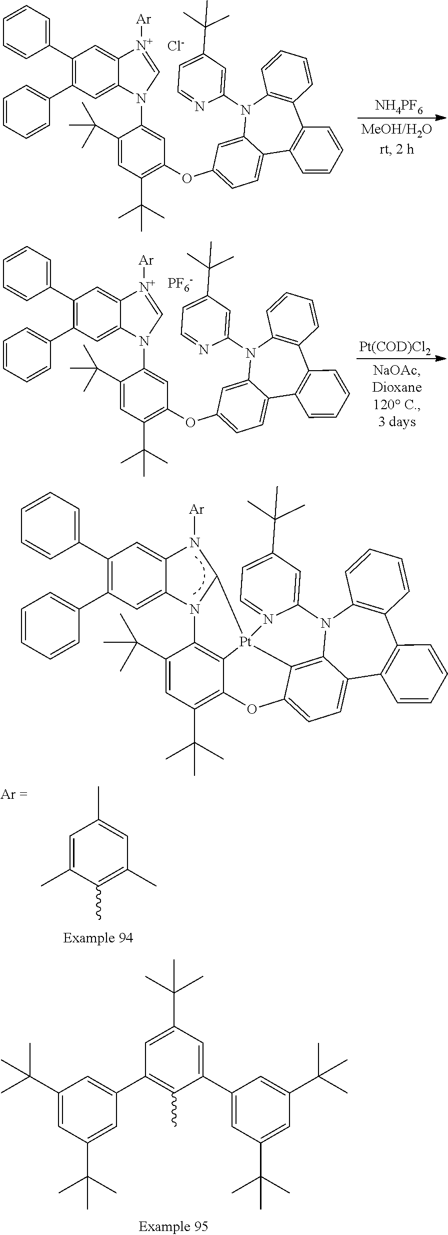

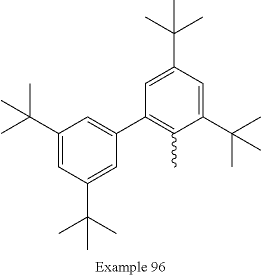

### Example 4: Tetradentate Platinum and Palladium Complexes with Narrowband Emission Employing Analogs of Bicarbazole and Phenyl-imidazole Carbene

In this invention, a series of platinum (II) and palladium (II) complexes with narrowband emission based on analogs of bicarbazole and phenyl-imidazole carbene have been designed. This class of emitters could be found utilization for full color displays and lighting applications.

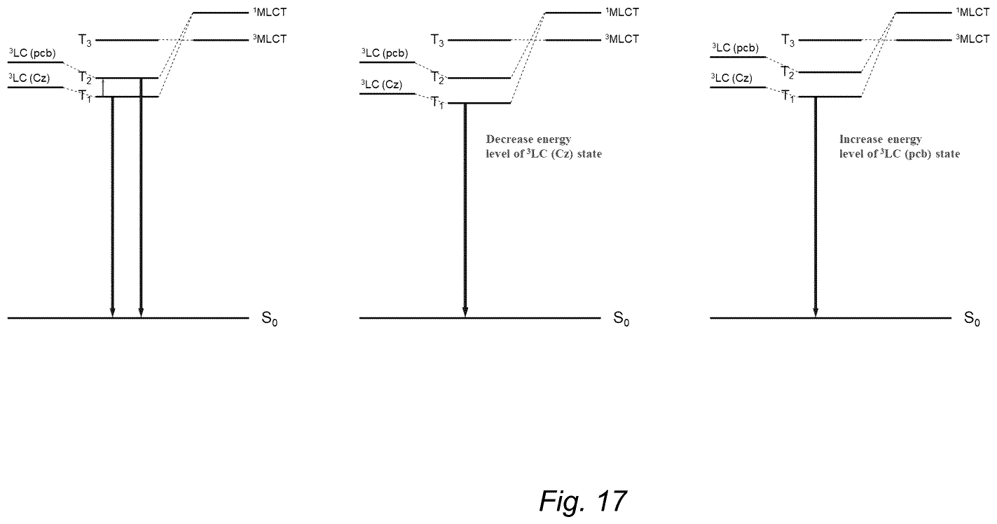

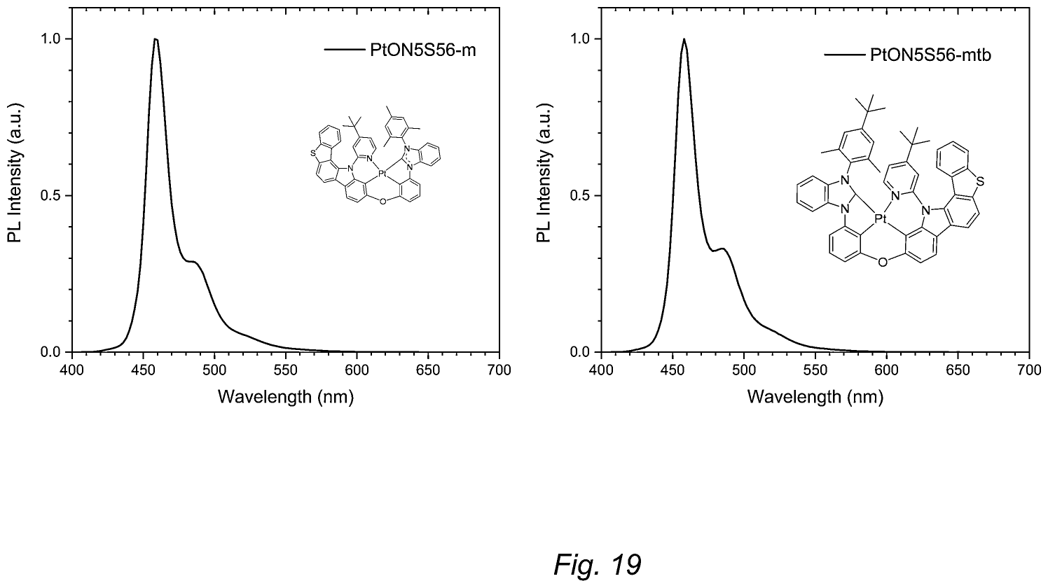

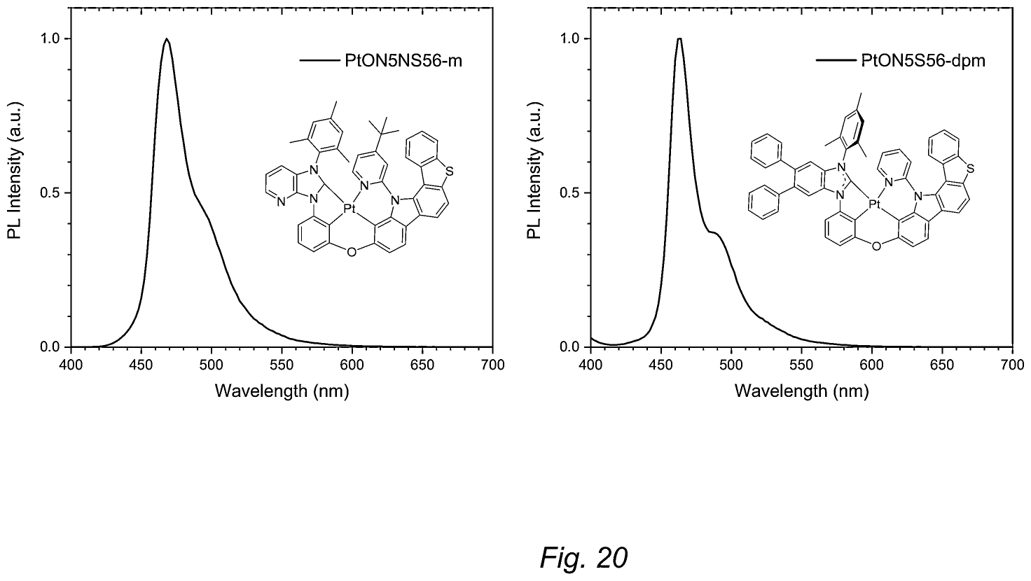

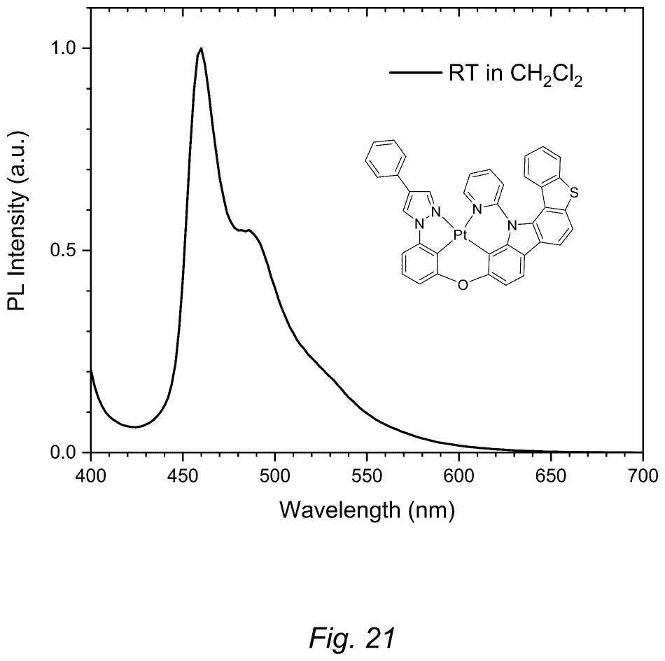

FWHM (full width at half maximum) is an important property for improving color purity. The broad emission resulting from second-lowest triplet energy state (T₂) emission and vibronic coupling is a major hurdle to overcome when designing OLED emitters. Increasing the energy gap between T₁ and T₂ by reducing the energy of T₁ or increasing the energy of T₂ can effectively inhibit T₂ emission (FIG. 17). In PtON5S56-m, the extended conjugation on the carbazole ring lowers the energy level of T₁, resulting in a larger energy separation between T₁ and T₂. Thus, a narrowband emission under room temperature is achieved. The photoluminescent spectra of exemplary compounds PtON5S56-m and PtON5S56-mtb are presented in FIG. 19. The photoluminescent spectra of exemplary compounds PtON5NS56-m and PtON5S56-dpm are presented in FIG. 20. The photoluminescent spectrum of another exemplary compound is presented in FIG. 21.

Compounds may be synthesized in the following manner:

### Ex. 1

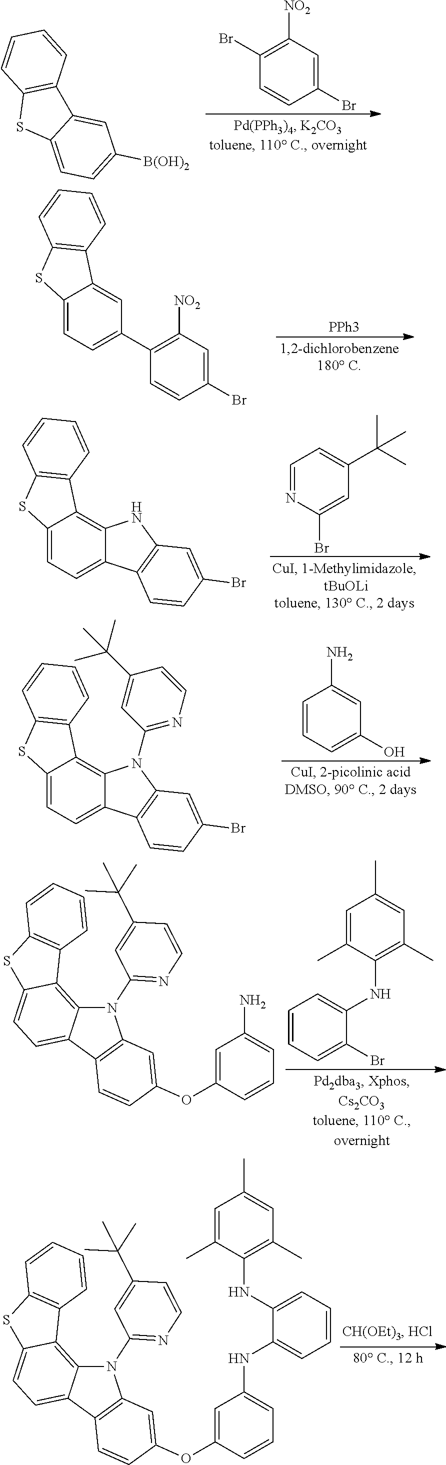

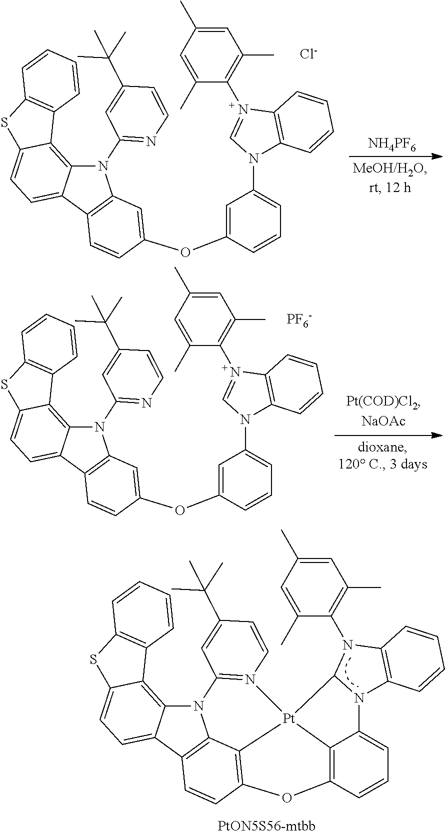

### Ex. 2

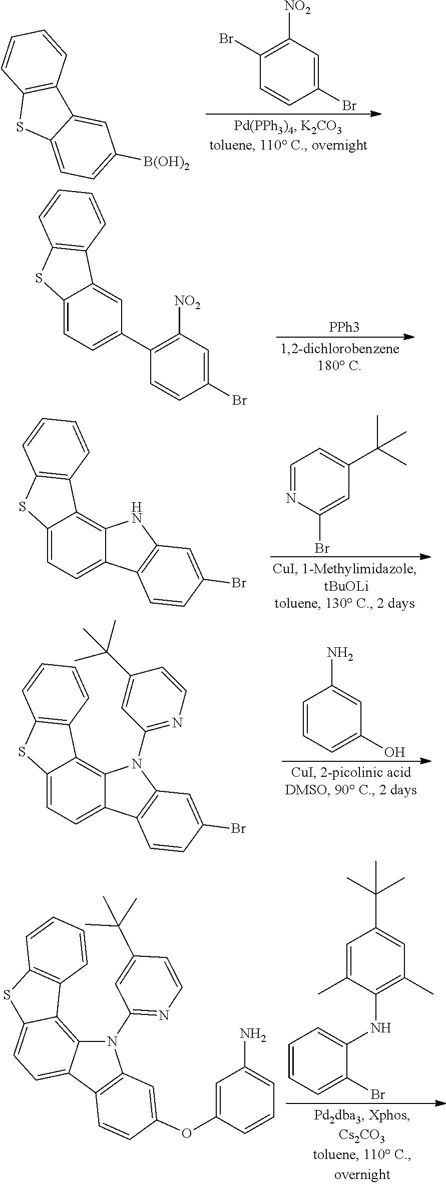

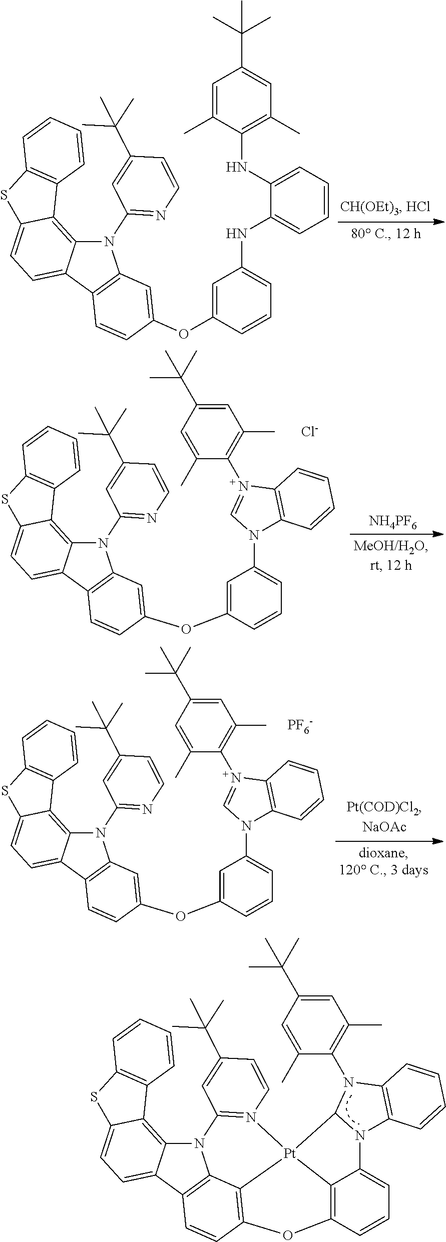

### Ex. 3

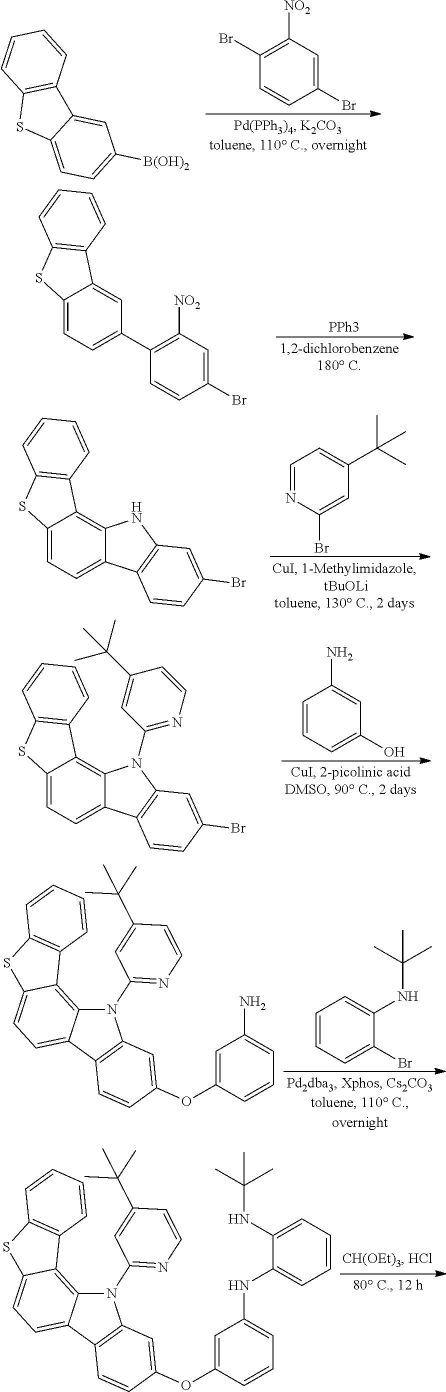

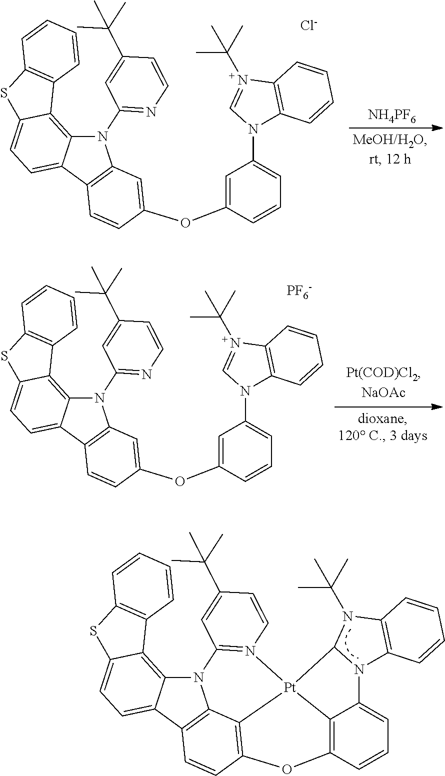

### Ex. 4

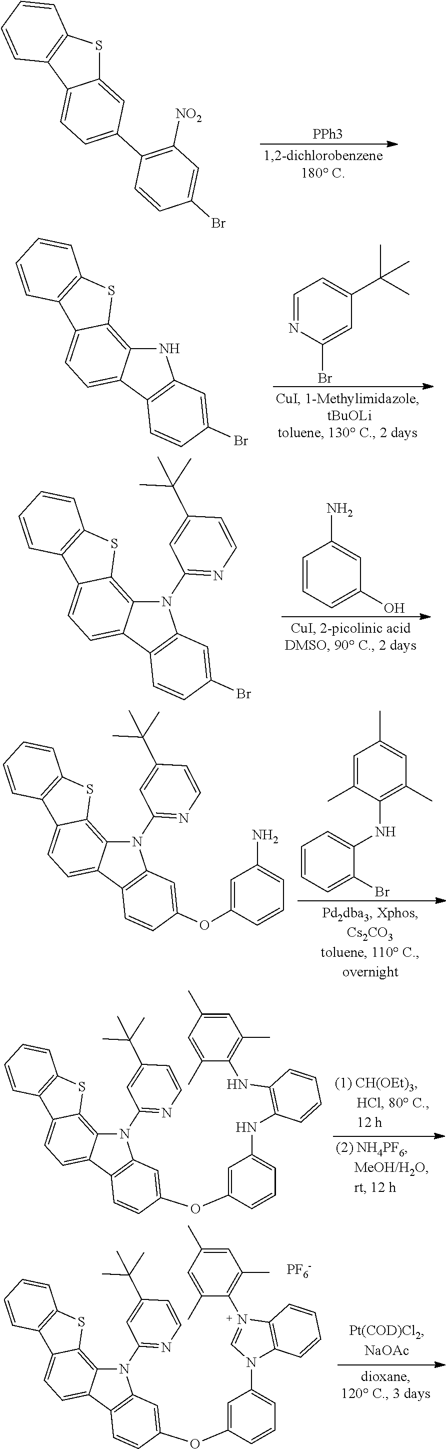

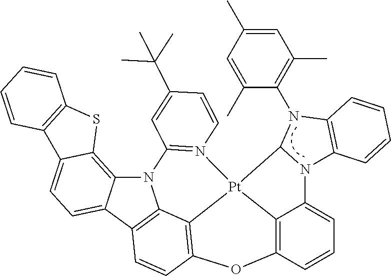

### Ex. 5

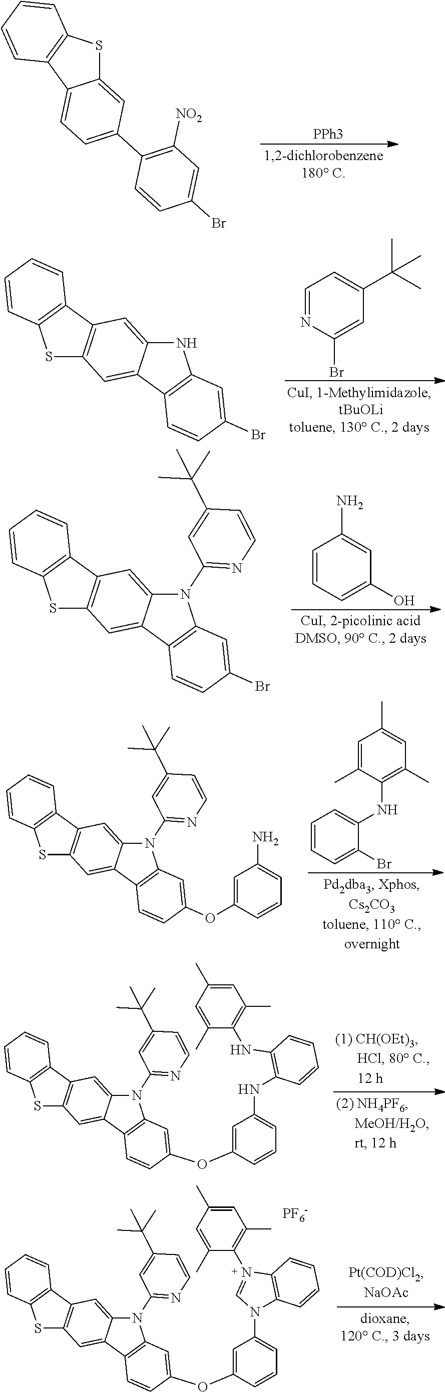

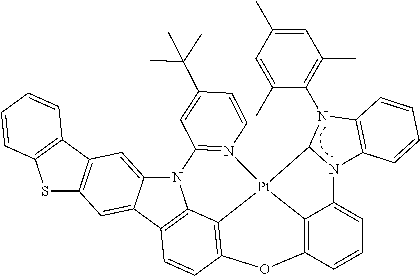

### Ex. 6

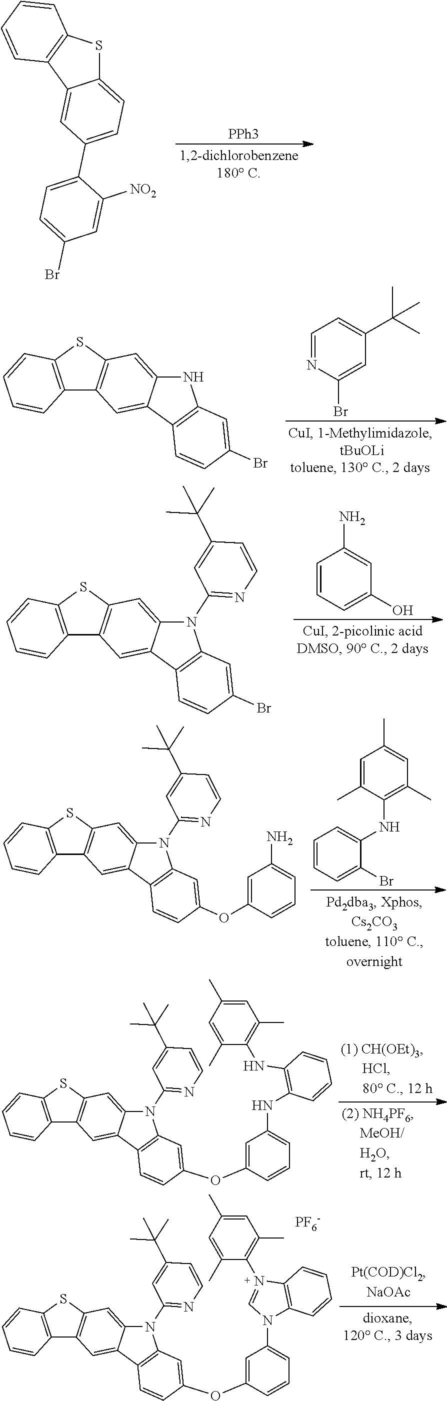

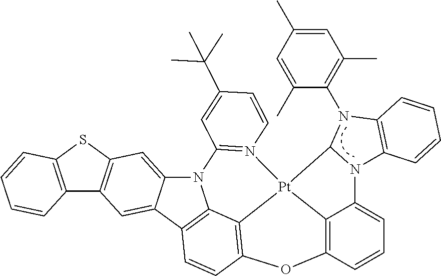

### Ex. 7

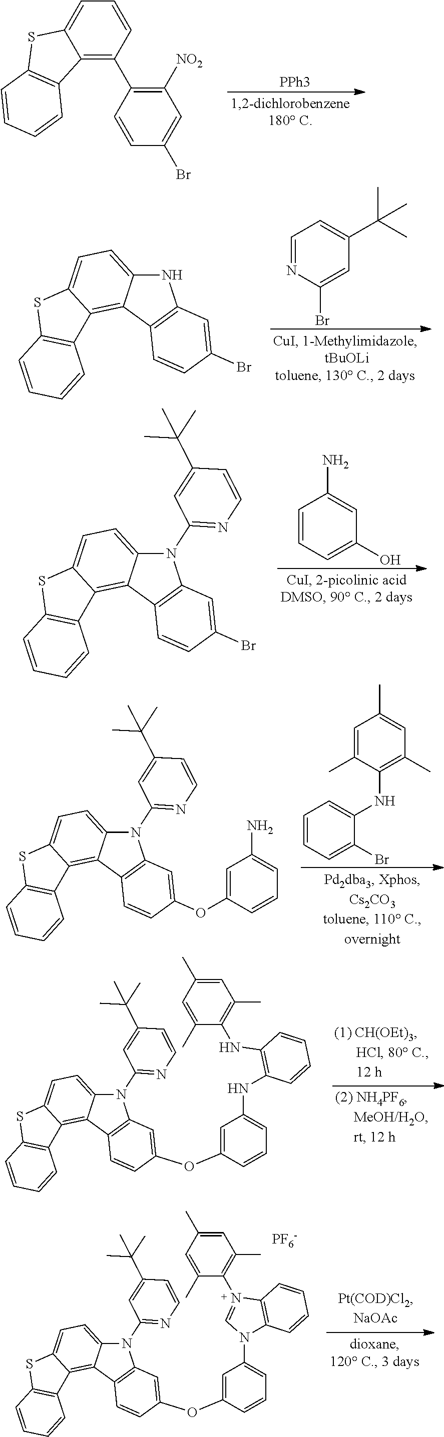

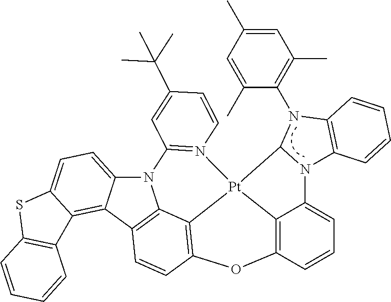

### Ex. 8

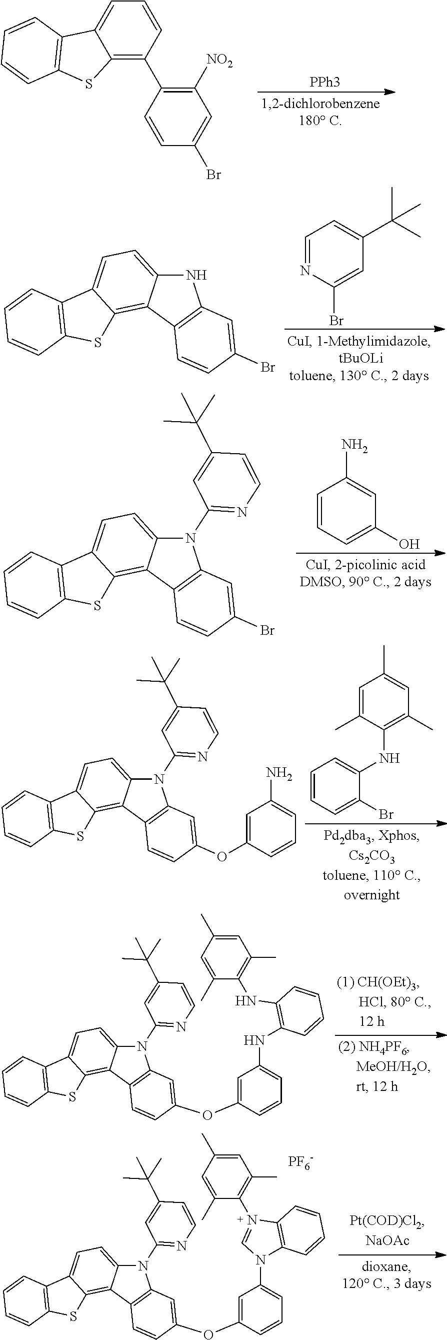

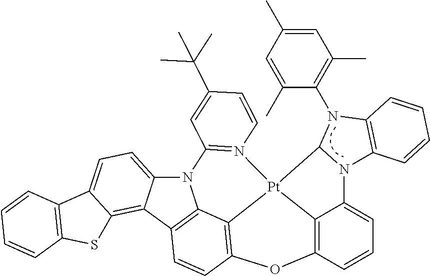

### Ex. 9

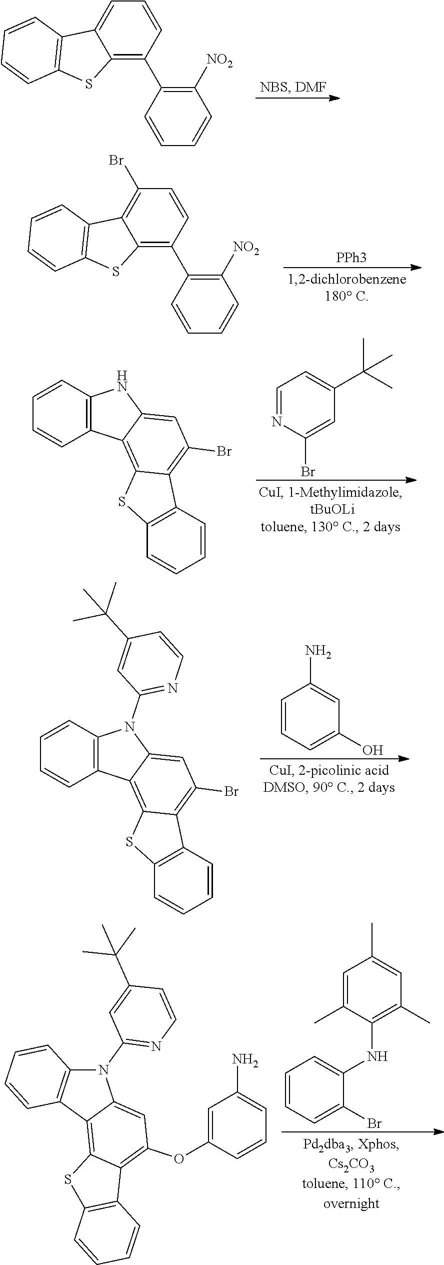

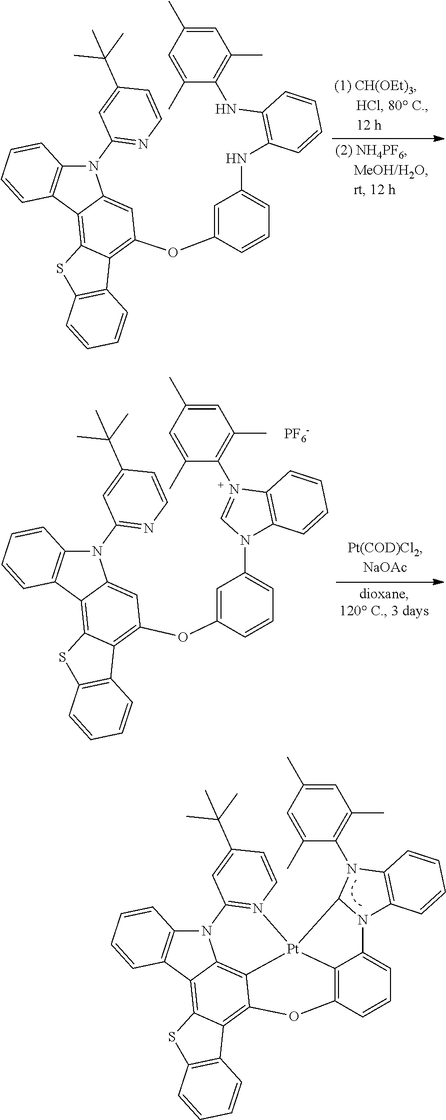

### Ex. 10

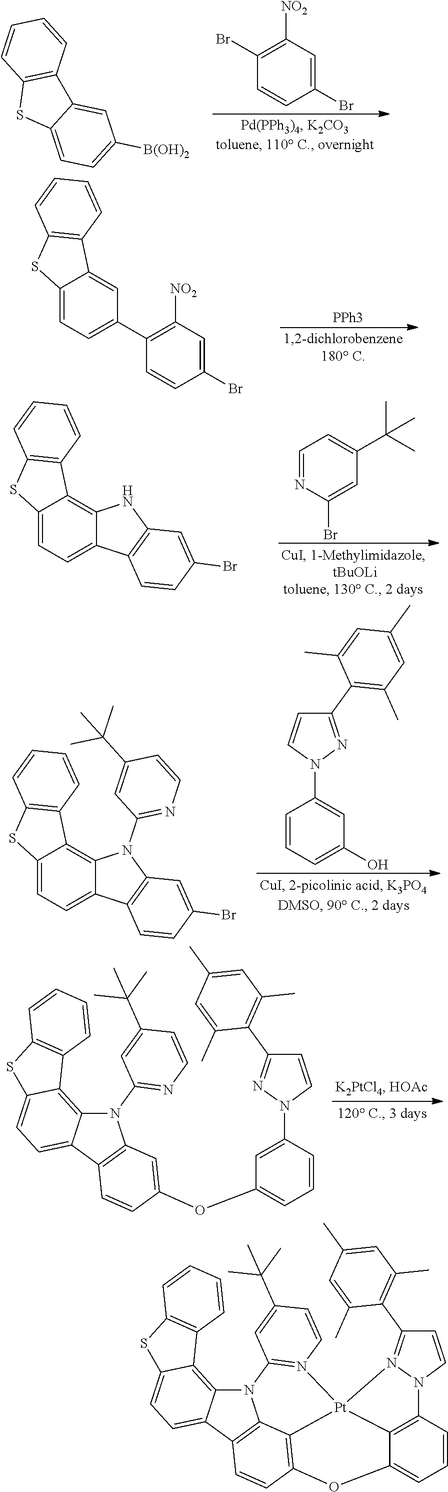

### Ex. 11

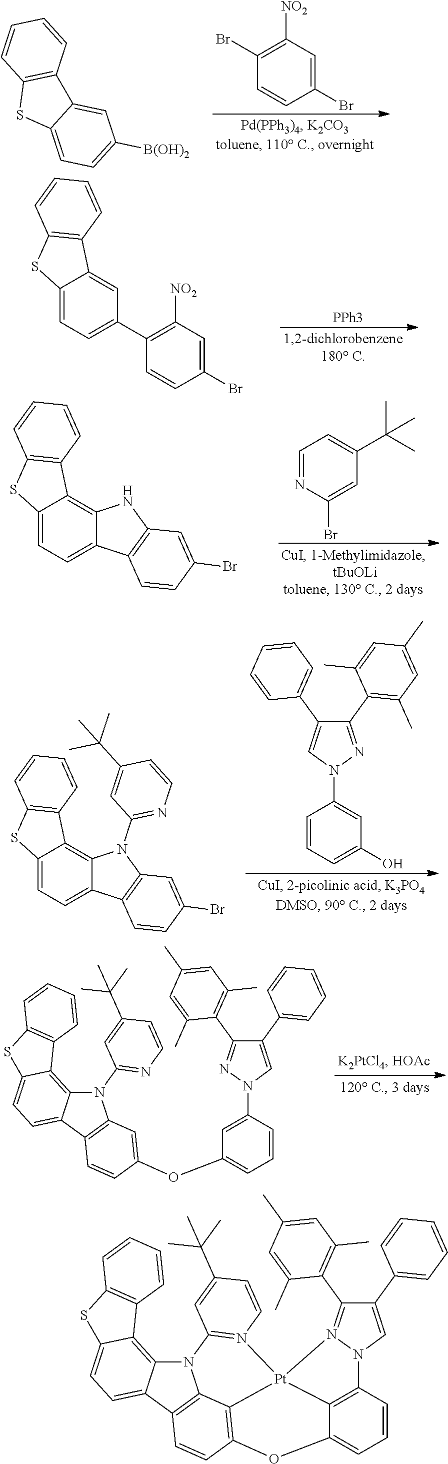

### Ex. 12

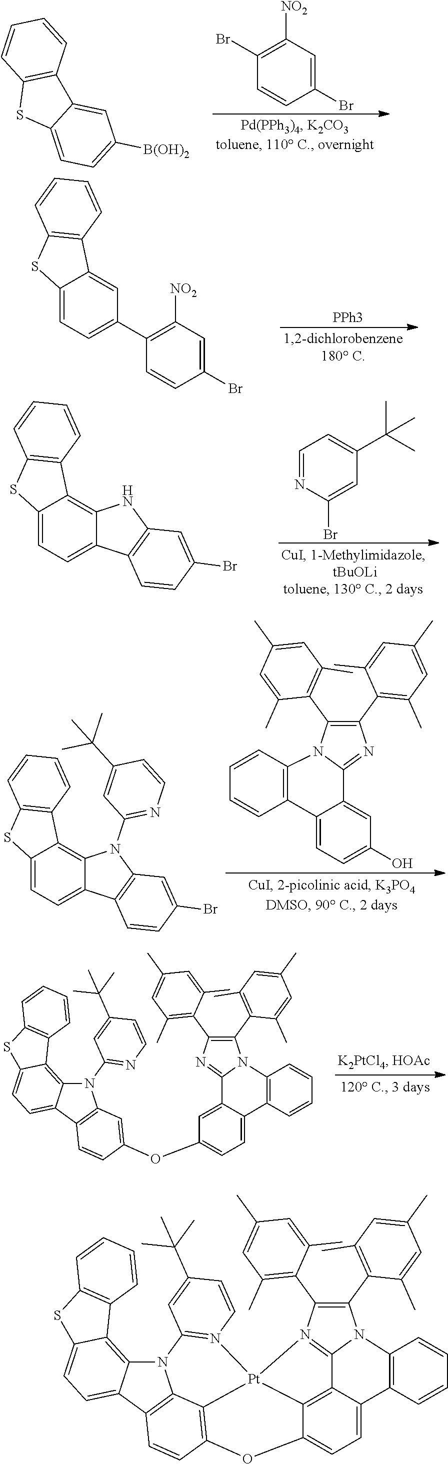

### Ex. 13

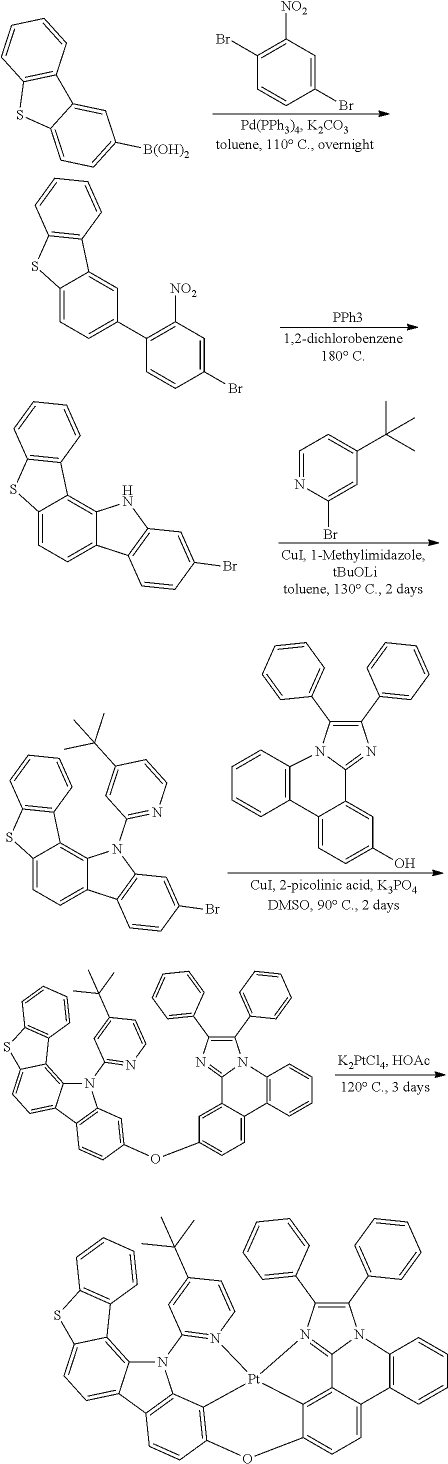

### Ex. 14

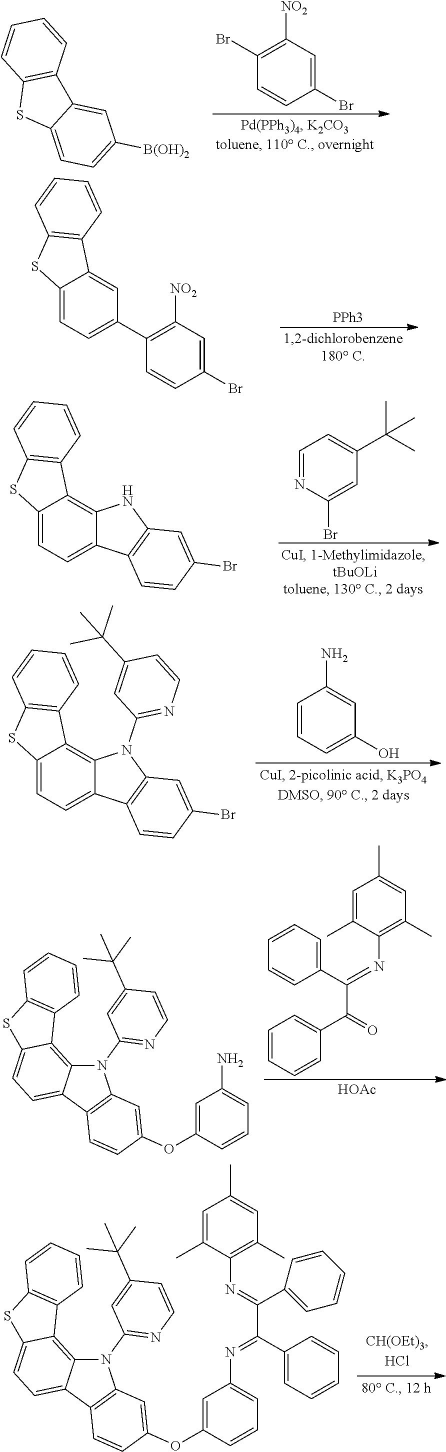

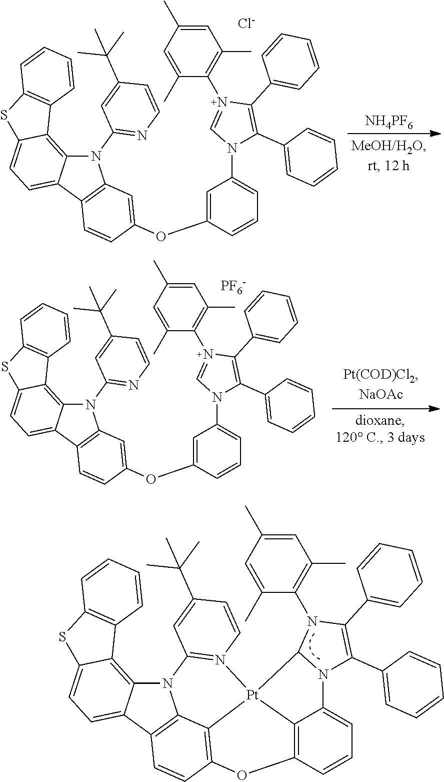

### Ex. 4-1:

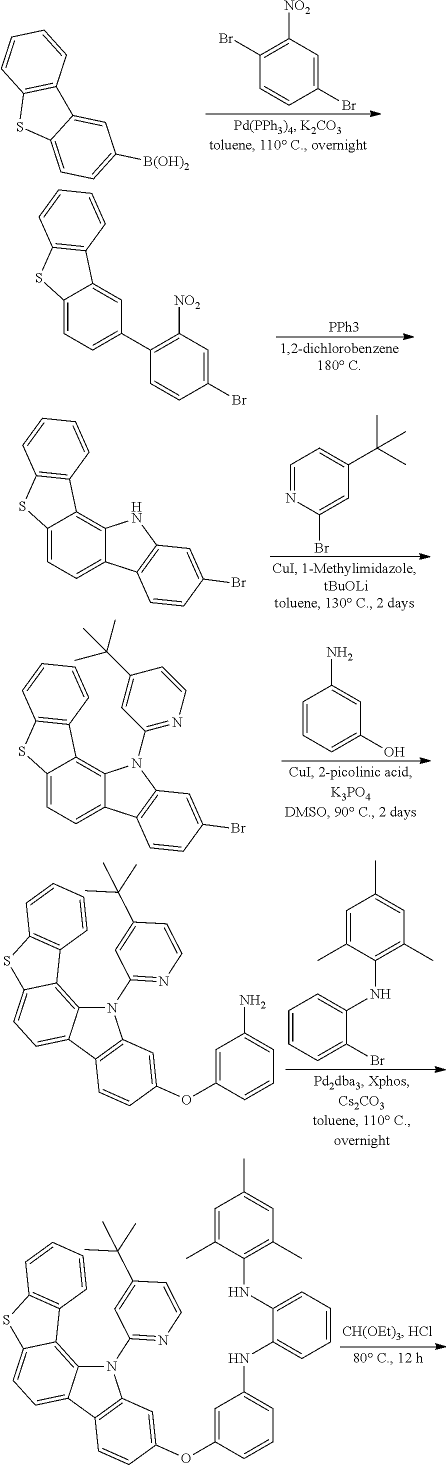

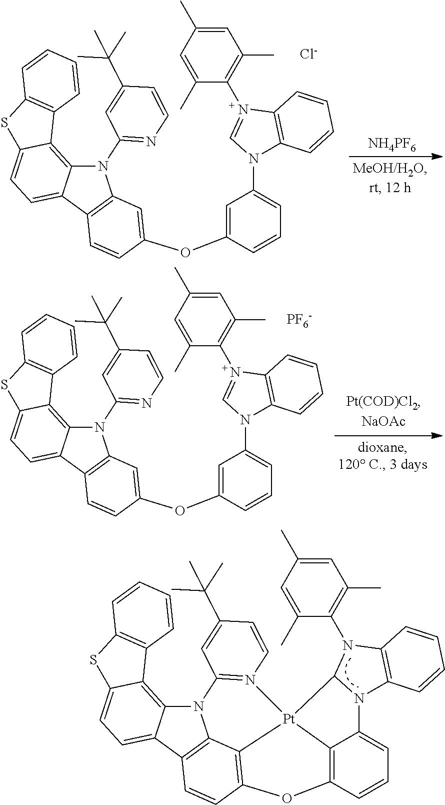

### Ex. 4-2:

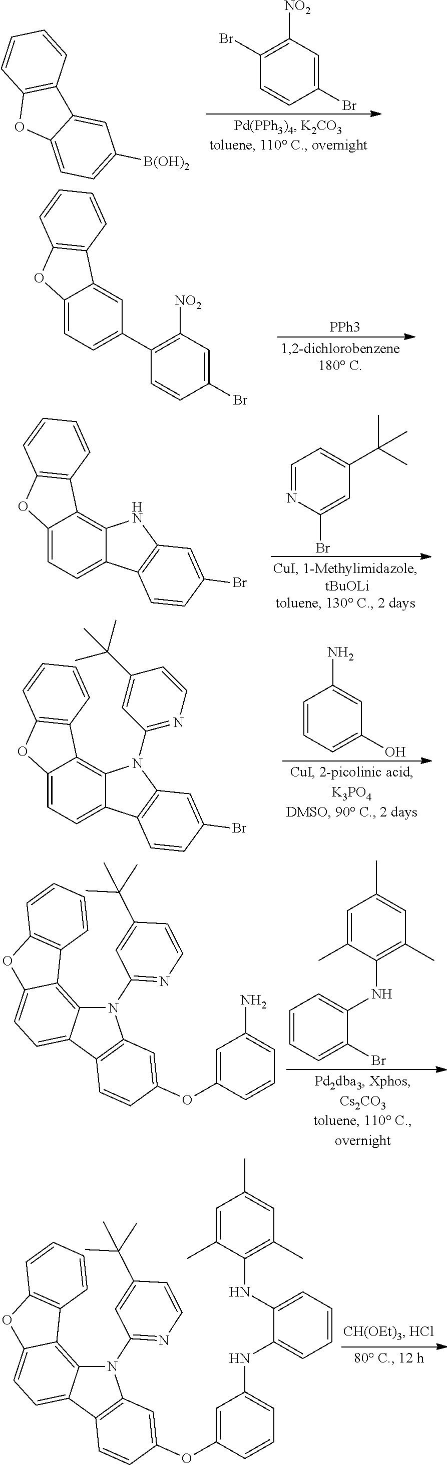

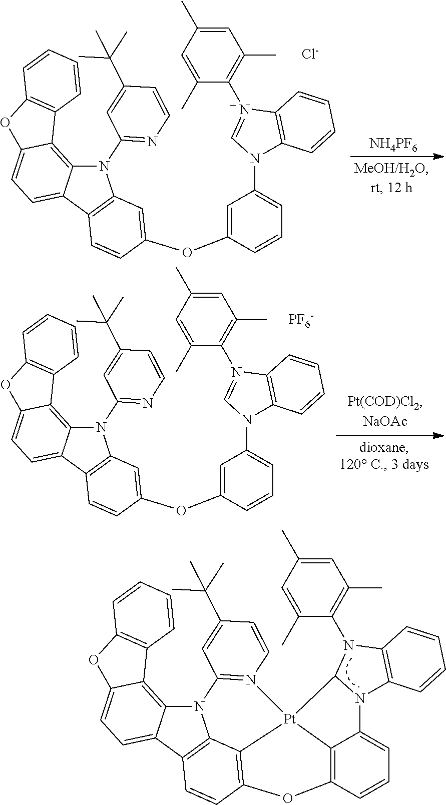

### Ex. 4-3:

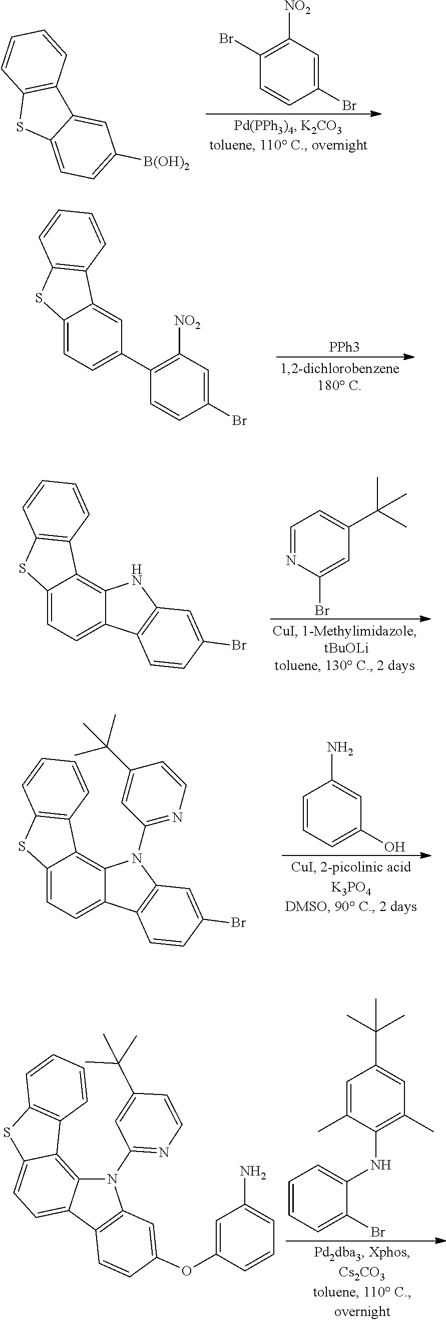

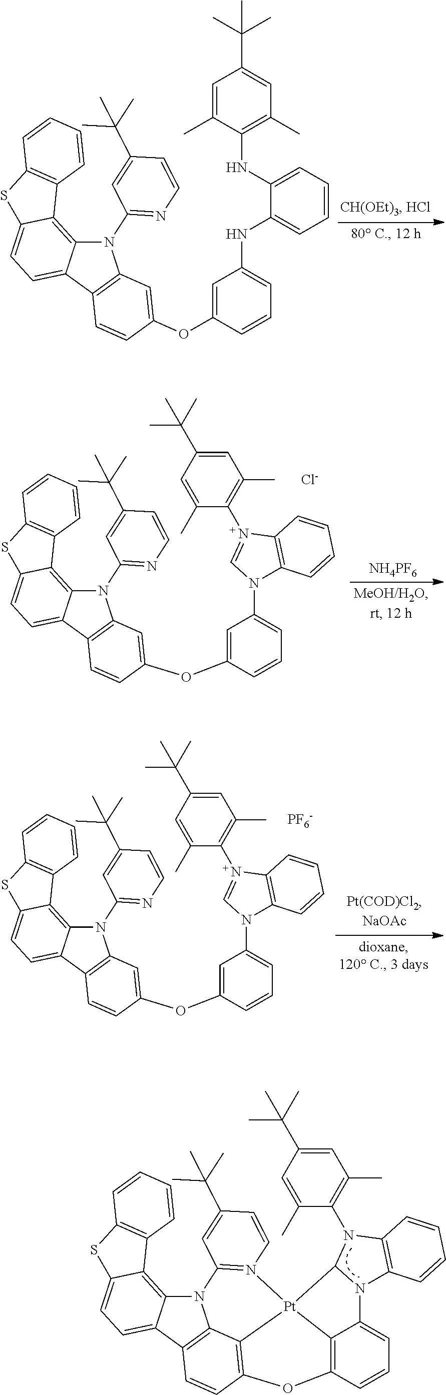

### Ex. 4-4:

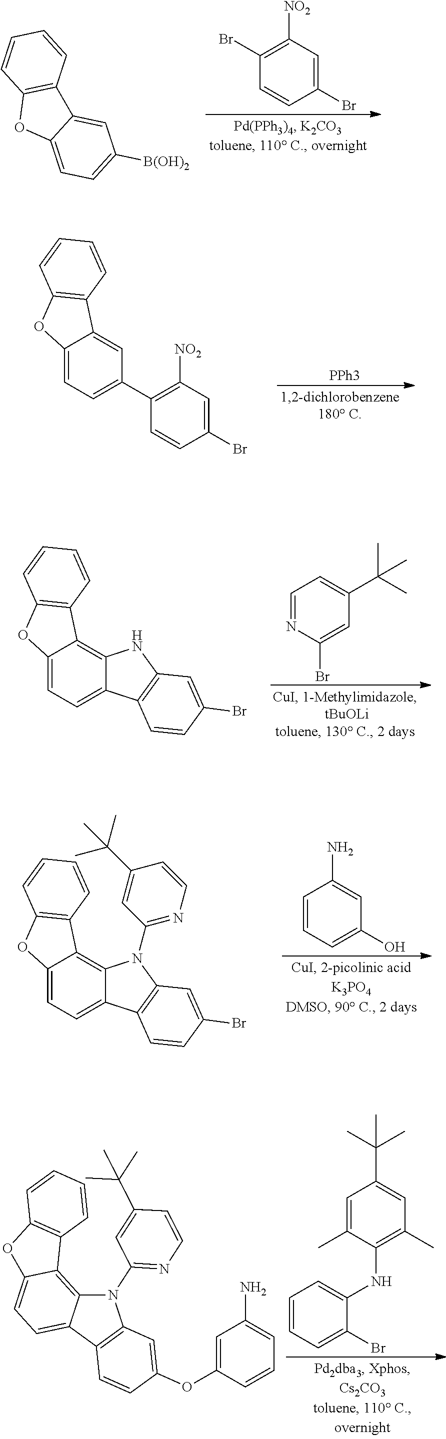

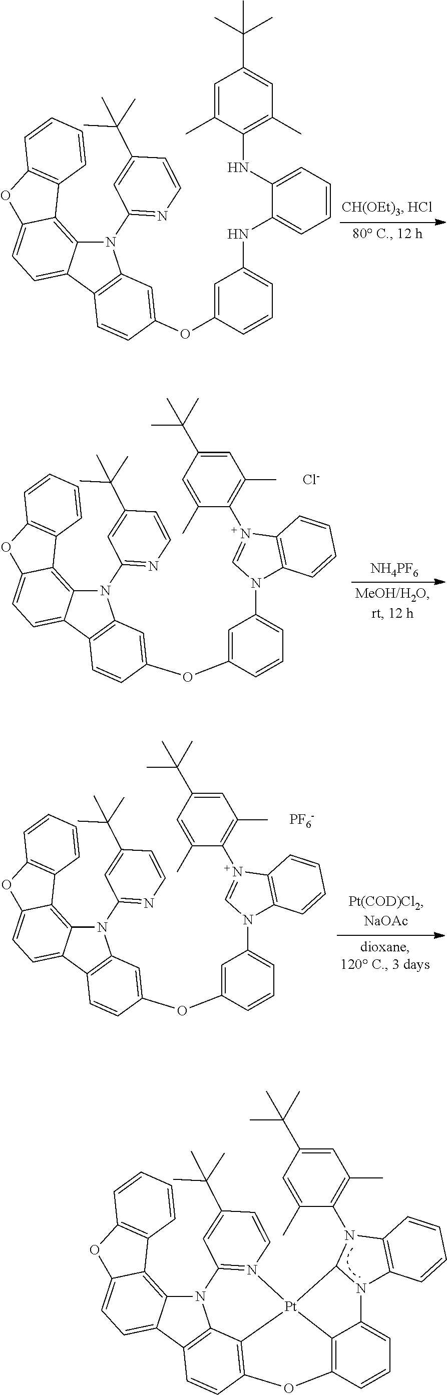

### Ex. 4-5:

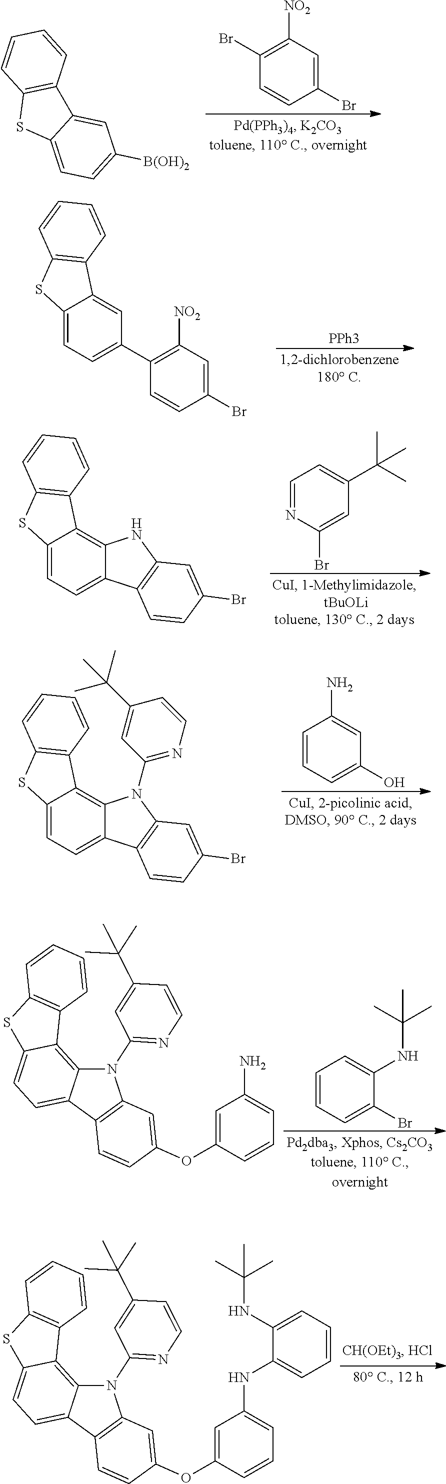

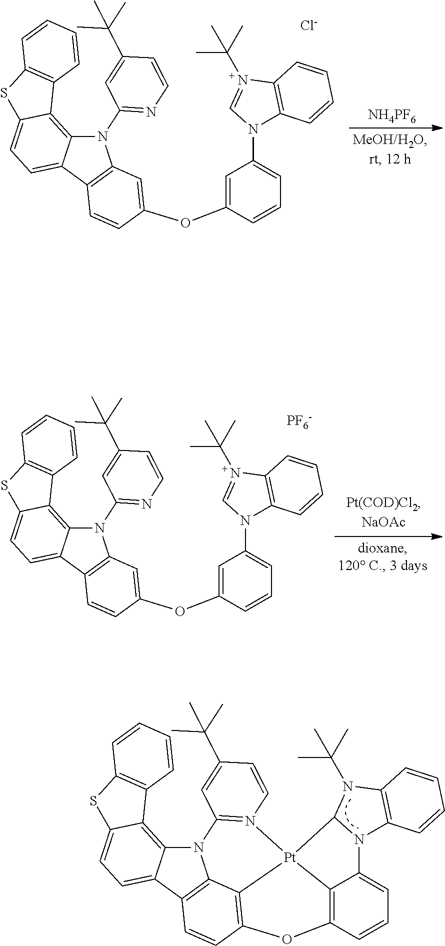

### Ex. 4-6:

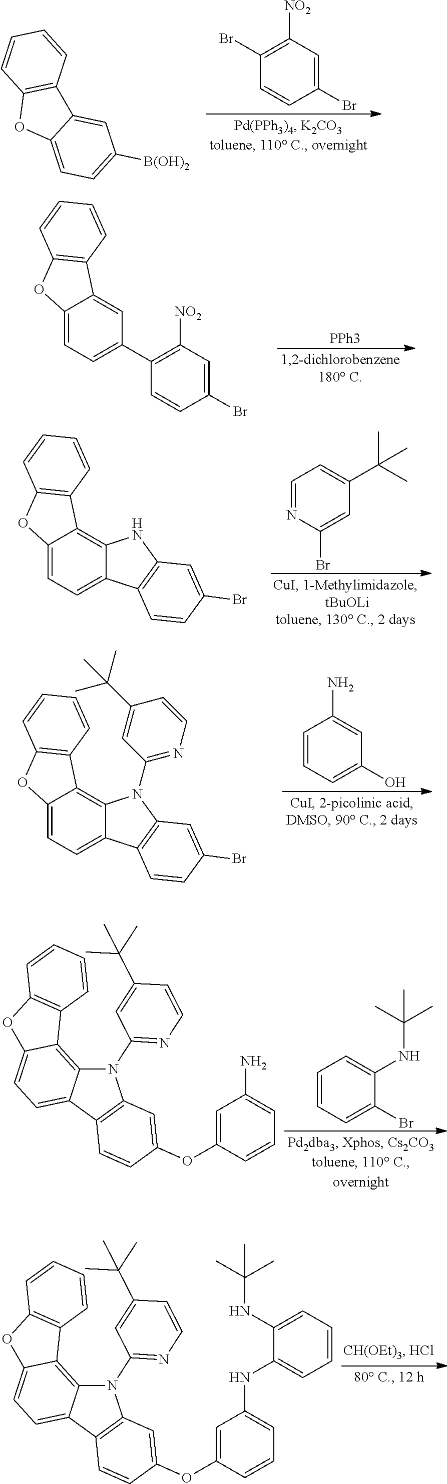

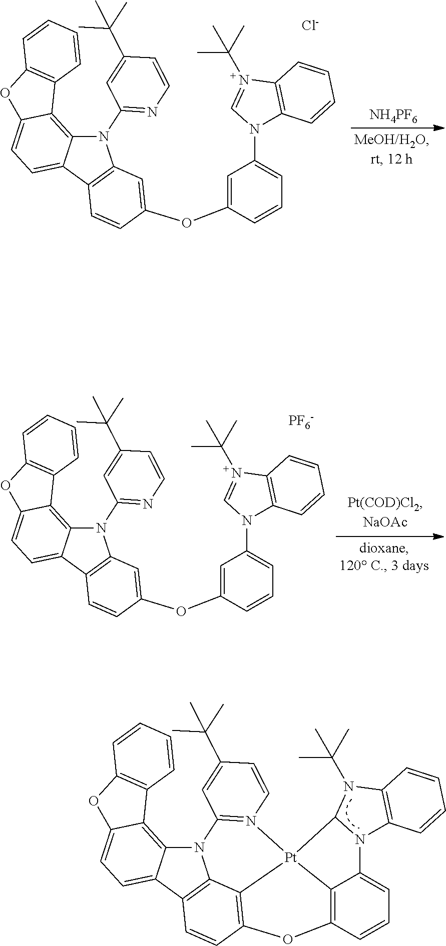

### Ex. 4-7:

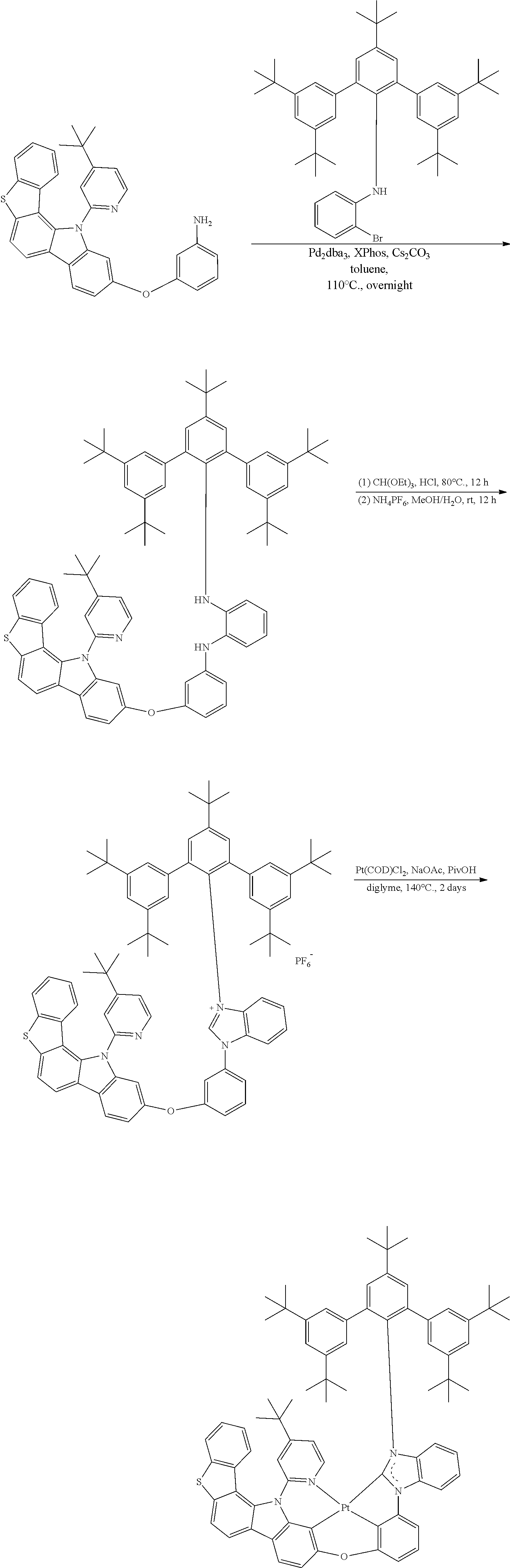

### Ex. 4-8:

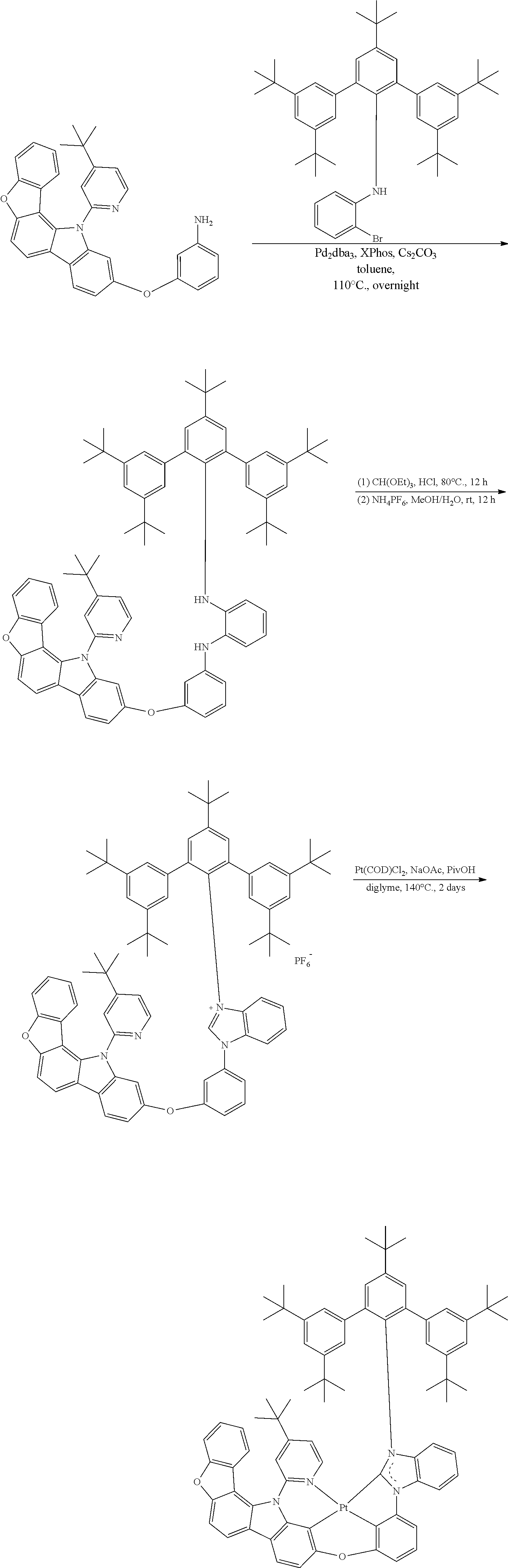

### Ex. 4-9:

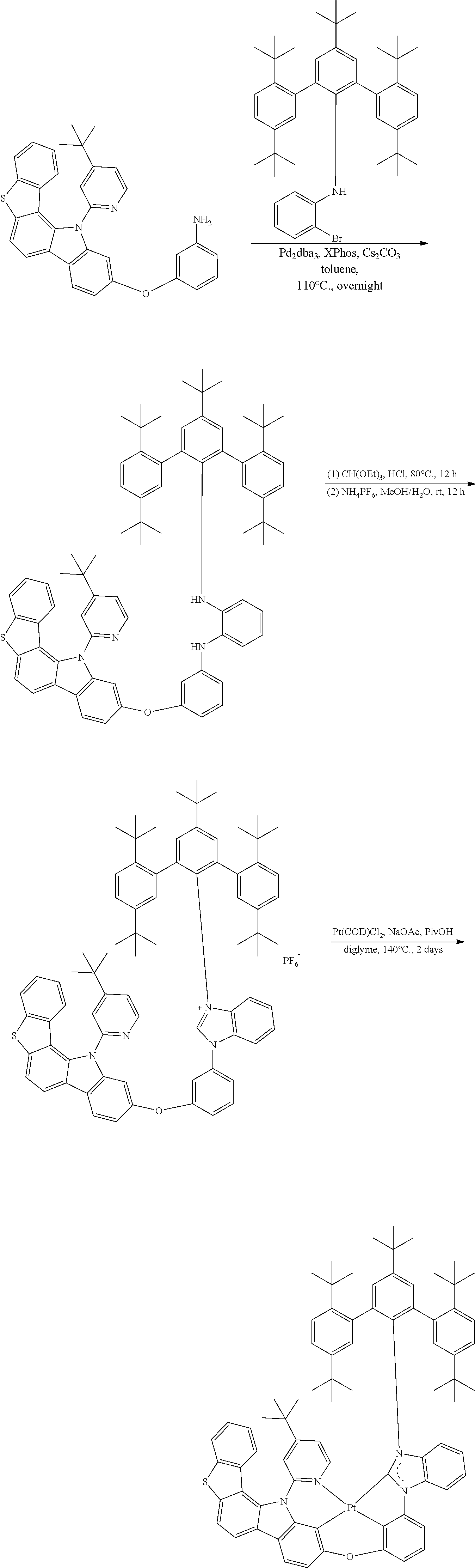

### Ex. 4-10:

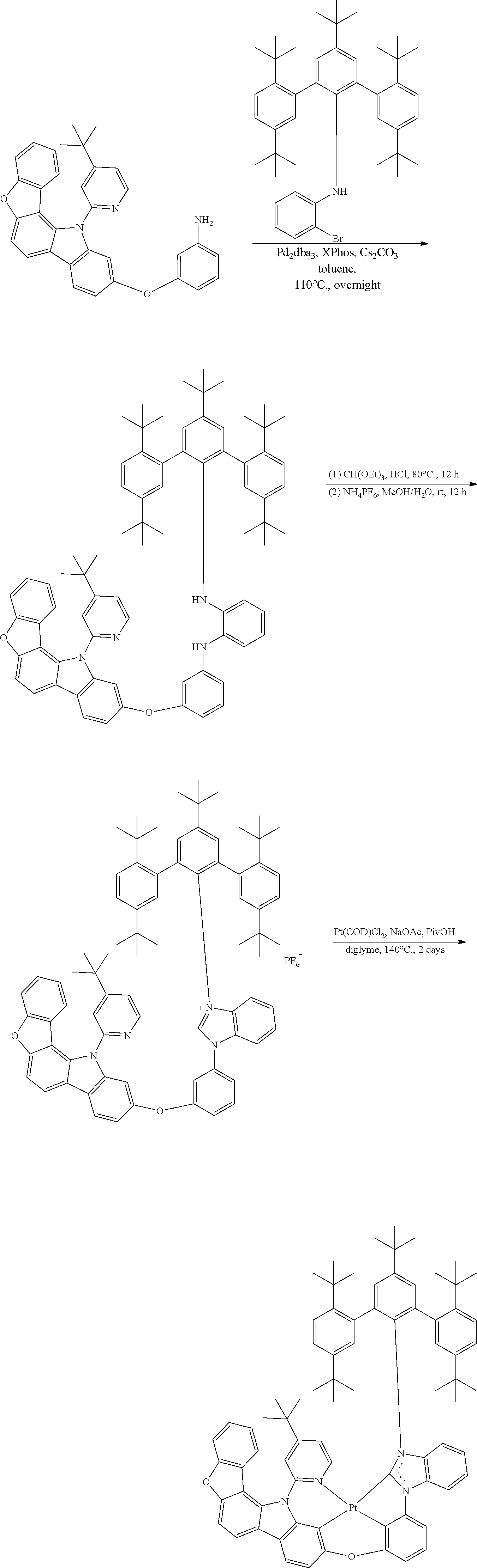

### Ex. 4-11:

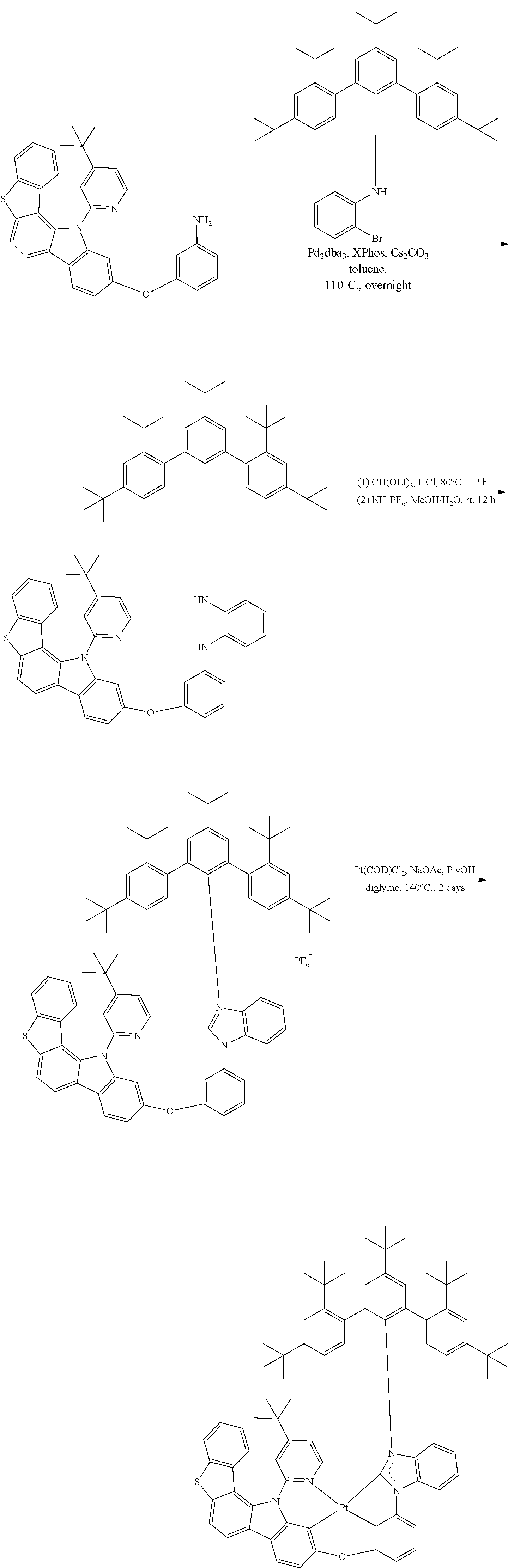

### Ex. 4-12:

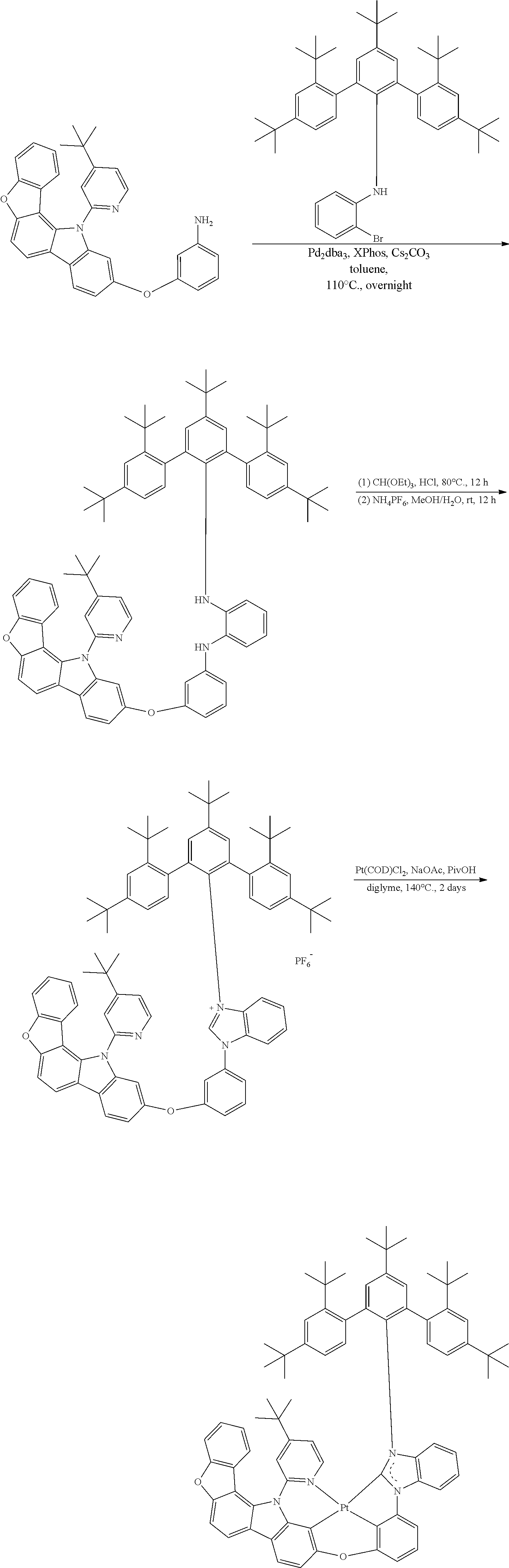

### Ex. 4-13:

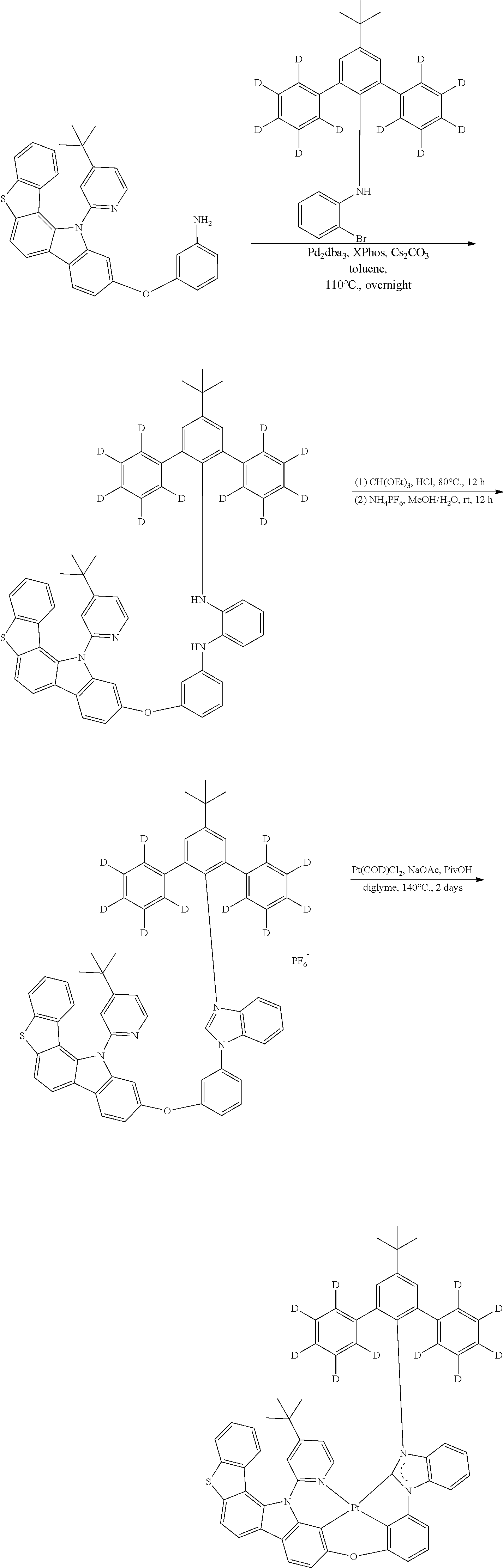

### Ex. 4-14:

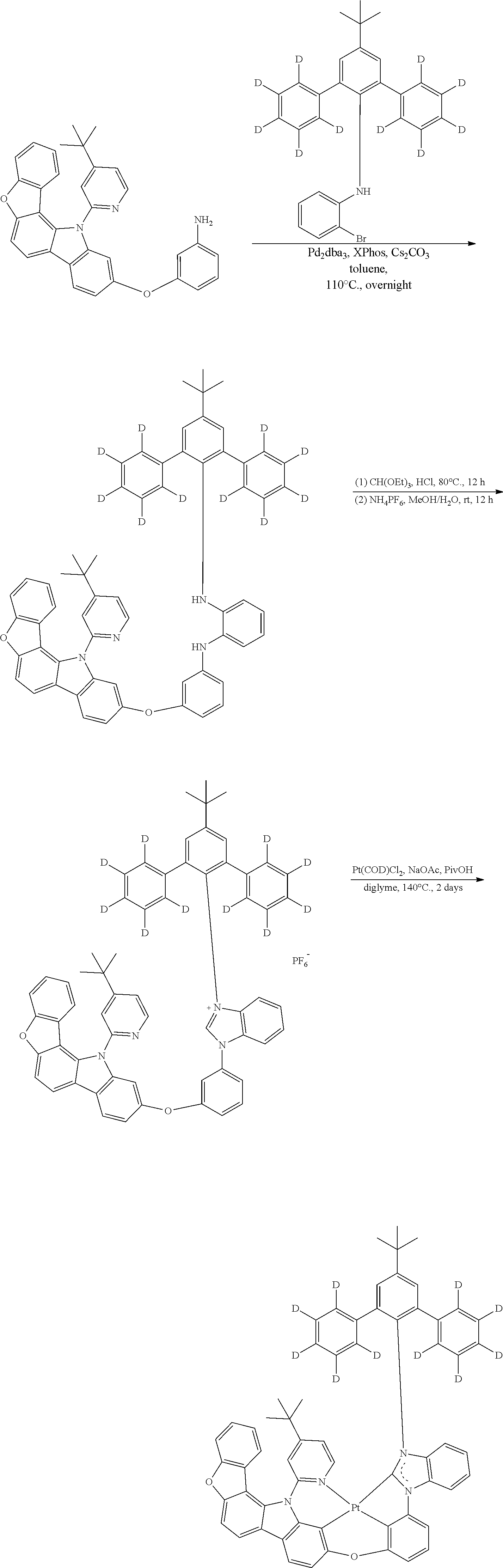

### Ex. 4-15:

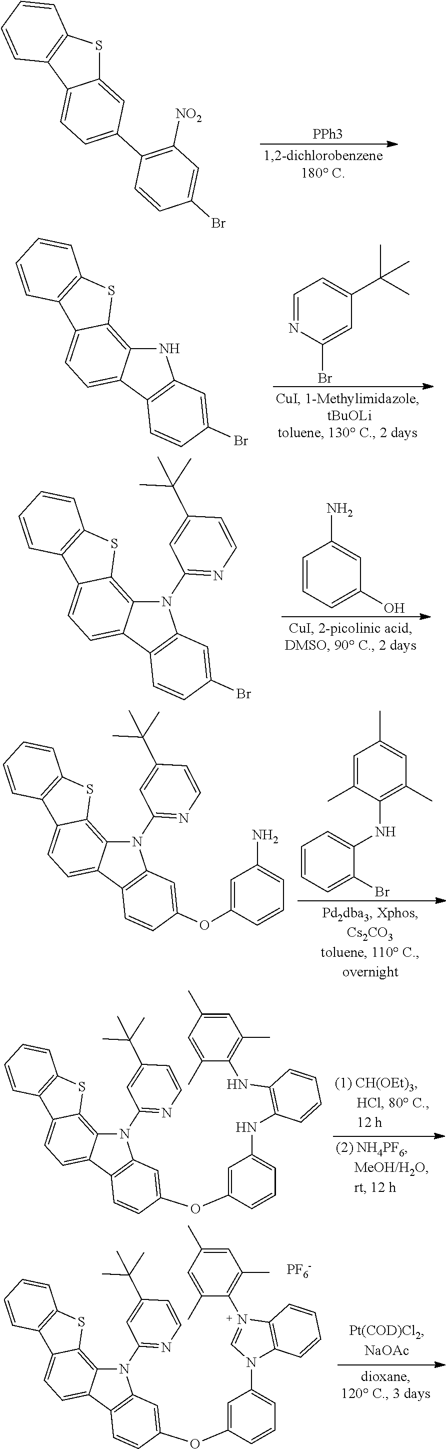

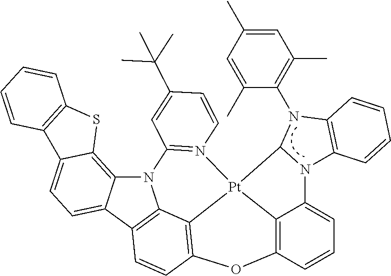

### Ex. 4-16:

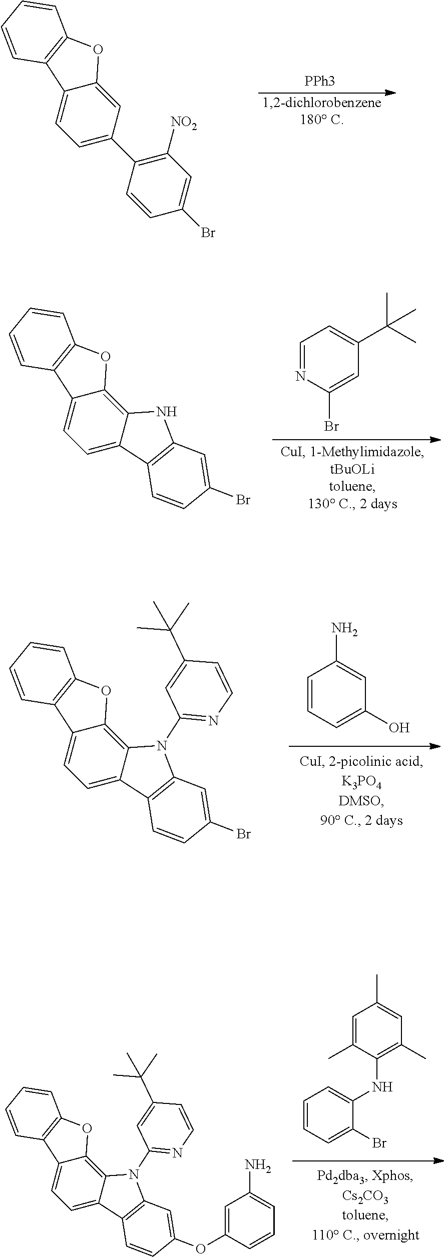

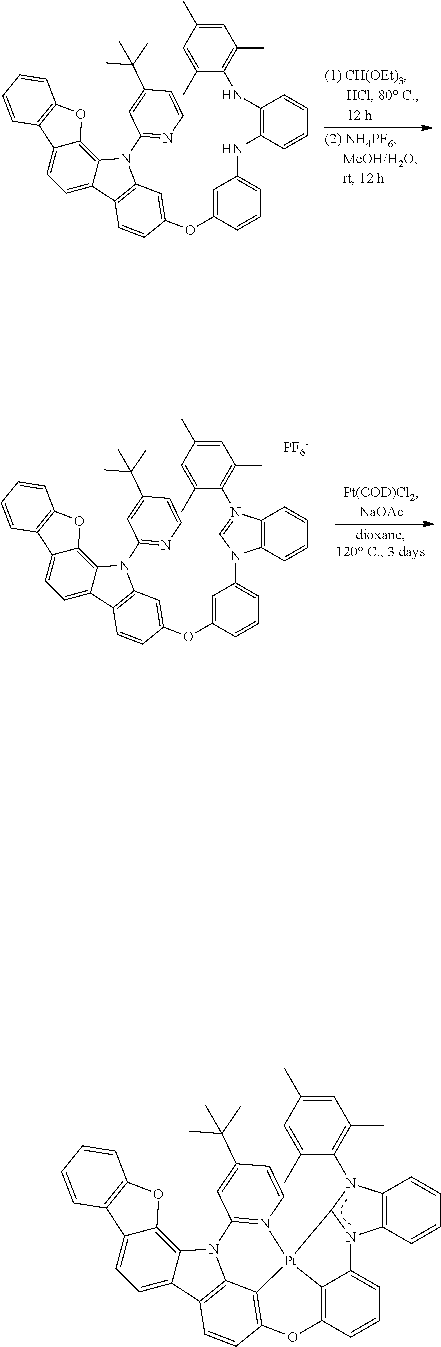

### Ex. 4-17:

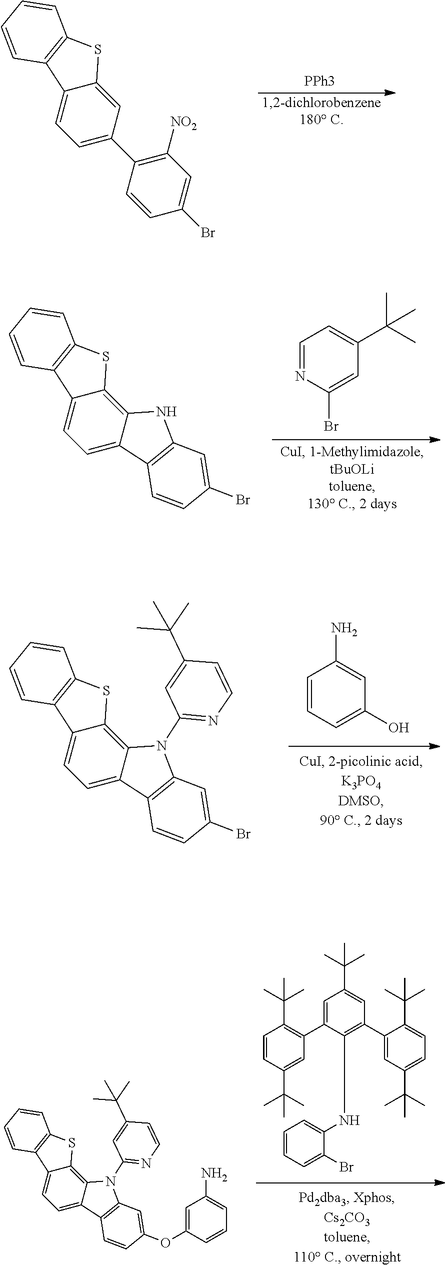

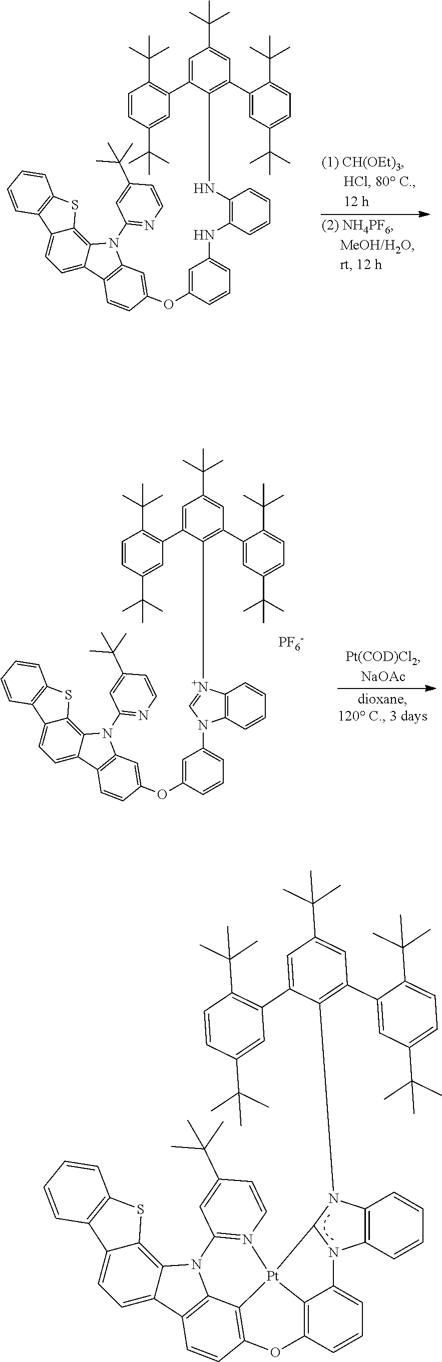

### Ex. 4-18:

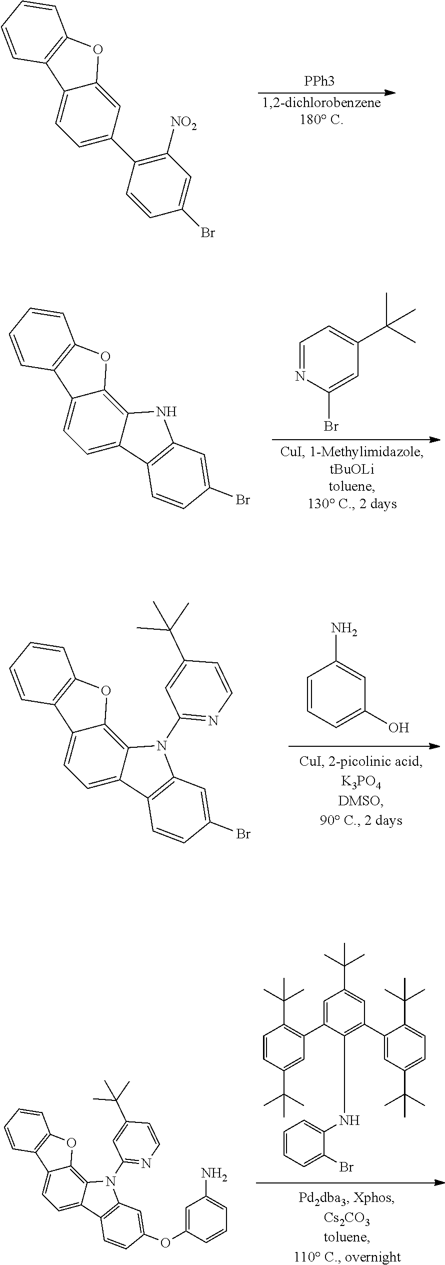

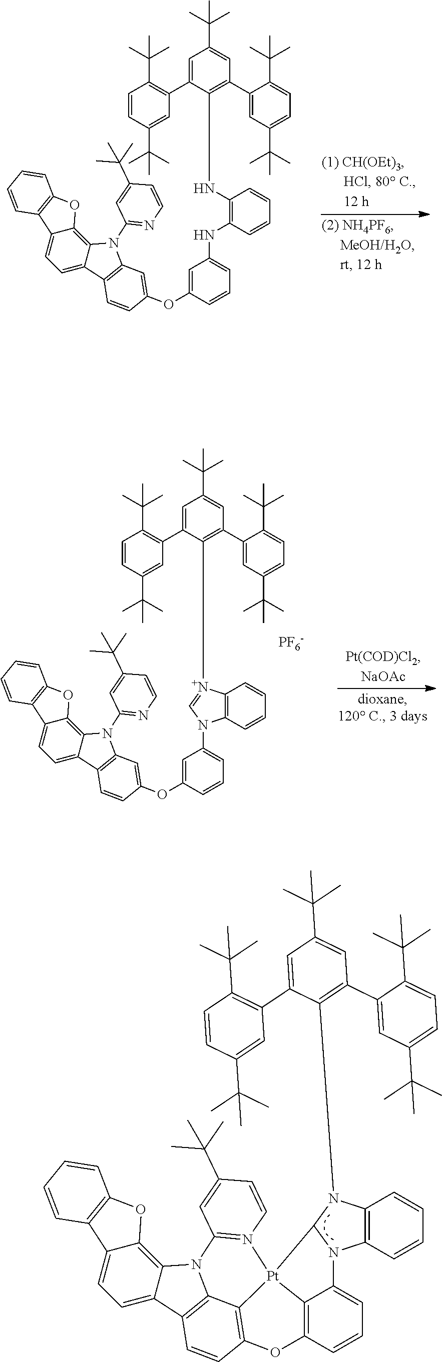

### Ex. 4-19:

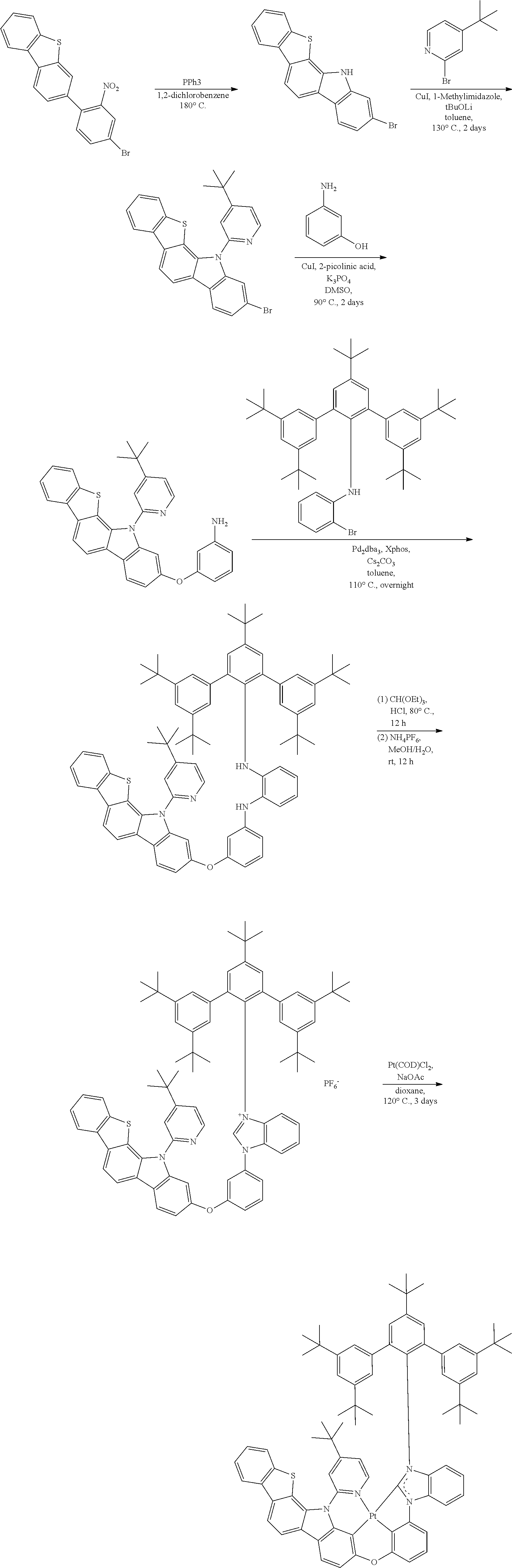

### Ex. 4-20:

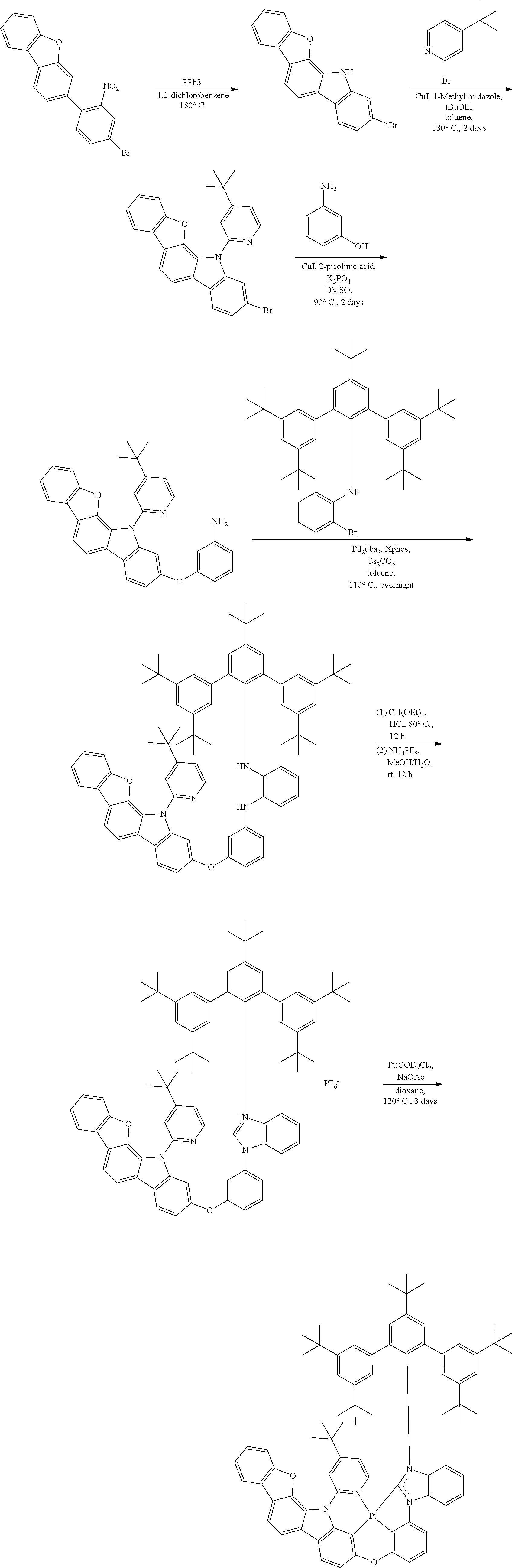

### Ex. 4-21:

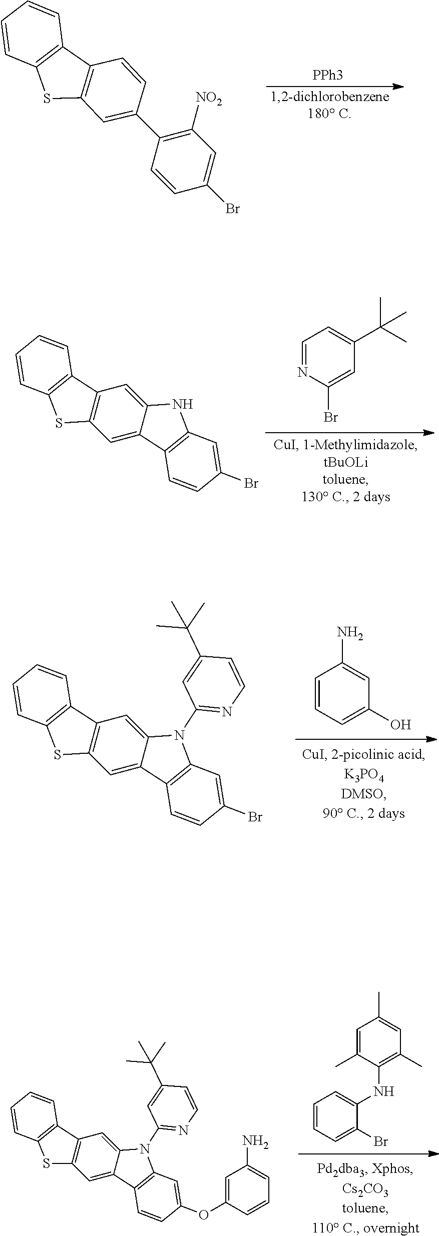

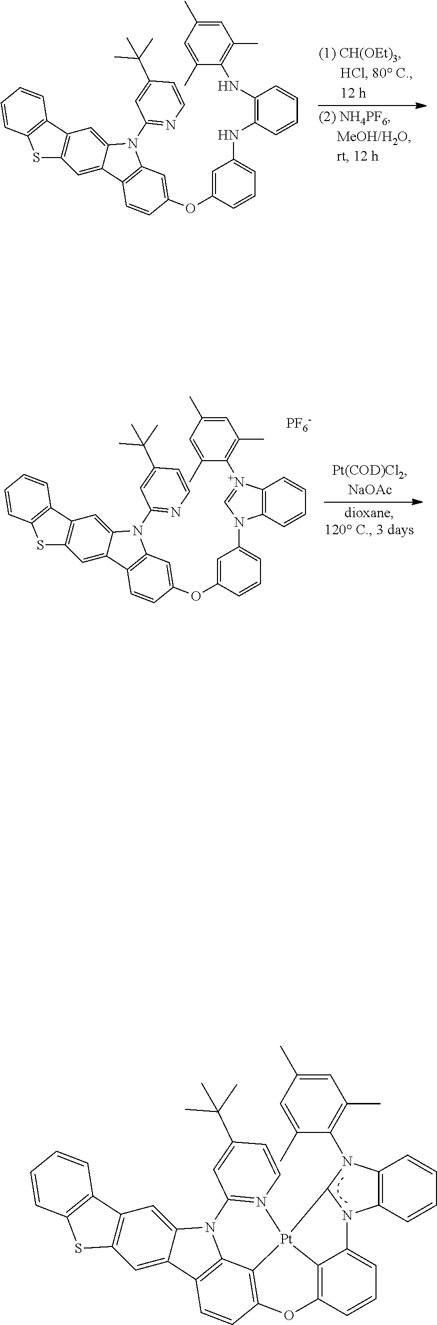

### Ex. 4-22:

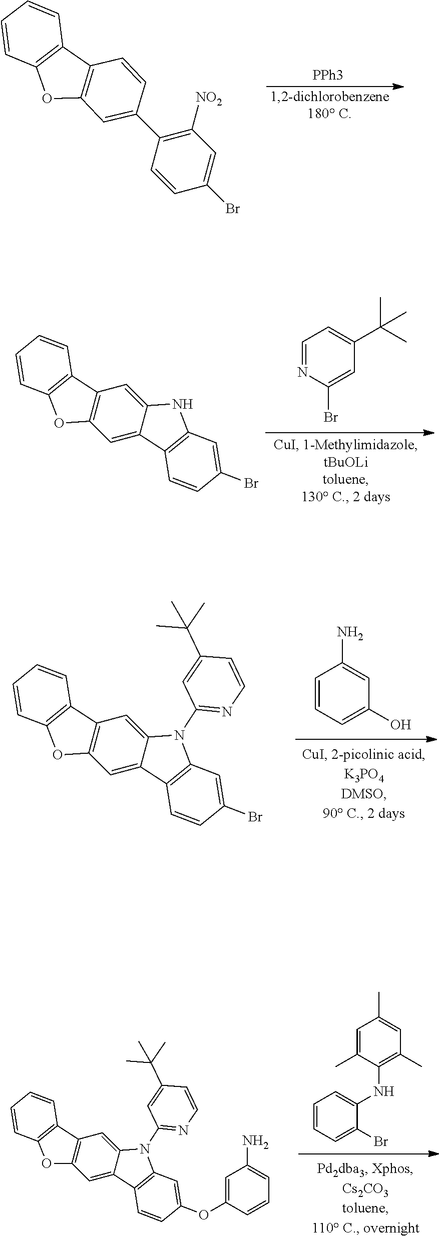

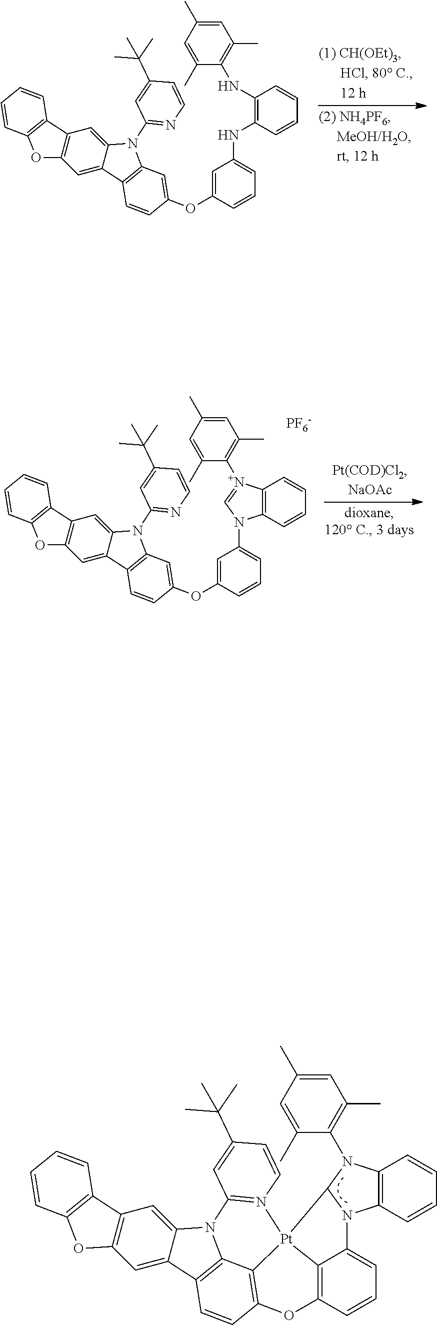

### Ex. 4-23:

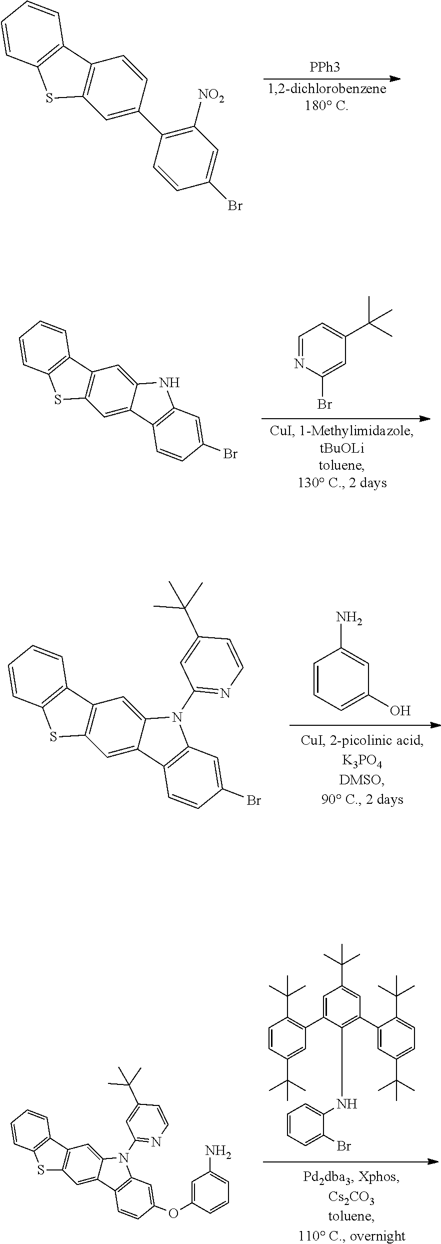

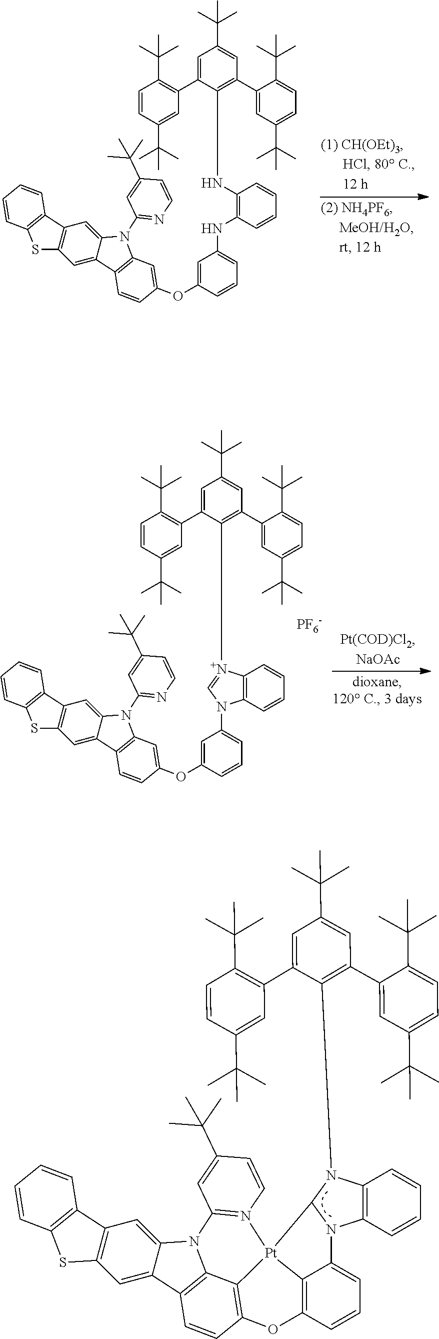

### Ex. 4-24:

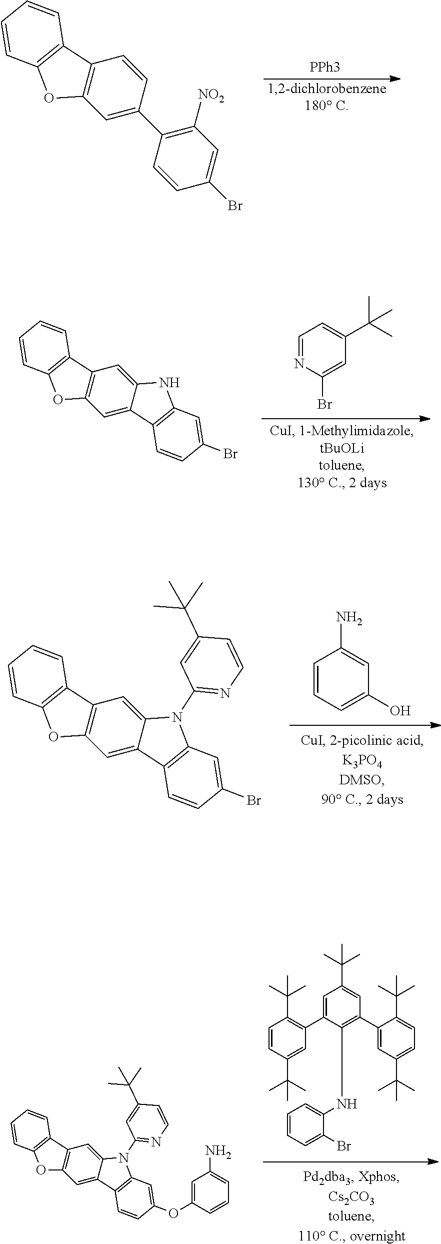

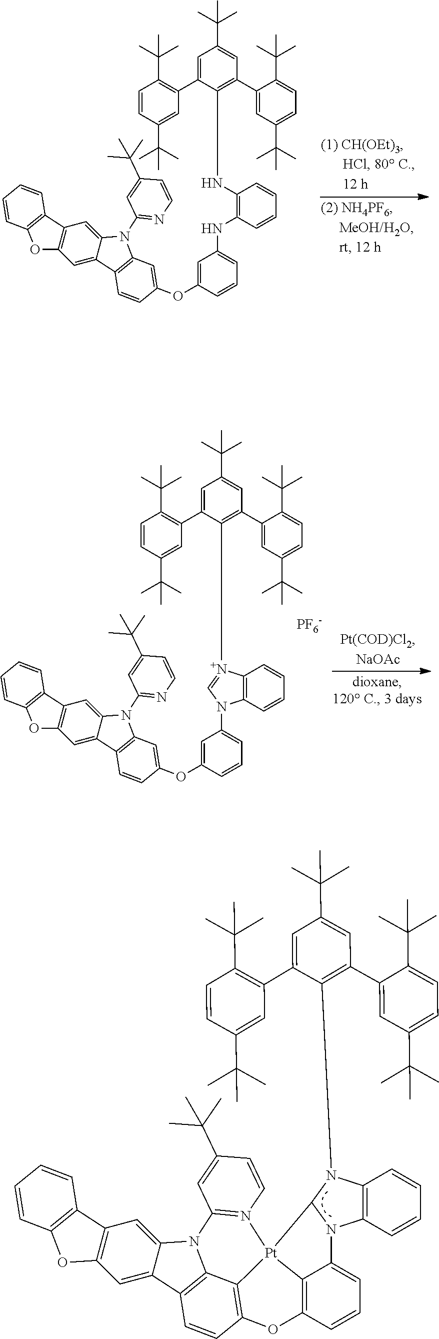

### Ex. 4-25:

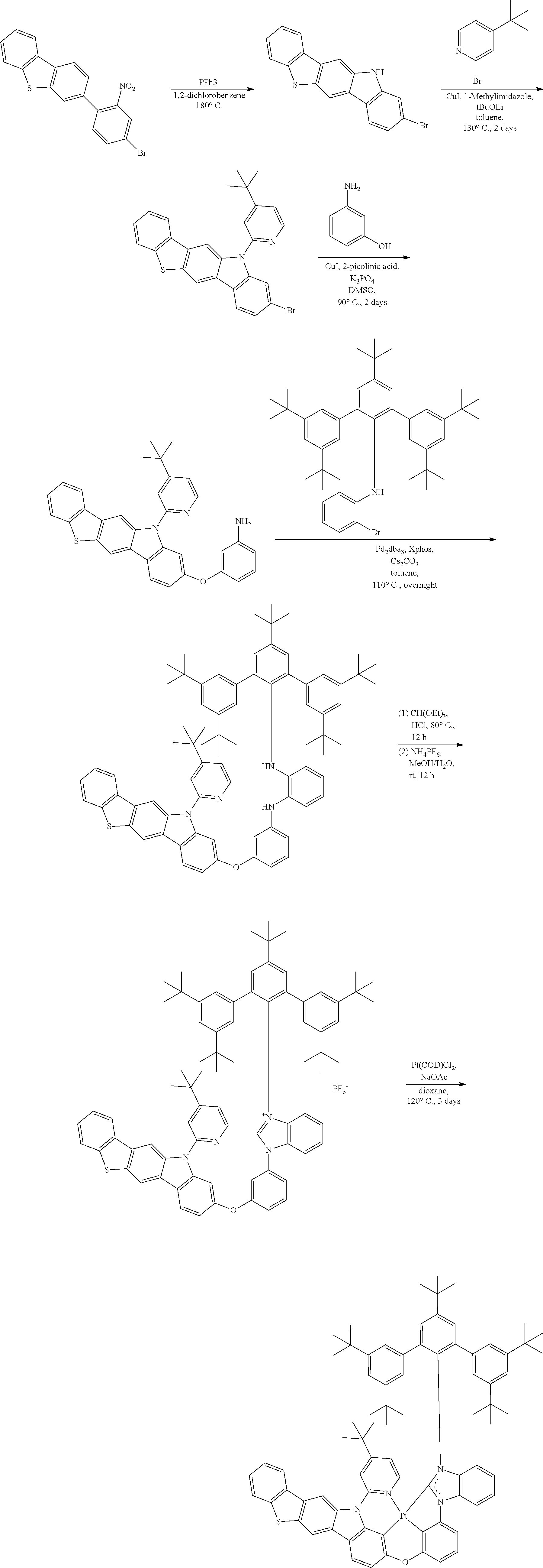

### Ex. 4-26:

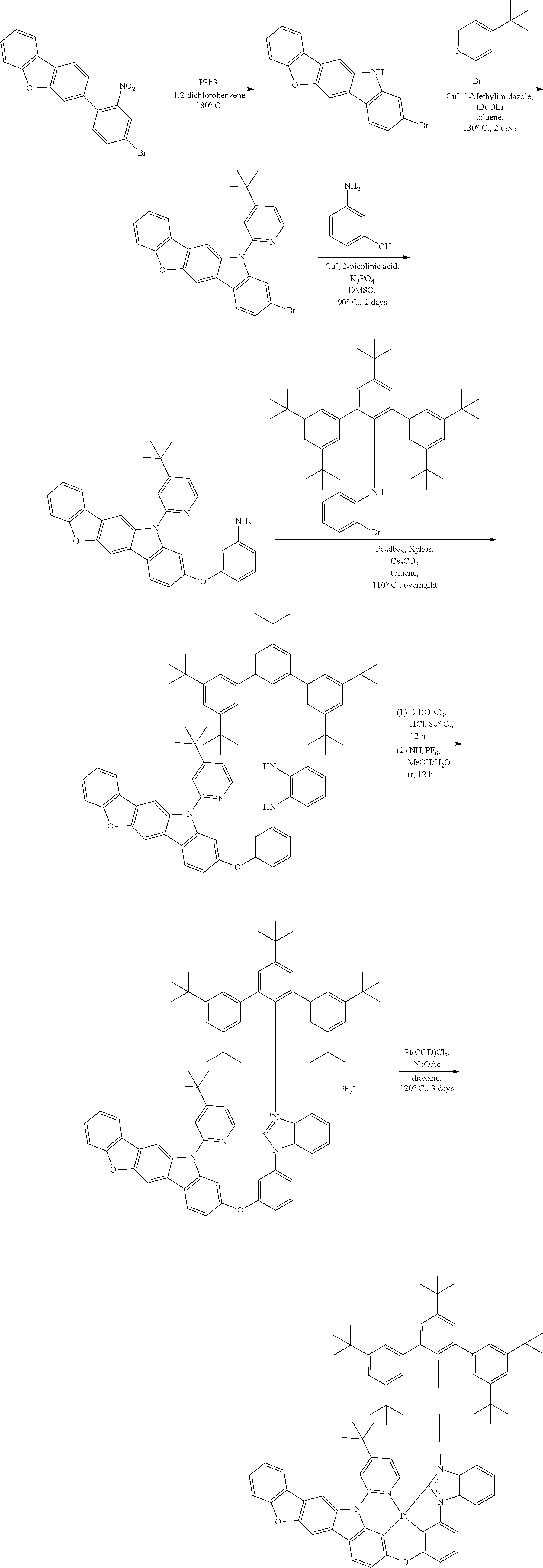

### Ex. 4-27:

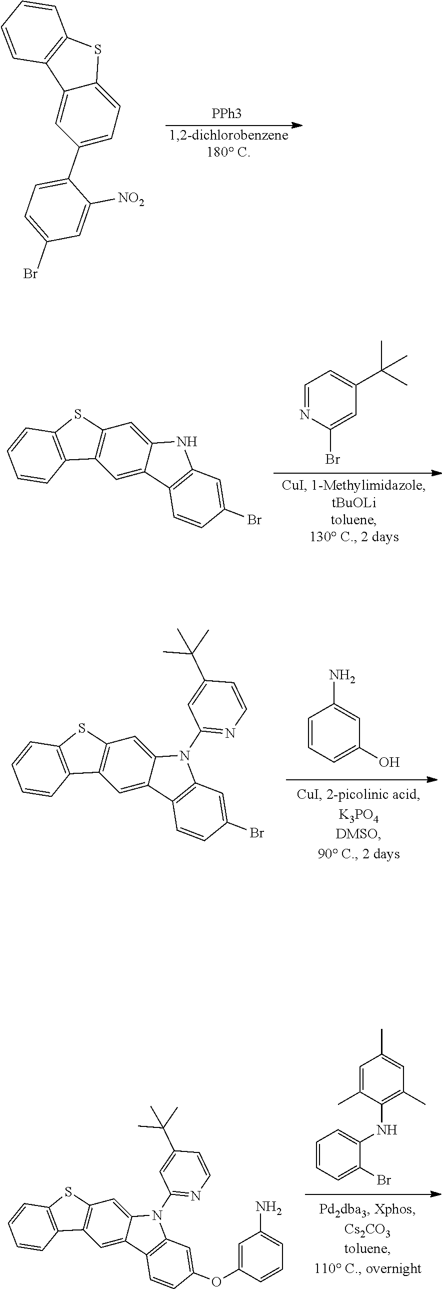

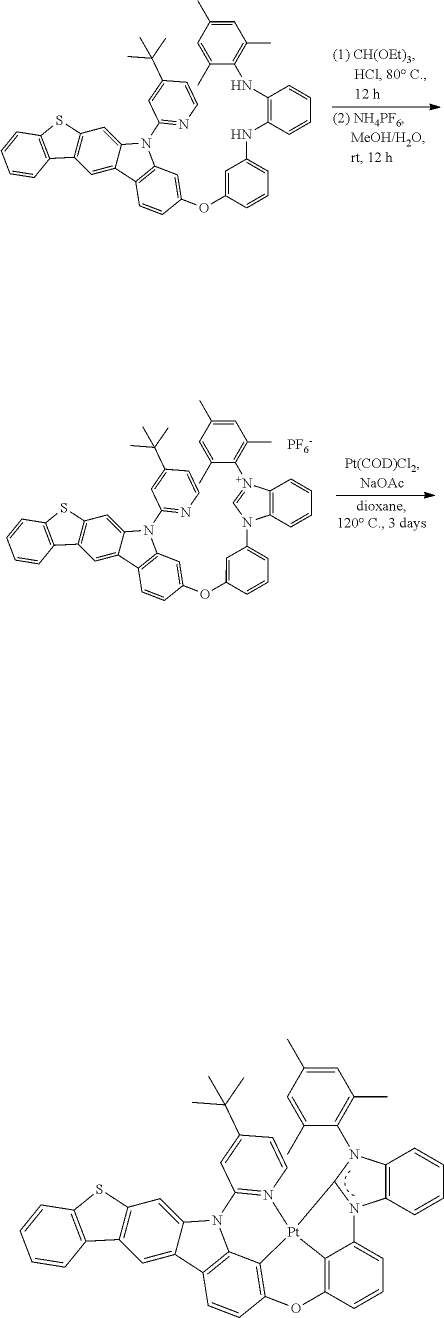

### Ex. 4-28:

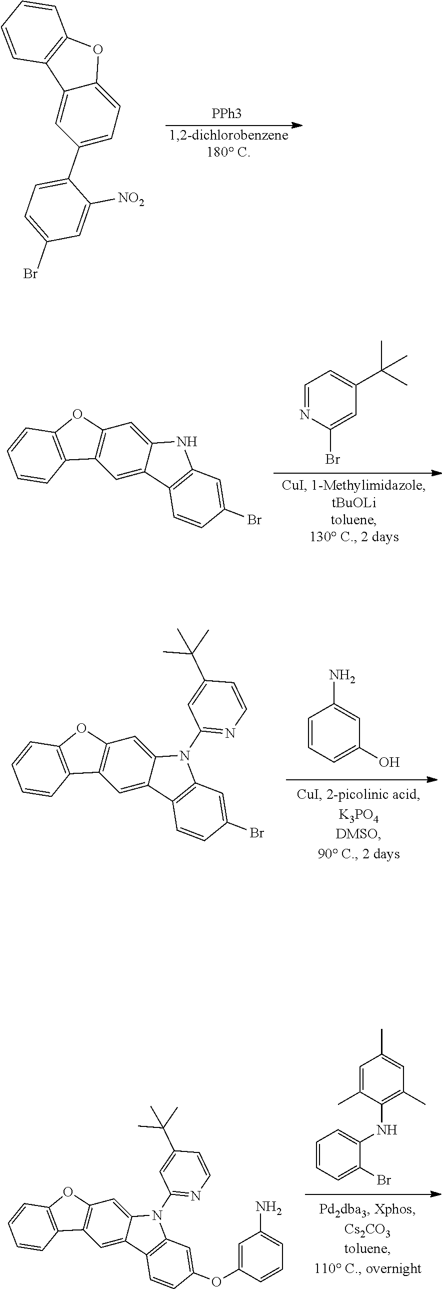

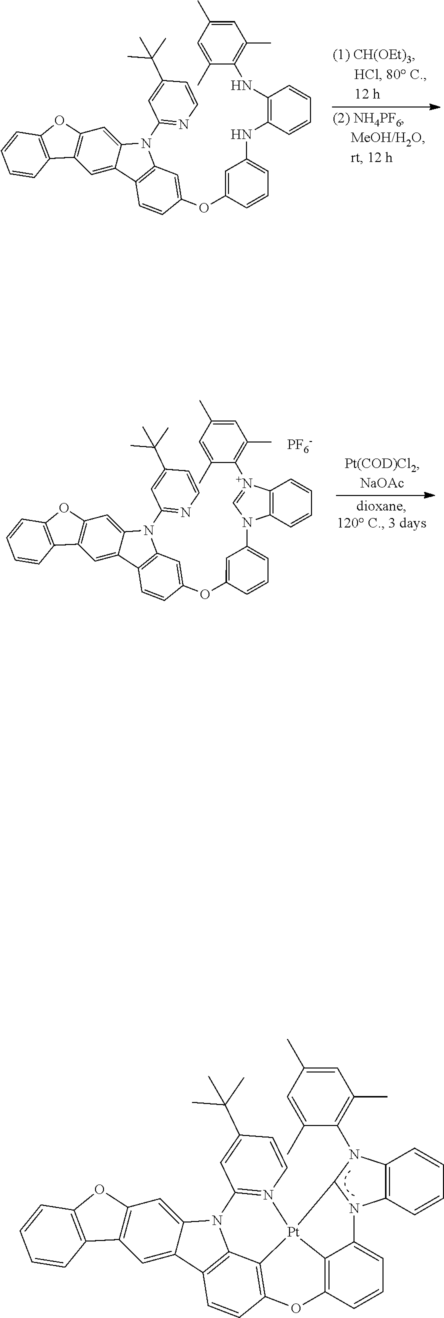

### Ex. 4-29:

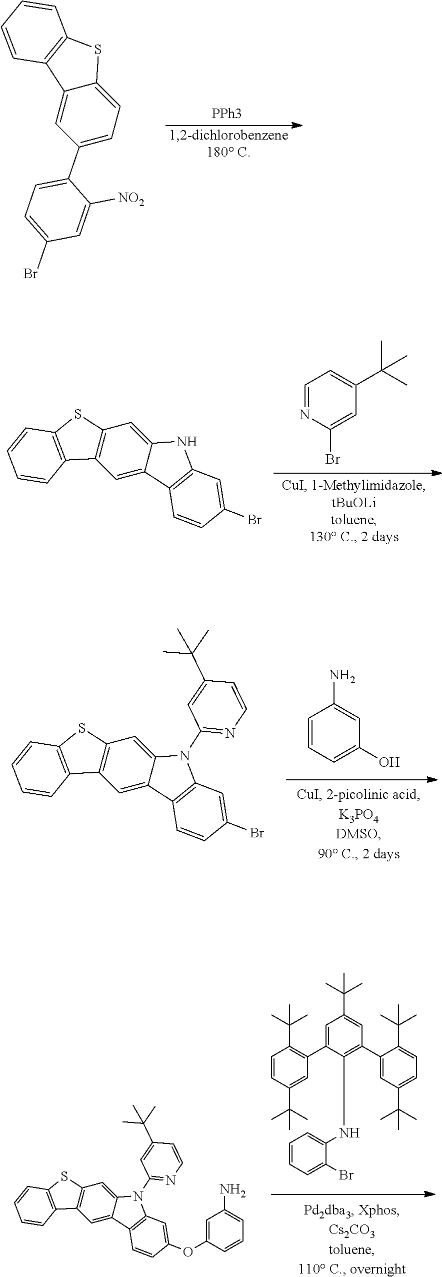

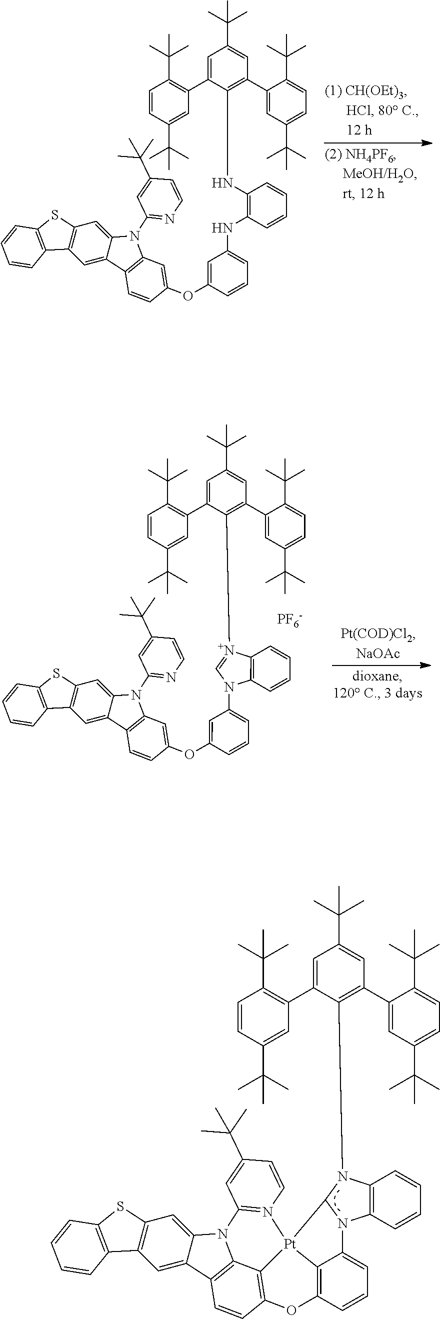

### Ex. 4-30:

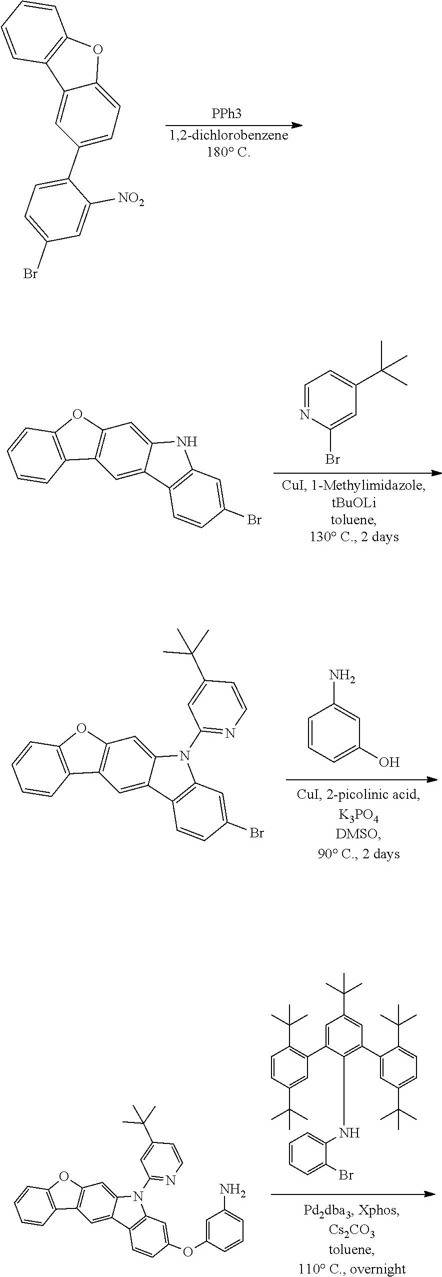

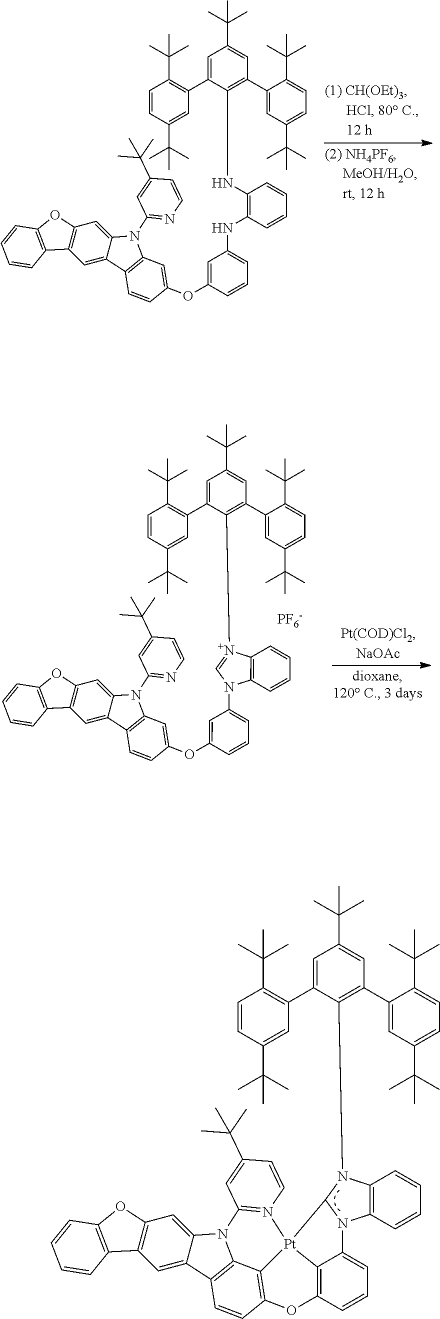

### Ex. 4-31:

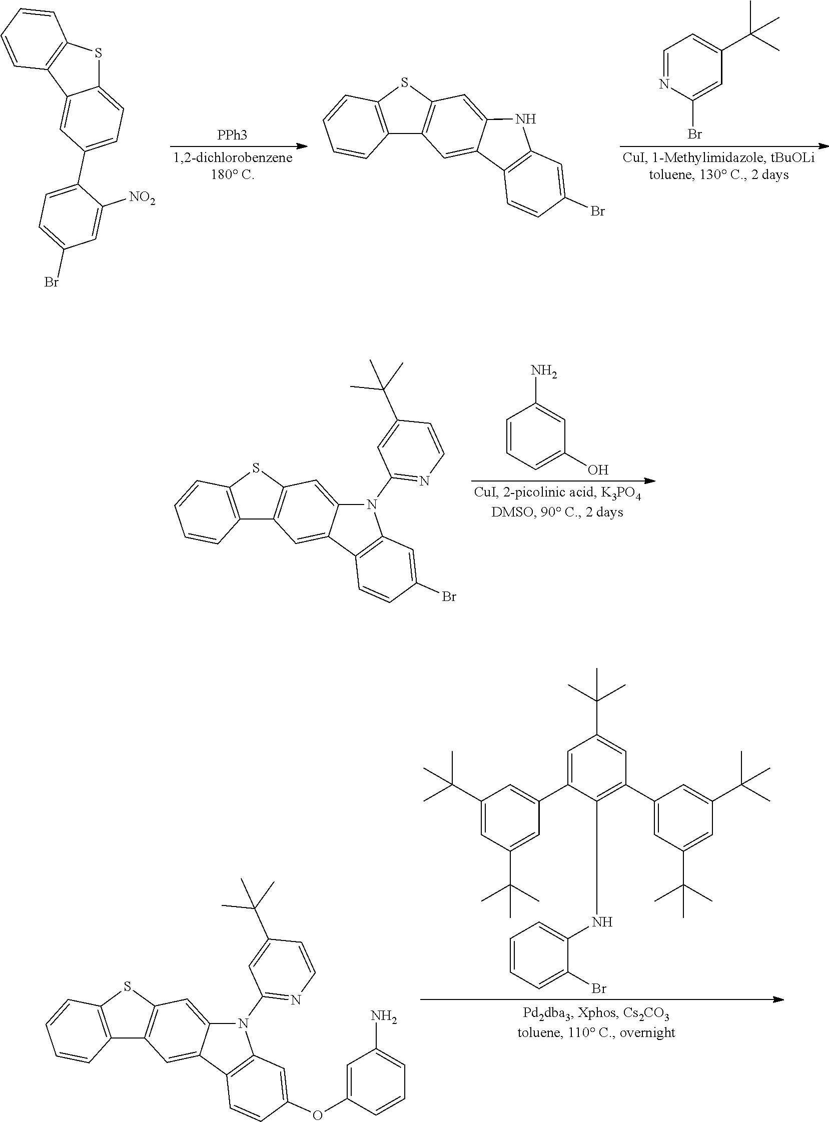

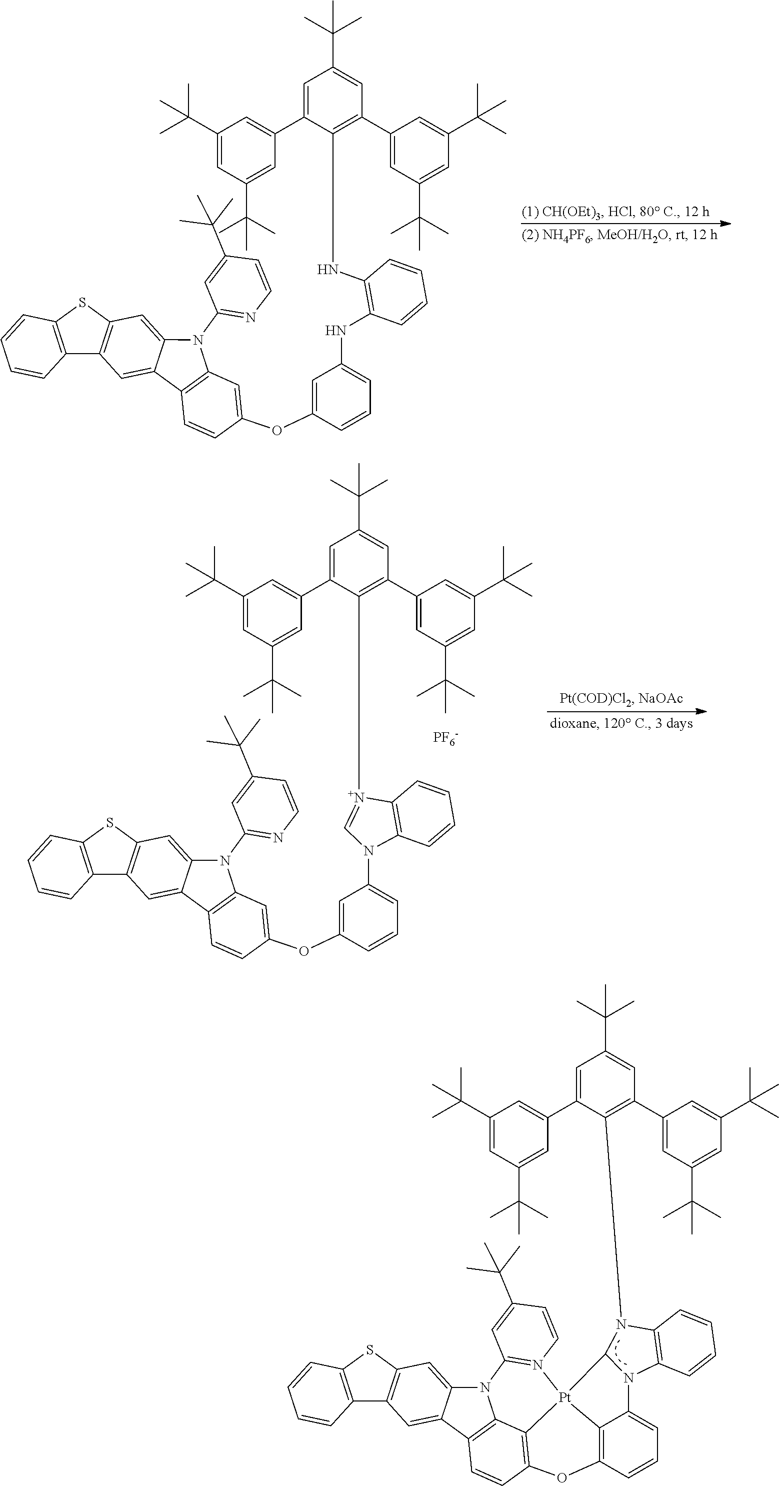

### Ex. 4-32:

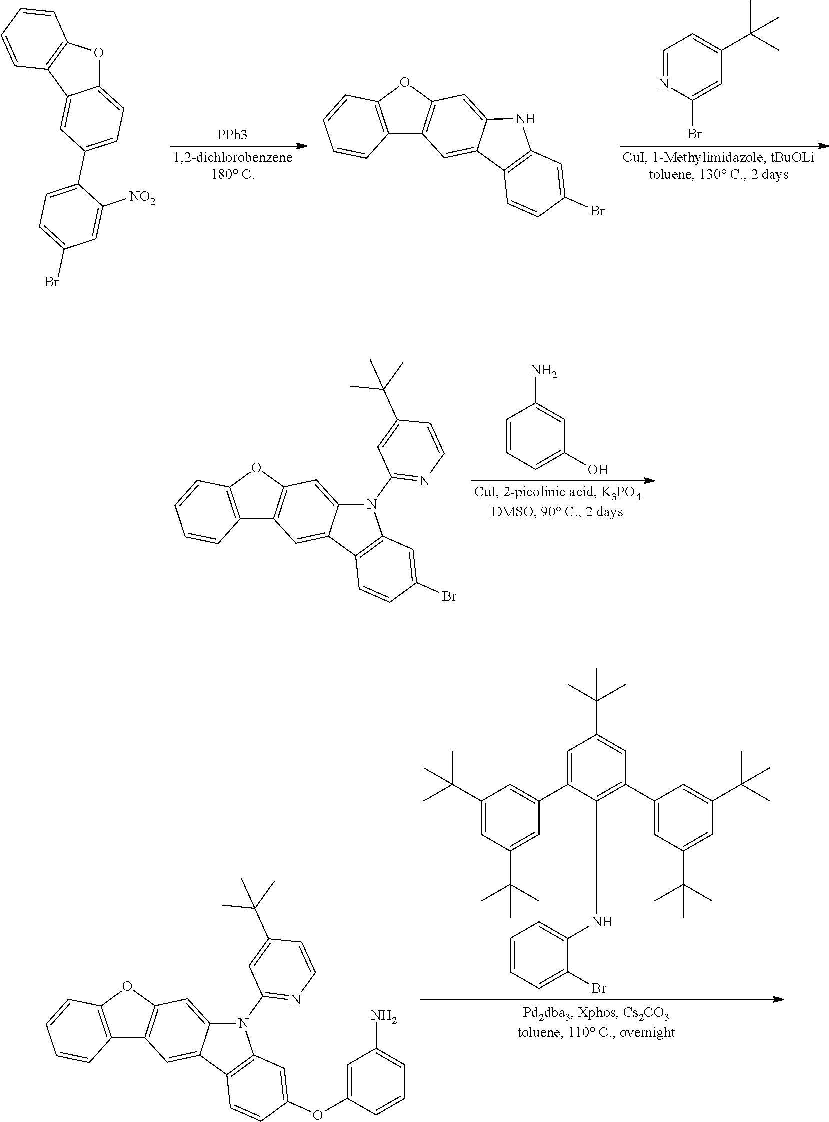

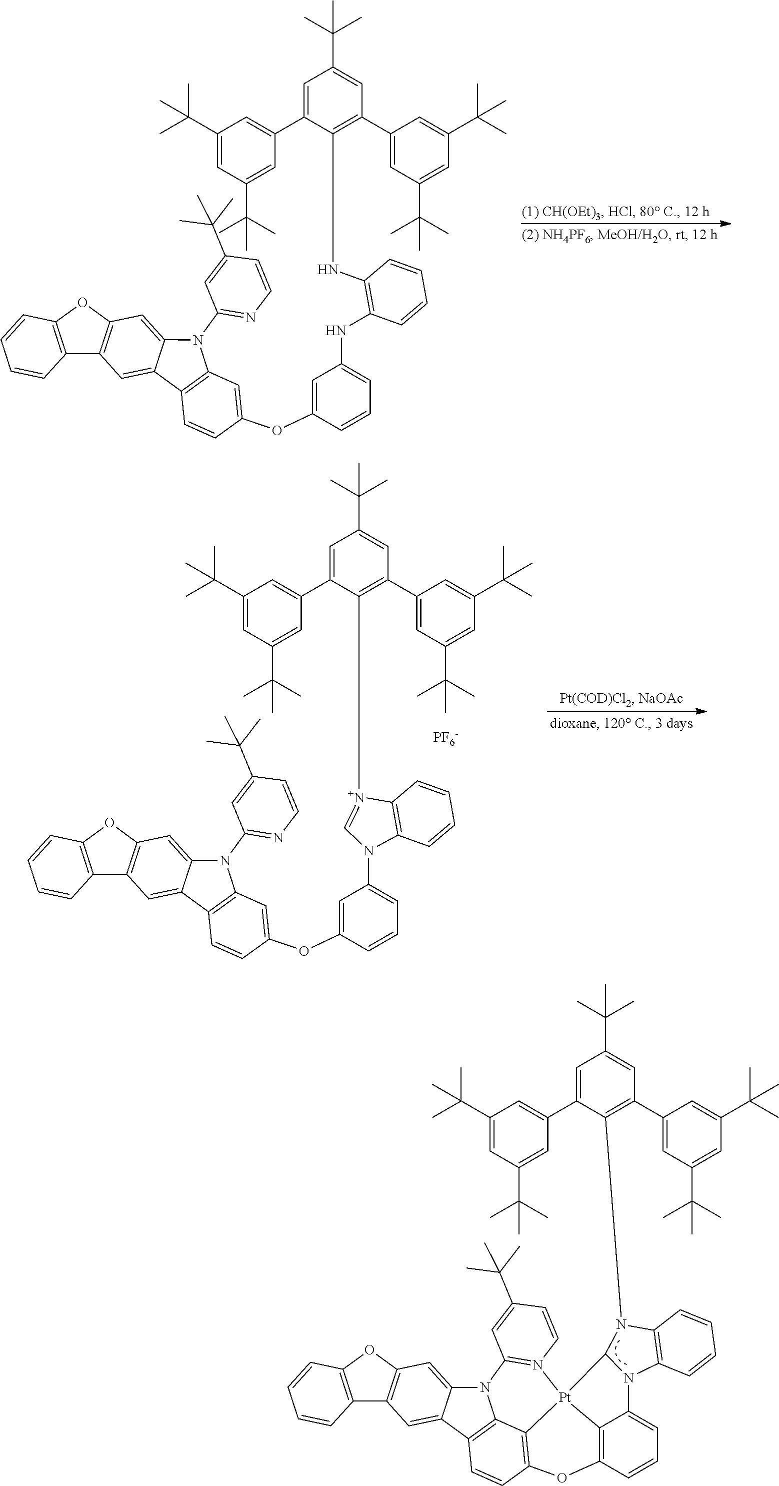

### Ex. 4-33:

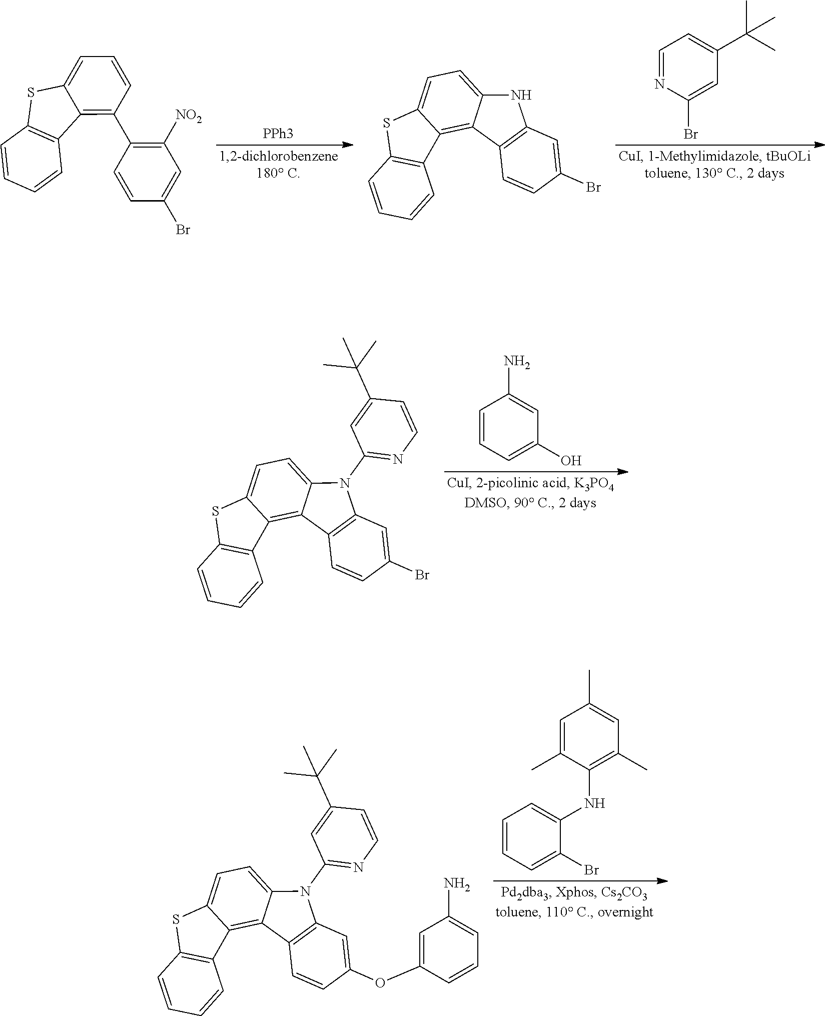

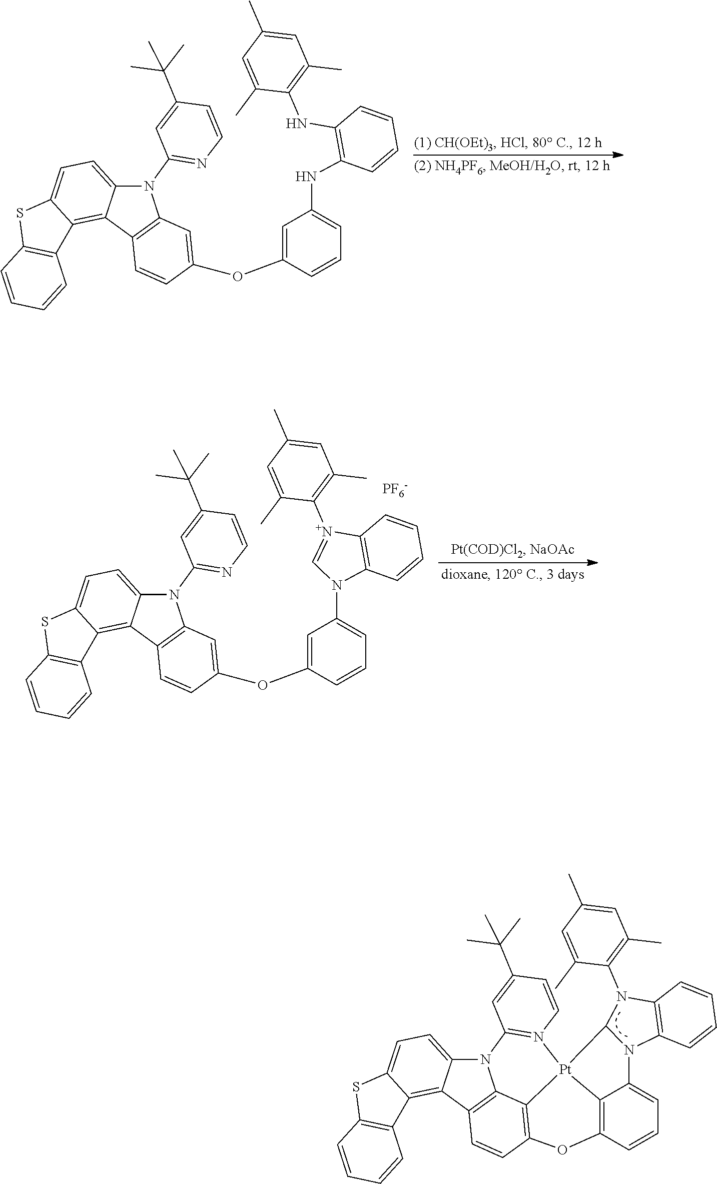

### Ex. 4-34:

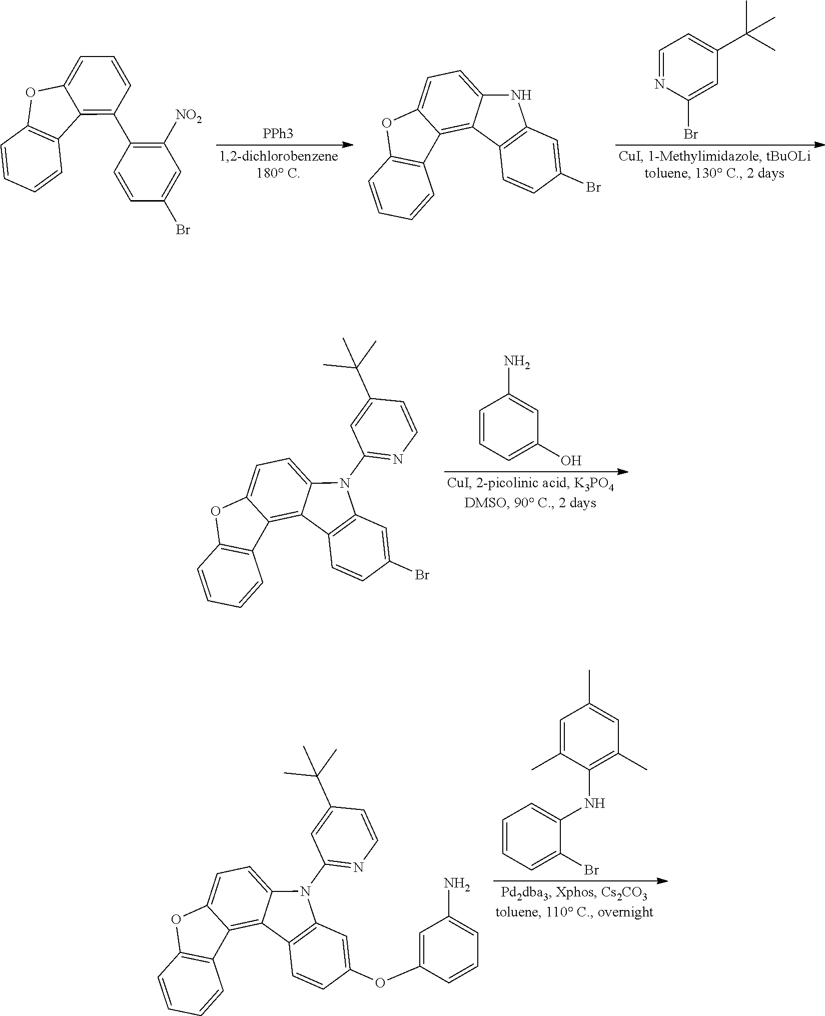

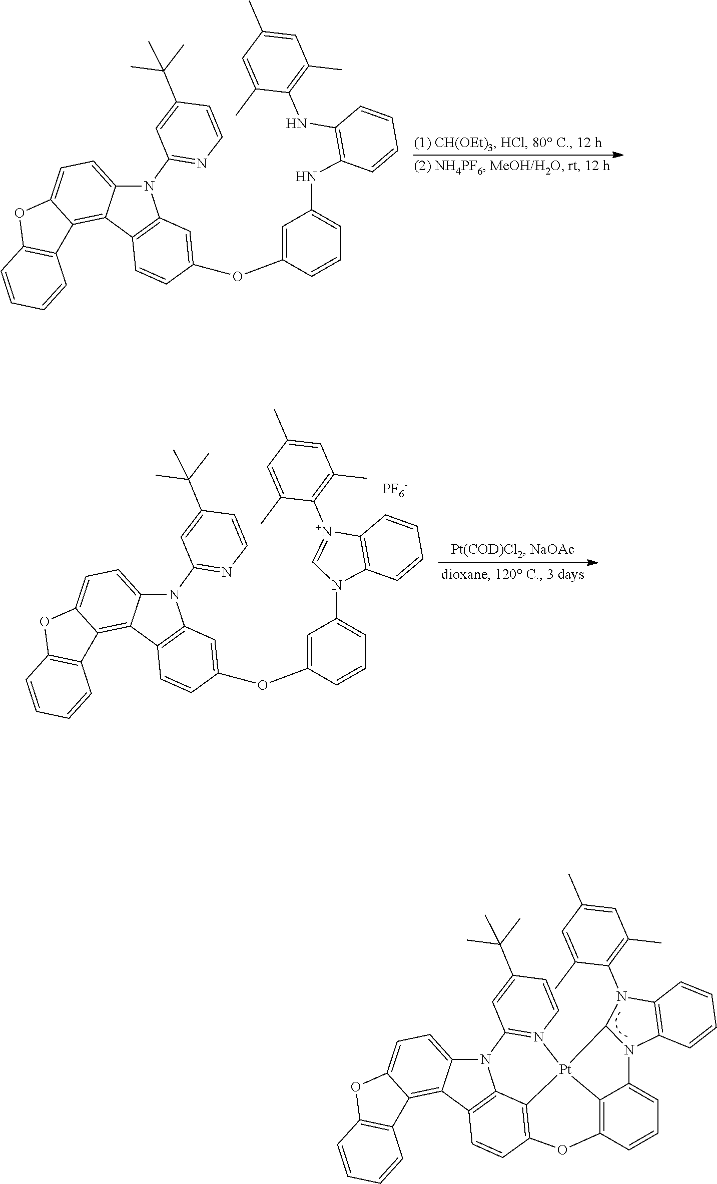

### Ex. 4-35:

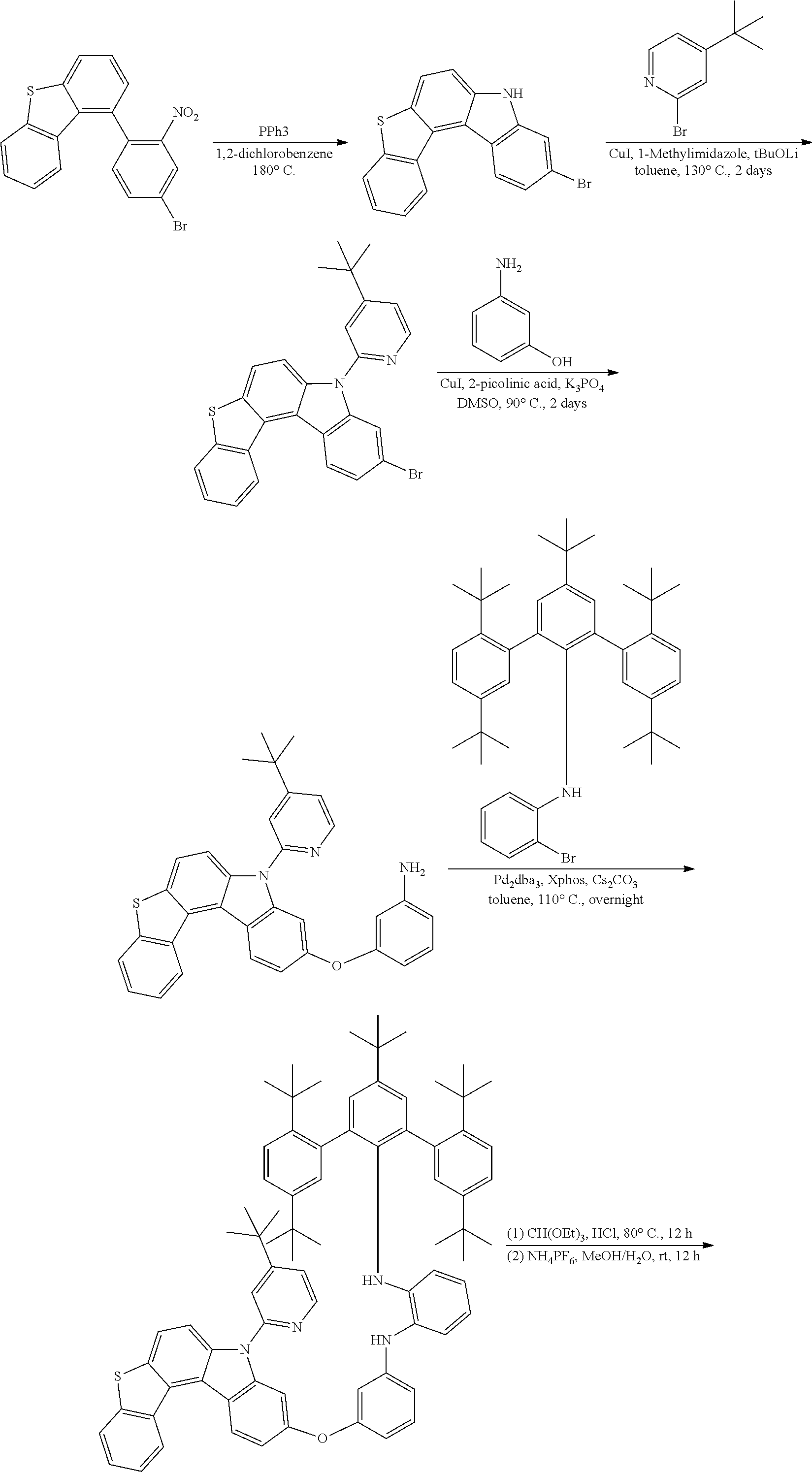

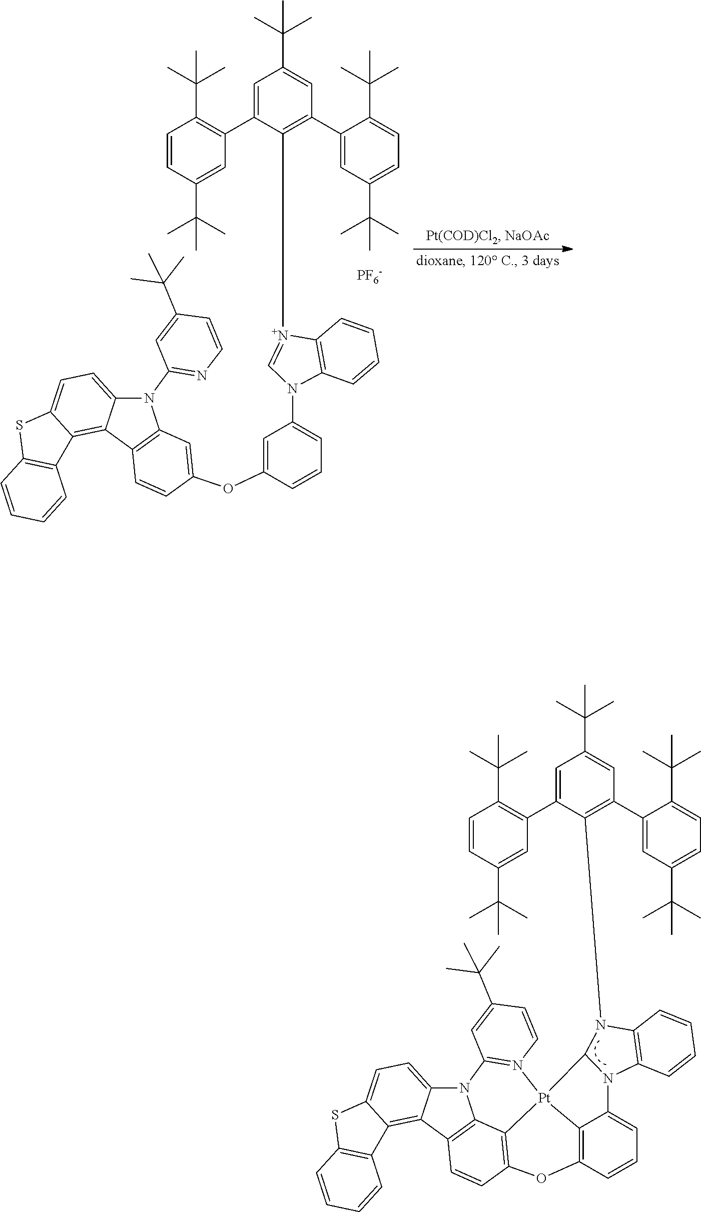

### Ex. 4-36:

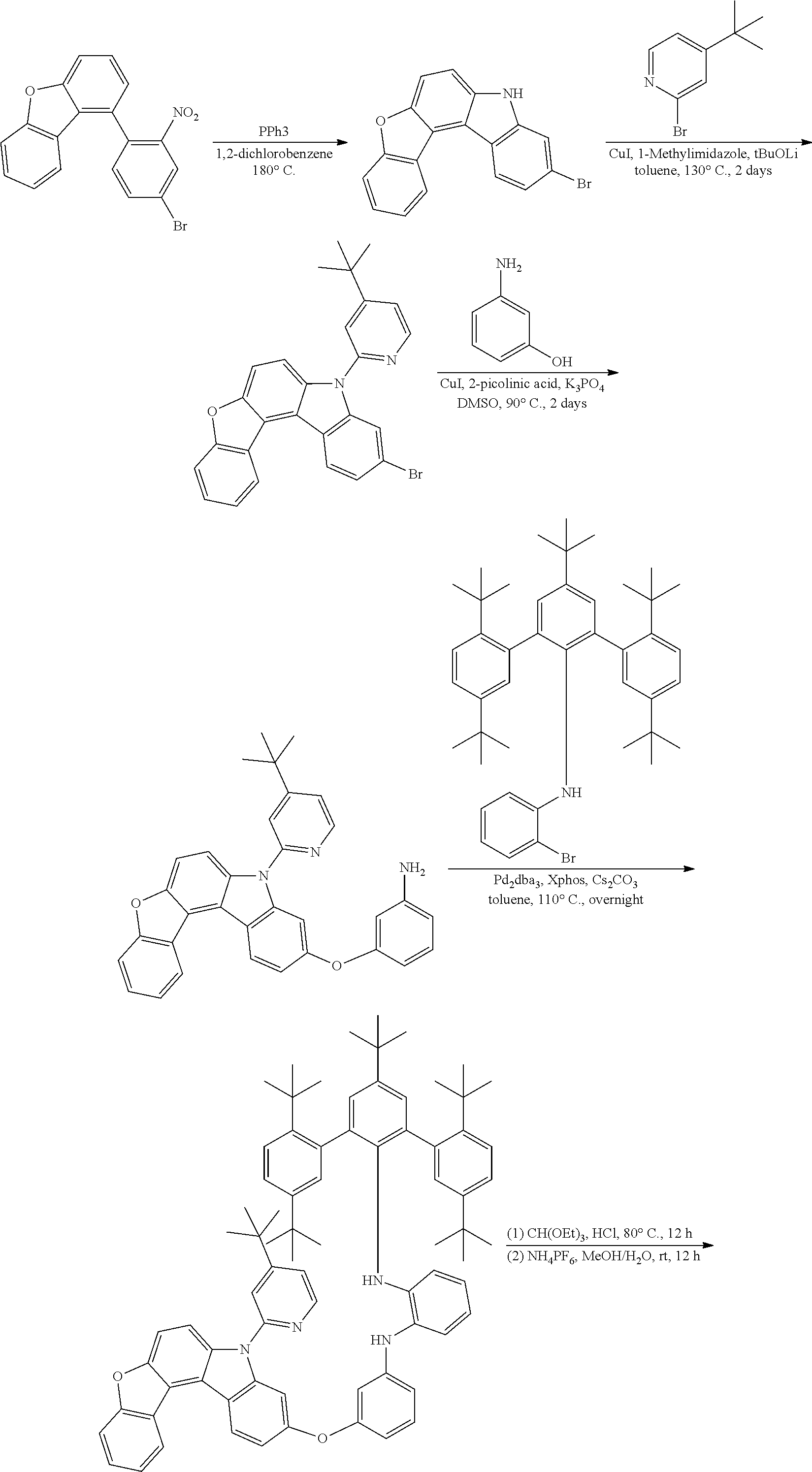

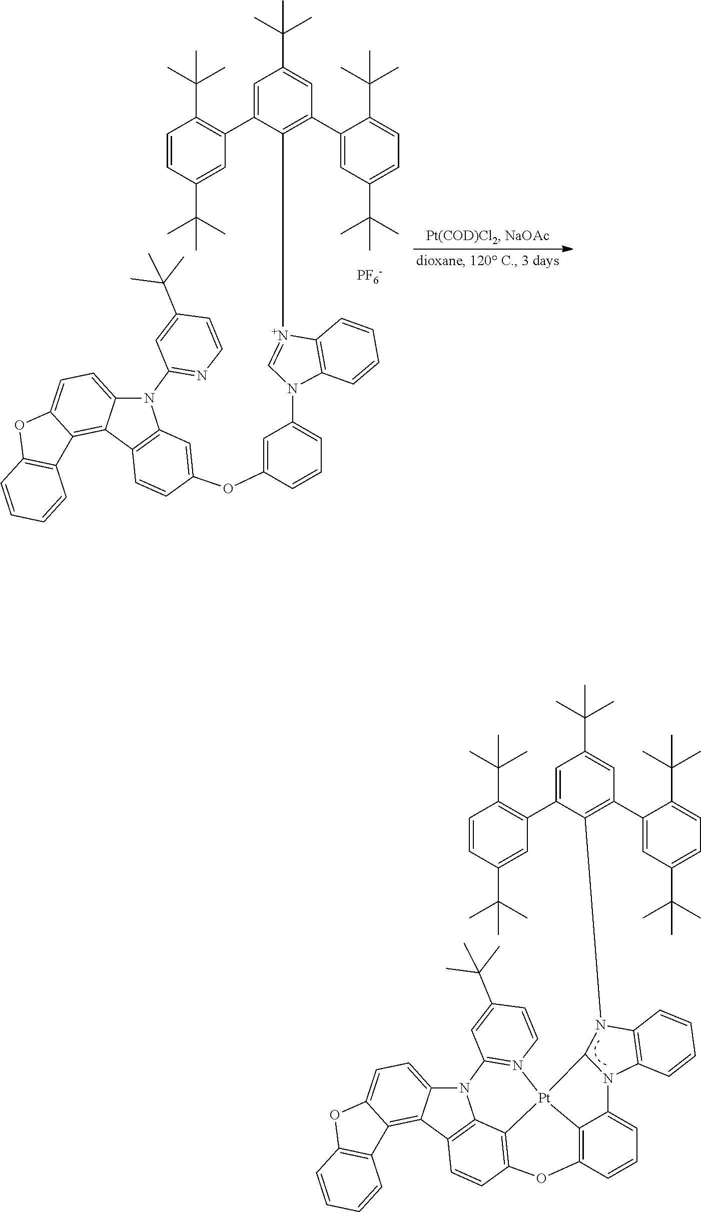

### Ex. 4-37:

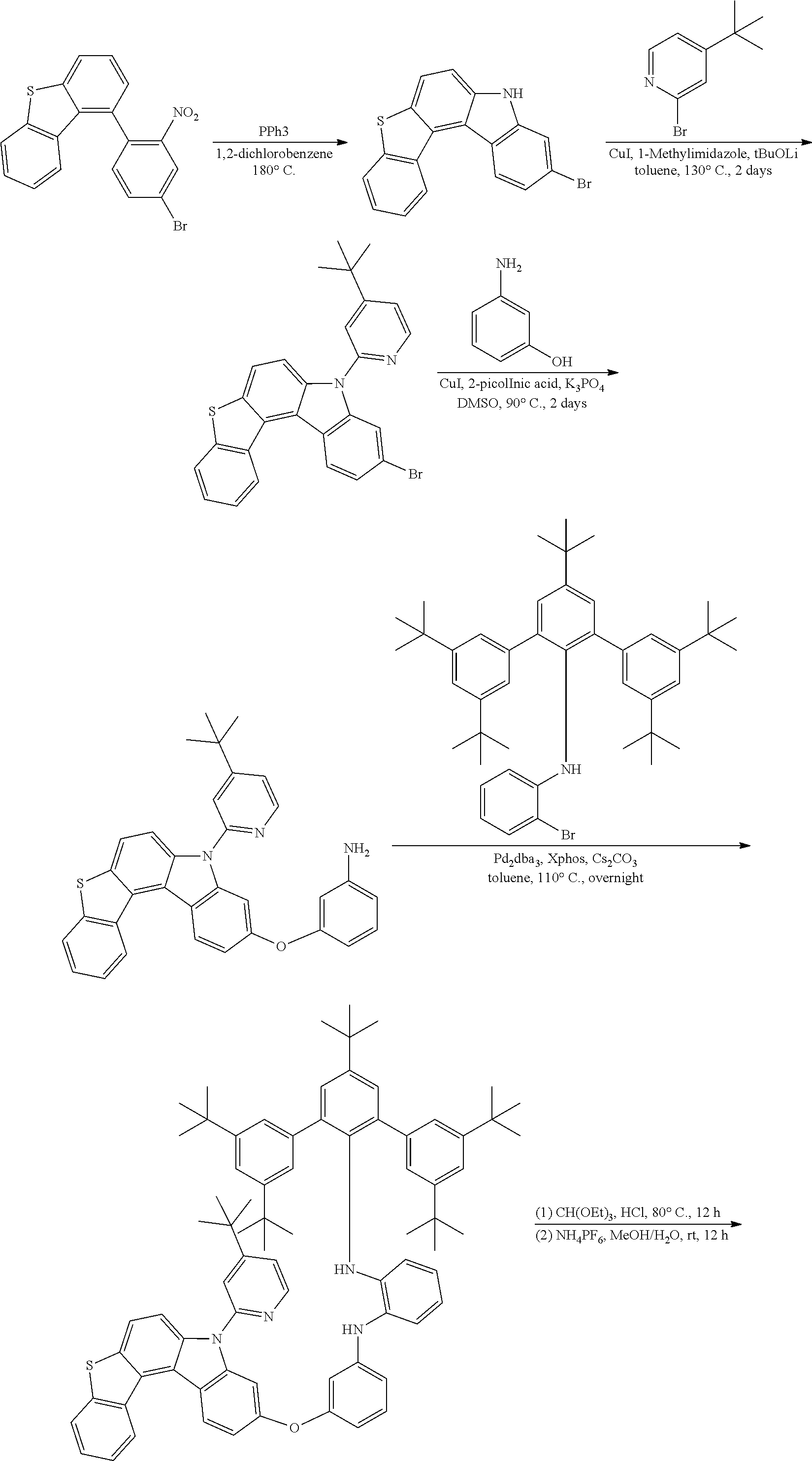

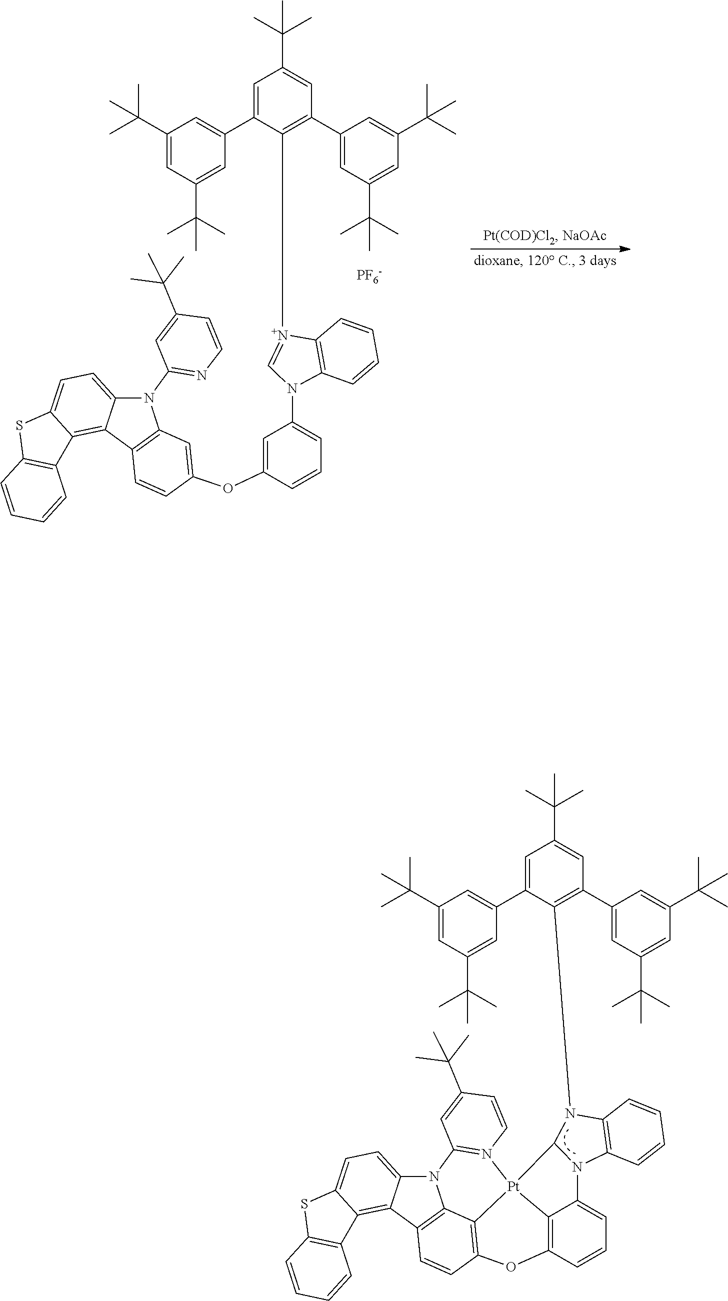

### Ex. 4-38:

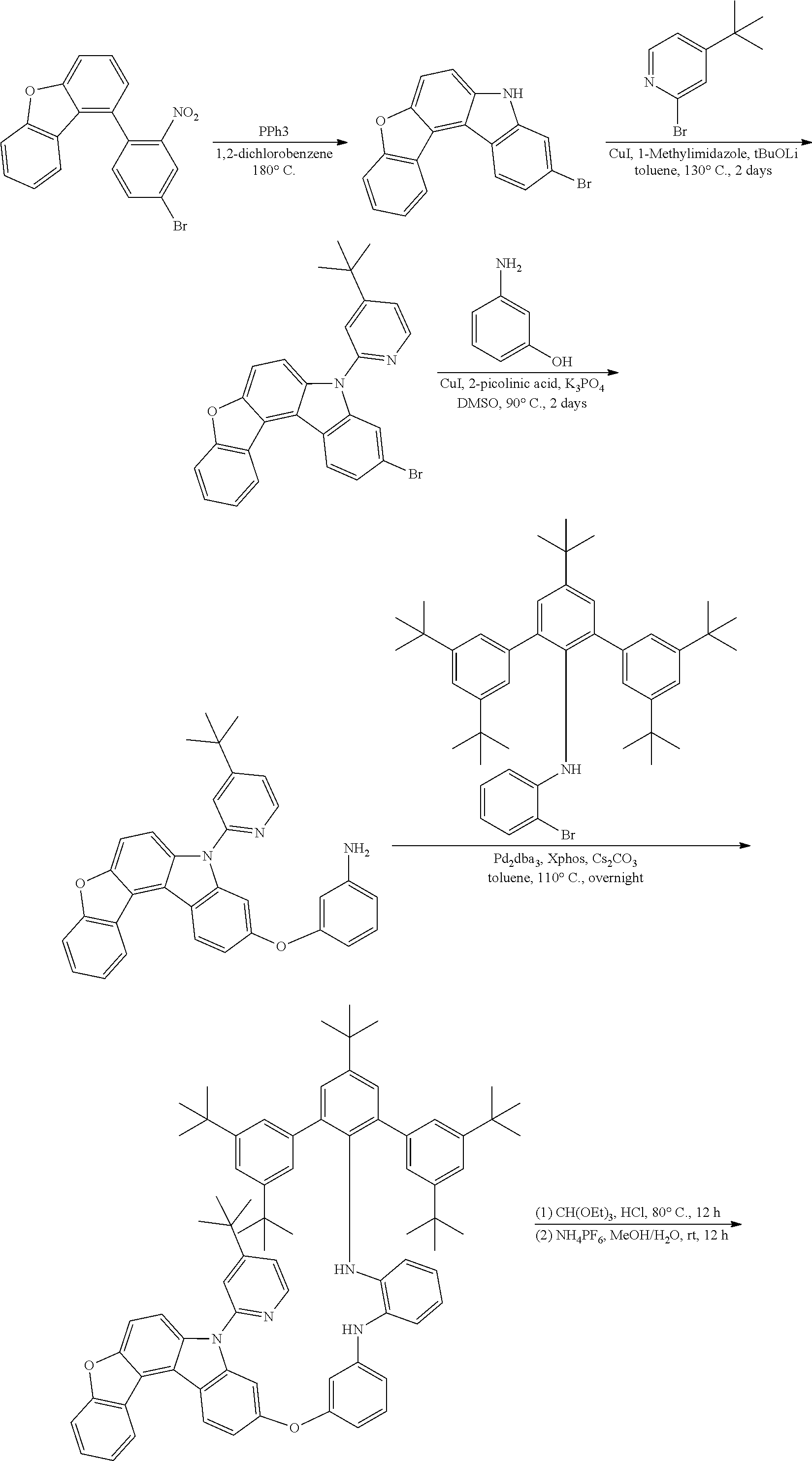

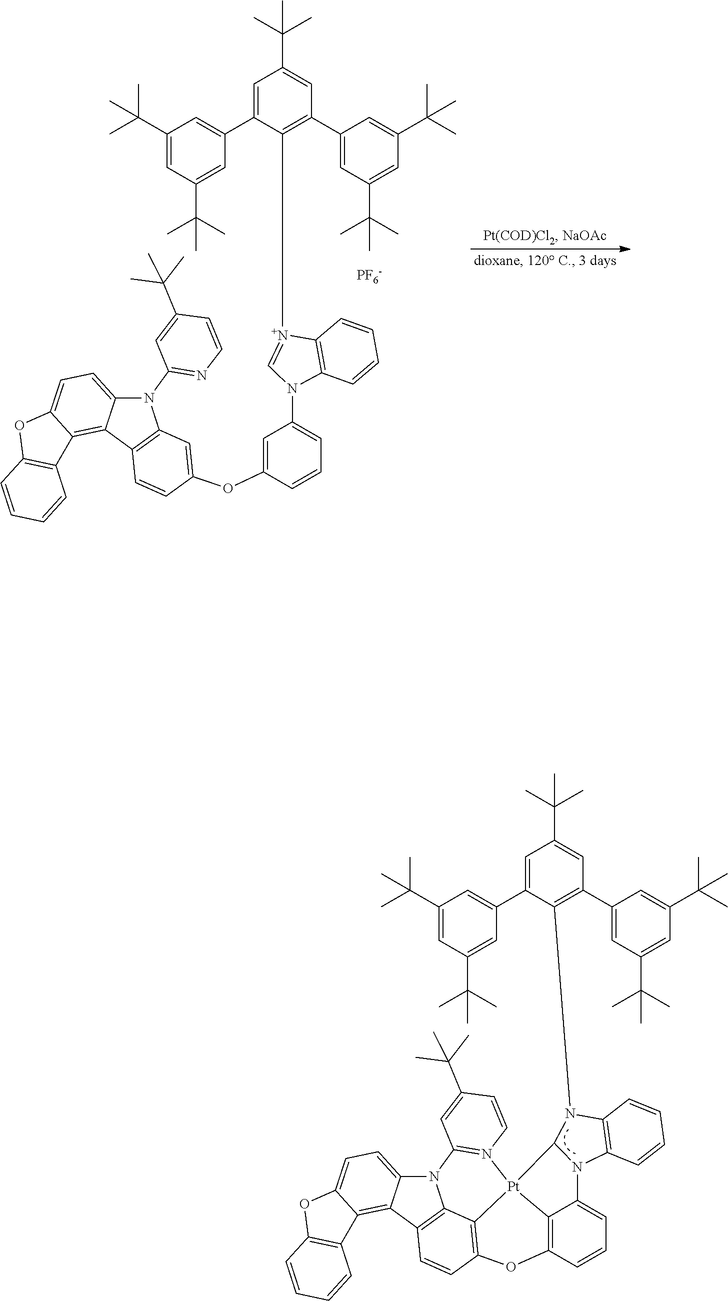

### Ex. 4-39:

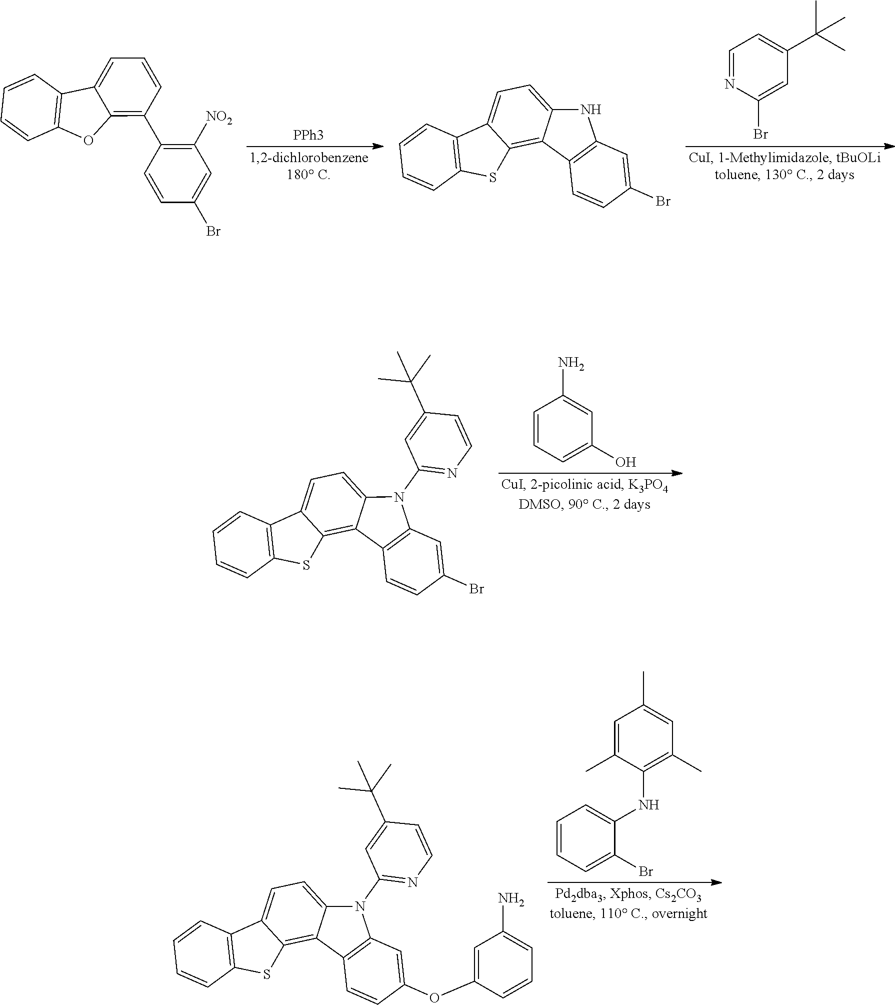

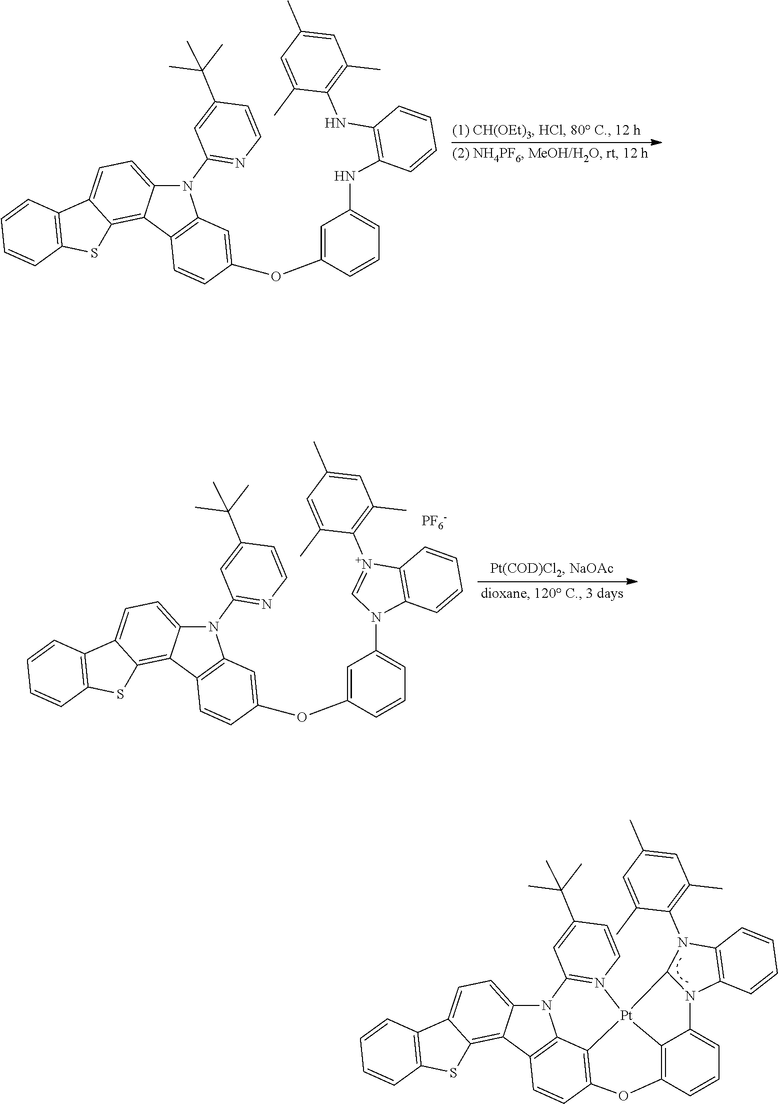

### Ex. 4-40:

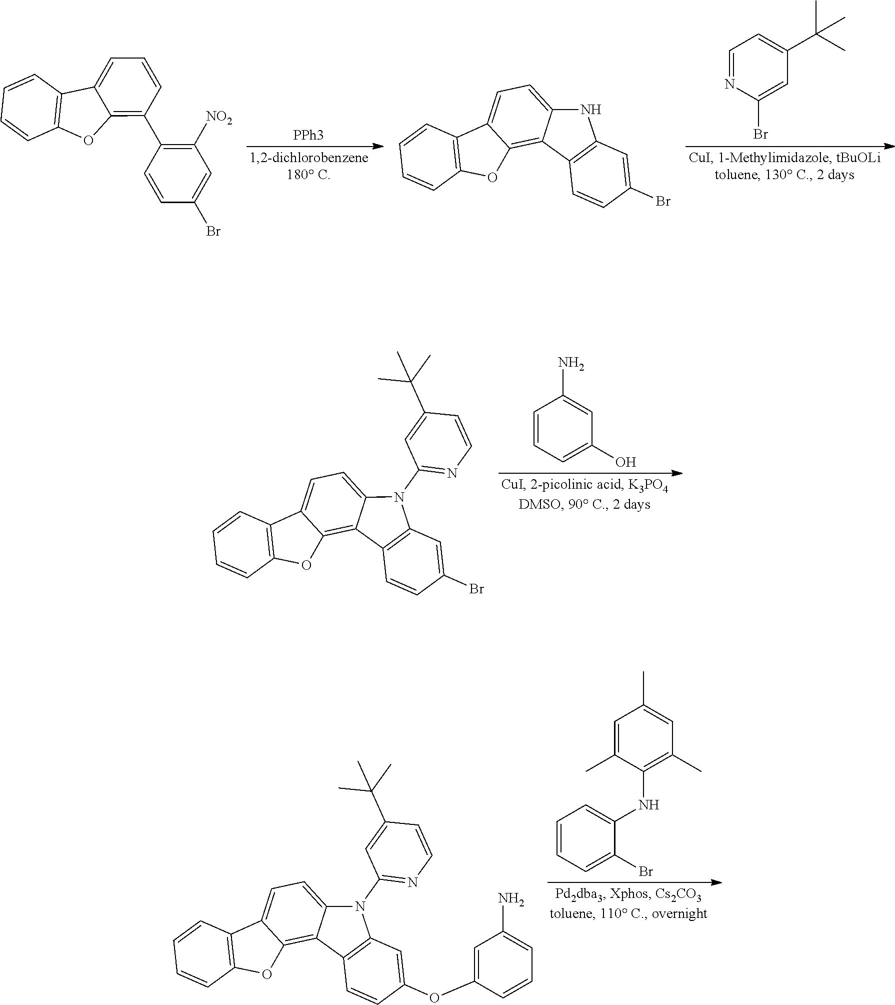

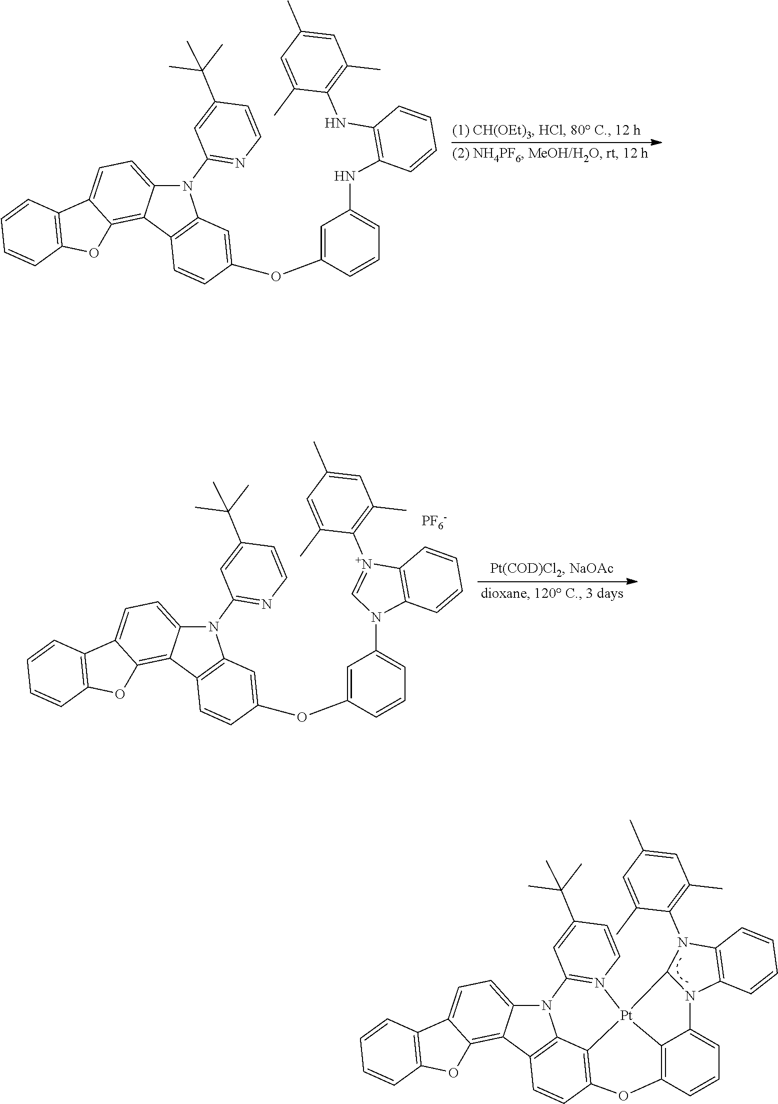

### Ex. 4-41:

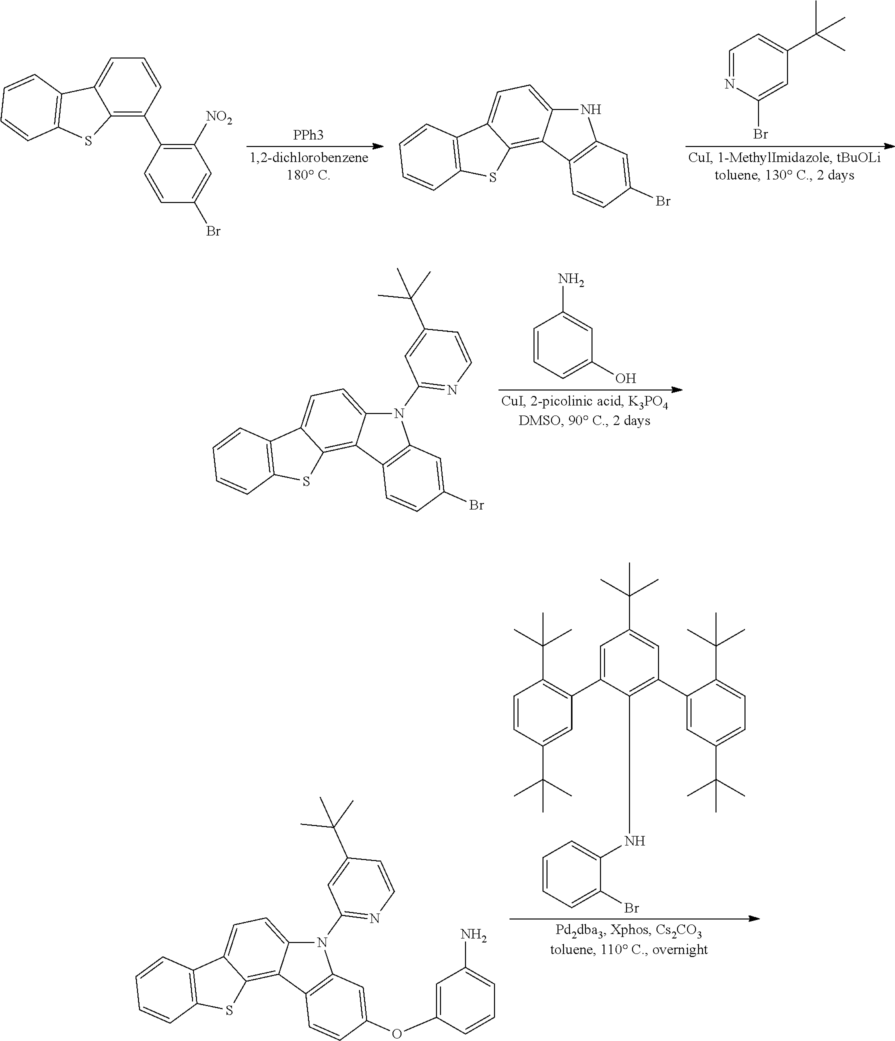

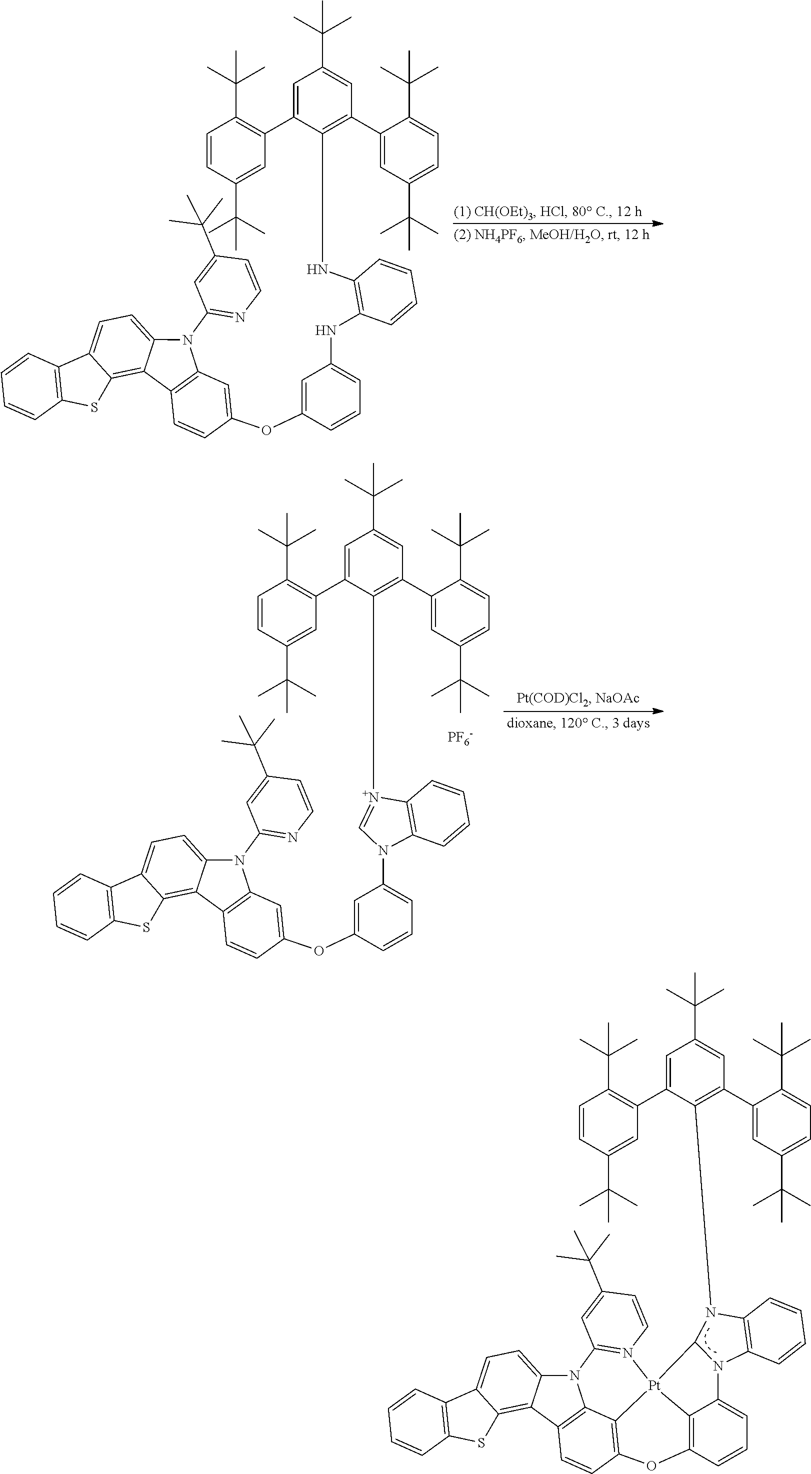

### Ex. 4-42:

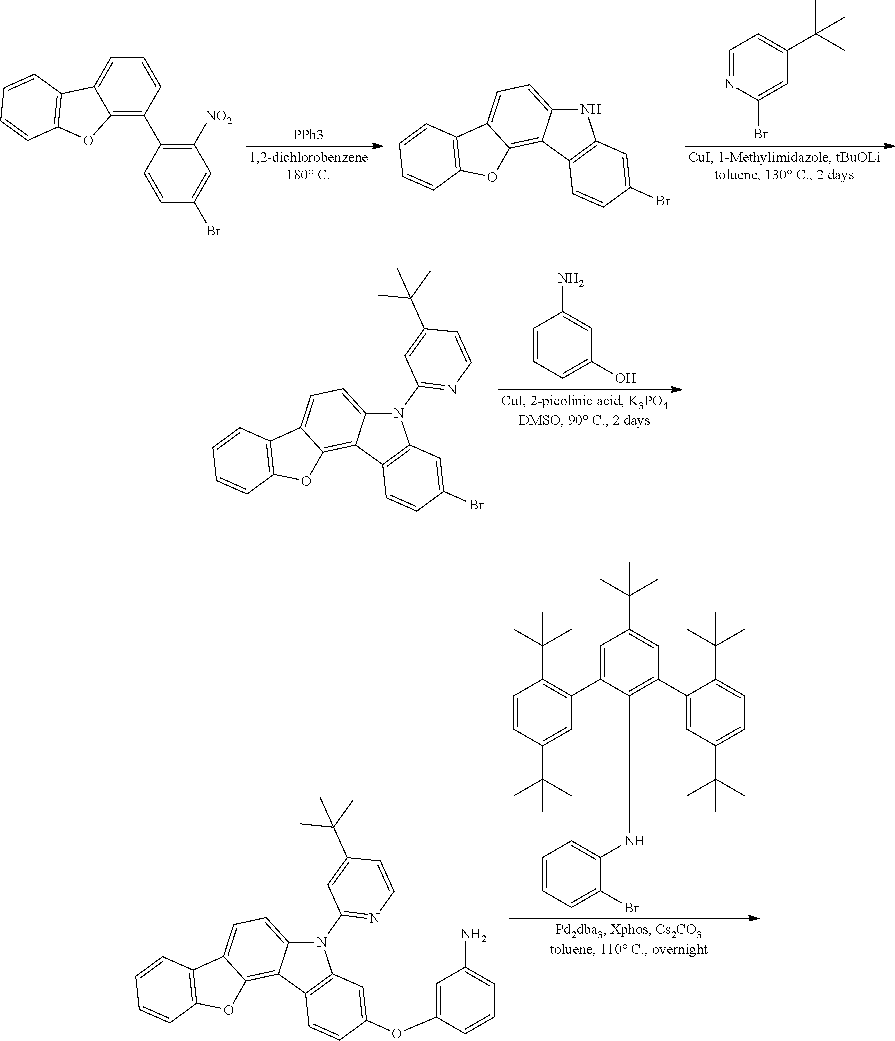

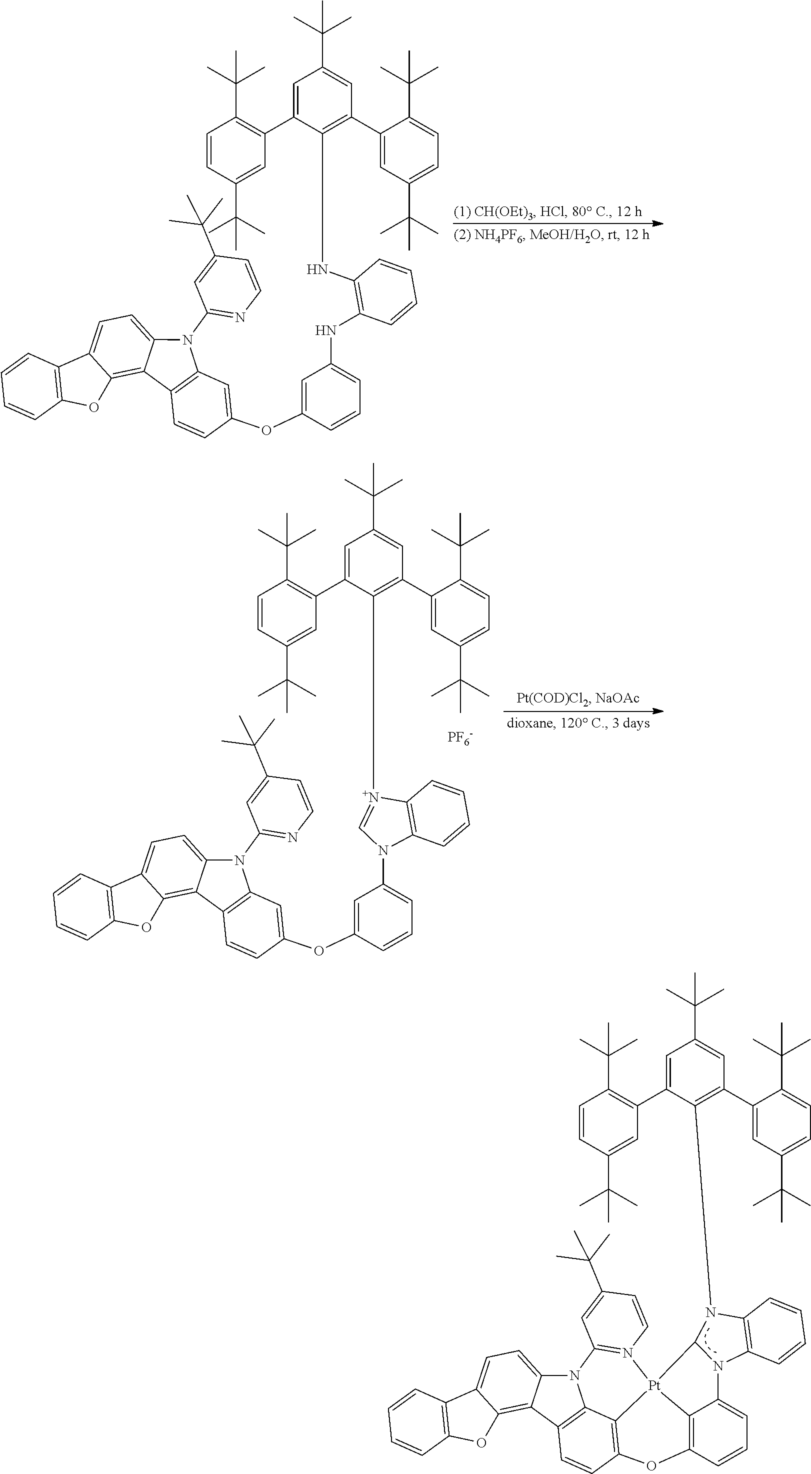

### Ex. 4-43:

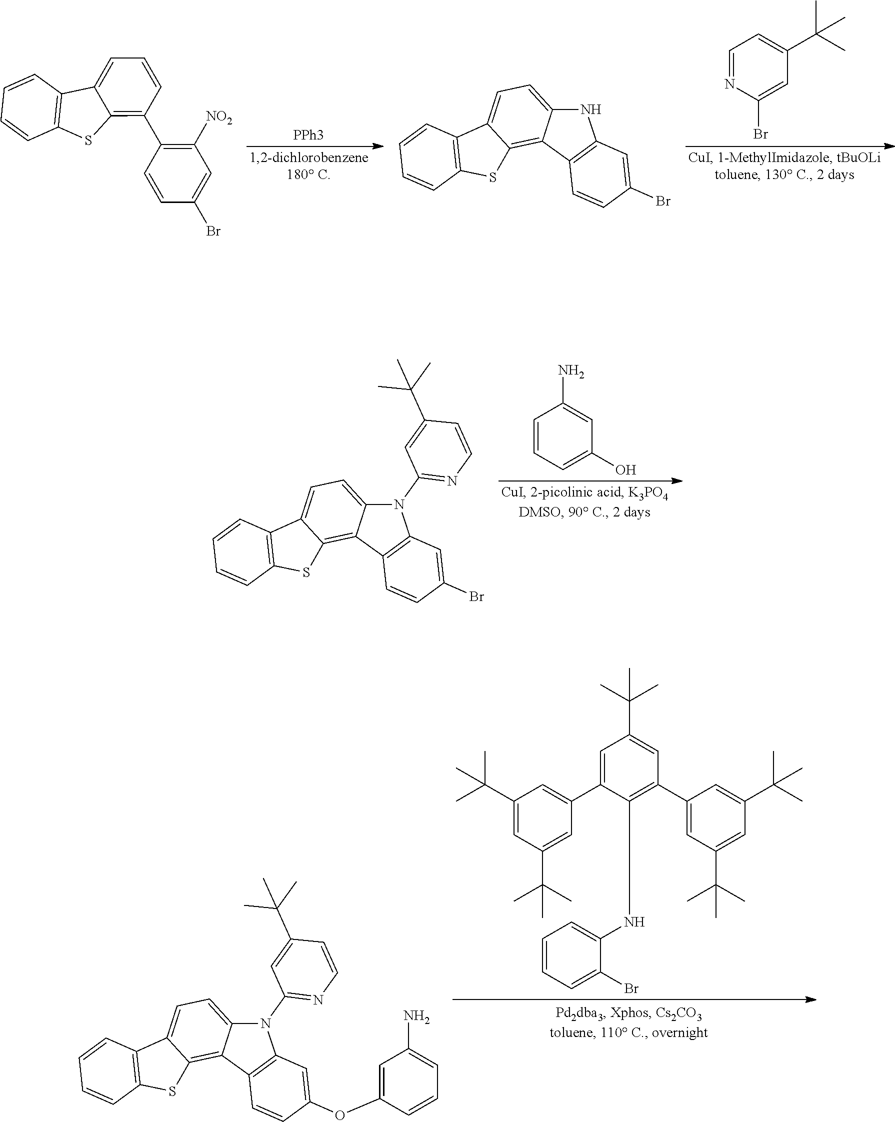

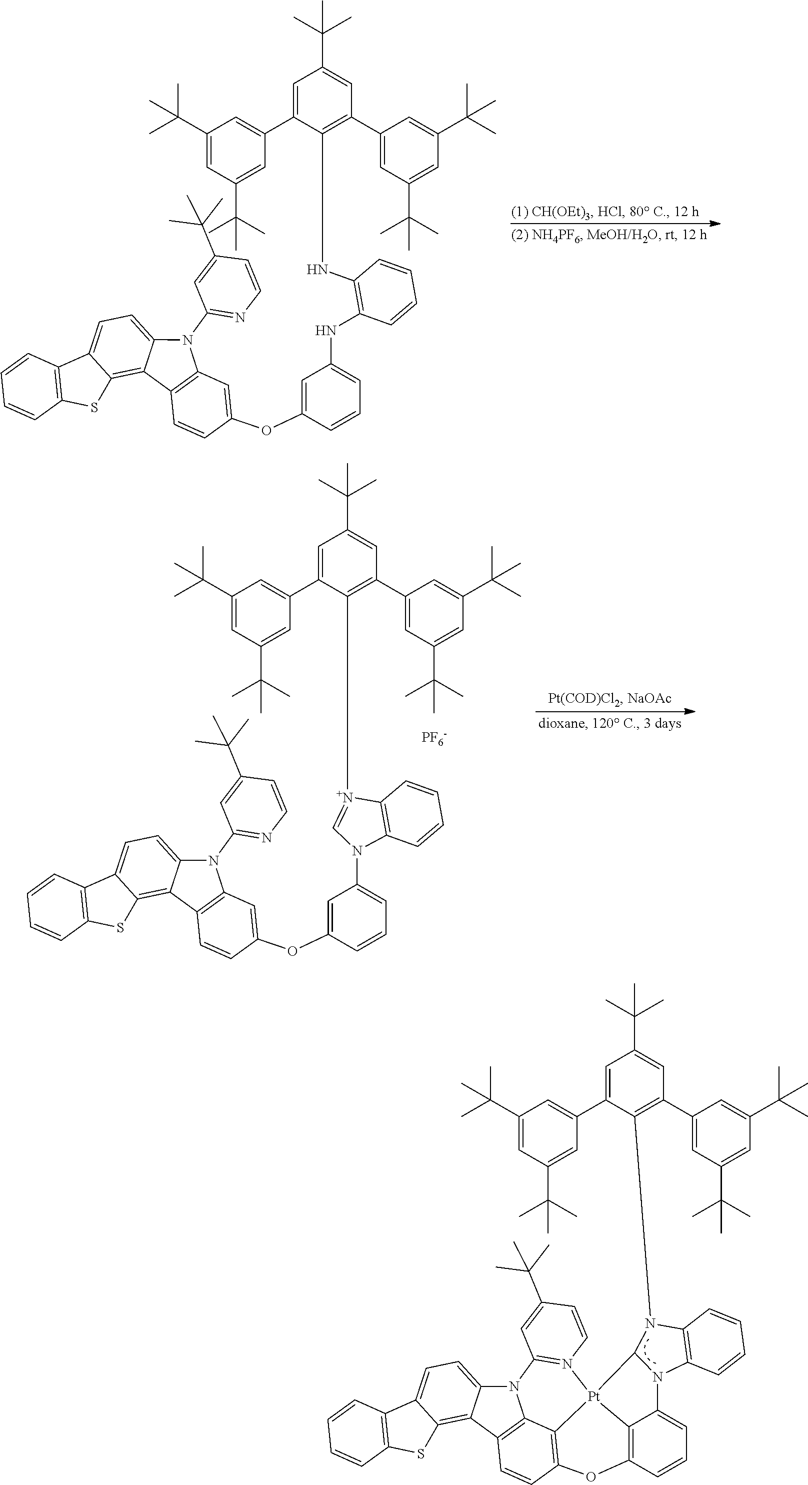

101251 Ex. 4-44:

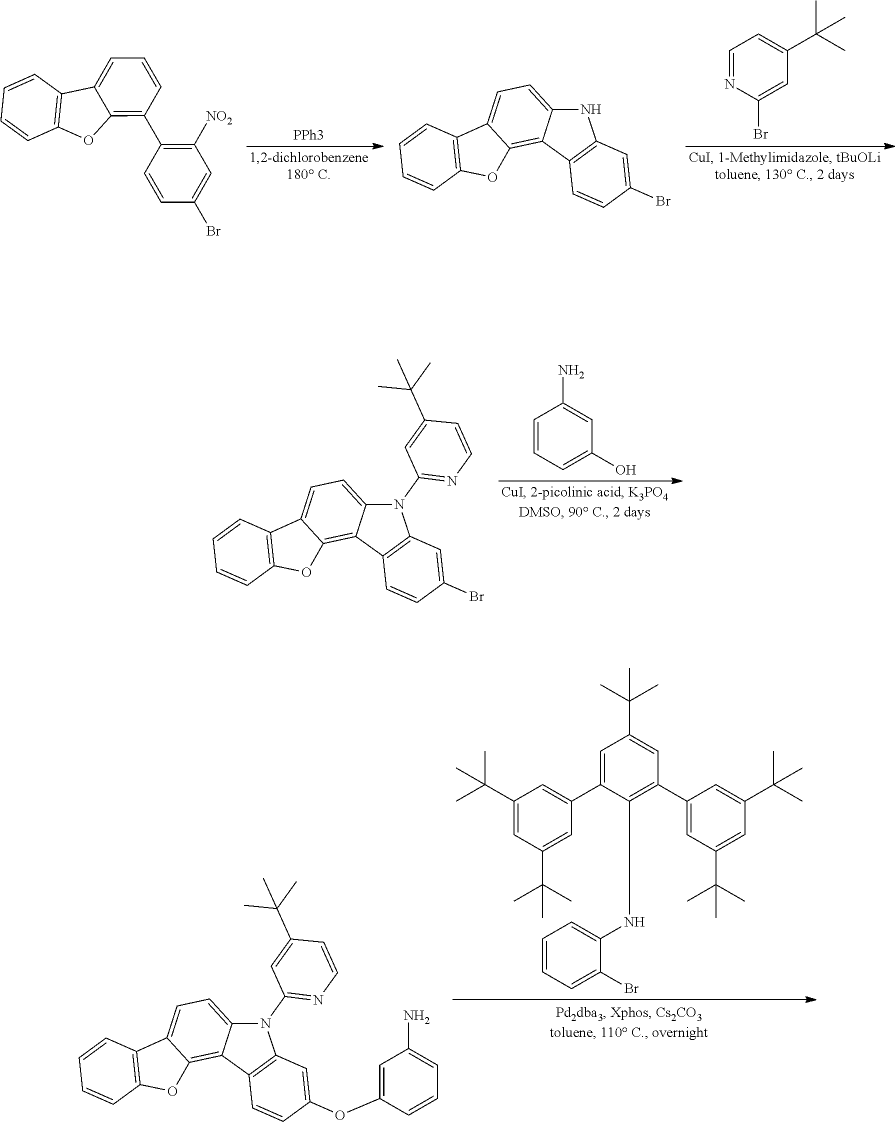

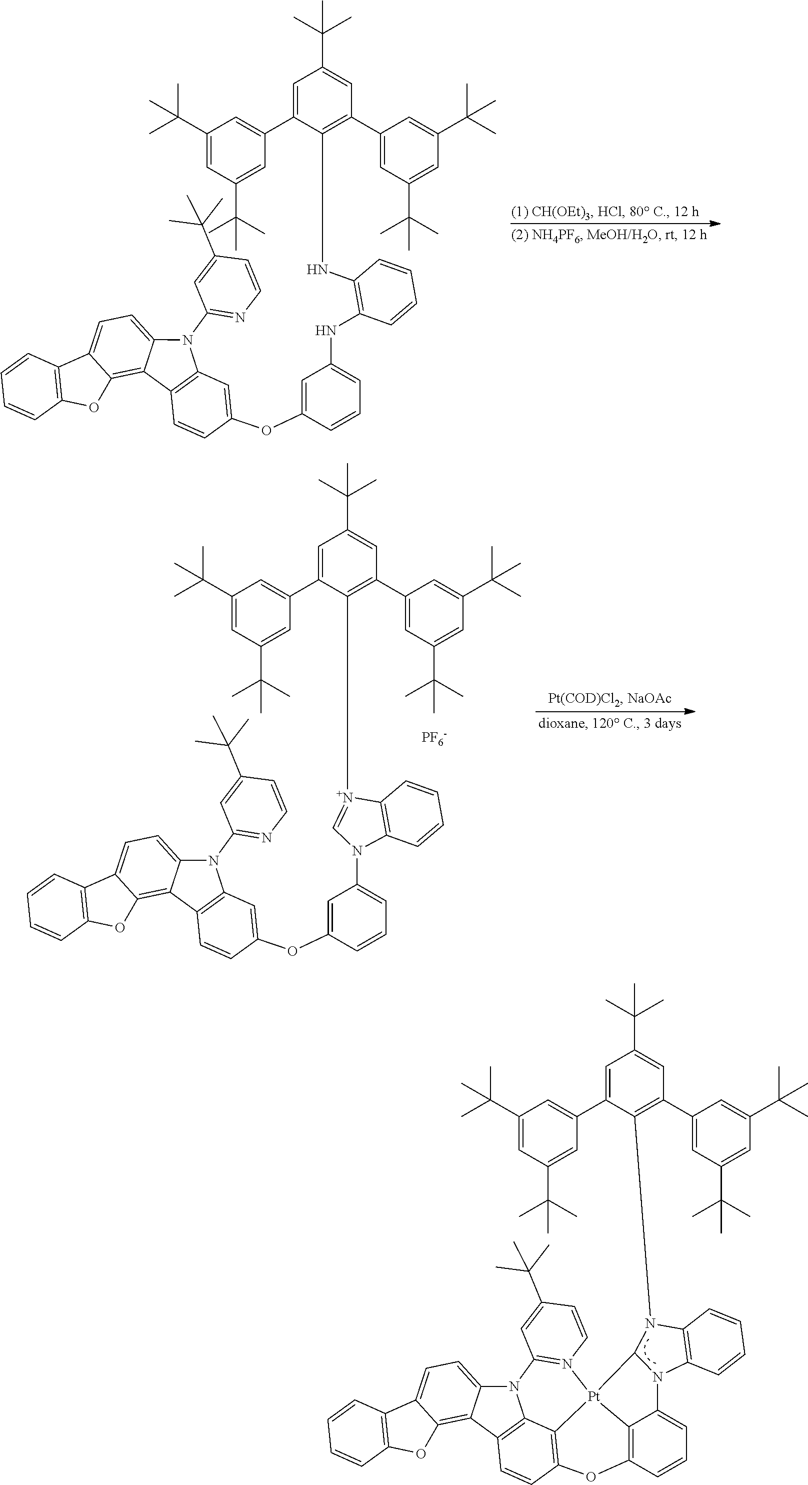

### Ex. 4-45:

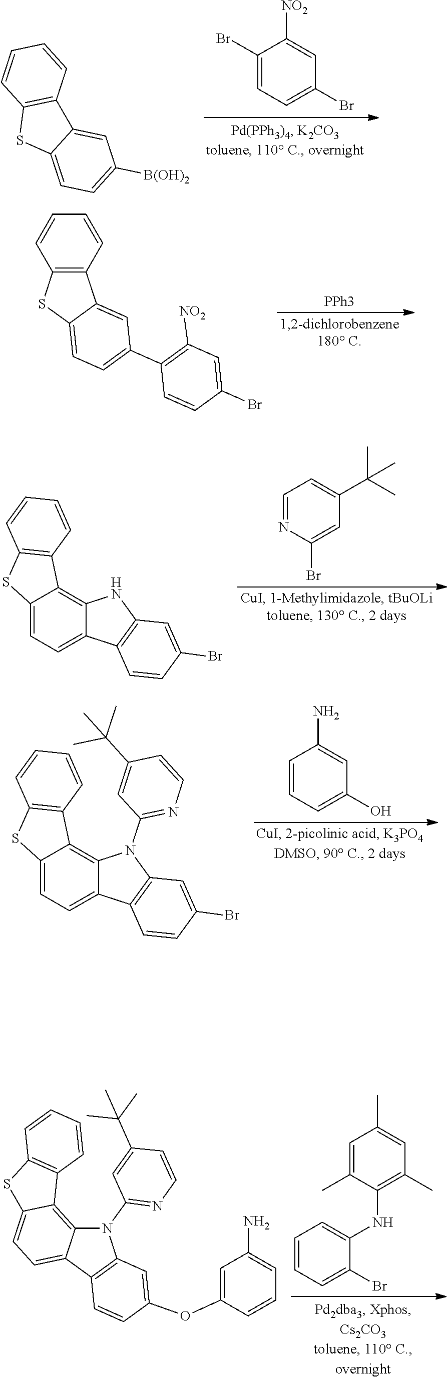

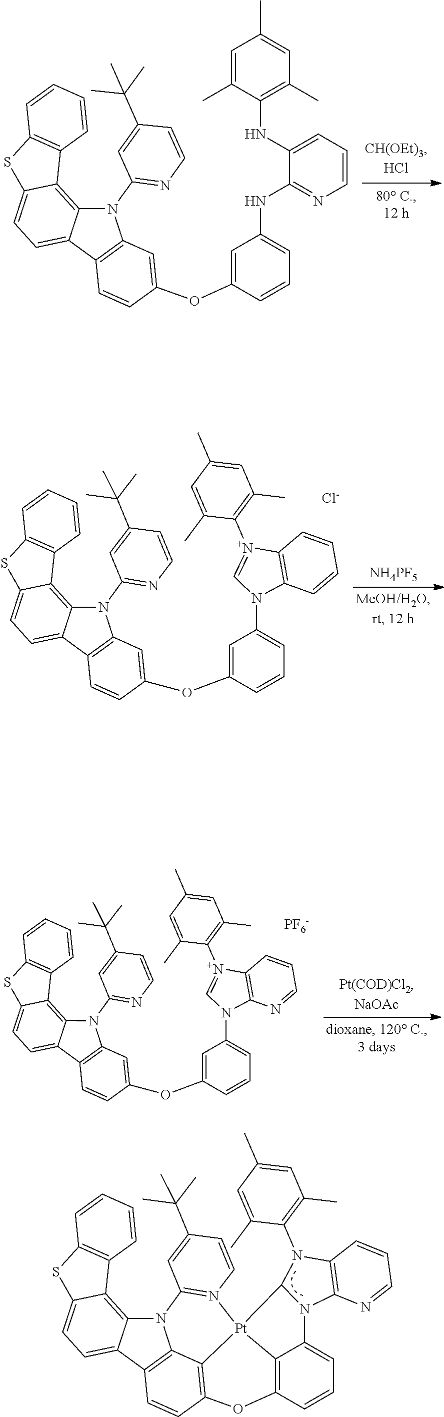

### Ex. 4-46:

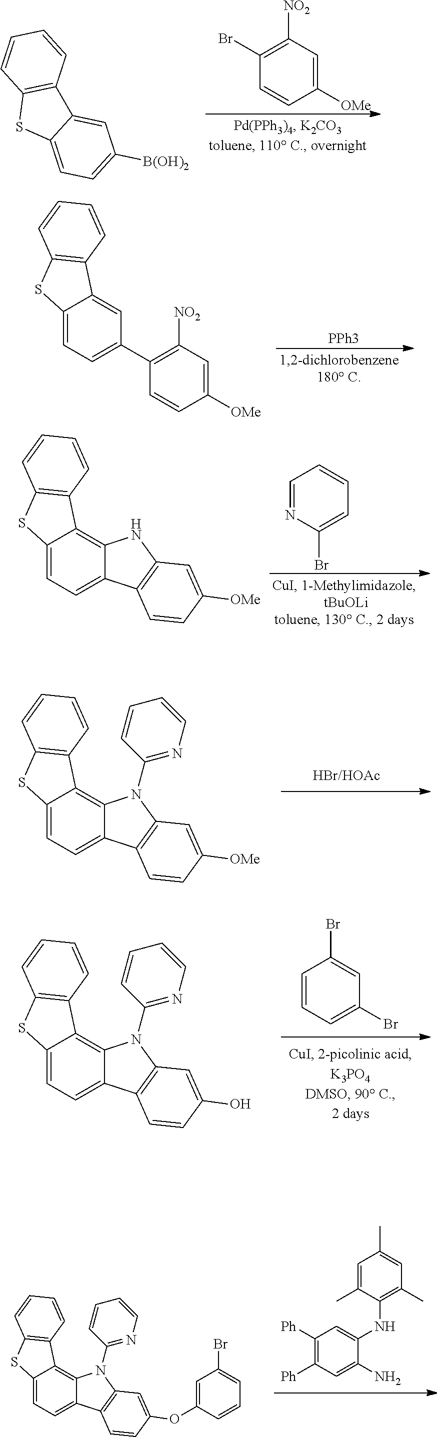

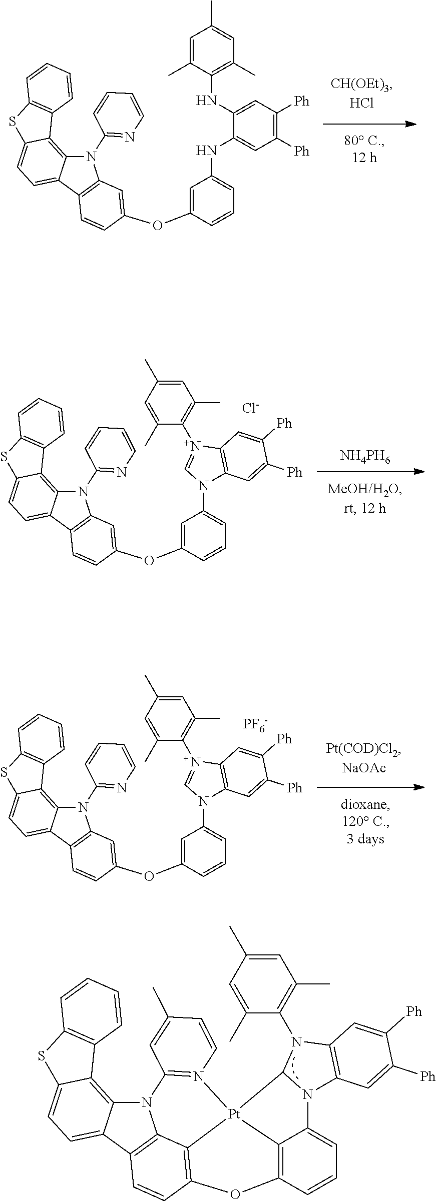

### Ex. 4-47:

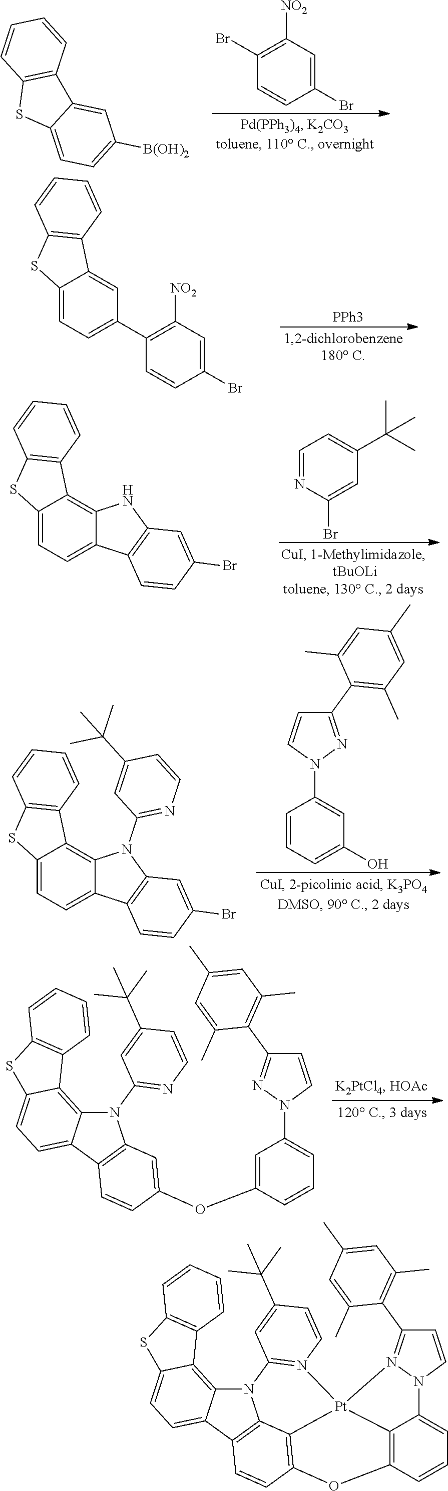

### Ex. 4-48:

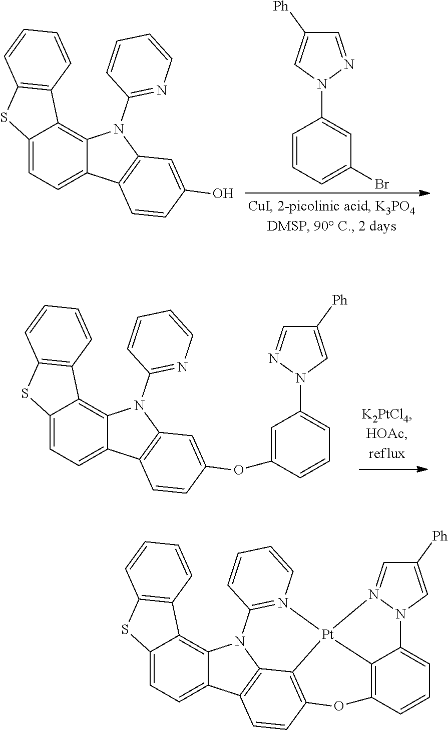

### Ex. 4-49:

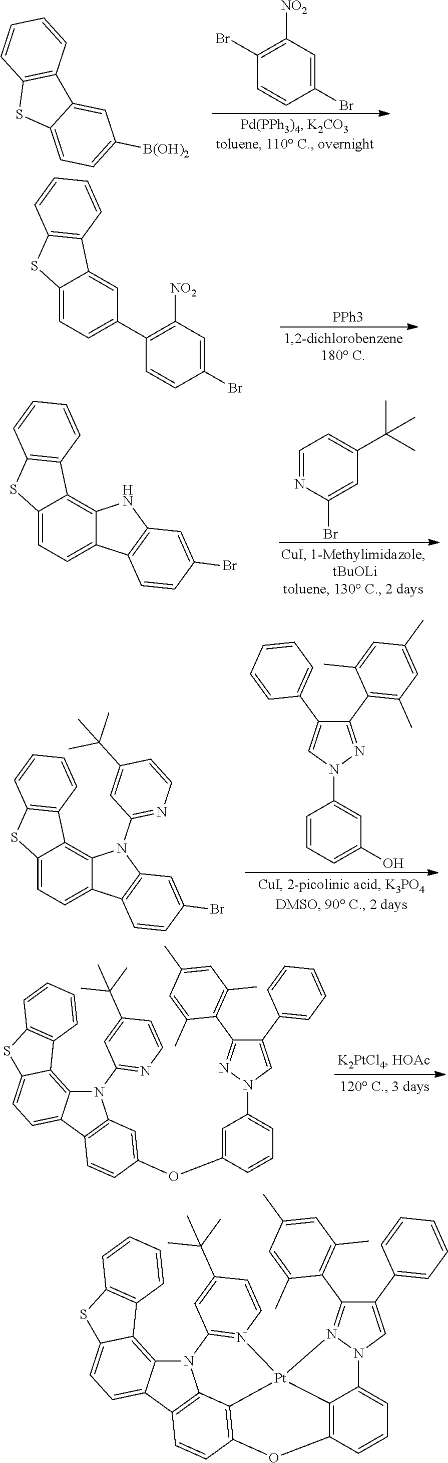

### Ex. 4-50:

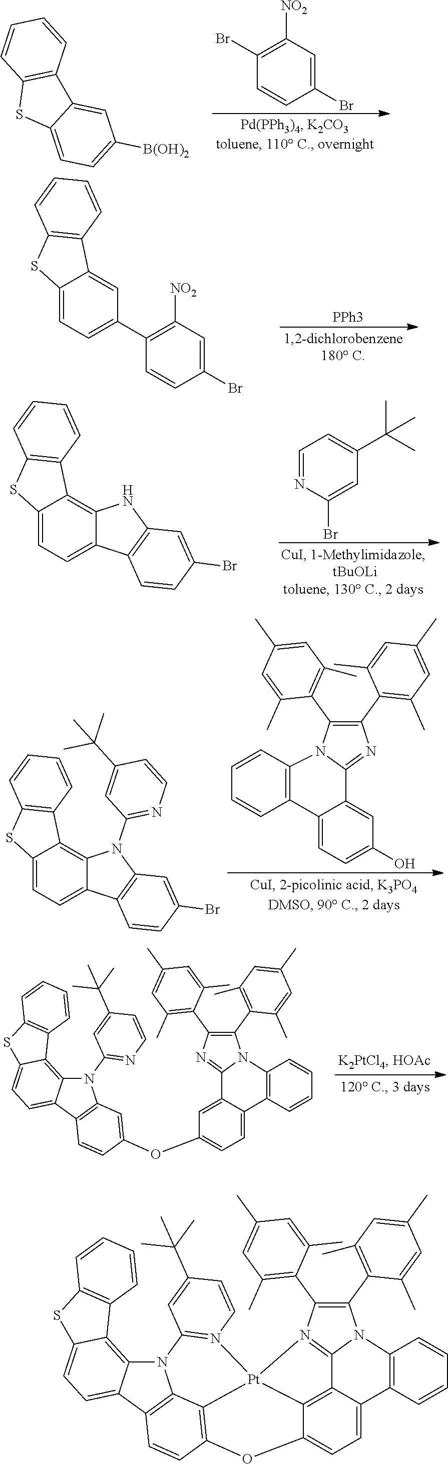

### Ex. 4-51:

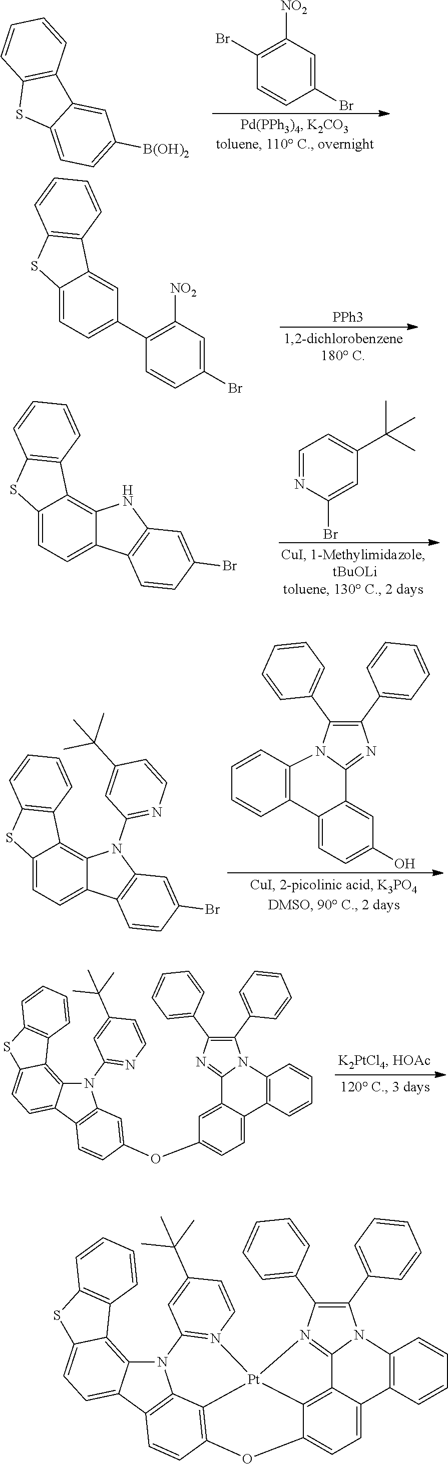

### Ex. 4-52:

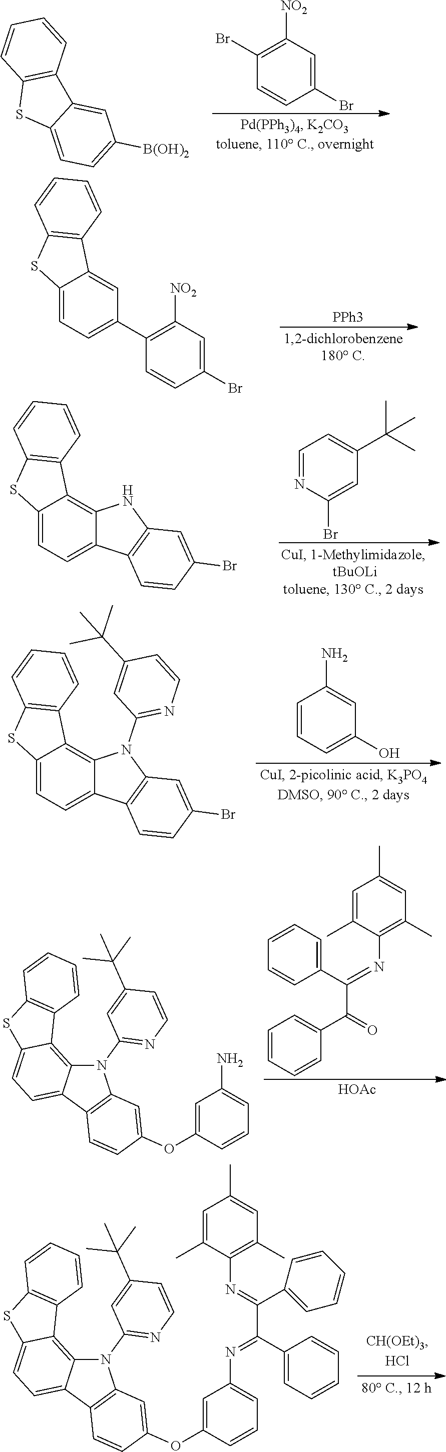

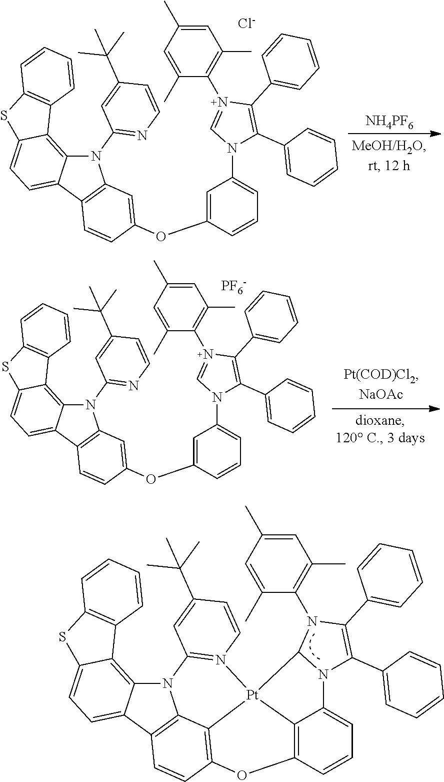

### Example 5: Phenyl-pyridine Based tetradentate Platinum Complex Emitters with Narrow Emission Spectrum in the Green and Red Emission Range

The narrowband emitters were designed to have a small spectral difference between the 77k emission and room temperature emission through rigid tetradentate metal complex design. Moreover, the emitter was incorporated with potential fragment of carbazole and its analogs to decrease the vibronic features of their emission spectra at 77K, which could further minimize their emission spectral bandwidth.

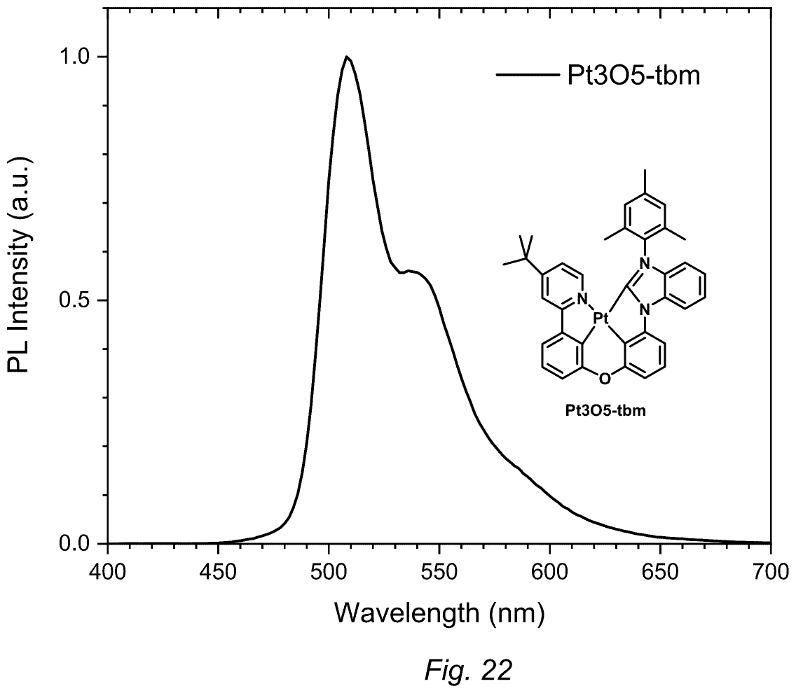

The PL spectrum of Pt305-tbm in solution of dichloromethane at room temperature is presented in FIG. 22.

The compounds can be synthesized in the following manner:

### Ex. 1

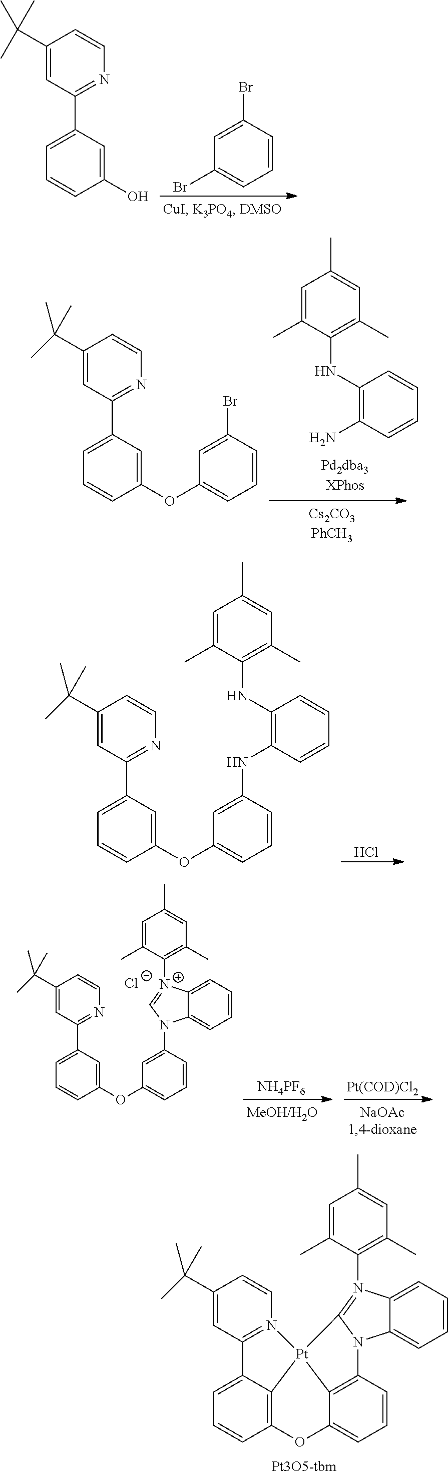

### Ex. 2

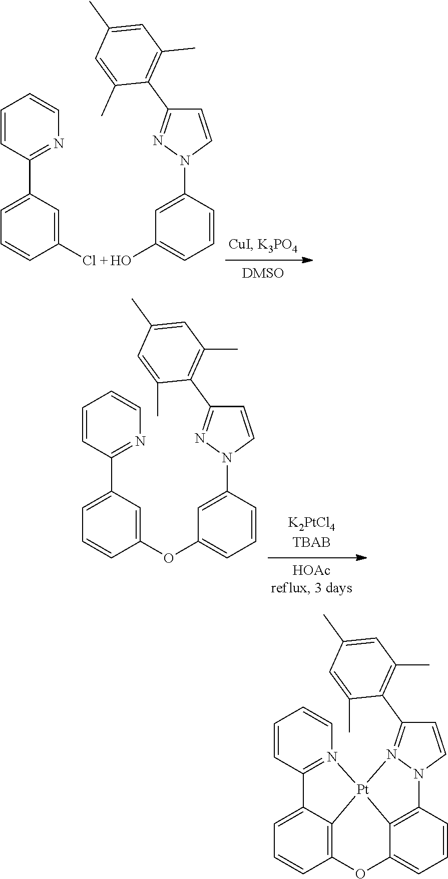

### Ex. 3

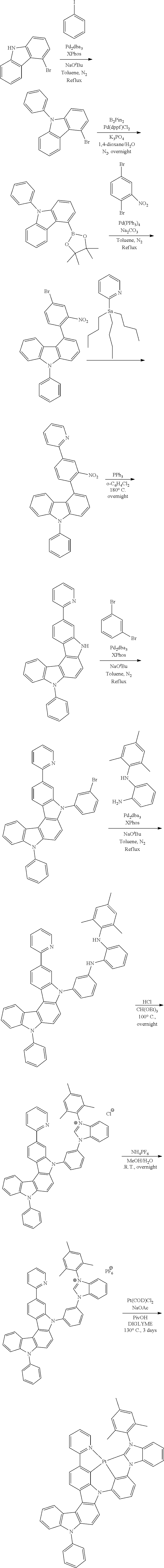

### Ex. 4

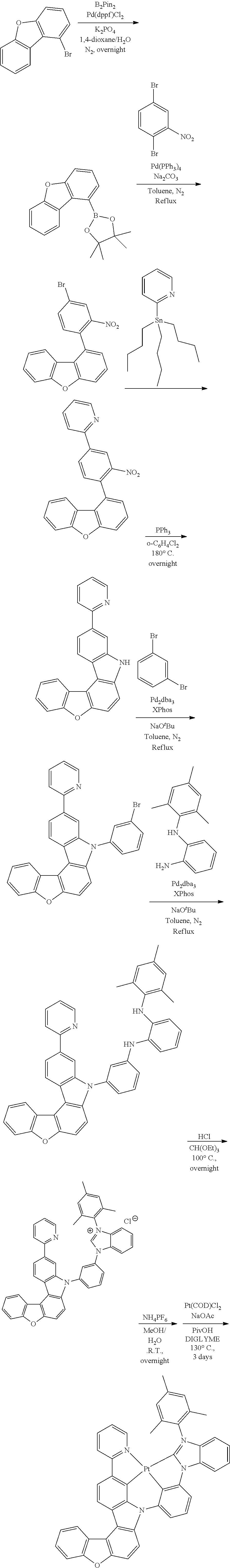

### Ex. 5

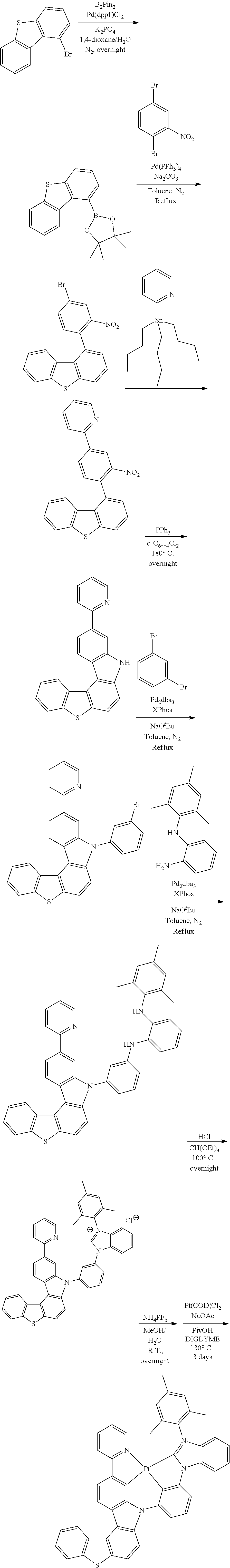

### Ex. 6

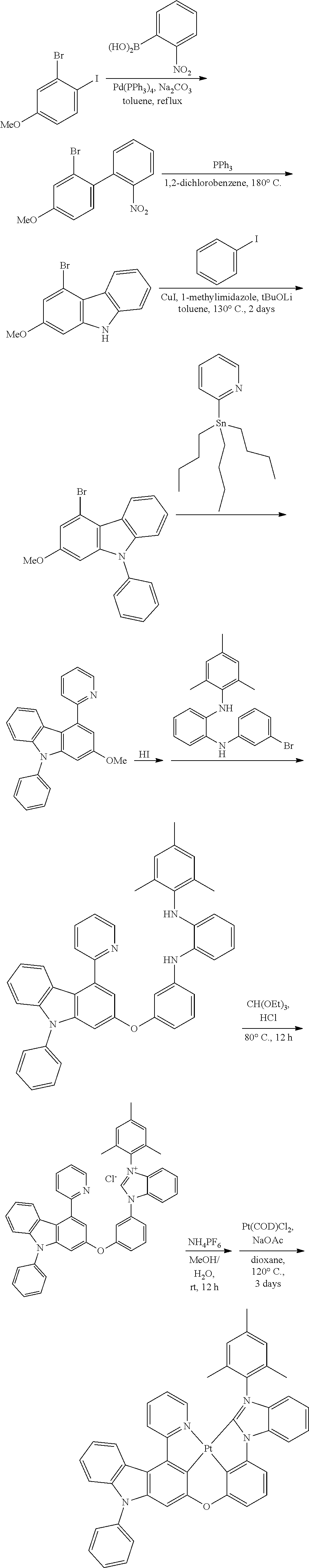

### Ex. 7/8

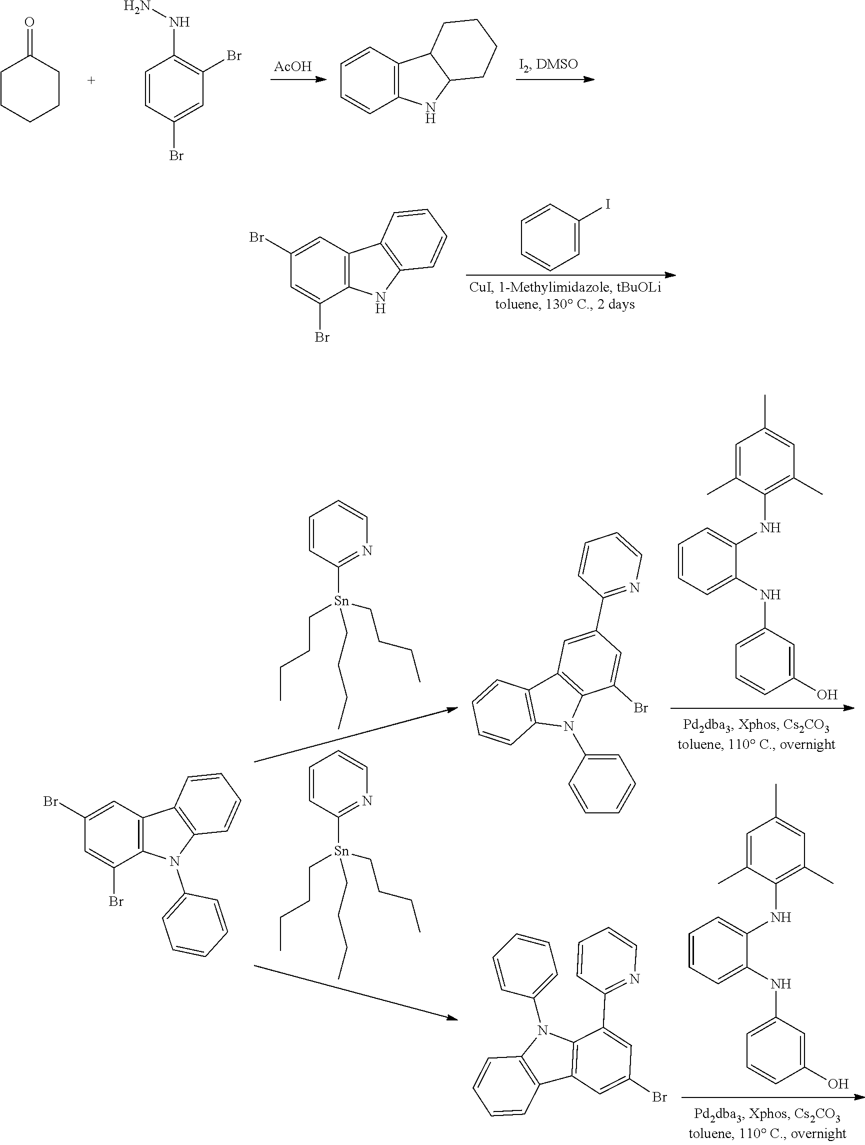

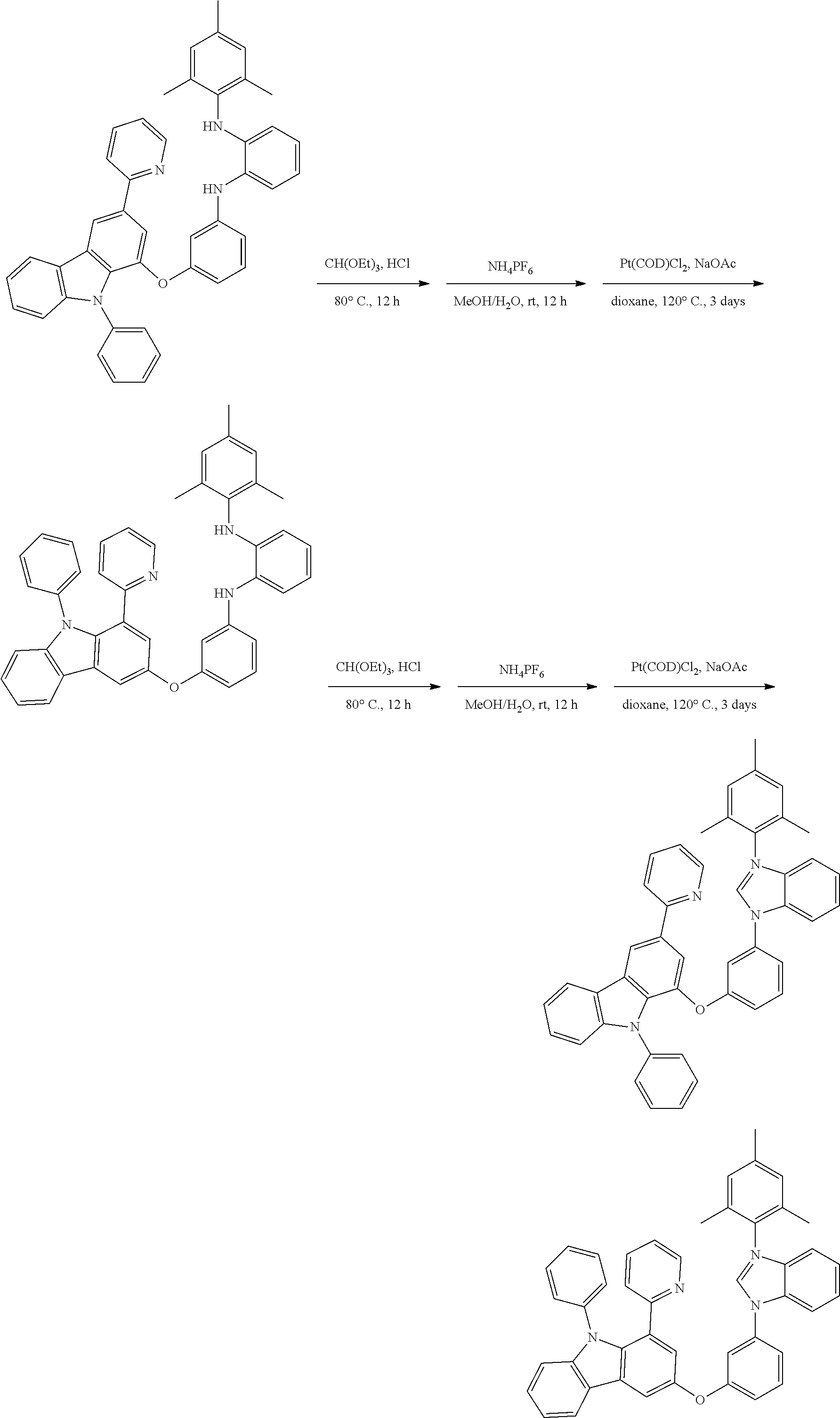

### Ex. 9

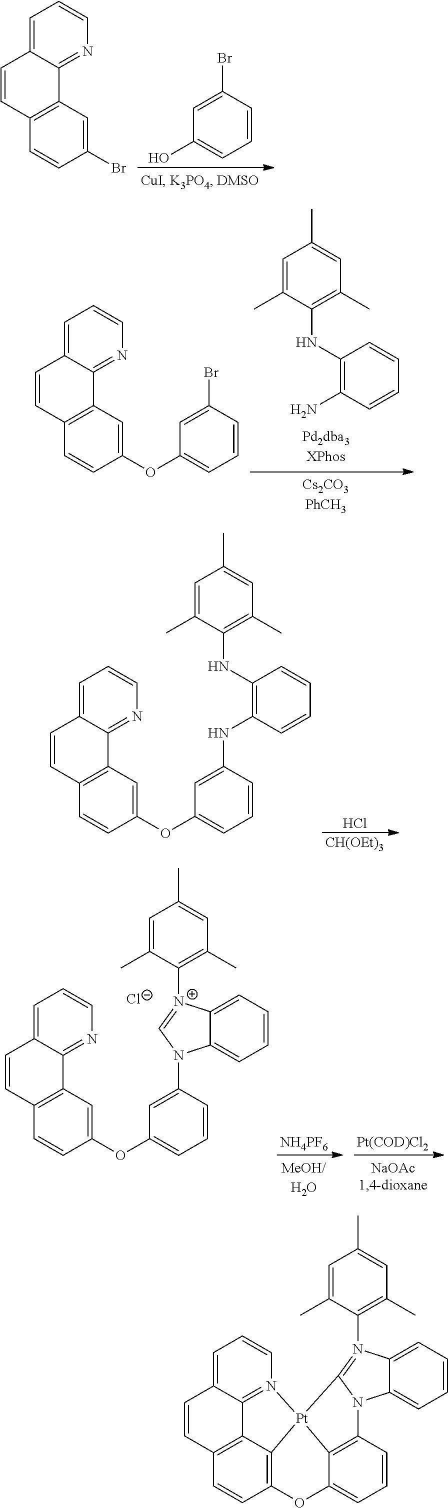

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

We claim:

1. A compound represented Formula I: 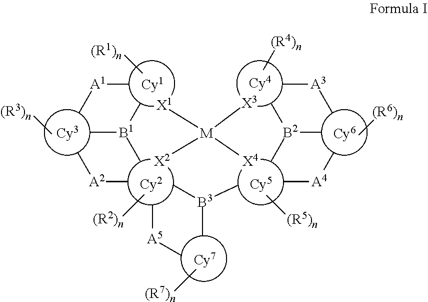
wherein:
M represents platinum (Pt) or palladium (Pd);
X¹, X², X³, and X⁴ are coordinated with M and are independently N or C;
each of Cy¹, Cy², Cy⁴, and Cy⁵ is independently substituted or unsubstituted aryl, cycloalkyl, cycloalkenyl, heteroaryl, heterocyclyl, carbene, or N-heterocyclic carbene;
Cy³, Cy⁶, and Cy⁷ are independently present or absent; wherein each Cy³, Cy⁶, and Cy⁷ present is independently substituted or unsubstituted aryl, cycloalkyl, cycloalkenyl, heteroaryl, heterocyclyl, carbene, or N-heterocyclic carbene;
wherein when Cy³ is absent, then B¹ is selected from the group consisting of CR⁸R⁹, CR¹═CR², C≡C, C═O, C═S, SiR⁸R⁹, GeR⁸R⁹, NR¹⁰, PR¹⁰, R¹⁰P═O, AsR¹⁰, R¹⁰As═O, O, S, S═O, SO₂, Se, Se═O, SeO₂, BR¹⁰, BiR¹⁰, R³Bi═O, 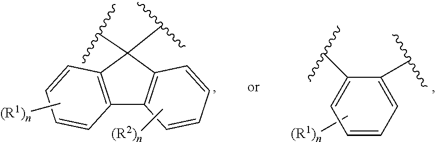
or B¹ is not present and Cy¹ and Cy² are connected by a single bond;
wherein when Cy³ is present, then B¹ is selected from the group consisting of CR⁸, SiR⁸, GeR⁸, N, P, P═O, As, As═O, B, R¹⁰Bi═O, or Bi, or B¹ is not present and Cy¹ and Cy² are connected by a single bond;
wherein when Cy⁶ is absent, then B² is selected from the group consisting of CR¹R², CR¹═CR², C≡C, C═O, C═S, SiR¹¹R¹², GeR¹¹R¹², NR¹³, PR¹³, R¹³P═O, AsR¹³, R¹³As═O, O, S, S═O, SO₂, Se, Se═O, SeO₂, BR¹³, BiR¹³, R¹³Bi═O, 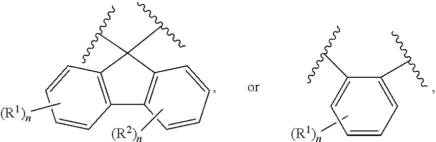
or B² is not present and Cy⁴ and Cy⁵ are connected by a single bond;
wherein when Cy⁶ is present, then B² is selected from the group consisting of CR¹¹, SiR¹¹, GeR¹¹, N, P, P═O, As, As═O, B, R¹³Bi═O, or Bi, or B² is not present and Cy⁴ and Cy⁵ are connected by a single bond;
wherein when Cy⁷ is absent, then A⁴ is absent and B² is A⁸;
wherein when Cy⁷ is present, then B² is selected from the group consisting of CR¹⁴, SiR¹⁴, GeR¹⁴, N, P, P═O, As, As═O, B, R¹⁴Bi═O, or Bi;
each of A¹, A², A³, A⁴, A⁵, and A⁸ is independently absent or present, and each of A¹, A², A³, A⁴, A⁵, and A⁸ represents a single bond, CR¹⁵R¹⁶, CR¹⁵═CR¹⁶, C≡C, C═O, C═S, SiR¹⁵R¹⁶, GeR¹⁵R¹⁶, NR¹⁷, PR¹⁷, R¹⁷P═O, AsR¹⁷, R¹⁷As═O, O, S, S═O, SO₂, Se, Se═O, SeO₂, BR¹⁷, BiR¹⁷, R¹⁷Bi═O, 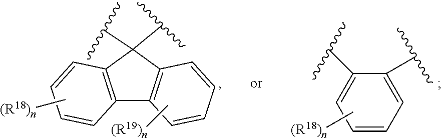
each of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ is independently absent or present as a single substituent or multiple substituents, valency permitting, and each R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents optionally join to form a fused ring of Formula A, Formula B, Formula C, or Formula D: 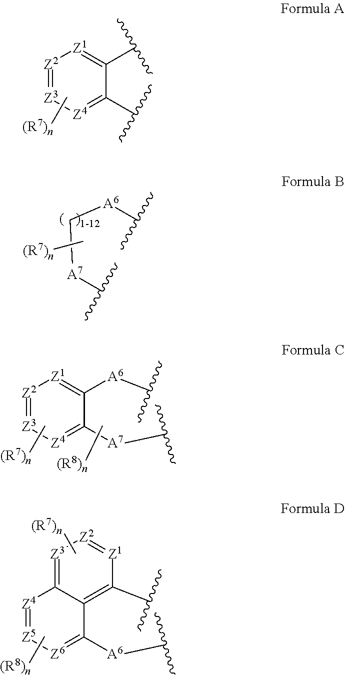
each of A⁶ and A⁷ is independently a single bond, CR¹R², CR¹═CR², C≡C, C═O, C═S, SiR¹R², GeR¹R², NR³, PR³, R³P═O, AsR³, R³As═O, O, S, S═O, SO₂, Se, Se═O, SeO₂, BR³, BiR³, R³Bi═O, 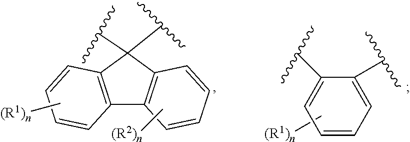
each of Z¹, Z², Z³, Z⁴, Z⁵, and Z⁶ is independently N, C, P, O, S, or Si.
each R⁷ and R⁸ is independently absent or present as a single substituent or multiple substituents, valency permitting, and each R⁷ and R⁸ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
wherein any two adjacent substituents may further join to form a fused ring; and
wherein one or more of R¹, R², R³, R⁴, R⁵, R⁶, R⁷, R⁸, R⁹, R¹⁰, R¹¹, R¹², R¹³, R¹⁴, R¹⁵, R¹⁶, R¹⁷, R¹⁸, and R¹⁹ optionally represents R^{X}, wherein R^{X} is a bulky substituent selected from the group consisting branched alkyl, cycloalkyl, bicyclo, fused bicyclo, adamantyl, ferrocenyl, dialkylamino, diarylamino, alkylarylamino, trialkylsilyl, tricycloalkylsilyl, triarylsilyl, triheteroarylsilyl, dialkylarylsilyl, alkyldiarylsilyl, alkylarylamino, and optionally substituted: aryl and heteroaryl.

2. The compound of claim 1, wherein the compound is represented by Formula II: 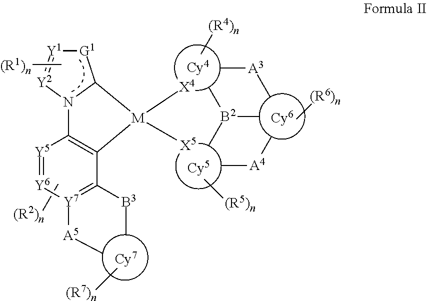
wherein:
G¹ is O, NR¹, CR¹, or S;
Y¹, Y², Y⁵, Y⁶, and Y⁷ is independently N, C, P, O, S, or Si; and
at least one R¹ is present and represents R^{X}.

3. The compound of claim 1, wherein the compound is represented by a structure of LIST 1.

4. The compound of claim 1, wherein the compound is represented by a structure of LIST 2 or LIST 2A.

5. The compound of claim 1, wherein the compound is represented by a structure of LIST 3.

6. The compound of claim 1, wherein the compound is represented by Formula III: 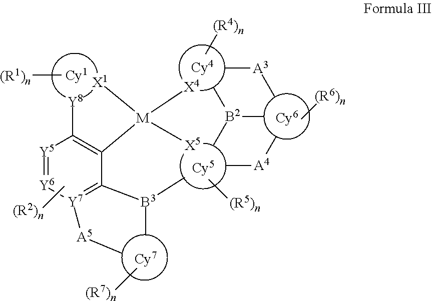
wherein:
each of Y⁵, Y⁶, and Y⁷ is independently N, C, P, O, S, or Si;
Cy¹ is selected from the group consisting of N-heterocyclic carbene, carbene, imidazole, and benzimidazole; wherein when Cy¹ is N-heterocyclic carbene or carbene, X¹ is C and Y⁸ is N; and when Cy¹ is imidazole or benzimidazole, X¹ is N and Y⁸ is C. X¹ is N; and
Y⁵ optionally fuses to R¹ or a substituent on R¹ to form a ring.

7. The compound of claim 1, wherein the compound is represented a structure of LIST 4.

8. The compound of claim 6, wherein the moiety 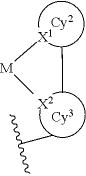
is independently one of the following structures: 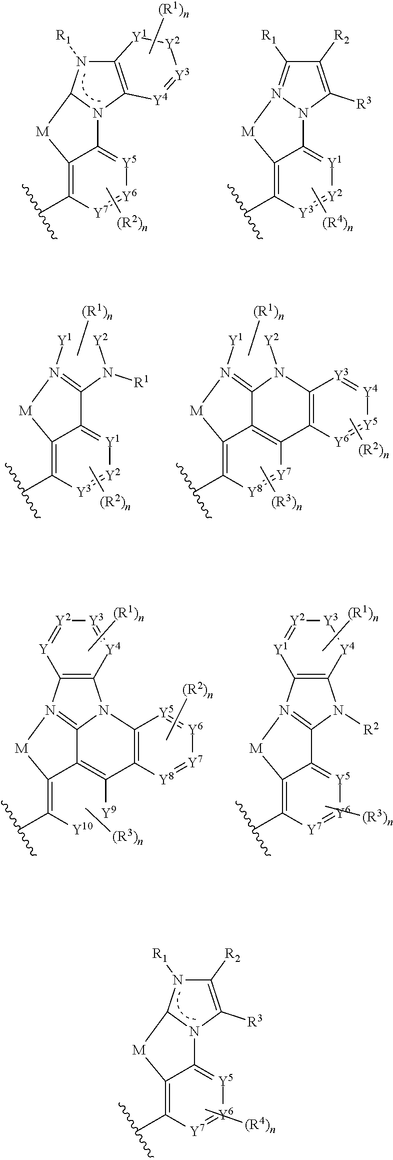
wherein:
each of Y¹, Y², Y³, Y⁴, Y⁵, Y⁶, Y⁷, Y⁸, Y⁹, and Y¹⁰ is independently N, C, P, O, S, or Si;
each of R¹, R², R³, R⁴ is independently absent or present as a single substituent or multiple substituents, valency permitting, and each R¹, R², R³, R⁴ present independently represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

9. The compound of claim 1, wherein the compound is represented by a structure of LIST 5.

10. The compound of claim 5, wherein Cy¹ represents N-heterocyclic carbene;
X¹ represents C; and
two adjacent two adjacent substituents R³ are present and together represent a group of Formula C.

11. The compound of claim 1, wherein the compound is represented by a structure of LIST 6.

12. The compound of claim 1, wherein the compound is represented by a structure of LIST 7 or LIST 7A.

13. The compound of claim 1, wherein A¹ is not present; Cy¹ is heteroaryl; X¹ is N; and two adjacent substituents R¹, two adjacent substituents R², two adjacent substituents R³, or two adjacent substituents R⁷ are present and together represent a group of Formula C.

14. The compound of claim 1, wherein the compound is represented by a structure of LIST 8.

15. The compound of claim 1, wherein B¹ is not present;
B² is not present;
Cy¹ is heteroaryl;
X¹ is N; and
the structure 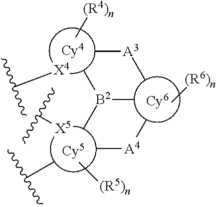
represents 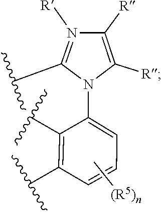
wherein R′ and R″ each represents hydrogen, deuterium, halogen, hydroxyl, thiol, nitro, cyanide, isocyanide, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof; and each occurrence of R″ represents aryl or heteroaryl;
wherein any two adjacent groups R′ or R″ optionally join to form a fused ring which is optionally further substituted.

16. The compound of claim 1, wherein B¹ is not present;
Cy¹ represents a heteroaryl;
X¹ is N; and
two adjacent substituents R¹, two adjacent substituents R², two adjacent substituents R³, or two adjacent substituents R⁷ are present and together represent a group of Formula C.

17. The compound of claim 1, wherein the compound is represented by a structure of LIST 9.

18. The compound of claim 1, wherein the compound is represented by a structure of LIST 10.

19. The compound of claim 1, wherein the compound is represented by a structure of LIST 11 or LIST 11A.

20. An organic electroluminescent device comprising the compound of claim 1.
